(19) United States
(12) Patent Application Publication
(10) Pub. No.: US 2025/0043174 A1
(43) Pub. Date: Feb. 6, 2025

(54) ORGANIC ELECTROLUMINESCENT MATERIAL AND DEVICE COMPRISING SAME

(71) Applicant: Beijing Summer Sprout Technology Co., LTD, Beijing (CN)

(72) Inventors: Zheng WANG, Beijing (CN); Zhen WANG, Beijing (CN); Hongbo LI, Beijing (CN); Wei CAI, Beijing (CN); Chi Yuen Raymond Kwong, Beijing (CN); Chuanjun Xia, Beijing (CN)

(21) Appl. No.: 18/784,359

(22) Filed: Jul. 25, 2024

(30) Foreign Application Priority Data
Jul. 27, 2023 (CN) 202310933375.2

(51) Int. Cl. C09K 11/06; H10K 50/12; H10K 85/30

(52) U.S. Cl. CPC C09K 11/06; H10K 50/12; H10K 85/342; C09K 2211/185

(57) ABSTRACT

Provided are an organic electroluminescent material and a device comprising the same. The organic electroluminescent material is a metal complex including a ligand Lₐ having a structure of Formula 1 and a ligand L_{b} having a structure of Formula 2. These new metal complexes, when applied to electroluminescent devices, can reduce the full width at half maximum of the device to make the maximum emission wavelength blue-shifted, thereby obtaining more saturated green light, and can also improve the efficiency of the device, thereby helping improve the comprehensive performance of the device. The metal complexes have great advantages and broad prospects in industrial applications. Further provided are an organic electroluminescent device including the metal complex and a composition including the metal complex.

### CROSS-REFERENCE TO RELATED APPLICATION(S)

This application claims priority to Chinese Patent Application No. 202310933375.2 filed on Jul. 27, 2023, the disclosure of which is incorporated herein by reference in its entirety.

### TECHNICAL FIELD

The present disclosure relates to compounds for organic electronic devices such as organic light-emitting devices. In particular, the present disclosure relates to a metal complex including a ligand Lₐ having a structure of Formula 1 and a ligand L_{b} having a structure of Formula 2, an organic electroluminescent device including the metal complex and a compound composition including the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid-state device, it offers tremendous potential for display and lighting applications. In addition, the inherent properties of organic materials, such as their flexibility, may make them well suited for particular applications such as fabrication on flexible substrates.

The OLED can be categorized into three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal-containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have a small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has a well-defined structure. Dendrimers with well-defined structures are considered as small molecules. Polymer OLEDs include conjugated polymers and non-conjugated polymers with pendant emitting groups. Small molecule OLED can become the polymer OLED if post-polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve a desired spectrum. In the case of green, yellow, and red OLEDs, phosphorescent emitters have successfully reached commercialization. The blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, the efficiency roll-off of phosphorescent OLEDs at high brightness remains a problem. In addition, it is desirable to have more saturated emitting color, higher efficiency, and longer device lifetime.

From the perspective of electronics, the display principle of the OLED is briefly explained as follows: under the action of an applied electric field greater than a certain threshold, holes and electrons are injected into an organic thin-film emissive layer sandwiched between the anode and the cathode, respectively, in the form of an electric current, the two recombine and form excitons, and radiation recombination occurs to cause light emission. Since the organic emissive thin film has significant capacitance characteristics, the capacitance of the organic thin-film emissive layer is a key factor that affects the response time and refresh frequency of the OLED display device at a low grayscale.

US20200251666A1 discloses a metal complex including a ligand Lₐ of the general formula:

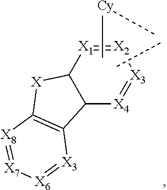

wherein at least one CRₓ is present in X₁ to X₈ and Rₓ is a cyano group or fluorine. This application has not disclosed or taught a metal complex in which X₄ is a specific substituent and heteroaryl or aryl substitution is further performed on other ligands and the effect thereof on device performance.

### SUMMARY

The present disclosure aims to provide a series of metal complexes each including a ligand Lₐ having a structure of Formula 1 and a ligand L_{b} having a structure of Formula 2 to solve at least part of the aforementioned problems. These new metal complexes, when applied to electroluminescent devices, can obtain more saturated green light and improve the efficiency of the device, thereby helping improve the comprehensive performance of the device.

According to an embodiment of the present disclosure, a metal complex is disclosed. The metal complex has a general structure of M(Lₐ)ₘ(L_{b})ₙ(L_{c})_{q};
wherein the metal M is selected from a metal with a relative atomic mass greater than 40;
m is selected from 1 or 2, n is selected from 1 or 2, q is selected from 0 or 1, and m+n+q equals the oxidation state of the metal M; when m is 2, two Lₐ are identical or different; when n is 2, two L_{b} are identical or different;
L_{c} is selected from a monoanionic bidentate ligand;
Lₐ has a structure represented by Formula 1, and L_{b} has a structure represented by Formula 2:

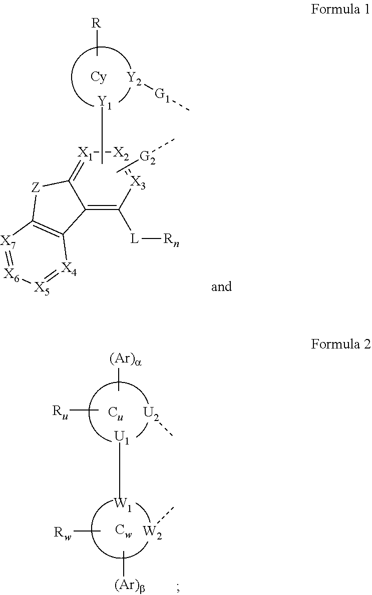

wherein
C_{y} is, at each occurrence identically or differently, selected from an aromatic ring including Y₁ and Y₂ and having 6 to 24 ring atoms, a heteroaromatic ring including Y₁ and Y₂ and having 5 to 24 ring atoms, or a combination thereof;
Cᵤ is, at each occurrence identically or differently, selected from an aromatic ring including U₁ and U₂ and having 6 to 24 ring atoms, a heteroaromatic ring including U₁ and U₂ and having 5 to 24 ring atoms, or a combination thereof;
C_{w} is, at each occurrence identically or differently, selected from an aromatic ring including W₁ and W₂ and having 6 to 24 ring atoms, a heteroaromatic ring including W₁ and W₂ and having 5 to 24 ring atoms, or a combination thereof;
G₁ and G₂ are, at each occurrence identically or differently, selected from a single bond, O or S;
X₁ to X₃ are, at each occurrence identically or differently, selected from C, CRₓ or N; one of
X₁ to X₃ is selected from C and joined to Y₁;
when G₂ is selected from a single bond and X₁, X₂ or X₃ is selected from N, X₁, X₂ or X₃ is joined to the metal through a metal-nitrogen bond formed through G₂; or when G₂ is selected from a single bond, O or S and X₁, X₂ or X₃ is selected from C, X₁, X₂ or X₃ is joined to the metal through G₂;
X₄ to X₇ are, at each occurrence identically or differently, selected from CRₓ or N;
at least one of X₁ to X₇ is selected from CRₓ, wherein Rₓ is a cyano group or fluorine;
Z is, at each occurrence identically or differently, selected from the group consisting of O, S, Se, NR′, CR′R′, SiR′R′ and GeR′R′; when two R′ are present at the same time, the two R′ are identical or different;
Y₁, Y₂, U₁, U₂, W₁ and W₂ are, at each occurrence identically or differently, selected from C or N;
α and β are, at each occurrence identically or differently, selected from 0, 1 or 2, and α+β is greater than or equal to 1;
Ar is, at each occurrence identically or differently, selected from substituted or unsubstituted aryl having 6 to 30 carbon atoms, substituted or unsubstituted heteroaryl having 3 to 30 carbon atoms, or a combination thereof;
L is, at each occurrence identically or differently, selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R, Rᵤ and R_{w} represent, at each occurrence identically or differently, mono-substitution, multiple substitutions or non-substitution; when a plurality of R are present, the plurality of R are identical or different; when a plurality of Rᵤ are present, the plurality of Rᵤ are identical or different; when a plurality of R_{w} are present, the plurality of R_{w} are identical or different;
R, Rₓ and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring;
adjacent substituents R′, Rₓ can be optionally joined to form a ring.

According to another embodiment of the present disclosure, an organic electroluminescent device is further disclosed. The organic electroluminescent device includes an anode, a cathode, and an organic layer disposed between the anode and the cathode, wherein at least one layer of the organic layer includes the metal complex described in the aforementioned embodiment.

According to another embodiment of the present disclosure, a compound composition is further disclosed. The compound composition includes the metal complex described in the aforementioned embodiments.

The present disclosure aims to provide a series of metal complexes each including a ligand Lₐ having a structure of Formula 1 and a ligand L_{b} having a structure of Formula 2 to solve at least part of the aforementioned problems. These new metal complexes, when applied to electroluminescent devices, can reduce the full width at half maximum of the device to make the maximum emission wavelength blue-shifted, thereby obtaining more saturated green light, and can also improve the efficiency of the device, thereby helping improve the comprehensive performance of the device. The metal complexes have great advantages and broad prospects in industrial applications.

### BRIEF DESCRIPTION OF DRAWINGS

FIG. 1 is a schematic diagram of an organic light-emitting apparatus that may include a metal complex and a compound composition including the metal complex disclosed herein.

FIG. 2 is another schematic diagram of an organic light-emitting apparatus that may include a metal complex and a compound composition including the metal complex disclosed herein.

### DETAILED DESCRIPTION

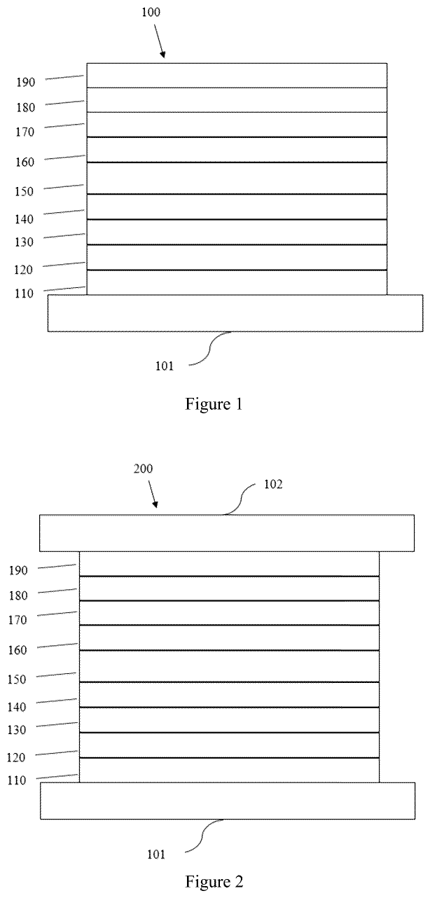

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve the desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light-emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal-containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight-chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h] quinoxaline, dibenzo[f,h] quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

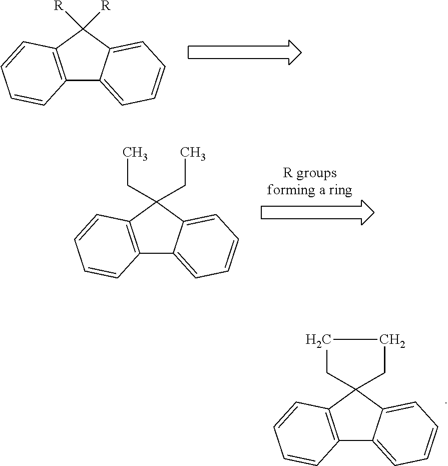

The expression that adjacent substituents can be optionally joined to form a ring is also intended to mean that two substituents bonded to carbon atoms which are directly bonded to each other are joined to each other via a chemical bond to form a ring, which can be exemplified by the following formula:

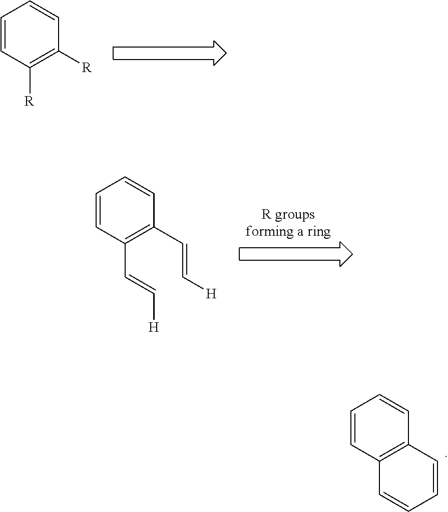

The expression that adjacent substituents can be optionally joined to form a ring is also intended to mean that two substituents bonded to a further distant carbon atom are joined to each other via a chemical bond to form a ring, which can be exemplified by the following formula:

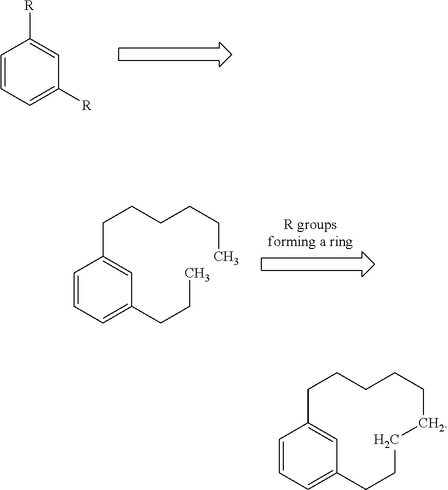

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

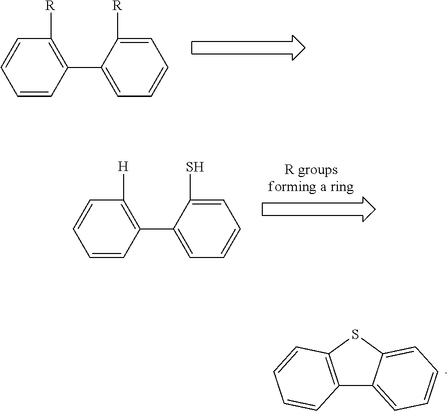

According to an embodiment of the present disclosure, a metal complex is disclosed. The metal complex has a general structure of M(Lₐ)ₘ(L_{b})ₙ(L_{c})_{q};
wherein the metal M is selected from a metal with a relative atomic mass greater than 40;
m is selected from 1 or 2, n is selected from 1 or 2, q is selected from 0 or 1, and m+n+q equals the oxidation state of the metal M; when m is 2, two Lₐ are identical or different; when n is 2, two L_{b} are identical or different;
L_{c} is selected from a monoanionic bidentate ligand;
Lₐ has a structure represented by Formula 1, and L_{b} has a structure represented by Formula 2:

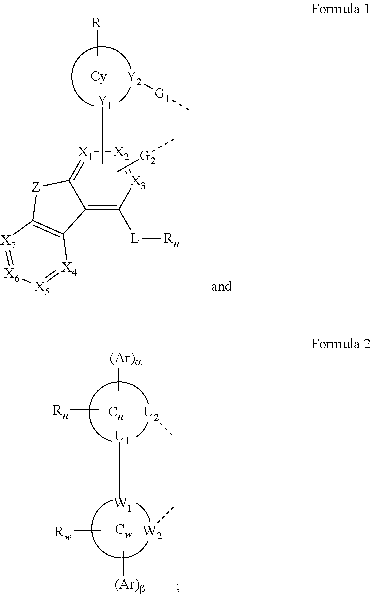

wherein
C_{y} is, at each occurrence identically or differently, selected from an aromatic ring including Y₁ and Y₂ and having 6 to 24 ring atoms, a heteroaromatic ring including Y₁ and Y₂ and having 5 to 24 ring atoms, or a combination thereof;
Cᵤ is, at each occurrence identically or differently, selected from an aromatic ring including U₁ and U₂ and having 6 to 24 ring atoms, a heteroaromatic ring including U₁ and U₂ and having 5 to 24 ring atoms, or a combination thereof;
C_{w} is, at each occurrence identically or differently, selected from an aromatic ring including W₁ and W₂ and having 6 to 24 ring atoms, a heteroaromatic ring including W₁ and W₂ and having 5 to 24 ring atoms, or a combination thereof;
G₁ and G₂ are, at each occurrence identically or differently, selected from a single bond, O or S;
X₁ to X₃ are, at each occurrence identically or differently, selected from C, CRₓ or N; one of X₁ to X₃ is selected from C and joined to Y₁;
when G₂ is selected from a single bond and X₁, X₂ or X₃ is selected from N, X₁, X₂ or X₃ is joined to the metal through a metal-nitrogen bond formed through G₂; or when G₂ is selected from a single bond, O or S and X₁, X₂ or X₃ is selected from C, X₁, X₂ or X₃ is joined to the metal through G₂;
X₄ to X₇ are, at each occurrence identically or differently, selected from CRₓ or N;
at least one of X₁ to X₇ is selected from CRₓ, wherein Rₓ is a cyano group or fluorine;
Z is, at each occurrence identically or differently, selected from the group consisting of O, S, Se, NR′, CR′R′, SiR′R′ and GeR′R′; when two R′ are present at the same time, the two R′ are identical or different;
Y₁, Y₂, U₁, U₂, W₁ and W₂ are, at each occurrence identically or differently, selected from C or N;
α and β are, at each occurrence identically or differently, selected from 0, 1 or 2, and α+β is greater than or equal to 1;
Ar is, at each occurrence identically or differently, selected from substituted or unsubstituted aryl having 6 to 30 carbon atoms, substituted or unsubstituted heteroaryl having 3 to 30 carbon atoms, or a combination thereof;
L is, at each occurrence identically or differently, selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R, Rᵤ and R_{w} represent, at each occurrence identically or differently, mono-substitution, multiple substitutions or non-substitution; when a plurality of R are present, the plurality of R are identical or different; when a plurality of Rᵤ are present, the plurality of Rᵤ are identical or different; when a plurality of R_{w} are present, the plurality of R_{w} are identical or different;
R, Rₓ and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring;
adjacent substituents R′, Rₓ can be optionally joined to form a ring.

In this embodiment, the expression that “at least one of X₁ to X₇ is selected from CRₓ, wherein Rₓ is a cyano group or fluorine” is intended to mean that, except that X₁, X₂ or X₃ is joined to the metal and X₁, X₂ or X₃ is joined to Y₁ through G₂, at least one of X₁ to X₇ is CRₓ, wherein Ry is a cyano group or fluorine. For example, when X₂ is selected from C or N and joined to the metal through G₂ and X₁ is selected from C and joined to Y₁, the others (that is, X₃ to X₇) in X₁ to X₇ are identically or differently selected from CRₓ or N, and at least one of X₃ to X₇ is CRₓ, wherein Rₓ is a cyano group or fluorine. For example, X₇ or X₈ is CRₓ, wherein Rₓ is a cyano group or fluorine.

Herein, when G₁ is selected from a single bond, it means that Y₂ is directly joined to the metal M; when G₂ is selected from a single bond, it means that X₁, X₂ or X₃ is directly joined to the metal M.

Herein, the expression that “adjacent substituents R can be optionally joined to form a ring” is intended to mean that any one or more of groups of any two adjacent substituents R can be optionally joined to form a ring. Obviously, it is also possible that none of these substituents are joined to form a ring.

Herein, the expression that “adjacent substituents Rₓ, R′ can be optionally joined to form a ring” is intended to mean that any one or more of groups of adjacent substituents, such as two substituents Rₓ, two substituents R′, and substituents Rₓ and R′, can be joined to form a ring. Obviously, it is also possible that none of these substituents are joined to form a ring.

According to an embodiment of the present disclosure, C_{y} is, at each occurrence identically or differently, any structure selected from the group consisting of the following:

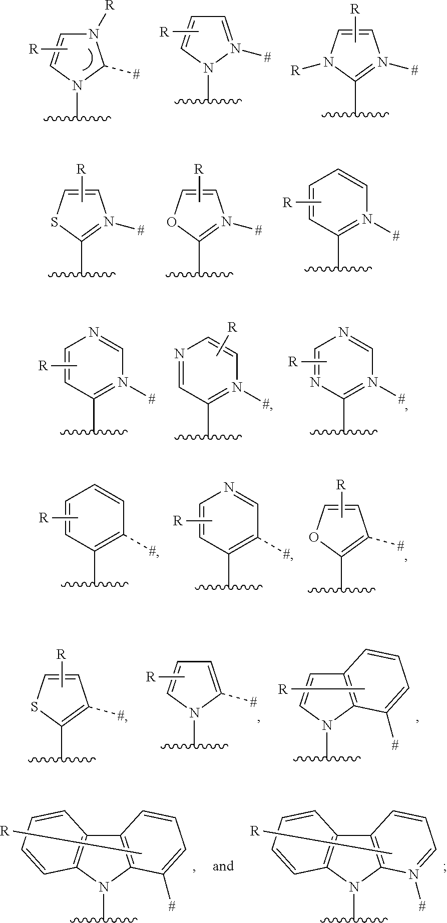

wherein
R represents, at each occurrence identically or differently, mono-substitution, multiple substitutions or non-substitution; when a plurality of R are present in any structure, the plurality of R are identical or different;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring;
“#” represents the position of attachment to the metal M, and

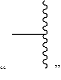

represents the position of attachment to X₁, X₂ or X₃.

According to an embodiment of the present disclosure, L_{b} is, at each occurrence identically or differently, a structure represented by any one selected from the group consisting of the following:

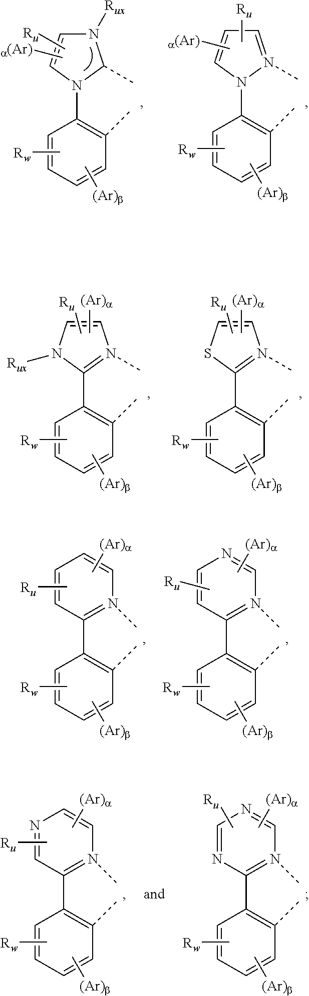

wherein
Rᵤ and R_{w} represent, at each occurrence identically or differently, mono-substitution, multiple substitutions or non-substitution;
α and β are, at each occurrence identically or differently, selected from 0, 1 or 2, and α+β is greater than or equal to 1;
Ar is, at each occurrence identically or differently, selected from substituted or unsubstituted aryl having 6 to 30 carbon atoms, substituted or unsubstituted heteroaryl having 3 to 30 carbon atoms, or a combination thereof;
Rᵤ, Rᵤₓ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, the metal M is, at each occurrence identically or differently, selected from the group consisting of Cu, Ag, Au, Ru, Rh, Pd, Os, Ir and Pt.

According to an embodiment of the present disclosure, the metal M is, at each occurrence identically or differently, selected from Pt or Ir.

According to an embodiment of the present disclosure, the metal M is, at each occurrence identically or differently, selected from Ir.

According to an embodiment of the present disclosure, G and G₂ are, at each occurrence identically or differently, selected from a single bond or O.

According to an embodiment of the present disclosure, G₁ and G₂ each are a single bond.

According to an embodiment of the present disclosure, L_{c} is, at each occurrence identically or differently, a structure represented by any one selected from the group consisting of the following:

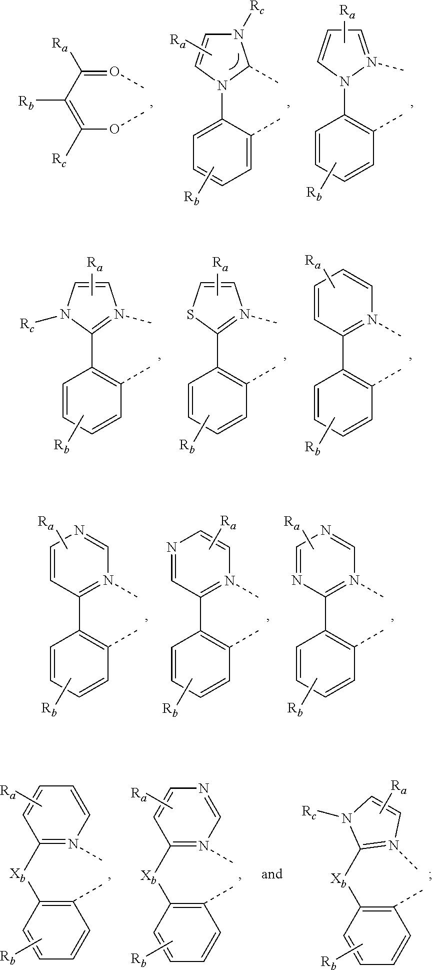

wherein
X_{b} is, at each occurrence identically or differently, selected from the group consisting of: O, S, Se, NR_{N1} and CR_{C1}R_{C2};
Rₐ and R_{b} represent, at each occurrence identically or differently, mono-substitution, multiple substitutions or non-substitution;
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{C1} and R_{C2} can be optionally joined to form a ring.

Herein, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{c} and R_{C2}, can be joined to form a ring. Obviously, it is also possible that none of these substituents are joined to form a ring. For example, adjacent substituents Rₐ and R_{b} in

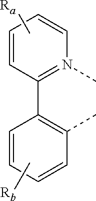

can be optionally joined to form a ring. When Rₐ is optionally joined to form a ring,

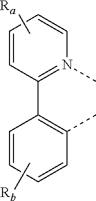

may form a structure of

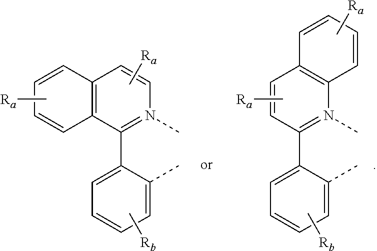

According to an embodiment of the present disclosure, L_{c} has the following structure:

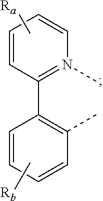

wherein
Rₐ and R_{b} represent, at each occurrence identically or differently, mono-substitution, multiple substitutions or non-substitution;
Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ and R_{b} can be optionally joined to form a ring.

According to an embodiment of the present disclosure, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, and combinations thereof.

According to an embodiment of the present disclosure, the metal complex has a general structure of Ir(Lₐ)ₘ(L_{b})₃₋ₘ which is represented by Formula 3:

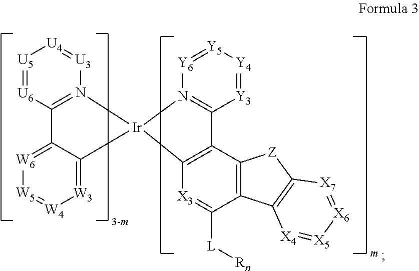

wherein
m is selected from 1 or 2; when m is selected from 1, two L_{b} are identical or different; when m is selected from 2, two Lₐ are identical or different;
Z is, at each occurrence identically or differently, selected from the group consisting of O, S, Se, NR′, CR′R′, SiR′R′ and GeR′R′; when two R′ are present at the same time, the two R′ are identical or different;
L is, at each occurrence identically or differently, selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
U₃ to U₆ are, at each occurrence identically or differently, selected from CRᵤ, CAr or N;
W₃ to W₆ are, at each occurrence identically or differently, selected from CR_{w}, CAr or N;
at least one of U₃ to U₆ and W₃ to W₆ is selected from CAr; Ar is, at each occurrence identically or differently, selected from substituted or unsubstituted aryl having 6 to 30 carbon atoms, substituted or unsubstituted heteroaryl having 3 to 30 carbon atoms, or a combination thereof;
X₃ to X₇ are, at each occurrence identically or differently, selected from CRₓ or N, and at least one of X₃ to X₇ is CRₓ, wherein Rₓ is a cyano group or fluorine;
Y₃ to Y₆ are, at each occurrence identically or differently, selected from CR or N;
R′, Rₓ and R are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring;
adjacent substituents R′ and Rₓ can be optionally joined to form a ring.

According to an embodiment of the present disclosure, m is selected from 1.

According to an embodiment of the present disclosure, Z is, at each occurrence identically or differently, selected from O or S.

According to an embodiment of the present disclosure, Z is selected from O.

According to an embodiment of the present disclosure, L is, at each occurrence identically or differently, selected from the group consisting of: a single bond, substituted or unsubstituted alkylene having 1 to 6 carbon atoms, substituted or unsubstituted cycloalkylene having 4 to 10 carbon atoms, substituted or unsubstituted arylene having 6 to 12 carbon atoms, and combinations thereof.

According to an embodiment of the present disclosure, L is, at each occurrence identically or differently, selected from the group consisting of: a single bond and substituted or unsubstituted alkylene having 1 to 6 carbon atoms.

According to an embodiment of the present disclosure, L is, at each occurrence identically or differently, selected from a single bond or substituted or unsubstituted methylene.

According to an embodiment of the present disclosure, Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted heteroaryl having 3 to 30 carbon atoms, and combinations thereof.

According to an embodiment of the present disclosure, Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, Rₙ is, at each occurrence identically or differently, selected from the group consisting of: deuterium, substituted or unsubstituted alkyl having 1 to 6 carbon atoms, and combinations thereof.

According to an embodiment of the present disclosure, Rₙ is, at each occurrence identically or differently, selected from the group consisting of:

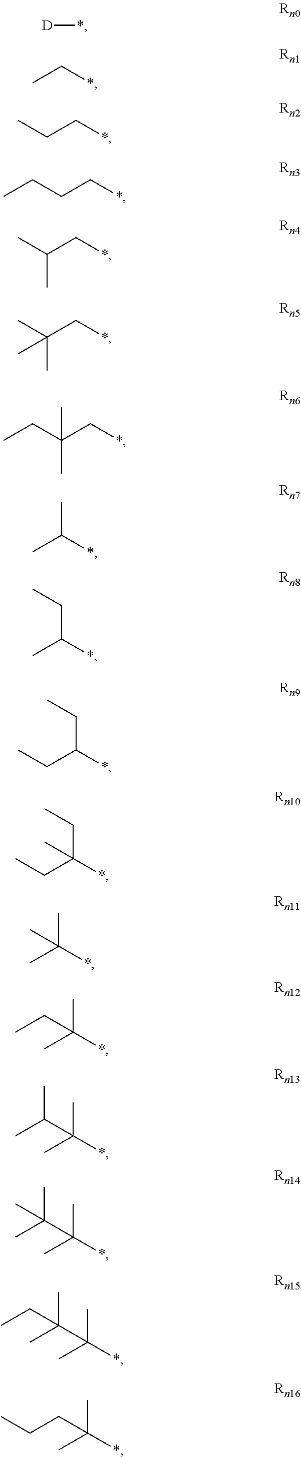

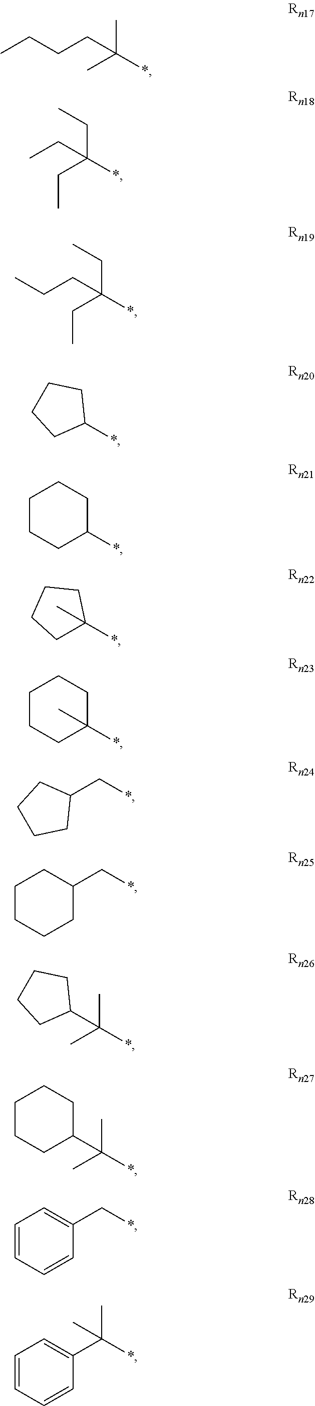

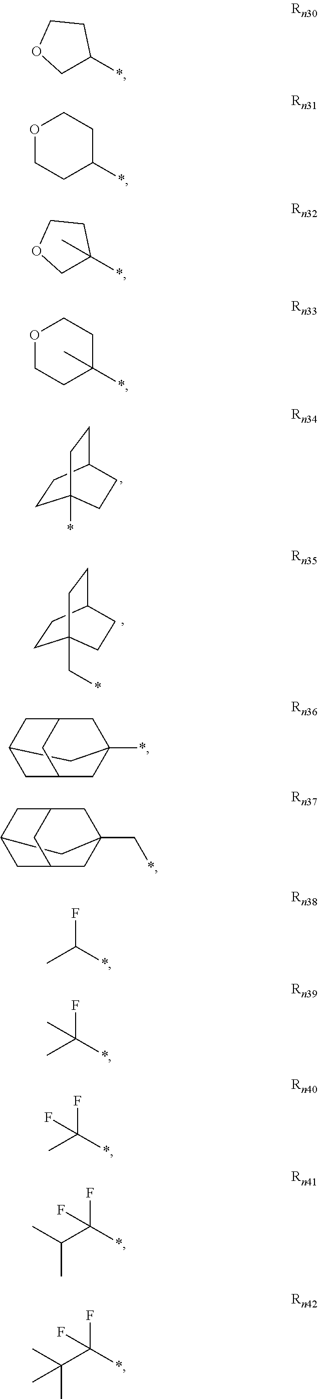

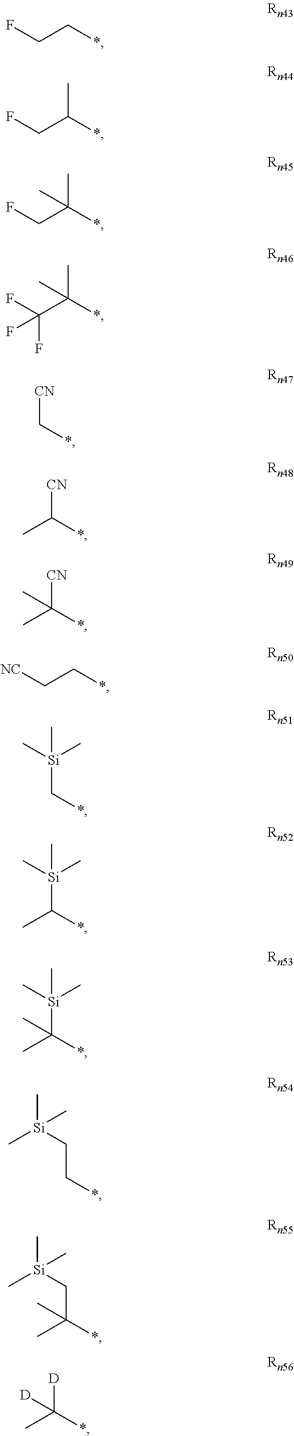

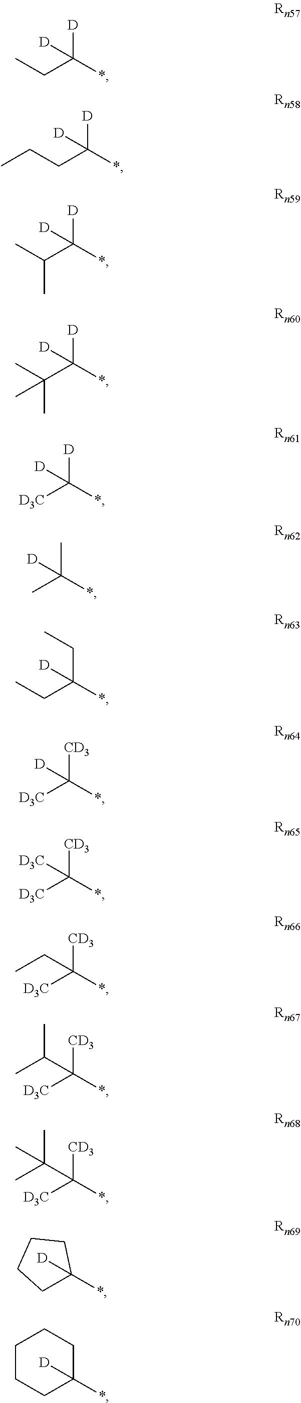

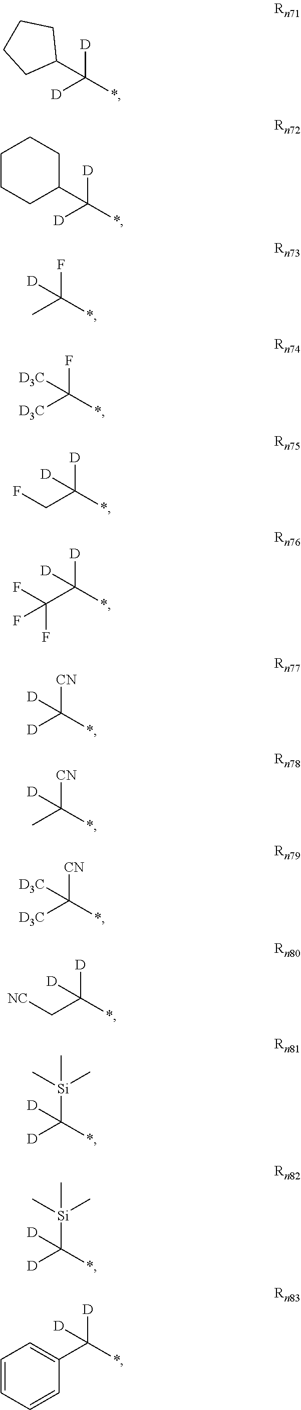

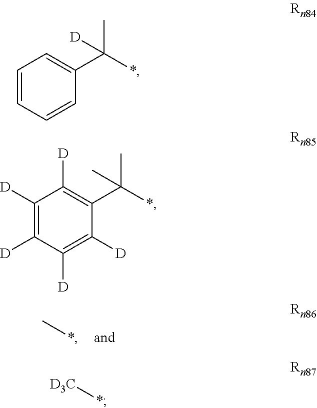

wherein optionally, hydrogens in the above Rₙ can be partially or fully substituted with deuterium;
“*” in Rₙ₁ to Rₙ₈₇ represents the position of attachment to L.

According to an embodiment of the present disclosure, Y₃ to Y₆ are, at each occurrence identically or differently, CR or N, and at least one of Y₃ to Y₆ is selected from CR, wherein R is selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, Y₃ to Y₆ are, at each occurrence identically or differently, CR or N, and at least one of Y₃ to Y₆ is selected from CR, wherein R is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, Y₃ to Y₆ are, at each occurrence identically or differently, CR or N, and at least one of Y₃ to Y₆ is selected from CR, wherein R is, at each occurrence identically or differently, selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, and combinations thereof.

According to an embodiment of the present disclosure, X₃ to X₇ are, at each occurrence identically or differently, selected from CRₓ.

According to an embodiment of the present disclosure, X₃ to X₇ are, at each occurrence identically or differently, selected from CRₓ or N, and at least one of X₃ to X₆ is N. For example, one of X₃ to X₇ is selected from N or two of X₃ to X₇ are selected from N.

According to an embodiment of the present disclosure, at least two of X₃ to X₇ are selected from CRY, wherein one Rₓ is a cyano group or fluorine, and another Ry is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least two of X₄ to X₇ are selected from CRₓ, wherein one Rₓ is a cyano group or fluorine, and another Rₓ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, X₆ is selected from CRₓ, wherein Rₓ is a cyano group or fluorine; X₇ is selected from CRₓ, wherein Rₓ is selected from deuterium, substituted or unsubstituted aryl having 6 to 18 carbon atoms, substituted or unsubstituted heteroaryl having 3 to 18 carbon atoms, or a combination thereof.

According to an embodiment of the present disclosure, at least one of X₄ to X₇ is CRₓ, wherein Rₓ is a cyano group or fluorine.

According to an embodiment of the present disclosure, at least one of X₆ and/or X₇ is CRₓ, wherein Rₓ is a cyano group or fluorine.

According to an embodiment of the present disclosure, X₆ is CRₓ, wherein Rₓ is a cyano group.

According to an embodiment of the present disclosure, Y₃ to Y₆ are, at each occurrence identically or differently, selected from CR.

According to an embodiment of the present disclosure, Y₃ to Y₆ are, at each occurrence identically or differently, selected from CR or N, at least one of Y₃ to Y₆ is N. For example, one of Y₃ to Y₆ is selected from N or two of Y₃ to Y₆ are selected from N.

According to an embodiment of the present disclosure, U₃ to U₆ are, at each occurrence identically or differently, selected from CAr or CRᵤ.

According to an embodiment of the present disclosure, U₃ to U₆ are, at each occurrence identically or differently, selected from CAr, CRᵤ or N, and at least one of U₃ to U₆ is N. For example, one of U₃ to U₆ is selected from N.

According to an embodiment of the present disclosure, W₃ to W₆ are, at each occurrence identically or differently, selected from CAr or CR_{w}.

According to an embodiment of the present disclosure, W₃ to W₆ are, at each occurrence identically or differently, selected from CAr, CR_{w} or N, and at least one of W₃ to W₆ is N. For example, one of W₃ to W₆ is selected from N.

According to an embodiment of the present disclosure, at least one of U₃ to U₆ is CAr, and at least one of W₃ to W₆ is CAr, wherein Ar is selected from substituted or unsubstituted aryl having 6 to 30 carbon atoms, substituted or unsubstituted heteroaryl having 3 to 30 carbon atoms, or a combination thereof.

According to an embodiment of the present disclosure, at least one of U₃ to U₆ is CAr or at least one of W₃ to W₆ is CAr, wherein Ar is selected from substituted or unsubstituted aryl having 6 to 30 carbon atoms, substituted or unsubstituted heteroaryl having 3 to 30 carbon atoms, or a combination thereof.

According to an embodiment of the present disclosure, at least one of U₃ to U₆ is CAr or at least one of W₃ to W₆ is CAr, wherein Ar is selected from substituted or unsubstituted aryl having 6 to 18 carbon atoms, substituted or unsubstituted heteroaryl having 3 to 18 carbon atoms, or a combination thereof.

According to an embodiment of the present disclosure, Us is CAr or W₅ is CAr, wherein Ar is selected from substituted or unsubstituted aryl having 6 to 18 carbon atoms.

According to an embodiment of the present disclosure, W₅ is CAr, wherein Ar is selected from substituted or unsubstituted aryl having 6 to 18 carbon atoms.

According to an embodiment of the present disclosure, at least one or at least two of U₃ to U₆ are selected from CRᵤ, wherein Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of Rᵤ is at least 4.

According to an embodiment of the present disclosure, at least one or at least two of W₃ to W₆ are selected from CR_{w}, wherein R_{w} is selected from substituted or unsubstituted alkyl having 1 to 20 carbon atoms, substituted or unsubstituted cycloalkyl having 3 to 20 ring carbon atoms, or a combination thereof, and the total number of carbon atoms in all of R_{w} is at least 4.

According to an embodiment of the present disclosure, W₃ to W₆ are, at each occurrence identically or differently, selected from CAr or CR_{w}, at least one of W₃ to W₆ is selected from CAr, and U₃ to U₆ are, at each occurrence identically or differently, selected from CRᵤ, wherein Ar is selected from substituted or unsubstituted aryl having 6 to 30 carbon atoms, and R_{w} and Rᵤ are selected from the group consisting of: hydrogen, deuterium, halogen, substituted or unsubstituted alkyl having 1 to 20 carbon atoms, substituted or unsubstituted cycloalkyl having 3 to 20 ring carbon atoms, and combinations thereof.

According to an embodiment of the present disclosure, W₃ to W₆ are, at each occurrence identically or differently, selected from CAr or CR_{w}, W₅ is selected from CAr, and U₃ to U₆ are, at each occurrence identically or differently, selected from CRᵤ, wherein Ar is selected from substituted or unsubstituted aryl having 6 to 18 carbon atoms, and R_{w} and Rᵤ are selected from the group consisting of: hydrogen, deuterium, halogen, substituted or unsubstituted alkyl having 1 to 6 carbon atoms, and combinations thereof.

According to an embodiment of the present disclosure, U₃ to U₆ are selected from CAr or CRᵤ, and W₃ to W₆ are selected from CAr or CR_{w}, wherein Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, an isocyano group, and combinations thereof.

According to an embodiment of the present disclosure, U₃ to U₆ are selected from CAr or CRᵤ, and W₃ to W₆ are selected from CAr or CR_{w}, wherein Rᵤ and R_{w} are, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, U₃ to U₆ are selected from CAr or CRᵤ, and W₃ to W₆ are selected from CAr or CR_{w}, wherein Rᵤ and R_{w} are, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, and combinations thereof.

According to an embodiment of the present disclosure, Rᵤₓ is, at each occurrence identically or differently, selected from the group consisting of: hydrogen, deuterium, halogen, substituted or unsubstituted alkyl having 1 to 20 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, Ar is, at each occurrence identically or differently, selected from a group consisting of the following:

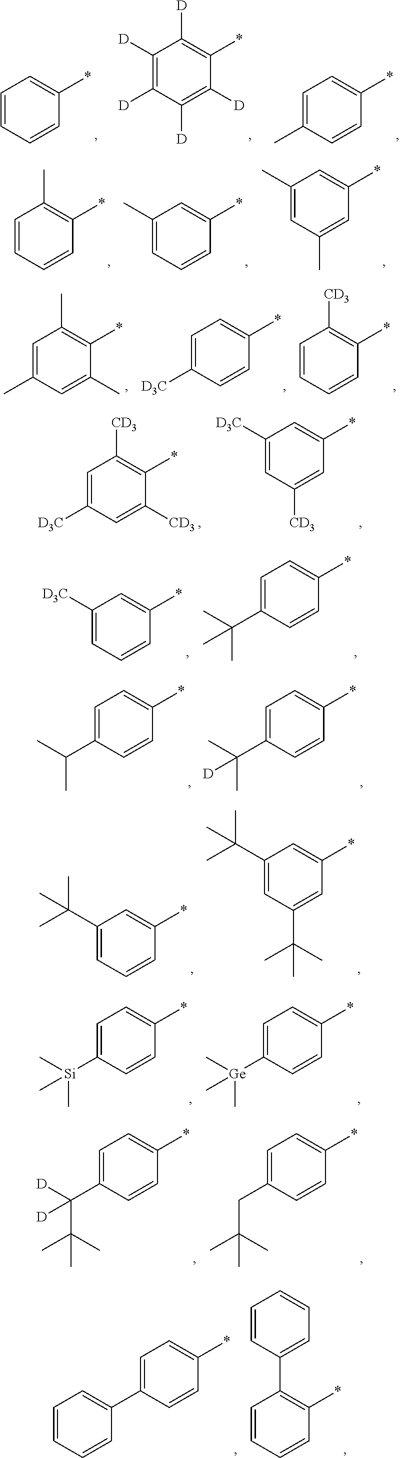

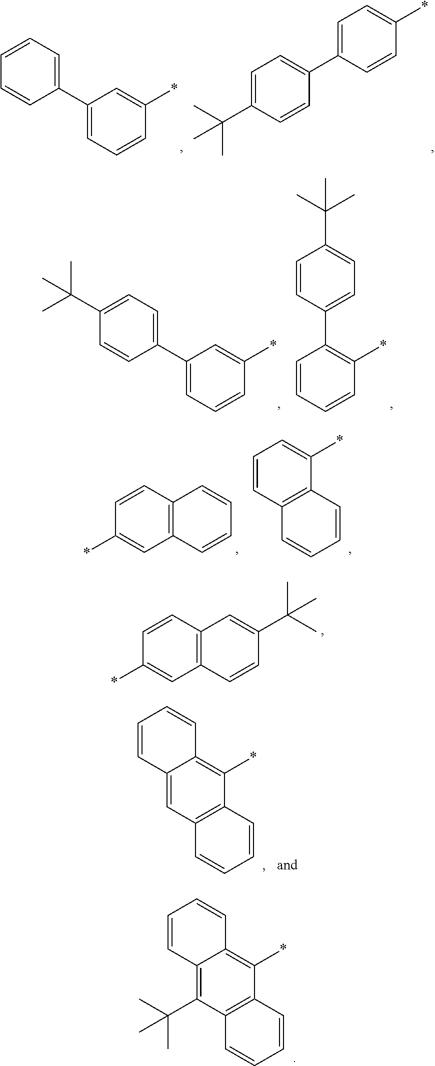

According to an embodiment of the present disclosure, Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof.

According to an embodiment of the present disclosure, Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

According to an embodiment of the present disclosure, Rₓ is, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, biphenyl, naphthyl, carbazolyl, pyridyl, trimethylsilyl, trimethylgermanyl, and combinations thereof.

According to an embodiment of the present disclosure, R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof.

According to an embodiment of the present disclosure, R is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

According to an embodiment of the present disclosure, R is, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated 1-butyl, deuterated cyclopentyl, deuterated cyclohexyl, phenyl, pyridyl, trimethylsilyl, trimethylgermanyl, and combinations thereof.

According to an embodiment of the present disclosure, at least one of Y₃ to Y₆ is selected from CR, wherein R is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, at least one Y₃ to Y₆ is selected from CR, wherein R is selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, and combinations thereof.

According to an embodiment of the present disclosure, at least one Y₃ to Y₆ is selected from CR, wherein R is selected from the group consisting of: deuterium, fluorine, methyl, ethyl, propyl, isopropyl, n-butyl, isobutyl, neopentyl, 1-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated 1-butyl, deuterated cyclopentyl, deuterated cyclohexyl, phenyl, trimethylsilyl, trimethylgermanyl, and combinations thereof.

According to an embodiment of the present disclosure, Lₐ is, at each occurrence identically or differently, selected from the group consisting of Lₐ₁ to Lₐ₃₅₂₆, wherein for the specific structures of Lₐ₁ to Lₐ₃₅₂₆, reference is made to claim 15.

According to an embodiment of the present disclosure, hydrogens in Lₐ₁ to Lₐ₃₅₂₆ can be partially or fully substituted with deuterium.

According to an embodiment of the present disclosure, L_{b} is, at each occurrence identically or differently, selected from any one of the group consisting of L_{b1} to L_{b1566}, wherein for the specific structures of L_{b1} to L_{b1566}, reference is made to claim 16.

According to an embodiment of the present disclosure, hydrogens in L_{b1} to L_{b1566} can be partially or fully substituted with deuterium.

According to an embodiment of the present disclosure, L_{c} is, at each occurrence identically or differently, selected from any one of the group consisting of L_{c1} to L_{c142}, wherein for the specific structures of L_{c1} to L_{c142}, reference is made to claim 17.

According to an embodiment of the present disclosure, hydrogens in L_{c1} to L_{c18}, L_{c20} to L_{c26} and L_{c31} to L_{c142} can be partially or fully substituted with deuterium.

According to an embodiment of the present disclosure, the metal complex has a structure of Ir(Lₐ)(L_{b})₂ or Ir(Lₐ)₂(L_{b}), wherein Lₐ is, at each occurrence identically or differently, selected from one or two of the group consisting of Lₐ₁ to Lₐ₃₅₂₆, and L_{b} is, at each occurrence identically or differently, selected from one or two of the group consisting of L_{b1} to L_{b1566}.

According to an embodiment of the present disclosure, the metal complex has a structure of Ir(Lₐ)(L_{b})(L_{c}), wherein Lₐ is, at each occurrence identically or differently, selected from one of the group consisting of Lₐ₁ to Lₐ₃₅₂₆, L_{b} is, at each occurrence identically or differently, selected from one of the group consisting of L_{b1} to L_{b1566}, and L_{c} is, at each occurrence identically or differently, selected from one of the group consisting of L_{c1} to L_{c142}.

According to an embodiment of the present disclosure, the metal complex is selected from the group consisting of Metal Complex 1 to Metal Complex 2959, wherein for the specific structures of Metal Complex 1 to Metal Complex 2959, reference is made to claim 18.

According to an embodiment of the present disclosure, an organic electroluminescent device is further disclosed. The organic electroluminescent device includes an anode, a cathode, and an organic layer disposed between the anode and the cathode, wherein at least one layer of the organic layer includes the metal complex described in any of the aforementioned embodiments.

According to an embodiment of the present disclosure, the organic layer including the metal complex is an emissive layer.

According to an embodiment of the present disclosure, the emissive layer further includes a first host compound.

According to an embodiment of the present disclosure, the emissive layer further includes a first host compound and a second host compound.

According to an embodiment of the present disclosure, the first host compound and/or the second host compound include at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the first host compound has a structure represented by Formula X-1 or Formula X-2:

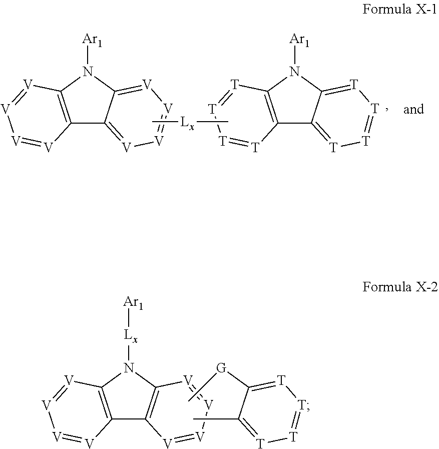

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O or S;
V is, at each occurrence identically or differently, selected from C, CR, or N;
in Formula X-1, T is, at each occurrence identically or differently, selected from C, CRₜ or N;
in Formula X-2, Tis, at each occurrence identically or differently, selected from CRI or N;
R_{g}, Rᵥ and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof;
adjacent substituents R_{g}, Rᵥ and Rₜ can be optionally joined to form a ring.

In this embodiment, the expression that “adjacent substituents R_{g}, Rᵥ and Rₜ can be optionally joined to form a ring” is intended to mean that any one or more of groups of adjacent substituents, such as two substituents Rᵥ, two substituents Rₜ, two substituents R_{g}, substituents Rᵥ and Rₜ, substituents Rᵥ and R_{g}, and substituents R_{g} and Rₜ, can be joined to form a ring. Obviously, it is also possible that none of these substituents are joined to form a ring.

According to an embodiment of the present disclosure, the first host compound has a structure represented by one of Formula X-a to Formula X-p:

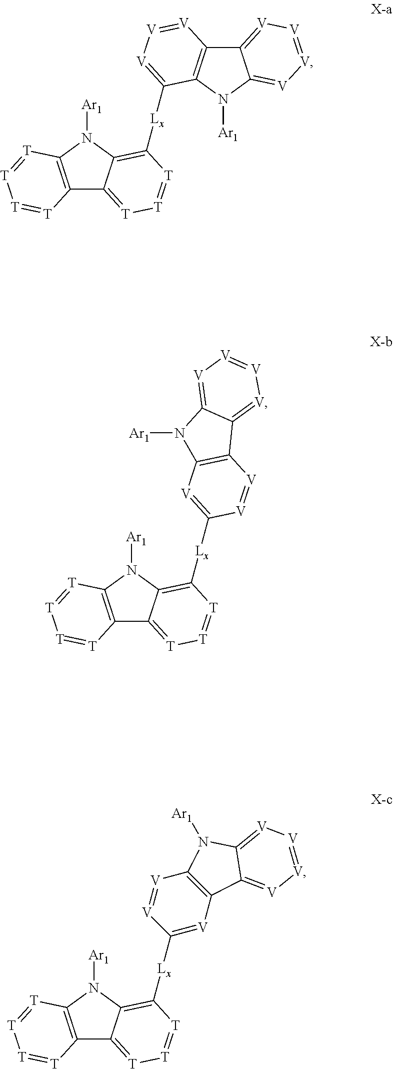

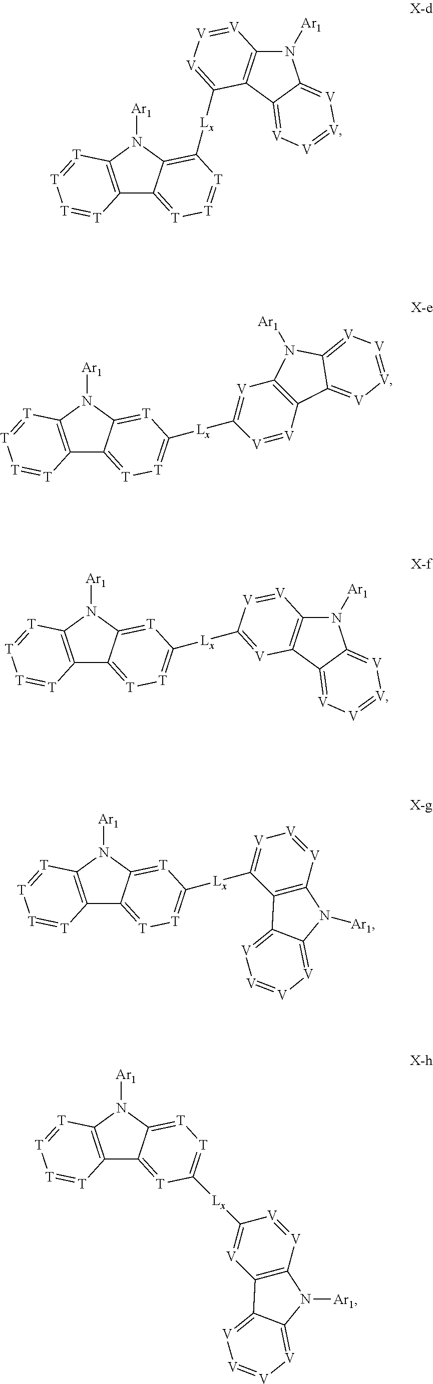

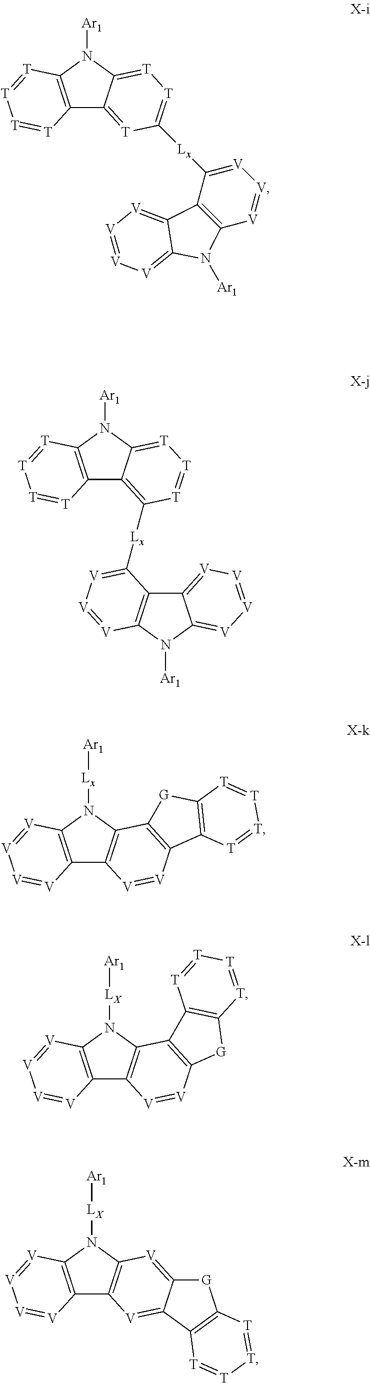

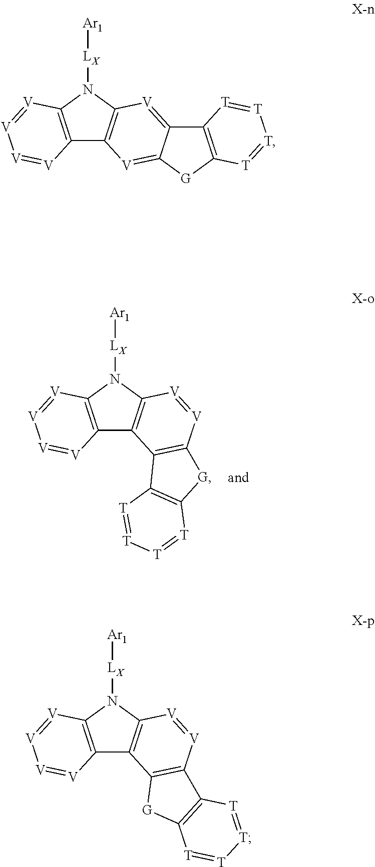

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O or S;
V is, at each occurrence identically or differently, selected from CR, or N;
T is, at each occurrence identically or differently, selected from CRₜ or N;
R_{g}, Rᵥ and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof;
adjacent substituents R_{g}, Rᵥ and Rₜ can be optionally joined to form a ring.

According to an embodiment of the present disclosure, the first host compound is selected from the group consisting of the following compounds:

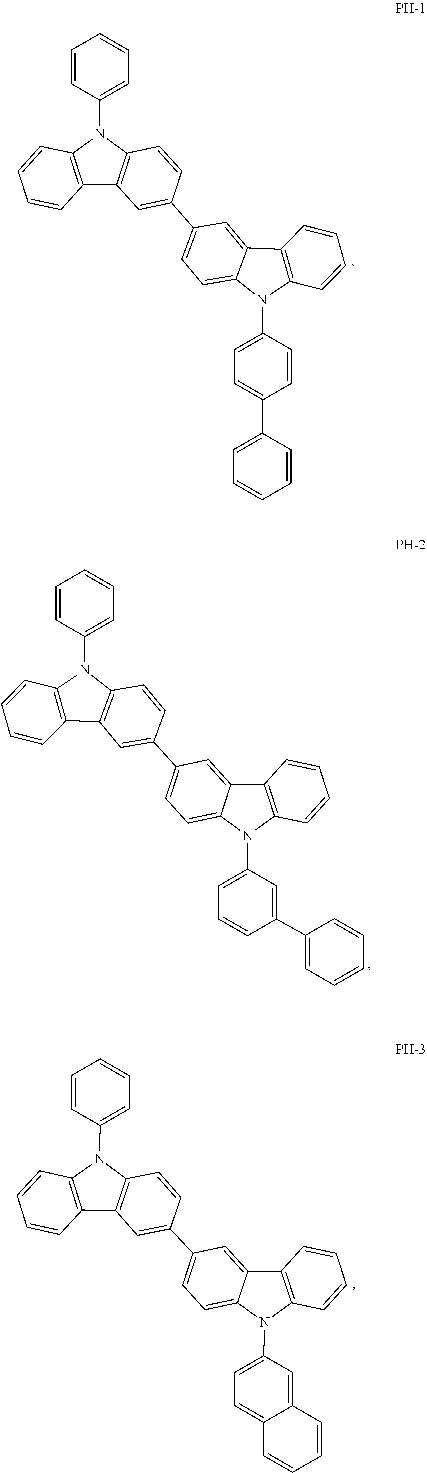 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1]

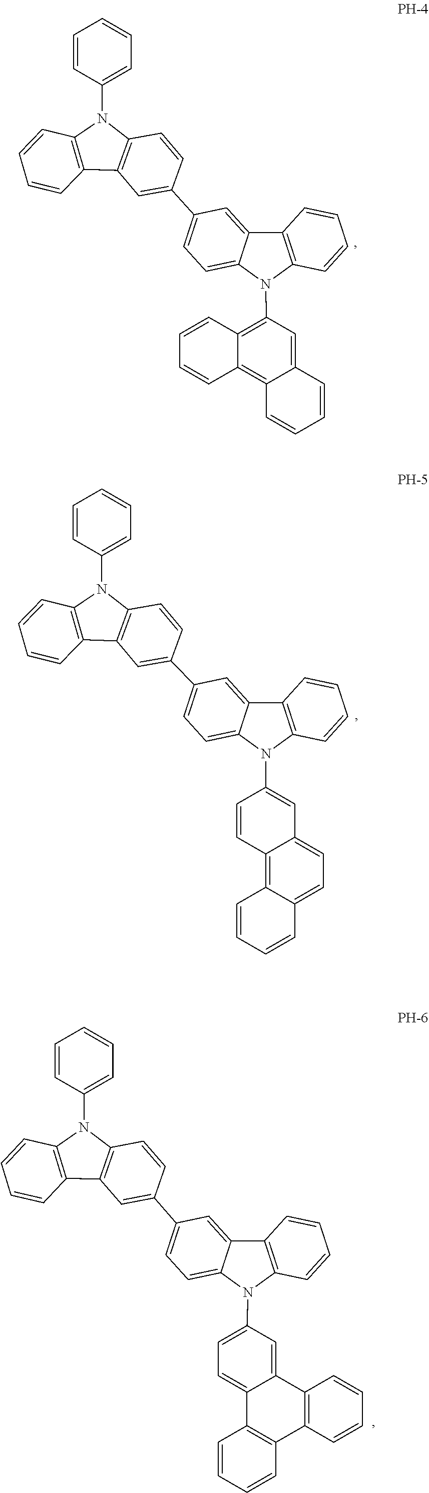 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

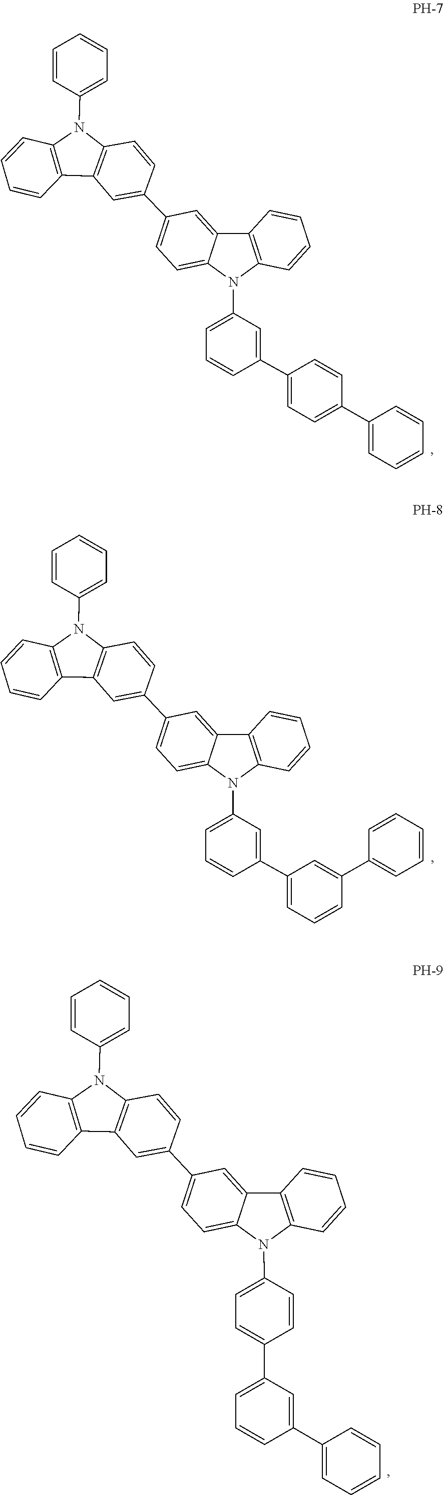 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

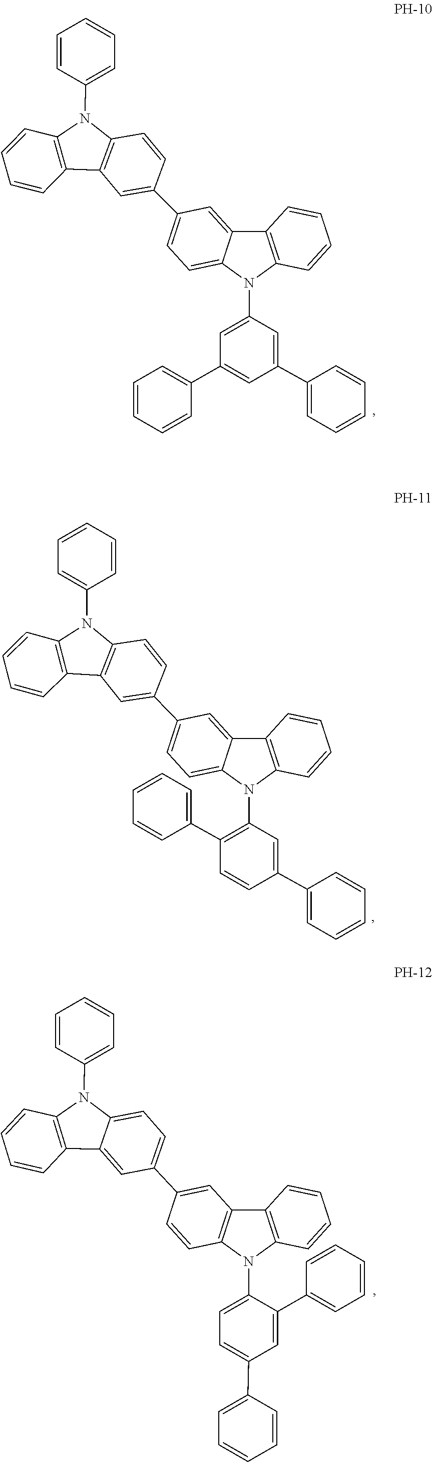 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1]

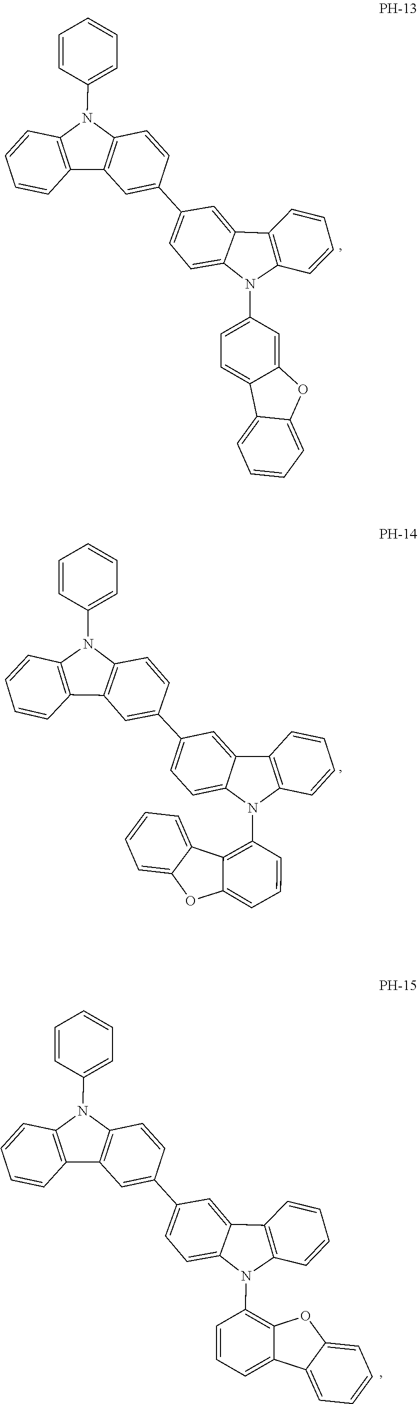 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1]

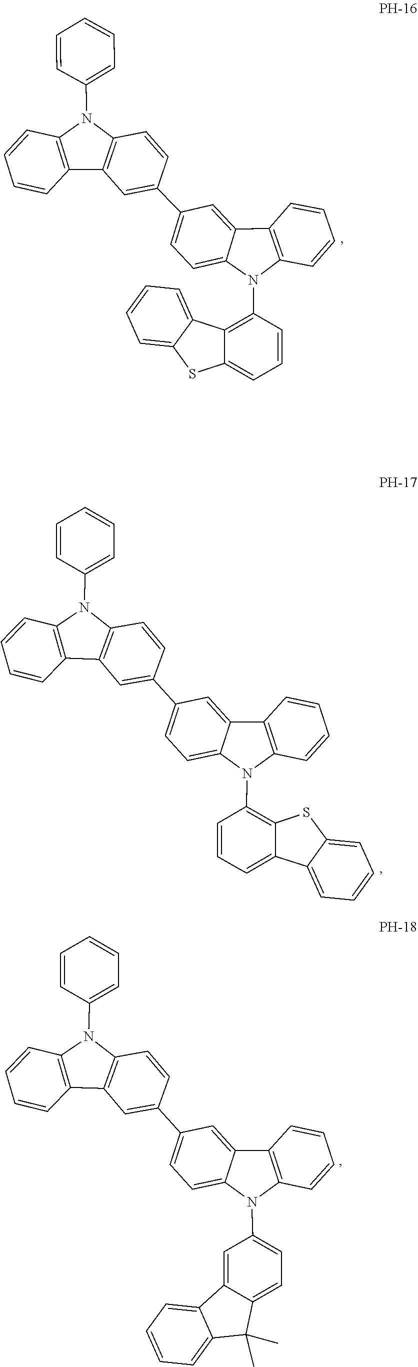 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21]

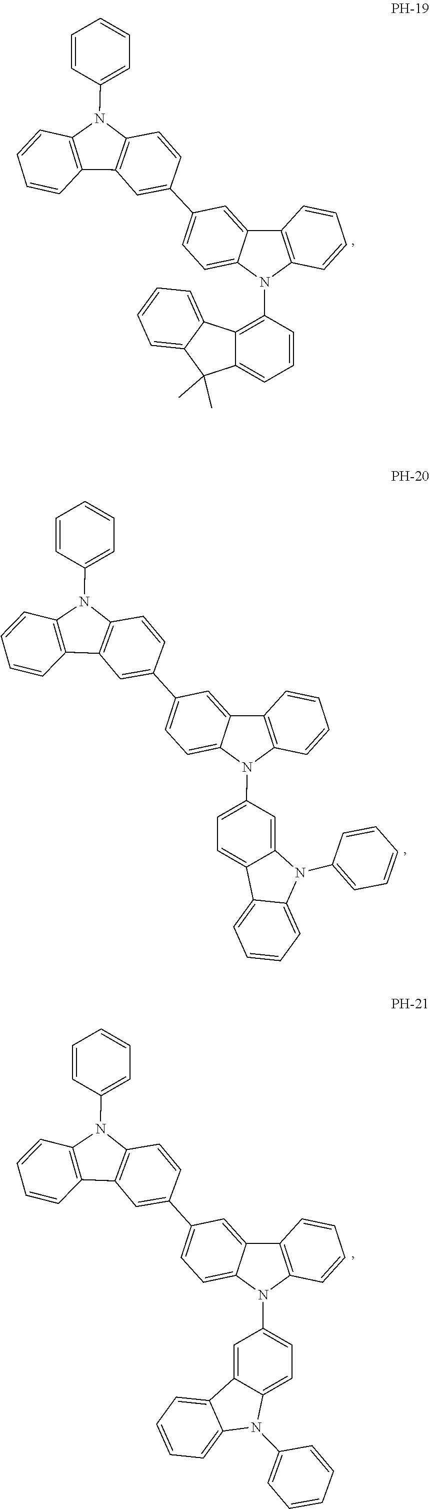 [SMILES: CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

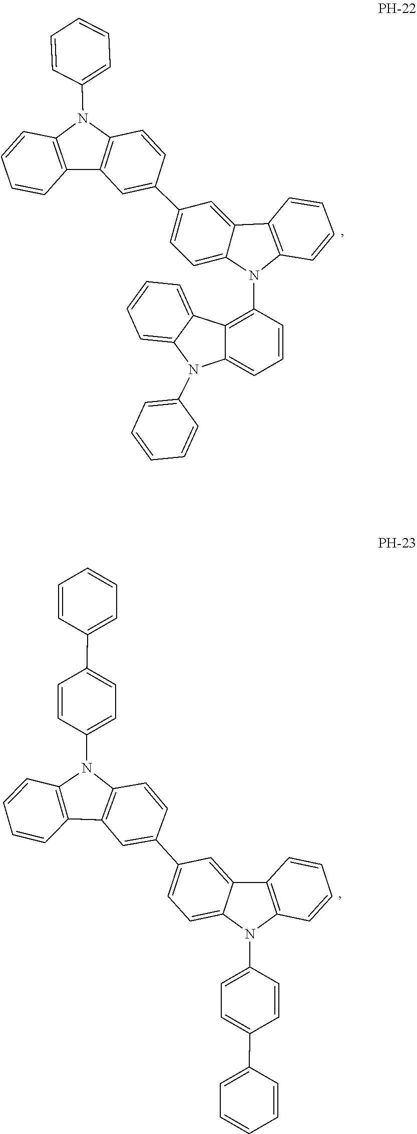 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

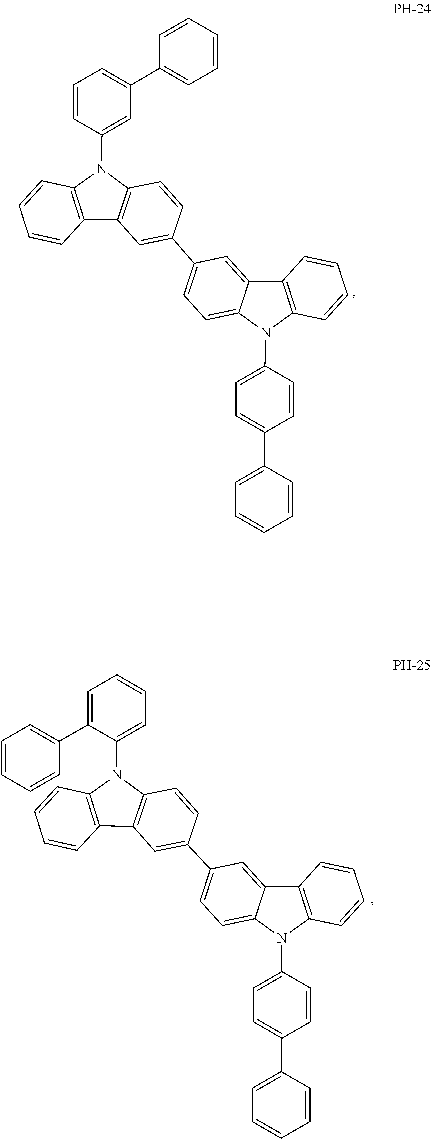 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1]

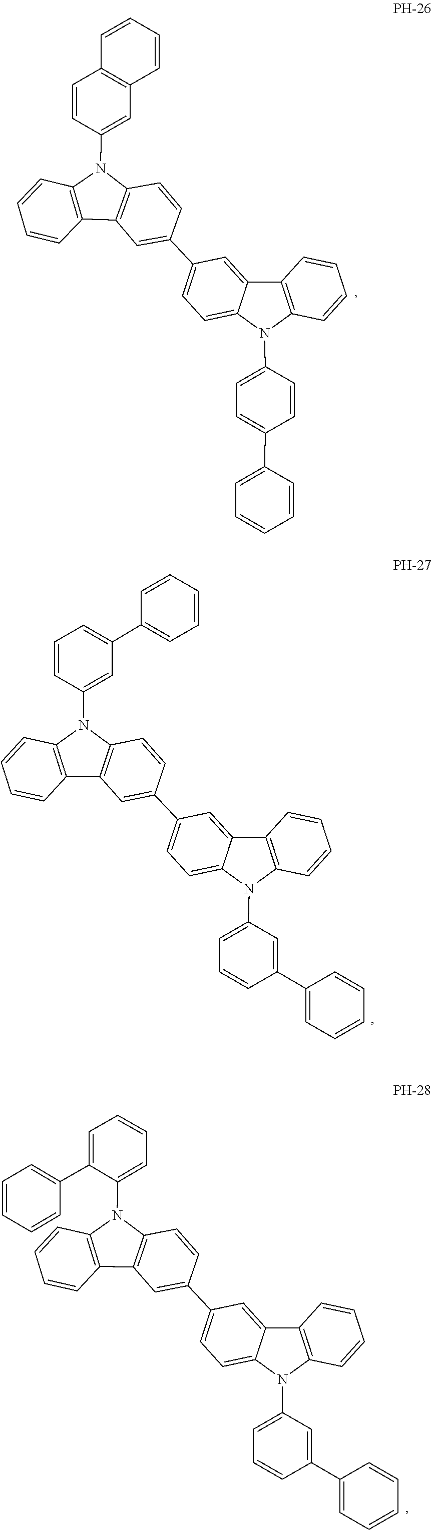 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

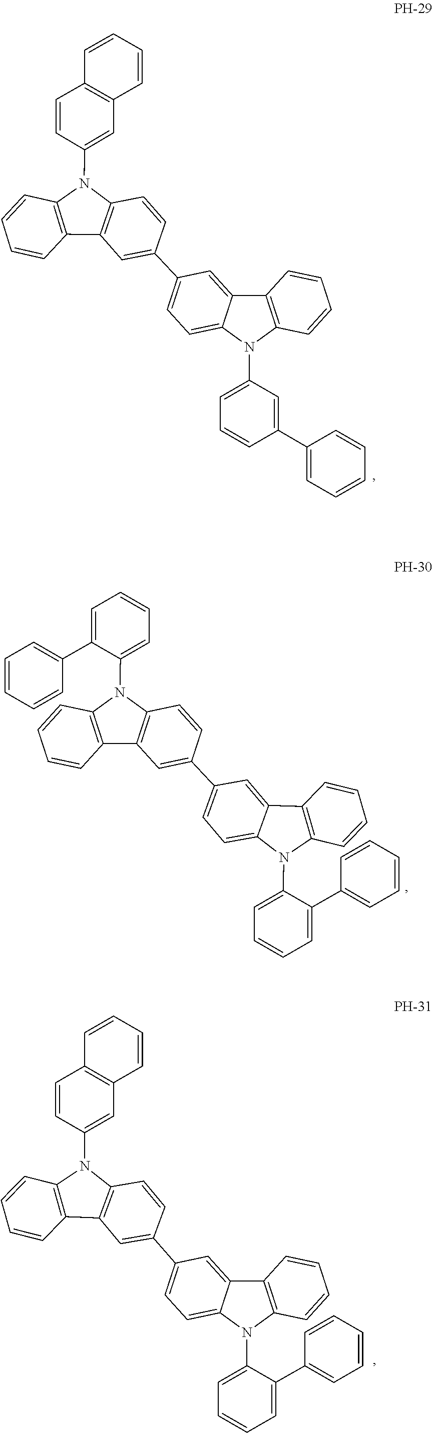 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1]

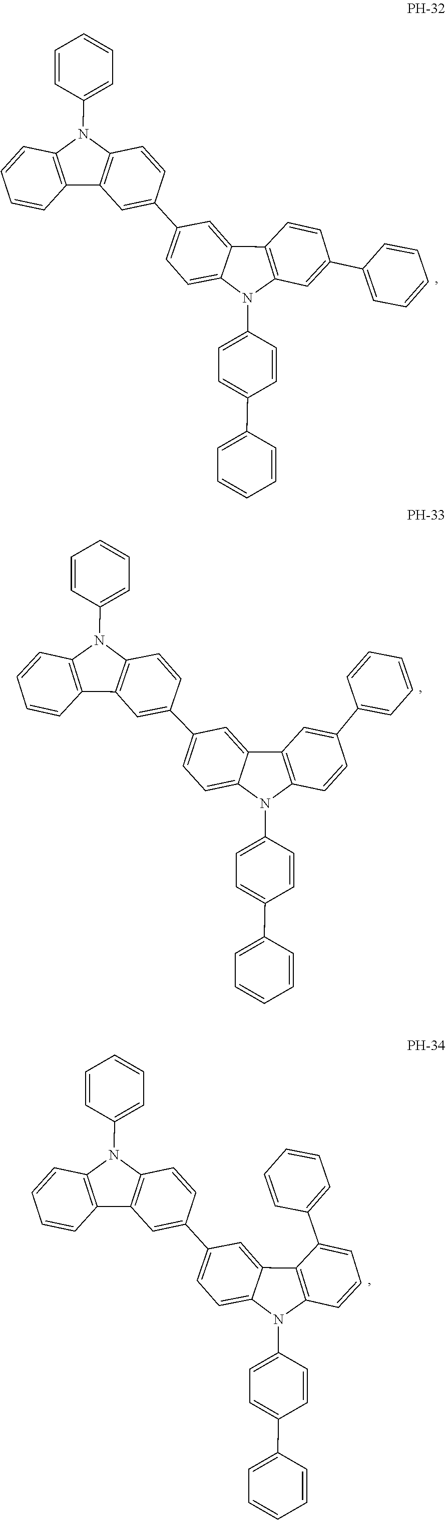 [SMILES: c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

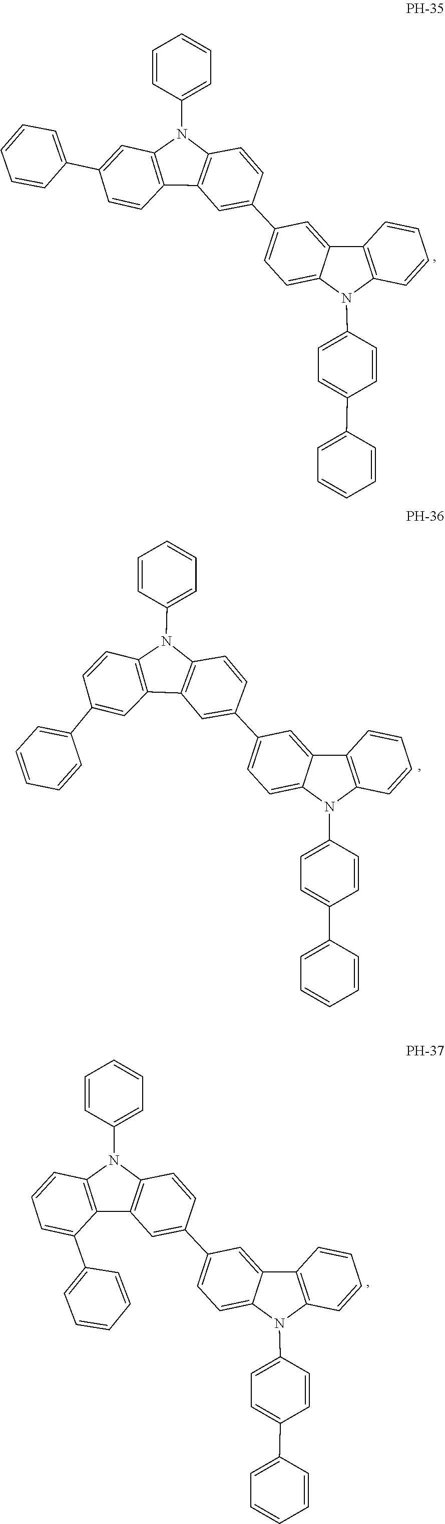 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1]

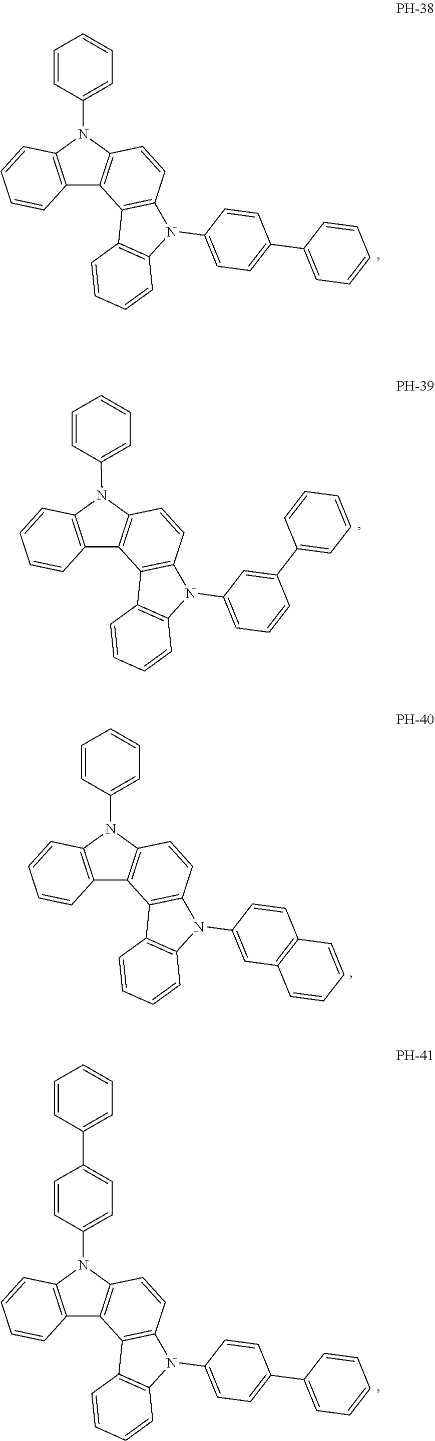 [SMILES: c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1 ; c1ccc(-n2c3ccccc3c3c4c5ccccc5n(-c5ccc6ccccc6c5)c4ccc32)cc1 ; c1ccc(-c2ccc(-n3c4ccccc4c4c5c6ccccc6n(-c6ccc(-c7ccccc7)cc6)c5ccc43)cc2)cc1]

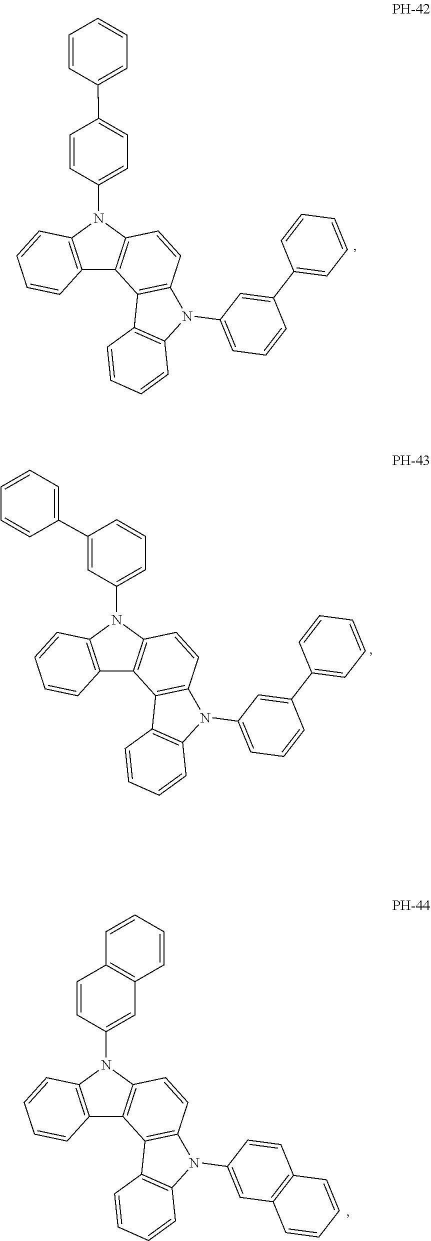 [SMILES: c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1 ; c1ccc2cc(-n3c4ccccc4c4c5c6ccccc6n(-c6ccc7ccccc7c6)c5ccc43)ccc2c1]

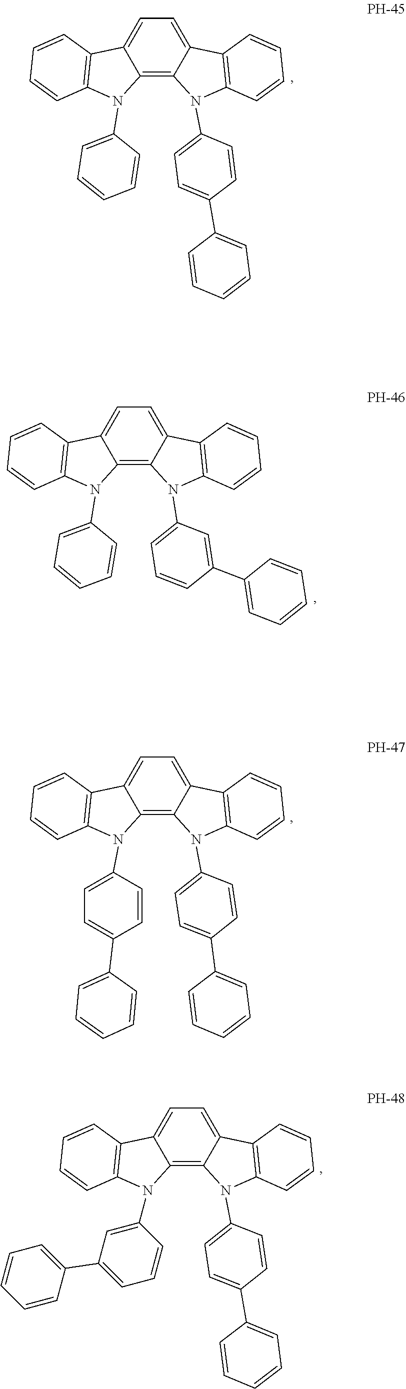 [SMILES: c1ccc(-c2ccc(-n3c4ccccc4c4ccc5c6ccccc6n(-c6ccccc6)c5c43)cc2)cc1 ; c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1]

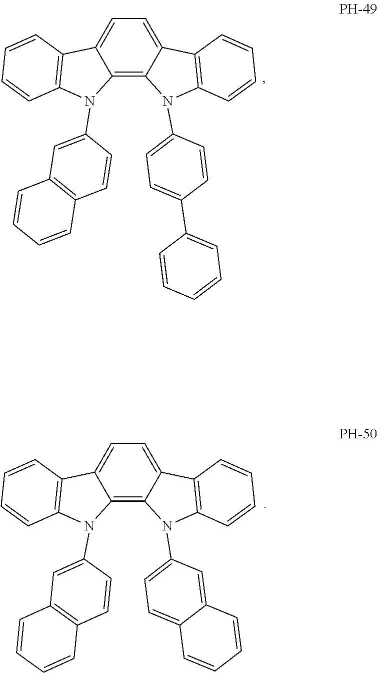 [SMILES: c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1]

According to an embodiment of the present disclosure, the second host compound has a structure represented by Formula 4:

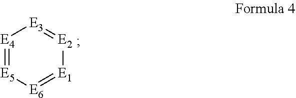

wherein
E₁ to E₆ are, at each occurrence identically or differently, selected from C, CR_{c} or N, at least two of E₁ to E₆ are N, and at least one of E₁ to E₆ is C and joined to Formula A:

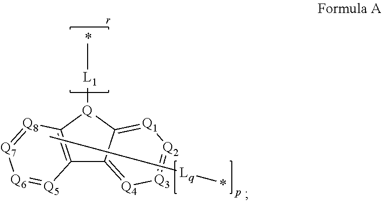

wherein
Q is, at each occurrence identically or differently, selected from the group consisting of O, S, Se, N, NR_{Q}, CR_{Q}R_{Q}, SiR_{Q}R_{Q}, GeR_{Q}R_{Q} and R_{Q}C═CR_{Q}; when two R_{Q} are present at the same time, the two R_{Q} may be identical or different;
p is 0 or 1, and r is 0 or 1;
when Q is selected from N, p is 0, and r is 1;
when Q is selected from the group consisting of O, S, Se, NR_{Q}, CR_{Q}R_{Q}, SiR_{Q}R_{Q}, GER_{Q}R_{Q} and R_{Q}C═CR_{Q}, p is 1, and r is 0;
L_{q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
Q₁ to Q₈ are, at each occurrence identically or differently, selected from C, CR_{q} or N;
Rₑ, R_{Q} and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents the position of attachment of Formula A to Formula 4;
adjacent substituents Rₑ, R_{Q}, R_{q} can be optionally joined to form a ring.

Herein, the expression that “adjacent substituents Rₑ, R_{Q}, R_{q} can be optionally joined to form a ring” is intended to mean that any one or more of groups of adjacent substituents, such as two substituents Rₑ, two substituents R_{Q}, two substituents R_{q}, and two substituents R_{Q} and R_{q}, can be joined to form a ring. Obviously, it is also possible that none of these substituents are joined to form a ring.

According to an embodiment of the present disclosure, the second host compound is selected from the group consisting of the following compounds:

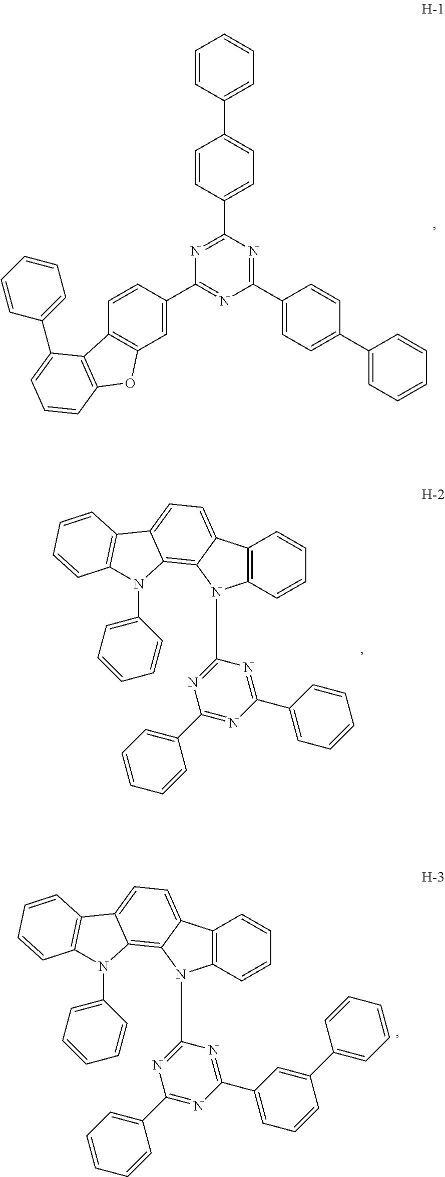 [SMILES: c1ccc(-c2ccc(-c3nc(-c4ccc(-c5ccccc5)cc4)nc(-c4ccc5c(c4)oc4cccc(-c6ccccc6)c45)n3)cc2)cc1 ; c1ccc(-c2nc(-c3ccccc3)nc(-n3c4ccccc4c4ccc5c6ccccc6n(-c6ccccc6)c5c43)n2)cc1 ; c1ccc(-c2cccc(-c3nc(-c4ccccc4)nc(-n4c5ccccc5c5ccc6c7ccccc7n(-c7ccccc7)c6c54)n3)c2)cc1]

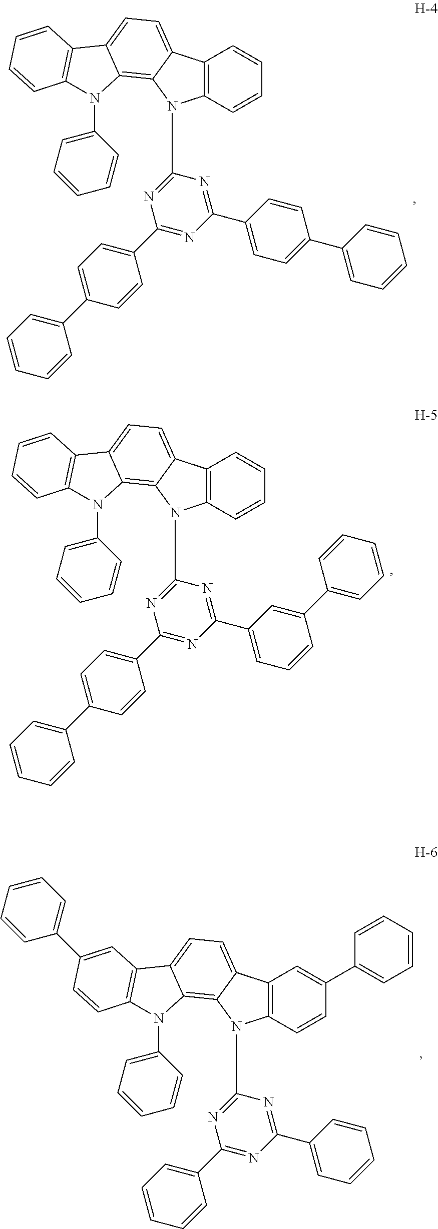 [SMILES: c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1]

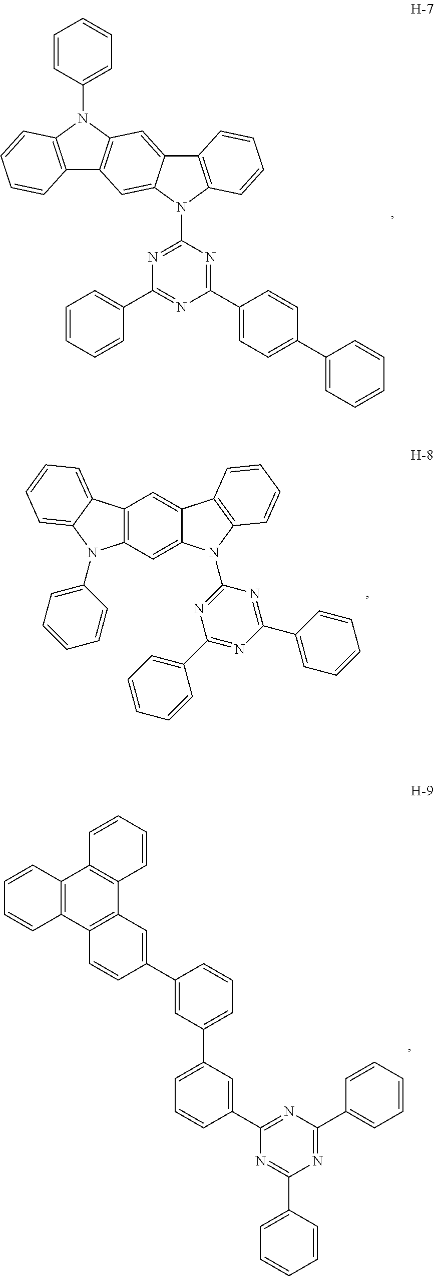 [SMILES: c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-c3cccc(-c4cccc(-c5ccc6c7ccccc7c7ccccc7c6c5)c4)c3)n2)cc1]

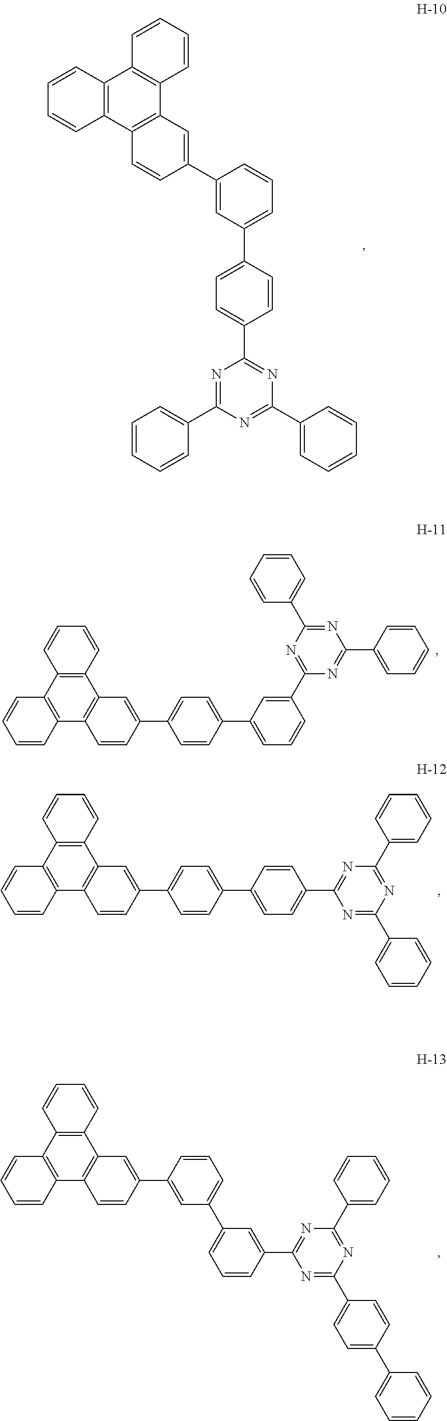 [SMILES: c1ccc(-c2nc(-c3ccccc3)nc(-c3ccc(-c4cccc(-c5ccc6c7ccccc7c7ccccc7c6c5)c4)cc3)n2)cc1 ; c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3ccc(-c4ccc(-c5ccc6c7ccccc7c7ccccc7c6c5)cc4)cc3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1]

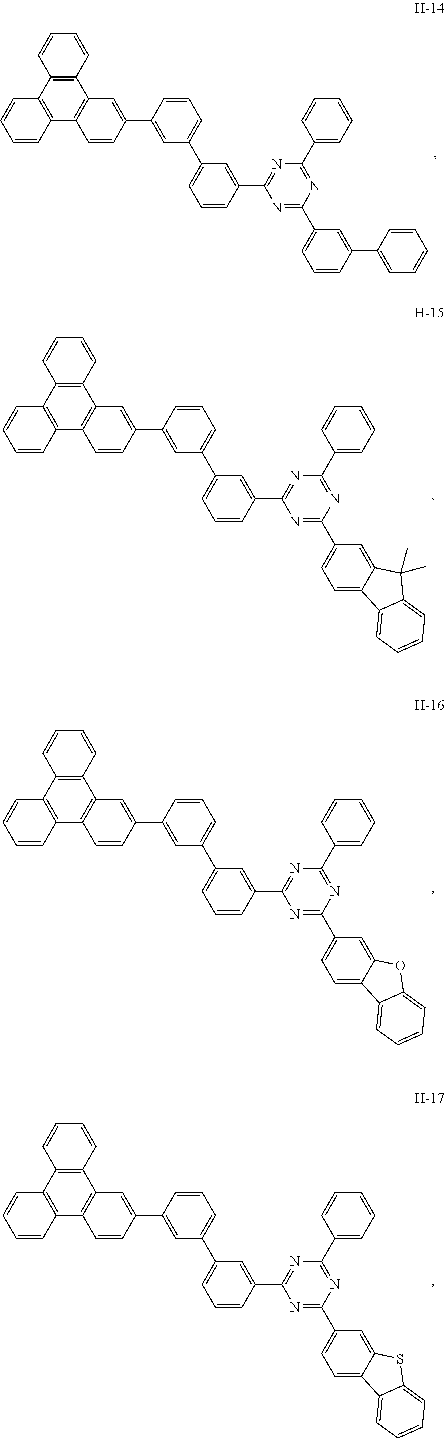 [SMILES: c1ccc(-c2cccc(-c3nc(-c4ccccc4)nc(-c4cccc(-c5cccc(-c6ccc7c8ccccc8c8ccccc8c7c6)c5)c4)n3)c2)cc1 ; CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21 ; c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1]

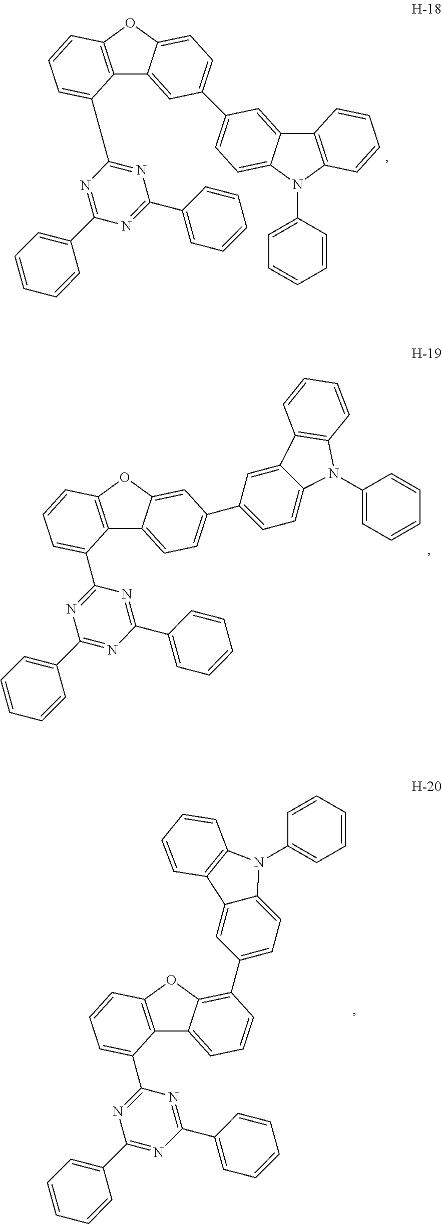 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1]

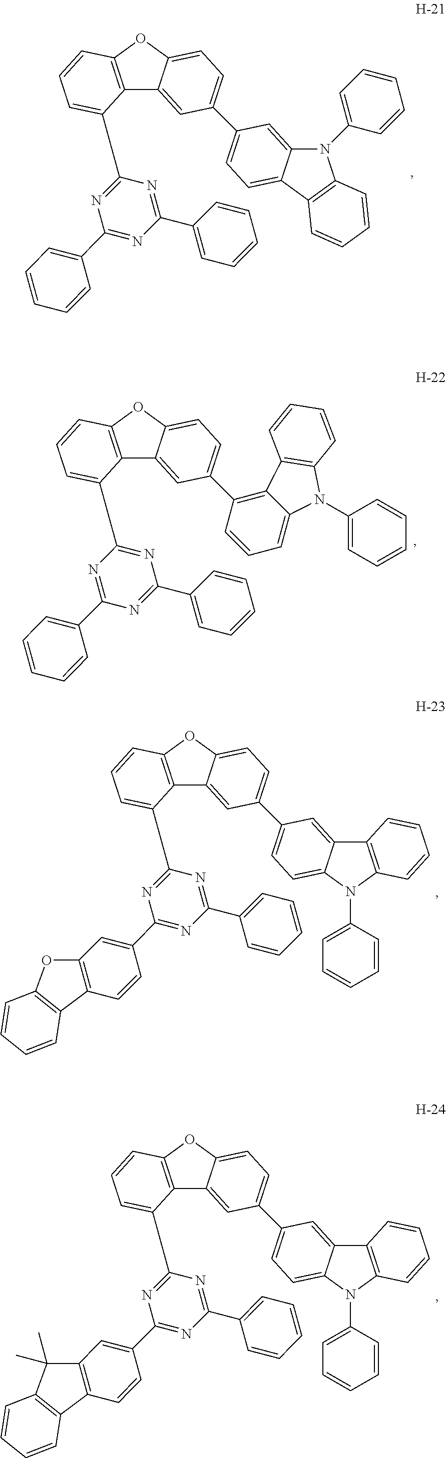 [SMILES: c1ccc(-c2nc(-c3ccccc3)nc(-c3cccc4oc5ccc(-c6ccc7c8ccccc8n(-c8ccccc8)c7c6)cc5c34)n2)cc1 ; c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21]

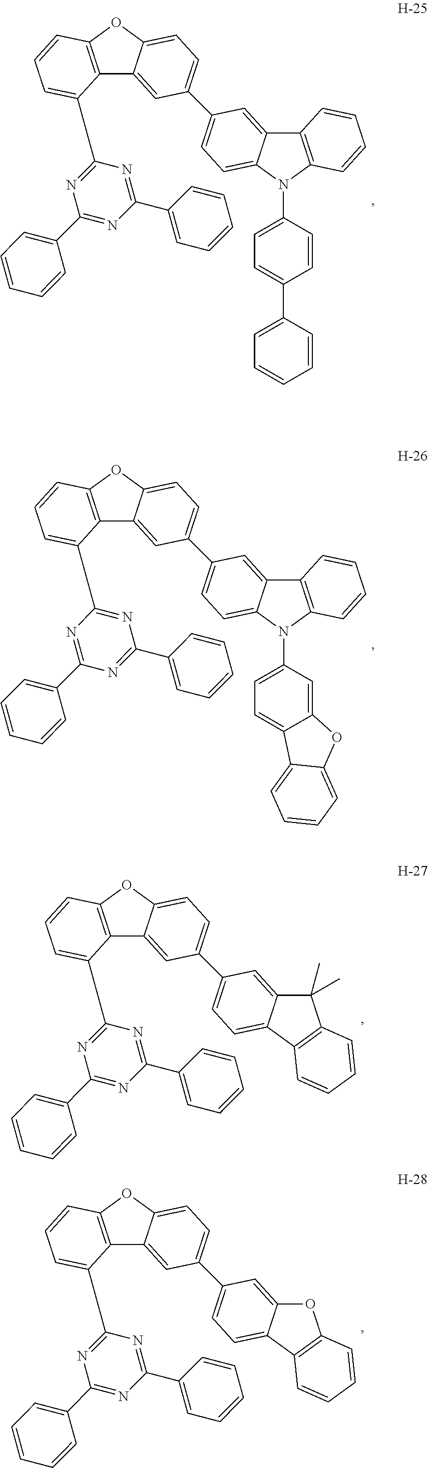 [SMILES: c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1 ; CC1(C)c2ccccc2-c2ccc(-c3ccc4oc5cccc(-c6nc(-c7ccccc7)nc(-c7ccccc7)n6)c5c4c3)cc21 ; c1ccc(-c2nc(-c3ccccc3)nc(-c3cccc4oc5ccc(-c6ccc7c(c6)oc6ccccc67)cc5c34)n2)cc1]

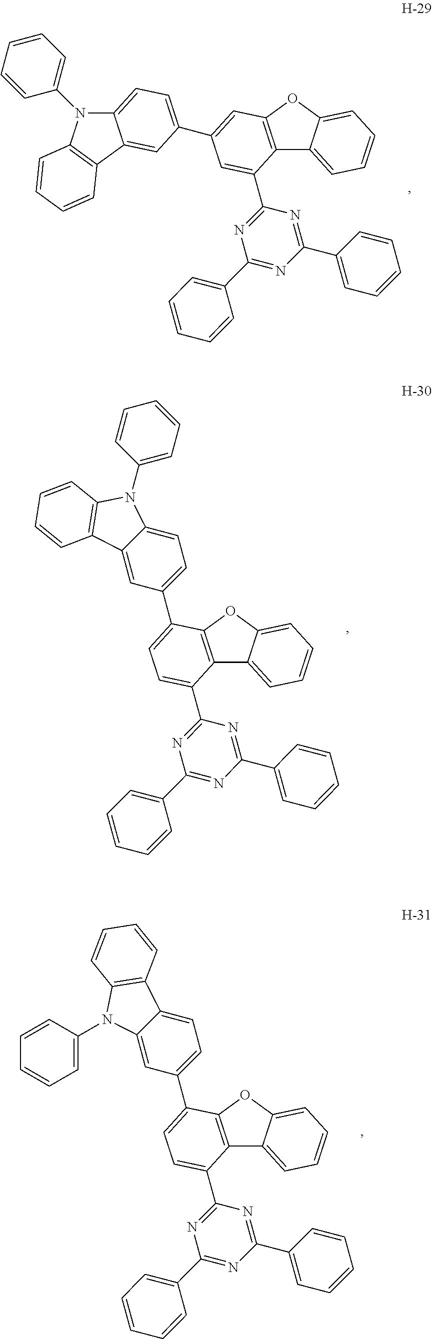 [SMILES: c1ccc(-c2nc(-c3ccccc3)nc(-c3cc(-c4ccc5c(c4)c4ccccc4n5-c4ccccc4)cc4oc5ccccc5c34)n2)cc1 ; c1ccc(-c2nc(-c3ccccc3)nc(-c3ccc(-c4ccc5c(c4)c4ccccc4n5-c4ccccc4)c4oc5ccccc5c34)n2)cc1 ; c1ccc(-c2nc(-c3ccccc3)nc(-c3ccc(-c4ccc5c6ccccc6n(-c6ccccc6)c5c4)c4oc5ccccc5c34)n2)cc1]

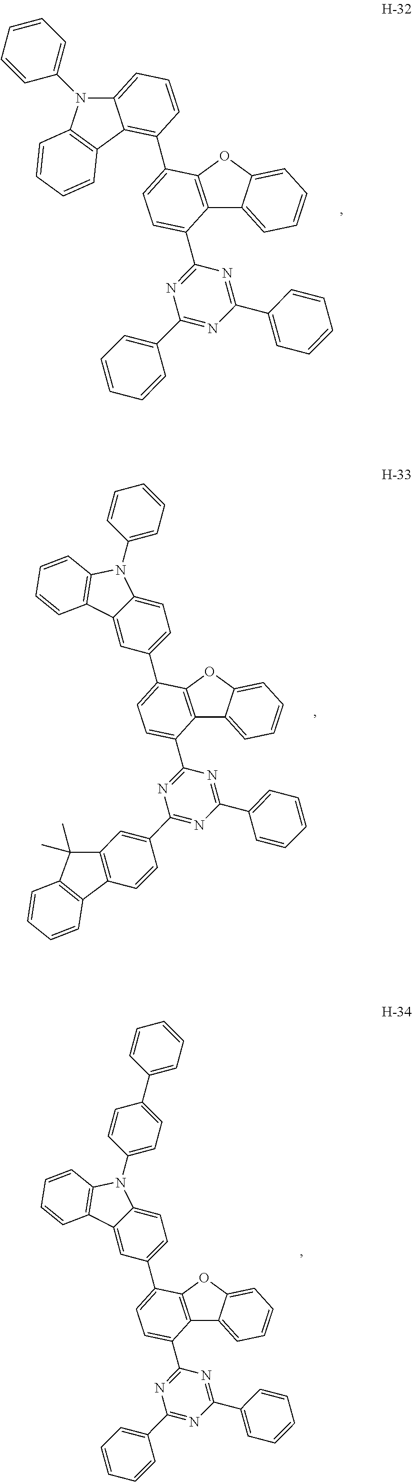 [SMILES: c1ccc(-c2nc(-c3ccccc3)nc(-c3ccc(-c4cccc5c4c4ccccc4n5-c4ccccc4)c4oc5ccccc5c34)n2)cc1 ; CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21 ; c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1]

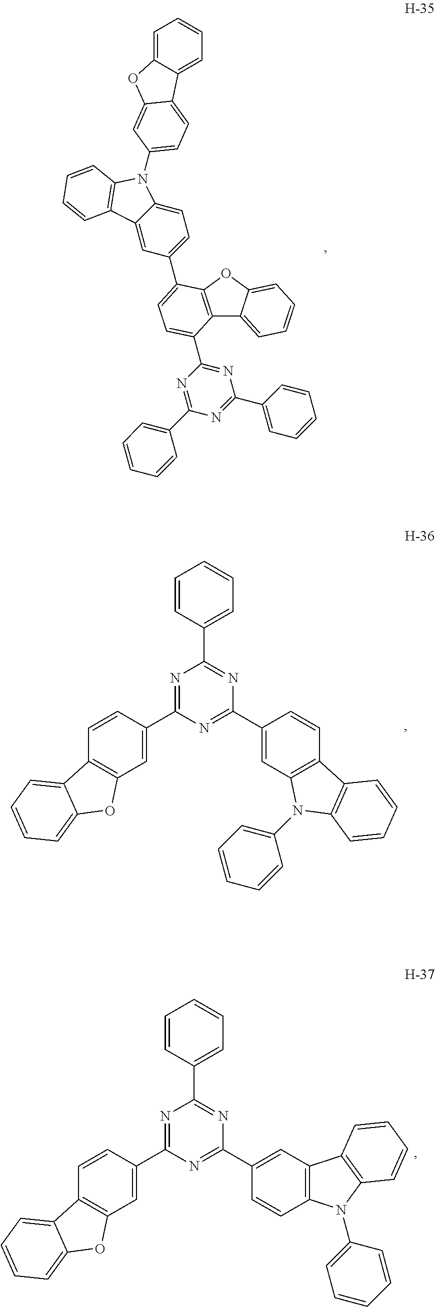 [SMILES: c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1]

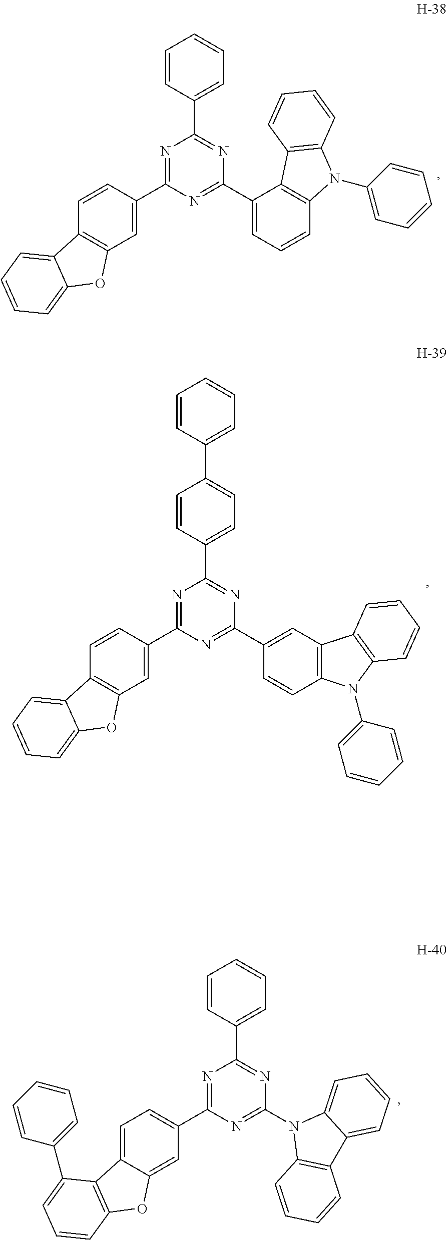 [SMILES: c1ccc(-c2nc(-c3ccc4c(c3)oc3ccccc34)nc(-c3cccc4c3c3ccccc3n4-c3ccccc3)n2)cc1 ; c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)oc3cccc(-c5ccccc5)c34)nc(-n3c4ccccc4c4ccccc43)n2)cc1]

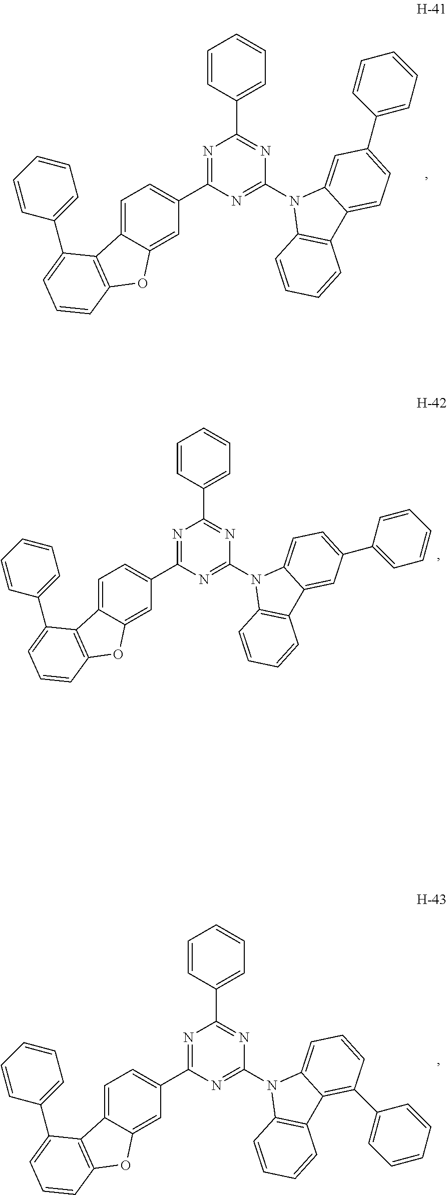 [SMILES: c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1 ; c1ccc(-c2nc(-c3ccc4c(c3)oc3cccc(-c5ccccc5)c34)nc(-n3c4ccccc4c4c(-c5ccccc5)cccc43)n2)cc1]

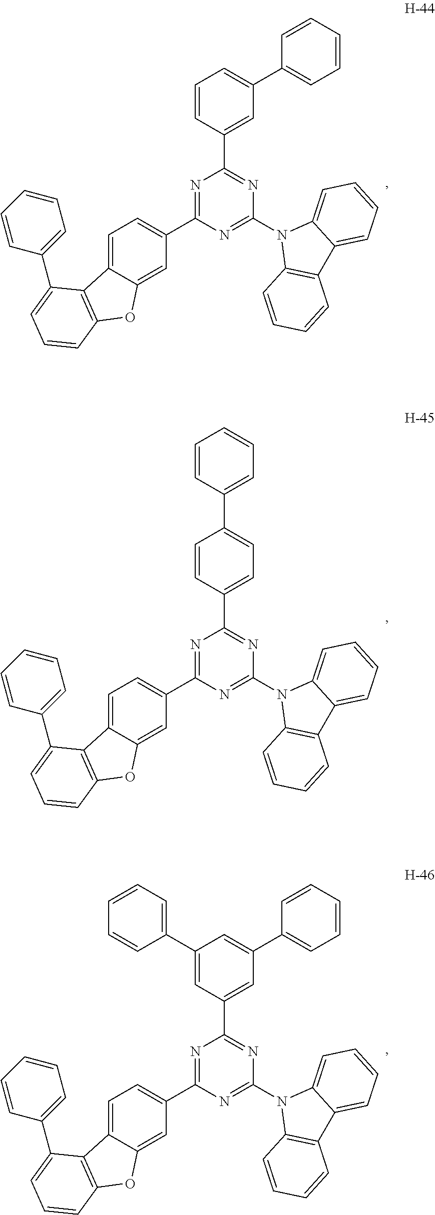 [SMILES: c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1 ; c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1]

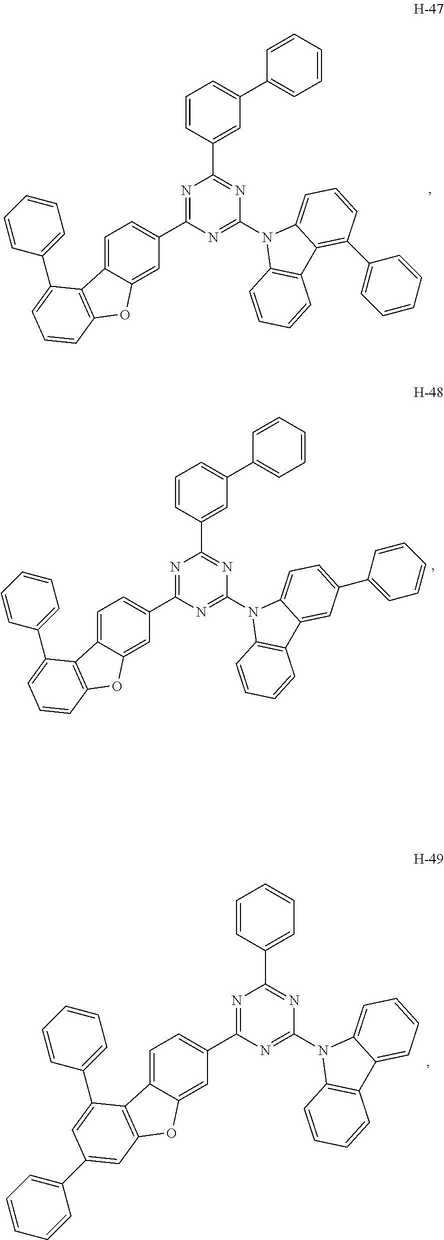 [SMILES: c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1 ; c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1 ; c1ccc(-c2cc(-c3ccccc3)c3c(c2)oc2cc(-c4nc(-c5ccccc5)nc(-n5c6ccccc6c6ccccc65)n4)ccc23)cc1]

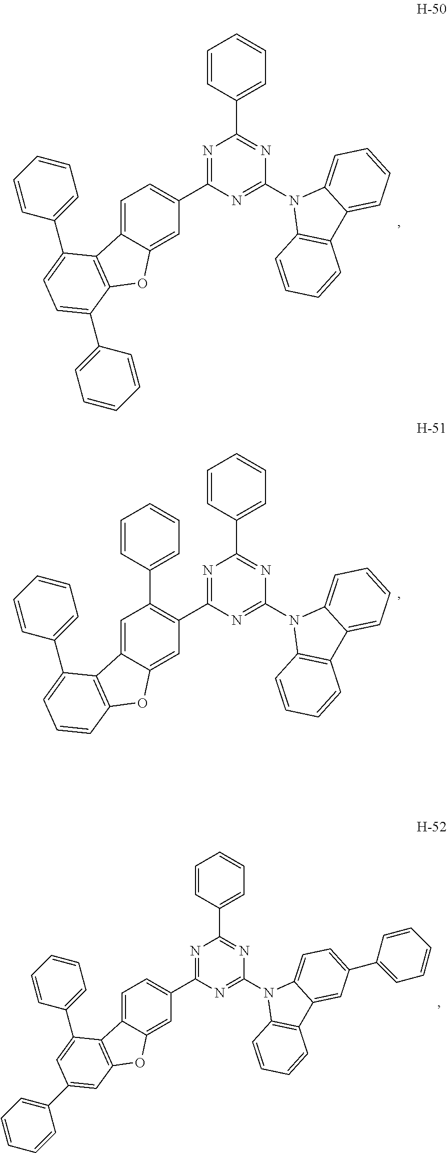 [SMILES: c1ccc(-c2nc(-c3ccc4c(c3)oc3c(-c5ccccc5)ccc(-c5ccccc5)c34)nc(-n3c4ccccc4c4ccccc43)n2)cc1 ; c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1]

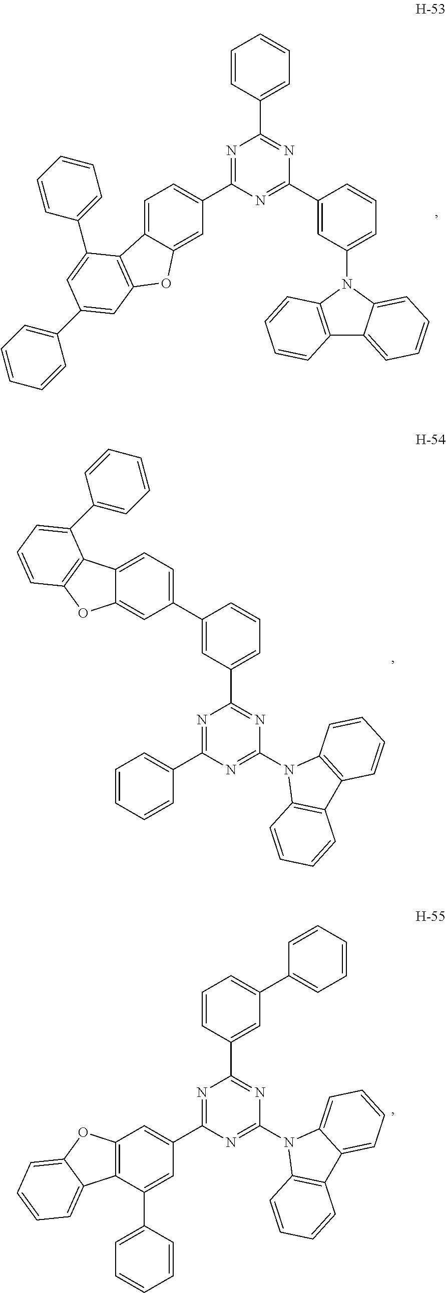 [SMILES: c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1 ; c1ccc(-c2nc(-c3cccc(-c4ccc5c(c4)oc4cccc(-c6ccccc6)c45)c3)nc(-n3c4ccccc4c4ccccc43)n2)cc1 ; c1ccc(-c2cccc(-c3nc(-c4cc(-c5ccccc5)c5c(c4)oc4ccccc45)nc(-n4c5ccccc5c5ccccc54)n3)c2)cc1]

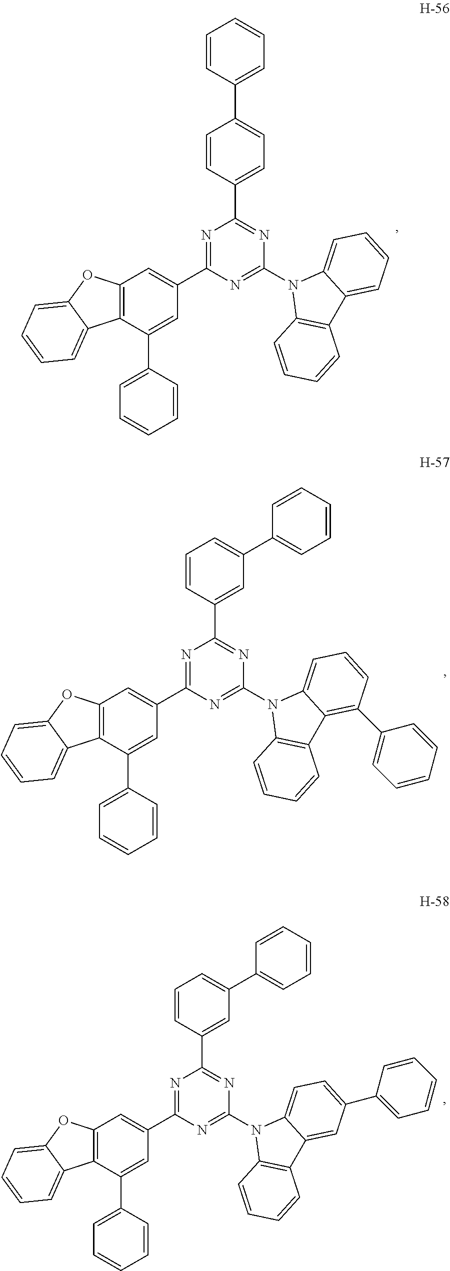 [SMILES: c1ccc(-c2ccc(-c3nc(-c4cc(-c5ccccc5)c5c(c4)oc4ccccc45)nc(-n4c5ccccc5c5ccccc54)n3)cc2)cc1 ; c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1 ; c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1]

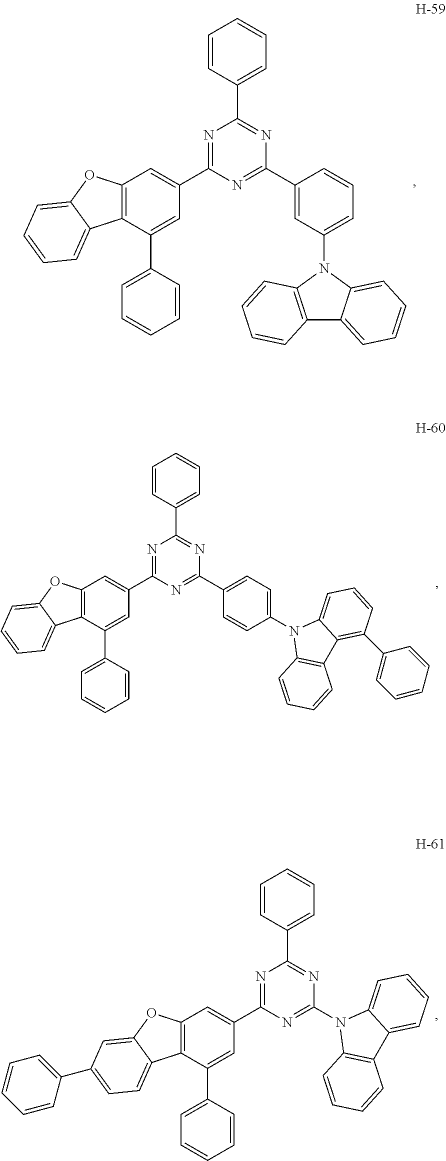 [SMILES: c1ccc(-c2nc(-c3cccc(-n4c5ccccc5c5ccccc54)c3)nc(-c3cc(-c4ccccc4)c4c(c3)oc3ccccc34)n2)cc1 ; c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2ccc3c(c2)oc2cc(-c4nc(-c5ccccc5)nc(-n5c6ccccc6c6ccccc65)n4)cc(-c4ccccc4)c23)cc1]

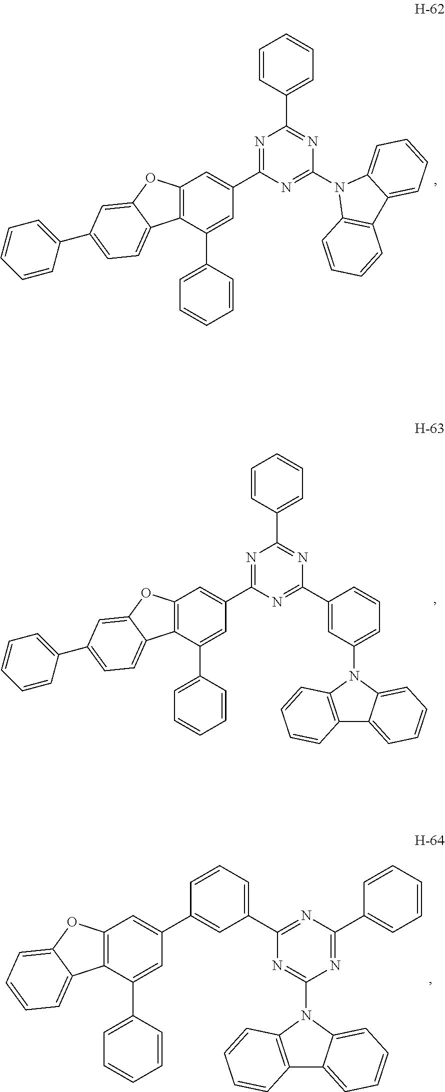 [SMILES: c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1 ; c1ccc(-c2nc(-c3cccc(-c4cc(-c5ccccc5)c5c(c4)oc4ccccc45)c3)nc(-n3c4ccccc4c4ccccc43)n2)cc1]

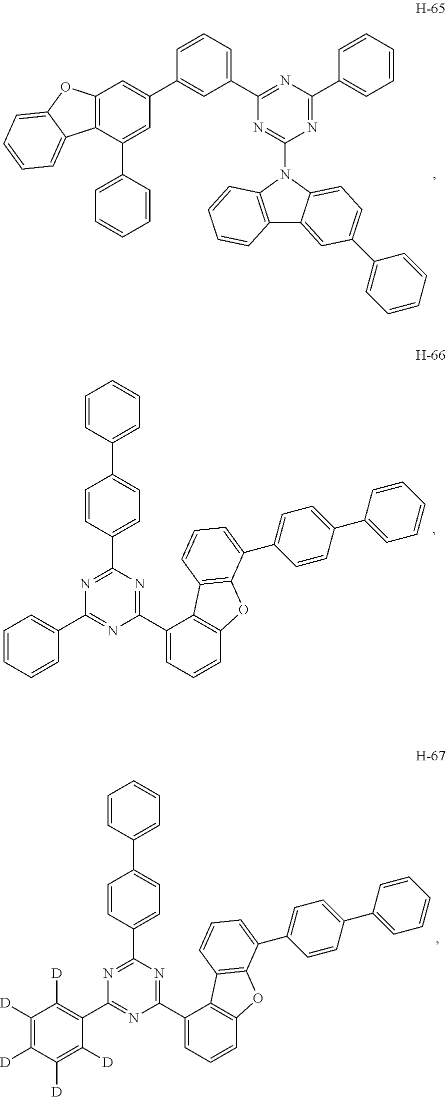 [SMILES: c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1 ; c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H]]

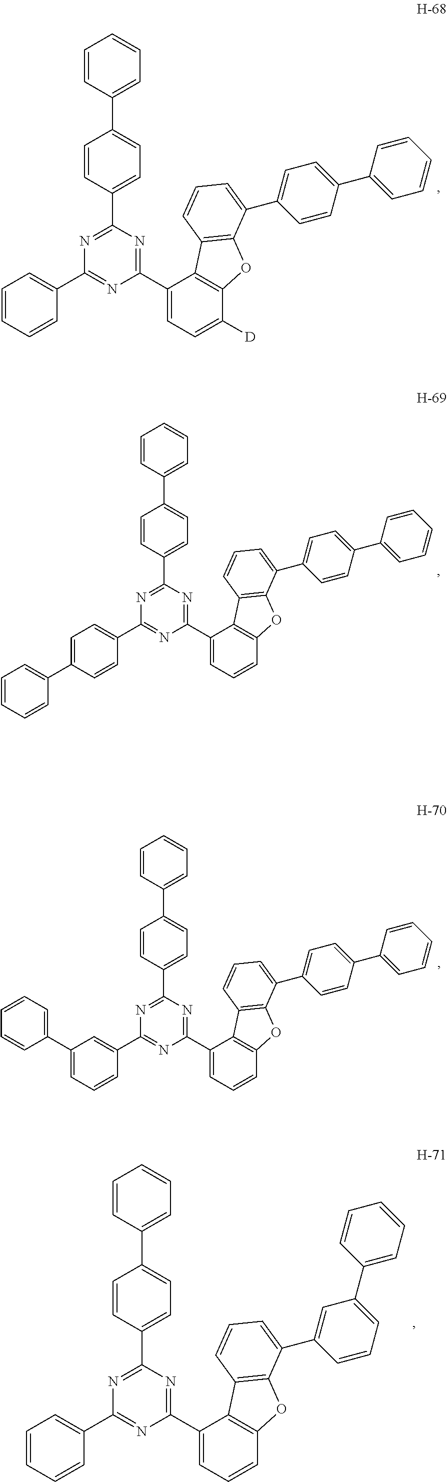 [SMILES: [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1]

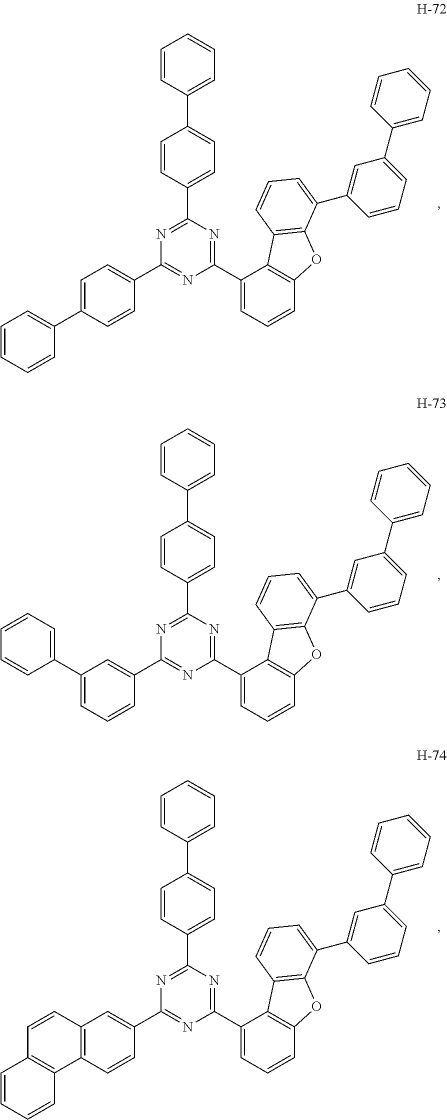 [SMILES: c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1]

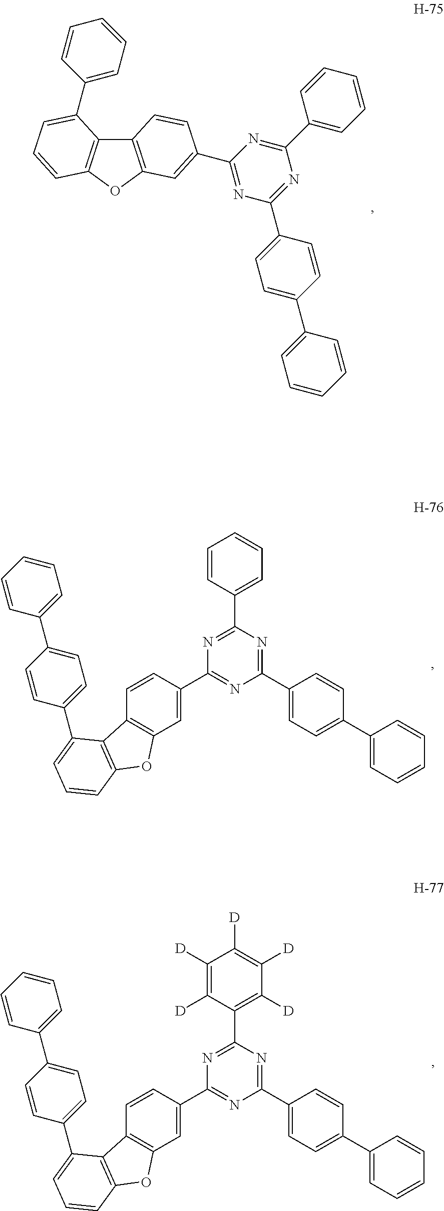 [SMILES: c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H]]

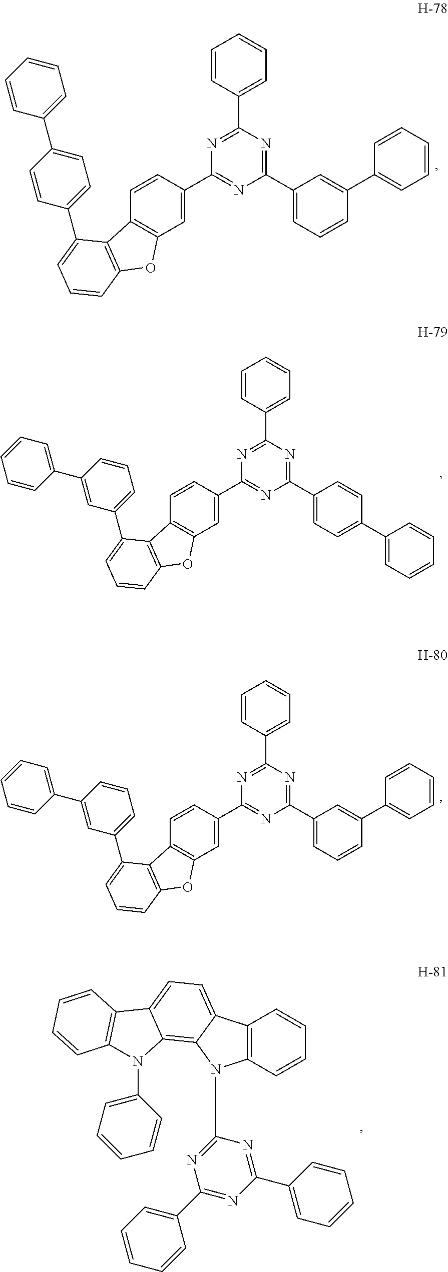 [SMILES: c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2nc(-c3ccccc3)nc(-n3c4ccccc4c4ccc5c6ccccc6n(-c6ccccc6)c5c43)n2)cc1]

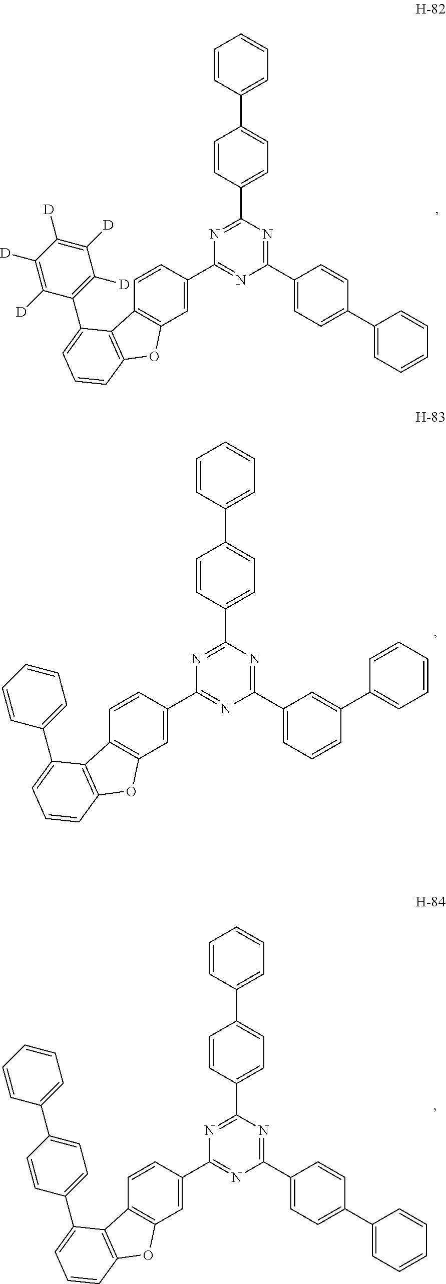 [SMILES: [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1]

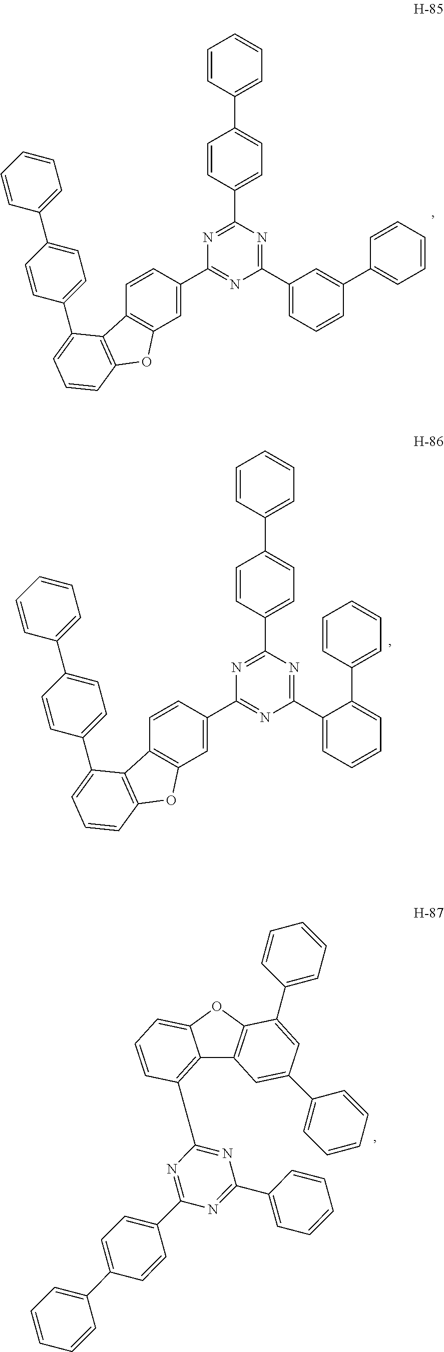 [SMILES: c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccccc4)nc(-c4cccc5oc6c(-c7ccccc7)cc(-c7ccccc7)cc6c45)n3)cc2)cc1]

According to an embodiment of the present disclosure, the metal complex is doped in the first host compound and the second host compound, and the weight of the metal complex accounts for 1% to 30% of the total weight of the emissive layer.

According to an embodiment of the present disclosure, the metal complex is doped in the first host compound and the second host compound, and the weight of the metal complex accounts for 3% to 13% of the total weight of the emissive layer.

According to an embodiment of the present disclosure, the organic electroluminescent device further includes a hole injection layer. The hole injection layer may be a functional layer containing a single material or a functional layer containing a variety of materials, wherein the most commonly used ones among the variety of materials contained are hole transport materials doped with a certain proportion of p-type conductive doped material. The common p-type doped materials are as follows:

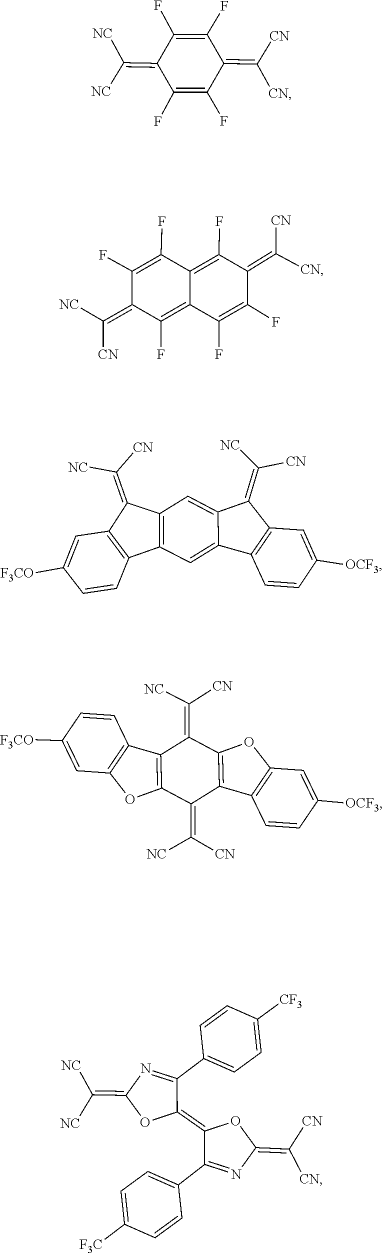 [SMILES: N#CC(C#N)=c1c(F)c(F)c(=C(C#N)C#N)c(F)c1F ; N#CC(C#N)=c1c(F)c(F)c2c(F)c(=C(C#N)C#N)c(F)c(F)c2c1F ; N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=c1c2oc3cc(OC(F)(F)F)ccc3c2c(=C(C#N)C#N)c2oc3cc(OC(F)(F)F)ccc3c12 ; N#CC(C#N)=c1nc(-c2ccc(C(F)(F)F)cc2)/c(=c2\oc(=C(C#N)C#N)nc2-c2ccc(C(F)(F)F)cc2)o1]

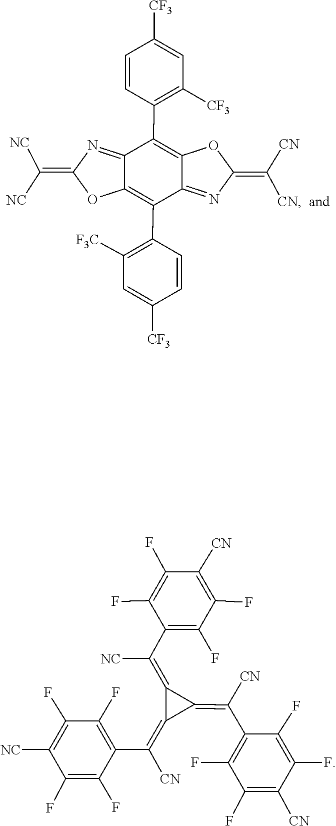

According to an embodiment of the present disclosure, a compound composition is further disclosed. The compound composition includes the metal complex described in any of the aforementioned embodiments.

Combination with Other Materials

The materials described in the present disclosure for a particular layer in an organic light-emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to in the present disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. Pub. No. 20150349273, which is incorporated by reference herein in its entirety. The materials described or referred to in the present disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### MATERIAL SYNTHESIS EXAMPLE

### Synthesis Example 1: Synthesis of Metal Complex 61

### Step 1: Synthesis of Intermediate 1

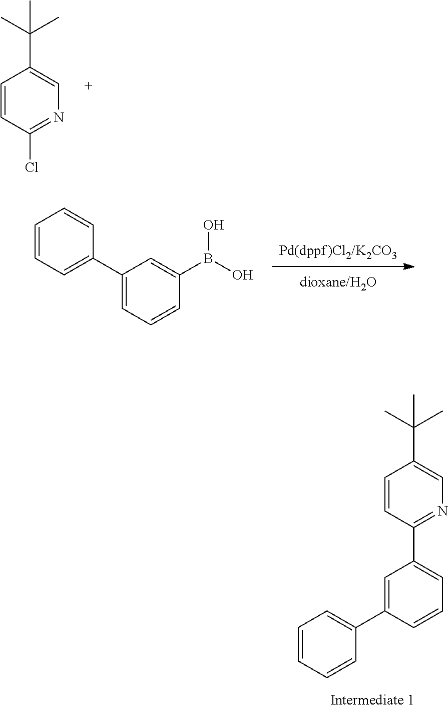 [SMILES: CC(C)(C)c1ccc(Cl)nc1 ; OB(O)c1cccc(-c2ccccc2)c1 ; CC(C)(C)c1ccc(-c2cccc(-c3ccccc3)c2)nc1]

Under the protection of nitrogen, 2-chloro-5-tert-butyl-pyridine (10.0 g, 58.8 mmol), 3-biphenylboronic acid (14.0 g, 70.6 mmol), Pd(dppf)Cl₂ (2.1 g, 2.9 mmol), potassium carbonate (16.0 g, 117.6 mmol) and dioxane/water (3/1, 120 mL) were added in sequence in a dry 250 mL round-bottom flask and reacted at 110° C. overnight. After the reaction was completed, the reaction mixture was extracted with ethyl acetate and purified by column chromatography to give Intermediate 1 (12.0 g, 41.8 mmol, with a yield of 71%) as a white solid.

### Step 2: Synthesis of Intermediate 2

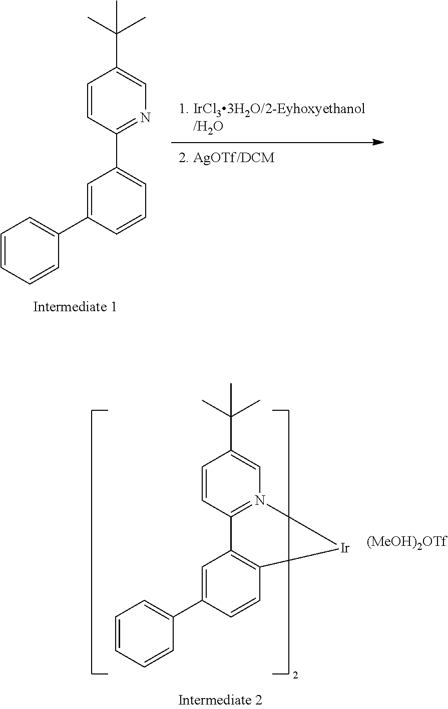

Under the protection of nitrogen, Intermediate 1 (12.0 g, 41.8 mmol), iridium trichloride trihydrate (5.9 g, 16.7 mmol), 2-Eyhoxyethanol (90 mL) and water (20 mL) were added in sequence in a dry 250 mL round-bottom flask and reacted at 110° C. for 24 hours. The reaction mixture was filtered to collect a solid. The solid was dried and dissolved with dichloromethane (DCM, 100 mL), silver trifluoromethanesulfonate (AgOTf, 4.7 g, 18.4 mmol) and methanol (10 mL) were added, and the resulting mixture was stirred at room temperature overnight. After the reaction was completed, the reaction mixture was filtered to obtain a filtrate. The filtrate was concentrated under reduced pressure to give Intermediate 2 (11.4 g, 11.6 mmol, with a yield of 69%) as a yellow solid.

### Step 3: Synthesis of Metal Complex 61

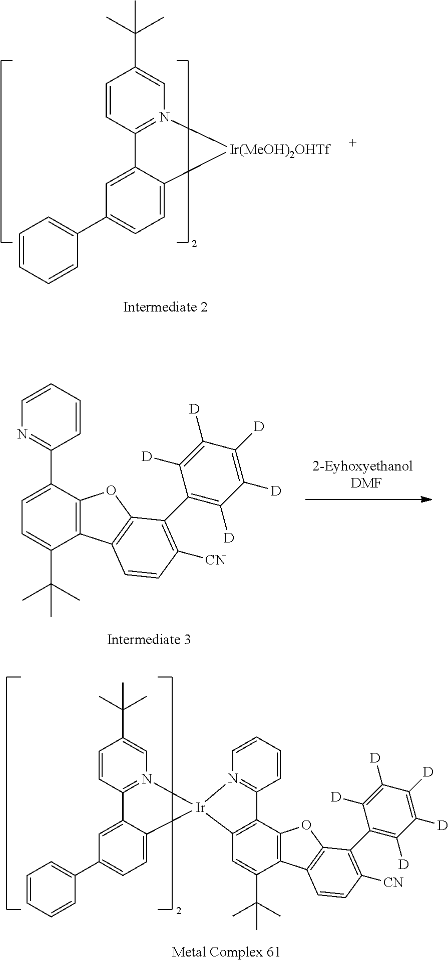

Intermediate 2 (1.4 g, 1.4 mmol), Intermediate 3 (0.7 g, 1.7 mmol), 2-Eyhoxyethanol (30 mL) and DMF (30 mL) were added in sequence in a dry 250 mL round-bottom flask and heated to react at 100° C. for 5 days under the protection of N₂. After the reaction was cooled, the reaction mixture was concentrated under reduced pressure and purified by column chromatography to give Metal Complex 61 (0.8 g, 0.7 mmol, with a yield of 49%) as a yellow solid. The resulting product was confirmed as the target product with a molecular weight of 1171.5.

### Synthesis Example 2: Synthesis of Metal Complex 62

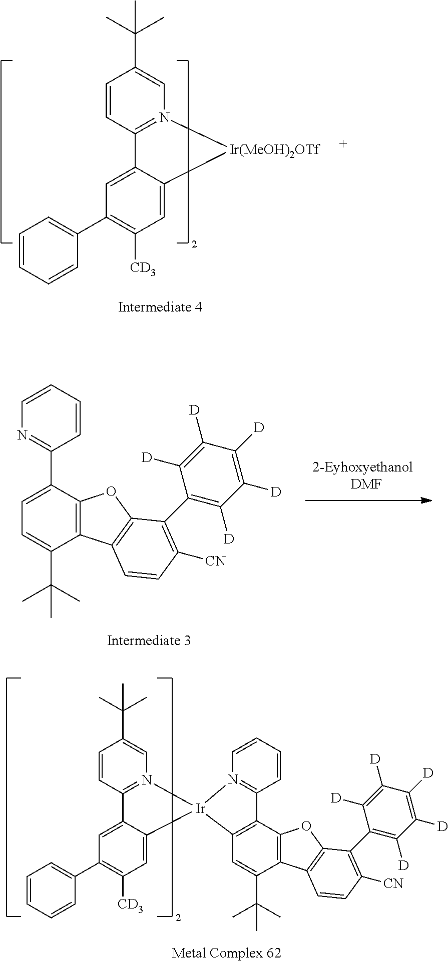

Intermediate 4 (1.4 g, 1.4 mmol), Intermediate 3 (0.7 g, 1.7 mmol), 2-Eyhoxyethanol (30 mL) and DMF (30 mL) were added in sequence in a dry 250 mL round-bottom flask and heated to react at 100° C. for 5 days under the protection of N₂. After the reaction was cooled, the reaction mixture was concentrated under reduced pressure and purified by column chromatography to give Metal Complex 62 (0.7 g, 0.6 mmol, with a yield of 44%) as a yellow solid. The resulting product was confirmed as the target product with a molecular weight of 1205.5.

### Synthesis Example 3: Synthesis of Metal Complex 592

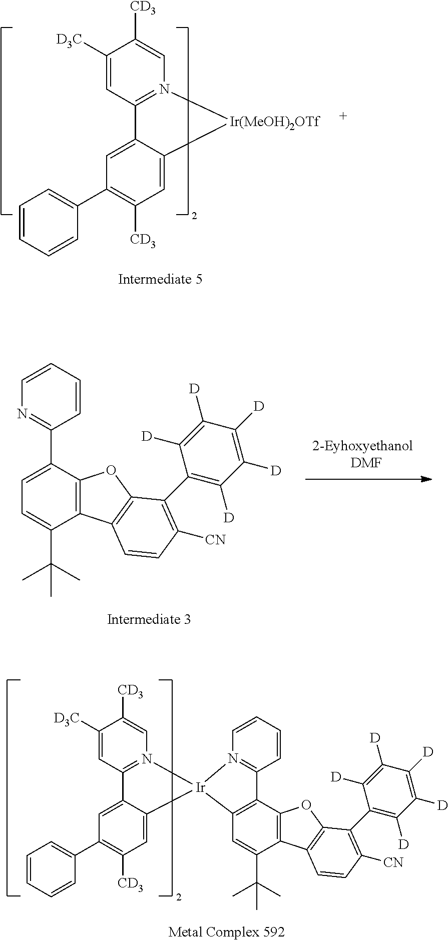

Intermediate 5 (1.7 g, 1.7 mmol), Intermediate 3 (1.0 g, 2.4 mmol), 2-Eyhoxyethanol (30 mL) and DMF (30 mL) were added in sequence in a dry 250 mL round-bottom flask and heated to react at 100° C. for 5 days under the protection of N₂. After the reaction was cooled, the reaction mixture was concentrated under reduced pressure and purified by column chromatography to give Metal Complex 592 (0.9 g, 0.8 mmol, with a yield of 45%) as a yellow solid. The resulting product was confirmed as the target product with a molecular weight of 1161.6.

### Synthesis Example 4: Synthesis of Metal Complex 1598

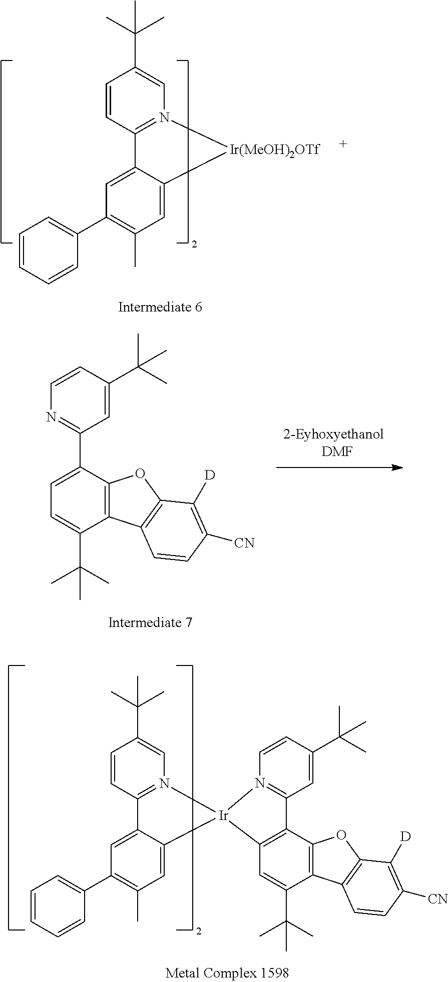

Intermediate 6 (2.6 g, 2.6 mmol), Intermediate 7 (1.4 g, 3.7 mmol), 2-Eyhoxyethanol (40 mL) and DMF (40 mL) were added in sequence in a dry 250 mL round-bottom flask and heated to react at 100° C. for 5 days under the protection of N₂. After the reaction was cooled, the reaction mixture was concentrated under reduced pressure and purified by column chromatography to give Metal Complex 1598 (1.2 g, 1.0 mmol, with a yield of 38%) as a yellow solid. The resulting product was confirmed as the target product with a molecular weight of 1175.52.

Those skilled in the art will appreciate that the above preparation methods are merely exemplary. Those skilled in the art can obtain other compound structures of the present disclosure via modifications of the preparation methods.

### Device Example 1

First, a glass substrate having an indium tin oxide (ITO) anode (whose sheet resistance was 14 to 20 Ω/sq and emission area was 0.04 cm²) with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second at a vacuum degree of about 10⁻⁸ torr. Compound PD was doped in Compound HT, and the resulting mixture was deposited as a hole injection layer (HIL). Compound HT was deposited as a hole transport layer (HTL). Compound PH-1 was deposited as an electron blocking layer (EBL). Metal Complex 61 of the present disclosure was doped in Compound PH-1 and Compound H-40, and the resulting mixture was co-deposited as an emissive layer (EML). On the EML, Compound H-2 was deposited as a hole blocking layer (HBL). On the HBL, Compound ET and 8-hydroxyquinolinolato-lithium (Liq) were co-deposited as an electron transport layer (ETL). Finally, 8-hydroxyquinolinolato-lithium (Liq) with a thickness of 1 nm was deposited as an electron injection layer, and Al with a thickness of 120 nm was deposited as a cathode. The device was transferred back to the glovebox and encapsulated with a glass lid and a moisture absorbent to complete the device.

### Device Example 2

The implementation mode in Device Example 2 was the same as the implementation mode in Device Example 1, except that, in the emissive layer (EML), Metal Complex 61 was replaced with Metal Complex 62 of the present disclosure.

### Device Example 3

The implementation mode in Device Example 3 was the same as the implementation mode in Device Example 1, except that in the emissive layer (EML), Metal Complex 61 was replaced with Metal Complex 592 of the present disclosure and the ratio of Compound PH-1: Compound H-40: Metal Complex 592 was 56:38:6.

### Device Example 4

The implementation mode in Device Example 4 was the same as the implementation mode in Device Example 1, except that, in the emissive layer (EML), Metal Complex 61 was replaced with Metal Complex 1598 of the present disclosure.

### Device Comparative Example 1

The implementation mode in Device Comparative Example 1 was the same as the implementation mode in Device Example 1, except that in the emissive layer (EML), Metal Complex 61 was replaced with GD1.

Detailed structures and thicknesses of layers of the devices are shown in the following table. A layer using more than one material was obtained by doping different compounds at their mass ratio as recorded.

TABLE 1
Device structures in Examples 1 to 4 and Comparative Example 1

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT | PH-1 | PH-1:Compound | H-2 | ET:Liq |
| | PD (97:3) | (350 Å) | (50 Å) | H-40:Metal | (50 Å) | (40:60) |
| | (100 Å) | | | Complex 61 | | (350 Å) |
| | | | | (47:47:6) (400 Å) | | |
| Example 2 | Compound | Compound | Compound | Compound | Compound | Compound |
| | HT:Compound | HT | PH-1 | PH-1:Compound | H-2 | ET:Liq |
| | PD(97:3) | (350 Å) | (50 Å) | H-40:Metal | (50 Å) | (40:60) |
| | (100 Å) | | | Complex 62 | | (350 Å) |
| | | | | (47:47:6) (400 Å) | | |
| Example 3 | Compound | Compound | Compound | Compound | Compound | Compound |
| | HT:Compound | HT | PH-1 | PH-1:Compound | H-2 | ET:Liq |
| | PD (97:3) | (350 Å) | (50 Å) | H-40:Metal | (50 Å) | (40:60) |
| | (100 Å) | | | Complex 592 | | (350 Å) |
| | | | | (56:38:6) (400 Å) | | |
| Example 4 | Compound | Compound | Compound | Compound | Compound | Compound |
| | HT:Compound | HT | PH-1 | PH-1:Compound | H-2 | ET:Liq |
| | PD (97:3) | (350 Å) | (50 Å) | H-40:Metal | (50 Å) | (40:60) |
| | (100 Å) | | | Complex 1598 | | (350 Å) |
| | | | | (47:47:6) (400 Å) | | |
| Comparative | Compound | Compound | Compound | Compound | Compound | Compound |
| Example 1 | HT:Compound | HT | PH-1 | PH-1:Compound | H-2 | ET:Liq |
| | PD(97:3) | (350 Å) | (50 Å) | H-40:Metal | (50 Å) | (40:60) |
| | (100 Å) | | | Complex GD1 | | (350 Å) |
| | | | | (47:47:6) (400 Å) | | |

The structures of the materials used in the devices are as follows:

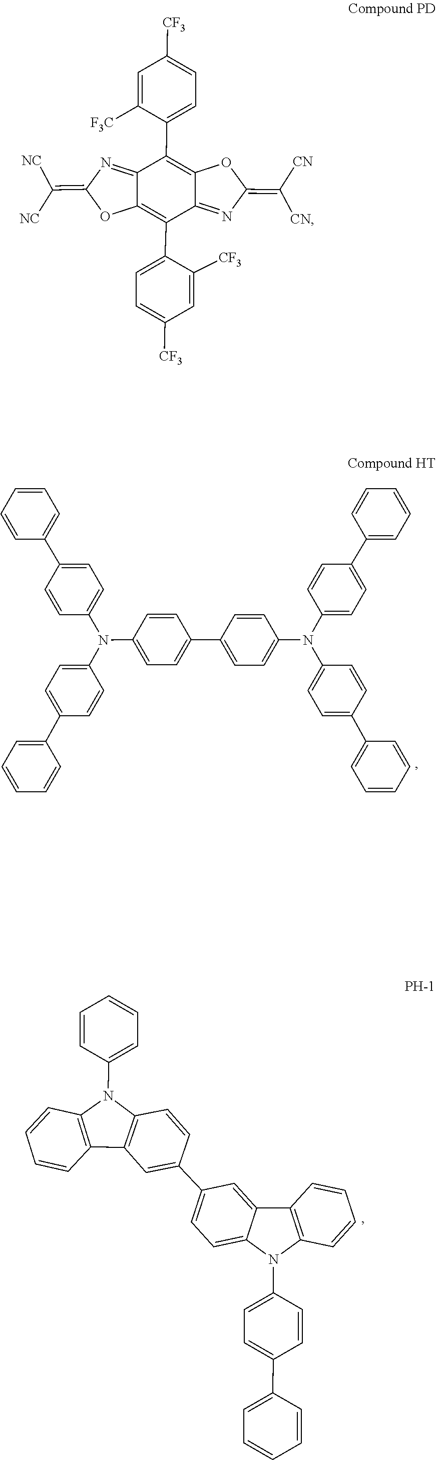 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccccc5)ccc43)cc2)cc1]

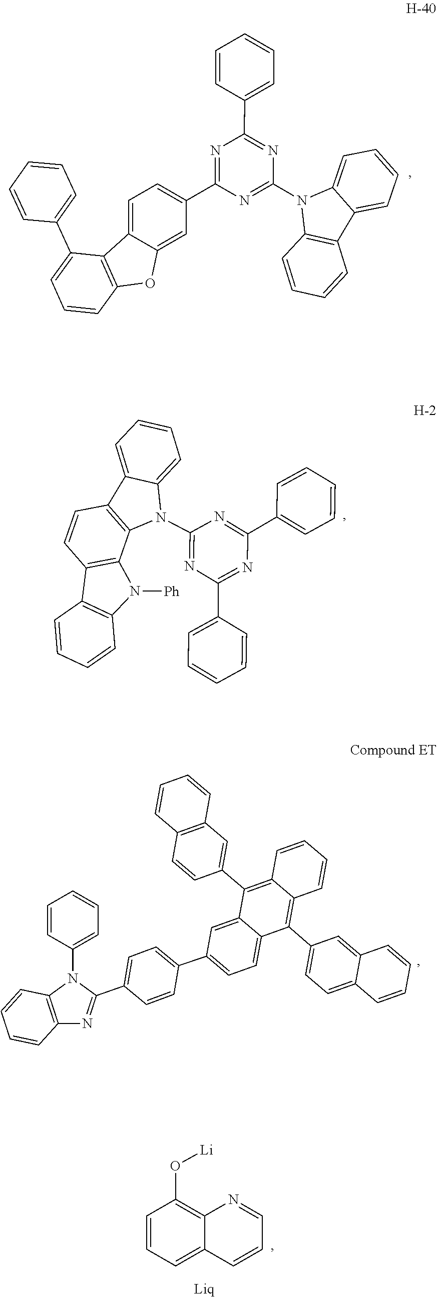

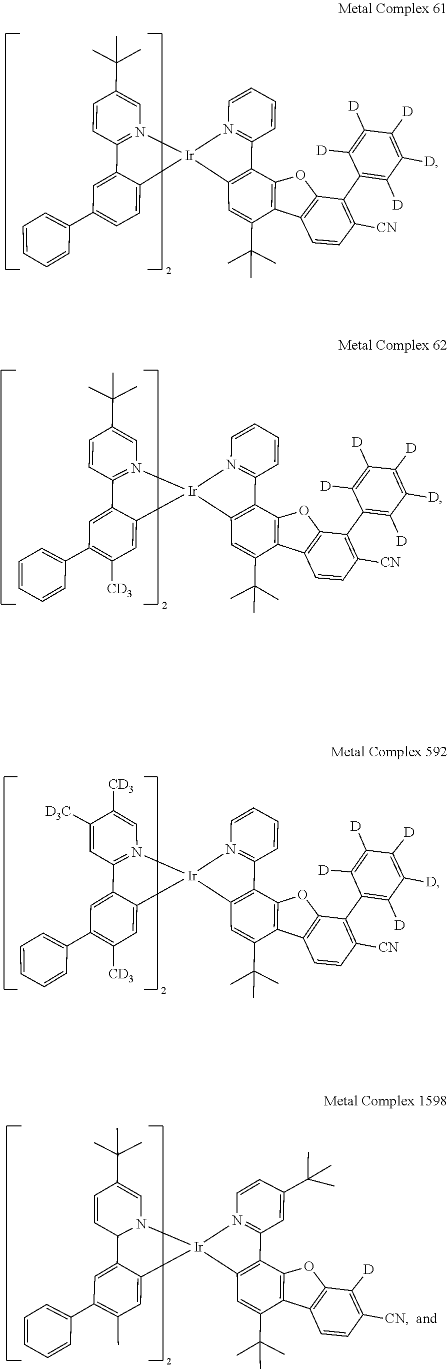

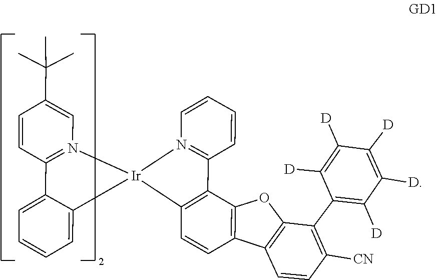

The IVL properties of the devices were measured. The CIE data, maximum emission wavelength (λₘₐₓ), full width at half maximum (FWHM) and external quantum efficiency (EQE) of each device were measured at 10 mA/cm². The data are recorded and shown in Table 2.

TABLE 2
Device data of Examples 1 to 4 and Comparative Example 1

| Device ID | CIE (x, y) | λₘₐₓ (nm) | FWHM (nm) | EQE (%) |
|---|---|---|---|---|
| Example1 | (0.288, 0.664) | 521 | 31.0 | 25.38 |
| Example 2 | (0.299, 0.659) | 523 | 30.8 | 25.78 |
| Example 3 | (0.312, 0.652) | 525 | 33.7 | 25.26 |
| Example 4 | (0.283, 0.661) | 518 | 31.7 | 24.60 |
| Comparative | (0.343, 0.634) | 531 | 35.5 | 23.39 |
| Example 1 | | | | |

As can be seen from the data in Table 2, the difference between Example 1 and Comparative Example 1 only lies in the Ar substituent in the ligand L_{b} and the Rₙ substituent in the ligand Lₐ in the metal complex. In comparison to the device in Comparative Example 1, the maximum emission wavelength of the device in Example 1 was blue-shifted by 10 nm, and the full width at half maximum was narrowed by 4.5 nm, which indicates that the device in Example 1 can obtain more saturated green light. In addition, the EQE of the device in Example 1 was improved by 8.5%, thereby achieving better device performance. On the basis of Example 1, Example 2 and Example 3 involved different substituents in the ligand L_{b}, and the device performance of Example 2 and Example 3 was similar to the device performance of Example 1 and significantly better than the device performance of Comparative Example 1. Example 4 involved different substituents in the ligand Lₐ, and its device performance was also better than that of Comparative Example 1.

As indicated in the above results, the metal complex of the present disclosure including a ligand Lₐ having a structure of Formula 1 and a ligand L_{b} having a structure of Formula 2 can obtain more saturated green light and better device efficiency. The metal complex of the present disclosure can help improve the comprehensive performance of the device and has great advantages and broad prospects in industrial applications.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex having a general structure of M(Lₐ)ₘ(L_{b})ₙ(L_{c})_{q};
wherein the metal M is selected from a metal with a relative atomic mass greater than 40;
m is selected from 1 or 2, n is selected from 1 or 2, q is selected from 0 or 1, and m+n+q equals the oxidation state of the metal M; when m is 2, two Lₐ are identical or different; when n is 2, two L_{b} are identical or different;
L_{c} is selected from a monoanionic bidentate ligand;
Lₐ has a structure represented by Formula 1, and L_{b} has a structure represented by Formula 2: 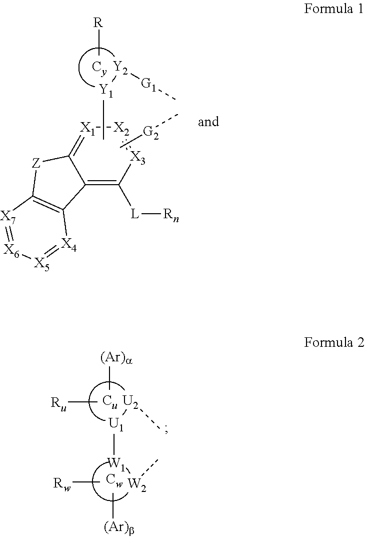
wherein
C_{y} is, at each occurrence identically or differently, selected from an aromatic ring comprising Y₁ and Y₂ and having 6 to 24 ring atoms, a heteroaromatic ring comprising Y₁ and Y₂ and having 5 to 24 ring atoms, or a combination thereof;
Cᵤ is, at each occurrence identically or differently, selected from an aromatic ring comprising U₁ and U₂ and having 6 to 24 ring atoms, a heteroaromatic ring comprising U₁ and U₂ and having 5 to 24 ring atoms, or a combination thereof;
C_{w} is, at each occurrence identically or differently, selected from an aromatic ring comprising W₁ and W₂ and having 6 to 24 ring atoms, a heteroaromatic ring comprising W₁ and W₂ and having 5 to 24 ring atoms, or a combination thereof;
G₁ and G₂ are, at each occurrence identically or differently, selected from a single bond, O or S;
X₁ to X₃ are, at each occurrence identically or differently, selected from C, CRₓ or N; one of X₁ to X₃ is selected from C and joined to Y₁;
when G₂ is selected from a single bond and X₁, X₂ or X₃ is selected from N, X₁, X₂ or X₃ is joined to the metal through a metal-nitrogen bond formed through G₂; or when G₂ is selected from a single bond, O or S and X₁, X₂ or X₃ is selected from C, X₁, X₂ or X₃ is joined to the metal through G₂;
X₄ to X₇ are, at each occurrence identically or differently, selected from CRₓ or N;
at least one of X₁ to X₇ is selected from CRₓ, wherein Rₓ is a cyano group or fluorine;
Z is, at each occurrence identically or differently, selected from the group consisting of O, S, Se, NR′, CR′R′, SiR′R′ and GeR′R′; when two R′ are present at the same time, the two R′ are identical or different;
Y₁, Y₂, U₁, U₂, W₁ and W₂ are, at each occurrence identically or differently, selected from C or N;
α and β are, at each occurrence identically or differently, selected from 0, 1 or 2, and α+β is greater than or equal to 1;
Ar is, at each occurrence identically or differently, selected from substituted or unsubstituted aryl having 6 to 30 carbon atoms, substituted or unsubstituted heteroaryl having 3 to 30 carbon atoms, or a combination thereof;
L is, at each occurrence identically or differently, selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R, Rᵤ and R_{w} represent, at each occurrence identically or differently, mono-substitution, multiple substitutions or non-substitution; when a plurality of R are present, the plurality of R are identical or different; when a plurality of Rᵤ are present, the plurality of Rᵤ are identical or different; when a plurality of R_{w} are present, the plurality of R_{w} are identical or different;
R, Rₓ and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring;
adjacent substituents R′ and Rₓ can be optionally joined to form a ring.

2. The metal complex of claim 1, wherein C_{y} is, at each occurrence identically or differently, any structure selected from the group consisting of the following: 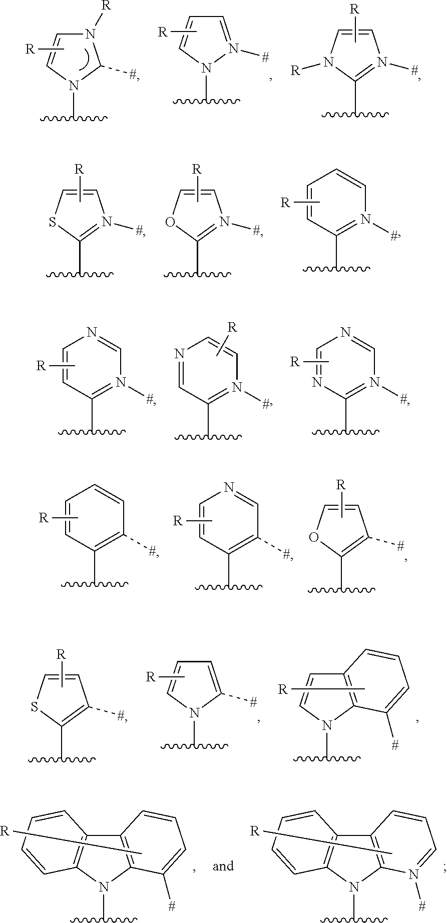
wherein
R represents, at each occurrence identically or differently, mono-substitution, multiple substitutions or non-substitution; when a plurality of R are present in any structure, the plurality of R are identical or different;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring;
“#” represents the position of attachment to the metal M, and 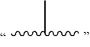
represents the position of attachment to X₁, X₂ or X₃.

3. The metal complex of claim 1, wherein L_{b} is, at each occurrence identically or differently, a structure represented by any one selected from the group consisting of the following: 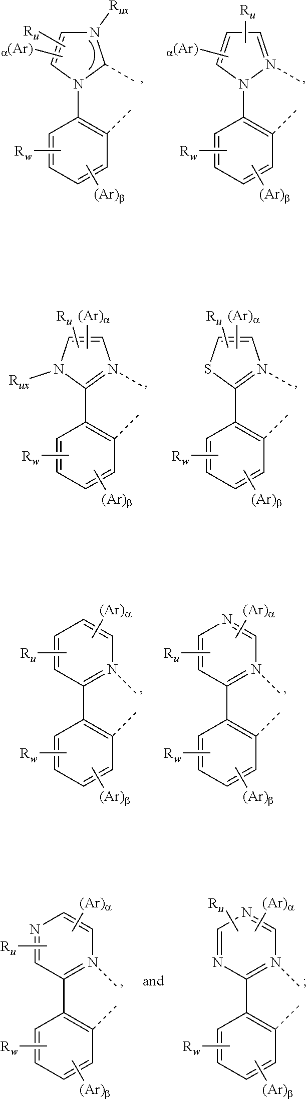
wherein
Rᵤ and R_{w} represent, at each occurrence identically or differently, mono-substitution, multiple substitutions or non-substitution;
α and β are, at each occurrence identically or differently, selected from 0, 1 or 2, and α+β is greater than or equal to 1;
Ar is, at each occurrence identically or differently, selected from substituted or unsubstituted aryl having 6 to 30 carbon atoms, substituted or unsubstituted heteroaryl having 3 to 30 carbon atoms, or a combination thereof;
Rᵤ, Rᵤₓ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

4. The metal complex of claim 1, wherein L_{c} is, at each occurrence identically or differently, a structure represented by any one selected from the group consisting of the following: 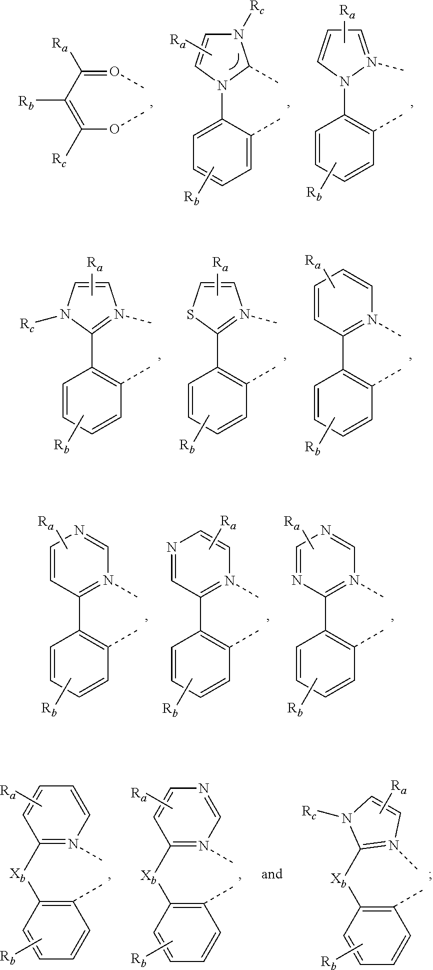
wherein
X_{b} is, at each occurrence identically or differently, selected from the group consisting of: O, S, Se, NR_{N1} and CR_{C1}R_{C2};
Rₐ and R_{b} represent, at each occurrence identically or differently, mono-substitution, multiple substitutions or non-substitution;
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{C1} and R_{C2} can be optionally joined to form a ring.

5. The metal complex of claim 1, wherein the metal M is, at each occurrence identically or differently, selected from the group consisting of Cᵤ, Ag, Au, Rᵤ, Rh, Pd, Os, Ir and Pt;
preferably, the metal M is, at each occurrence identically or differently, selected from Pt or Ir.

6. The metal complex of claim 1, wherein the metal complex has a general structure of Ir(Lₐ)ₘ(L_{b})₃₋ₘ which is represented by Formula 3: 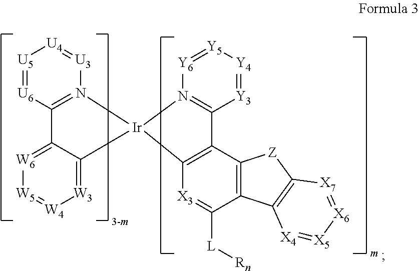
wherein
m is selected from 1 or 2; when m is selected from 1, two L_{b} are identical or different; when m is selected from 2, two Lₐ are identical or different;
Z is, at each occurrence identically or differently, selected from the group consisting of O, S, Se, NR′, CR′R′, SiR′R′ and GeR′R′; when two R′ are present at the same time, the two R′ are identical or different;
L is, at each occurrence identically or differently, selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
U₃ to U₆ are, at each occurrence identically or differently, selected from CRᵤ, CAr or N;
W₃ to W₆ are, at each occurrence identically or differently, selected from CR_{w}, CAr or N;
at least one of U₃ to U₆ and W₃ to W₆ is selected from CAr; Ar is, at each occurrence identically or differently, selected from substituted or unsubstituted aryl having 6 to 30 carbon atoms, substituted or unsubstituted heteroaryl having 3 to 30 carbon atoms, or a combination thereof;
X₃ to X₇ are, at each occurrence identically or differently, selected from CRₓ or N, and at least one of X₃ to X₇ is CRₓ, wherein Rₓ is a cyano group or fluorine;
Y₃ to Y₆ are, at each occurrence identically or differently, selected from CR or N;
R′, Rₓ and R are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring;
adjacent substituents R′ and Rₓ can be optionally joined to form a ring.

7. The metal complex of claim 1, wherein Z is, at each occurrence identically or differently, selected from O or S; preferably, Z is selected from O.

8. The metal complex of claim 1, wherein L is, at each occurrence identically or differently, selected from the group consisting of: a single bond, substituted or unsubstituted alkylene having 1 to 6 carbon atoms, substituted or unsubstituted cycloalkylene having 4 to 10 carbon atoms, substituted or unsubstituted arylene having 6 to 12 carbon atoms, and combinations thereof;
preferably, L is, at each occurrence identically or differently, selected from a single bond or substituted or unsubstituted methylene.

9. The metal complex of claim 1, wherein Rₙ is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms, substituted or unsubstituted heteroaryl having 3 to 30 carbon atoms, and combinations thereof;
preferably, Rₙ is, at each occurrence identically or differently, selected from the group consisting of: deuterium, substituted or unsubstituted alkyl having 1 to 20 carbon atoms, and substituted or unsubstituted cycloalkyl having 3 to 20 ring carbon atoms;
more preferably, Rₙ is, at each occurrence identically or differently, selected from the group consisting of: deuterium and substituted or unsubstituted alkyl having 1 to 6 carbon atoms.

10. The metal complex of claim 6, wherein Y₃ to Y₆ are, at each occurrence identically or differently, CR or N, and at least one of Y₃ to Y₆ is selected from CR, wherein R is selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, Y₃ to Y₆ are, at each occurrence identically or differently, CR or N, and at least one of Y₃ to Y₆ is selected from CR, wherein R is, at each occurrence identically or differently, selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, and combinations thereof.

11. The metal complex of claim 1, wherein at least one of X₄ to X₇ is CRₓ, wherein Rₓ is a cyano group or fluorine;
preferably, at least one of X₆ and/or X₇ is CRₓ, wherein Ry is a cyano group or fluorine;
more preferably, X₆ is CRₓ, wherein Rₓ is a cyano group.

12. The metal complex of claim 1, wherein at least two of X₃ to X₇ are selected from CRₓ, wherein one Rₓ is a cyano group or fluorine, and another Ry is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least two of X₄ to X₇ are selected from CRₓ, wherein one Rₓ is a cyano group or fluorine, and another Rₓ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
more preferably, X₆ is selected from CRₓ, wherein Rₓ is a cyano group or fluorine; X₇ is selected from CRₓ, wherein Rₓ is selected from deuterium, substituted or unsubstituted aryl having 6 to 18 carbon atoms, substituted or unsubstituted heteroaryl having 3 to 18 carbon atoms, or a combination thereof.

13. The metal complex of claim 6, wherein at least one of U₃ to U₆ is CAr and/or at least one of W₃ to W₆ is CAr, wherein Ar is selected from substituted or unsubstituted aryl having 6 to 30 carbon atoms, substituted or unsubstituted heteroaryl having 3 to 30 carbon atoms, or a combination thereof;
preferably, at least one of U₃ to U₆ is CAr or at least one of W₃ to W₆ is CAr, wherein Ar is selected from substituted or unsubstituted aryl having 6 to 18 carbon atoms, substituted or unsubstituted heteroaryl having 3 to 18 carbon atoms, or a combination thereof;
more preferably, W₅ is CAr, wherein Ar is selected from substituted or unsubstituted aryl having 6 to 12 carbon atoms.

14. The metal complex of claim 6, wherein U₃ to U₆ are selected from CAr or CRᵤ, and W₃ to W₆ are selected from CAr or CR_{w}, wherein Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, an isocyano group, and combinations thereof;
preferably, U₃ to U₆ are selected from CAr or CRᵤ, and W₃ to W₆ are selected from CAr or CR_{w}, wherein Rᵤ and R_{w} are, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, and combinations thereof;
more preferably, U₃ to U₆ are selected from CAr or CRᵤ, and W₃ to W₆ are selected from CAr or CR_{w}, wherein Ry and R_{w} are, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms, and combinations thereof.

15. The metal complex of claim 1, wherein Lₐ is, at each occurrence identically or differently, selected from the group consisting of Lₐ₁ to Lₐ₃₅₂₆;
wherein Lₐ₁ to Lₐ₃₅₂₆ each have the following structure: 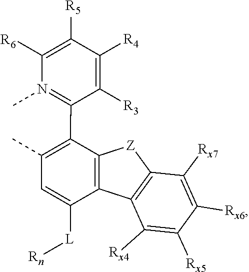
wherein R₃ to R₆, Rₓ₄ to Rₓ₇, L-Rₙ and Z are selected from the atoms or groups in the following table:

| Lₐ | L-Rₙ | R₃ | R₄ | R₅ | R₆ | Rₓ₄ | Rₓ₅ | Rₓ₆ | Rₓ₇ | Z |
|---|---|---|---|---|---|---|---|---|---|---|
| Lₐ₁ | P6 | H | H | H | H | H | H | CN | H | O |
| Lₐ₂ | P6 | H | P1 | H | H | H | H | CN | H | O |
| Lₐ₃ | P6 | H | P2 | H | H | H | H | CN | H | O |
| Lₐ₄ | P6 | H | P3 | H | H | H | H | CN | H | O |
| Lₐ₅ | P6 | H | P4 | H | H | H | H | CN | H | O |
| Lₐ₆ | P6 | H | P5 | H | H | H | H | CN | H | O |
| Lₐ₇ | P6 | H | P6 | H | H | H | H | CN | H | O |
| Lₐ₈ | P6 | H | P7 | H | H | H | H | CN | H | O |
| Lₐ₉ | P6 | H | P8 | H | H | H | H | CN | H | O |
| Lₐ₁₀ | P6 | H | P9 | H | H | H | H | CN | H | O |
| Lₐ₁₁ | P6 | H | P10 | H | H | H | H | CN | H | O |
| Lₐ₁₂ | P6 | H | P11 | H | H | H | H | CN | H | O |
| Lₐ₁₃ | P6 | H | P12 | H | H | H | H | CN | H | O |
| Lₐ₁₄ | P6 | H | P13 | H | H | H | H | CN | H | O |
| Lₐ₁₅ | P6 | H | P14 | H | H | H | H | CN | H | O |
| Lₐ₁₆ | P6 | H | P15 | H | H | H | H | CN | H | O |
| Lₐ₁₇ | P6 | H | P16 | H | H | H | H | CN | H | O |
| Lₐ₁₈ | P6 | H | P17 | H | H | H | H | CN | H | O |
| Lₐ₁₉ | P6 | H | P18 | H | H | H | H | CN | H | O |
| Lₐ₂₀ | P6 | H | P19 | H | H | H | H | CN | H | O |
| Lₐ₂₁ | P6 | H | P20 | H | H | H | H | CN | H | O |
| Lₐ₂₂ | P6 | H | P21 | H | H | H | H | CN | H | O |
| Lₐ₂₃ | P6 | H | P22 | H | H | H | H | CN | H | O |
| Lₐ₂₄ | P6 | H | P23 | H | H | H | H | CN | H | O |
| Lₐ₂₅ | P6 | H | P24 | H | H | H | H | CN | H | O |
| Lₐ₂₆ | P6 | H | P25 | H | H | H | H | CN | H | O |
| Lₐ₂₇ | P6 | H | P26 | H | H | H | H | CN | H | O |
| Lₐ₂₈ | P6 | H | P27 | H | H | H | H | CN | H | O |
| Lₐ₂₉ | P6 | H | P28 | H | H | H | H | CN | H | O |
| Lₐ₃₀ | P6 | H | P29 | H | H | H | H | CN | H | O |
| Lₐ₃₁ | P6 | H | P30 | H | H | H | H | CN | H | O |
| Lₐ₃₂ | P6 | H | P31 | H | H | H | H | CN | H | O |
| Lₐ₃₃ | P6 | H | P32 | H | H | H | H | CN | H | O |
| Lₐ₃₄ | P6 | H | P33 | H | H | H | H | CN | H | O |
| Lₐ₃₅ | P6 | H | P34 | H | H | H | H | CN | H | O |
| Lₐ₃₆ | P6 | H | H | P1 | H | H | H | CN | H | O |
| Lₐ₃₇ | P6 | H | H | P2 | H | H | H | CN | H | O |
| Lₐ₃₈ | P6 | H | H | P3 | H | H | H | CN | H | O |
| Lₐ₃₉ | P6 | H | H | P4 | H | H | H | CN | H | O |
| Lₐ₄₀ | P6 | H | H | P5 | H | H | H | CN | H | O |
| Lₐ₄₁ | P6 | H | H | P6 | H | H | H | CN | H | O |
| Lₐ₄₂ | P6 | H | H | P7 | H | H | H | CN | H | O |
| Lₐ₄₃ | P6 | H | H | P8 | H | H | H | CN | H | O |
| Lₐ₄₄ | P6 | H | H | P9 | H | H | H | CN | H | O |
| Lₐ₄₅ | P6 | H | H | P10 | H | H | H | CN | H | O |
| Lₐ₄₆ | P6 | H | H | P11 | H | H | H | CN | H | O |
| Lₐ₄₇ | P6 | H | H | P12 | H | H | H | CN | H | O |
| Lₐ₄₈ | P6 | H | H | P13 | H | H | H | CN | H | O |
| Lₐ₄₉ | P6 | H | H | P14 | H | H | H | CN | H | O |
| Lₐ₅₀ | P6 | H | H | P15 | H | H | H | CN | H | O |
| Lₐ₅₁ | P6 | H | H | P16 | H | H | H | CN | H | O |
| Lₐ₅₂ | P6 | H | H | P17 | H | H | H | CN | H | O |
| Lₐ₅₃ | P6 | H | H | P18 | H | H | H | CN | H | O |
| Lₐ₅₄ | P6 | H | H | P19 | H | H | H | CN | H | O |
| Lₐ₅₅ | P6 | H | H | P20 | H | H | H | CN | H | O |
| Lₐ₅₆ | P6 | H | H | P21 | H | H | H | CN | H | O |
| Lₐ₅₇ | P6 | H | H | P22 | H | H | H | CN | H | O |
| Lₐ₅₈ | P6 | H | H | P23 | H | H | H | CN | H | O |
| Lₐ₅₉ | P6 | H | H | P24 | H | H | H | CN | H | O |
| Lₐ₆₀ | P6 | H | H | P25 | H | H | H | CN | H | O |
| Lₐ₆₁ | P6 | H | H | P26 | H | H | H | CN | H | O |
| Lₐ₆₂ | P6 | H | H | P27 | H | H | H | CN | H | O |
| Lₐ₆₃ | P6 | H | H | P28 | H | H | H | CN | H | O |
| Lₐ₆₄ | P6 | H | H | P29 | H | H | H | CN | H | O |
| Lₐ₆₅ | P6 | H | H | P30 | H | H | H | CN | H | O |
| Lₐ₆₆ | P6 | H | H | P31 | H | H | H | CN | H | O |
| Lₐ₆₇ | P6 | H | H | P32 | H | H | H | CN | H | O |
| Lₐ₆₈ | P6 | H | H | P33 | H | H | H | CN | H | O |
| Lₐ₆₉ | P6 | H | H | P34 | H | H | H | CN | H | O |
| Lₐ₇₀ | P6 | H | P1 | P1 | H | H | H | CN | H | O |
| Lₐ₇₁ | P6 | H | P2 | P2 | H | H | H | CN | H | O |
| Lₐ₇₂ | P6 | H | F | H | H | H | H | CN | H | O |
| Lₐ₇₃ | P6 | H | H | F | H | H | H | CN | H | O |
| Lₐ₇₄ | P6 | H | F | P1 | H | H | H | CN | H | O |
| Lₐ₇₅ | P6 | H | F | P2 | H | H | H | CN | H | O |
| Lₐ₇₆ | P6 | H | P1 | F | H | H | H | CN | H | O |
| Lₐ₇₇ | P6 | H | P2 | F | H | H | H | CN | H | O |
| Lₐ₇₈ | P6 | H | H | H | H | H | H | CN | D | O |
| Lₐ₇₉ | P6 | H | P1 | H | H | H | H | CN | D | O |
| Lₐ₈₀ | P6 | H | P2 | H | H | H | H | CN | D | O |
| Lₐ₈₁ | P6 | H | P3 | H | H | H | H | CN | D | O |
| Lₐ₈₂ | P6 | H | P4 | H | H | H | H | CN | D | O |
| Lₐ₈₃ | P6 | H | P5 | H | H | H | H | CN | D | O |
| Lₐ₈₄ | P6 | H | P6 | H | H | H | H | CN | D | O |
| Lₐ₈₅ | P6 | H | P7 | H | H | H | H | CN | D | O |
| Lₐ₈₆ | P6 | H | P8 | H | H | H | H | CN | D | O |
| Lₐ₈₇ | P6 | H | P9 | H | H | H | H | CN | D | O |
| Lₐ₈₈ | P6 | H | P10 | H | H | H | H | CN | D | O |
| Lₐ₈₉ | P6 | H | P11 | H | H | H | H | CN | D | O |
| Lₐ₉₀ | P6 | H | P12 | H | H | H | H | CN | D | O |
| Lₐ₉₁ | P6 | H | P13 | H | H | H | H | CN | D | O |
| Lₐ₉₂ | P6 | H | P14 | H | H | H | H | CN | D | O |
| Lₐ₉₃ | P6 | H | P15 | H | H | H | H | CN | D | O |
| Lₐ₉₄ | P6 | H | P16 | H | H | H | H | CN | D | O |
| Lₐ₉₅ | P6 | H | P17 | H | H | H | H | CN | D | O |
| Lₐ₉₆ | P6 | H | P18 | H | H | H | H | CN | D | O |
| Lₐ₉₇ | P6 | H | P19 | H | H | H | H | CN | D | O |
| Lₐ₉₈ | P6 | H | P20 | H | H | H | H | CN | D | O |
| Lₐ₉₉ | P6 | H | P21 | H | H | H | H | CN | D | O |
| Lₐ₁₀₀ | P6 | H | P22 | H | H | H | H | CN | D | O |
| Lₐ₁₀₁ | P6 | H | P23 | H | H | H | H | CN | D | O |
| Lₐ₁₀₂ | P6 | H | P24 | H | H | H | H | CN | D | O |
| Lₐ₁₀₃ | P6 | H | P25 | H | H | H | H | CN | D | O |
| Lₐ₁₀₄ | P6 | H | P26 | H | H | H | H | CN | D | O |
| Lₐ₁₀₅ | P6 | H | P27 | H | H | H | H | CN | D | O |
| Lₐ₁₀₆ | P6 | H | P28 | H | H | H | H | CN | D | O |
| Lₐ₁₀₇ | P6 | H | P29 | H | H | H | H | CN | D | O |
| Lₐ₁₀₈ | P6 | H | P30 | H | H | H | H | CN | D | O |
| Lₐ₁₀₉ | P6 | H | P31 | H | H | H | H | CN | D | O |
| Lₐ₁₁₀ | P6 | H | P32 | H | H | H | H | CN | D | O |
| Lₐ₁₁₁ | P6 | H | P33 | H | H | H | H | CN | D | O |
| Lₐ₁₁₂ | P6 | H | P34 | H | H | H | H | CN | D | O |
| Lₐ₁₁₃ | P6 | H | H | P1 | H | H | H | CN | D | O |
| Lₐ₁₁₄ | P6 | H | H | P2 | H | H | H | CN | D | O |
| Lₐ₁₁₅ | P6 | H | H | P3 | H | H | H | CN | D | O |
| Lₐ₁₁₆ | P6 | H | H | P4 | H | H | H | CN | D | O |
| Lₐ₁₁₇ | P6 | H | H | P5 | H | H | H | CN | D | O |
| Lₐ₁₁₈ | P6 | H | H | P6 | H | H | H | CN | D | O |
| Lₐ₁₁₉ | P6 | H | H | P7 | H | H | H | CN | D | O |
| Lₐ₁₂₀ | P6 | H | H | P8 | H | H | H | CN | D | O |
| Lₐ₁₂₁ | P6 | H | H | P9 | H | H | H | CN | D | O |
| Lₐ₁₂₂ | P6 | H | H | P10 | H | H | H | CN | D | O |
| Lₐ₁₂₃ | P6 | H | H | P11 | H | H | H | CN | D | O |
| Lₐ₁₂₄ | P6 | H | H | P12 | H | H | H | CN | D | O |
| Lₐ₁₂₅ | P6 | H | H | P13 | H | H | H | CN | D | O |
| Lₐ₁₂₆ | P6 | H | H | P14 | H | H | H | CN | D | O |
| Lₐ₁₂₇ | P6 | H | H | P15 | H | H | H | CN | D | O |
| Lₐ₁₂₈ | P6 | H | H | P16 | H | H | H | CN | D | O |
| Lₐ₁₂₉ | P6 | H | H | P17 | H | H | H | CN | D | O |
| Lₐ₁₃₀ | P6 | H | H | P18 | H | H | H | CN | D | O |
| Lₐ₁₃₁ | P6 | H | H | P19 | H | H | H | CN | D | O |
| Lₐ₁₃₂ | P6 | H | H | P20 | H | H | H | CN | D | O |
| Lₐ₁₃₃ | P6 | H | H | P21 | H | H | H | CN | D | O |
| Lₐ₁₃₄ | P6 | H | H | P22 | H | H | H | CN | D | O |
| Lₐ₁₃₅ | P6 | H | H | P23 | H | H | H | CN | D | O |
| Lₐ₁₃₆ | P6 | H | H | P24 | H | H | H | CN | D | O |
| Lₐ₁₃₇ | P6 | H | H | P25 | H | H | H | CN | D | O |
| Lₐ₁₃₈ | P6 | H | H | P26 | H | H | H | CN | D | O |
| Lₐ₁₃₉ | P6 | H | H | P27 | H | H | H | CN | D | O |
| Lₐ₁₄₀ | P6 | H | H | P28 | H | H | H | CN | D | O |
| Lₐ₁₄₁ | P6 | H | H | P29 | H | H | H | CN | D | O |
| Lₐ₁₄₂ | P6 | H | H | P30 | H | H | H | CN | D | O |
| Lₐ₁₄₃ | P6 | H | H | P31 | H | H | H | CN | D | O |
| Lₐ₁₄₄ | P6 | H | H | P32 | H | H | H | CN | D | O |
| Lₐ₁₄₅ | P6 | H | H | P33 | H | H | H | CN | D | O |
| Lₐ₁₄₆ | P6 | H | H | P34 | H | H | H | CN | D | O |
| Lₐ₁₄₇ | P6 | H | P1 | P1 | H | H | H | CN | D | O |
| Lₐ₁₄₈ | P6 | H | P2 | P2 | H | H | H | CN | D | O |
| Lₐ₁₄₉ | P6 | H | F | H | H | H | H | CN | D | O |
| Lₐ₁₅₀ | P6 | H | H | F | H | H | H | CN | D | O |
| Lₐ₁₅₁ | P6 | H | F | P1 | H | H | H | CN | D | O |
| Lₐ₁₅₂ | P6 | H | F | P2 | H | H | H | CN | D | O |
| Lₐ₁₅₃ | P6 | H | P1 | F | H | H | H | CN | D | O |
| Lₐ₁₅₄ | P6 | H | P2 | F | H | H | H | CN | D | O |
| Lₐ₁₅₅ | P6 | D | H | P1 | H | H | H | CN | H | O |
| Lₐ₁₅₆ | P6 | H | H | P2 | D | H | H | CN | H | O |
| Lₐ₁₅₇ | P6 | H | H | H | H | H | H | CN | P23 | O |
| Lₐ₁₅₈ | P6 | H | H | H | H | H | H | CN | P24 | O |
| Lₐ₁₅₉ | P6 | H | H | H | H | H | H | CN | P25 | O |
| Lₐ₁₆₀ | P6 | H | H | H | H | H | H | CN | P26 | O |
| Lₐ₁₆₁ | P6 | H | H | H | H | H | H | CN | P27 | O |
| Lₐ₁₆₂ | P6 | H | H | H | H | H | H | CN | P28 | O |
| Lₐ₁₆₃ | P6 | H | H | H | H | H | H | CN | P29 | O |
| Lₐ₁₆₄ | P6 | H | H | H | H | H | H | CN | P30 | O |
| Lₐ₁₆₅ | P6 | H | H | H | H | H | H | CN | P31 | O |
| Lₐ₁₆₆ | P6 | H | H | H | H | H | H | CN | P32 | O |
| Lₐ₁₆₇ | P6 | H | H | H | H | H | H | CN | P33 | O |
| Lₐ₁₆₈ | P6 | H | H | H | H | H | H | CN | P34 | O |
| Lₐ₁₆₉ | P6 | H | H | H | H | H | H | CN | P35 | O |
| Lₐ₁₇₀ | P6 | H | H | H | H | H | H | CN | P36 | O |
| Lₐ₁₇₁ | P6 | H | H | H | H | H | H | CN | P37 | O |
| Lₐ₁₇₂ | P6 | H | H | H | H | H | H | CN | P38 | O |
| Lₐ₁₇₃ | P6 | H | H | H | H | H | H | CN | P39 | O |
| Lₐ₁₇₄ | P6 | H | H | H | H | H | H | CN | P40 | O |
| Lₐ₁₇₅ | P6 | H | H | H | H | H | H | CN | P41 | O |
| Lₐ₁₇₆ | P6 | H | H | H | H | H | H | CN | P42 | O |
| Lₐ₁₇₇ | P6 | H | H | H | H | H | H | CN | P43 | O |
| Lₐ₁₇₈ | P6 | H | H | H | H | H | H | CN | P44 | O |
| Lₐ₁₇₉ | P6 | H | H | H | H | H | H | CN | P45 | O |
| Lₐ₁₈₀ | P6 | H | H | H | H | H | H | CN | P46 | O |
| Lₐ₁₈₁ | P6 | H | H | H | H | H | H | CN | P47 | O |
| Lₐ₁₈₂ | P6 | H | H | H | H | H | H | CN | P48 | O |
| Lₐ₁₈₃ | P6 | H | H | H | H | H | H | CN | P49 | O |
| Lₐ₁₈₄ | P6 | H | H | H | H | H | H | CN | P50 | O |
| Lₐ₁₈₅ | P6 | H | H | H | H | H | H | CN | P51 | O |
| Lₐ₁₈₆ | P6 | H | H | H | H | H | H | CN | P52 | O |
| Lₐ₁₈₇ | P6 | H | H | H | H | H | H | CN | P53 | O |
| Lₐ₁₈₈ | P6 | H | H | H | H | H | H | CN | P54 | O |
| Lₐ₁₈₉ | P6 | H | H | H | H | H | H | CN | P55 | O |
| Lₐ₁₉₀ | P6 | H | H | H | H | H | H | CN | P56 | O |
| Lₐ₁₉₁ | P6 | H | H | H | H | H | H | CN | P57 | O |
| Lₐ₁₉₂ | P6 | H | H | H | H | H | H | CN | P58 | O |
| Lₐ₁₉₃ | P6 | H | H | H | H | H | H | CN | P59 | O |
| Lₐ₁₉₄ | P6 | H | H | H | H | H | H | CN | P60 | O |
| Lₐ₁₉₅ | P6 | H | H | H | H | H | H | CN | P61 | O |
| Lₐ₁₉₆ | P6 | H | H | H | H | H | H | CN | P62 | O |
| Lₐ₁₉₇ | P6 | H | H | H | H | H | H | CN | P63 | O |
| Lₐ₁₉₈ | P6 | H | H | H | H | H | H | CN | P64 | O |
| Lₐ₁₉₉ | P6 | H | H | H | H | H | H | CN | P65 | O |
| Lₐ₂₀₀ | P6 | H | H | H | H | H | H | CN | P66 | O |
| Lₐ₂₀₁ | P6 | H | H | H | H | H | H | CN | P67 | O |
| Lₐ₂₀₂ | P6 | H | H | H | H | H | H | CN | P68 | O |
| Lₐ₂₀₃ | P6 | H | H | H | H | H | H | CN | P69 | O |
| Lₐ₂₀₄ | P6 | H | H | H | H | H | H | CN | P70 | O |
| Lₐ₂₀₅ | P6 | H | H | H | H | H | H | CN | P71 | O |
| Lₐ₂₀₆ | P6 | H | H | H | H | H | H | CN | P72 | O |
| Lₐ₂₀₇ | P6 | H | H | H | H | H | H | CN | P73 | O |
| Lₐ₂₀₈ | P6 | H | H | H | H | H | H | CN | P74 | O |
| Lₐ₂₀₉ | P6 | H | H | H | H | H | H | CN | P75 | O |
| Lₐ₂₁₀ | P6 | H | H | H | H | H | H | CN | P76 | O |
| Lₐ₂₁₁ | P6 | H | H | H | H | H | H | CN | P77 | O |
| Lₐ₂₁₂ | P6 | H | H | H | H | H | H | CN | P78 | O |
| Lₐ₂₁₃ | P6 | H | H | H | H | H | H | CN | P79 | O |
| Lₐ₂₁₄ | P6 | H | H | H | H | H | H | CN | P80 | O |
| Lₐ₂₁₅ | P6 | H | H | H | H | H | H | CN | P81 | O |
| Lₐ₂₁₆ | P6 | H | H | H | H | H | H | CN | P82 | O |
| Lₐ₂₁₇ | P6 | H | H | H | H | H | H | CN | P83 | O |
| Lₐ₂₁₈ | P6 | H | H | H | H | H | H | CN | P84 | O |
| Lₐ₂₁₉ | P6 | H | H | H | H | H | H | CN | P85 | O |
| Lₐ₂₂₀ | P6 | H | H | H | H | H | H | CN | P86 | O |
| Lₐ₂₂₁ | P6 | H | H | H | H | H | H | CN | P87 | O |
| Lₐ₂₂₂ | P6 | H | H | H | H | H | H | CN | P88 | O |
| Lₐ₂₂₃ | P6 | H | H | H | H | H | H | CN | P89 | O |
| Lₐ₂₂₄ | P6 | H | H | H | H | H | H | CN | P90 | O |
| Lₐ₂₂₅ | P6 | H | P1 | H | H | H | H | CN | P23 | O |
| Lₐ₂₂₆ | P6 | H | P2 | H | H | H | H | CN | P23 | O |
| Lₐ₂₂₇ | P6 | H | P3 | H | H | H | H | CN | P23 | O |
| Lₐ₂₂₈ | P6 | H | P4 | H | H | H | H | CN | P23 | O |
| Lₐ₂₂₉ | P6 | H | P5 | H | H | H | H | CN | P23 | O |
| Lₐ₂₃₀ | P6 | H | P6 | H | H | H | H | CN | P23 | O |
| Lₐ₂₃₁ | P6 | H | P7 | H | H | H | H | CN | P23 | O |
| Lₐ₂₃₂ | P6 | H | P8 | H | H | H | H | CN | P23 | O |
| Lₐ₂₃₃ | P6 | H | P9 | H | H | H | H | CN | P23 | O |
| Lₐ₂₃₄ | P6 | H | P10 | H | H | H | H | CN | P23 | O |
| Lₐ₂₃₅ | P6 | H | P11 | H | H | H | H | CN | P23 | O |
| Lₐ₂₃₆ | P6 | H | P12 | H | H | H | H | CN | P23 | O |
| Lₐ₂₃₇ | P6 | H | P15 | H | H | H | H | CN | P23 | O |
| Lₐ₂₃₈ | P6 | H | P17 | H | H | H | H | CN | P23 | O |
| Lₐ₂₃₉ | P6 | H | H | P1 | H | H | H | CN | P23 | O |
| Lₐ₂₄₀ | P6 | H | H | P2 | H | H | H | CN | P23 | O |
| Lₐ₂₄₁ | P6 | H | H | P3 | H | H | H | CN | P23 | O |
| Lₐ₂₄₂ | P6 | H | H | P4 | H | H | H | CN | P23 | O |
| Lₐ₂₄₃ | P6 | H | H | P5 | H | H | H | CN | P23 | O |
| Lₐ₂₄₄ | P6 | H | H | P6 | H | H | H | CN | P23 | O |
| Lₐ₂₄₅ | P6 | H | H | P7 | H | H | H | CN | P23 | O |
| Lₐ₂₄₆ | P6 | H | H | P8 | H | H | H | CN | P23 | O |
| Lₐ₂₄₇ | P6 | H | H | P9 | H | H | H | CN | P23 | O |
| Lₐ₂₄₈ | P6 | H | H | P10 | H | H | H | CN | P23 | O |
| Lₐ₂₄₉ | P6 | H | H | P11 | H | H | H | CN | P23 | O |
| Lₐ₂₅₀ | P6 | H | H | P12 | H | H | H | CN | P23 | O |
| Lₐ₂₅₁ | P6 | H | H | P15 | H | H | H | CN | P23 | O |
| Lₐ₂₅₂ | P6 | H | H | P17 | H | H | H | CN | P23 | O |
| Lₐ₂₅₃ | P6 | H | F | H | H | H | H | CN | P23 | O |
| Lₐ₂₅₄ | P6 | H | H | F | H | H | H | CN | P23 | O |
| Lₐ₂₅₅ | P6 | H | F | P1 | H | H | H | CN | P23 | O |
| Lₐ₂₅₆ | P6 | H | F | P2 | H | H | H | CN | P23 | O |
| Lₐ₂₅₇ | P6 | H | P1 | F | H | H | H | CN | P23 | O |
| Lₐ₂₅₈ | P6 | H | P2 | F | H | H | H | CN | P23 | O |
| Lₐ₂₅₉ | P6 | H | P1 | P1 | H | H | H | CN | P23 | O |
| Lₐ₂₆₀ | P6 | H | P2 | P2 | H | H | H | CN | P23 | O |
| Lₐ₂₆₁ | P6 | H | P1 | H | H | H | H | CN | P24 | O |
| Lₐ₂₆₂ | P6 | H | P2 | H | H | H | H | CN | P24 | O |
| Lₐ₂₆₃ | P6 | H | P3 | H | H | H | H | CN | P24 | O |
| Lₐ₂₆₄ | P6 | H | P4 | H | H | H | H | CN | P24 | O |
| Lₐ₂₆₅ | P6 | H | P5 | H | H | H | H | CN | P24 | O |
| Lₐ₂₆₆ | P6 | H | P6 | H | H | H | H | CN | P24 | O |
| Lₐ₂₆₇ | P6 | H | P7 | H | H | H | H | CN | P24 | O |
| Lₐ₂₆₈ | P6 | H | P8 | H | H | H | H | CN | P24 | O |
| Lₐ₂₆₉ | P6 | H | P9 | H | H | H | H | CN | P24 | O |
| Lₐ₂₇₀ | P6 | H | P10 | H | H | H | H | CN | P24 | O |
| Lₐ₂₇₁ | P6 | H | P11 | H | H | H | H | CN | P24 | O |
| Lₐ₂₇₂ | P6 | H | P12 | H | H | H | H | CN | P24 | O |
| Lₐ₂₇₃ | P6 | H | P15 | H | H | H | H | CN | P24 | O |
| Lₐ₂₇₄ | P6 | H | P17 | H | H | H | H | CN | P24 | O |
| Lₐ₂₇₅ | P6 | H | H | P1 | H | H | H | CN | P24 | O |
| Lₐ₂₇₆ | P6 | H | H | P2 | H | H | H | CN | P24 | O |
| Lₐ₂₇₇ | P6 | H | H | P3 | H | H | H | CN | P24 | O |
| Lₐ₂₇₈ | P6 | H | H | P4 | H | H | H | CN | P24 | O |
| Lₐ₂₇₉ | P6 | H | H | P5 | H | H | H | CN | P24 | O |
| Lₐ₂₈₀ | P6 | H | H | P6 | H | H | H | CN | P24 | O |
| Lₐ₂₈₁ | P6 | H | H | P7 | H | H | H | CN | P24 | O |
| Lₐ₂₈₂ | P6 | H | H | P8 | H | H | H | CN | P24 | O |
| Lₐ₂₈₃ | P6 | H | H | P9 | H | H | H | CN | P24 | O |
| Lₐ₂₈₄ | P6 | H | H | P10 | H | H | H | CN | P24 | O |
| Lₐ₂₈₅ | P6 | H | H | P11 | H | H | H | CN | P24 | O |
| Lₐ₂₈₆ | P6 | H | H | P12 | H | H | H | CN | P24 | O |
| Lₐ₂₈₇ | P6 | H | H | P15 | H | H | H | CN | P24 | O |
| Lₐ₂₈₈ | P6 | H | H | P17 | H | H | H | CN | P24 | O |
| Lₐ₂₈₉ | P6 | H | F | H | H | H | H | CN | P24 | O |
| Lₐ₂₉₀ | P6 | H | H | F | H | H | H | CN | P24 | O |
| Lₐ₂₉₁ | P6 | H | F | P1 | H | H | H | CN | P24 | O |
| Lₐ₂₉₂ | P6 | H | F | P2 | H | H | H | CN | P24 | O |
| Lₐ₂₉₃ | P6 | H | P1 | F | H | H | H | CN | P24 | O |
| Lₐ₂₉₄ | P6 | H | P2 | F | H | H | H | CN | P24 | O |
| Lₐ₂₉₅ | P6 | H | P1 | P1 | H | H | H | CN | P24 | O |
| Lₐ₂₉₆ | P6 | H | P2 | P2 | H | H | H | CN | P24 | O |
| Lₐ₂₉₇ | P6 | H | P1 | H | H | H | H | CN | P56 | O |
| Lₐ₂₉₈ | P6 | H | P2 | H | H | H | H | CN | P56 | O |
| Lₐ₂₉₉ | P6 | H | P3 | H | H | H | H | CN | P56 | O |
| Lₐ₃₀₀ | P6 | H | P4 | H | H | H | H | CN | P56 | O |
| Lₐ₃₀₁ | P6 | H | P5 | H | H | H | H | CN | P56 | O |
| Lₐ₃₀₂ | P6 | H | P6 | H | H | H | H | CN | P56 | O |
| Lₐ₃₀₃ | P6 | H | P7 | H | H | H | H | CN | P56 | O |
| Lₐ₃₀₄ | P6 | H | P8 | H | H | H | H | CN | P56 | O |
| Lₐ₃₀₅ | P6 | H | P9 | H | H | H | H | CN | P56 | O |
| Lₐ₃₀₆ | P6 | H | P10 | H | H | H | H | CN | P56 | O |
| Lₐ₃₀₇ | P6 | H | P11 | H | H | H | H | CN | P56 | O |
| Lₐ₃₀₈ | P6 | H | P12 | H | H | H | H | CN | P56 | O |
| Lₐ₃₀₉ | P6 | H | P15 | H | H | H | H | CN | P56 | O |
| Lₐ₃₁₀ | P6 | H | P17 | H | H | H | H | CN | P56 | O |
| Lₐ₃₁₁ | P6 | H | H | P1 | H | H | H | CN | P56 | O |
| Lₐ₃₁₂ | P6 | H | H | P2 | H | H | H | CN | P56 | O |
| Lₐ₃₁₃ | P6 | H | H | P3 | H | H | H | CN | P56 | O |
| Lₐ₃₁₄ | P6 | H | H | P4 | H | H | H | CN | P56 | O |
| Lₐ₃₁₅ | P6 | H | H | P5 | H | H | H | CN | P56 | O |
| Lₐ₃₁₆ | P6 | H | H | P6 | H | H | H | CN | P56 | O |
| Lₐ₃₁₇ | P6 | H | H | P7 | H | H | H | CN | P56 | O |
| Lₐ₃₁₈ | P6 | H | H | P8 | H | H | H | CN | P56 | O |
| Lₐ₃₁₉ | P6 | H | H | P9 | H | H | H | CN | P56 | O |
| Lₐ₃₂₀ | P6 | H | H | P10 | H | H | H | CN | P56 | O |
| Lₐ₃₂₁ | P6 | H | H | P11 | H | H | H | CN | P56 | O |
| Lₐ₃₂₂ | P6 | H | H | P12 | H | H | H | CN | P56 | O |
| Lₐ₃₂₃ | P6 | H | H | P15 | H | H | H | CN | P56 | O |
| Lₐ₃₂₄ | P6 | H | H | P17 | H | H | H | CN | P56 | O |
| Lₐ₃₂₅ | P6 | H | F | H | H | H | H | CN | P56 | O |
| Lₐ₃₂₆ | P6 | H | H | F | H | H | H | CN | P56 | O |
| Lₐ₃₂₇ | P6 | H | F | P1 | H | H | H | CN | P56 | O |
| Lₐ₃₂₈ | P6 | H | F | P2 | H | H | H | CN | P56 | O |
| Lₐ₃₂₉ | P6 | H | P1 | F | H | H | H | CN | P56 | O |
| Lₐ₃₃₀ | P6 | H | P2 | F | H | H | H | CN | P56 | O |
| Lₐ₃₃₁ | P6 | H | P1 | P1 | H | H | H | CN | P56 | O |
| Lₐ₃₃₂ | P6 | H | P2 | P2 | H | H | H | CN | P56 | O |
| Lₐ₃₃₃ | P6 | H | P2 | H | H | H | H | CN | P73 | O |
| Lₐ₃₃₄ | P6 | H | P3 | H | H | H | H | CN | P73 | O |
| Lₐ₃₃₅ | P6 | H | P4 | H | H | H | H | CN | P73 | O |
| Lₐ₃₃₆ | P6 | H | P5 | H | H | H | H | CN | P73 | O |
| Lₐ₃₃₇ | P6 | H | P6 | H | H | H | H | CN | P73 | O |
| Lₐ₃₃₈ | P6 | H | P7 | H | H | H | H | CN | P73 | O |
| Lₐ₃₃₉ | P6 | H | P8 | H | H | H | H | CN | P73 | O |
| Lₐ₃₄₀ | P6 | H | P9 | H | H | H | H | CN | P73 | O |
| Lₐ₃₄₁ | P6 | H | P10 | H | H | H | H | CN | P73 | O |
| Lₐ₃₄₂ | P6 | H | P11 | H | H | H | H | CN | P73 | O |
| Lₐ₃₄₃ | P6 | H | P12 | H | H | H | H | CN | P73 | O |
| Lₐ₃₄₄ | P6 | H | P15 | H | H | H | H | CN | P73 | O |
| Lₐ₃₄₅ | P6 | H | P17 | H | H | H | H | CN | P73 | O |
| Lₐ₃₄₆ | P6 | H | P1 | P1 | H | H | H | CN | P73 | O |
| Lₐ₃₄₇ | P6 | H | H | P1 | H | H | H | CN | P73 | O |
| Lₐ₃₄₈ | P6 | H | H | P2 | H | H | H | CN | P73 | O |
| Lₐ₃₄₉ | P6 | H | H | P3 | H | H | H | CN | P73 | O |
| Lₐ₃₅₀ | P6 | H | H | P4 | H | H | H | CN | P73 | O |
| Lₐ₃₅₁ | P6 | H | H | P5 | H | H | H | CN | P73 | O |
| Lₐ₃₅₂ | P6 | H | H | P6 | H | H | H | CN | P73 | O |
| Lₐ₃₅₃ | P6 | H | H | P7 | H | H | H | CN | P73 | O |
| Lₐ₃₅₄ | P6 | H | H | P8 | H | H | H | CN | P73 | O |
| Lₐ₃₅₅ | P6 | H | H | P9 | H | H | H | CN | P73 | O |
| Lₐ₃₅₆ | P6 | H | H | P10 | H | H | H | CN | P73 | O |
| Lₐ₃₅₇ | P6 | H | H | P11 | H | H | H | CN | P73 | O |
| Lₐ₃₅₈ | P6 | H | H | P12 | H | H | H | CN | P73 | O |
| Lₐ₃₅₉ | P6 | H | H | P15 | H | H | H | CN | P73 | O |
| Lₐ₃₆₀ | P6 | H | F | P17 | H | H | H | CN | P73 | O |
| Lₐ₃₆₁ | P6 | H | P2 | P2 | H | H | H | CN | P73 | O |
| Lₐ₃₆₂ | P6 | H | F | F | H | H | H | CN | P73 | O |
| Lₐ₃₆₃ | P6 | H | F | P1 | H | H | H | CN | P73 | O |
| Lₐ₃₆₄ | P6 | H | P1 | P2 | H | H | H | CN | P73 | O |
| Lₐ₃₆₅ | P6 | H | P2 | F | H | H | H | CN | P73 | O |
| Lₐ₃₆₆ | P6 | H | P1 | F | H | H | H | CN | P73 | O |
| Lₐ₃₆₇ | P6 | H | P2 | P1 | H | H | H | CN | P73 | O |
| Lₐ₃₆₈ | P6 | H | P1 | P1 | H | H | H | CN | P74 | O |
| Lₐ₃₆₉ | P6 | H | P2 | H | H | H | H | CN | P74 | O |
| Lₐ₃₇₀ | P6 | H | P3 | H | H | H | H | CN | P74 | O |
| Lₐ₃₇₁ | P6 | H | P4 | H | H | H | H | CN | P74 | O |
| Lₐ₃₇₂ | P6 | H | P5 | H | H | H | H | CN | P74 | O |
| Lₐ₃₇₃ | P6 | H | P6 | H | H | H | H | CN | P74 | O |
| Lₐ₃₇₄ | P6 | H | P7 | H | H | H | H | CN | P74 | O |
| Lₐ₃₇₅ | P6 | H | P8 | H | H | H | H | CN | P74 | O |
| Lₐ₃₇₆ | P6 | H | P9 | H | H | H | H | CN | P74 | O |
| Lₐ₃₇₇ | P6 | H | P10 | H | H | H | H | CN | P74 | O |
| Lₐ₃₇₈ | P6 | H | P11 | H | H | H | H | CN | P74 | O |
| Lₐ₃₇₉ | P6 | H | P12 | H | H | H | H | CN | P74 | O |
| Lₐ₃₈₀ | P6 | H | P15 | H | H | H | H | CN | P74 | O |
| Lₐ₃₈₁ | P6 | H | P17 | H | H | H | H | CN | P74 | O |
| Lₐ₃₈₂ | P6 | H | P2 | P2 | H | H | H | CN | P74 | O |
| Lₐ₃₈₃ | P6 | H | H | P1 | H | H | H | CN | P74 | O |
| Lₐ₃₈₄ | P6 | H | H | P2 | H | H | H | CN | P74 | O |
| Lₐ₃₈₅ | P6 | H | H | P3 | H | H | H | CN | P74 | O |
| Lₐ₃₈₆ | P6 | H | H | P4 | H | H | H | CN | P74 | O |
| Lₐ₃₈₇ | P6 | H | H | P5 | H | H | H | CN | P74 | O |
| Lₐ₃₈₈ | P6 | H | H | P6 | H | H | H | CN | P74 | O |
| Lₐ₃₈₉ | P6 | H | H | P7 | H | H | H | CN | P74 | O |
| Lₐ₃₉₀ | P6 | H | H | P8 | H | H | H | CN | P74 | O |
| Lₐ₃₉₁ | P6 | H | H | P9 | H | H | H | CN | P74 | O |
| Lₐ₃₉₂ | P6 | H | H | P10 | H | H | H | CN | P74 | O |
| Lₐ₃₉₃ | P6 | H | H | P11 | H | H | H | CN | P74 | O |
| Lₐ₃₉₄ | P6 | H | H | P12 | H | H | H | CN | P74 | O |
| Lₐ₃₉₅ | P6 | H | H | P15 | H | H | H | CN | P74 | O |
| Lₐ₃₉₆ | P6 | H | F | P17 | H | H | H | CN | P74 | O |
| Lₐ₃₉₇ | P6 | H | H | H | H | H | H | CN | P74 | O |
| Lₐ₃₉₈ | P6 | H | F | F | H | H | H | CN | P74 | O |
| Lₐ₃₉₉ | P6 | H | F | P1 | H | H | H | CN | P74 | O |
| Lₐ₄₀₀ | P6 | H | P1 | P1 | H | H | H | CN | P74 | O |
| Lₐ₄₀₁ | P6 | H | P2 | F | H | H | H | CN | P74 | O |
| Lₐ₄₀₂ | P6 | H | P1 | F | H | H | H | CN | P74 | O |
| Lₐ₄₀₃ | P6 | H | P2 | P2 | H | H | H | CN | P74 | O |
| Lₐ₄₀₄ | P6 | H | P1 | P1 | H | H | H | CN | P79 | O |
| Lₐ₄₀₅ | P6 | H | P2 | H | H | H | H | CN | P79 | O |
| Lₐ₄₀₆ | P6 | H | P3 | H | H | H | H | CN | P79 | O |
| Lₐ₄₀₇ | P6 | H | P4 | H | H | H | H | CN | P79 | O |
| Lₐ₄₀₈ | P6 | H | P5 | H | H | H | H | CN | P79 | O |
| Lₐ₄₀₉ | P6 | H | P6 | H | H | H | H | CN | P79 | O |
| Lₐ₄₁₀ | P6 | H | P7 | H | H | H | H | CN | P79 | O |
| Lₐ₄₁₁ | P6 | H | P8 | H | H | H | H | CN | P79 | O |
| Lₐ₄₁₂ | P6 | H | P9 | H | H | H | H | CN | P79 | O |
| Lₐ₄₁₃ | P6 | H | P10 | H | H | H | H | CN | P79 | O |
| Lₐ₄₁₄ | P6 | H | P11 | H | H | H | H | CN | P79 | O |
| Lₐ₄₁₅ | P6 | H | P12 | H | H | H | H | CN | P79 | O |
| Lₐ₄₁₆ | P6 | H | P15 | H | H | H | H | CN | P79 | O |
| Lₐ₄₁₇ | P6 | H | P17 | H | H | H | H | CN | P79 | O |
| Lₐ₄₁₈ | P6 | H | P1 | P1 | H | H | H | CN | P79 | O |
| Lₐ₄₁₉ | P6 | H | H | P1 | H | H | H | CN | P79 | O |
| Lₐ₄₂₀ | P6 | H | H | P2 | H | H | H | CN | P79 | O |
| Lₐ₄₂₁ | P6 | H | H | P3 | H | H | H | CN | P79 | O |
| Lₐ₄₂₂ | P6 | H | H | P4 | H | H | H | CN | P79 | O |
| Lₐ₄₂₃ | P6 | H | H | P5 | H | H | H | CN | P79 | O |
| Lₐ₄₂₄ | P6 | H | H | P6 | H | H | H | CN | P79 | O |
| Lₐ₄₂₅ | P6 | H | H | P7 | H | H | H | CN | P79 | O |
| Lₐ₄₂₆ | P6 | H | H | P8 | H | H | H | CN | P79 | O |
| Lₐ₄₂₇ | P6 | H | H | P9 | H | H | H | CN | P79 | O |
| Lₐ₄₂₈ | P6 | H | H | P10 | H | H | H | CN | P79 | O |
| Lₐ₄₂₉ | P6 | H | H | P11 | H | H | H | CN | P79 | O |
| Lₐ₄₃₀ | P6 | H | H | P12 | H | H | H | CN | P79 | O |
| Lₐ₄₃₁ | P6 | H | H | P15 | H | H | H | CN | P79 | O |
| Lₐ₄₃₂ | P6 | H | F | P17 | H | H | H | CN | P79 | O |
| Lₐ₄₃₃ | P6 | H | H | H | H | H | H | CN | P79 | O |
| Lₐ₄₃₄ | P6 | H | F | F | H | H | H | CN | P79 | O |
| Lₐ₄₃₅ | P6 | H | F | P1 | H | H | H | CN | P79 | O |
| Lₐ₄₃₆ | P6 | H | P1 | P2 | H | H | H | CN | P79 | O |
| Lₐ₄₃₇ | P6 | H | P2 | F | H | H | H | CN | P79 | O |
| Lₐ₄₃₈ | P6 | H | P1 | F | H | H | H | CN | P79 | O |
| Lₐ₄₃₉ | P6 | H | P2 | P1 | H | H | H | CN | P79 | O |
| Lₐ₄₄₀ | P6 | H | P1 | P2 | H | H | H | CN | P80 | O |
| Lₐ₄₄₁ | P6 | H | P2 | H | H | H | H | CN | P80 | O |
| Lₐ₄₄₂ | P6 | H | P3 | H | H | H | H | CN | P80 | O |
| Lₐ₄₄₃ | P6 | H | P4 | H | H | H | H | CN | P80 | O |
| Lₐ₄₄₄ | P6 | H | P5 | H | H | H | H | CN | P80 | O |
| Lₐ₄₄₅ | P6 | H | P6 | H | H | H | H | CN | P80 | O |
| Lₐ₄₄₆ | P6 | H | P7 | H | H | H | H | CN | P80 | O |
| Lₐ₄₄₇ | P6 | H | P8 | H | H | H | H | CN | P80 | O |
| Lₐ₄₄₈ | P6 | H | P9 | H | H | H | H | CN | P80 | O |
| Lₐ₄₄₉ | P6 | H | P10 | H | H | H | H | CN | P80 | O |
| Lₐ₄₅₀ | P6 | H | P11 | H | H | H | H | CN | P80 | O |
| Lₐ₄₅₁ | P6 | H | P12 | H | H | H | H | CN | P80 | O |
| Lₐ₄₅₂ | P6 | H | P15 | H | H | H | H | CN | P80 | O |
| Lₐ₄₅₃ | P6 | H | P17 | H | H | H | H | CN | P80 | O |
| Lₐ₄₅₄ | P6 | H | P1 | P1 | H | H | H | CN | P80 | O |
| Lₐ₄₅₅ | P6 | H | H | P1 | H | H | H | CN | P80 | O |
| Lₐ₄₅₆ | P6 | H | H | P2 | H | H | H | CN | P80 | O |
| Lₐ₄₅₇ | P6 | H | H | P3 | H | H | H | CN | P80 | O |
| Lₐ₄₅₈ | P6 | H | H | P4 | H | H | H | CN | P80 | O |
| Lₐ₄₅₉ | P6 | H | H | P5 | H | H | H | CN | P80 | O |
| Lₐ₄₆₀ | P6 | H | H | P6 | H | H | H | CN | P80 | O |
| Lₐ₄₆₁ | P6 | H | H | P7 | H | H | H | CN | P80 | O |
| Lₐ₄₆₂ | P6 | H | H | P8 | H | H | H | CN | P80 | O |
| Lₐ₄₆₃ | P6 | H | H | P9 | H | H | H | CN | P80 | O |
| Lₐ₄₆₄ | P6 | H | H | P10 | H | H | H | CN | P80 | O |
| Lₐ₄₆₅ | P6 | H | H | P11 | H | H | H | CN | P80 | O |
| Lₐ₄₆₆ | P6 | H | H | P12 | H | H | H | CN | P80 | O |
| Lₐ₄₆₇ | P6 | H | H | P15 | H | H | H | CN | P80 | O |
| Lₐ₄₆₈ | P6 | H | F | P17 | H | H | H | CN | P80 | O |
| Lₐ₄₆₉ | P6 | H | H | F | H | H | H | CN | P80 | O |
| Lₐ₄₇₀ | P6 | H | F | P1 | H | H | H | CN | P80 | O |
| Lₐ₄₇₁ | P6 | H | F | P2 | H | H | H | CN | P80 | O |
| Lₐ₄₇₂ | P6 | H | P1 | F | H | H | H | CN | P80 | O |
| Lₐ₄₇₃ | P6 | H | P2 | F | H | H | H | CN | P80 | O |
| Lₐ₄₇₄ | P6 | H | P1 | P1 | H | H | H | CN | P80 | O |
| Lₐ₄₇₅ | P6 | H | P2 | P2 | H | H | H | CN | P80 | O |
| Lₐ₄₇₆ | P6 | H | P1 | H | H | H | H | CN | P89 | O |
| Lₐ₄₇₇ | P6 | H | P2 | H | H | H | H | CN | P89 | O |
| Lₐ₄₇₈ | P6 | H | P3 | H | H | H | H | CN | P89 | O |
| Lₐ₄₇₉ | P6 | H | P4 | H | H | H | H | CN | P89 | O |
| Lₐ₄₈₀ | P6 | H | P5 | H | H | H | H | CN | P89 | O |
| Lₐ₄₈₁ | P6 | H | P6 | H | H | H | H | CN | P89 | O |
| Lₐ₄₈₂ | P6 | H | P7 | H | H | H | H | CN | P89 | O |
| Lₐ₄₈₃ | P6 | H | P8 | H | H | H | H | CN | P89 | O |
| Lₐ₄₈₄ | P6 | H | P9 | H | H | H | H | CN | P89 | O |
| Lₐ₄₈₅ | P6 | H | P10 | H | H | H | H | CN | P89 | O |
| Lₐ₄₈₆ | P6 | H | P11 | H | H | H | H | CN | P89 | O |
| Lₐ₄₈₇ | P6 | H | P12 | H | H | H | H | CN | P89 | O |
| Lₐ₄₈₈ | P6 | H | P15 | H | H | H | H | CN | P89 | O |
| Lₐ₄₈₉ | P6 | H | P17 | H | H | H | H | CN | P89 | O |
| Lₐ₄₉₀ | P6 | H | H | P1 | H | H | H | CN | P89 | O |
| Lₐ₄₉₁ | P6 | H | H | P2 | H | H | H | CN | P89 | O |
| Lₐ₄₉₂ | P6 | H | H | P3 | H | H | H | CN | P89 | O |
| Lₐ₄₉₃ | P6 | H | H | P4 | H | H | H | CN | P89 | O |
| Lₐ₄₉₄ | P6 | H | H | P5 | H | H | H | CN | P89 | O |
| Lₐ₄₉₅ | P6 | H | H | P6 | H | H | H | CN | P89 | O |
| Lₐ₄₉₆ | P6 | H | H | P7 | H | H | H | CN | P89 | O |
| Lₐ₄₉₇ | P6 | H | H | P8 | H | H | H | CN | P89 | O |
| Lₐ₄₉₈ | P6 | H | H | P9 | H | H | H | CN | P89 | O |
| Lₐ₄₉₉ | P6 | H | H | P10 | H | H | H | CN | P89 | O |
| Lₐ₅₀₀ | P6 | H | H | P11 | H | H | H | CN | P89 | O |
| Lₐ₅₀₁ | P6 | H | H | P12 | H | H | H | CN | P89 | O |
| Lₐ₅₀₂ | P6 | H | H | P15 | H | H | H | CN | P89 | O |
| Lₐ₅₀₃ | P6 | H | H | P17 | H | H | H | CN | P89 | O |
| Lₐ₅₀₄ | P6 | H | F | H | H | H | H | CN | P89 | O |
| Lₐ₅₀₅ | P6 | H | H | F | H | H | H | CN | P89 | O |
| Lₐ₅₀₆ | P6 | H | F | P1 | H | H | H | CN | P89 | O |
| Lₐ₅₀₇ | P6 | H | F | P2 | H | H | H | CN | P89 | O |
| Lₐ₅₀₈ | P6 | H | P1 | F | H | H | H | CN | P89 | O |
| Lₐ₅₀₉ | P6 | H | P2 | F | H | H | H | CN | P89 | O |
| Lₐ₅₁₀ | P6 | H | P1 | P1 | H | H | H | CN | P89 | O |
| Lₐ₅₁₁ | P6 | H | P2 | P2 | H | H | H | CN | P89 | O |
| Lₐ₅₁₂ | P11 | H | H | H | H | H | H | CN | H | O |
| Lₐ₅₁₃ | P11 | H | P1 | H | H | H | H | CN | H | O |
| Lₐ₅₁₄ | P11 | H | P2 | H | H | H | H | CN | H | O |
| Lₐ₅₁₅ | P11 | H | P3 | H | H | H | H | CN | H | O |
| Lₐ₅₁₆ | P11 | H | P4 | H | H | H | H | CN | H | O |
| Lₐ₅₁₇ | P11 | H | P5 | H | H | H | H | CN | H | O |
| Lₐ₅₁₈ | P11 | H | P6 | H | H | H | H | CN | H | O |
| Lₐ₅₁₉ | P11 | H | P7 | H | H | H | H | CN | H | O |
| Lₐ₅₂₀ | P11 | H | P8 | H | H | H | H | CN | H | O |
| Lₐ₅₂₁ | P11 | H | P9 | H | H | H | H | CN | H | O |
| Lₐ₅₂₂ | P11 | H | P10 | H | H | H | H | CN | H | O |
| Lₐ₅₂₃ | P11 | H | P11 | H | H | H | H | CN | H | O |
| Lₐ₅₂₄ | P11 | H | P12 | H | H | H | H | CN | H | O |
| Lₐ₅₂₅ | P11 | H | P13 | H | H | H | H | CN | H | O |
| Lₐ₅₂₆ | P11 | H | P14 | H | H | H | H | CN | H | O |
| Lₐ₅₂₇ | P11 | H | P15 | H | H | H | H | CN | H | O |
| Lₐ₅₂₈ | P11 | H | P16 | H | H | H | H | CN | H | O |
| Lₐ₅₂₉ | P11 | H | P17 | H | H | H | H | CN | H | O |
| Lₐ₅₃₀ | P11 | H | P18 | H | H | H | H | CN | H | O |
| Lₐ₅₃₁ | P11 | H | P19 | H | H | H | H | CN | H | O |
| Lₐ₅₃₂ | P11 | H | P20 | H | H | H | H | CN | H | O |
| Lₐ₅₃₃ | P11 | H | P21 | H | H | H | H | CN | H | O |
| Lₐ₅₃₄ | P11 | H | P22 | H | H | H | H | CN | H | O |
| Lₐ₅₃₅ | P11 | H | P23 | H | H | H | H | CN | H | O |
| Lₐ₅₃₆ | P11 | H | P24 | H | H | H | H | CN | H | O |
| Lₐ₅₃₇ | P11 | H | P25 | H | H | H | H | CN | H | O |
| Lₐ₅₃₈ | P11 | H | P26 | H | H | H | H | CN | H | O |
| Lₐ₅₃₉ | P11 | H | P27 | H | H | H | H | CN | H | O |
| Lₐ₅₄₀ | P11 | H | P28 | H | H | H | H | CN | H | O |
| Lₐ₅₄₁ | P11 | H | P29 | H | H | H | H | CN | H | O |
| Lₐ₅₄₂ | P11 | H | P30 | H | H | H | H | CN | H | O |
| Lₐ₅₄₃ | P11 | H | P31 | H | H | H | H | CN | H | O |
| Lₐ₅₄₄ | P11 | H | P32 | H | H | H | H | CN | H | O |
| Lₐ₅₄₅ | P11 | H | P33 | H | H | H | H | CN | H | O |
| Lₐ₅₄₆ | P11 | H | P34 | H | H | H | H | CN | H | O |
| Lₐ₅₄₇ | P11 | H | H | P1 | H | H | H | CN | H | O |
| Lₐ₅₄₈ | P11 | H | H | P2 | H | H | H | CN | H | O |
| Lₐ₅₄₉ | P11 | H | H | P3 | H | H | H | CN | H | O |
| Lₐ₅₅₀ | P11 | H | H | P4 | H | H | H | CN | H | O |
| Lₐ₅₅₁ | P11 | H | H | P5 | H | H | H | CN | H | O |
| Lₐ₅₅₂ | P11 | H | H | P6 | H | H | H | CN | H | O |
| Lₐ₅₅₃ | P11 | H | H | P7 | H | H | H | CN | H | O |
| Lₐ₅₅₄ | P11 | H | H | P8 | H | H | H | CN | H | O |
| Lₐ₅₅₅ | P11 | H | H | P9 | H | H | H | CN | H | O |
| Lₐ₅₅₆ | P11 | H | H | P10 | H | H | H | CN | H | O |
| Lₐ₅₅₇ | P11 | H | H | P11 | H | H | H | CN | H | O |
| Lₐ₅₅₈ | P11 | H | H | P12 | H | H | H | CN | H | O |
| Lₐ₅₅₉ | P11 | H | H | P13 | H | H | H | CN | H | O |
| Lₐ₅₆₀ | P11 | H | H | P14 | H | H | H | CN | H | O |
| Lₐ₅₆₁ | P11 | H | H | P15 | H | H | H | CN | H | O |
| Lₐ₅₆₂ | P11 | H | H | P16 | H | H | H | CN | H | O |
| Lₐ₅₆₃ | P11 | H | H | P17 | H | H | H | CN | H | O |
| Lₐ₅₆₄ | P11 | H | H | P18 | H | H | H | CN | H | O |
| Lₐ₅₆₅ | P11 | H | H | P19 | H | H | H | CN | H | O |
| Lₐ₅₆₆ | P11 | H | H | P20 | H | H | H | CN | H | O |
| Lₐ₅₆₇ | P11 | H | H | P21 | H | H | H | CN | H | O |
| Lₐ₅₆₈ | P11 | H | H | P22 | H | H | H | CN | H | O |
| Lₐ₅₆₉ | P11 | H | H | P23 | H | H | H | CN | H | O |
| Lₐ₅₇₀ | P11 | H | H | P24 | H | H | H | CN | H | O |
| Lₐ₅₇₁ | P11 | H | H | P25 | H | H | H | CN | H | O |
| Lₐ₅₇₂ | P11 | H | H | P26 | H | H | H | CN | H | O |
| Lₐ₅₇₃ | P11 | H | H | P27 | H | H | H | CN | H | O |
| Lₐ₅₇₄ | P11 | H | H | P28 | H | H | H | CN | H | O |
| Lₐ₅₇₅ | P11 | H | H | P29 | H | H | H | CN | H | O |
| Lₐ₅₇₆ | P11 | H | H | P30 | H | H | H | CN | H | O |
| Lₐ₅₇₇ | P11 | H | H | P31 | H | H | H | CN | H | O |
| Lₐ₅₇₈ | P11 | H | H | P32 | H | H | H | CN | H | O |
| Lₐ₅₇₉ | P11 | H | H | P33 | H | H | H | CN | H | O |
| Lₐ₅₈₀ | P11 | H | H | P34 | H | H | H | CN | H | O |
| Lₐ₅₈₁ | P11 | H | P1 | P1 | H | H | H | CN | H | O |
| Lₐ₅₈₂ | P11 | H | P2 | P2 | H | H | H | CN | H | O |
| Lₐ₅₈₃ | P11 | H | F | H | H | H | H | CN | H | O |
| Lₐ₅₈₄ | P11 | H | H | F | H | H | H | CN | H | O |
| Lₐ₅₈₅ | P11 | H | F | P1 | H | H | H | CN | H | O |
| Lₐ₅₈₆ | P11 | H | F | P2 | H | H | H | CN | H | O |
| Lₐ₅₈₇ | P11 | H | P1 | F | H | H | H | CN | H | O |
| Lₐ₅₈₈ | P11 | H | P2 | F | H | H | H | CN | H | O |
| Lₐ₅₈₉ | P11 | H | H | H | H | H | H | CN | D | O |
| Lₐ₅₉₀ | P11 | H | P1 | H | H | H | H | CN | D | O |
| Lₐ₅₉₁ | P11 | H | P2 | H | H | H | H | CN | D | O |
| Lₐ₅₉₂ | P11 | H | P3 | H | H | H | H | CN | D | O |
| Lₐ₅₉₃ | P11 | H | P4 | H | H | H | H | CN | D | O |
| Lₐ₅₉₄ | P11 | H | P5 | H | H | H | H | CN | D | O |
| Lₐ₅₉₅ | P11 | H | P6 | H | H | H | H | CN | D | O |
| Lₐ₅₉₆ | P11 | H | P7 | H | H | H | H | CN | D | O |
| Lₐ₅₉₇ | P11 | H | P8 | H | H | H | H | CN | D | O |
| Lₐ₅₉₈ | P11 | H | P9 | H | H | H | H | CN | D | O |
| Lₐ₅₉₉ | P11 | H | P10 | H | H | H | H | CN | D | O |
| Lₐ₆₀₀ | P11 | H | P11 | H | H | H | H | CN | D | O |
| Lₐ₆₀₁ | P11 | H | P12 | H | H | H | H | CN | D | O |
| Lₐ₆₀₂ | P11 | H | P13 | H | H | H | H | CN | D | O |
| Lₐ₆₀₃ | P11 | H | P14 | H | H | H | H | CN | D | O |
| Lₐ₆₀₄ | P11 | H | P15 | H | H | H | H | CN | D | O |
| Lₐ₆₀₅ | P11 | H | P16 | H | H | H | H | CN | D | O |
| Lₐ₆₀₆ | P11 | H | P17 | H | H | H | H | CN | D | O |
| Lₐ₆₀₇ | P11 | H | P18 | H | H | H | H | CN | D | O |
| Lₐ₆₀₈ | P11 | H | P19 | H | H | H | H | CN | D | O |
| Lₐ₆₀₉ | P11 | H | P20 | H | H | H | H | CN | D | O |
| Lₐ₆₁₀ | P11 | H | P21 | H | H | H | H | CN | D | O |
| Lₐ₆₁₁ | P11 | H | P22 | H | H | H | H | CN | D | O |
| Lₐ₆₁₂ | P11 | H | P23 | H | H | H | H | CN | D | O |
| Lₐ₆₁₃ | P11 | H | P24 | H | H | H | H | CN | D | O |
| Lₐ₆₁₄ | P11 | H | P25 | H | H | H | H | CN | D | O |
| Lₐ₆₁₅ | P11 | H | P26 | H | H | H | H | CN | D | O |
| Lₐ₆₁₆ | P11 | H | P27 | H | H | H | H | CN | D | O |
| Lₐ₆₁₇ | P11 | H | P28 | H | H | H | H | CN | D | O |
| Lₐ₆₁₈ | P11 | H | P29 | H | H | H | H | CN | D | O |
| Lₐ₆₁₉ | P11 | H | P30 | H | H | H | H | CN | D | O |
| Lₐ₆₂₀ | P11 | H | P31 | H | H | H | H | CN | D | O |
| Lₐ₆₂₁ | P11 | H | P32 | H | H | H | H | CN | D | O |
| Lₐ₆₂₂ | P11 | H | P33 | H | H | H | H | CN | D | O |
| Lₐ₆₂₃ | P11 | H | P34 | H | H | H | H | CN | D | O |
| Lₐ₆₂₄ | P11 | H | H | P1 | H | H | H | CN | D | O |
| Lₐ₆₂₅ | P11 | H | H | P2 | H | H | H | CN | D | O |
| Lₐ₆₂₆ | P11 | H | H | P3 | H | H | H | CN | D | O |
| Lₐ₆₂₇ | P11 | H | H | P4 | H | H | H | CN | D | O |
| Lₐ₆₂₈ | P11 | H | H | P5 | H | H | H | CN | D | O |
| Lₐ₆₂₉ | P11 | H | H | P6 | H | H | H | CN | D | O |
| Lₐ₆₃₀ | P11 | H | H | P7 | H | H | H | CN | D | O |
| Lₐ₆₃₁ | P11 | H | H | P8 | H | H | H | CN | D | O |
| Lₐ₆₃₂ | P11 | H | H | P9 | H | H | H | CN | D | O |
| Lₐ₆₃₃ | P11 | H | H | P10 | H | H | H | CN | D | O |
| Lₐ₆₃₄ | P11 | H | H | P11 | H | H | H | CN | D | O |
| Lₐ₆₃₅ | P11 | H | H | P12 | H | H | H | CN | D | O |
| Lₐ₆₃₆ | P11 | H | H | P13 | H | H | H | CN | D | O |
| Lₐ₆₃₇ | P11 | H | H | P14 | H | H | H | CN | D | O |
| Lₐ₆₃₈ | P11 | H | H | P15 | H | H | H | CN | D | O |
| Lₐ₆₃₉ | P11 | H | H | P16 | H | H | H | CN | D | O |
| Lₐ₆₄₀ | P11 | H | H | P17 | H | H | H | CN | D | O |
| Lₐ₆₄₁ | P11 | H | H | P18 | H | H | H | CN | D | O |
| Lₐ₆₄₂ | P11 | H | H | P19 | H | H | H | CN | D | O |
| Lₐ₆₄₃ | P11 | H | H | P20 | H | H | H | CN | D | O |
| Lₐ₆₄₄ | P11 | H | H | P21 | H | H | H | CN | D | O |
| Lₐ₆₄₅ | P11 | H | H | P22 | H | H | H | CN | D | O |
| Lₐ₆₄₆ | P11 | H | H | P23 | H | H | H | CN | D | O |
| Lₐ₆₄₇ | P11 | H | H | P24 | H | H | H | CN | D | O |
| Lₐ₆₄₈ | P11 | H | H | P25 | H | H | H | CN | D | O |
| Lₐ₆₄₉ | P11 | H | H | P26 | H | H | H | CN | D | O |
| Lₐ₆₅₀ | P11 | H | H | P27 | H | H | H | CN | D | O |
| Lₐ₆₅₁ | P11 | H | H | P28 | H | H | H | CN | D | O |
| Lₐ₆₅₂ | P11 | H | H | P29 | H | H | H | CN | D | O |
| Lₐ₆₅₃ | P11 | H | H | P30 | H | H | H | CN | D | O |
| Lₐ₆₅₄ | P11 | H | H | P31 | H | H | H | CN | D | O |
| Lₐ₆₅₅ | P11 | H | H | P32 | H | H | H | CN | D | O |
| Lₐ₆₅₆ | P11 | H | H | P33 | H | H | H | CN | D | O |
| Lₐ₆₅₇ | P11 | H | H | P34 | H | H | H | CN | D | O |
| Lₐ₆₅₈ | P11 | H | P1 | P1 | H | H | H | CN | D | O |
| Lₐ₆₅₉ | P11 | H | P2 | P2 | H | H | H | CN | D | O |
| Lₐ₆₆₀ | P11 | H | F | H | H | H | H | CN | D | O |
| Lₐ₆₆₁ | P11 | H | H | F | H | H | H | CN | D | O |
| Lₐ₆₆₂ | P11 | H | F | P1 | H | H | H | CN | D | O |
| Lₐ₆₆₃ | P11 | H | F | P2 | H | H | H | CN | D | O |
| Lₐ₆₆₄ | P11 | H | P1 | F | H | H | H | CN | D | O |
| Lₐ₆₆₅ | P11 | H | P2 | F | H | H | H | CN | D | O |
| Lₐ₆₆₆ | P11 | D | H | P1 | H | H | H | CN | H | O |
| Lₐ₆₆₇ | P11 | H | H | P2 | D | H | H | CN | H | O |
| Lₐ₆₆₈ | P11 | H | H | H | H | H | H | CN | P23 | O |
| Lₐ₆₆₉ | P11 | H | H | H | H | H | H | CN | P24 | O |
| Lₐ₆₇₀ | P11 | H | H | H | H | H | H | CN | P25 | O |
| Lₐ₆₇₁ | P11 | H | H | H | H | H | H | CN | P26 | O |
| Lₐ₆₇₂ | P11 | H | H | H | H | H | H | CN | P27 | O |
| Lₐ₆₇₃ | P11 | H | H | H | H | H | H | CN | P28 | O |
| Lₐ₆₇₄ | P11 | H | H | H | H | H | H | CN | P29 | O |
| Lₐ₆₇₅ | P11 | H | H | H | H | H | H | CN | P30 | O |
| Lₐ₆₇₆ | P11 | H | H | H | H | H | H | CN | P31 | O |
| Lₐ₆₇₇ | P11 | H | H | H | H | H | H | CN | P32 | O |
| Lₐ₆₇₈ | P11 | H | H | H | H | H | H | CN | P33 | O |
| Lₐ₆₇₉ | P11 | H | H | H | H | H | H | CN | P34 | O |
| Lₐ₆₈₀ | P11 | H | H | H | H | H | H | CN | P35 | O |
| Lₐ₆₈₁ | P11 | H | H | H | H | H | H | CN | P36 | O |
| Lₐ₆₈₂ | P11 | H | H | H | H | H | H | CN | P37 | O |
| Lₐ₆₈₃ | P11 | H | H | H | H | H | H | CN | P38 | O |
| Lₐ₆₈₄ | P11 | H | H | H | H | H | H | CN | P39 | O |
| Lₐ₆₈₅ | P11 | H | H | H | H | H | H | CN | P40 | O |
| Lₐ₆₈₆ | P11 | H | H | H | H | H | H | CN | P41 | O |
| Lₐ₆₈₇ | P11 | H | H | H | H | H | H | CN | P42 | O |
| Lₐ₆₈₈ | P11 | H | H | H | H | H | H | CN | P43 | O |
| Lₐ₆₈₉ | P11 | H | H | H | H | H | H | CN | P44 | O |
| Lₐ₆₉₀ | P11 | H | H | H | H | H | H | CN | P45 | O |
| Lₐ₆₉₁ | P11 | H | H | H | H | H | H | CN | P46 | O |
| Lₐ₆₉₂ | P11 | H | H | H | H | H | H | CN | P47 | O |
| Lₐ₆₉₃ | P11 | H | H | H | H | H | H | CN | P48 | O |
| Lₐ₆₉₄ | P11 | H | H | H | H | H | H | CN | P49 | O |
| Lₐ₆₉₅ | P11 | H | H | H | H | H | H | CN | P50 | O |
| Lₐ₆₉₆ | P11 | H | H | H | H | H | H | CN | P51 | O |
| Lₐ₆₉₇ | P11 | H | H | H | H | H | H | CN | P52 | O |
| Lₐ₆₉₈ | P11 | H | H | H | H | H | H | CN | P53 | O |
| Lₐ₆₉₉ | P11 | H | H | H | H | H | H | CN | P54 | O |
| Lₐ₇₀₀ | P11 | H | H | H | H | H | H | CN | P55 | O |
| Lₐ₇₀₁ | P11 | H | H | H | H | H | H | CN | P56 | O |
| Lₐ₇₀₂ | P11 | H | H | H | H | H | H | CN | P57 | O |
| Lₐ₇₀₃ | P11 | H | H | H | H | H | H | CN | P58 | O |
| Lₐ₇₀₄ | P11 | H | H | H | H | H | H | CN | P59 | O |
| Lₐ₇₀₅ | P11 | H | H | H | H | H | H | CN | P60 | O |
| Lₐ₇₀₆ | P11 | H | H | H | H | H | H | CN | P61 | O |
| Lₐ₇₀₇ | P11 | H | H | H | H | H | H | CN | P62 | O |
| Lₐ₇₀₈ | P11 | H | H | H | H | H | H | CN | P63 | O |
| Lₐ₇₀₉ | P11 | H | H | H | H | H | H | CN | P64 | O |
| Lₐ₇₁₀ | P11 | H | H | H | H | H | H | CN | P65 | O |
| Lₐ₇₁₁ | P11 | H | H | H | H | H | H | CN | P66 | O |
| Lₐ₇₁₂ | P11 | H | H | H | H | H | H | CN | P67 | O |
| Lₐ₇₁₃ | P11 | H | H | H | H | H | H | CN | P68 | O |
| Lₐ₇₁₄ | P11 | H | H | H | H | H | H | CN | P69 | O |
| Lₐ₇₁₅ | P11 | H | H | H | H | H | H | CN | P70 | O |
| Lₐ₇₁₆ | P11 | H | H | H | H | H | H | CN | P71 | O |
| Lₐ₇₁₇ | P11 | H | H | H | H | H | H | CN | P72 | O |
| Lₐ₇₁₈ | P11 | H | H | H | H | H | H | CN | P73 | O |
| Lₐ₇₁₉ | P11 | H | H | H | H | H | H | CN | P74 | O |
| Lₐ₇₂₀ | P11 | H | H | H | H | H | H | CN | P75 | O |
| Lₐ₇₂₁ | P11 | H | H | H | H | H | H | CN | P76 | O |
| Lₐ₇₂₂ | P11 | H | H | H | H | H | H | CN | P77 | O |
| Lₐ₇₂₃ | P11 | H | H | H | H | H | H | CN | P78 | O |
| Lₐ₇₂₄ | P11 | H | H | H | H | H | H | CN | P79 | O |
| Lₐ₇₂₅ | P11 | H | H | H | H | H | H | CN | P80 | O |
| Lₐ₇₂₆ | P11 | H | H | H | H | H | H | CN | P81 | O |
| Lₐ₇₂₇ | P11 | H | H | H | H | H | H | CN | P82 | O |
| Lₐ₇₂₈ | P11 | H | H | H | H | H | H | CN | P83 | O |
| Lₐ₇₂₉ | P11 | H | H | H | H | H | H | CN | P84 | O |
| Lₐ₇₃₀ | P11 | H | H | H | H | H | H | CN | P85 | O |
| Lₐ₇₃₁ | P11 | H | H | H | H | H | H | CN | P86 | O |
| Lₐ₇₃₂ | P11 | H | H | H | H | H | H | CN | P87 | O |
| Lₐ₇₃₃ | P11 | H | H | H | H | H | H | CN | P88 | O |
| Lₐ₇₃₄ | P11 | H | H | H | H | H | H | CN | P89 | O |
| Lₐ₇₃₅ | P11 | H | H | H | H | H | H | CN | P90 | O |
| Lₐ₇₃₆ | P11 | H | P1 | H | H | H | H | CN | P23 | O |
| Lₐ₇₃₇ | P11 | H | P2 | H | H | H | H | CN | P23 | O |
| Lₐ₇₃₈ | P11 | H | P3 | H | H | H | H | CN | P23 | O |
| Lₐ₇₃₉ | P11 | H | P4 | H | H | H | H | CN | P23 | O |
| Lₐ₇₄₀ | P11 | H | P5 | H | H | H | H | CN | P23 | O |
| Lₐ₇₄₁ | P11 | H | P6 | H | H | H | H | CN | P23 | O |
| Lₐ₇₄₂ | P11 | H | P7 | H | H | H | H | CN | P23 | O |
| Lₐ₇₄₃ | P11 | H | P8 | H | H | H | H | CN | P23 | O |
| Lₐ₇₄₄ | P11 | H | P9 | H | H | H | H | CN | P23 | O |
| Lₐ₇₄₅ | P11 | H | P10 | H | H | H | H | CN | P23 | O |
| Lₐ₇₄₆ | P11 | H | P11 | H | H | H | H | CN | P23 | O |
| Lₐ₇₄₇ | P11 | H | P12 | H | H | H | H | CN | P23 | O |
| Lₐ₇₄₈ | P11 | H | P15 | H | H | H | H | CN | P23 | O |
| Lₐ₇₄₉ | P11 | H | P17 | H | H | H | H | CN | P23 | O |
| Lₐ₇₅₀ | P11 | H | H | P1 | H | H | H | CN | P23 | O |
| Lₐ₇₅₁ | P11 | H | H | P2 | H | H | H | CN | P23 | O |
| Lₐ₇₅₂ | P11 | H | H | P3 | H | H | H | CN | P23 | O |
| Lₐ₇₅₃ | P11 | H | H | P4 | H | H | H | CN | P23 | O |
| Lₐ₇₅₄ | P11 | H | H | P5 | H | H | H | CN | P23 | O |
| Lₐ₇₅₅ | P11 | H | H | P6 | H | H | H | CN | P23 | O |
| Lₐ₇₅₆ | P11 | H | H | P7 | H | H | H | CN | P23 | O |
| Lₐ₇₅₇ | P11 | H | H | P8 | H | H | H | CN | P23 | O |
| Lₐ₇₅₈ | P11 | H | H | P9 | H | H | H | CN | P23 | O |
| Lₐ₇₅₉ | P11 | H | H | P10 | H | H | H | CN | P23 | O |
| Lₐ₇₆₀ | P11 | H | H | P11 | H | H | H | CN | P23 | O |
| Lₐ₇₆₁ | P11 | H | H | P12 | H | H | H | CN | P23 | O |
| Lₐ₇₆₂ | P11 | H | H | P15 | H | H | H | CN | P23 | O |
| Lₐ₇₆₃ | P11 | H | H | P17 | H | H | H | CN | P23 | O |
| Lₐ₇₆₄ | P11 | H | F | H | H | H | H | CN | P23 | O |
| Lₐ₇₆₅ | P11 | H | H | F | H | H | H | CN | P23 | O |
| Lₐ₇₆₆ | P11 | H | F | P1 | H | H | H | CN | P23 | O |
| Lₐ₇₆₇ | P11 | H | F | P2 | H | H | H | CN | P23 | O |
| Lₐ₇₆₈ | P11 | H | P1 | F | H | H | H | CN | P23 | O |
| Lₐ₇₆₉ | P11 | H | P2 | F | H | H | H | CN | P23 | O |
| Lₐ₇₇₀ | P11 | H | P1 | P1 | H | H | H | CN | P23 | O |
| Lₐ₇₇₁ | P11 | H | P2 | P2 | H | H | H | CN | P23 | O |
| Lₐ₇₇₂ | P11 | H | P1 | H | H | H | H | CN | P24 | O |
| Lₐ₇₇₃ | P11 | H | P2 | H | H | H | H | CN | P24 | O |
| Lₐ₇₇₄ | P11 | H | P3 | H | H | H | H | CN | P24 | O |
| Lₐ₇₇₅ | P11 | H | P4 | H | H | H | H | CN | P24 | O |
| Lₐ₇₇₆ | P11 | H | P5 | H | H | H | H | CN | P24 | O |
| Lₐ₇₇₇ | P11 | H | P6 | H | H | H | H | CN | P24 | O |
| Lₐ₇₇₈ | P11 | H | P7 | H | H | H | H | CN | P24 | O |
| Lₐ₇₇₉ | P11 | H | P8 | H | H | H | H | CN | P24 | O |
| Lₐ₇₈₀ | P11 | H | P9 | H | H | H | H | CN | P24 | O |
| Lₐ₇₈₁ | P11 | H | P10 | H | H | H | H | CN | P24 | O |
| Lₐ₇₈₂ | P11 | H | P11 | H | H | H | H | CN | P24 | O |
| Lₐ₇₈₃ | P11 | H | P12 | H | H | H | H | CN | P24 | O |
| Lₐ₇₈₄ | P11 | H | P15 | H | H | H | H | CN | P24 | O |
| Lₐ₇₈₅ | P11 | H | P17 | H | H | H | H | CN | P24 | O |
| Lₐ₇₈₆ | P11 | H | H | P1 | H | H | H | CN | P24 | O |
| Lₐ₇₈₇ | P11 | H | H | P2 | H | H | H | CN | P24 | O |
| Lₐ₇₈₈ | P11 | H | H | P3 | H | H | H | CN | P24 | O |
| Lₐ₇₈₉ | P11 | H | H | P4 | H | H | H | CN | P24 | O |
| Lₐ₇₉₀ | P11 | H | H | P5 | H | H | H | CN | P24 | O |
| Lₐ₇₉₁ | P11 | H | H | P6 | H | H | H | CN | P24 | O |
| Lₐ₇₉₂ | P11 | H | H | P7 | H | H | H | CN | P24 | O |
| Lₐ₇₉₃ | P11 | H | H | P8 | H | H | H | CN | P24 | O |
| Lₐ₇₉₄ | P11 | H | H | P9 | H | H | H | CN | P24 | O |
| Lₐ₇₉₅ | P11 | H | H | P10 | H | H | H | CN | P24 | O |
| Lₐ₇₉₆ | P11 | H | H | P11 | H | H | H | CN | P24 | O |
| Lₐ₇₉₇ | P11 | H | H | P12 | H | H | H | CN | P24 | O |
| Lₐ₇₉₈ | P11 | H | H | P15 | H | H | H | CN | P24 | O |
| Lₐ₇₉₉ | P11 | H | H | P17 | H | H | H | CN | P24 | O |
| Lₐ₈₀₀ | P11 | H | F | H | H | H | H | CN | P24 | O |
| Lₐ₈₀₁ | P11 | H | H | F | H | H | H | CN | P24 | O |
| Lₐ₈₀₂ | P11 | H | F | P1 | H | H | H | CN | P24 | O |
| Lₐ₈₀₃ | P11 | H | F | P2 | H | H | H | CN | P24 | O |
| Lₐ₈₀₄ | P11 | H | P1 | F | H | H | H | CN | P24 | O |
| Lₐ₈₀₅ | P11 | H | P2 | F | H | H | H | CN | P24 | O |
| Lₐ₈₀₆ | P11 | H | P1 | P1 | H | H | H | CN | P24 | O |
| Lₐ₈₀₇ | P11 | H | P2 | P2 | H | H | H | CN | P24 | O |
| Lₐ₈₀₈ | P11 | H | P1 | H | H | H | H | CN | P56 | O |
| Lₐ₈₀₉ | P11 | H | P2 | H | H | H | H | CN | P56 | O |
| Lₐ₈₁₀ | P11 | H | P3 | H | H | H | H | CN | P56 | O |
| Lₐ₈₁₁ | P11 | H | P4 | H | H | H | H | CN | P56 | O |
| Lₐ₈₁₂ | P11 | H | P5 | H | H | H | H | CN | P56 | O |
| Lₐ₈₁₃ | P11 | H | P6 | H | H | H | H | CN | P56 | O |
| Lₐ₈₁₄ | P11 | H | P7 | H | H | H | H | CN | P56 | O |
| Lₐ₈₁₅ | P11 | H | P8 | H | H | H | H | CN | P56 | O |
| Lₐ₈₁₆ | P11 | H | P9 | H | H | H | H | CN | P56 | O |
| Lₐ₈₁₇ | P11 | H | P10 | H | H | H | H | CN | P56 | O |
| Lₐ₈₁₈ | P11 | H | P11 | H | H | H | H | CN | P56 | O |
| Lₐ₈₁₉ | P11 | H | P12 | H | H | H | H | CN | P56 | O |
| Lₐ₈₂₀ | P11 | H | P15 | H | H | H | H | CN | P56 | O |
| Lₐ₈₂₁ | P11 | H | P17 | H | H | H | H | CN | P56 | O |
| Lₐ₈₂₂ | P11 | H | H | P1 | H | H | H | CN | P56 | O |
| Lₐ₈₂₃ | P11 | H | H | P2 | H | H | H | CN | P56 | O |
| Lₐ₈₂₄ | P11 | H | H | P3 | H | H | H | CN | P56 | O |
| Lₐ₈₂₅ | P11 | H | H | P4 | H | H | H | CN | P56 | O |
| Lₐ₈₂₆ | P11 | H | H | P5 | H | H | H | CN | P56 | O |
| Lₐ₈₂₇ | P11 | H | H | P6 | H | H | H | CN | P56 | O |
| Lₐ₈₂₈ | P11 | H | H | P7 | H | H | H | CN | P56 | O |
| Lₐ₈₂₉ | P11 | H | H | P8 | H | H | H | CN | P56 | O |
| Lₐ₈₃₀ | P11 | H | H | P9 | H | H | H | CN | P56 | O |
| Lₐ₈₃₁ | P11 | H | H | P10 | H | H | H | CN | P56 | O |
| Lₐ₈₃₂ | P11 | H | H | P11 | H | H | H | CN | P56 | O |
| Lₐ₈₃₃ | P11 | H | H | P12 | H | H | H | CN | P56 | O |
| Lₐ₈₃₄ | P11 | H | H | P15 | H | H | H | CN | P56 | O |
| Lₐ₈₃₅ | P11 | H | H | P17 | H | H | H | CN | P56 | O |
| Lₐ₈₃₆ | P11 | H | F | H | H | H | H | CN | P56 | O |
| Lₐ₈₃₇ | P11 | H | H | F | H | H | H | CN | P56 | O |
| Lₐ₈₃₈ | P11 | H | F | P1 | H | H | H | CN | P56 | O |
| Lₐ₈₃₉ | P11 | H | F | P2 | H | H | H | CN | P56 | O |
| Lₐ₈₄₀ | P11 | H | P1 | F | H | H | H | CN | P56 | O |
| Lₐ₈₄₁ | P11 | H | P2 | F | H | H | H | CN | P56 | O |
| Lₐ₈₄₂ | P11 | H | P1 | P1 | H | H | H | CN | P56 | O |
| Lₐ₈₄₃ | P11 | H | P2 | P2 | H | H | H | CN | P56 | O |
| Lₐ₈₄₄ | P11 | H | P1 | H | H | H | H | CN | P73 | O |
| Lₐ₈₄₅ | P11 | H | P2 | H | H | H | H | CN | P73 | O |
| Lₐ₈₄₆ | P11 | H | P3 | H | H | H | H | CN | P73 | O |
| Lₐ₈₄₇ | P11 | H | P4 | H | H | H | H | CN | P73 | O |
| Lₐ₈₄₈ | P11 | H | P5 | H | H | H | H | CN | P73 | O |
| Lₐ₈₄₉ | P11 | H | P6 | H | H | H | H | CN | P73 | O |
| Lₐ₈₅₀ | P11 | H | P7 | H | H | H | H | CN | P73 | O |
| Lₐ₈₅₁ | P11 | H | P8 | H | H | H | H | CN | P73 | O |
| Lₐ₈₅₂ | P11 | H | P9 | H | H | H | H | CN | P73 | O |
| Lₐ₈₅₃ | P11 | H | P10 | H | H | H | H | CN | P73 | O |
| Lₐ₈₅₄ | P11 | H | P11 | H | H | H | H | CN | P73 | O |
| Lₐ₈₅₅ | P11 | H | P12 | H | H | H | H | CN | P73 | O |
| Lₐ₈₅₆ | P11 | H | P15 | H | H | H | H | CN | P73 | O |
| Lₐ₈₅₇ | P11 | H | P17 | P1 | H | H | H | CN | P73 | O |
| Lₐ₈₅₈ | P11 | H | H | P1 | H | H | H | CN | P73 | O |
| Lₐ₈₅₉ | P11 | H | H | P2 | H | H | H | CN | P73 | O |
| Lₐ₈₆₀ | P11 | H | H | P3 | H | H | H | CN | P73 | O |
| Lₐ₈₆₁ | P11 | H | H | P4 | H | H | H | CN | P73 | O |
| Lₐ₈₆₂ | P11 | H | H | P5 | H | H | H | CN | P73 | O |
| Lₐ₈₆₃ | P11 | H | H | P6 | H | H | H | CN | P73 | O |
| Lₐ₈₆₄ | P11 | H | H | P7 | H | H | H | CN | P73 | O |
| Lₐ₈₆₅ | P11 | H | H | P8 | H | H | H | CN | P73 | O |
| Lₐ₈₆₆ | P11 | H | H | P9 | H | H | H | CN | P73 | O |
| Lₐ₈₆₇ | P11 | H | H | P10 | H | H | H | CN | P73 | O |
| Lₐ₈₆₈ | P11 | H | H | P11 | H | H | H | CN | P73 | O |
| Lₐ₈₆₉ | P11 | H | H | P12 | H | H | H | CN | P73 | O |
| Lₐ₈₇₀ | P11 | H | H | P15 | H | H | H | CN | P73 | O |
| Lₐ₈₇₁ | P11 | H | H | P17 | H | H | H | CN | P73 | O |
| Lₐ₈₇₂ | P11 | H | F | P2 | H | H | H | CN | P73 | O |
| Lₐ₈₇₃ | P11 | H | H | F | H | H | H | CN | P73 | O |
| Lₐ₈₇₄ | P11 | H | F | P1 | H | H | H | CN | P73 | O |
| Lₐ₈₇₅ | P11 | H | F | P2 | H | H | H | CN | P73 | O |
| Lₐ₈₇₆ | P11 | H | P1 | F | H | H | H | CN | P73 | O |
| Lₐ₈₇₇ | P11 | H | P2 | F | H | H | H | CN | P73 | O |
| Lₐ₈₇₈ | P11 | H | P1 | P1 | H | H | H | CN | P73 | O |
| Lₐ₈₇₉ | P11 | H | P2 | P1 | H | H | H | CN | P73 | O |
| Lₐ₈₈₀ | P11 | H | P1 | H | H | H | H | CN | P74 | O |
| Lₐ₈₈₁ | P11 | H | P2 | H | H | H | H | CN | P74 | O |
| Lₐ₈₈₂ | P11 | H | P3 | H | H | H | H | CN | P74 | O |
| Lₐ₈₈₃ | P11 | H | P4 | H | H | H | H | CN | P74 | O |
| Lₐ₈₈₄ | P11 | H | P5 | H | H | H | H | CN | P74 | O |
| Lₐ₈₈₅ | P11 | H | P6 | H | H | H | H | CN | P74 | O |
| Lₐ₈₈₆ | P11 | H | P7 | H | H | H | H | CN | P74 | O |
| Lₐ₈₈₇ | P11 | H | P8 | H | H | H | H | CN | P74 | O |
| Lₐ₈₈₈ | P11 | H | P9 | H | H | H | H | CN | P74 | O |
| Lₐ₈₈₉ | P11 | H | P10 | H | H | H | H | CN | P74 | O |
| Lₐ₈₉₀ | P11 | H | P11 | H | H | H | H | CN | P74 | O |
| Lₐ₈₉₁ | P11 | H | P12 | H | H | H | H | CN | P74 | O |
| Lₐ₈₉₂ | P11 | H | P15 | H | H | H | H | CN | P74 | O |
| Lₐ₈₉₃ | P11 | H | P17 | P2 | H | H | H | CN | P74 | O |
| Lₐ₈₉₄ | P11 | H | H | P1 | H | H | H | CN | P74 | O |
| Lₐ₈₉₅ | P11 | H | H | P2 | H | H | H | CN | P74 | O |
| Lₐ₈₉₆ | P11 | H | H | P3 | H | H | H | CN | P74 | O |
| Lₐ₈₉₇ | P11 | H | H | P4 | H | H | H | CN | P74 | O |
| Lₐ₈₉₈ | P11 | H | H | P5 | H | H | H | CN | P74 | O |
| Lₐ₈₉₉ | P11 | H | H | P6 | H | H | H | CN | P74 | O |
| Lₐ₉₀₀ | P11 | H | H | P7 | H | H | H | CN | P74 | O |
| Lₐ₉₀₁ | P11 | H | H | P8 | H | H | H | CN | P74 | O |
| Lₐ₉₀₂ | P11 | H | H | P9 | H | H | H | CN | P74 | O |
| Lₐ₉₀₃ | P11 | H | H | P10 | H | H | H | CN | P74 | O |
| Lₐ₉₀₄ | P11 | H | H | P11 | H | H | H | CN | P74 | O |
| Lₐ₉₀₅ | P11 | H | H | P12 | H | H | H | CN | P74 | O |
| Lₐ₉₀₆ | P11 | H | H | P15 | H | H | H | CN | P74 | O |
| Lₐ₉₀₇ | P11 | H | H | P17 | H | H | H | CN | P74 | O |
| Lₐ₉₀₈ | P11 | H | F | H | H | H | H | CN | P74 | O |
| Lₐ₉₀₉ | P11 | H | H | F | H | H | H | CN | P74 | O |
| Lₐ₉₁₀ | P11 | H | F | P1 | H | H | H | CN | P74 | O |
| Lₐ₉₁₁ | P11 | H | F | P1 | H | H | H | CN | P74 | O |
| Lₐ₉₁₂ | P11 | H | P1 | F | H | H | H | CN | P74 | O |
| Lₐ₉₁₃ | P11 | H | P2 | F | H | H | H | CN | P74 | O |
| Lₐ₉₁₄ | P11 | H | P1 | P2 | H | H | H | CN | P74 | O |
| Lₐ₉₁₅ | P11 | H | P2 | P1 | H | H | H | CN | P74 | O |
| Lₐ₉₁₆ | P11 | H | P1 | H | H | H | H | CN | P79 | O |
| Lₐ₉₁₇ | P11 | H | P2 | H | H | H | H | CN | P79 | O |
| Lₐ₉₁₈ | P11 | H | P3 | H | H | H | H | CN | P79 | O |
| Lₐ₉₁₉ | P11 | H | P4 | H | H | H | H | CN | P79 | O |
| Lₐ₉₂₀ | P11 | H | P5 | H | H | H | H | CN | P79 | O |
| Lₐ₉₂₁ | P11 | H | P6 | H | H | H | H | CN | P79 | O |
| Lₐ₉₂₂ | P11 | H | P7 | H | H | H | H | CN | P79 | O |
| Lₐ₉₂₃ | P11 | H | P8 | H | H | H | H | CN | P79 | O |
| Lₐ₉₂₄ | P11 | H | P9 | H | H | H | H | CN | P79 | O |
| Lₐ₉₂₅ | P11 | H | P10 | H | H | H | H | CN | P79 | O |
| Lₐ₉₂₆ | P11 | H | P11 | H | H | H | H | CN | P79 | O |
| Lₐ₉₂₇ | P11 | H | P12 | H | H | H | H | CN | P79 | O |
| Lₐ₉₂₈ | P11 | H | P15 | H | H | H | H | CN | P79 | O |
| Lₐ₉₂₉ | P11 | H | P17 | P1 | H | H | H | CN | P79 | O |
| Lₐ₉₃₀ | P11 | H | H | P1 | H | H | H | CN | P79 | O |
| Lₐ₉₃₁ | P11 | H | H | P2 | H | H | H | CN | P79 | O |
| Lₐ₉₃₂ | P11 | H | H | P3 | H | H | H | CN | P79 | O |
| Lₐ₉₃₃ | P11 | H | H | P4 | H | H | H | CN | P79 | O |
| Lₐ₉₃₄ | P11 | H | H | P5 | H | H | H | CN | P79 | O |
| Lₐ₉₃₅ | P11 | H | H | P6 | H | H | H | CN | P79 | O |
| Lₐ₉₃₆ | P11 | H | H | P7 | H | H | H | CN | P79 | O |
| Lₐ₉₃₇ | P11 | H | H | P8 | H | H | H | CN | P79 | O |
| Lₐ₉₃₈ | P11 | H | H | P9 | H | H | H | CN | P79 | O |
| Lₐ₉₃₉ | P11 | H | H | P10 | H | H | H | CN | P79 | O |
| Lₐ₉₄₀ | P11 | H | H | P11 | H | H | H | CN | P79 | O |
| Lₐ₉₄₁ | P11 | H | H | P12 | H | H | H | CN | P79 | O |
| Lₐ₉₄₂ | P11 | H | H | P15 | H | H | H | CN | P79 | O |
| Lₐ₉₄₃ | P11 | H | H | P17 | H | H | H | CN | P79 | O |
| Lₐ₉₄₄ | P11 | H | F | H | H | H | H | CN | P79 | O |
| Lₐ₉₄₅ | P11 | H | H | F | H | H | H | CN | P79 | O |
| Lₐ₉₄₆ | P11 | H | F | P1 | H | H | H | CN | P79 | O |
| Lₐ₉₄₇ | P11 | H | F | P2 | H | H | H | CN | P79 | O |
| Lₐ₉₄₈ | P11 | H | P1 | F | H | H | H | CN | P79 | O |
| Lₐ₉₄₉ | P11 | H | P2 | F | H | H | H | CN | P79 | O |
| Lₐ₉₅₀ | P11 | H | P1 | P1 | H | H | H | CN | P79 | O |
| Lₐ₉₅₁ | P11 | H | P2 | P2 | H | H | H | CN | P79 | O |
| Lₐ₉₅₂ | P11 | H | P1 | H | H | H | H | CN | P80 | O |
| Lₐ₉₅₃ | P11 | H | P2 | H | H | H | H | CN | P80 | O |
| Lₐ₉₅₄ | P11 | H | P3 | H | H | H | H | CN | P80 | O |
| Lₐ₉₅₅ | P11 | H | P4 | H | H | H | H | CN | P80 | O |
| Lₐ₉₅₆ | P11 | H | P5 | H | H | H | H | CN | P80 | O |
| Lₐ₉₅₇ | P11 | H | P6 | H | H | H | H | CN | P80 | O |
| Lₐ₉₅₈ | P11 | H | P7 | H | H | H | H | CN | P80 | O |
| Lₐ₉₅₉ | P11 | H | P8 | H | H | H | H | CN | P80 | O |
| Lₐ₉₆₀ | P11 | H | P9 | H | H | H | H | CN | P80 | O |
| Lₐ₉₆₁ | P11 | H | P10 | H | H | H | H | CN | P80 | O |
| Lₐ₉₆₂ | P11 | H | P11 | H | H | H | H | CN | P80 | O |
| Lₐ₉₆₃ | P11 | H | P12 | H | H | H | H | CN | P80 | O |
| Lₐ₉₆₄ | P11 | H | P15 | H | H | H | H | CN | P80 | O |
| Lₐ₉₆₅ | P11 | H | P17 | P1 | H | H | H | CN | P80 | O |
| Lₐ₉₆₆ | P11 | H | H | P1 | H | H | H | CN | P80 | O |
| Lₐ₉₆₇ | P11 | H | H | P2 | H | H | H | CN | P80 | O |
| Lₐ₉₆₈ | P11 | H | H | P3 | H | H | H | CN | P80 | O |
| Lₐ₉₆₉ | P11 | H | H | P4 | H | H | H | CN | P80 | O |
| Lₐ₉₇₀ | P11 | H | H | P5 | H | H | H | CN | P80 | O |
| Lₐ₉₇₁ | P11 | H | H | P6 | H | H | H | CN | P80 | O |
| Lₐ₉₇₂ | P11 | H | H | P7 | H | H | H | CN | P80 | O |
| Lₐ₉₇₃ | P11 | H | H | P8 | H | H | H | CN | P80 | O |
| Lₐ₉₇₄ | P11 | H | H | P9 | H | H | H | CN | P80 | O |
| Lₐ₉₇₅ | P11 | H | H | P10 | H | H | H | CN | P80 | O |
| Lₐ₉₇₆ | P11 | H | H | P11 | H | H | H | CN | P80 | O |
| Lₐ₉₇₇ | P11 | H | H | P12 | H | H | H | CN | P80 | O |
| Lₐ₉₇₈ | P11 | H | H | P15 | H | H | H | CN | P80 | O |
| Lₐ₉₇₉ | P11 | H | H | P17 | H | H | H | CN | P80 | O |
| Lₐ₉₈₀ | P11 | H | F | H | H | H | H | CN | P80 | O |
| Lₐ₉₈₁ | P11 | H | H | F | H | H | H | CN | P80 | O |
| Lₐ₉₈₂ | P11 | H | F | P1 | H | H | H | CN | P80 | O |
| Lₐ₉₈₃ | P11 | H | F | P2 | H | H | H | CN | P80 | O |
| Lₐ₉₈₄ | P11 | H | P1 | F | H | H | H | CN | P80 | O |
| Lₐ₉₈₅ | P11 | H | P2 | F | H | H | H | CN | P80 | O |
| Lₐ₉₈₆ | P11 | H | P1 | P1 | H | H | H | CN | P80 | O |
| Lₐ₉₈₇ | P11 | H | P2 | P2 | H | H | H | CN | P80 | O |
| Lₐ₉₈₈ | P11 | H | P1 | H | H | H | H | CN | P89 | O |
| Lₐ₉₈₉ | P11 | H | P2 | H | H | H | H | CN | P89 | O |
| Lₐ₉₉₀ | P11 | H | P3 | H | H | H | H | CN | P89 | O |
| Lₐ₉₉₁ | P11 | H | P4 | H | H | H | H | CN | P89 | O |
| Lₐ₉₉₂ | P11 | H | P5 | H | H | H | H | CN | P89 | O |
| Lₐ₉₉₃ | P11 | H | P6 | H | H | H | H | CN | P89 | O |
| Lₐ₉₉₄ | P11 | H | P7 | H | H | H | H | CN | P89 | O |
| Lₐ₉₉₅ | P11 | H | P8 | H | H | H | H | CN | P89 | O |
| Lₐ₉₉₆ | P11 | H | P9 | H | H | H | H | CN | P89 | O |
| Lₐ₉₉₇ | P11 | H | P10 | H | H | H | H | CN | P89 | O |
| Lₐ₉₉₈ | P11 | H | P11 | H | H | H | H | CN | P89 | O |
| Lₐ₉₉₉ | P11 | H | P12 | H | H | H | H | CN | P89 | O |
| Lₐ₁₀₀₀ | P11 | H | P15 | H | H | H | H | CN | P89 | O |
| Lₐ₁₀₀₁ | P11 | H | P17 | H | H | H | H | CN | P89 | O |
| Lₐ₁₀₀₂ | P11 | H | H | P1 | H | H | H | CN | P89 | O |
| Lₐ₁₀₀₃ | P11 | H | H | P2 | H | H | H | CN | P89 | O |
| Lₐ₁₀₀₄ | P11 | H | H | P3 | H | H | H | CN | P89 | O |
| Lₐ₁₀₀₅ | P11 | H | H | P4 | H | H | H | CN | P89 | O |
| Lₐ₁₀₀₆ | P11 | H | H | P5 | H | H | H | CN | P89 | O |
| Lₐ₁₀₀₇ | P11 | H | H | P6 | H | H | H | CN | P89 | O |
| Lₐ₁₀₀₈ | P11 | H | H | P7 | H | H | H | CN | P89 | O |
| Lₐ₁₀₀₉ | P11 | H | H | P8 | H | H | H | CN | P89 | O |
| Lₐ₁₀₁₀ | P11 | H | H | P9 | H | H | H | CN | P89 | O |
| Lₐ₁₀₁₁ | P11 | H | H | P10 | H | H | H | CN | P89 | O |
| Lₐ₁₀₁₂ | P11 | H | H | P11 | H | H | H | CN | P89 | O |
| Lₐ₁₀₁₃ | P11 | H | H | P12 | H | H | H | CN | P89 | O |
| Lₐ₁₀₁₄ | P11 | H | H | P15 | H | H | H | CN | P89 | O |
| Lₐ₁₀₁₅ | P11 | H | H | P17 | H | H | H | CN | P89 | O |
| Lₐ₁₀₁₆ | P11 | H | F | H | H | H | H | CN | P89 | O |
| Lₐ₁₀₁₇ | P11 | H | H | F | H | H | H | CN | P89 | O |
| Lₐ₁₀₁₈ | P11 | H | F | P1 | H | H | H | CN | P89 | O |
| Lₐ₁₀₁₉ | P11 | H | F | P2 | H | H | H | CN | P89 | O |
| Lₐ₁₀₂₀ | P11 | H | P1 | F | H | H | H | CN | P89 | O |
| Lₐ₁₀₂₁ | P11 | H | P2 | F | H | H | H | CN | P89 | O |
| Lₐ₁₀₂₂ | P11 | H | P1 | P1 | H | H | H | CN | P89 | O |
| Lₐ₁₀₂₃ | P11 | H | P2 | P2 | H | H | H | CN | P89 | O |
| Lₐ₁₀₂₄ | P10 | H | H | H | H | H | H | CN | H | O |
| Lₐ₁₀₂₅ | P10 | H | P1 | H | H | H | H | CN | H | O |
| Lₐ₁₀₂₆ | P10 | H | P2 | H | H | H | H | CN | H | O |
| Lₐ₁₀₂₇ | P10 | H | P3 | H | H | H | H | CN | H | O |
| Lₐ₁₀₂₈ | P10 | H | P4 | H | H | H | H | CN | H | O |
| Lₐ₁₀₂₉ | P10 | H | P5 | H | H | H | H | CN | H | O |
| Lₐ₁₀₃₀ | P10 | H | P6 | H | H | H | H | CN | H | O |
| Lₐ₁₀₃₁ | P10 | H | P7 | H | H | H | H | CN | H | O |
| Lₐ₁₀₃₂ | P10 | H | P8 | H | H | H | H | CN | H | O |
| Lₐ₁₀₃₃ | P10 | H | P9 | H | H | H | H | CN | H | O |
| Lₐ₁₀₃₄ | P10 | H | P10 | H | H | H | H | CN | H | O |
| Lₐ₁₀₃₅ | P10 | H | P11 | H | H | H | H | CN | H | O |
| Lₐ₁₀₃₆ | P10 | H | P12 | H | H | H | H | CN | H | O |
| Lₐ₁₀₃₇ | P10 | H | P13 | H | H | H | H | CN | H | O |
| Lₐ₁₀₃₈ | P10 | H | P14 | H | H | H | H | CN | H | O |
| Lₐ₁₀₃₉ | P10 | H | P15 | H | H | H | H | CN | H | O |
| Lₐ₁₀₄₀ | P10 | H | P16 | H | H | H | H | CN | H | O |
| Lₐ₁₀₄₁ | P10 | H | P17 | H | H | H | H | CN | H | O |
| Lₐ₁₀₄₂ | P10 | H | P18 | H | H | H | H | CN | H | O |
| Lₐ₁₀₄₃ | P10 | H | P19 | H | H | H | H | CN | H | O |
| Lₐ₁₀₄₄ | P10 | H | P20 | H | H | H | H | CN | H | O |
| Lₐ₁₀₄₅ | P10 | H | P21 | H | H | H | H | CN | H | O |
| Lₐ₁₀₄₆ | P10 | H | P22 | H | H | H | H | CN | H | O |
| Lₐ₁₀₄₇ | P10 | H | P23 | H | H | H | H | CN | H | O |
| Lₐ₁₀₄₈ | P10 | H | P24 | H | H | H | H | CN | H | O |
| Lₐ₁₀₄₉ | P10 | H | P25 | H | H | H | H | CN | H | O |
| Lₐ₁₀₅₀ | P10 | H | P26 | H | H | H | H | CN | H | O |
| Lₐ₁₀₅₁ | P10 | H | P27 | H | H | H | H | CN | H | O |
| Lₐ₁₀₅₂ | P10 | H | P28 | H | H | H | H | CN | H | O |
| Lₐ₁₀₅₃ | P10 | H | P29 | H | H | H | H | CN | H | O |
| Lₐ₁₀₅₄ | P10 | H | P30 | H | H | H | H | CN | H | O |
| Lₐ₁₀₅₅ | P10 | H | P31 | H | H | H | H | CN | H | O |
| Lₐ₁₀₅₆ | P10 | H | P32 | H | H | H | H | CN | H | O |
| Lₐ₁₀₅₇ | P10 | H | P33 | H | H | H | H | CN | H | O |
| Lₐ₁₀₅₈ | P10 | H | P34 | H | H | H | H | CN | H | O |
| Lₐ₁₀₅₉ | P10 | H | H | P1 | H | H | H | CN | H | O |
| Lₐ₁₀₆₀ | P10 | H | H | P2 | H | H | H | CN | H | O |
| Lₐ₁₀₆₁ | P10 | H | H | P3 | H | H | H | CN | H | O |
| Lₐ₁₀₆₂ | P10 | H | H | P4 | H | H | H | CN | H | O |
| Lₐ₁₀₆₃ | P10 | H | H | P5 | H | H | H | CN | H | O |
| Lₐ₁₀₆₄ | P10 | H | H | P6 | H | H | H | CN | H | O |
| Lₐ₁₀₆₅ | P10 | H | H | P7 | H | H | H | CN | H | O |
| Lₐ₁₀₆₆ | P10 | H | H | P8 | H | H | H | CN | H | O |
| Lₐ₁₀₆₇ | P10 | H | H | P9 | H | H | H | CN | H | O |
| Lₐ₁₀₆₈ | P10 | H | H | P10 | H | H | H | CN | H | O |
| Lₐ₁₀₆₉ | P10 | H | H | P11 | H | H | H | CN | H | O |
| Lₐ₁₀₇₀ | P10 | H | H | P12 | H | H | H | CN | H | O |
| Lₐ₁₀₇₁ | P10 | H | H | P13 | H | H | H | CN | H | O |
| Lₐ₁₀₇₂ | P10 | H | H | P14 | H | H | H | CN | H | O |
| Lₐ₁₀₇₃ | P10 | H | H | P15 | H | H | H | CN | H | O |
| Lₐ₁₀₇₄ | P10 | H | H | P16 | H | H | H | CN | H | O |
| Lₐ₁₀₇₅ | P10 | H | H | P17 | H | H | H | CN | H | O |
| Lₐ₁₀₇₆ | P10 | H | H | P18 | H | H | H | CN | H | O |
| Lₐ₁₀₇₇ | P10 | H | H | P19 | H | H | H | CN | H | O |
| Lₐ₁₀₇₈ | P10 | H | H | P20 | H | H | H | CN | H | O |
| Lₐ₁₀₇₉ | P10 | H | H | P21 | H | H | H | CN | H | O |
| Lₐ₁₀₈₀ | P10 | H | H | P22 | H | H | H | CN | H | O |
| Lₐ₁₀₈₁ | P10 | H | H | P23 | H | H | H | CN | H | O |
| Lₐ₁₀₈₂ | P10 | H | H | P24 | H | H | H | CN | H | O |
| Lₐ₁₀₈₃ | P10 | H | H | P25 | H | H | H | CN | H | O |
| Lₐ₁₀₈₄ | P10 | H | H | P26 | H | H | H | CN | H | O |
| Lₐ₁₀₈₅ | P10 | H | H | P27 | H | H | H | CN | H | O |
| Lₐ₁₀₈₆ | P10 | H | H | P28 | H | H | H | CN | H | O |
| Lₐ₁₀₈₇ | P10 | H | H | P29 | H | H | H | CN | H | O |
| Lₐ₁₀₈₈ | P10 | H | H | P30 | H | H | H | CN | H | O |
| Lₐ₁₀₈₉ | P10 | H | H | P31 | H | H | H | CN | H | O |
| Lₐ₁₀₉₀ | P10 | H | H | P32 | H | H | H | CN | H | O |
| Lₐ₁₀₉₁ | P10 | H | H | P33 | H | H | H | CN | H | O |
| Lₐ₁₀₉₂ | P10 | H | H | P34 | H | H | H | CN | H | O |
| Lₐ₁₀₉₃ | P10 | H | P1 | P1 | H | H | H | CN | H | O |
| Lₐ₁₀₉₄ | P10 | H | P2 | P2 | H | H | H | CN | H | O |
| Lₐ₁₀₉₅ | P10 | H | F | H | H | H | H | CN | H | O |
| Lₐ₁₀₉₆ | P10 | H | H | F | H | H | H | CN | H | O |
| Lₐ₁₀₉₇ | P10 | H | F | P1 | H | H | H | CN | H | O |
| Lₐ₁₀₉₈ | P10 | H | F | P2 | H | H | H | CN | H | O |
| Lₐ₁₀₉₉ | P10 | H | P1 | F | H | H | H | CN | H | O |
| Lₐ₁₁₀₀ | P10 | H | P2 | F | H | H | H | CN | H | O |
| Lₐ₁₁₀₁ | P10 | H | H | H | H | H | H | CN | D | O |
| Lₐ₁₁₀₂ | P10 | H | P1 | H | H | H | H | CN | D | O |
| Lₐ₁₁₀₃ | P10 | H | P2 | H | H | H | H | CN | D | O |
| Lₐ₁₁₀₄ | P10 | H | P3 | H | H | H | H | CN | D | O |
| Lₐ₁₁₀₅ | P10 | H | P4 | H | H | H | H | CN | D | O |
| Lₐ₁₁₀₆ | P10 | H | P5 | H | H | H | H | CN | D | O |
| Lₐ₁₁₀₇ | P10 | H | P6 | H | H | H | H | CN | D | O |
| Lₐ₁₁₀₈ | P10 | H | P7 | H | H | H | H | CN | D | O |
| Lₐ₁₁₀₉ | P10 | H | P8 | H | H | H | H | CN | D | O |
| Lₐ₁₁₁₀ | P10 | H | P9 | H | H | H | H | CN | D | O |
| Lₐ₁₁₁₁ | P10 | H | P10 | H | H | H | H | CN | D | O |
| Lₐ₁₁₁₂ | P10 | H | P11 | H | H | H | H | CN | D | O |
| Lₐ₁₁₁₃ | P10 | H | P12 | H | H | H | H | CN | D | O |
| Lₐ₁₁₁₄ | P10 | H | P13 | H | H | H | H | CN | D | O |
| Lₐ₁₁₁₅ | P10 | H | P14 | H | H | H | H | CN | D | O |
| Lₐ₁₁₁₆ | P10 | H | P15 | H | H | H | H | CN | D | O |
| Lₐ₁₁₁₇ | P10 | H | P16 | H | H | H | H | CN | D | O |
| Lₐ₁₁₁₈ | P10 | H | P17 | H | H | H | H | CN | D | O |
| Lₐ₁₁₁₉ | P10 | H | P18 | H | H | H | H | CN | D | O |
| Lₐ₁₁₂₀ | P10 | H | P19 | H | H | H | H | CN | D | O |
| Lₐ₁₁₂₁ | P10 | H | P20 | H | H | H | H | CN | D | O |
| Lₐ₁₁₂₂ | P10 | H | P21 | H | H | H | H | CN | D | O |
| Lₐ₁₁₂₃ | P10 | H | P22 | H | H | H | H | CN | D | O |
| Lₐ₁₁₂₄ | P10 | H | P23 | H | H | H | H | CN | D | O |
| Lₐ₁₁₂₅ | P10 | H | P24 | H | H | H | H | CN | D | O |
| Lₐ₁₁₂₆ | P10 | H | P25 | H | H | H | H | CN | D | O |
| Lₐ₁₁₂₇ | P10 | H | P26 | H | H | H | H | CN | D | O |
| Lₐ₁₁₂₈ | P10 | H | P27 | H | H | H | H | CN | D | O |
| Lₐ₁₁₂₉ | P10 | H | P28 | H | H | H | H | CN | D | O |
| Lₐ₁₁₃₀ | P10 | H | P29 | H | H | H | H | CN | D | O |
| Lₐ₁₁₃₁ | P10 | H | P30 | H | H | H | H | CN | D | O |
| Lₐ₁₁₃₂ | P10 | H | P31 | H | H | H | H | CN | D | O |
| Lₐ₁₁₃₃ | P10 | H | P32 | H | H | H | H | CN | D | O |
| Lₐ₁₁₃₄ | P10 | H | P33 | H | H | H | H | CN | D | O |
| Lₐ₁₁₃₅ | P10 | H | P34 | H | H | H | H | CN | D | O |
| Lₐ₁₁₃₆ | P10 | H | H | P1 | H | H | H | CN | D | O |
| Lₐ₁₁₃₇ | P10 | H | H | P2 | H | H | H | CN | D | O |
| Lₐ₁₁₃₈ | P10 | H | H | P3 | H | H | H | CN | D | O |
| Lₐ₁₁₃₉ | P10 | H | H | P4 | H | H | H | CN | D | O |
| Lₐ₁₁₄₀ | P10 | H | H | P5 | H | H | H | CN | D | O |
| Lₐ₁₁₄₁ | P10 | H | H | P6 | H | H | H | CN | D | O |
| Lₐ₁₁₄₂ | P10 | H | H | P7 | H | H | H | CN | D | O |
| Lₐ₁₁₄₃ | P10 | H | H | P8 | H | H | H | CN | D | O |
| Lₐ₁₁₄₄ | P10 | H | H | P9 | H | H | H | CN | D | O |
| Lₐ₁₁₄₅ | P10 | H | H | P10 | H | H | H | CN | D | O |
| Lₐ₁₁₄₆ | P10 | H | H | P11 | H | H | H | CN | D | O |
| Lₐ₁₁₄₇ | P10 | H | H | P12 | H | H | H | CN | D | O |
| Lₐ₁₁₄₈ | P10 | H | H | P13 | H | H | H | CN | D | O |
| Lₐ₁₁₄₉ | P10 | H | H | P14 | H | H | H | CN | D | O |
| Lₐ₁₁₅₀ | P10 | H | H | P15 | H | H | H | CN | D | O |
| Lₐ₁₁₅₁ | P10 | H | H | P16 | H | H | H | CN | D | O |
| Lₐ₁₁₅₂ | P10 | H | H | P17 | H | H | H | CN | D | O |
| Lₐ₁₁₅₃ | P10 | H | H | P18 | H | H | H | CN | D | O |
| Lₐ₁₁₅₄ | P10 | H | H | P19 | H | H | H | CN | D | O |
| Lₐ₁₁₅₅ | P10 | H | H | P20 | H | H | H | CN | D | O |
| Lₐ₁₁₅₆ | P10 | H | H | P21 | H | H | H | CN | D | O |
| Lₐ₁₁₅₇ | P10 | H | H | P22 | H | H | H | CN | D | O |
| Lₐ₁₁₅₈ | P10 | H | H | P23 | H | H | H | CN | D | O |
| Lₐ₁₁₅₉ | P10 | H | H | P24 | H | H | H | CN | D | O |
| Lₐ₁₁₆₀ | P10 | H | H | P25 | H | H | H | CN | D | O |
| Lₐ₁₁₆₁ | P10 | H | H | P26 | H | H | H | CN | D | O |
| Lₐ₁₁₆₂ | P10 | H | H | P27 | H | H | H | CN | D | O |
| Lₐ₁₁₆₃ | P10 | H | H | P28 | H | H | H | CN | D | O |
| Lₐ₁₁₆₄ | P10 | H | H | P29 | H | H | H | CN | D | O |
| Lₐ₁₁₆₅ | P10 | H | H | P30 | H | H | H | CN | D | O |
| Lₐ₁₁₆₆ | P10 | H | H | P31 | H | H | H | CN | D | O |
| Lₐ₁₁₆₇ | P10 | H | H | P32 | H | H | H | CN | D | O |
| Lₐ₁₁₆₈ | P10 | H | H | P33 | H | H | H | CN | D | O |
| Lₐ₁₁₆₉ | P10 | H | H | P34 | H | H | H | CN | D | O |
| Lₐ₁₁₇₀ | P10 | H | P1 | P1 | H | H | H | CN | D | O |
| Lₐ₁₁₇₁ | P10 | H | P2 | P2 | H | H | H | CN | D | O |
| Lₐ₁₁₇₂ | P10 | H | F | H | H | H | H | CN | D | O |
| Lₐ₁₁₇₃ | P10 | H | H | F | H | H | H | CN | D | O |
| Lₐ₁₁₇₄ | P10 | H | F | P1 | H | H | H | CN | D | O |
| Lₐ₁₁₇₅ | P10 | H | F | P2 | H | H | H | CN | D | O |
| Lₐ₁₁₇₆ | P10 | H | P1 | F | H | H | H | CN | D | O |
| Lₐ₁₁₇₇ | P10 | H | P2 | F | H | H | H | CN | D | O |
| Lₐ₁₁₇₈ | P10 | D | H | P1 | H | H | H | CN | H | O |
| Lₐ₁₁₇₉ | P10 | H | H | P2 | D | H | H | CN | H | O |
| Lₐ₁₁₈₀ | P10 | H | H | H | H | H | H | CN | P23 | O |
| Lₐ₁₁₈₁ | P10 | H | H | H | H | H | H | CN | P24 | O |
| Lₐ₁₁₈₂ | P10 | H | H | H | H | H | H | CN | P25 | O |
| Lₐ₁₁₈₃ | P10 | H | H | H | H | H | H | CN | P26 | O |
| Lₐ₁₁₈₄ | P10 | H | H | H | H | H | H | CN | P27 | O |
| Lₐ₁₁₈₅ | P10 | H | H | H | H | H | H | CN | P28 | O |
| Lₐ₁₁₈₆ | P10 | H | H | H | H | H | H | CN | P29 | O |
| Lₐ₁₁₈₇ | P10 | H | H | H | H | H | H | CN | P30 | O |
| Lₐ₁₁₈₈ | P10 | H | H | H | H | H | H | CN | P31 | O |
| Lₐ₁₁₈₉ | P10 | H | H | H | H | H | H | CN | P32 | O |
| Lₐ₁₁₉₀ | P10 | H | H | H | H | H | H | CN | P33 | O |
| Lₐ₁₁₉₁ | P10 | H | H | H | H | H | H | CN | P34 | O |
| Lₐ₁₁₉₂ | P10 | H | H | H | H | H | H | CN | P35 | O |
| Lₐ₁₁₉₃ | P10 | H | H | H | H | H | H | CN | P36 | O |
| Lₐ₁₁₉₄ | P10 | H | H | H | H | H | H | CN | P37 | O |
| Lₐ₁₁₉₅ | P10 | H | H | H | H | H | H | CN | P38 | O |
| Lₐ₁₁₉₆ | P10 | H | H | H | H | H | H | CN | P39 | O |
| Lₐ₁₁₉₇ | P10 | H | H | H | H | H | H | CN | P40 | O |
| Lₐ₁₁₉₈ | P10 | H | H | H | H | H | H | CN | P41 | O |
| Lₐ₁₁₉₉ | P10 | H | H | H | H | H | H | CN | P42 | O |
| Lₐ₁₂₀₀ | P10 | H | H | H | H | H | H | CN | P43 | O |
| Lₐ₁₂₀₁ | P10 | H | H | H | H | H | H | CN | P44 | O |
| Lₐ₁₂₀₂ | P10 | H | H | H | H | H | H | CN | P45 | O |
| Lₐ₁₂₀₃ | P10 | H | H | H | H | H | H | CN | P46 | O |
| Lₐ₁₂₀₄ | P10 | H | H | H | H | H | H | CN | P47 | O |
| Lₐ₁₂₀₅ | P10 | H | H | H | H | H | H | CN | P48 | O |
| Lₐ₁₂₀₆ | P10 | H | H | H | H | H | H | CN | P49 | O |
| Lₐ₁₂₀₇ | P10 | H | H | H | H | H | H | CN | P50 | O |
| Lₐ₁₂₀₈ | P10 | H | H | H | H | H | H | CN | P51 | O |
| Lₐ₁₂₀₉ | P10 | H | H | H | H | H | H | CN | P52 | O |
| Lₐ₁₂₁₀ | P10 | H | H | H | H | H | H | CN | P53 | O |
| Lₐ₁₂₁₁ | P10 | H | H | H | H | H | H | CN | P54 | O |
| Lₐ₁₂₁₂ | P10 | H | H | H | H | H | H | CN | P55 | O |
| Lₐ₁₂₁₃ | P10 | H | H | H | H | H | H | CN | P56 | O |
| Lₐ₁₂₁₄ | P10 | H | H | H | H | H | H | CN | P57 | O |
| Lₐ₁₂₁₅ | P10 | H | H | H | H | H | H | CN | P58 | O |
| Lₐ₁₂₁₆ | P10 | H | H | H | H | H | H | CN | P59 | O |
| Lₐ₁₂₁₇ | P10 | H | H | H | H | H | H | CN | P60 | O |
| Lₐ₁₂₁₈ | P10 | H | H | H | H | H | H | CN | P61 | O |
| Lₐ₁₂₁₉ | P10 | H | H | H | H | H | H | CN | P62 | O |
| Lₐ₁₂₂₀ | P10 | H | H | H | H | H | H | CN | P63 | O |
| Lₐ₁₂₂₁ | P10 | H | H | H | H | H | H | CN | P64 | O |
| Lₐ₁₂₂₂ | P10 | H | H | H | H | H | H | CN | P65 | O |
| Lₐ₁₂₂₃ | P10 | H | H | H | H | H | H | CN | P66 | O |
| Lₐ₁₂₂₄ | P10 | H | H | H | H | H | H | CN | P67 | O |
| Lₐ₁₂₂₅ | P10 | H | H | H | H | H | H | CN | P68 | O |
| Lₐ₁₂₂₆ | P10 | H | H | H | H | H | H | CN | P69 | O |
| Lₐ₁₂₂₇ | P10 | H | H | H | H | H | H | CN | P70 | O |
| Lₐ₁₂₂₈ | P10 | H | H | H | H | H | H | CN | P71 | O |
| Lₐ₁₂₂₉ | P10 | H | H | H | H | H | H | CN | P72 | O |
| Lₐ₁₂₃₀ | P10 | H | H | H | H | H | H | CN | P73 | O |
| Lₐ₁₂₃₁ | P10 | H | H | H | H | H | H | CN | P74 | O |
| Lₐ₁₂₃₂ | P10 | H | H | H | H | H | H | CN | P75 | O |
| Lₐ₁₂₃₃ | P10 | H | H | H | H | H | H | CN | P76 | O |
| Lₐ₁₂₃₄ | P10 | H | H | H | H | H | H | CN | P77 | O |
| Lₐ₁₂₃₅ | P10 | H | H | H | H | H | H | CN | P78 | O |
| Lₐ₁₂₃₆ | P10 | H | H | H | H | H | H | CN | P79 | O |
| Lₐ₁₂₃₇ | P10 | H | H | H | H | H | H | CN | P80 | O |
| Lₐ₁₂₃₈ | P10 | H | H | H | H | H | H | CN | P81 | O |
| Lₐ₁₂₃₉ | P10 | H | H | H | H | H | H | CN | P82 | O |
| Lₐ₁₂₄₀ | P10 | H | H | H | H | H | H | CN | P83 | O |
| Lₐ₁₂₄₁ | P10 | H | H | H | H | H | H | CN | P84 | O |
| Lₐ₁₂₄₂ | P10 | H | H | H | H | H | H | CN | P85 | O |
| Lₐ₁₂₄₃ | P10 | H | H | H | H | H | H | CN | P86 | O |
| Lₐ₁₂₄₄ | P10 | H | H | H | H | H | H | CN | P87 | O |
| Lₐ₁₂₄₅ | P10 | H | H | H | H | H | H | CN | P88 | O |
| Lₐ₁₂₄₆ | P10 | H | H | H | H | H | H | CN | P89 | O |
| Lₐ₁₂₄₇ | P10 | H | H | H | H | H | H | CN | P90 | O |
| Lₐ₁₂₄₈ | P10 | H | P1 | H | H | H | H | CN | P23 | O |
| Lₐ₁₂₄₉ | P10 | H | P2 | H | H | H | H | CN | P23 | O |
| Lₐ₁₂₅₀ | P10 | H | P3 | H | H | H | H | CN | P23 | O |
| Lₐ₁₂₅₁ | P10 | H | P4 | H | H | H | H | CN | P23 | O |
| Lₐ₁₂₅₂ | P10 | H | P5 | H | H | H | H | CN | P23 | O |
| Lₐ₁₂₅₃ | P10 | H | P6 | H | H | H | H | CN | P23 | O |
| Lₐ₁₂₅₄ | P10 | H | P7 | H | H | H | H | CN | P23 | O |
| Lₐ₁₂₅₅ | P10 | H | P8 | H | H | H | H | CN | P23 | O |
| Lₐ₁₂₅₆ | P10 | H | P9 | H | H | H | H | CN | P23 | O |
| Lₐ₁₂₅₇ | P10 | H | P10 | H | H | H | H | CN | P23 | O |
| Lₐ₁₂₅₈ | P10 | H | P11 | H | H | H | H | CN | P23 | O |
| Lₐ₁₂₅₉ | P10 | H | P12 | H | H | H | H | CN | P23 | O |
| Lₐ₁₂₆₀ | P10 | H | P15 | H | H | H | H | CN | P23 | O |
| Lₐ₁₂₆₁ | P10 | H | P17 | H | H | H | H | CN | P23 | O |
| Lₐ₁₂₆₂ | P10 | H | H | P1 | H | H | H | CN | P23 | O |
| Lₐ₁₂₆₃ | P10 | H | H | P2 | H | H | H | CN | P23 | O |
| Lₐ₁₂₆₄ | P10 | H | H | P3 | H | H | H | CN | P23 | O |
| Lₐ₁₂₆₅ | P10 | H | H | P4 | H | H | H | CN | P23 | O |
| Lₐ₁₂₆₆ | P10 | H | H | P5 | H | H | H | CN | P23 | O |
| Lₐ₁₂₆₇ | P10 | H | H | P6 | H | H | H | CN | P23 | O |
| Lₐ₁₂₆₈ | P10 | H | H | P7 | H | H | H | CN | P23 | O |
| Lₐ₁₂₆₉ | P10 | H | H | P8 | H | H | H | CN | P23 | O |
| Lₐ₁₂₇₀ | P10 | H | H | P9 | H | H | H | CN | P23 | O |
| Lₐ₁₂₇₁ | P10 | H | H | P10 | H | H | H | CN | P23 | O |
| Lₐ₁₂₇₂ | P10 | H | H | P11 | H | H | H | CN | P23 | O |
| Lₐ₁₂₇₃ | P10 | H | H | P12 | H | H | H | CN | P23 | O |
| Lₐ₁₂₇₄ | P10 | H | H | P15 | H | H | H | CN | P23 | O |
| Lₐ₁₂₇₅ | P10 | H | H | P17 | H | H | H | CN | P23 | O |
| Lₐ₁₂₇₆ | P10 | H | F | H | H | H | H | CN | P23 | O |
| Lₐ₁₂₇₇ | P10 | H | H | F | H | H | H | CN | P23 | O |
| Lₐ₁₂₇₈ | P10 | H | F | P1 | H | H | H | CN | P23 | O |
| Lₐ₁₂₇₉ | P10 | H | F | P2 | H | H | H | CN | P23 | O |
| Lₐ₁₂₈₀ | P10 | H | P1 | F | H | H | H | CN | P23 | O |
| Lₐ₁₂₈₁ | P10 | H | P2 | F | H | H | H | CN | P23 | O |
| Lₐ₁₂₈₂ | P10 | H | P1 | P1 | H | H | H | CN | P23 | O |
| Lₐ₁₂₈₃ | P10 | H | P2 | P2 | H | H | H | CN | P23 | O |
| Lₐ₁₂₈₄ | P10 | H | P1 | H | H | H | H | CN | P24 | O |
| Lₐ₁₂₈₅ | P10 | H | P2 | H | H | H | H | CN | P24 | O |
| Lₐ₁₂₈₆ | P10 | H | P3 | H | H | H | H | CN | P24 | O |
| Lₐ₁₂₈₇ | P10 | H | P4 | H | H | H | H | CN | P24 | O |
| Lₐ₁₂₈₈ | P10 | H | P5 | H | H | H | H | CN | P24 | O |
| Lₐ₁₂₈₉ | P10 | H | P6 | H | H | H | H | CN | P24 | O |
| Lₐ₁₂₉₀ | P10 | H | P7 | H | H | H | H | CN | P24 | O |
| Lₐ₁₂₉₁ | P10 | H | P8 | H | H | H | H | CN | P24 | O |
| Lₐ₁₂₉₂ | P10 | H | P9 | H | H | H | H | CN | P24 | O |
| Lₐ₁₂₉₃ | P10 | H | P10 | H | H | H | H | CN | P24 | O |
| Lₐ₁₂₉₄ | P10 | H | P11 | H | H | H | H | CN | P24 | O |
| Lₐ₁₂₉₅ | P10 | H | P12 | H | H | H | H | CN | P24 | O |
| Lₐ₁₂₉₆ | P10 | H | P15 | H | H | H | H | CN | P24 | O |
| Lₐ₁₂₉₇ | P10 | H | P17 | H | H | H | H | CN | P24 | O |
| Lₐ₁₂₉₈ | P10 | H | H | P1 | H | H | H | CN | P24 | O |
| Lₐ₁₂₉₉ | P10 | H | H | P2 | H | H | H | CN | P24 | O |
| Lₐ₁₃₀₀ | P10 | H | H | P3 | H | H | H | CN | P24 | O |
| Lₐ₁₃₀₁ | P10 | H | H | P4 | H | H | H | CN | P24 | O |
| Lₐ₁₃₀₂ | P10 | H | H | P5 | H | H | H | CN | P24 | O |
| Lₐ₁₃₀₃ | P10 | H | H | P6 | H | H | H | CN | P24 | O |
| Lₐ₁₃₀₄ | P10 | H | H | P7 | H | H | H | CN | P24 | O |
| Lₐ₁₃₀₅ | P10 | H | H | P8 | H | H | H | CN | P24 | O |
| Lₐ₁₃₀₆ | P10 | H | H | P9 | H | H | H | CN | P24 | O |
| Lₐ₁₃₀₇ | P10 | H | H | P10 | H | H | H | CN | P24 | O |
| Lₐ₁₃₀₈ | P10 | H | H | P11 | H | H | H | CN | P24 | O |
| Lₐ₁₃₀₉ | P10 | H | H | P12 | H | H | H | CN | P24 | O |
| Lₐ₁₃₁₀ | P10 | H | H | P15 | H | H | H | CN | P24 | O |
| Lₐ₁₃₁₁ | P10 | H | H | P17 | H | H | H | CN | P24 | O |
| Lₐ₁₃₁₂ | P10 | H | F | H | H | H | H | CN | P24 | O |
| Lₐ₁₃₁₃ | P10 | H | H | F | H | H | H | CN | P24 | O |
| Lₐ₁₃₁₄ | P10 | H | F | P1 | H | H | H | CN | P24 | O |
| Lₐ₁₃₁₅ | P10 | H | F | P2 | H | H | H | CN | P24 | O |
| Lₐ₁₃₁₆ | P10 | H | P1 | F | H | H | H | CN | P24 | O |
| Lₐ₁₃₁₇ | P10 | H | P2 | F | H | H | H | CN | P24 | O |
| Lₐ₁₃₁₈ | P10 | H | P1 | P1 | H | H | H | CN | P24 | O |
| Lₐ₁₃₁₉ | P10 | H | P2 | P2 | H | H | H | CN | P24 | O |
| Lₐ₁₃₂₀ | P10 | H | P1 | H | H | H | H | CN | P73 | O |
| Lₐ₁₃₂₁ | P10 | H | P2 | H | H | H | H | CN | P73 | O |
| Lₐ₁₃₂₂ | P10 | H | P3 | H | H | H | H | CN | P73 | O |
| Lₐ₁₃₂₃ | P10 | H | P4 | H | H | H | H | CN | P73 | O |
| Lₐ₁₃₂₄ | P10 | H | P5 | H | H | H | H | CN | P73 | O |
| Lₐ₁₃₂₅ | P10 | H | P6 | H | H | H | H | CN | P73 | O |
| Lₐ₁₃₂₆ | P10 | H | P7 | H | H | H | H | CN | P73 | O |
| Lₐ₁₃₂₇ | P10 | H | P8 | H | H | H | H | CN | P73 | O |
| Lₐ₁₃₂₈ | P10 | H | P9 | H | H | H | H | CN | P73 | O |
| Lₐ₁₃₂₉ | P10 | H | P10 | H | H | H | H | CN | P73 | O |
| Lₐ₁₃₃₀ | P10 | H | P11 | H | H | H | H | CN | P73 | O |
| Lₐ₁₃₃₁ | P10 | H | P12 | H | H | H | H | CN | P73 | O |
| Lₐ₁₃₃₂ | P10 | H | P15 | H | H | H | H | CN | P73 | O |
| Lₐ₁₃₃₃ | P10 | H | P17 | H | H | H | H | CN | P73 | O |
| Lₐ₁₃₃₄ | P10 | H | H | P1 | H | H | H | CN | P73 | O |
| Lₐ₁₃₃₅ | P10 | H | H | P2 | H | H | H | CN | P73 | O |
| Lₐ₁₃₃₆ | P10 | H | H | P3 | H | H | H | CN | P73 | O |
| Lₐ₁₃₃₇ | P10 | H | H | P4 | H | H | H | CN | P73 | O |
| Lₐ₁₃₃₈ | P10 | H | H | P5 | H | H | H | CN | P73 | O |
| Lₐ₁₃₃₉ | P10 | H | H | P6 | H | H | H | CN | P73 | O |
| Lₐ₁₃₄₀ | P10 | H | H | P7 | H | H | H | CN | P73 | O |
| Lₐ₁₃₄₁ | P10 | H | H | P8 | H | H | H | CN | P73 | O |
| Lₐ₁₃₄₂ | P10 | H | H | P9 | H | H | H | CN | P73 | O |
| Lₐ₁₃₄₃ | P10 | H | H | P10 | H | H | H | CN | P73 | O |
| Lₐ₁₃₄₄ | P10 | H | H | P11 | H | H | H | CN | P73 | O |
| Lₐ₁₃₄₅ | P10 | H | H | P12 | H | H | H | CN | P73 | O |
| Lₐ₁₃₄₆ | P10 | H | H | P15 | H | H | H | CN | P73 | O |
| Lₐ₁₃₄₇ | P10 | H | H | P17 | H | H | H | CN | P73 | O |
| Lₐ₁₃₄₈ | P10 | H | F | H | H | H | H | CN | P73 | O |
| Lₐ₁₃₄₉ | P10 | H | H | F | H | H | H | CN | P73 | O |
| Lₐ₁₃₅₀ | P10 | H | F | P1 | H | H | H | CN | P73 | O |
| Lₐ₁₃₅₁ | P10 | H | F | P2 | H | H | H | CN | P73 | O |
| Lₐ₁₃₅₂ | P10 | H | P1 | F | H | H | H | CN | P73 | O |
| Lₐ₁₃₅₃ | P10 | H | P2 | F | H | H | H | CN | P73 | O |
| Lₐ₁₃₅₄ | P10 | H | P1 | P1 | H | H | H | CN | P73 | O |
| Lₐ₁₃₅₅ | P10 | H | P2 | P2 | H | H | H | CN | P73 | O |
| Lₐ₁₃₅₆ | P10 | H | P1 | H | H | H | H | CN | P74 | O |
| Lₐ₁₃₅₇ | P10 | H | P2 | H | H | H | H | CN | P74 | O |
| Lₐ₁₃₅₈ | P10 | H | P3 | H | H | H | H | CN | P74 | O |
| Lₐ₁₃₅₉ | P10 | H | P4 | H | H | H | H | CN | P74 | O |
| Lₐ₁₃₆₀ | P10 | H | P5 | H | H | H | H | CN | P74 | O |
| Lₐ₁₃₆₁ | P10 | H | P6 | H | H | H | H | CN | P74 | O |
| Lₐ₁₃₆₂ | P10 | H | P7 | H | H | H | H | CN | P74 | O |
| Lₐ₁₃₆₃ | P10 | H | P8 | H | H | H | H | CN | P74 | O |
| Lₐ₁₃₆₄ | P10 | H | P9 | H | H | H | H | CN | P74 | O |
| Lₐ₁₃₆₅ | P10 | H | P10 | H | H | H | H | CN | P74 | O |
| Lₐ₁₃₆₆ | P10 | H | P11 | H | H | H | H | CN | P74 | O |
| Lₐ₁₃₆₇ | P10 | H | P12 | H | H | H | H | CN | P74 | O |
| Lₐ₁₃₆₈ | P10 | H | P15 | H | H | H | H | CN | P74 | O |
| Lₐ₁₃₆₉ | P10 | H | P17 | H | H | H | H | CN | P74 | O |
| Lₐ₁₃₇₀ | P10 | H | H | P1 | H | H | H | CN | P74 | O |
| Lₐ₁₃₇₁ | P10 | H | H | P2 | H | H | H | CN | P74 | O |
| Lₐ₁₃₇₂ | P10 | H | H | P3 | H | H | H | CN | P74 | O |
| Lₐ₁₃₇₃ | P10 | H | H | P4 | H | H | H | CN | P74 | O |
| Lₐ₁₃₇₄ | P10 | H | H | P5 | H | H | H | CN | P74 | O |
| Lₐ₁₃₇₅ | P10 | H | H | P6 | H | H | H | CN | P74 | O |
| Lₐ₁₃₇₆ | P10 | H | H | P7 | H | H | H | CN | P74 | O |
| Lₐ₁₃₇₇ | P10 | H | H | P8 | H | H | H | CN | P74 | O |
| Lₐ₁₃₇₈ | P10 | H | H | P9 | H | H | H | CN | P74 | O |
| Lₐ₁₃₇₉ | P10 | H | H | P10 | H | H | H | CN | P74 | O |
| Lₐ₁₃₈₀ | P10 | H | H | P11 | H | H | H | CN | P74 | O |
| Lₐ₁₃₈₁ | P10 | H | H | P12 | H | H | H | CN | P74 | O |
| Lₐ₁₃₈₂ | P10 | H | H | P15 | H | H | H | CN | P74 | O |
| Lₐ₁₃₈₃ | P10 | H | H | P17 | H | H | H | CN | P74 | O |
| Lₐ₁₃₈₄ | P10 | H | F | H | H | H | H | CN | P74 | O |
| Lₐ₁₃₈₅ | P10 | H | H | F | H | H | H | CN | P74 | O |
| Lₐ₁₃₈₆ | P10 | H | F | P1 | H | H | H | CN | P74 | O |
| Lₐ₁₃₈₇ | P10 | H | F | P2 | H | H | H | CN | P74 | O |
| Lₐ₁₃₈₈ | P10 | H | P1 | F | H | H | H | CN | P74 | O |
| Lₐ₁₃₈₉ | P10 | H | P2 | F | H | H | H | CN | P74 | O |
| Lₐ₁₃₉₀ | P10 | H | P1 | P1 | H | H | H | CN | P74 | O |
| Lₐ₁₃₉₁ | P10 | H | P2 | P2 | H | H | H | CN | P74 | O |
| Lₐ₁₃₉₂ | P10 | H | P1 | H | H | H | H | CN | P79 | O |
| Lₐ₁₃₉₃ | P10 | H | P2 | H | H | H | H | CN | P79 | O |
| Lₐ₁₃₉₄ | P10 | H | P3 | H | H | H | H | CN | P79 | O |
| Lₐ₁₃₉₅ | P10 | H | P4 | H | H | H | H | CN | P79 | O |
| Lₐ₁₃₉₆ | P10 | H | P5 | H | H | H | H | CN | P79 | O |
| Lₐ₁₃₉₇ | P10 | H | P6 | H | H | H | H | CN | P79 | O |
| Lₐ₁₃₉₈ | P10 | H | P7 | H | H | H | H | CN | P79 | O |
| Lₐ₁₃₉₉ | P10 | H | P8 | H | H | H | H | CN | P79 | O |
| Lₐ₁₄₀₀ | P10 | H | P9 | H | H | H | H | CN | P79 | O |
| Lₐ₁₄₀₁ | P10 | H | P10 | H | H | H | H | CN | P79 | O |
| Lₐ₁₄₀₂ | P10 | H | P1 | H | H | H | H | CN | P79 | O |
| Lₐ₁₄₀₃ | P10 | H | P12 | H | H | H | H | CN | P79 | O |
| Lₐ₁₄₀₄ | P10 | H | P15 | H | H | H | H | CN | P79 | O |
| Lₐ₁₄₀₅ | P10 | H | P17 | H | H | H | H | CN | P79 | O |
| Lₐ₁₄₀₆ | P10 | H | H | P1 | H | H | H | CN | P79 | O |
| Lₐ₁₄₀₇ | P10 | H | H | P2 | H | H | H | CN | P79 | O |
| Lₐ₁₄₀₈ | P10 | H | H | P3 | H | H | H | CN | P79 | O |
| Lₐ₁₄₀₉ | P10 | H | H | P4 | H | H | H | CN | P79 | O |
| Lₐ₁₄₁₀ | P10 | H | H | P5 | H | H | H | CN | P79 | O |
| Lₐ₁₄₁₁ | P10 | H | H | P6 | H | H | H | CN | P79 | O |
| Lₐ₁₄₁₂ | P10 | H | H | P7 | H | H | H | CN | P79 | O |
| Lₐ₁₄₁₃ | P10 | H | H | P8 | H | H | H | CN | P79 | O |
| Lₐ₁₄₁₄ | P10 | H | H | P9 | H | H | H | CN | P79 | O |
| Lₐ₁₄₁₅ | P10 | H | H | P10 | H | H | H | CN | P79 | O |
| Lₐ₁₄₁₆ | P10 | H | H | P11 | H | H | H | CN | P79 | O |
| Lₐ₁₄₁₇ | P10 | H | H | P12 | H | H | H | CN | P79 | O |
| Lₐ₁₄₁₈ | P10 | H | H | P15 | H | H | H | CN | P79 | O |
| Lₐ₁₄₁₉ | P10 | H | H | P17 | H | H | H | CN | P79 | O |
| Lₐ₁₄₂₀ | P10 | H | F | H | H | H | H | CN | P79 | O |
| Lₐ₁₄₂₁ | P10 | H | H | F | H | H | H | CN | P79 | O |
| Lₐ₁₄₂₂ | P10 | H | F | P1 | H | H | H | CN | P79 | O |
| Lₐ₁₄₂₃ | P10 | H | F | P2 | H | H | H | CN | P79 | O |
| Lₐ₁₄₂₄ | P10 | H | P1 | F | H | H | H | CN | P79 | O |
| Lₐ₁₄₂₅ | P10 | H | P2 | F | H | H | H | CN | P79 | O |
| Lₐ₁₄₂₆ | P10 | H | P1 | P1 | H | H | H | CN | P79 | O |
| Lₐ₁₄₂₇ | P10 | H | P2 | P2 | H | H | H | CN | P79 | O |
| Lₐ₁₄₂₈ | P10 | H | P1 | H | H | H | H | CN | P80 | O |
| Lₐ₁₄₂₉ | P10 | H | P2 | H | H | H | H | CN | P80 | O |
| Lₐ₁₄₃₀ | P10 | H | P3 | H | H | H | H | CN | P80 | O |
| Lₐ₁₄₃₁ | P10 | H | P4 | H | H | H | H | CN | P80 | O |
| Lₐ₁₄₃₂ | P10 | H | P5 | H | H | H | H | CN | P80 | O |
| Lₐ₁₄₃₃ | P10 | H | P6 | H | H | H | H | CN | P80 | O |
| Lₐ₁₄₃₄ | P10 | H | P7 | H | H | H | H | CN | P80 | O |
| Lₐ₁₄₃₅ | P10 | H | P8 | H | H | H | H | CN | P80 | O |
| Lₐ₁₄₃₆ | P10 | H | P9 | H | H | H | H | CN | P80 | O |
| Lₐ₁₄₃₇ | P10 | H | P10 | H | H | H | H | CN | P80 | O |
| Lₐ₁₄₃₈ | P10 | H | P11 | H | H | H | H | CN | P80 | O |
| Lₐ₁₄₃₉ | P10 | H | P12 | H | H | H | H | CN | P80 | O |
| Lₐ₁₄₄₀ | P10 | H | P15 | H | H | H | H | CN | P80 | O |
| Lₐ₁₄₄₁ | P10 | H | P17 | H | H | H | H | CN | P80 | O |
| Lₐ₁₄₄₂ | P10 | H | H | P1 | H | H | H | CN | P80 | O |
| Lₐ₁₄₄₃ | P10 | H | H | P2 | H | H | H | CN | P80 | O |
| Lₐ₁₄₄₄ | P10 | H | H | P3 | H | H | H | CN | P80 | O |
| Lₐ₁₄₄₅ | P10 | H | H | P4 | H | H | H | CN | P80 | O |
| Lₐ₁₄₄₆ | P10 | H | H | P5 | H | H | H | CN | P80 | O |
| Lₐ₁₄₄₇ | P10 | H | H | P6 | H | H | H | CN | P80 | O |
| Lₐ₁₄₄₈ | P10 | H | H | P7 | H | H | H | CN | P80 | O |
| Lₐ₁₄₄₉ | P10 | H | H | P8 | H | H | H | CN | P80 | O |
| Lₐ₁₄₅₀ | P10 | H | H | P9 | H | H | H | CN | P80 | O |
| Lₐ₁₄₅₁ | P10 | H | H | P10 | H | H | H | CN | P80 | O |
| Lₐ₁₄₅₂ | P10 | H | H | P11 | H | H | H | CN | P80 | O |
| Lₐ₁₄₅₃ | P10 | H | H | P12 | H | H | H | CN | P80 | O |
| Lₐ₁₄₅₄ | P10 | H | H | P15 | H | H | H | CN | P80 | O |
| Lₐ₁₄₅₅ | P10 | H | H | P17 | H | H | H | CN | P80 | O |
| Lₐ₁₄₅₆ | P10 | H | F | H | H | H | H | CN | P80 | O |
| Lₐ₁₄₅₇ | P10 | H | H | F | H | H | H | CN | P80 | O |
| Lₐ₁₄₅₈ | P10 | H | F | P1 | H | H | H | CN | P80 | O |
| Lₐ₁₄₅₉ | P10 | H | F | P2 | H | H | H | CN | P80 | O |
| Lₐ₁₄₆₀ | P10 | H | P1 | F | H | H | H | CN | P80 | O |
| Lₐ₁₄₆₁ | P10 | H | P2 | F | H | H | H | CN | P80 | O |
| Lₐ₁₄₆₂ | P10 | H | P1 | P1 | H | H | H | CN | P80 | O |
| Lₐ₁₄₆₃ | P10 | H | P2 | P2 | H | H | H | CN | P80 | O |
| Lₐ₁₄₆₄ | P10 | H | P1 | H | H | H | H | CN | P89 | O |
| Lₐ₁₄₆₅ | P10 | H | P2 | H | H | H | H | CN | P89 | O |
| Lₐ₁₄₆₆ | P10 | H | P3 | H | H | H | H | CN | P89 | O |
| Lₐ₁₄₆₇ | P10 | H | P4 | H | H | H | H | CN | P89 | O |
| Lₐ₁₄₆₈ | P10 | H | P5 | H | H | H | H | CN | P89 | O |
| Lₐ₁₄₆₉ | P10 | H | P6 | H | H | H | H | CN | P89 | O |
| Lₐ₁₄₇₀ | P10 | H | P7 | H | H | H | H | CN | P89 | O |
| Lₐ₁₄₇₁ | P10 | H | P8 | H | H | H | H | CN | P89 | O |
| Lₐ₁₄₇₂ | P10 | H | P9 | H | H | H | H | CN | P89 | O |
| Lₐ₁₄₇₃ | P10 | H | P10 | H | H | H | H | CN | P89 | O |
| Lₐ₁₄₇₄ | P10 | H | P11 | H | H | H | H | CN | P89 | O |
| Lₐ₁₄₇₅ | P10 | H | P12 | H | H | H | H | CN | P89 | O |
| Lₐ₁₄₇₆ | P10 | H | P15 | H | H | H | H | CN | P89 | O |
| Lₐ₁₄₇₇ | P10 | H | P17 | H | H | H | H | CN | P89 | O |
| Lₐ₁₄₇₈ | P10 | H | H | P1 | H | H | H | CN | P89 | O |
| Lₐ₁₄₇₉ | P10 | H | H | P2 | H | H | H | CN | P89 | O |
| Lₐ₁₄₈₀ | P10 | H | H | P3 | H | H | H | CN | P89 | O |
| Lₐ₁₄₈₁ | P10 | H | H | P4 | H | H | H | CN | P89 | O |
| Lₐ₁₄₈₂ | P10 | H | H | P5 | H | H | H | CN | P89 | O |
| Lₐ₁₄₈₃ | P10 | H | H | P6 | H | H | H | CN | P89 | O |
| Lₐ₁₄₈₄ | P10 | H | H | P7 | H | H | H | CN | P89 | O |
| Lₐ₁₄₈₅ | P10 | H | H | P8 | H | H | H | CN | P89 | O |
| Lₐ₁₄₈₆ | P10 | H | H | P9 | H | H | H | CN | P89 | O |
| Lₐ₁₄₈₇ | P10 | H | H | P10 | H | H | H | CN | P89 | O |
| Lₐ₁₄₈₈ | P10 | H | H | P11 | H | H | H | CN | P89 | O |
| Lₐ₁₄₈₉ | P10 | H | H | P12 | H | H | H | CN | P89 | O |
| Lₐ₁₄₉₀ | P10 | H | H | P15 | H | H | H | CN | P89 | O |
| Lₐ₁₄₉₁ | P10 | H | H | P17 | H | H | H | CN | P89 | O |
| Lₐ₁₄₉₂ | P10 | H | F | H | H | H | H | CN | P89 | O |
| Lₐ₁₄₉₃ | P10 | H | H | F | H | H | H | CN | P89 | O |
| Lₐ₁₄₉₄ | P10 | H | F | P1 | H | H | H | CN | P89 | O |
| Lₐ₁₄₉₅ | P10 | H | F | P2 | H | H | H | CN | P89 | O |
| Lₐ₁₄₉₆ | P10 | H | P1 | F | H | H | H | CN | P89 | O |
| Lₐ₁₄₉₇ | P10 | H | P2 | F | H | H | H | CN | P89 | O |
| Lₐ₁₄₉₈ | P10 | H | P1 | P1 | H | H | H | CN | P89 | O |
| Lₐ₁₄₉₉ | P10 | H | P2 | P2 | H | H | H | CN | P89 | O |
| Lₐ₁₅₀₀ | P1 | H | H | H | H | H | H | CN | H | O |
| Lₐ₁₅₀₁ | P2 | H | H | H | H | H | H | CN | H | O |
| Lₐ₁₅₀₂ | P3 | H | H | H | H | H | H | CN | H | O |
| Lₐ₁₅₀₃ | P4 | H | H | H | H | H | H | CN | H | O |
| Lₐ₁₅₀₄ | P5 | H | H | H | H | H | H | CN | H | O |
| Lₐ₁₅₀₅ | P7 | H | H | H | H | H | H | CN | H | O |
| Lₐ₁₅₀₆ | P8 | H | H | H | H | H | H | CN | H | O |
| Lₐ₁₅₀₇ | P9 | H | H | H | H | H | H | CN | H | O |
| Lₐ₁₅₀₈ | P12 | H | H | H | H | H | H | CN | H | O |
| Lₐ₁₅₀₉ | P13 | H | H | H | H | H | H | CN | H | O |
| Lₐ₁₅₁₀ | P14 | H | H | H | H | H | H | CN | H | O |
| Lₐ₁₅₁₁ | P15 | H | H | H | H | H | H | CN | H | O |
| Lₐ₁₅₁₂ | P16 | H | H | H | H | H | H | CN | H | O |
| Lₐ₁₅₁₃ | P17 | H | H | H | H | H | H | CN | H | O |
| Lₐ₁₅₁₄ | P18 | H | H | H | H | H | H | CN | H | O |
| Lₐ₁₅₁₅ | P19 | H | H | H | H | H | H | CN | H | O |
| Lₐ₁₅₁₆ | P20 | H | H | H | H | H | H | CN | H | O |
| Lₐ₁₅₁₇ | P25 | H | H | H | H | H | H | CN | H | O |
| Lₐ₁₅₁₈ | P27 | H | H | H | H | H | H | CN | H | O |
| Lₐ₁₅₁₉ | P29 | H | H | H | H | H | H | CN | H | O |
| Lₐ₁₅₂₀ | P31 | H | H | H | H | H | H | CN | H | O |
| Lₐ₁₅₂₁ | P33 | H | H | H | H | H | H | CN | H | O |
| Lₐ₁₅₂₂ | P34 | H | H | H | H | H | H | CN | H | O |
| Lₐ₁₅₂₃ | P1 | H | H | H | H | H | H | CN | D | O |
| Lₐ₁₅₂₄ | P2 | H | H | H | H | H | H | CN | D | O |
| Lₐ₁₅₂₅ | P3 | H | H | H | H | H | H | CN | D | O |
| Lₐ₁₅₂₆ | P4 | H | H | H | H | H | H | CN | D | O |
| Lₐ₁₅₂₇ | P5 | H | H | H | H | H | H | CN | D | O |
| Lₐ₁₅₂₈ | P7 | H | H | H | H | H | H | CN | D | O |
| Lₐ₁₅₂₉ | P8 | H | H | H | H | H | H | CN | D | O |
| Lₐ₁₅₃₀ | P9 | H | H | H | H | H | H | CN | D | O |
| Lₐ₁₅₃₁ | P12 | H | H | H | H | H | H | CN | D | O |
| Lₐ₁₅₃₂ | P13 | H | H | H | H | H | H | CN | D | O |
| Lₐ₁₅₃₃ | P14 | H | H | H | H | H | H | CN | D | O |
| Lₐ₁₅₃₄ | P15 | H | H | H | H | H | H | CN | D | O |
| Lₐ₁₅₃₅ | P16 | H | H | H | H | H | H | CN | D | O |
| Lₐ₁₅₃₆ | P17 | H | H | H | H | H | H | CN | D | O |
| Lₐ₁₅₃₇ | P18 | H | H | H | H | H | H | CN | D | O |
| Lₐ₁₅₃₈ | P19 | H | H | H | H | H | H | CN | D | O |
| Lₐ₁₅₃₉ | P20 | H | H | H | H | H | H | CN | D | O |
| Lₐ₁₅₄₀ | P25 | H | H | H | H | H | H | CN | D | O |
| Lₐ₁₅₄₁ | P27 | H | H | H | H | H | H | CN | D | O |
| Lₐ₁₅₄₂ | P29 | H | H | H | H | H | H | CN | D | O |
| Lₐ₁₅₄₃ | P31 | H | H | H | H | H | H | CN | D | O |
| Lₐ₁₅₄₄ | P33 | H | H | H | H | H | H | CN | D | O |
| Lₐ₁₅₄₅ | P34 | H | H | H | H | H | H | CN | D | O |
| Lₐ₁₅₄₆ | P1 | H | P4 | H | H | H | H | CN | D | O |
| Lₐ₁₅₄₇ | P2 | H | P4 | H | H | H | H | CN | D | O |
| Lₐ₁₅₄₈ | P3 | H | P4 | H | H | H | H | CN | D | O |
| Lₐ₁₅₄₉ | P4 | H | P4 | H | H | H | H | CN | D | O |
| Lₐ₁₅₅₀ | P5 | H | P4 | H | H | H | H | CN | D | O |
| Lₐ₁₅₅₁ | P7 | H | P4 | H | H | H | H | CN | D | O |
| Lₐ₁₅₅₂ | P8 | H | P4 | H | H | H | H | CN | D | O |
| Lₐ₁₅₅₃ | P9 | H | P4 | H | H | H | H | CN | D | O |
| Lₐ₁₅₅₄ | P12 | H | P4 | H | H | H | H | CN | D | O |
| Lₐ₁₅₅₅ | P13 | H | P4 | H | H | H | H | CN | D | O |
| Lₐ₁₅₅₆ | P14 | H | P4 | H | H | H | H | CN | D | O |
| Lₐ₁₅₅₇ | P15 | H | P4 | H | H | H | H | CN | D | O |
| Lₐ₁₅₅₈ | P16 | H | P4 | H | H | H | H | CN | D | O |
| Lₐ₁₅₅₉ | P17 | H | P4 | H | H | H | H | CN | D | O |
| Lₐ₁₅₆₀ | P18 | H | P4 | H | H | H | H | CN | D | O |
| Lₐ₁₅₆₁ | P19 | H | P4 | H | H | H | H | CN | D | O |
| Lₐ₁₅₆₂ | P20 | H | P4 | H | H | H | H | CN | D | O |
| Lₐ₁₅₆₃ | P25 | H | P4 | H | H | H | H | CN | H | O |
| Lₐ₁₅₆₄ | P27 | H | P4 | H | H | H | H | CN | D | O |
| Lₐ₁₅₆₅ | P29 | H | P4 | H | H | H | H | CN | D | O |
| Lₐ₁₅₆₆ | P31 | H | P4 | H | H | H | H | CN | D | O |
| Lₐ₁₅₆₇ | P33 | H | P4 | H | H | H | H | CN | D | O |
| Lₐ₁₅₆₈ | P34 | H | P4 | H | H | H | H | CN | D | O |
| Lₐ₁₅₆₉ | P1 | H | H | P4 | H | H | H | CN | D | O |
| Lₐ₁₅₇₀ | P2 | H | H | P4 | H | H | H | CN | D | O |
| Lₐ₁₅₇₁ | P3 | H | H | P4 | H | H | H | CN | D | O |
| Lₐ₁₅₇₂ | P4 | H | H | P4 | H | H | H | CN | D | O |
| Lₐ₁₅₇₃ | P5 | H | H | P4 | H | H | H | CN | D | O |
| Lₐ₁₅₇₄ | P7 | H | H | P4 | H | H | H | CN | D | O |
| Lₐ₁₅₇₅ | P8 | H | H | P4 | H | H | H | CN | D | O |
| Lₐ₁₅₇₆ | P9 | H | H | P4 | H | H | H | CN | D | O |
| Lₐ₁₅₇₇ | P12 | H | H | P4 | H | H | H | CN | D | O |
| Lₐ₁₅₇₈ | P13 | H | H | P4 | H | H | H | CN | D | O |
| Lₐ₁₅₇₉ | P14 | H | H | P4 | H | H | H | CN | D | O |
| Lₐ₁₅₈₀ | P15 | H | H | P4 | H | H | H | CN | D | O |
| Lₐ₁₅₈₁ | P16 | H | H | P4 | H | H | H | CN | D | O |
| Lₐ₁₅₈₂ | P17 | H | H | P4 | H | H | H | CN | H | O |
| Lₐ₁₅₈₃ | P18 | H | H | P4 | H | H | H | CN | D | O |
| Lₐ₁₅₈₄ | P19 | H | H | P4 | H | H | H | CN | D | O |
| Lₐ₁₅₈₅ | P20 | H | H | P4 | H | H | H | CN | D | O |
| Lₐ₁₅₈₆ | P25 | H | H | P4 | H | H | H | CN | D | O |
| Lₐ₁₅₈₇ | P27 | H | H | P4 | H | H | H | CN | D | O |
| Lₐ₁₅₈₈ | P29 | H | H | P4 | H | H | H | CN | D | O |
| Lₐ₁₅₈₉ | P31 | H | H | P4 | H | H | H | CN | D | O |
| Lₐ₁₅₉₀ | P33 | H | H | P4 | H | H | H | CN | D | O |
| Lₐ₁₅₉₁ | P34 | H | H | P4 | H | H | H | CN | D | O |
| Lₐ₁₅₉₂ | P1 | H | P6 | H | H | H | H | CN | D | O |
| Lₐ₁₅₉₃ | P2 | H | P6 | H | H | H | H | CN | D | O |
| Lₐ₁₅₉₄ | P3 | H | P6 | H | H | H | H | CN | D | O |
| Lₐ₁₅₉₅ | P4 | H | P6 | H | H | H | H | CN | D | O |
| Lₐ₁₅₉₆ | P5 | H | P6 | H | H | H | H | CN | D | O |
| Lₐ₁₅₉₇ | P7 | H | P6 | H | H | H | H | CN | H | O |
| Lₐ₁₅₉₈ | P8 | H | P6 | H | H | H | H | CN | D | O |
| Lₐ₁₅₉₉ | P9 | H | P6 | H | H | H | H | CN | D | O |
| Lₐ₁₆₀₀ | P12 | H | P6 | H | H | H | H | CN | D | O |
| Lₐ₁₆₀₁ | P13 | H | P6 | H | H | H | H | CN | D | O |
| Lₐ₁₆₀₂ | P14 | H | P6 | H | H | H | H | CN | D | O |
| Lₐ₁₆₀₃ | P15 | H | P6 | H | H | H | H | CN | D | O |
| Lₐ₁₆₀₄ | P16 | H | P6 | H | H | H | H | CN | D | O |
| Lₐ₁₆₀₅ | P17 | H | P6 | H | H | H | H | CN | D | O |
| Lₐ₁₆₀₆ | P18 | H | P6 | H | H | H | H | CN | D | O |
| Lₐ₁₆₀₇ | P19 | H | P6 | H | H | H | H | CN | D | O |
| Lₐ₁₆₀₈ | P20 | H | P6 | H | H | H | H | CN | D | O |
| Lₐ₁₆₀₉ | P25 | H | P6 | H | H | H | H | CN | D | O |
| Lₐ₁₆₁₀ | P27 | H | P6 | H | H | H | H | CN | D | O |
| Lₐ₁₆₁₁ | P29 | H | P6 | H | H | H | H | CN | D | O |
| Lₐ₁₆₁₂ | P31 | H | P6 | H | H | H | H | CN | D | O |
| Lₐ₁₆₁₃ | P33 | H | P6 | H | H | H | H | CN | D | O |
| Lₐ₁₆₁₄ | P34 | H | P6 | H | H | H | H | CN | D | O |
| Lₐ₁₆₁₅ | P1 | H | H | P6 | H | H | H | CN | H | O |
| Lₐ₁₆₁₆ | P2 | H | H | P6 | H | H | H | CN | D | O |
| Lₐ₁₆₁₇ | P3 | H | H | P6 | H | H | H | CN | D | O |
| Lₐ₁₆₁₈ | P4 | H | H | P6 | H | H | H | CN | D | O |
| Lₐ₁₆₁₉ | P5 | H | H | P6 | H | H | H | CN | H | O |
| Lₐ₁₆₂₀ | P7 | H | H | P6 | H | H | H | CN | D | O |
| Lₐ₁₆₂₁ | P8 | H | H | P6 | H | H | H | CN | D | O |
| Lₐ₁₆₂₂ | P9 | H | H | P6 | H | H | H | CN | D | O |
| Lₐ₁₆₂₃ | P12 | H | H | P6 | H | H | H | CN | D | O |
| Lₐ₁₆₂₄ | P13 | H | H | P6 | H | H | H | CN | D | O |
| Lₐ₁₆₂₅ | P14 | H | H | P6 | H | H | H | CN | D | O |
| Lₐ₁₆₂₆ | P15 | H | H | P6 | H | H | H | CN | D | O |
| Lₐ₁₆₂₇ | P16 | H | H | P6 | H | H | H | CN | D | O |
| Lₐ₁₆₂₈ | P17 | H | H | P6 | H | H | H | CN | D | O |
| Lₐ₁₆₂₉ | P18 | H | H | P6 | H | H | H | CN | D | O |
| Lₐ₁₆₃₀ | P19 | H | H | P6 | H | H | H | CN | D | O |
| Lₐ₁₆₃₁ | P20 | H | H | P6 | H | H | H | CN | D | O |
| Lₐ₁₆₃₂ | P25 | H | H | P6 | H | H | H | CN | D | O |
| Lₐ₁₆₃₃ | P27 | H | H | P6 | H | H | H | CN | D | O |
| Lₐ₁₆₃₄ | P29 | H | H | P6 | H | H | H | CN | D | O |
| Lₐ₁₆₃₅ | P31 | H | H | P6 | H | H | H | CN | D | O |
| Lₐ₁₆₃₆ | P33 | H | H | P6 | H | H | H | CN | D | O |
| Lₐ₁₆₃₇ | P34 | H | H | P6 | H | H | H | CN | D | O |
| Lₐ₁₆₃₈ | P1 | H | P10 | H | H | H | H | CN | D | O |
| Lₐ₁₆₃₉ | P2 | H | P11 | H | H | H | H | CN | D | O |
| Lₐ₁₆₄₀ | P3 | H | P10 | H | H | H | H | CN | D | O |
| Lₐ₁₆₄₁ | P4 | H | P11 | H | H | H | H | CN | D | O |
| Lₐ₁₆₄₂ | P5 | H | P10 | H | H | H | H | CN | D | O |
| Lₐ₁₆₄₃ | P7 | H | P11 | H | H | H | H | CN | D | O |
| Lₐ₁₆₄₄ | P8 | H | P10 | H | H | H | H | CN | D | O |
| Lₐ₁₆₄₅ | P9 | H | P11 | H | H | H | H | CN | D | O |
| Lₐ₁₆₄₆ | P12 | H | P10 | H | H | H | H | CN | H | O |
| Lₐ₁₆₄₇ | P13 | H | P11 | H | H | H | H | CN | H | O |
| Lₐ₁₆₄₈ | P14 | H | P10 | H | H | H | H | CN | D | O |
| Lₐ₁₆₄₉ | P15 | H | P11 | H | H | H | H | CN | D | O |
| Lₐ₁₆₅₀ | P16 | H | P10 | H | H | H | H | CN | D | O |
| Lₐ₁₆₅₁ | P17 | H | P11 | H | H | H | H | CN | D | O |
| Lₐ₁₆₅₂ | P18 | H | P10 | H | H | H | H | CN | H | O |
| Lₐ₁₆₅₃ | P19 | H | P11 | H | H | H | H | CN | D | O |
| Lₐ₁₆₅₄ | P20 | H | P10 | H | H | H | H | CN | D | O |
| Lₐ₁₆₅₅ | P25 | H | P11 | H | H | H | H | CN | D | O |
| Lₐ₁₆₅₆ | P27 | H | P10 | H | H | H | H | CN | H | O |
| Lₐ₁₆₅₇ | P29 | H | P11 | H | H | H | H | CN | D | O |
| Lₐ₁₆₅₈ | P31 | H | P10 | H | H | H | H | CN | D | O |
| Lₐ₁₆₅₉ | P33 | H | P11 | H | H | H | H | CN | D | O |
| Lₐ₁₆₆₀ | P34 | H | P10 | H | H | H | H | CN | D | O |
| Lₐ₁₆₆₁ | P1 | H | H | P10 | H | H | H | CN | D | O |
| Lₐ₁₆₆₂ | P2 | H | H | P11 | H | H | H | CN | D | O |
| Lₐ₁₆₆₃ | P3 | H | H | P10 | H | H | H | CN | D | O |
| Lₐ₁₆₆₄ | P4 | H | H | P11 | H | H | H | CN | D | O |
| Lₐ₁₆₆₅ | P5 | H | H | P10 | H | H | H | CN | D | O |
| Lₐ₁₆₆₆ | P7 | H | H | P11 | H | H | H | CN | D | O |
| Lₐ₁₆₆₇ | P8 | H | H | P10 | H | H | H | CN | D | O |
| Lₐ₁₆₆₈ | P9 | H | H | P11 | H | H | H | CN | D | O |
| Lₐ₁₆₆₉ | P12 | H | H | P10 | H | H | H | CN | D | O |
| Lₐ₁₆₇₀ | P13 | H | H | P11 | H | H | H | CN | D | O |
| Lₐ₁₆₇₁ | P14 | H | H | P10 | H | H | H | CN | D | O |
| Lₐ₁₆₇₂ | P15 | H | H | P11 | H | H | H | CN | D | O |
| Lₐ₁₆₇₃ | P16 | H | H | P10 | H | H | H | CN | D | O |
| Lₐ₁₆₇₄ | P17 | H | H | P11 | H | H | H | CN | D | O |
| Lₐ₁₆₇₅ | P18 | H | H | P10 | H | H | H | CN | D | O |
| Lₐ₁₆₇₆ | P19 | H | H | P11 | H | H | H | CN | D | O |
| Lₐ₁₆₇₇ | P20 | H | H | P10 | H | H | H | CN | D | O |
| Lₐ₁₆₇₈ | P25 | H | H | P11 | H | H | H | CN | D | O |
| Lₐ₁₆₇₉ | P27 | H | H | P10 | H | H | H | CN | D | O |
| Lₐ₁₆₈₀ | P29 | H | H | P11 | H | H | H | CN | D | O |
| Lₐ₁₆₈₁ | P31 | H | H | P10 | H | H | H | CN | D | O |
| Lₐ₁₆₈₂ | P33 | H | H | P11 | H | H | H | CN | D | O |
| Lₐ₁₆₈₃ | P34 | H | H | P10 | H | H | H | CN | D | O |
| Lₐ₁₆₈₄ | P1 | H | P1 | P1 | H | H | H | CN | D | O |
| Lₐ₁₆₈₅ | P2 | H | P1 | P1 | H | H | H | CN | D | O |
| Lₐ₁₆₈₆ | P3 | H | P1 | P1 | H | H | H | CN | D | O |
| Lₐ₁₆₈₇ | P4 | H | P1 | P1 | H | H | H | CN | D | O |
| Lₐ₁₆₈₈ | P5 | H | P1 | P1 | H | H | H | CN | D | O |
| Lₐ₁₆₈₉ | P7 | H | P1 | P1 | H | H | H | CN | D | O |
| Lₐ₁₆₉₀ | P8 | H | P1 | P1 | H | H | H | CN | D | O |
| Lₐ₁₆₉₁ | P9 | H | P1 | P1 | H | H | H | CN | D | O |
| Lₐ₁₆₉₂ | P12 | H | P1 | P1 | H | H | H | CN | D | O |
| Lₐ₁₆₉₃ | P13 | H | P1 | P1 | H | H | H | CN | D | O |
| Lₐ₁₆₉₄ | P14 | H | P1 | P1 | H | H | H | CN | D | O |
| Lₐ₁₆₉₅ | P15 | H | P1 | P1 | H | H | H | CN | D | O |
| Lₐ₁₆₉₆ | P16 | H | P1 | P1 | H | H | H | CN | D | O |
| Lₐ₁₆₉₇ | P17 | H | P1 | P1 | H | H | H | CN | D | O |
| Lₐ₁₆₉₈ | P18 | H | P1 | P1 | H | H | H | CN | D | O |
| Lₐ₁₆₉₉ | P19 | H | P1 | P1 | H | H | H | CN | D | O |
| Lₐ₁₇₀₀ | P20 | H | P1 | P1 | H | H | H | CN | D | O |
| Lₐ₁₇₀₁ | P25 | H | P1 | P1 | H | H | H | CN | D | O |
| Lₐ₁₇₀₂ | P27 | H | P1 | P1 | H | H | H | CN | D | O |
| Lₐ₁₇₀₃ | P29 | H | P1 | P1 | H | H | H | CN | D | O |
| Lₐ₁₇₀₄ | P31 | H | P1 | P1 | H | H | H | CN | D | O |
| Lₐ₁₇₀₅ | P33 | H | P1 | P1 | H | H | H | CN | D | O |
| Lₐ₁₇₀₆ | P34 | H | P1 | P1 | H | H | H | CN | D | O |
| Lₐ₁₇₀₇ | P1 | H | P2 | P2 | H | H | H | CN | D | O |
| Lₐ₁₇₀₈ | P2 | H | P2 | P2 | H | H | H | CN | D | O |
| Lₐ₁₇₀₉ | P3 | H | P2 | P2 | H | H | H | CN | D | O |
| Lₐ₁₇₁₀ | P4 | H | P2 | P2 | H | H | H | CN | D | O |
| Lₐ₁₇₁₁ | P5 | H | P2 | P2 | H | H | H | CN | D | O |
| Lₐ₁₇₁₂ | P7 | H | P2 | P2 | H | H | H | CN | D | O |
| Lₐ₁₇₁₃ | P8 | H | P2 | P2 | H | H | H | CN | D | O |
| Lₐ₁₇₁₄ | P9 | H | P2 | P2 | H | H | H | CN | D | O |
| Lₐ₁₇₁₅ | P12 | H | P2 | P2 | H | H | H | CN | D | O |
| Lₐ₁₇₁₆ | P13 | H | P2 | P2 | H | H | H | CN | D | O |
| Lₐ₁₇₁₇ | P14 | H | P2 | P2 | H | H | H | CN | D | O |
| Lₐ₁₇₁₈ | P15 | H | P2 | P2 | H | H | H | CN | D | O |
| Lₐ₁₇₁₉ | P16 | H | P2 | P2 | H | H | H | CN | D | O |
| Lₐ₁₇₂₀ | P17 | H | P2 | P2 | H | H | H | CN | D | O |
| Lₐ₁₇₂₁ | P18 | H | P2 | P2 | H | H | H | CN | D | O |
| Lₐ₁₇₂₂ | P19 | H | P2 | P2 | H | H | H | CN | D | O |
| Lₐ₁₇₂₃ | P20 | H | P2 | P2 | H | H | H | CN | D | O |
| Lₐ₁₇₂₄ | P25 | H | P2 | P2 | H | H | H | CN | D | O |
| Lₐ₁₇₂₅ | P27 | H | P2 | P2 | H | H | H | CN | D | O |
| Lₐ₁₇₂₆ | P29 | H | P2 | P2 | H | H | H | CN | D | O |
| Lₐ₁₇₂₇ | P31 | H | P2 | P2 | H | H | H | CN | D | O |
| Lₐ₁₇₂₈ | P33 | H | P2 | P2 | H | H | H | CN | D | O |
| Lₐ₁₇₂₉ | P34 | H | P2 | P2 | H | H | H | CN | D | O |
| Lₐ₁₇₃₀ | P6 | H | H | H | H | H | H | H | CN | O |
| Lₐ₁₇₃₁ | P6 | H | H | H | H | H | CN | H | H | O |
| Lₐ₁₇₃₂ | P6 | H | H | H | H | CN | H | H | H | O |
| Lₐ₁₇₃₃ | P6 | H | P6 | H | H | H | H | H | CN | O |
| Lₐ₁₇₃₄ | P6 | H | P6 | H | H | H | CN | H | H | O |
| Lₐ₁₇₃₅ | P6 | H | P6 | H | H | CN | H | H | H | O |
| Lₐ₁₇₃₆ | P6 | H | H | P6 | H | H | H | H | CN | O |
| Lₐ₁₇₃₇ | P6 | H | H | P6 | H | H | CN | H | H | O |
| Lₐ₁₇₃₈ | P6 | H | H | P6 | H | CN | H | H | H | O |
| Lₐ₁₇₃₉ | P6 | H | H | H | H | H | H | P24 | CN | O |
| Lₐ₁₇₄₀ | P6 | H | H | H | H | H | H | D | CN | O |
| Lₐ₁₇₄₁ | P6 | H | H | H | H | H | H | P56 | CN | O |
| Lₐ₁₇₄₂ | P6 | H | H | H | H | H | H | P24 | CN | O |
| Lₐ₁₇₄₃ | P6 | H | H | H | H | H | H | P74 | CN | O |
| Lₐ₁₇₄₄ | P6 | H | H | H | H | H | H | CN | H | S |
| Lₐ₁₇₄₅ | P6 | H | H | H | H | H | H | CN | D | S |
| Lₐ₁₇₄₆ | P3 | H | H | P4 | H | H | H | CN | H | S |
| Lₐ₁₇₄₇ | P6 | H | H | P11 | H | H | H | H | CN | S |
| Lₐ₁₇₄₈ | P3 | H | H | P6 | H | H | H | H | CN | S |
| Lₐ₁₇₄₉ | P2 | H | H | H | H | H | H | H | CN | S |
| Lₐ₁₇₅₀ | P6 | H | H | P11 | H | H | H | CN | H | S |
| Lₐ₁₇₅₁ | P6 | H | H | P6 | H | H | H | CN | H | S |
| Lₐ₁₇₅₂ | P6 | H | P11 | H | H | H | H | CN | H | S |
| Lₐ₁₇₅₃ | P6 | H | P6 | H | H | H | H | CN | H | S |
| Lₐ₁₇₅₄ | P11 | H | H | H | H | H | H | CN | H | S |
| Lₐ₁₇₅₅ | P11 | H | H | H | H | H | H | CN | D | S |
| Lₐ₁₇₅₆ | P10 | H | P2 | P2 | H | H | H | CN | H | S |
| Lₐ₁₇₅₇ | P11 | H | H | H | H | H | H | H | CN | S |
| Lₐ₁₇₅₈ | P10 | H | P2 | P2 | H | H | H | H | CN | S |
| Lₐ₁₇₅₉ | P15 | H | H | H | H | H | H | H | CN | S |
| Lₐ₁₇₆₀ | P11 | H | H | P11 | H | H | H | CN | H | S |
| Lₐ₁₇₆₁ | P11 | H | H | P6 | H | H | H | CN | H | S |
| Lₐ₁₇₆₂ | P11 | H | P11 | H | H | H | H | CN | H | S |
| Lₐ₁₇₆₃ | P11 | H | P6 | H | H | H | H | CN | H | S |
| Lₐ₁₇₆₄ | P6 | H | H | H | H | H | H | F | H | O |
| Lₐ₁₇₆₅ | P6 | H | P1 | H | H | H | H | F | H | O |
| Lₐ₁₇₆₆ | P6 | H | P2 | H | H | H | H | F | H | O |
| Lₐ₁₇₆₇ | P6 | H | P3 | H | H | H | H | F | H | O |
| Lₐ₁₇₆₈ | P6 | H | P4 | H | H | H | H | F | H | O |
| Lₐ₁₇₆₉ | P6 | H | P5 | H | H | H | H | F | H | O |
| Lₐ₁₇₇₀ | P6 | H | P6 | H | H | H | H | F | H | O |
| Lₐ₁₇₇₁ | P6 | H | P7 | H | H | H | H | F | H | O |
| Lₐ₁₇₇₂ | P6 | H | P8 | H | H | H | H | F | H | O |
| Lₐ₁₇₇₃ | P6 | H | P9 | H | H | H | H | F | H | O |
| Lₐ₁₇₇₄ | P6 | H | P10 | H | H | H | H | F | H | O |
| Lₐ₁₇₇₅ | P6 | H | P11 | H | H | H | H | F | H | O |
| Lₐ₁₇₇₆ | P6 | H | P12 | H | H | H | H | F | H | O |
| Lₐ₁₇₇₇ | P6 | H | P13 | H | H | H | H | F | H | O |
| Lₐ₁₇₇₈ | P6 | H | P14 | H | H | H | H | F | H | O |
| Lₐ₁₇₇₉ | P6 | H | P15 | H | H | H | H | F | H | O |
| Lₐ₁₇₈₀ | P6 | H | P16 | H | H | H | H | F | H | O |
| Lₐ₁₇₈₁ | P6 | H | P17 | H | H | H | H | F | H | O |
| Lₐ₁₇₈₂ | P6 | H | P18 | H | H | H | H | F | H | O |
| Lₐ₁₇₈₃ | P6 | H | P19 | H | H | H | H | F | H | O |
| Lₐ₁₇₈₄ | P6 | H | P20 | H | H | H | H | F | H | O |
| Lₐ₁₇₈₅ | P6 | H | P21 | H | H | H | H | F | H | O |
| Lₐ₁₇₈₆ | P6 | H | P22 | H | H | H | H | F | H | O |
| Lₐ₁₇₈₇ | P6 | H | P23 | H | H | H | H | F | H | O |
| Lₐ₁₇₈₈ | P6 | H | P24 | H | H | H | H | F | H | O |
| Lₐ₁₇₈₉ | P6 | H | P25 | H | H | H | H | F | H | O |
| Lₐ₁₇₉₀ | P6 | H | P26 | H | H | H | H | F | H | O |
| Lₐ₁₇₉₁ | P6 | H | P27 | H | H | H | H | F | H | O |
| Lₐ₁₇₉₂ | P6 | H | P28 | H | H | H | H | F | H | O |
| Lₐ₁₇₉₃ | P6 | H | P29 | H | H | H | H | F | H | O |
| Lₐ₁₇₉₄ | P6 | H | P30 | H | H | H | H | F | H | O |
| Lₐ₁₇₉₅ | P6 | H | P31 | H | H | H | H | F | H | O |
| Lₐ₁₇₉₆ | P6 | H | P32 | H | H | H | H | F | H | O |
| Lₐ₁₇₉₇ | P6 | H | P33 | H | H | H | H | F | H | O |
| Lₐ₁₇₉₈ | P6 | H | P34 | H | H | H | H | F | H | O |
| Lₐ₁₇₉₉ | P6 | H | H | P1 | H | H | H | F | H | O |
| Lₐ₁₈₀₀ | P6 | H | H | P2 | H | H | H | F | H | O |
| Lₐ₁₈₀₁ | P6 | H | H | P3 | H | H | H | F | H | O |
| Lₐ₁₈₀₂ | P6 | H | H | P4 | H | H | H | F | H | O |
| Lₐ₁₈₀₃ | P6 | H | H | P5 | H | H | H | F | H | O |
| Lₐ₁₈₀₄ | P6 | H | H | P6 | H | H | H | F | H | O |
| Lₐ₁₈₀₅ | P6 | H | H | P7 | H | H | H | F | H | O |
| Lₐ₁₈₀₆ | P6 | H | H | P8 | H | H | H | F | H | O |
| Lₐ₁₈₀₇ | P6 | H | H | P9 | H | H | H | F | H | O |
| Lₐ₁₈₀₈ | P6 | H | H | P10 | H | H | H | F | H | O |
| Lₐ₁₈₀₉ | P6 | H | H | P11 | H | H | H | F | H | O |
| Lₐ₁₈₁₀ | P6 | H | H | P12 | H | H | H | F | H | O |
| Lₐ₁₈₁₁ | P6 | H | H | P13 | H | H | H | F | H | O |
| Lₐ₁₈₁₂ | P6 | H | H | P14 | H | H | H | F | H | O |
| Lₐ₁₈₁₃ | P6 | H | H | P15 | H | H | H | F | H | O |
| Lₐ₁₈₁₄ | P6 | H | H | P16 | H | H | H | F | H | O |
| Lₐ₁₈₁₅ | P6 | H | H | P17 | H | H | H | F | H | O |
| Lₐ₁₈₁₆ | P6 | H | H | P18 | H | H | H | F | H | O |
| Lₐ₁₈₁₇ | P6 | H | H | P19 | H | H | H | F | H | O |
| Lₐ₁₈₁₈ | P6 | H | H | P20 | H | H | H | F | H | O |
| Lₐ₁₈₁₉ | P6 | H | H | P21 | H | H | H | F | H | O |
| Lₐ₁₈₂₀ | P6 | H | H | P22 | H | H | H | F | H | O |
| Lₐ₁₈₂₁ | P6 | H | H | P23 | H | H | H | F | H | O |
| Lₐ₁₈₂₂ | P6 | H | H | P24 | H | H | H | F | H | O |
| Lₐ₁₈₂₃ | P6 | H | H | P25 | H | H | H | F | H | O |
| Lₐ₁₈₂₄ | P6 | H | H | P26 | H | H | H | F | H | O |
| Lₐ₁₈₂₅ | P6 | H | H | P27 | H | H | H | F | H | O |
| Lₐ₁₈₂₆ | P6 | H | H | P28 | H | H | H | F | H | O |
| Lₐ₁₈₂₇ | P6 | H | H | P29 | H | H | H | F | H | O |
| Lₐ₁₈₂₈ | P6 | H | H | P30 | H | H | H | F | H | O |
| Lₐ₁₈₂₉ | P6 | H | H | P31 | H | H | H | F | H | O |
| Lₐ₁₈₃₀ | P6 | H | H | P32 | H | H | H | F | H | O |
| Lₐ₁₈₃₁ | P6 | H | H | P33 | H | H | H | F | H | O |
| Lₐ₁₈₃₂ | P6 | H | H | P34 | H | H | H | F | H | O |
| Lₐ₁₈₃₃ | P6 | H | P1 | P1 | H | H | H | F | H | O |
| Lₐ₁₈₃₄ | P6 | H | P2 | P2 | H | H | H | F | H | O |
| Lₐ₁₈₃₅ | P6 | H | F | H | H | H | H | F | H | O |
| Lₐ₁₈₃₆ | P6 | H | H | F | H | H | H | F | H | O |
| Lₐ₁₈₃₇ | P6 | H | F | P1 | H | H | H | F | H | O |
| Lₐ₁₈₃₈ | P6 | H | F | P2 | H | H | H | F | H | O |
| Lₐ₁₈₃₉ | P6 | H | P1 | F | H | H | H | F | H | O |
| Lₐ₁₈₄₀ | P6 | H | P2 | F | H | H | H | F | H | O |
| Lₐ₁₈₄₁ | P6 | H | H | H | H | H | H | F | D | O |
| Lₐ₁₈₄₂ | P6 | H | P1 | H | H | H | H | F | D | O |
| Lₐ₁₈₄₃ | P6 | H | P2 | H | H | H | H | F | D | O |
| Lₐ₁₈₄₄ | P6 | H | P3 | H | H | H | H | F | D | O |
| Lₐ₁₈₄₅ | P6 | H | P4 | H | H | H | H | F | D | O |
| Lₐ₁₈₄₆ | P6 | H | P5 | H | H | H | H | F | D | O |
| Lₐ₁₈₄₇ | P6 | H | P6 | H | H | H | H | F | D | O |
| Lₐ₁₈₄₈ | P6 | H | P7 | H | H | H | H | F | D | O |
| Lₐ₁₈₄₉ | P6 | H | P8 | H | H | H | H | F | D | O |
| Lₐ₁₈₅₀ | P6 | H | P9 | H | H | H | H | F | D | O |
| Lₐ₁₈₅₁ | P6 | H | P10 | H | H | H | H | F | D | O |
| Lₐ₁₈₅₂ | P6 | H | P11 | H | H | H | H | F | D | O |
| Lₐ₁₈₅₃ | P6 | H | P12 | H | H | H | H | F | D | O |
| Lₐ₁₈₅₄ | P6 | H | P13 | H | H | H | H | F | D | O |
| Lₐ₁₈₅₅ | P6 | H | P14 | H | H | H | H | F | D | O |
| Lₐ₁₈₅₆ | P6 | H | P15 | H | H | H | H | F | D | O |
| Lₐ₁₈₅₇ | P6 | H | P16 | H | H | H | H | F | D | O |
| Lₐ₁₈₅₈ | P6 | H | P17 | H | H | H | H | F | D | O |
| Lₐ₁₈₅₉ | P6 | H | P18 | H | H | H | H | F | D | O |
| Lₐ₁₈₆₀ | P6 | H | P19 | H | H | H | H | F | D | O |
| Lₐ₁₈₆₁ | P6 | H | P20 | H | H | H | H | F | D | O |
| Lₐ₁₈₆₂ | P6 | H | P21 | H | H | H | H | F | D | O |
| Lₐ₁₈₆₃ | P6 | H | P22 | H | H | H | H | F | D | O |
| Lₐ₁₈₆₄ | P6 | H | P23 | H | H | H | H | F | D | O |
| Lₐ₁₈₆₅ | P6 | H | P24 | H | H | H | H | F | D | O |
| Lₐ₁₈₆₆ | P6 | H | P25 | H | H | H | H | F | D | O |
| Lₐ₁₈₆₇ | P6 | H | P26 | H | H | H | H | F | D | O |
| Lₐ₁₈₆₈ | P6 | H | P27 | H | H | H | H | F | D | O |
| Lₐ₁₈₆₉ | P6 | H | P28 | H | H | H | H | F | D | O |
| Lₐ₁₈₇₀ | P6 | H | P29 | H | H | H | H | F | D | O |
| Lₐ₁₈₇₁ | P6 | H | P30 | H | H | H | H | F | D | O |
| Lₐ₁₈₇₂ | P6 | H | P31 | H | H | H | H | F | D | O |
| Lₐ₁₈₇₃ | P6 | H | P32 | H | H | H | H | F | D | O |
| Lₐ₁₈₇₄ | P6 | H | P33 | H | H | H | H | F | D | O |
| Lₐ₁₈₇₅ | P6 | H | P34 | H | H | H | H | F | D | O |
| Lₐ₁₈₇₆ | P6 | H | H | P1 | H | H | H | F | D | O |
| Lₐ₁₈₇₇ | P6 | H | H | P2 | H | H | H | F | D | O |
| Lₐ₁₈₇₈ | P6 | H | H | P3 | H | H | H | F | D | O |
| Lₐ₁₈₇₉ | P6 | H | H | P4 | H | H | H | F | D | O |
| Lₐ₁₈₈₀ | P6 | H | H | P5 | H | H | H | F | D | O |
| Lₐ₁₈₈₁ | P6 | H | H | P6 | H | H | H | F | D | O |
| Lₐ₁₈₈₂ | P6 | H | H | P7 | H | H | H | F | D | O |
| Lₐ₁₈₈₃ | P6 | H | H | P8 | H | H | H | F | D | O |
| Lₐ₁₈₈₄ | P6 | H | H | P9 | H | H | H | F | D | O |
| Lₐ₁₈₈₅ | P6 | H | H | P10 | H | H | H | F | D | O |
| Lₐ₁₈₈₆ | P6 | H | H | P11 | H | H | H | F | D | O |
| Lₐ₁₈₈₇ | P6 | H | H | P12 | H | H | H | F | D | O |
| Lₐ₁₈₈₈ | P6 | H | H | P13 | H | H | H | F | D | O |
| Lₐ₁₈₈₉ | P6 | H | H | P14 | H | H | H | F | D | O |
| Lₐ₁₈₉₀ | P6 | H | H | P15 | H | H | H | F | D | O |
| Lₐ₁₈₉₁ | P6 | H | H | P16 | H | H | H | F | D | O |
| Lₐ₁₈₉₂ | P6 | H | H | P17 | H | H | H | F | D | O |
| Lₐ₁₈₉₃ | P6 | H | H | P18 | H | H | H | F | D | O |
| Lₐ₁₈₉₄ | P6 | H | H | P19 | H | H | H | F | D | O |
| Lₐ₁₈₉₅ | P6 | H | H | P20 | H | H | H | F | D | O |
| Lₐ₁₈₉₆ | P6 | H | H | P21 | H | H | H | F | D | O |
| Lₐ₁₈₉₇ | P6 | H | H | P22 | H | H | H | F | D | O |
| Lₐ₁₈₉₈ | P6 | H | H | P23 | H | H | H | F | D | O |
| Lₐ₁₈₉₉ | P6 | H | H | P24 | H | H | H | F | D | O |
| Lₐ₁₉₀₀ | P6 | H | H | P25 | H | H | H | F | D | O |
| Lₐ₁₉₀₁ | P6 | H | H | P26 | H | H | H | F | D | O |
| Lₐ₁₉₀₂ | P6 | H | H | P27 | H | H | H | F | D | O |
| Lₐ₁₉₀₃ | P6 | H | H | P28 | H | H | H | F | D | O |
| Lₐ₁₉₀₄ | P6 | H | H | P29 | H | H | H | F | D | O |
| Lₐ₁₉₀₅ | P6 | H | H | P30 | H | H | H | F | D | O |
| Lₐ₁₉₀₆ | P6 | H | H | P31 | H | H | H | F | D | O |
| Lₐ₁₉₀₇ | P6 | H | H | P32 | H | H | H | F | D | O |
| Lₐ₁₉₀₈ | P6 | H | H | P33 | H | H | H | F | D | O |
| Lₐ₁₉₀₉ | P6 | H | H | P34 | H | H | H | F | D | O |
| Lₐ₁₉₁₀ | P6 | H | P1 | P1 | H | H | H | F | D | O |
| Lₐ₁₉₁₁ | P6 | H | P2 | P2 | H | H | H | F | D | O |
| Lₐ₁₉₁₂ | P6 | H | F | H | H | H | H | F | D | O |
| Lₐ₁₉₁₃ | P6 | H | H | F | H | H | H | F | D | O |
| Lₐ₁₉₁₄ | P6 | H | F | P1 | H | H | H | F | D | O |
| Lₐ₁₉₁₅ | P6 | H | F | P2 | H | H | H | F | D | O |
| Lₐ₁₉₁₆ | P6 | H | P1 | F | H | H | H | F | D | O |
| Lₐ₁₉₁₇ | P6 | H | P2 | F | H | H | H | F | D | O |
| Lₐ₁₉₁₈ | P6 | D | H | P1 | H | H | H | F | H | O |
| Lₐ₁₉₁₉ | P6 | H | H | P2 | D | H | H | F | H | O |
| Lₐ₁₉₂₀ | P6 | H | H | H | H | H | H | F | P23 | O |
| Lₐ₁₉₂₁ | P6 | H | H | H | H | H | H | F | P24 | O |
| Lₐ₁₉₂₂ | P6 | H | H | H | H | H | H | F | P25 | O |
| Lₐ₁₉₂₃ | P6 | H | H | H | H | H | H | F | P26 | O |
| Lₐ₁₉₂₄ | P6 | H | H | H | H | H | H | F | P27 | O |
| Lₐ₁₉₂₅ | P6 | H | H | H | H | H | H | F | P28 | O |
| Lₐ₁₉₂₆ | P6 | H | H | H | H | H | H | F | P29 | O |
| Lₐ₁₉₂₇ | P6 | H | H | H | H | H | H | F | P30 | O |
| Lₐ₁₉₂₈ | P6 | H | H | H | H | H | H | F | P31 | O |
| Lₐ₁₉₂₉ | P6 | H | H | H | H | H | H | F | P32 | O |
| Lₐ₁₉₃₀ | P6 | H | H | H | H | H | H | F | P33 | O |
| Lₐ₁₉₃₁ | P6 | H | H | H | H | H | H | F | P34 | O |
| Lₐ₁₉₃₂ | P6 | H | H | H | H | H | H | F | P35 | O |
| Lₐ₁₉₃₃ | P6 | H | H | H | H | H | H | F | P36 | O |
| Lₐ₁₉₃₄ | P6 | H | H | H | H | H | H | F | P37 | O |
| Lₐ₁₉₃₅ | P6 | H | H | H | H | H | H | F | P38 | O |
| Lₐ₁₉₃₆ | P6 | H | H | H | H | H | H | F | P39 | O |
| Lₐ₁₉₃₇ | P6 | H | H | H | H | H | H | F | P40 | O |
| Lₐ₁₉₃₈ | P6 | H | H | H | H | H | H | F | P41 | O |
| Lₐ₁₉₃₉ | P6 | H | H | H | H | H | H | F | P42 | O |
| Lₐ₁₉₄₀ | P6 | H | H | H | H | H | H | F | P43 | O |
| Lₐ₁₉₄₁ | P6 | H | H | H | H | H | H | F | P44 | O |
| Lₐ₁₉₄₂ | P6 | H | H | H | H | H | H | F | P45 | O |
| Lₐ₁₉₄₃ | P6 | H | H | H | H | H | H | F | P46 | O |
| Lₐ₁₉₄₄ | P6 | H | H | H | H | H | H | F | P47 | O |
| Lₐ₁₉₄₅ | P6 | H | H | H | H | H | H | F | P48 | O |
| Lₐ₁₉₄₆ | P6 | H | H | H | H | H | H | F | P49 | O |
| Lₐ₁₉₄₇ | P6 | H | H | H | H | H | H | F | P50 | O |
| Lₐ₁₉₄₈ | P6 | H | H | H | H | H | H | F | P51 | O |
| Lₐ₁₉₄₉ | P6 | H | H | H | H | H | H | F | P52 | O |
| Lₐ₁₉₅₀ | P6 | H | H | H | H | H | H | F | P53 | O |
| Lₐ₁₉₅₁ | P6 | H | H | H | H | H | H | F | P54 | O |
| Lₐ₁₉₅₂ | P6 | H | H | H | H | H | H | F | P55 | O |
| Lₐ₁₉₅₃ | P6 | H | H | H | H | H | H | F | P56 | O |
| Lₐ₁₉₅₄ | P6 | H | H | H | H | H | H | F | P57 | O |
| Lₐ₁₉₅₅ | P6 | H | H | H | H | H | H | F | P58 | O |
| Lₐ₁₉₅₆ | P6 | H | H | H | H | H | H | F | P59 | O |
| Lₐ₁₉₅₇ | P6 | H | H | H | H | H | H | F | P60 | O |
| Lₐ₁₉₅₈ | P6 | H | H | H | H | H | H | F | P61 | O |
| Lₐ₁₉₅₉ | P6 | H | H | H | H | H | H | F | P62 | O |
| Lₐ₁₉₆₀ | P6 | H | H | H | H | H | H | F | P63 | O |
| Lₐ₁₉₆₁ | P6 | H | H | H | H | H | H | F | P64 | O |
| Lₐ₁₉₆₂ | P6 | H | H | H | H | H | H | F | P65 | O |
| Lₐ₁₉₆₃ | P6 | H | H | H | H | H | H | F | P66 | O |
| Lₐ₁₉₆₄ | P6 | H | H | H | H | H | H | F | P67 | O |
| Lₐ₁₉₆₅ | P6 | H | H | H | H | H | H | F | P68 | O |
| Lₐ₁₉₆₆ | P6 | H | H | H | H | H | H | F | P69 | O |
| Lₐ₁₉₆₇ | P6 | H | H | H | H | H | H | F | P70 | O |
| Lₐ₁₉₆₈ | P6 | H | H | H | H | H | H | F | P71 | O |
| Lₐ₁₉₆₉ | P6 | H | H | H | H | H | H | F | P72 | O |
| Lₐ₁₉₇₀ | P6 | H | H | H | H | H | H | F | P73 | O |
| Lₐ₁₉₇₁ | P6 | H | H | H | H | H | H | F | P74 | O |
| Lₐ₁₉₇₂ | P6 | H | H | H | H | H | H | F | P75 | O |
| Lₐ₁₉₇₃ | P6 | H | H | H | H | H | H | F | P76 | O |
| Lₐ₁₉₇₄ | P6 | H | H | H | H | H | H | F | P77 | O |
| Lₐ₁₉₇₅ | P6 | H | H | H | H | H | H | F | P78 | O |
| Lₐ₁₉₇₆ | P6 | H | H | H | H | H | H | F | P79 | O |
| Lₐ₁₉₇₇ | P6 | H | H | H | H | H | H | F | P80 | O |
| Lₐ₁₉₇₈ | P6 | H | H | H | H | H | H | F | P81 | O |
| Lₐ₁₉₇₉ | P6 | H | H | H | H | H | H | F | P82 | O |
| Lₐ₁₉₈₀ | P6 | H | H | H | H | H | H | F | P83 | O |
| Lₐ₁₉₈₁ | P6 | H | H | H | H | H | H | F | P84 | O |
| Lₐ₁₉₈₂ | P6 | H | H | H | H | H | H | F | P85 | O |
| Lₐ₁₉₈₃ | P6 | H | H | H | H | H | H | F | P86 | O |
| Lₐ₁₉₈₄ | P6 | H | H | H | H | H | H | F | P87 | O |
| Lₐ₁₉₈₅ | P6 | H | H | H | H | H | H | F | P88 | O |
| Lₐ₁₉₈₆ | P6 | H | H | H | H | H | H | F | P89 | O |
| Lₐ₁₉₈₇ | P6 | H | H | H | H | H | H | F | P90 | O |
| Lₐ₁₉₈₈ | P6 | H | P1 | H | H | H | H | F | P23 | O |
| Lₐ₁₉₈₉ | P6 | H | P2 | H | H | H | H | F | P23 | O |
| Lₐ₁₉₉₀ | P6 | H | P3 | H | H | H | H | F | P23 | O |
| Lₐ₁₉₉₁ | P6 | H | P4 | H | H | H | H | F | P23 | O |
| Lₐ₁₉₉₂ | P6 | H | P5 | H | H | H | H | F | P23 | O |
| Lₐ₁₉₉₃ | P6 | H | P6 | H | H | H | H | F | P23 | O |
| Lₐ₁₉₉₄ | P6 | H | P7 | H | H | H | H | F | P23 | O |
| Lₐ₁₉₉₅ | P6 | H | P8 | H | H | H | H | F | P23 | O |
| Lₐ₁₉₉₆ | P6 | H | P9 | H | H | H | H | F | P23 | O |
| Lₐ₁₉₉₇ | P6 | H | P10 | H | H | H | H | F | P23 | O |
| Lₐ₁₉₉₈ | P6 | H | P11 | H | H | H | H | F | P23 | O |
| Lₐ₁₉₉₉ | P6 | H | P12 | H | H | H | H | F | P23 | O |
| Lₐ₂₀₀₀ | P6 | H | P15 | H | H | H | H | F | P23 | O |
| Lₐ₂₀₀₁ | P6 | H | P17 | H | H | H | H | F | P23 | O |
| Lₐ₂₀₀₂ | P6 | H | H | P1 | H | H | H | F | P23 | O |
| Lₐ₂₀₀₃ | P6 | H | H | P2 | H | H | H | F | P23 | O |
| Lₐ₂₀₀₄ | P6 | H | H | P3 | H | H | H | F | P23 | O |
| Lₐ₂₀₀₅ | P6 | H | H | P4 | H | H | H | F | P23 | O |
| Lₐ₂₀₀₆ | P6 | H | H | P5 | H | H | H | F | P23 | O |
| Lₐ₂₀₀₇ | P6 | H | H | P6 | H | H | H | F | P23 | O |
| Lₐ₂₀₀₈ | P6 | H | H | P7 | H | H | H | F | P23 | O |
| Lₐ₂₀₀₉ | P6 | H | H | P8 | H | H | H | F | P23 | O |
| Lₐ₂₀₁₀ | P6 | H | H | P9 | H | H | H | F | P23 | O |
| Lₐ₂₀₁₁ | P6 | H | H | P10 | H | H | H | F | P23 | O |
| Lₐ₂₀₁₂ | P6 | H | H | P11 | H | H | H | F | P23 | O |
| Lₐ₂₀₁₃ | P6 | H | H | P12 | H | H | H | F | P23 | O |
| Lₐ₂₀₁₄ | P6 | H | H | P15 | H | H | H | F | P23 | O |
| Lₐ₂₀₁₅ | P6 | H | H | P17 | H | H | H | F | P23 | O |
| Lₐ₂₀₁₆ | P6 | H | F | H | H | H | H | F | P23 | O |
| Lₐ₂₀₁₇ | P6 | H | H | F | H | H | H | F | P23 | O |
| Lₐ₂₀₁₈ | P6 | H | F | P1 | H | H | H | F | P23 | O |
| Lₐ₂₀₁₉ | P6 | H | F | P2 | H | H | H | F | P23 | O |
| Lₐ₂₀₂₀ | P6 | H | P1 | F | H | H | H | F | P23 | O |
| Lₐ₂₀₂₁ | P6 | H | P2 | F | H | H | H | F | P23 | O |
| Lₐ₂₀₂₂ | P6 | H | P1 | P1 | H | H | H | F | P23 | O |
| Lₐ₂₀₂₃ | P6 | H | P2 | P2 | H | H | H | F | P23 | O |
| Lₐ₂₀₂₄ | P6 | H | P1 | H | H | H | H | F | P24 | O |
| Lₐ₂₀₂₅ | P6 | H | P2 | H | H | H | H | F | P24 | O |
| Lₐ₂₀₂₆ | P6 | H | P3 | H | H | H | H | F | P24 | O |
| Lₐ₂₀₂₇ | P6 | H | P4 | H | H | H | H | F | P24 | O |
| Lₐ₂₀₂₈ | P6 | H | P5 | H | H | H | H | F | P24 | O |
| Lₐ₂₀₂₉ | P6 | H | P6 | H | H | H | H | F | P24 | O |
| Lₐ₂₀₃₀ | P6 | H | P7 | H | H | H | H | F | P24 | O |
| Lₐ₂₀₃₁ | P6 | H | P8 | H | H | H | H | F | P24 | O |
| Lₐ₂₀₃₂ | P6 | H | P9 | H | H | H | H | F | P24 | O |
| Lₐ₂₀₃₃ | P6 | H | P10 | H | H | H | H | F | P24 | O |
| Lₐ₂₀₃₄ | P6 | H | P11 | H | H | H | H | F | P24 | O |
| Lₐ₂₀₃₅ | P6 | H | P12 | H | H | H | H | F | P24 | O |
| Lₐ₂₀₃₆ | P6 | H | P15 | H | H | H | H | F | P24 | O |
| Lₐ₂₀₃₇ | P6 | H | P17 | H | H | H | H | F | P24 | O |
| Lₐ₂₀₃₈ | P6 | H | H | P1 | H | H | H | F | P24 | O |
| Lₐ₂₀₃₉ | P6 | H | H | P2 | H | H | H | F | P24 | O |
| Lₐ₂₀₄₀ | P6 | H | H | P3 | H | H | H | F | P24 | O |
| Lₐ₂₀₄₁ | P6 | H | H | P4 | H | H | H | F | P24 | O |
| Lₐ₂₀₄₂ | P6 | H | H | P5 | H | H | H | F | P24 | O |
| Lₐ₂₀₄₃ | P6 | H | H | P6 | H | H | H | F | P24 | O |
| Lₐ₂₀₄₄ | P6 | H | H | P7 | H | H | H | F | P24 | O |
| Lₐ₂₀₄₅ | P6 | H | H | P8 | H | H | H | F | P24 | O |
| Lₐ₂₀₄₆ | P6 | H | H | P9 | H | H | H | F | P24 | O |
| Lₐ₂₀₄₇ | P6 | H | H | P10 | H | H | H | F | P24 | O |
| Lₐ₂₀₄₈ | P6 | H | H | P11 | H | H | H | F | P24 | O |
| Lₐ₂₀₄₉ | P6 | H | H | P12 | H | H | H | F | P24 | O |
| Lₐ₂₀₅₀ | P6 | H | H | P15 | H | H | H | F | P24 | O |
| Lₐ₂₀₅₁ | P6 | H | H | P17 | H | H | H | F | P24 | O |
| Lₐ₂₀₅₂ | P6 | H | F | H | H | H | H | F | P24 | O |
| Lₐ₂₀₅₃ | P6 | H | H | F | H | H | H | F | P24 | O |
| Lₐ₂₀₅₄ | P6 | H | F | P1 | H | H | H | F | P24 | O |
| Lₐ₂₀₅₅ | P6 | H | F | P2 | H | H | H | F | P24 | O |
| Lₐ₂₀₅₆ | P6 | H | P1 | F | H | H | H | F | P24 | O |
| Lₐ₂₀₅₇ | P6 | H | P2 | F | H | H | H | F | P24 | O |
| Lₐ₂₀₅₈ | P6 | H | P1 | P1 | H | H | H | F | P24 | O |
| Lₐ₂₀₅₉ | P6 | H | P2 | P2 | H | H | H | F | P24 | O |
| Lₐ₂₀₆₀ | P6 | H | P1 | H | H | H | H | F | P56 | O |
| Lₐ₂₀₆₁ | P6 | H | P2 | H | H | H | H | F | P56 | O |
| Lₐ₂₀₆₂ | P6 | H | P3 | H | H | H | H | F | P56 | O |
| Lₐ₂₀₆₃ | P6 | H | P4 | H | H | H | H | F | P56 | O |
| Lₐ₂₀₆₄ | P6 | H | P5 | H | H | H | H | F | P56 | O |
| Lₐ₂₀₆₅ | P6 | H | P6 | H | H | H | H | F | P56 | O |
| Lₐ₂₀₆₆ | P6 | H | P7 | H | H | H | H | F | P56 | O |
| Lₐ₂₀₆₇ | P6 | H | P8 | H | H | H | H | F | P56 | O |
| Lₐ₂₀₆₈ | P6 | H | P9 | H | H | H | H | F | P56 | O |
| Lₐ₂₀₆₉ | P6 | H | P10 | H | H | H | H | F | P56 | O |
| Lₐ₂₀₇₀ | P6 | H | P11 | H | H | H | H | F | P56 | O |
| Lₐ₂₀₇₁ | P6 | H | P12 | H | H | H | H | F | P56 | O |
| Lₐ₂₀₇₂ | P6 | H | P15 | H | H | H | H | F | P56 | O |
| Lₐ₂₀₇₃ | P6 | H | P17 | H | H | H | H | F | P56 | O |
| Lₐ₂₀₇₄ | P6 | H | H | P1 | H | H | H | F | P56 | O |
| Lₐ₂₀₇₅ | P6 | H | H | P2 | H | H | H | F | P56 | O |
| Lₐ₂₀₇₆ | P6 | H | H | P3 | H | H | H | F | P56 | O |
| Lₐ₂₀₇₇ | P6 | H | H | P4 | H | H | H | F | P56 | O |
| Lₐ₂₀₇₈ | P6 | H | H | P5 | H | H | H | F | P56 | O |
| Lₐ₂₀₇₉ | P6 | H | H | P6 | H | H | H | F | P56 | O |
| Lₐ₂₀₈₀ | P6 | H | H | P7 | H | H | H | F | P56 | O |
| Lₐ₂₀₈₁ | P6 | H | H | P8 | H | H | H | F | P56 | O |
| Lₐ₂₀₈₂ | P6 | H | H | P9 | H | H | H | F | P56 | O |
| Lₐ₂₀₈₃ | P6 | H | H | P10 | H | H | H | F | P56 | O |
| Lₐ₂₀₈₄ | P6 | H | H | P11 | H | H | H | F | P56 | O |
| Lₐ₂₀₈₅ | P6 | H | H | P12 | H | H | H | F | P56 | O |
| Lₐ₂₀₈₆ | P6 | H | H | P15 | H | H | H | F | P56 | O |
| Lₐ₂₀₈₇ | P6 | H | H | P17 | H | H | H | F | P56 | O |
| Lₐ₂₀₈₈ | P6 | H | F | H | H | H | H | F | P56 | O |
| Lₐ₂₀₈₉ | P6 | H | H | F | H | H | H | F | P56 | O |
| Lₐ₂₀₉₀ | P6 | H | F | P1 | H | H | H | F | P56 | O |
| Lₐ₂₀₉₁ | P6 | H | F | P2 | H | H | H | F | P56 | O |
| Lₐ₂₀₉₂ | P6 | H | P1 | F | H | H | H | F | P56 | O |
| Lₐ₂₀₉₃ | P6 | H | P2 | F | H | H | H | F | P56 | O |
| Lₐ₂₀₉₄ | P6 | H | P1 | P1 | H | H | H | F | P56 | O |
| Lₐ₂₀₉₅ | P6 | H | P2 | P2 | H | H | H | F | P56 | O |
| Lₐ₂₀₉₆ | P6 | H | P2 | H | H | H | H | F | P73 | O |
| Lₐ₂₀₉₇ | P6 | H | P3 | H | H | H | H | F | P73 | O |
| Lₐ₂₀₉₈ | P6 | H | P4 | H | H | H | H | F | P73 | O |
| Lₐ₂₀₉₉ | P6 | H | P5 | H | H | H | H | F | P73 | O |
| Lₐ₂₁₀₀ | P6 | H | P6 | H | H | H | H | F | P73 | O |
| Lₐ₂₁₀₁ | P6 | H | P7 | H | H | H | H | F | P73 | O |
| Lₐ₂₁₀₂ | P6 | H | P8 | H | H | H | H | F | P73 | O |
| Lₐ₂₁₀₃ | P6 | H | P9 | H | H | H | H | F | P73 | O |
| Lₐ₂₁₀₄ | P6 | H | P10 | H | H | H | H | F | P73 | O |
| Lₐ₂₁₀₅ | P6 | H | P11 | H | H | H | H | F | P73 | O |
| Lₐ₂₁₀₆ | P6 | H | P12 | H | H | H | H | F | P73 | O |
| Lₐ₂₁₀₇ | P6 | H | P15 | H | H | H | H | F | P73 | O |
| Lₐ₂₁₀₈ | P6 | H | P17 | H | H | H | H | F | P73 | O |
| Lₐ₂₁₀₉ | P6 | H | H | P1 | H | H | H | F | P73 | O |
| Lₐ₂₁₁₀ | P6 | H | H | P2 | H | H | H | F | P73 | O |
| Lₐ₂₁₁₁ | P6 | H | H | P3 | H | H | H | F | P73 | O |
| Lₐ₂₁₁₂ | P6 | H | H | P4 | H | H | H | F | P73 | O |
| Lₐ₂₁₁₃ | P6 | H | H | P5 | H | H | H | F | P73 | O |
| Lₐ₂₁₁₄ | P6 | H | H | P6 | H | H | H | F | P73 | O |
| Lₐ₂₁₁₅ | P6 | H | H | P7 | H | H | H | F | P73 | O |
| Lₐ₂₁₁₆ | P6 | H | H | P8 | H | H | H | F | P73 | O |
| Lₐ₂₁₁₇ | P6 | H | H | P9 | H | H | H | F | P73 | O |
| Lₐ₂₁₁₈ | P6 | H | H | P10 | H | H | H | F | P73 | O |
| Lₐ₂₁₁₉ | P6 | H | H | P11 | H | H | H | F | P73 | O |
| Lₐ₂₁₂₀ | P6 | H | H | P12 | H | H | H | F | P73 | O |
| Lₐ₂₁₂₁ | P6 | H | H | P15 | H | H | H | F | P73 | O |
| Lₐ₂₁₂₂ | P6 | H | H | P17 | H | H | H | F | P73 | O |
| Lₐ₂₁₂₃ | P6 | H | F | H | H | H | H | F | P73 | O |
| Lₐ₂₁₂₄ | P6 | H | H | F | H | H | H | F | P73 | O |
| Lₐ₂₁₂₅ | P6 | H | F | P1 | H | H | H | F | P73 | O |
| Lₐ₂₁₂₆ | P6 | H | F | P2 | H | H | H | F | P73 | O |
| Lₐ₂₁₂₇ | P6 | H | P1 | F | H | H | H | F | P73 | O |
| Lₐ₂₁₂₈ | P6 | H | P2 | F | H | H | H | F | P73 | O |
| Lₐ₂₁₂₉ | P6 | H | P1 | P1 | H | H | H | F | P73 | O |
| Lₐ₂₁₃₀ | P6 | H | P2 | P2 | H | H | H | F | P73 | O |
| Lₐ₂₁₃₁ | P6 | H | P1 | H | H | H | H | F | P74 | O |
| Lₐ₂₁₃₂ | P6 | H | P2 | H | H | H | H | F | P74 | O |
| Lₐ₂₁₃₃ | P6 | H | P3 | H | H | H | H | F | P74 | O |
| Lₐ₂₁₃₄ | P6 | H | P4 | H | H | H | H | F | P74 | O |
| Lₐ₂₁₃₅ | P6 | H | P5 | H | H | H | H | F | P74 | O |
| Lₐ₂₁₃₆ | P6 | H | P6 | H | H | H | H | F | P74 | O |
| Lₐ₂₁₃₇ | P6 | H | P7 | H | H | H | H | F | P74 | O |
| Lₐ₂₁₃₈ | P6 | H | P8 | H | H | H | H | F | P74 | O |
| Lₐ₂₁₃₉ | P6 | H | P9 | H | H | H | H | F | P74 | O |
| Lₐ₂₁₄₀ | P6 | H | P10 | H | H | H | H | F | P74 | O |
| Lₐ₂₁₄₁ | P6 | H | P11 | H | H | H | H | F | P74 | O |
| Lₐ₂₁₄₂ | P6 | H | P12 | H | H | H | H | F | P74 | O |
| Lₐ₂₁₄₃ | P6 | H | P15 | H | H | H | H | F | P74 | O |
| Lₐ₂₁₄₄ | P6 | H | P17 | H | H | H | H | F | P74 | O |
| Lₐ₂₁₄₅ | P6 | H | H | P1 | H | H | H | F | P74 | O |
| Lₐ₂₁₄₆ | P6 | H | H | P2 | H | H | H | F | P74 | O |
| Lₐ₂₁₄₇ | P6 | H | H | P3 | H | H | H | F | P74 | O |
| Lₐ₂₁₄₈ | P6 | H | H | P4 | H | H | H | F | P74 | O |
| Lₐ₂₁₄₉ | P6 | H | H | P5 | H | H | H | F | P74 | O |
| Lₐ₂₁₅₀ | P6 | H | H | P6 | H | H | H | F | P74 | O |
| Lₐ₂₁₅₁ | P6 | H | H | P7 | H | H | H | F | P74 | O |
| Lₐ₂₁₅₂ | P6 | H | H | P8 | H | H | H | F | P74 | O |
| Lₐ₂₁₅₃ | P6 | H | H | P9 | H | H | H | F | P74 | O |
| Lₐ₂₁₅₄ | P6 | H | H | P10 | H | H | H | F | P74 | O |
| Lₐ₂₁₅₅ | P6 | H | H | P11 | H | H | H | F | P74 | O |
| Lₐ₂₁₅₆ | P6 | H | H | P12 | H | H | H | F | P74 | O |
| Lₐ₂₁₅₇ | P6 | H | H | P15 | H | H | H | F | P74 | O |
| Lₐ₂₁₅₈ | P6 | H | H | P17 | H | H | H | F | P74 | O |
| Lₐ₂₁₅₉ | P6 | H | F | H | H | H | H | F | P74 | O |
| Lₐ₂₁₆₀ | P6 | H | H | F | H | H | H | F | P74 | O |
| Lₐ₂₁₆₁ | P6 | H | F | P1 | H | H | H | F | P74 | O |
| Lₐ₂₁₆₂ | P6 | H | F | P2 | H | H | H | F | P74 | O |
| Lₐ₂₁₆₃ | P6 | H | P1 | F | H | H | H | F | P74 | O |
| Lₐ₂₁₆₄ | P6 | H | P2 | F | H | H | H | F | P74 | O |
| Lₐ₂₁₆₅ | P6 | H | P1 | P1 | H | H | H | F | P74 | O |
| Lₐ₂₁₆₆ | P6 | H | P2 | P2 | H | H | H | F | P74 | O |
| Lₐ₂₁₆₇ | P6 | H | P1 | H | H | H | H | F | P79 | O |
| Lₐ₂₁₆₈ | P6 | H | P2 | H | H | H | H | F | P79 | O |
| Lₐ₂₁₆₉ | P6 | H | P3 | H | H | H | H | F | P79 | O |
| Lₐ₂₁₇₀ | P6 | H | P4 | H | H | H | H | F | P79 | O |
| Lₐ₂₁₇₁ | P6 | H | P5 | H | H | H | H | F | P79 | O |
| Lₐ₂₁₇₂ | P6 | H | P6 | H | H | H | H | F | P79 | O |
| Lₐ₂₁₇₃ | P6 | H | P7 | H | H | H | H | F | P79 | O |
| Lₐ₂₁₇₄ | P6 | H | P8 | H | H | H | H | F | P79 | O |
| Lₐ₂₁₇₅ | P6 | H | P9 | H | H | H | H | F | P79 | O |
| Lₐ₂₁₇₆ | P6 | H | P10 | H | H | H | H | F | P79 | O |
| Lₐ₂₁₇₇ | P6 | H | P11 | H | H | H | H | F | P79 | O |
| Lₐ₂₁₇₈ | P6 | H | P12 | H | H | H | H | F | P79 | O |
| Lₐ₂₁₇₉ | P6 | H | P15 | H | H | H | H | F | P79 | O |
| Lₐ₂₁₈₀ | P6 | H | P17 | H | H | H | H | F | P79 | O |
| Lₐ₂₁₈₁ | P6 | H | H | P1 | H | H | H | F | P79 | O |
| Lₐ₂₁₈₂ | P6 | H | H | P2 | H | H | H | F | P79 | O |
| Lₐ₂₁₈₃ | P6 | H | H | P3 | H | H | H | F | P79 | O |
| Lₐ₂₁₈₄ | P6 | H | H | P4 | H | H | H | F | P79 | O |
| Lₐ₂₁₈₅ | P6 | H | H | P5 | H | H | H | F | P79 | O |
| Lₐ₂₁₈₆ | P6 | H | H | P6 | H | H | H | F | P79 | O |
| Lₐ₂₁₈₇ | P6 | H | H | P7 | H | H | H | F | P79 | O |
| Lₐ₂₁₈₈ | P6 | H | H | P8 | H | H | H | F | P79 | O |
| Lₐ₂₁₈₉ | P6 | H | H | P9 | H | H | H | F | P79 | O |
| Lₐ₂₁₉₀ | P6 | H | H | P10 | H | H | H | F | P79 | O |
| Lₐ₂₁₉₁ | P6 | H | H | P11 | H | H | H | F | P79 | O |
| Lₐ₂₁₉₂ | P6 | H | H | P12 | H | H | H | F | P79 | O |
| Lₐ₂₁₉₃ | P6 | H | H | P15 | H | H | H | F | P79 | O |
| Lₐ₂₁₉₄ | P6 | H | H | P17 | H | H | H | F | P79 | O |
| Lₐ₂₁₉₅ | P6 | H | F | H | H | H | H | F | P79 | O |
| Lₐ₂₁₉₆ | P6 | H | H | F | H | H | H | F | P79 | O |
| Lₐ₂₁₉₇ | P6 | H | F | P1 | H | H | H | F | P79 | O |
| Lₐ₂₁₉₈ | P6 | H | F | P2 | H | H | H | F | P79 | O |
| Lₐ₂₁₉₉ | P6 | H | P1 | F | H | H | H | F | P79 | O |
| Lₐ₂₂₀₀ | P6 | H | P2 | F | H | H | H | F | P79 | O |
| Lₐ₂₂₀₁ | P6 | H | P1 | P1 | H | H | H | F | P79 | O |
| Lₐ₂₂₀₂ | P6 | H | P2 | P2 | H | H | H | F | P79 | O |
| Lₐ₂₂₀₃ | P6 | H | P1 | H | H | H | H | F | P80 | O |
| Lₐ₂₂₀₄ | P6 | H | P2 | H | H | H | H | F | P80 | O |
| Lₐ₂₂₀₅ | P6 | H | P3 | H | H | H | H | F | P80 | O |
| Lₐ₂₂₀₆ | P6 | H | P4 | H | H | H | H | F | P80 | O |
| Lₐ₂₂₀₇ | P6 | H | P5 | H | H | H | H | F | P80 | O |
| Lₐ₂₂₀₈ | P6 | H | P6 | H | H | H | H | F | P80 | O |
| Lₐ₂₂₀₉ | P6 | H | P7 | H | H | H | H | F | P80 | O |
| Lₐ₂₂₁₀ | P6 | H | P8 | H | H | H | H | F | P80 | O |
| Lₐ₂₂₁₁ | P6 | H | P9 | H | H | H | H | F | P80 | O |
| Lₐ₂₂₁₂ | P6 | H | P10 | H | H | H | H | F | P80 | O |
| Lₐ₂₂₁₃ | P6 | H | P11 | H | H | H | H | F | P80 | O |
| Lₐ₂₂₁₄ | P6 | H | P12 | H | H | H | H | F | P80 | O |
| Lₐ₂₂₁₅ | P6 | H | P15 | H | H | H | H | F | P80 | O |
| Lₐ₂₂₁₆ | P6 | H | P17 | H | H | H | H | F | P80 | O |
| Lₐ₂₂₁₇ | P6 | H | H | P1 | H | H | H | F | P80 | O |
| Lₐ₂₂₁₈ | P6 | H | H | P2 | H | H | H | F | P80 | O |
| Lₐ₂₂₁₉ | P6 | H | H | P3 | H | H | H | F | P80 | O |
| Lₐ₂₂₂₀ | P6 | H | H | P4 | H | H | H | F | P80 | O |
| Lₐ₂₂₂₁ | P6 | H | H | P5 | H | H | H | F | P80 | O |
| Lₐ₂₂₂₂ | P6 | H | H | P6 | H | H | H | F | P80 | O |
| Lₐ₂₂₂₃ | P6 | H | H | P7 | H | H | H | F | P80 | O |
| Lₐ₂₂₂₄ | P6 | H | H | P8 | H | H | H | F | P80 | O |
| Lₐ₂₂₂₅ | P6 | H | H | P9 | H | H | H | F | P80 | O |
| Lₐ₂₂₂₆ | P6 | H | H | P10 | H | H | H | F | P80 | O |
| Lₐ₂₂₂₇ | P6 | H | H | P11 | H | H | H | F | P80 | O |
| Lₐ₂₂₂₈ | P6 | H | H | P12 | H | H | H | F | P80 | O |
| Lₐ₂₂₂₉ | P6 | H | H | P15 | H | H | H | F | P80 | O |
| Lₐ₂₂₃₀ | P6 | H | H | P17 | H | H | H | F | P80 | O |
| Lₐ₂₂₃₁ | P6 | H | F | H | H | H | H | F | P80 | O |
| Lₐ₂₂₃₂ | P6 | H | H | F | H | H | H | F | P80 | O |
| Lₐ₂₂₃₃ | P6 | H | F | P1 | H | H | H | F | P80 | O |
| Lₐ₂₂₃₄ | P6 | H | F | P2 | H | H | H | F | P80 | O |
| Lₐ₂₂₃₅ | P6 | H | P1 | F | H | H | H | F | P80 | O |
| Lₐ₂₂₃₆ | P6 | H | P2 | F | H | H | H | F | P80 | O |
| Lₐ₂₂₃₇ | P6 | H | P1 | P1 | H | H | H | F | P80 | O |
| Lₐ₂₂₃₈ | P6 | H | P2 | P2 | H | H | H | F | P80 | O |
| Lₐ₂₂₃₉ | P6 | H | P1 | H | H | H | H | F | P89 | O |
| Lₐ₂₂₄₀ | P6 | H | P2 | H | H | H | H | F | P89 | O |
| Lₐ₂₂₄₁ | P6 | H | P3 | H | H | H | H | F | P89 | O |
| Lₐ₂₂₄₂ | P6 | H | P4 | H | H | H | H | F | P89 | O |
| Lₐ₂₂₄₃ | P6 | H | P5 | H | H | H | H | F | P89 | O |
| Lₐ₂₂₄₄ | P6 | H | P6 | H | H | H | H | F | P89 | O |
| Lₐ₂₂₄₅ | P6 | H | P7 | H | H | H | H | F | P89 | O |
| Lₐ₂₂₄₆ | P6 | H | P8 | H | H | H | H | F | P89 | O |
| Lₐ₂₂₄₇ | P6 | H | P9 | H | H | H | H | F | P89 | O |
| Lₐ₂₂₄₈ | P6 | H | P10 | H | H | H | H | F | P89 | O |
| Lₐ₂₂₄₉ | P6 | H | P11 | H | H | H | H | F | P89 | O |
| Lₐ₂₂₅₀ | P6 | H | P12 | H | H | H | H | F | P89 | O |
| Lₐ₂₂₅₁ | P6 | H | P15 | H | H | H | H | F | P89 | O |
| Lₐ₂₂₅₂ | P6 | H | P17 | H | H | H | H | F | P89 | O |
| Lₐ₂₂₅₃ | P6 | H | H | P1 | H | H | H | F | P89 | O |
| Lₐ₂₂₅₄ | P6 | H | H | P2 | H | H | H | F | P89 | O |
| Lₐ₂₂₅₅ | P6 | H | H | P3 | H | H | H | F | P89 | O |
| Lₐ₂₂₅₆ | P6 | H | H | P4 | H | H | H | F | P89 | O |
| Lₐ₂₂₅₇ | P6 | H | H | P5 | H | H | H | F | P89 | O |
| Lₐ₂₂₅₈ | P6 | H | H | P6 | H | H | H | F | P89 | O |
| Lₐ₂₂₅₉ | P6 | H | H | P7 | H | H | H | F | P89 | O |
| Lₐ₂₂₆₀ | P6 | H | H | P8 | H | H | H | F | P89 | O |
| Lₐ₂₂₆₁ | P6 | H | H | P9 | H | H | H | F | P89 | O |
| Lₐ₂₂₆₂ | P6 | H | H | P10 | H | H | H | F | P89 | O |
| Lₐ₂₂₆₃ | P6 | H | H | P11 | H | H | H | F | P89 | O |
| Lₐ₂₂₆₄ | P6 | H | H | P12 | H | H | H | F | P89 | O |
| Lₐ₂₂₆₅ | P6 | H | H | P15 | H | H | H | F | P89 | O |
| Lₐ₂₂₆₆ | P6 | H | H | P17 | H | H | H | F | P89 | O |
| Lₐ₂₂₆₇ | P6 | H | F | H | H | H | H | F | P89 | O |
| Lₐ₂₂₆₈ | P6 | H | H | F | H | H | H | F | P89 | O |
| Lₐ₂₂₆₉ | P6 | H | F | P1 | H | H | H | F | P89 | O |
| Lₐ₂₂₇₀ | P6 | H | F | P2 | H | H | H | F | P89 | O |
| Lₐ₂₂₇₁ | P6 | H | P1 | F | H | H | H | F | P89 | O |
| Lₐ₂₂₇₂ | P6 | H | P2 | F | H | H | H | F | P89 | O |
| Lₐ₂₂₇₃ | P6 | H | P1 | P1 | H | H | H | F | P89 | O |
| Lₐ₂₂₇₄ | P6 | H | P2 | P2 | H | H | H | F | P89 | O |
| Lₐ₂₂₇₅ | P11 | H | H | H | H | H | H | F | H | O |
| Lₐ₂₂₇₆ | P11 | H | P1 | H | H | H | H | F | H | O |
| Lₐ₂₂₇₇ | P11 | H | P2 | H | H | H | H | F | H | O |
| Lₐ₂₂₇₈ | P11 | H | P3 | H | H | H | H | F | H | O |
| Lₐ₂₂₇₉ | P11 | H | P4 | H | H | H | H | F | H | O |
| Lₐ₂₂₈₀ | P11 | H | P5 | H | H | H | H | F | H | O |
| Lₐ₂₂₈₁ | P11 | H | P6 | H | H | H | H | F | H | O |
| Lₐ₂₂₈₂ | P11 | H | P7 | H | H | H | H | F | H | O |
| Lₐ₂₂₈₃ | P11 | H | P8 | H | H | H | H | F | H | O |
| Lₐ₂₂₈₄ | P11 | H | P9 | H | H | H | H | F | H | O |
| Lₐ₂₂₈₅ | P11 | H | P10 | H | H | H | H | F | H | O |
| Lₐ₂₂₈₆ | P11 | H | P11 | H | H | H | H | F | H | O |
| Lₐ₂₂₈₇ | P11 | H | P12 | H | H | H | H | F | H | O |
| Lₐ₂₂₈₈ | P11 | H | P13 | H | H | H | H | F | H | O |
| Lₐ₂₂₈₉ | P11 | H | P14 | H | H | H | H | F | H | O |
| Lₐ₂₂₉₀ | P11 | H | P15 | H | H | H | H | F | H | O |
| Lₐ₂₂₉₁ | P11 | H | P16 | H | H | H | H | F | H | O |
| Lₐ₂₂₉₂ | P11 | H | P17 | H | H | H | H | F | H | O |
| Lₐ₂₂₉₃ | P11 | H | P18 | H | H | H | H | F | H | O |
| Lₐ₂₂₉₄ | P11 | H | P19 | H | H | H | H | F | H | O |
| Lₐ₂₂₉₅ | P11 | H | P20 | H | H | H | H | F | H | O |
| Lₐ₂₂₉₆ | P11 | H | P21 | H | H | H | H | F | H | O |
| Lₐ₂₂₉₇ | P11 | H | P22 | H | H | H | H | F | H | O |
| Lₐ₂₂₉₈ | P11 | H | P23 | H | H | H | H | F | H | O |
| Lₐ₂₂₉₉ | P11 | H | P24 | H | H | H | H | F | H | O |
| Lₐ₂₃₀₀ | P11 | H | P25 | H | H | H | H | F | H | O |
| Lₐ₂₃₀₁ | P11 | H | P26 | H | H | H | H | F | H | O |
| Lₐ₂₃₀₂ | P11 | H | P27 | H | H | H | H | F | H | O |
| Lₐ₂₃₀₃ | P11 | H | P28 | H | H | H | H | F | H | O |
| Lₐ₂₃₀₄ | P11 | H | P29 | H | H | H | H | F | H | O |
| Lₐ₂₃₀₅ | P11 | H | P30 | H | H | H | H | F | H | O |
| Lₐ₂₃₀₆ | P11 | H | P31 | H | H | H | H | F | H | O |
| Lₐ₂₃₀₇ | P11 | H | P32 | H | H | H | H | F | H | O |
| Lₐ₂₃₀₈ | P11 | H | P33 | H | H | H | H | F | H | O |
| Lₐ₂₃₀₉ | P11 | H | P34 | H | H | H | H | F | H | O |
| Lₐ₂₃₁₀ | P11 | H | H | P1 | H | H | H | F | H | O |
| Lₐ₂₃₁₁ | P11 | H | H | P2 | H | H | H | F | H | O |
| Lₐ₂₃₁₂ | P11 | H | H | P3 | H | H | H | F | H | O |
| Lₐ₂₃₁₃ | P11 | H | H | P4 | H | H | H | F | H | O |
| Lₐ₂₃₁₄ | P11 | H | H | P5 | H | H | H | F | H | O |
| Lₐ₂₃₁₅ | P11 | H | H | P6 | H | H | H | F | H | O |
| Lₐ₂₃₁₆ | P11 | H | H | P7 | H | H | H | F | H | O |
| Lₐ₂₃₁₇ | P11 | H | H | P8 | H | H | H | F | H | O |
| Lₐ₂₃₁₈ | P11 | H | H | P9 | H | H | H | F | H | O |
| Lₐ₂₃₁₉ | P11 | H | H | P10 | H | H | H | F | H | O |
| Lₐ₂₃₂₀ | P11 | H | H | P11 | H | H | H | F | H | O |
| Lₐ₂₃₂₁ | P11 | H | H | P12 | H | H | H | F | H | O |
| Lₐ₂₃₂₂ | P11 | H | H | P13 | H | H | H | F | H | O |
| Lₐ₂₃₂₃ | P11 | H | H | P14 | H | H | H | F | H | O |
| Lₐ₂₃₂₄ | P11 | H | H | P15 | H | H | H | F | H | O |
| Lₐ₂₃₂₅ | P11 | H | H | P16 | H | H | H | F | H | O |
| Lₐ₂₃₂₆ | P11 | H | H | P17 | H | H | H | F | H | O |
| Lₐ₂₃₂₇ | P11 | H | H | P18 | H | H | H | F | H | O |
| Lₐ₂₃₂₈ | P11 | H | H | P19 | H | H | H | F | H | O |
| Lₐ₂₃₂₉ | P11 | H | H | P20 | H | H | H | F | H | O |
| Lₐ₂₃₃₀ | P11 | H | H | P21 | H | H | H | F | H | O |
| Lₐ₂₃₃₁ | P11 | H | H | P22 | H | H | H | F | H | O |
| Lₐ₂₃₃₂ | P11 | H | H | P23 | H | H | H | F | H | O |
| Lₐ₂₃₃₃ | P11 | H | H | P24 | H | H | H | F | H | O |
| Lₐ₂₃₃₄ | P11 | H | H | P25 | H | H | H | F | H | O |
| Lₐ₂₃₃₅ | P11 | H | H | P26 | H | H | H | F | H | O |
| Lₐ₂₃₃₆ | P11 | H | H | P27 | H | H | H | F | H | O |
| Lₐ₂₃₃₇ | P11 | H | H | P28 | H | H | H | F | H | O |
| Lₐ₂₃₃₈ | P11 | H | H | P29 | H | H | H | F | H | O |
| Lₐ₂₃₃₉ | P11 | H | H | P30 | H | H | H | F | H | O |
| Lₐ₂₃₄₀ | P11 | H | H | P31 | H | H | H | F | H | O |
| Lₐ₂₃₄₁ | P11 | H | H | P32 | H | H | H | F | H | O |
| Lₐ₂₃₄₂ | P11 | H | H | P33 | H | H | H | F | H | O |
| Lₐ₂₃₄₃ | P11 | H | H | P34 | H | H | H | F | H | O |
| Lₐ₂₃₄₄ | P11 | H | P1 | P1 | H | H | H | F | H | O |
| Lₐ₂₃₄₅ | P11 | H | P2 | P2 | H | H | H | F | H | O |
| Lₐ₂₃₄₆ | P11 | H | F | H | H | H | H | F | H | O |
| Lₐ₂₃₄₇ | P11 | H | H | F | H | H | H | F | H | O |
| Lₐ₂₃₄₈ | P11 | H | F | P1 | H | H | H | F | H | O |
| Lₐ₂₃₄₉ | P11 | H | F | P2 | H | H | H | F | H | O |
| Lₐ₂₃₅₀ | P11 | H | P1 | F | H | H | H | F | H | O |
| Lₐ₂₃₅₁ | P11 | H | P2 | F | H | H | H | F | H | O |
| Lₐ₂₃₅₂ | P11 | H | H | H | H | H | H | F | D | O |
| Lₐ₂₃₅₃ | P11 | H | P1 | H | H | H | H | F | D | O |
| Lₐ₂₃₅₄ | P11 | H | P2 | H | H | H | H | F | D | O |
| Lₐ₂₃₅₅ | P11 | H | P3 | H | H | H | H | F | D | O |
| Lₐ₂₃₅₆ | P11 | H | P4 | H | H | H | H | F | D | O |
| Lₐ₂₃₅₇ | P11 | H | P5 | H | H | H | H | F | D | O |
| Lₐ₂₃₅₈ | P11 | H | P6 | H | H | H | H | F | D | O |
| Lₐ₂₃₅₉ | P11 | H | P7 | H | H | H | H | F | D | O |
| Lₐ₂₃₆₀ | P11 | H | P8 | H | H | H | H | F | D | O |
| Lₐ₂₃₆₁ | P11 | H | P9 | H | H | H | H | F | D | O |
| Lₐ₂₃₆₂ | P11 | H | P10 | H | H | H | H | F | D | O |
| Lₐ₂₃₆₃ | P11 | H | P11 | H | H | H | H | F | D | O |
| Lₐ₂₃₆₄ | P11 | H | P12 | H | H | H | H | F | D | O |
| Lₐ₂₃₆₅ | P11 | H | P13 | H | H | H | H | F | D | O |
| Lₐ₂₃₆₆ | P11 | H | P14 | H | H | H | H | F | D | O |
| Lₐ₂₃₆₇ | P11 | H | P15 | H | H | H | H | F | D | O |
| Lₐ₂₃₆₈ | P11 | H | P16 | H | H | H | H | F | D | O |
| Lₐ₂₃₆₉ | P11 | H | P17 | H | H | H | H | F | D | O |
| Lₐ₂₃₇₀ | P11 | H | P18 | H | H | H | H | F | D | O |
| Lₐ₂₃₇₁ | P11 | H | P19 | H | H | H | H | F | D | O |
| Lₐ₂₃₇₂ | P11 | H | P20 | H | H | H | H | F | D | O |
| Lₐ₂₃₇₃ | P11 | H | P21 | H | H | H | H | F | D | O |
| Lₐ₂₃₇₄ | P11 | H | P22 | H | H | H | H | F | D | O |
| Lₐ₂₃₇₅ | P11 | H | P23 | H | H | H | H | F | D | O |
| Lₐ₂₃₇₆ | P11 | H | P24 | H | H | H | H | F | D | O |
| Lₐ₂₃₇₇ | P11 | H | P25 | H | H | H | H | F | D | O |
| Lₐ₂₃₇₈ | P11 | H | P26 | H | H | H | H | F | D | O |
| Lₐ₂₃₇₉ | P11 | H | P27 | H | H | H | H | F | D | O |
| Lₐ₂₃₈₀ | P11 | H | P28 | H | H | H | H | F | D | O |
| Lₐ₂₃₈₁ | P11 | H | P29 | H | H | H | H | F | D | O |
| Lₐ₂₃₈₂ | P11 | H | P30 | H | H | H | H | F | D | O |
| Lₐ₂₃₈₃ | P11 | H | P31 | H | H | H | H | F | D | O |
| Lₐ₂₃₈₄ | P11 | H | P32 | H | H | H | H | F | D | O |
| Lₐ₂₃₈₅ | P11 | H | P33 | H | H | H | H | F | D | O |
| Lₐ₂₃₈₆ | P11 | H | P34 | H | H | H | H | F | D | O |
| Lₐ₂₃₈₇ | P11 | H | H | P1 | H | H | H | F | D | O |
| Lₐ₂₃₈₈ | P11 | H | H | P2 | H | H | H | F | D | O |
| Lₐ₂₃₈₉ | P11 | H | H | P3 | H | H | H | F | D | O |
| Lₐ₂₃₉₀ | P11 | H | H | P4 | H | H | H | F | D | O |
| Lₐ₂₃₉₁ | P11 | H | H | P5 | H | H | H | F | D | O |
| Lₐ₂₃₉₂ | P11 | H | H | P6 | H | H | H | F | D | O |
| Lₐ₂₃₉₃ | P11 | H | H | P7 | H | H | H | F | D | O |
| Lₐ₂₃₉₄ | P11 | H | H | P8 | H | H | H | F | D | O |
| Lₐ₂₃₉₅ | P11 | H | H | P9 | H | H | H | F | D | O |
| Lₐ₂₃₉₆ | P11 | H | H | P10 | H | H | H | F | D | O |
| Lₐ₂₃₉₇ | P11 | H | H | P11 | H | H | H | F | D | O |
| Lₐ₂₃₉₈ | P11 | H | H | P12 | H | H | H | F | D | O |
| Lₐ₂₃₉₉ | P11 | H | H | P13 | H | H | H | F | D | O |
| Lₐ₂₄₀₀ | P11 | H | H | P14 | H | H | H | F | D | O |
| Lₐ₂₄₀₁ | P11 | H | H | P15 | H | H | H | F | D | O |
| Lₐ₂₄₀₂ | P11 | H | H | P16 | H | H | H | F | D | O |
| Lₐ₂₄₀₃ | P11 | H | H | P17 | H | H | H | F | D | O |
| Lₐ₂₄₀₄ | P11 | H | H | P18 | H | H | H | F | D | O |
| Lₐ₂₄₀₅ | P11 | H | H | P19 | H | H | H | F | D | O |
| Lₐ₂₄₀₆ | P11 | H | H | P20 | H | H | H | F | D | O |
| Lₐ₂₄₀₇ | P11 | H | H | P21 | H | H | H | F | D | O |
| Lₐ₂₄₀₈ | P11 | H | H | P22 | H | H | H | F | D | O |
| Lₐ₂₄₀₉ | P11 | H | H | P23 | H | H | H | F | D | O |
| Lₐ₂₄₁₀ | P11 | H | H | P24 | H | H | H | F | D | O |
| Lₐ₂₄₁₁ | P11 | H | H | P25 | H | H | H | F | D | O |
| Lₐ₂₄₁₂ | P11 | H | H | P26 | H | H | H | F | D | O |
| Lₐ₂₄₁₃ | P11 | H | H | P27 | H | H | H | F | D | O |
| Lₐ₂₄₁₄ | P11 | H | H | P28 | H | H | H | F | D | O |
| Lₐ₂₄₁₅ | P11 | H | H | P29 | H | H | H | F | D | O |
| Lₐ₂₄₁₆ | P11 | H | H | P30 | H | H | H | F | D | O |
| Lₐ₂₄₁₇ | P11 | H | H | P31 | H | H | H | F | D | O |
| Lₐ₂₄₁₈ | P11 | H | H | P32 | H | H | H | F | D | O |
| Lₐ₂₄₁₉ | P11 | H | H | P33 | H | H | H | F | D | O |
| Lₐ₂₄₂₀ | P11 | H | H | P34 | H | H | H | F | D | O |
| Lₐ₂₄₂₁ | P11 | H | P1 | P1 | H | H | H | F | D | O |
| Lₐ₂₄₂₂ | P11 | H | P2 | P2 | H | H | H | F | D | O |
| Lₐ₂₄₂₃ | P11 | H | F | H | H | H | H | F | D | O |
| Lₐ₂₄₂₄ | P11 | H | H | F | H | H | H | F | D | O |
| Lₐ₂₄₂₅ | P11 | H | F | P1 | H | H | H | F | D | O |
| Lₐ₂₄₂₆ | P11 | H | F | P2 | H | H | H | F | D | O |
| Lₐ₂₄₂₇ | P11 | H | P1 | F | H | H | H | F | D | O |
| Lₐ₂₄₂₈ | P11 | H | P2 | F | H | H | H | F | D | O |
| Lₐ₂₄₂₉ | P11 | D | H | P1 | H | H | H | F | H | O |
| Lₐ₂₄₃₀ | P11 | H | H | P2 | D | H | H | F | H | O |
| Lₐ₂₄₃₁ | P11 | H | H | H | H | H | H | F | P23 | O |
| Lₐ₂₄₃₂ | P11 | H | H | H | H | H | H | F | P24 | O |
| Lₐ₂₄₃₃ | P11 | H | H | H | H | H | H | F | P25 | O |
| Lₐ₂₄₃₄ | P11 | H | H | H | H | H | H | F | P26 | O |
| Lₐ₂₄₃₅ | P11 | H | H | H | H | H | H | F | P27 | O |
| Lₐ₂₄₃₆ | P11 | H | H | H | H | H | H | F | P28 | O |
| Lₐ₂₄₃₇ | P11 | H | H | H | H | H | H | F | P29 | O |
| Lₐ₂₄₃₈ | P11 | H | H | H | H | H | H | F | P30 | O |
| Lₐ₂₄₃₉ | P11 | H | H | H | H | H | H | F | P31 | O |
| Lₐ₂₄₄₀ | P11 | H | H | H | H | H | H | F | P32 | O |
| Lₐ₂₄₄₁ | P11 | H | H | H | H | H | H | F | P33 | O |
| Lₐ₂₄₄₂ | P11 | H | H | H | H | H | H | F | P34 | O |
| Lₐ₂₄₄₃ | P11 | H | H | H | H | H | H | F | P35 | O |
| Lₐ₂₄₄₄ | P11 | H | H | H | H | H | H | F | P36 | O |
| Lₐ₂₄₄₅ | P11 | H | H | H | H | H | H | F | P37 | O |
| Lₐ₂₄₄₆ | P11 | H | H | H | H | H | H | F | P38 | O |
| Lₐ₂₄₄₇ | P11 | H | H | H | H | H | H | F | P39 | O |
| Lₐ₂₄₄₈ | P11 | H | H | H | H | H | H | F | P40 | O |
| Lₐ₂₄₄₉ | P11 | H | H | H | H | H | H | F | P41 | O |
| Lₐ₂₄₅₀ | P11 | H | H | H | H | H | H | F | P42 | O |
| Lₐ₂₄₅₁ | P11 | H | H | H | H | H | H | F | P43 | O |
| Lₐ₂₄₅₂ | P11 | H | H | H | H | H | H | F | P44 | O |
| Lₐ₂₄₅₃ | P11 | H | H | H | H | H | H | F | P45 | O |
| Lₐ₂₄₅₄ | P11 | H | H | H | H | H | H | F | P46 | O |
| Lₐ₂₄₅₅ | P11 | H | H | H | H | H | H | F | P47 | O |
| Lₐ₂₄₅₆ | P11 | H | H | H | H | H | H | F | P48 | O |
| Lₐ₂₄₅₇ | P11 | H | H | H | H | H | H | F | P49 | O |
| Lₐ₂₄₅₈ | P11 | H | H | H | H | H | H | F | P50 | O |
| Lₐ₂₄₅₉ | P11 | H | H | H | H | H | H | F | P51 | O |
| Lₐ₂₄₆₀ | P11 | H | H | H | H | H | H | F | P52 | O |
| Lₐ₂₄₆₁ | P11 | H | H | H | H | H | H | F | P53 | O |
| Lₐ₂₄₆₂ | P11 | H | H | H | H | H | H | F | P54 | O |
| Lₐ₂₄₆₃ | P11 | H | H | H | H | H | H | F | P55 | O |
| Lₐ₂₄₆₄ | P11 | H | H | H | H | H | H | F | P56 | O |
| Lₐ₂₄₆₅ | P11 | H | H | H | H | H | H | F | P57 | O |
| Lₐ₂₄₆₆ | P11 | H | H | H | H | H | H | F | P58 | O |
| Lₐ₂₄₆₇ | P11 | H | H | H | H | H | H | F | P59 | O |
| Lₐ₂₄₆₈ | P11 | H | H | H | H | H | H | F | P60 | O |
| Lₐ₂₄₆₉ | P11 | H | H | H | H | H | H | F | P61 | O |
| Lₐ₂₄₇₀ | P11 | H | H | H | H | H | H | F | P62 | O |
| Lₐ₂₄₇₁ | P11 | H | H | H | H | H | H | F | P63 | O |
| Lₐ₂₄₇₂ | P11 | H | H | H | H | H | H | F | P64 | O |
| Lₐ₂₄₇₃ | P11 | H | H | H | H | H | H | F | P65 | O |
| Lₐ₂₄₇₄ | P11 | H | H | H | H | H | H | F | P66 | O |
| Lₐ₂₄₇₅ | P11 | H | H | H | H | H | H | F | P67 | O |
| Lₐ₂₄₇₆ | P11 | H | H | H | H | H | H | F | P68 | O |
| Lₐ₂₄₇₇ | P11 | H | H | H | H | H | H | F | P69 | O |
| Lₐ₂₄₇₈ | P11 | H | H | H | H | H | H | F | P70 | O |
| Lₐ₂₄₇₉ | P11 | H | H | H | H | H | H | F | P71 | O |
| Lₐ₂₄₈₀ | P11 | H | H | H | H | H | H | F | P72 | O |
| Lₐ₂₄₈₁ | P11 | H | H | H | H | H | H | F | P73 | O |
| Lₐ₂₄₈₂ | P11 | H | H | H | H | H | H | F | P74 | O |
| Lₐ₂₄₈₃ | P11 | H | H | H | H | H | H | F | P75 | O |
| Lₐ₂₄₈₄ | P11 | H | H | H | H | H | H | F | P76 | O |
| Lₐ₂₄₈₅ | P11 | H | H | H | H | H | H | F | P77 | O |
| Lₐ₂₄₈₆ | P11 | H | H | H | H | H | H | F | P78 | O |
| Lₐ₂₄₈₇ | P11 | H | H | H | H | H | H | F | P79 | O |
| Lₐ₂₄₈₈ | P11 | H | H | H | H | H | H | F | P80 | O |
| Lₐ₂₄₈₉ | P11 | H | H | H | H | H | H | F | P81 | O |
| Lₐ₂₄₉₀ | P11 | H | H | H | H | H | H | F | P82 | O |
| Lₐ₂₄₉₁ | P11 | H | H | H | H | H | H | F | P83 | O |
| Lₐ₂₄₉₂ | P11 | H | H | H | H | H | H | F | P84 | O |
| Lₐ₂₄₉₃ | P11 | H | H | H | H | H | H | F | P85 | O |
| Lₐ₂₄₉₄ | P11 | H | H | H | H | H | H | F | P86 | O |
| Lₐ₂₄₉₅ | P11 | H | H | H | H | H | H | F | P87 | O |
| Lₐ₂₄₉₆ | P11 | H | H | H | H | H | H | F | P88 | O |
| Lₐ₂₄₉₇ | P11 | H | H | H | H | H | H | F | P89 | O |
| Lₐ₂₄₉₈ | P11 | H | H | H | H | H | H | F | P90 | O |
| Lₐ₂₄₉₉ | P11 | H | P1 | H | H | H | H | F | P23 | O |
| Lₐ₂₅₀₀ | P11 | H | P2 | H | H | H | H | F | P23 | O |
| Lₐ₂₅₀₁ | P11 | H | P3 | H | H | H | H | F | P23 | O |
| Lₐ₂₅₀₂ | P11 | H | P4 | H | H | H | H | F | P23 | O |
| Lₐ₂₅₀₃ | P11 | H | P5 | H | H | H | H | F | P23 | O |
| Lₐ₂₅₀₄ | P11 | H | P6 | H | H | H | H | F | P23 | O |
| Lₐ₂₅₀₅ | P11 | H | P7 | H | H | H | H | F | P23 | O |
| Lₐ₂₅₀₆ | P11 | H | P8 | H | H | H | H | F | P23 | O |
| Lₐ₂₅₀₇ | P11 | H | P9 | H | H | H | H | F | P23 | O |
| Lₐ₂₅₀₈ | P11 | H | P10 | H | H | H | H | F | P23 | O |
| Lₐ₂₅₀₉ | P11 | H | P11 | H | H | H | H | F | P23 | O |
| Lₐ₂₅₁₀ | P11 | H | P12 | H | H | H | H | F | P23 | O |
| Lₐ₂₅₁₁ | P11 | H | P15 | H | H | H | H | F | P23 | O |
| Lₐ₂₅₁₂ | P11 | H | P17 | H | H | H | H | F | P23 | O |
| Lₐ₂₅₁₃ | P11 | H | H | P1 | H | H | H | F | P23 | O |
| Lₐ₂₅₁₄ | P11 | H | H | P2 | H | H | H | F | P23 | O |
| Lₐ₂₅₁₅ | P11 | H | H | P3 | H | H | H | F | P23 | O |
| Lₐ₂₅₁₆ | P11 | H | H | P4 | H | H | H | F | P23 | O |
| Lₐ₂₅₁₇ | P11 | H | H | P5 | H | H | H | F | P23 | O |
| Lₐ₂₅₁₈ | P11 | H | H | P6 | H | H | H | F | P23 | O |
| Lₐ₂₅₁₉ | P11 | H | H | P7 | H | H | H | F | P23 | O |
| Lₐ₂₅₂₀ | P11 | H | H | P8 | H | H | H | F | P23 | O |
| Lₐ₂₅₂₁ | P11 | H | H | P9 | H | H | H | F | P23 | O |
| Lₐ₂₅₂₂ | P11 | H | H | P10 | H | H | H | F | P23 | O |
| Lₐ₂₅₂₃ | P11 | H | H | P11 | H | H | H | F | P23 | O |
| Lₐ₂₅₂₄ | P11 | H | H | P12 | H | H | H | F | P23 | O |
| Lₐ₂₅₂₅ | P11 | H | H | P15 | H | H | H | F | P23 | O |
| Lₐ₂₅₂₆ | P11 | H | H | P17 | H | H | H | F | P23 | O |
| Lₐ₂₅₂₇ | P11 | H | F | H | H | H | H | F | P23 | O |
| Lₐ₂₅₂₈ | P11 | H | H | F | H | H | H | F | P23 | O |
| Lₐ₂₅₂₉ | P11 | H | F | P1 | H | H | H | F | P23 | O |
| Lₐ₂₅₃₀ | P11 | H | F | P2 | H | H | H | F | P23 | O |
| Lₐ₂₅₃₁ | P11 | H | P1 | F | H | H | H | F | P23 | O |
| Lₐ₂₅₃₂ | P11 | H | P2 | F | H | H | H | F | P23 | O |
| Lₐ₂₅₃₃ | P11 | H | P1 | P1 | H | H | H | F | P23 | O |
| Lₐ₂₅₃₄ | P11 | H | P2 | P2 | H | H | H | F | P23 | O |
| Lₐ₂₅₃₅ | P11 | H | P1 | H | H | H | H | F | P24 | O |
| Lₐ₂₅₃₆ | P11 | H | P2 | H | H | H | H | F | P24 | O |
| Lₐ₂₅₃₇ | P11 | H | P3 | H | H | H | H | F | P24 | O |
| Lₐ₂₅₃₈ | P11 | H | P4 | H | H | H | H | F | P24 | O |
| Lₐ₂₅₃₉ | P11 | H | P5 | H | H | H | H | F | P24 | O |
| Lₐ₂₅₄₀ | P11 | H | P6 | H | H | H | H | F | P24 | O |
| Lₐ₂₅₄₁ | P11 | H | P7 | H | H | H | H | F | P24 | O |
| Lₐ₂₅₄₂ | P11 | H | P8 | H | H | H | H | F | P24 | O |
| Lₐ₂₅₄₃ | P11 | H | P9 | H | H | H | H | F | P24 | O |
| Lₐ₂₅₄₄ | P11 | H | P10 | H | H | H | H | F | P24 | O |
| Lₐ₂₅₄₅ | P11 | H | P11 | H | H | H | H | F | P24 | O |
| Lₐ₂₅₄₆ | P11 | H | P12 | H | H | H | H | F | P24 | O |
| Lₐ₂₅₄₇ | P11 | H | P15 | H | H | H | H | F | P24 | O |
| Lₐ₂₅₄₈ | P11 | H | P17 | H | H | H | H | F | P24 | O |
| Lₐ₂₅₄₉ | P11 | H | H | P1 | H | H | H | F | P24 | O |
| Lₐ₂₅₅₀ | P11 | H | H | P2 | H | H | H | F | P24 | O |
| Lₐ₂₅₅₁ | P11 | H | H | P3 | H | H | H | F | P24 | O |
| Lₐ₂₅₅₂ | P11 | H | H | P4 | H | H | H | F | P24 | O |
| Lₐ₂₅₅₃ | P11 | H | H | P5 | H | H | H | F | P24 | O |
| Lₐ₂₅₅₄ | P11 | H | H | P6 | H | H | H | F | P24 | O |
| Lₐ₂₅₅₅ | P11 | H | H | P7 | H | H | H | F | P24 | O |
| Lₐ₂₅₅₆ | P11 | H | H | P8 | H | H | H | F | P24 | O |
| Lₐ₂₅₅₇ | P11 | H | H | P9 | H | H | H | F | P24 | O |
| Lₐ₂₅₅₈ | P11 | H | H | P10 | H | H | H | F | P24 | O |
| Lₐ₂₅₅₉ | P11 | H | H | P11 | H | H | H | F | P24 | O |
| Lₐ₂₅₆₀ | P11 | H | H | P12 | H | H | H | F | P24 | O |
| Lₐ₂₅₆₁ | P11 | H | H | P15 | H | H | H | F | P24 | O |
| Lₐ₂₅₆₂ | P11 | H | H | P17 | H | H | H | F | P24 | O |
| Lₐ₂₅₆₃ | P11 | H | F | H | H | H | H | F | P24 | O |
| Lₐ₂₅₆₄ | P11 | H | H | F | H | H | H | F | P24 | O |
| Lₐ₂₅₆₅ | P11 | H | F | P1 | H | H | H | F | P24 | O |
| Lₐ₂₅₆₆ | P11 | H | F | P2 | H | H | H | F | P24 | O |
| Lₐ₂₅₆₇ | P11 | H | P1 | F | H | H | H | F | P24 | O |
| Lₐ₂₅₆₈ | P11 | H | P2 | F | H | H | H | F | P24 | O |
| Lₐ₂₅₆₉ | P11 | H | P1 | P1 | H | H | H | F | P24 | O |
| Lₐ₂₅₇₀ | P11 | H | P2 | P2 | H | H | H | F | P24 | O |
| Lₐ₂₅₇₁ | P11 | H | P1 | H | H | H | H | F | P56 | O |
| Lₐ₂₅₇₂ | P11 | H | P2 | H | H | H | H | F | P56 | O |
| Lₐ₂₅₇₃ | P11 | H | P3 | H | H | H | H | F | P56 | O |
| Lₐ₂₅₇₄ | P11 | H | P4 | H | H | H | H | F | P56 | O |
| Lₐ₂₅₇₅ | P11 | H | P5 | H | H | H | H | F | P56 | O |
| Lₐ₂₅₇₆ | P11 | H | P6 | H | H | H | H | F | P56 | O |
| Lₐ₂₅₇₇ | P11 | H | P7 | H | H | H | H | F | P56 | O |
| Lₐ₂₅₇₈ | P11 | H | P8 | H | H | H | H | F | P56 | O |
| Lₐ₂₅₇₉ | P11 | H | P9 | H | H | H | H | F | P56 | O |
| Lₐ₂₅₈₀ | P11 | H | P10 | H | H | H | H | F | P56 | O |
| Lₐ₂₅₈₁ | P11 | H | P11 | H | H | H | H | F | P56 | O |
| Lₐ₂₅₈₂ | P11 | H | P12 | H | H | H | H | F | P56 | O |
| Lₐ₂₅₈₃ | P11 | H | P15 | H | H | H | H | F | P56 | O |
| Lₐ₂₅₈₄ | P11 | H | P17 | H | H | H | H | F | P56 | O |
| Lₐ₂₅₈₅ | P11 | H | H | P1 | H | H | H | F | P56 | O |
| Lₐ₂₅₈₆ | P11 | H | H | P2 | H | H | H | F | P56 | O |
| Lₐ₂₅₈₇ | P11 | H | H | P3 | H | H | H | F | P56 | O |
| Lₐ₂₅₈₈ | P11 | H | H | P4 | H | H | H | F | P56 | O |
| Lₐ₂₅₈₉ | P11 | H | H | P5 | H | H | H | F | P56 | O |
| Lₐ₂₅₉₀ | P11 | H | H | P6 | H | H | H | F | P56 | O |
| Lₐ₂₅₉₁ | P11 | H | H | P7 | H | H | H | F | P56 | O |
| Lₐ₂₅₉₂ | P11 | H | H | P8 | H | H | H | F | P56 | O |
| Lₐ₂₅₉₃ | P11 | H | H | P9 | H | H | H | F | P56 | O |
| Lₐ₂₅₉₄ | P11 | H | H | P10 | H | H | H | F | P56 | O |
| Lₐ₂₅₉₅ | P11 | H | H | P11 | H | H | H | F | P56 | O |
| Lₐ₂₅₉₆ | P11 | H | H | P12 | H | H | H | F | P56 | O |
| Lₐ₂₅₉₇ | P11 | H | H | P15 | H | H | H | F | P56 | O |
| Lₐ₂₅₉₈ | P11 | H | H | P17 | H | H | H | F | P56 | O |
| Lₐ₂₅₉₉ | P11 | H | F | H | H | H | H | F | P56 | O |
| Lₐ₂₆₀₀ | P11 | H | H | F | H | H | H | F | P56 | O |
| Lₐ₂₆₀₁ | P11 | H | F | P1 | H | H | H | F | P56 | O |
| Lₐ₂₆₀₂ | P11 | H | F | P2 | H | H | H | F | P56 | O |
| Lₐ₂₆₀₃ | P11 | H | P1 | F | H | H | H | F | P56 | O |
| Lₐ₂₆₀₄ | P11 | H | P2 | F | H | H | H | F | P56 | O |
| Lₐ₂₆₀₅ | P11 | H | P1 | P1 | H | H | H | F | P56 | O |
| Lₐ₂₆₀₆ | P11 | H | P2 | P2 | H | H | H | F | P56 | O |
| Lₐ₂₆₀₇ | P11 | H | P1 | H | H | H | H | F | P73 | O |
| Lₐ₂₆₀₈ | P11 | H | P2 | H | H | H | H | F | P73 | O |
| Lₐ₂₆₀₉ | P11 | H | P3 | H | H | H | H | F | P73 | O |
| Lₐ₂₆₁₀ | P11 | H | P4 | H | H | H | H | F | P73 | O |
| Lₐ₂₆₁₁ | P11 | H | P5 | H | H | H | H | F | P73 | O |
| Lₐ₂₆₁₂ | P11 | H | P6 | H | H | H | H | F | P73 | O |
| Lₐ₂₆₁₃ | P11 | H | P7 | H | H | H | H | F | P73 | O |
| Lₐ₂₆₁₄ | P11 | H | P8 | H | H | H | H | F | P73 | O |
| Lₐ₂₆₁₅ | P11 | H | P9 | H | H | H | H | F | P73 | O |
| Lₐ₂₆₁₆ | P11 | H | P10 | H | H | H | H | F | P73 | O |
| Lₐ₂₆₁₇ | P11 | H | P11 | H | H | H | H | F | P73 | O |
| Lₐ₂₆₁₈ | P11 | H | P12 | H | H | H | H | F | P73 | O |
| Lₐ₂₆₁₉ | P11 | H | P15 | H | H | H | H | F | P73 | O |
| Lₐ₂₆₂₀ | P11 | H | P17 | H | H | H | H | F | P73 | O |
| Lₐ₂₆₂₁ | P11 | H | H | P1 | H | H | H | F | P73 | O |
| Lₐ₂₆₂₂ | P11 | H | H | P2 | H | H | H | F | P73 | O |
| Lₐ₂₆₂₃ | P11 | H | H | P3 | H | H | H | F | P73 | O |
| Lₐ₂₆₂₄ | P11 | H | H | P4 | H | H | H | F | P73 | O |
| Lₐ₂₆₂₅ | P11 | H | H | P5 | H | H | H | F | P73 | O |
| Lₐ₂₆₂₆ | P11 | H | H | P6 | H | H | H | F | P73 | O |
| Lₐ₂₆₂₇ | P11 | H | H | P7 | H | H | H | F | P73 | O |
| Lₐ₂₆₂₈ | P11 | H | H | P8 | H | H | H | F | P73 | O |
| Lₐ₂₆₂₉ | P11 | H | H | P9 | H | H | H | F | P73 | O |
| Lₐ₂₆₃₀ | P11 | H | H | P10 | H | H | H | F | P73 | O |
| Lₐ₂₆₃₁ | P11 | H | H | P11 | H | H | H | F | P73 | O |
| Lₐ₂₆₃₂ | P11 | H | H | P12 | H | H | H | F | P73 | O |
| Lₐ₂₆₃₃ | P11 | H | H | P15 | H | H | H | F | P73 | O |
| Lₐ₂₆₃₄ | P11 | H | H | P17 | H | H | H | F | P73 | O |
| Lₐ₂₆₃₅ | P11 | H | F | H | H | H | H | F | P73 | O |
| Lₐ₂₆₃₆ | P11 | H | H | F | H | H | H | F | P73 | O |
| Lₐ₂₆₃₇ | P11 | H | F | P1 | H | H | H | F | P73 | O |
| Lₐ₂₆₃₈ | P11 | H | F | P2 | H | H | H | F | P73 | O |
| Lₐ₂₆₃₉ | P11 | H | P1 | F | H | H | H | F | P73 | O |
| Lₐ₂₆₄₀ | P11 | H | P2 | F | H | H | H | F | P73 | O |
| Lₐ₂₆₄₁ | P11 | H | P1 | P1 | H | H | H | F | P73 | O |
| Lₐ₂₆₄₂ | P11 | H | P2 | P2 | H | H | H | F | P73 | O |
| Lₐ₂₆₄₃ | P11 | H | P1 | H | H | H | H | F | P74 | O |
| Lₐ₂₆₄₄ | P11 | H | P2 | H | H | H | H | F | P74 | O |
| Lₐ₂₆₄₅ | P11 | H | P3 | H | H | H | H | F | P74 | O |
| Lₐ₂₆₄₆ | P11 | H | P4 | H | H | H | H | F | P74 | O |
| Lₐ₂₆₄₇ | P11 | H | P5 | H | H | H | H | F | P74 | O |
| Lₐ₂₆₄₈ | P11 | H | P6 | H | H | H | H | F | P74 | O |
| Lₐ₂₆₄₉ | P11 | H | P7 | H | H | H | H | F | P74 | O |
| Lₐ₂₆₅₀ | P11 | H | P8 | H | H | H | H | F | P74 | O |
| Lₐ₂₆₅₁ | P11 | H | P9 | H | H | H | H | F | P74 | O |
| Lₐ₂₆₅₂ | P11 | H | P10 | H | H | H | H | F | P74 | O |
| Lₐ₂₆₅₃ | P11 | H | P11 | H | H | H | H | F | P74 | O |
| Lₐ₂₆₅₄ | P11 | H | P12 | H | H | H | H | F | P74 | O |
| Lₐ₂₆₅₅ | P11 | H | P15 | H | H | H | H | F | P74 | O |
| Lₐ₂₆₅₆ | P11 | H | P17 | H | H | H | H | F | P74 | O |
| Lₐ₂₆₅₇ | P11 | H | H | P1 | H | H | H | F | P74 | O |
| Lₐ₂₆₅₈ | P11 | H | H | P2 | H | H | H | F | P74 | O |
| Lₐ₂₆₅₉ | P11 | H | H | P3 | H | H | H | F | P74 | O |
| Lₐ₂₆₆₀ | P11 | H | H | P4 | H | H | H | F | P74 | O |
| Lₐ₂₆₆₁ | P11 | H | H | P5 | H | H | H | F | P74 | O |
| Lₐ₂₆₆₂ | P11 | H | H | P6 | H | H | H | F | P74 | O |
| Lₐ₂₆₆₃ | P11 | H | H | P7 | H | H | H | F | P74 | O |
| Lₐ₂₆₆₄ | P11 | H | H | P8 | H | H | H | F | P74 | O |
| Lₐ₂₆₆₅ | P11 | H | H | P9 | H | H | H | F | P74 | O |
| Lₐ₂₆₆₆ | P11 | H | H | P10 | H | H | H | F | P74 | O |
| Lₐ₂₆₆₇ | P11 | H | H | P11 | H | H | H | F | P74 | O |
| Lₐ₂₆₆₈ | P11 | H | H | P12 | H | H | H | F | P74 | O |
| Lₐ₂₆₆₉ | P11 | H | H | P15 | H | H | H | F | P74 | O |
| Lₐ₂₆₇₀ | P11 | H | H | P17 | H | H | H | F | P74 | O |
| Lₐ₂₆₇₁ | P11 | H | F | H | H | H | H | F | P74 | O |
| Lₐ₂₆₇₂ | P11 | H | H | F | H | H | H | F | P74 | O |
| Lₐ₂₆₇₃ | P11 | H | F | P1 | H | H | H | F | P74 | O |
| Lₐ₂₆₇₄ | P11 | H | F | P2 | H | H | H | F | P74 | O |
| Lₐ₂₆₇₅ | P11 | H | P1 | F | H | H | H | F | P74 | O |
| Lₐ₂₆₇₆ | P11 | H | P2 | F | H | H | H | F | P74 | O |
| Lₐ₂₆₇₇ | P11 | H | P1 | P1 | H | H | H | F | P74 | O |
| Lₐ₂₆₇₈ | P11 | H | P2 | P2 | H | H | H | F | P74 | O |
| Lₐ₂₆₇₉ | P11 | H | P1 | H | H | H | H | F | P79 | O |
| Lₐ₂₆₈₀ | P11 | H | P2 | H | H | H | H | F | P79 | O |
| Lₐ₂₆₈₁ | P11 | H | P3 | H | H | H | H | F | P79 | O |
| Lₐ₂₆₈₂ | P11 | H | P4 | H | H | H | H | F | P79 | O |
| Lₐ₂₆₈₃ | P11 | H | P5 | H | H | H | H | F | P79 | O |
| Lₐ₂₆₈₄ | P11 | H | P6 | H | H | H | H | F | P79 | O |
| Lₐ₂₆₈₅ | P11 | H | P7 | H | H | H | H | F | P79 | O |
| Lₐ₂₆₈₆ | P11 | H | P8 | H | H | H | H | F | P79 | O |
| Lₐ₂₆₈₇ | P11 | H | P9 | H | H | H | H | F | P79 | O |
| Lₐ₂₆₈₈ | P11 | H | P10 | H | H | H | H | F | P79 | O |
| Lₐ₂₆₈₉ | P11 | H | P11 | H | H | H | H | F | P79 | O |
| Lₐ₂₆₉₀ | P11 | H | P12 | H | H | H | H | F | P79 | O |
| Lₐ₂₆₉₁ | P11 | H | P15 | H | H | H | H | F | P79 | O |
| Lₐ₂₆₉₂ | P11 | H | P17 | H | H | H | H | F | P79 | O |
| Lₐ₂₆₉₃ | P11 | H | H | P1 | H | H | H | F | P79 | O |
| Lₐ₂₆₉₄ | P11 | H | H | P2 | H | H | H | F | P79 | O |
| Lₐ₂₆₉₅ | P11 | H | H | P3 | H | H | H | F | P79 | O |
| Lₐ₂₆₉₆ | P11 | H | H | P4 | H | H | H | F | P79 | O |
| Lₐ₂₆₉₇ | P11 | H | H | P5 | H | H | H | F | P79 | O |
| Lₐ₂₆₉₈ | P11 | H | H | P6 | H | H | H | F | P79 | O |
| Lₐ₂₆₉₉ | P11 | H | H | P7 | H | H | H | F | P79 | O |
| Lₐ₂₇₀₀ | P11 | H | H | P8 | H | H | H | F | P79 | O |
| Lₐ₂₇₀₁ | P11 | H | H | P9 | H | H | H | F | P79 | O |
| Lₐ₂₇₀₂ | P11 | H | H | P10 | H | H | H | F | P79 | O |
| Lₐ₂₇₀₃ | P11 | H | H | P11 | H | H | H | F | P79 | O |
| Lₐ₂₇₀₄ | P11 | H | H | P12 | H | H | H | F | P79 | O |
| Lₐ₂₇₀₅ | P11 | H | H | P15 | H | H | H | F | P79 | O |
| Lₐ₂₇₀₆ | P11 | H | H | P17 | H | H | H | F | P79 | O |
| Lₐ₂₇₀₇ | P11 | H | F | H | H | H | H | F | P79 | O |
| Lₐ₂₇₀₈ | P11 | H | H | F | H | H | H | F | P79 | O |
| Lₐ₂₇₀₉ | P11 | H | F | P1 | H | H | H | F | P79 | O |
| Lₐ₂₇₁₀ | P11 | H | F | P2 | H | H | H | F | P79 | O |
| Lₐ₂₇₁₁ | P11 | H | P1 | F | H | H | H | F | P79 | O |
| Lₐ₂₇₁₂ | P11 | H | P2 | F | H | H | H | F | P79 | O |
| Lₐ₂₇₁₃ | P11 | H | P1 | P1 | H | H | H | F | P79 | O |
| Lₐ₂₇₁₄ | P11 | H | P2 | P2 | H | H | H | F | P79 | O |
| Lₐ₂₇₁₅ | P11 | H | P1 | H | H | H | H | F | P80 | O |
| Lₐ₂₇₁₆ | P11 | H | P2 | H | H | H | H | F | P80 | O |
| Lₐ₂₇₁₇ | P11 | H | P3 | H | H | H | H | F | P80 | O |
| Lₐ₂₇₁₈ | P11 | H | P4 | H | H | H | H | F | P80 | O |
| Lₐ₂₇₁₉ | P11 | H | P5 | H | H | H | H | F | P80 | O |
| Lₐ₂₇₂₀ | P11 | H | P6 | H | H | H | H | F | P80 | O |
| Lₐ₂₇₂₁ | P11 | H | P7 | H | H | H | H | F | P80 | O |
| Lₐ₂₇₂₂ | P11 | H | P8 | H | H | H | H | F | P80 | O |
| Lₐ₂₇₂₃ | P11 | H | P9 | H | H | H | H | F | P80 | O |
| Lₐ₂₇₂₄ | P11 | H | P10 | H | H | H | H | F | P80 | O |
| Lₐ₂₇₂₅ | P11 | H | P11 | H | H | H | H | F | P80 | O |
| Lₐ₂₇₂₆ | P11 | H | P12 | H | H | H | H | F | P80 | O |
| Lₐ₂₇₂₇ | P11 | H | P15 | H | H | H | H | F | P80 | O |
| Lₐ₂₇₂₈ | P11 | H | P17 | H | H | H | H | F | P80 | O |
| Lₐ₂₇₂₉ | P11 | H | H | P1 | H | H | H | F | P80 | O |
| Lₐ₂₇₃₀ | P11 | H | H | P2 | H | H | H | F | P80 | O |
| Lₐ₂₇₃₁ | P11 | H | H | P3 | H | H | H | F | P80 | O |
| Lₐ₂₇₃₂ | P11 | H | H | P4 | H | H | H | F | P80 | O |
| Lₐ₂₇₃₃ | P11 | H | H | P5 | H | H | H | F | P80 | O |
| Lₐ₂₇₃₄ | P11 | H | H | P6 | H | H | H | F | P80 | O |
| Lₐ₂₇₃₅ | P11 | H | H | P7 | H | H | H | F | P80 | O |
| Lₐ₂₇₃₆ | P11 | H | H | P8 | H | H | H | F | P80 | O |
| Lₐ₂₇₃₇ | P11 | H | H | P9 | H | H | H | F | P80 | O |
| Lₐ₂₇₃₈ | P11 | H | H | P10 | H | H | H | F | P80 | O |
| Lₐ₂₇₃₉ | P11 | H | H | P11 | H | H | H | F | P80 | O |
| Lₐ₂₇₄₀ | P11 | H | H | P12 | H | H | H | F | P80 | O |
| Lₐ₂₇₄₁ | P11 | H | H | P15 | H | H | H | F | P80 | O |
| Lₐ₂₇₄₂ | P11 | H | H | P17 | H | H | H | F | P80 | O |
| Lₐ₂₇₄₃ | P11 | H | F | H | H | H | H | F | P80 | O |
| Lₐ₂₇₄₄ | P11 | H | H | F | H | H | H | F | P80 | O |
| Lₐ₂₇₄₅ | P11 | H | F | P1 | H | H | H | F | P80 | O |
| Lₐ₂₇₄₆ | P11 | H | F | P2 | H | H | H | F | P80 | O |
| Lₐ₂₇₄₇ | P11 | H | P1 | F | H | H | H | F | P80 | O |
| Lₐ₂₇₄₈ | P11 | H | P2 | F | H | H | H | F | P80 | O |
| Lₐ₂₇₄₉ | P11 | H | P1 | P1 | H | H | H | F | P80 | O |
| Lₐ₂₇₅₀ | P11 | H | P2 | P2 | H | H | H | F | P80 | O |
| Lₐ₂₇₅₁ | P11 | H | P1 | H | H | H | H | F | P89 | O |
| Lₐ₂₇₅₂ | P11 | H | P2 | H | H | H | H | F | P89 | O |
| Lₐ₂₇₅₃ | P11 | H | P3 | H | H | H | H | F | P89 | O |
| Lₐ₂₇₅₄ | P11 | H | P4 | H | H | H | H | F | P89 | O |
| Lₐ₂₇₅₅ | P11 | H | P5 | H | H | H | H | F | P89 | O |
| Lₐ₂₇₅₆ | P11 | H | P6 | H | H | H | H | F | P89 | O |
| Lₐ₂₇₅₇ | P11 | H | P7 | H | H | H | H | F | P89 | O |
| Lₐ₂₇₅₈ | P11 | H | P8 | H | H | H | H | F | P89 | O |
| Lₐ₂₇₅₉ | P11 | H | P9 | H | H | H | H | F | P89 | O |
| Lₐ₂₇₆₀ | P11 | H | P10 | H | H | H | H | F | P89 | O |
| Lₐ₂₇₆₁ | P11 | H | P11 | H | H | H | H | F | P89 | O |
| Lₐ₂₇₆₂ | P11 | H | P12 | H | H | H | H | F | P89 | O |
| Lₐ₂₇₆₃ | P11 | H | P15 | H | H | H | H | F | P89 | O |
| Lₐ₂₇₆₄ | P11 | H | P17 | H | H | H | H | F | P89 | O |
| Lₐ₂₇₆₅ | P11 | H | H | P1 | H | H | H | F | P89 | O |
| Lₐ₂₇₆₆ | P11 | H | H | P2 | H | H | H | F | P89 | O |
| Lₐ₂₇₆₇ | P11 | H | H | P3 | H | H | H | F | P89 | O |
| Lₐ₂₇₆₈ | P11 | H | H | P4 | H | H | H | F | P89 | O |
| Lₐ₂₇₆₉ | P11 | H | H | P5 | H | H | H | F | P89 | O |
| Lₐ₂₇₇₀ | P11 | H | H | P6 | H | H | H | F | P89 | O |
| Lₐ₂₇₇₁ | P11 | H | H | P7 | H | H | H | F | P89 | O |
| Lₐ₂₇₇₂ | P11 | H | H | P8 | H | H | H | F | P89 | O |
| Lₐ₂₇₇₃ | P11 | H | H | P9 | H | H | H | F | P89 | O |
| Lₐ₂₇₇₄ | P11 | H | H | P10 | H | H | H | F | P89 | O |
| Lₐ₂₇₇₅ | P11 | H | H | P11 | H | H | H | F | P89 | O |
| Lₐ₂₇₇₆ | P11 | H | H | P12 | H | H | H | F | P89 | O |
| Lₐ₂₇₇₇ | P11 | H | H | P15 | H | H | H | F | P89 | O |
| Lₐ₂₇₇₈ | P11 | H | H | P17 | H | H | H | F | P89 | O |
| Lₐ₂₇₇₉ | P11 | H | F | H | H | H | H | F | P89 | O |
| Lₐ₂₇₈₀ | P11 | H | H | F | H | H | H | F | P89 | O |
| Lₐ₂₇₈₁ | P11 | H | F | P1 | H | H | H | F | P89 | O |
| Lₐ₂₇₈₂ | P11 | H | F | P2 | H | H | H | F | P89 | O |
| Lₐ₂₇₈₃ | P11 | H | P1 | F | H | H | H | F | P89 | O |
| Lₐ₂₇₈₄ | P11 | H | P2 | F | H | H | H | F | P89 | O |
| Lₐ₂₇₈₅ | P11 | H | P1 | P1 | H | H | H | F | P89 | O |
| Lₐ₂₇₈₆ | P11 | H | P2 | P2 | H | H | H | F | P89 | O |
| Lₐ₂₇₈₇ | P10 | H | H | H | H | H | H | F | H | O |
| Lₐ₂₇₈₈ | P10 | H | P1 | H | H | H | H | F | H | O |
| Lₐ₂₇₈₉ | P10 | H | P2 | H | H | H | H | F | H | O |
| Lₐ₂₇₉₀ | P10 | H | P3 | H | H | H | H | F | H | O |
| Lₐ₂₇₉₁ | P10 | H | P4 | H | H | H | H | F | H | O |
| Lₐ₂₇₉₂ | P10 | H | P5 | H | H | H | H | F | H | O |
| Lₐ₂₇₉₃ | P10 | H | P6 | H | H | H | H | F | H | O |
| Lₐ₂₇₉₄ | P10 | H | P7 | H | H | H | H | F | H | O |
| Lₐ₂₇₉₅ | P10 | H | P8 | H | H | H | H | F | H | O |
| Lₐ₂₇₉₆ | P10 | H | P9 | H | H | H | H | F | H | O |
| Lₐ₂₇₉₇ | P10 | H | P10 | H | H | H | H | F | H | O |
| Lₐ₂₇₉₈ | P10 | H | P11 | H | H | H | H | F | H | O |
| Lₐ₂₇₉₉ | P10 | H | P12 | H | H | H | H | F | H | O |
| Lₐ₂₈₀₀ | P10 | H | P13 | H | H | H | H | F | H | O |
| Lₐ₂₈₀₁ | P10 | H | P14 | H | H | H | H | F | H | O |
| Lₐ₂₈₀₂ | P10 | H | P15 | H | H | H | H | F | H | O |
| Lₐ₂₈₀₃ | P10 | H | P16 | H | H | H | H | F | H | O |
| Lₐ₂₈₀₄ | P10 | H | P17 | H | H | H | H | F | H | O |
| Lₐ₂₈₀₅ | P10 | H | P18 | H | H | H | H | F | H | O |
| Lₐ₂₈₀₆ | P10 | H | P19 | H | H | H | H | F | H | O |
| Lₐ₂₈₀₇ | P10 | H | P20 | H | H | H | H | F | H | O |
| Lₐ₂₈₀₈ | P10 | H | P21 | H | H | H | H | F | H | O |
| Lₐ₂₈₀₉ | P10 | H | P22 | H | H | H | H | F | H | O |
| Lₐ₂₈₁₀ | P10 | H | P23 | H | H | H | H | F | H | O |
| Lₐ₂₈₁₁ | P10 | H | P24 | H | H | H | H | F | H | O |
| Lₐ₂₈₁₂ | P10 | H | P25 | H | H | H | H | F | H | O |
| Lₐ₂₈₁₃ | P10 | H | P26 | H | H | H | H | F | H | O |
| Lₐ₂₈₁₄ | P10 | H | P27 | H | H | H | H | F | H | O |
| Lₐ₂₈₁₅ | P10 | H | P28 | H | H | H | H | F | H | O |
| Lₐ₂₈₁₆ | P10 | H | P29 | H | H | H | H | F | H | O |
| Lₐ₂₈₁₇ | P10 | H | P30 | H | H | H | H | F | H | O |
| Lₐ₂₈₁₈ | P10 | H | P31 | H | H | H | H | F | H | O |
| Lₐ₂₈₁₉ | P10 | H | P32 | H | H | H | H | F | H | O |
| Lₐ₂₈₂₀ | P10 | H | P33 | H | H | H | H | F | H | O |
| Lₐ₂₈₂₁ | P10 | H | P34 | H | H | H | H | F | H | O |
| Lₐ₂₈₂₂ | P10 | H | H | P1 | H | H | H | F | H | O |
| Lₐ₂₈₂₃ | P10 | H | H | P2 | H | H | H | F | H | O |
| Lₐ₂₈₂₄ | P10 | H | H | P3 | H | H | H | F | H | O |
| Lₐ₂₈₂₅ | P10 | H | H | P4 | H | H | H | F | H | O |
| Lₐ₂₈₂₆ | P10 | H | H | P5 | H | H | H | F | H | O |
| Lₐ₂₈₂₇ | P10 | H | H | P6 | H | H | H | F | H | O |
| Lₐ₂₈₂₈ | P10 | H | H | P7 | H | H | H | F | H | O |
| Lₐ₂₈₂₉ | P10 | H | H | P8 | H | H | H | F | H | O |
| Lₐ₂₈₃₀ | P10 | H | H | P9 | H | H | H | F | H | O |
| Lₐ₂₈₃₁ | P10 | H | H | P10 | H | H | H | F | H | O |
| Lₐ₂₈₃₂ | P10 | H | H | P11 | H | H | H | F | H | O |
| Lₐ₂₈₃₃ | P10 | H | H | P12 | H | H | H | F | H | O |
| Lₐ₂₈₃₄ | P10 | H | H | P13 | H | H | H | F | H | O |
| Lₐ₂₈₃₅ | P10 | H | H | P14 | H | H | H | F | H | O |
| Lₐ₂₈₃₆ | P10 | H | H | P15 | H | H | H | F | H | O |
| Lₐ₂₈₃₇ | P10 | H | H | P16 | H | H | H | F | H | O |
| Lₐ₂₈₃₈ | P10 | H | H | P17 | H | H | H | F | H | O |
| Lₐ₂₈₃₉ | P10 | H | H | P18 | H | H | H | F | H | O |
| Lₐ₂₈₄₀ | P10 | H | H | P19 | H | H | H | F | H | O |
| Lₐ₂₈₄₁ | P10 | H | H | P20 | H | H | H | F | H | O |
| Lₐ₂₈₄₂ | P10 | H | H | P21 | H | H | H | F | H | O |
| Lₐ₂₈₄₃ | P10 | H | H | P22 | H | H | H | F | H | O |
| Lₐ₂₈₄₄ | P10 | H | H | P23 | H | H | H | F | H | O |
| Lₐ₂₈₄₅ | P10 | H | H | P24 | H | H | H | F | H | O |
| Lₐ₂₈₄₆ | P10 | H | H | P25 | H | H | H | F | H | O |
| Lₐ₂₈₄₇ | P10 | H | H | P26 | H | H | H | F | H | O |
| Lₐ₂₈₄₈ | P10 | H | H | P27 | H | H | H | F | H | O |
| Lₐ₂₈₄₉ | P10 | H | H | P28 | H | H | H | F | H | O |
| Lₐ₂₈₅₀ | P10 | H | H | P29 | H | H | H | F | H | O |
| Lₐ₂₈₅₁ | P10 | H | H | P30 | H | H | H | F | H | O |
| Lₐ₂₈₅₂ | P10 | H | H | P31 | H | H | H | F | H | O |
| Lₐ₂₈₅₃ | P10 | H | H | P32 | H | H | H | F | H | O |
| Lₐ₂₈₅₄ | P10 | H | H | P33 | H | H | H | F | H | O |
| Lₐ₂₈₅₅ | P10 | H | H | P34 | H | H | H | F | H | O |
| Lₐ₂₈₅₆ | P10 | H | P1 | P1 | H | H | H | F | H | O |
| Lₐ₂₈₅₇ | P10 | H | P2 | P2 | H | H | H | F | H | O |
| Lₐ₂₈₅₈ | P10 | H | F | H | H | H | H | F | H | O |
| Lₐ₂₈₅₉ | P10 | H | H | F | H | H | H | F | H | O |
| Lₐ₂₈₆₀ | P10 | H | F | P1 | H | H | H | F | H | O |
| Lₐ₂₈₆₁ | P10 | H | F | P2 | H | H | H | F | H | O |
| Lₐ₂₈₆₂ | P10 | H | P1 | F | H | H | H | F | H | O |
| Lₐ₂₈₆₃ | P10 | H | P2 | F | H | H | H | F | H | O |
| Lₐ₂₈₆₄ | P10 | H | H | H | H | H | H | F | D | O |
| Lₐ₂₈₆₅ | P10 | H | P1 | H | H | H | H | F | D | O |
| Lₐ₂₈₆₆ | P10 | H | P2 | H | H | H | H | F | D | O |
| Lₐ₂₈₆₇ | P10 | H | P3 | H | H | H | H | F | D | O |
| Lₐ₂₈₆₈ | P10 | H | P4 | H | H | H | H | F | D | O |
| Lₐ₂₈₆₉ | P10 | H | P5 | H | H | H | H | F | D | O |
| Lₐ₂₈₇₀ | P10 | H | P6 | H | H | H | H | F | D | O |
| Lₐ₂₈₇₁ | P10 | H | P7 | H | H | H | H | F | D | O |
| Lₐ₂₈₇₂ | P10 | H | P8 | H | H | H | H | F | D | O |
| Lₐ₂₈₇₃ | P10 | H | P9 | H | H | H | H | F | D | O |
| Lₐ₂₈₇₄ | P10 | H | P10 | H | H | H | H | F | D | O |
| Lₐ₂₈₇₅ | P10 | H | P11 | H | H | H | H | F | D | O |
| Lₐ₂₈₇₆ | P10 | H | P12 | H | H | H | H | F | D | O |
| Lₐ₂₈₇₇ | P10 | H | P13 | H | H | H | H | F | D | O |
| Lₐ₂₈₇₈ | P10 | H | P14 | H | H | H | H | F | D | O |
| Lₐ₂₈₇₉ | P10 | H | P15 | H | H | H | H | F | D | O |
| Lₐ₂₈₈₀ | P10 | H | P16 | H | H | H | H | F | D | O |
| Lₐ₂₈₈₁ | P10 | H | P17 | H | H | H | H | F | D | O |
| Lₐ₂₈₈₂ | P10 | H | P18 | H | H | H | H | F | D | O |
| Lₐ₂₈₈₃ | P10 | H | P19 | H | H | H | H | F | D | O |
| Lₐ₂₈₈₄ | P10 | H | P20 | H | H | H | H | F | D | O |
| Lₐ₂₈₈₅ | P10 | H | P21 | H | H | H | H | F | D | O |
| Lₐ₂₈₈₆ | P10 | H | P22 | H | H | H | H | F | D | O |
| Lₐ₂₈₈₇ | P10 | H | P23 | H | H | H | H | F | D | O |
| Lₐ₂₈₈₈ | P10 | H | P24 | H | H | H | H | F | D | O |
| Lₐ₂₈₈₉ | P10 | H | P25 | H | H | H | H | F | D | O |
| Lₐ₂₈₉₀ | P10 | H | P26 | H | H | H | H | F | D | O |
| Lₐ₂₈₉₁ | P10 | H | P27 | H | H | H | H | F | D | O |
| Lₐ₂₈₉₂ | P10 | H | P28 | H | H | H | H | F | D | O |
| Lₐ₂₈₉₃ | P10 | H | P29 | H | H | H | H | F | D | O |
| Lₐ₂₈₉₄ | P10 | H | P30 | H | H | H | H | F | D | O |
| Lₐ₂₈₉₅ | P10 | H | P31 | H | H | H | H | F | D | O |
| Lₐ₂₈₉₆ | P10 | H | P32 | H | H | H | H | F | D | O |
| Lₐ₂₈₉₇ | P10 | H | P33 | H | H | H | H | F | D | O |
| Lₐ₂₈₉₈ | P10 | H | P34 | H | H | H | H | F | D | O |
| Lₐ₂₈₉₉ | P10 | H | H | P1 | H | H | H | F | D | O |
| Lₐ₂₉₀₀ | P10 | H | H | P2 | H | H | H | F | D | O |
| Lₐ₂₉₀₁ | P10 | H | H | P3 | H | H | H | F | D | O |
| Lₐ₂₉₀₂ | P10 | H | H | P4 | H | H | H | F | D | O |
| Lₐ₂₉₀₃ | P10 | H | H | P5 | H | H | H | F | D | O |
| Lₐ₂₉₀₄ | P10 | H | H | P6 | H | H | H | F | D | O |
| Lₐ₂₉₀₅ | P10 | H | H | P7 | H | H | H | F | D | O |
| Lₐ₂₉₀₆ | P10 | H | H | P8 | H | H | H | F | D | O |
| Lₐ₂₉₀₇ | P10 | H | H | P9 | H | H | H | F | D | O |
| Lₐ₂₉₀₈ | P10 | H | H | P10 | H | H | H | F | D | O |
| Lₐ₂₉₀₉ | P10 | H | H | P11 | H | H | H | F | D | O |
| Lₐ₂₉₁₀ | P10 | H | H | P12 | H | H | H | F | D | O |
| Lₐ₂₉₁₁ | P10 | H | H | P13 | H | H | H | F | D | O |
| Lₐ₂₉₁₂ | P10 | H | H | P14 | H | H | H | F | D | O |
| Lₐ₂₉₁₃ | P10 | H | H | P15 | H | H | H | F | D | O |
| Lₐ₂₉₁₄ | P10 | H | H | P16 | H | H | H | F | D | O |
| Lₐ₂₉₁₅ | P10 | H | H | P17 | H | H | H | F | D | O |
| Lₐ₂₉₁₆ | P10 | H | H | P18 | H | H | H | F | D | O |
| Lₐ₂₉₁₇ | P10 | H | H | P19 | H | H | H | F | D | O |
| Lₐ₂₉₁₈ | P10 | H | H | P20 | H | H | H | F | D | O |
| Lₐ₂₉₁₉ | P10 | H | H | P21 | H | H | H | F | D | O |
| Lₐ₂₉₂₀ | P10 | H | H | P22 | H | H | H | F | D | O |
| Lₐ₂₉₂₁ | P10 | H | H | P23 | H | H | H | F | D | O |
| Lₐ₂₉₂₂ | P10 | H | H | P24 | H | H | H | F | D | O |
| Lₐ₂₉₂₃ | P10 | H | H | P25 | H | H | H | F | D | O |
| Lₐ₂₉₂₄ | P10 | H | H | P26 | H | H | H | F | D | O |
| Lₐ₂₉₂₅ | P10 | H | H | P27 | H | H | H | F | D | O |
| Lₐ₂₉₂₆ | P10 | H | H | P28 | H | H | H | F | D | O |
| Lₐ₂₉₂₇ | P10 | H | H | P29 | H | H | H | F | D | O |
| Lₐ₂₉₂₈ | P10 | H | H | P30 | H | H | H | F | D | O |
| Lₐ₂₉₂₉ | P10 | H | H | P31 | H | H | H | F | D | O |
| Lₐ₂₉₃₀ | P10 | H | H | P32 | H | H | H | F | D | O |
| Lₐ₂₉₃₁ | P10 | H | H | P33 | H | H | H | F | D | O |
| Lₐ₂₉₃₂ | P10 | H | H | P34 | H | H | H | F | D | O |
| Lₐ₂₉₃₃ | P10 | H | P1 | P1 | H | H | H | F | D | O |
| Lₐ₂₉₃₄ | P10 | H | P2 | P2 | H | H | H | F | D | O |
| Lₐ₂₉₃₅ | P10 | H | F | H | H | H | H | F | D | O |
| Lₐ₂₉₃₆ | P10 | H | H | F | H | H | H | F | D | O |
| Lₐ₂₉₃₇ | P10 | H | F | P1 | H | H | H | F | D | O |
| Lₐ₂₉₃₈ | P10 | H | F | P2 | H | H | H | F | D | O |
| Lₐ₂₉₃₉ | P10 | H | P1 | F | H | H | H | F | D | O |
| Lₐ₂₉₄₀ | P10 | H | P2 | F | H | H | H | F | D | O |
| Lₐ₂₉₄₁ | P10 | D | H | P1 | H | H | H | F | H | O |
| Lₐ₂₉₄₂ | P10 | H | H | P2 | D | H | H | F | H | O |
| Lₐ₂₉₄₃ | P10 | H | H | H | H | H | H | F | P23 | O |
| Lₐ₂₉₄₄ | P10 | H | H | H | H | H | H | F | P24 | O |
| Lₐ₂₉₄₅ | P10 | H | H | H | H | H | H | F | P25 | O |
| Lₐ₂₉₄₆ | P10 | H | H | H | H | H | H | F | P26 | O |
| Lₐ₂₉₄₇ | P10 | H | H | H | H | H | H | F | P27 | O |
| Lₐ₂₉₄₈ | P10 | H | H | H | H | H | H | F | P28 | O |
| Lₐ₂₉₄₉ | P10 | H | H | H | H | H | H | F | P29 | O |
| Lₐ₂₉₅₀ | P10 | H | H | H | H | H | H | F | P30 | O |
| Lₐ₂₉₅₁ | P10 | H | H | H | H | H | H | F | P31 | O |
| Lₐ₂₉₅₂ | P10 | H | H | H | H | H | H | F | P32 | O |
| Lₐ₂₉₅₃ | P10 | H | H | H | H | H | H | F | P33 | O |
| Lₐ₂₉₅₄ | P10 | H | H | H | H | H | H | F | P34 | O |
| Lₐ₂₉₅₅ | P10 | H | H | H | H | H | H | F | P35 | O |
| Lₐ₂₉₅₆ | P10 | H | H | H | H | H | H | F | P36 | O |
| Lₐ₂₉₅₇ | P10 | H | H | H | H | H | H | F | P37 | O |
| Lₐ₂₉₅₈ | P10 | H | H | H | H | H | H | F | P38 | O |
| Lₐ₂₉₅₉ | P10 | H | H | H | H | H | H | F | P39 | O |
| Lₐ₂₉₆₀ | P10 | H | H | H | H | H | H | F | P40 | O |
| Lₐ₂₉₆₁ | P10 | H | H | H | H | H | H | F | P41 | O |
| Lₐ₂₉₆₂ | P10 | H | H | H | H | H | H | F | P42 | O |
| Lₐ₂₉₆₃ | P10 | H | H | H | H | H | H | F | P43 | O |
| Lₐ₂₉₆₄ | P10 | H | H | H | H | H | H | F | P44 | O |
| Lₐ₂₉₆₅ | P10 | H | H | H | H | H | H | F | P45 | O |
| Lₐ₂₉₆₆ | P10 | H | H | H | H | H | H | F | P46 | O |
| Lₐ₂₉₆₇ | P10 | H | H | H | H | H | H | F | P47 | O |
| Lₐ₂₉₆₈ | P10 | H | H | H | H | H | H | F | P48 | O |
| Lₐ₂₉₆₉ | P10 | H | H | H | H | H | H | F | P49 | O |
| Lₐ₂₉₇₀ | P10 | H | H | H | H | H | H | F | P50 | O |
| Lₐ₂₉₇₁ | P10 | H | H | H | H | H | H | F | P51 | O |
| Lₐ₂₉₇₂ | P10 | H | H | H | H | H | H | F | P52 | O |
| Lₐ₂₉₇₃ | P10 | H | H | H | H | H | H | F | P53 | O |
| Lₐ₂₉₇₄ | P10 | H | H | H | H | H | H | F | P54 | O |
| Lₐ₂₉₇₅ | P10 | H | H | H | H | H | H | F | P55 | O |
| Lₐ₂₉₇₆ | P10 | H | H | H | H | H | H | F | P56 | O |
| Lₐ₂₉₇₇ | P10 | H | H | H | H | H | H | F | P57 | O |
| Lₐ₂₉₇₈ | P10 | H | H | H | H | H | H | F | P58 | O |
| Lₐ₂₉₇₉ | P10 | H | H | H | H | H | H | F | P59 | O |
| Lₐ₂₉₈₀ | P10 | H | H | H | H | H | H | F | P60 | O |
| Lₐ₂₉₈₁ | P10 | H | H | H | H | H | H | F | P61 | O |
| Lₐ₂₉₈₂ | P10 | H | H | H | H | H | H | F | P62 | O |
| Lₐ₂₉₈₃ | P10 | H | H | H | H | H | H | F | P63 | O |
| Lₐ₂₉₈₄ | P10 | H | H | H | H | H | H | F | P64 | O |
| Lₐ₂₉₈₅ | P10 | H | H | H | H | H | H | F | P65 | O |
| Lₐ₂₉₈₆ | P10 | H | H | H | H | H | H | F | P66 | O |
| Lₐ₂₉₈₇ | P10 | H | H | H | H | H | H | F | P67 | O |
| Lₐ₂₉₈₈ | P10 | H | H | H | H | H | H | F | P68 | O |
| Lₐ₂₉₈₉ | P10 | H | H | H | H | H | H | F | P69 | O |
| Lₐ₂₉₉₀ | P10 | H | H | H | H | H | H | F | P70 | O |
| Lₐ₂₉₉₁ | P10 | H | H | H | H | H | H | F | P71 | O |
| Lₐ₂₉₉₂ | P10 | H | H | H | H | H | H | F | P72 | O |
| Lₐ₂₉₉₃ | P10 | H | H | H | H | H | H | F | P73 | O |
| Lₐ₂₉₉₄ | P10 | H | H | H | H | H | H | F | P74 | O |
| Lₐ₂₉₉₅ | P10 | H | H | H | H | H | H | F | P75 | O |
| Lₐ₂₉₉₆ | P10 | H | H | H | H | H | H | F | P76 | O |
| Lₐ₂₉₉₇ | P10 | H | H | H | H | H | H | F | P77 | O |
| Lₐ₂₉₉₈ | P10 | H | H | H | H | H | H | F | P78 | O |
| Lₐ₂₉₉₉ | P10 | H | H | H | H | H | H | F | P79 | O |
| Lₐ₃₀₀₀ | P10 | H | H | H | H | H | H | F | P80 | O |
| Lₐ₃₀₀₁ | P10 | H | H | H | H | H | H | F | P81 | O |
| Lₐ₃₀₀₂ | P10 | H | H | H | H | H | H | F | P82 | O |
| Lₐ₃₀₀₃ | P10 | H | H | H | H | H | H | F | P83 | O |
| Lₐ₃₀₀₄ | P10 | H | H | H | H | H | H | F | P84 | O |
| Lₐ₃₀₀₅ | P10 | H | H | H | H | H | H | F | P85 | O |
| Lₐ₃₀₀₆ | P10 | H | H | H | H | H | H | F | P86 | O |
| Lₐ₃₀₀₇ | P10 | H | H | H | H | H | H | F | P87 | O |
| Lₐ₃₀₀₈ | P10 | H | H | H | H | H | H | F | P88 | O |
| Lₐ₃₀₀₉ | P10 | H | H | H | H | H | H | F | P89 | O |
| Lₐ₃₀₁₀ | P10 | H | H | H | H | H | H | F | P90 | O |
| Lₐ₃₀₁₁ | P10 | H | P1 | H | H | H | H | F | P23 | O |
| Lₐ₃₀₁₂ | P10 | H | P2 | H | H | H | H | F | P23 | O |
| Lₐ₃₀₁₃ | P10 | H | P3 | H | H | H | H | F | P23 | O |
| Lₐ₃₀₁₄ | P10 | H | P4 | H | H | H | H | F | P23 | O |
| Lₐ₃₀₁₅ | P10 | H | P5 | H | H | H | H | F | P23 | O |
| Lₐ₃₀₁₆ | P10 | H | P6 | H | H | H | H | F | P23 | O |
| Lₐ₃₀₁₇ | P10 | H | P7 | H | H | H | H | F | P23 | O |
| Lₐ₃₀₁₈ | P10 | H | P8 | H | H | H | H | F | P23 | O |
| Lₐ₃₀₁₉ | P10 | H | P9 | H | H | H | H | F | P23 | O |
| Lₐ₃₀₂₀ | P10 | H | P10 | H | H | H | H | F | P23 | O |
| Lₐ₃₀₂₁ | P10 | H | P11 | H | H | H | H | F | P23 | O |
| Lₐ₃₀₂₂ | P10 | H | P12 | H | H | H | H | F | P23 | O |
| Lₐ₃₀₂₃ | P10 | H | P15 | H | H | H | H | F | P23 | O |
| Lₐ₃₀₂₄ | P10 | H | P17 | H | H | H | H | F | P23 | O |
| Lₐ₃₀₂₅ | P10 | H | H | P1 | H | H | H | F | P23 | O |
| Lₐ₃₀₂₆ | P10 | H | H | P2 | H | H | H | F | P23 | O |
| Lₐ₃₀₂₇ | P10 | H | H | P3 | H | H | H | F | P23 | O |
| Lₐ₃₀₂₈ | P10 | H | H | P4 | H | H | H | F | P23 | O |
| Lₐ₃₀₂₉ | P10 | H | H | P5 | H | H | H | F | P23 | O |
| Lₐ₃₀₃₀ | P10 | H | H | P6 | H | H | H | F | P23 | O |
| Lₐ₃₀₃₁ | P10 | H | H | P7 | H | H | H | F | P23 | O |
| Lₐ₃₀₃₂ | P10 | H | H | P8 | H | H | H | F | P23 | O |
| Lₐ₃₀₃₃ | P10 | H | H | P9 | H | H | H | F | P23 | O |
| Lₐ₃₀₃₄ | P10 | H | H | P10 | H | H | H | F | P23 | O |
| Lₐ₃₀₃₅ | P10 | H | H | P11 | H | H | H | F | P23 | O |
| Lₐ₃₀₃₆ | P10 | H | H | P12 | H | H | H | F | P23 | O |
| Lₐ₃₀₃₇ | P10 | H | H | P15 | H | H | H | F | P23 | O |
| Lₐ₃₀₃₈ | P10 | H | H | P17 | H | H | H | F | P23 | O |
| Lₐ₃₀₃₉ | P10 | H | F | H | H | H | H | F | P23 | O |
| Lₐ₃₀₄₀ | P10 | H | H | F | H | H | H | F | P23 | O |
| Lₐ₃₀₄₁ | P10 | H | F | P1 | H | H | H | F | P23 | O |
| Lₐ₃₀₄₂ | P10 | H | F | P2 | H | H | H | F | P23 | O |
| Lₐ₃₀₄₃ | P10 | H | P1 | F | H | H | H | F | P23 | O |
| Lₐ₃₀₄₄ | P10 | H | P2 | F | H | H | H | F | P23 | O |
| Lₐ₃₀₄₅ | P10 | H | P1 | P1 | H | H | H | F | P23 | O |
| Lₐ₃₀₄₆ | P10 | H | P2 | P2 | H | H | H | F | P23 | O |
| Lₐ₃₀₄₇ | P10 | H | P1 | H | H | H | H | F | P24 | O |
| Lₐ₃₀₄₈ | P10 | H | P2 | H | H | H | H | F | P24 | O |
| Lₐ₃₀₄₉ | P10 | H | P3 | H | H | H | H | F | P24 | O |
| Lₐ₃₀₅₀ | P10 | H | P4 | H | H | H | H | F | P24 | O |
| Lₐ₃₀₅₁ | P10 | H | P5 | H | H | H | H | F | P24 | O |
| Lₐ₃₀₅₂ | P10 | H | P6 | H | H | H | H | F | P24 | O |
| Lₐ₃₀₅₃ | P10 | H | P7 | H | H | H | H | F | P24 | O |
| Lₐ₃₀₅₄ | P10 | H | P8 | H | H | H | H | F | P24 | O |
| Lₐ₃₀₅₅ | P10 | H | P9 | H | H | H | H | F | P24 | O |
| Lₐ₃₀₅₆ | P10 | H | P10 | H | H | H | H | F | P24 | O |
| Lₐ₃₀₅₇ | P10 | H | P1 | H | H | H | H | F | P24 | O |
| Lₐ₃₀₅₈ | P10 | H | P12 | H | H | H | H | F | P24 | O |
| Lₐ₃₀₅₉ | P10 | H | P15 | H | H | H | H | F | P24 | O |
| Lₐ₃₀₆₀ | P10 | H | P17 | H | H | H | H | F | P24 | O |
| Lₐ₃₀₆₁ | P10 | H | H | P1 | H | H | H | F | P24 | O |
| Lₐ₃₀₆₂ | P10 | H | H | P2 | H | H | H | F | P24 | O |
| Lₐ₃₀₆₃ | P10 | H | H | P3 | H | H | H | F | P24 | O |
| Lₐ₃₀₆₄ | P10 | H | H | P4 | H | H | H | F | P24 | O |
| Lₐ₃₀₆₅ | P10 | H | H | P5 | H | H | H | F | P24 | O |
| Lₐ₃₀₆₆ | P10 | H | H | P6 | H | H | H | F | P24 | O |
| Lₐ₃₀₆₇ | P10 | H | H | P7 | H | H | H | F | P24 | O |
| Lₐ₃₀₆₈ | P10 | H | H | P8 | H | H | H | F | P24 | O |
| Lₐ₃₀₆₉ | P10 | H | H | P9 | H | H | H | F | P24 | O |
| Lₐ₃₀₇₀ | P10 | H | H | P10 | H | H | H | F | P24 | O |
| Lₐ₃₀₇₁ | P10 | H | H | P11 | H | H | H | F | P24 | O |
| Lₐ₃₀₇₂ | P10 | H | H | P12 | H | H | H | F | P24 | O |
| Lₐ₃₀₇₃ | P10 | H | H | P15 | H | H | H | F | P24 | O |
| Lₐ₃₀₇₄ | P10 | H | H | P17 | H | H | H | F | P24 | O |
| Lₐ₃₀₇₅ | P10 | H | F | H | H | H | H | F | P24 | O |
| Lₐ₃₀₇₆ | P10 | H | H | F | H | H | H | F | P24 | O |
| Lₐ₃₀₇₇ | P10 | H | F | P1 | H | H | H | F | P24 | O |
| Lₐ₃₀₇₈ | P10 | H | F | P2 | H | H | H | F | P24 | O |
| Lₐ₃₀₇₉ | P10 | H | P1 | F | H | H | H | F | P24 | O |
| Lₐ₃₀₈₀ | P10 | H | P2 | F | H | H | H | F | P24 | O |
| Lₐ₃₀₈₁ | P10 | H | P1 | P1 | H | H | H | F | P24 | O |
| Lₐ₃₀₈₂ | P10 | H | P2 | P2 | H | H | H | F | P24 | O |
| Lₐ₃₀₈₃ | P10 | H | P1 | H | H | H | H | F | P73 | O |
| Lₐ₃₀₈₄ | P10 | H | P2 | H | H | H | H | F | P73 | O |
| Lₐ₃₀₈₅ | P10 | H | P3 | H | H | H | H | F | P73 | O |
| Lₐ₃₀₈₆ | P10 | H | P4 | H | H | H | H | F | P73 | O |
| Lₐ₃₀₈₇ | P10 | H | P5 | H | H | H | H | F | P73 | O |
| Lₐ₃₀₈₈ | P10 | H | P6 | H | H | H | H | F | P73 | O |
| Lₐ₃₀₈₉ | P10 | H | P7 | H | H | H | H | F | P73 | O |
| Lₐ₃₀₉₀ | P10 | H | P8 | H | H | H | H | F | P73 | O |
| Lₐ₃₀₉₁ | P10 | H | P9 | H | H | H | H | F | P73 | O |
| Lₐ₃₀₉₂ | P10 | H | P10 | H | H | H | H | F | P73 | O |
| Lₐ₃₀₉₃ | P10 | H | P11 | H | H | H | H | F | P73 | O |
| Lₐ₃₀₉₄ | P10 | H | P12 | H | H | H | H | F | P73 | O |
| Lₐ₃₀₉₅ | P10 | H | P15 | H | H | H | H | F | P73 | O |
| Lₐ₃₀₉₆ | P10 | H | P17 | H | H | H | H | F | P73 | O |
| Lₐ₃₀₉₇ | P10 | H | H | P1 | H | H | H | F | P73 | O |
| Lₐ₃₀₉₈ | P10 | H | H | P2 | H | H | H | F | P73 | O |
| Lₐ₃₀₉₉ | P10 | H | H | P3 | H | H | H | F | P73 | O |
| Lₐ₃₁₀₀ | P10 | H | H | P4 | H | H | H | F | P73 | O |
| Lₐ₃₁₀₁ | P10 | H | H | P5 | H | H | H | F | P73 | O |
| Lₐ₃₁₀₂ | P10 | H | H | P6 | H | H | H | F | P73 | O |
| Lₐ₃₁₀₃ | P10 | H | H | P7 | H | H | H | F | P73 | O |
| Lₐ₃₁₀₄ | P10 | H | H | P8 | H | H | H | F | P73 | O |
| Lₐ₃₁₀₅ | P10 | H | H | P9 | H | H | H | F | P73 | O |
| Lₐ₃₁₀₆ | P10 | H | H | P10 | H | H | H | F | P73 | O |
| Lₐ₃₁₀₇ | P10 | H | H | P11 | H | H | H | F | P73 | O |
| Lₐ₃₁₀₈ | P10 | H | H | P12 | H | H | H | F | P73 | O |
| Lₐ₃₁₀₉ | P10 | H | H | P15 | H | H | H | F | P73 | O |
| Lₐ₃₁₁₀ | P10 | H | H | P17 | H | H | H | F | P73 | O |
| Lₐ₃₁₁₁ | P10 | H | F | H | H | H | H | F | P73 | O |
| Lₐ₃₁₁₂ | P10 | H | H | F | H | H | H | F | P73 | O |
| Lₐ₃₁₁₃ | P10 | H | F | P1 | H | H | H | F | P73 | O |
| Lₐ₃₁₁₄ | P10 | H | F | P2 | H | H | H | F | P73 | O |
| Lₐ₃₁₁₅ | P10 | H | P1 | F | H | H | H | F | P73 | O |
| Lₐ₃₁₁₆ | P10 | H | P2 | F | H | H | H | F | P73 | O |
| Lₐ₃₁₁₇ | P10 | H | P1 | P1 | H | H | H | F | P73 | O |
| Lₐ₃₁₁₈ | P10 | H | P2 | P2 | H | H | H | F | P73 | O |
| Lₐ₃₁₁₉ | P10 | H | P1 | H | H | H | H | F | P74 | O |
| Lₐ₃₁₂₀ | P10 | H | P2 | H | H | H | H | F | P74 | O |
| Lₐ₃₁₂₁ | P10 | H | P3 | H | H | H | H | F | P74 | O |
| Lₐ₃₁₂₂ | P10 | H | P4 | H | H | H | H | F | P74 | O |
| Lₐ₃₁₂₃ | P10 | H | P5 | H | H | H | H | F | P74 | O |
| Lₐ₃₁₂₄ | P10 | H | P6 | H | H | H | H | F | P74 | O |
| Lₐ₃₁₂₅ | P10 | H | P7 | H | H | H | H | F | P74 | O |
| Lₐ₃₁₂₆ | P10 | H | P8 | H | H | H | H | F | P74 | O |
| Lₐ₃₁₂₇ | P10 | H | P9 | H | H | H | H | F | P74 | O |
| Lₐ₃₁₂₈ | P10 | H | P10 | H | H | H | H | F | P74 | O |
| Lₐ₃₁₂₉ | P10 | H | P11 | H | H | H | H | F | P74 | O |
| Lₐ₃₁₃₀ | P10 | H | P12 | H | H | H | H | F | P74 | O |
| Lₐ₃₁₃₁ | P10 | H | P15 | H | H | H | H | F | P74 | O |
| Lₐ₃₁₃₂ | P10 | H | P17 | H | H | H | H | F | P74 | O |
| Lₐ₃₁₃₃ | P10 | H | H | P1 | H | H | H | F | P74 | O |
| Lₐ₃₁₃₄ | P10 | H | H | P2 | H | H | H | F | P74 | O |
| Lₐ₃₁₃₅ | P10 | H | H | P3 | H | H | H | F | P74 | O |
| Lₐ₃₁₃₆ | P10 | H | H | P4 | H | H | H | F | P74 | O |
| Lₐ₃₁₃₇ | P10 | H | H | P5 | H | H | H | F | P74 | O |
| Lₐ₃₁₃₈ | P10 | H | H | P6 | H | H | H | F | P74 | O |
| Lₐ₃₁₃₉ | P10 | H | H | P7 | H | H | H | F | P74 | O |
| Lₐ₃₁₄₀ | P10 | H | H | P8 | H | H | H | F | P74 | O |
| Lₐ₃₁₄₁ | P10 | H | H | P9 | H | H | H | F | P74 | O |
| Lₐ₃₁₄₂ | P10 | H | H | P10 | H | H | H | F | P74 | O |
| Lₐ₃₁₄₃ | P10 | H | H | P11 | H | H | H | F | P74 | O |
| Lₐ₃₁₄₄ | P10 | H | H | P12 | H | H | H | F | P74 | O |
| Lₐ₃₁₄₅ | P10 | H | H | P15 | H | H | H | F | P74 | O |
| Lₐ₃₁₄₆ | P10 | H | H | P17 | H | H | H | F | P74 | O |
| Lₐ₃₁₄₇ | P10 | H | F | H | H | H | H | F | P74 | O |
| Lₐ₃₁₄₈ | P10 | H | H | F | H | H | H | F | P74 | O |
| Lₐ₃₁₄₉ | P10 | H | F | P1 | H | H | H | F | P74 | O |
| Lₐ₃₁₅₀ | P10 | H | F | P2 | H | H | H | F | P74 | O |
| Lₐ₃₁₅₁ | P10 | H | P1 | F | H | H | H | F | P74 | O |
| Lₐ₃₁₅₂ | P10 | H | P2 | F | H | H | H | F | P74 | O |
| Lₐ₃₁₅₃ | P10 | H | P1 | P1 | H | H | H | F | P74 | O |
| Lₐ₃₁₅₄ | P10 | H | P2 | P2 | H | H | H | F | P74 | O |
| Lₐ₃₁₅₅ | P10 | H | P1 | H | H | H | H | F | P79 | O |
| Lₐ₃₁₅₆ | P10 | H | P2 | H | H | H | H | F | P79 | O |
| Lₐ₃₁₅₇ | P10 | H | P3 | H | H | H | H | F | P79 | O |
| Lₐ₃₁₅₈ | P10 | H | P4 | H | H | H | H | F | P79 | O |
| Lₐ₃₁₅₉ | P10 | H | P5 | H | H | H | H | F | P79 | O |
| Lₐ₃₁₆₀ | P10 | H | P6 | H | H | H | H | F | P79 | O |
| Lₐ₃₁₆₁ | P10 | H | P7 | H | H | H | H | F | P79 | O |
| Lₐ₃₁₆₂ | P10 | H | P8 | H | H | H | H | F | P79 | O |
| Lₐ₃₁₆₃ | P10 | H | P9 | H | H | H | H | F | P79 | O |
| Lₐ₃₁₆₄ | P10 | H | P10 | H | H | H | H | F | P79 | O |
| Lₐ₃₁₆₅ | P10 | H | P11 | H | H | H | H | F | P79 | O |
| Lₐ₃₁₆₆ | P10 | H | P12 | H | H | H | H | F | P79 | O |
| Lₐ₃₁₆₇ | P10 | H | P15 | H | H | H | H | F | P79 | O |
| Lₐ₃₁₆₈ | P10 | H | P17 | H | H | H | H | F | P79 | O |
| Lₐ₃₁₆₉ | P10 | H | H | P1 | H | H | H | F | P79 | O |
| Lₐ₃₁₇₀ | P10 | H | H | P2 | H | H | H | F | P79 | O |
| Lₐ₃₁₇₁ | P10 | H | H | P3 | H | H | H | F | P79 | O |
| Lₐ₃₁₇₂ | P10 | H | H | P4 | H | H | H | F | P79 | O |
| Lₐ₃₁₇₃ | P10 | H | H | P5 | H | H | H | F | P79 | O |
| Lₐ₃₁₇₄ | P10 | H | H | P6 | H | H | H | F | P79 | O |
| Lₐ₃₁₇₅ | P10 | H | H | P7 | H | H | H | F | P79 | O |
| Lₐ₃₁₇₆ | P10 | H | H | P8 | H | H | H | F | P79 | O |
| Lₐ₃₁₇₇ | P10 | H | H | P9 | H | H | H | F | P79 | O |
| Lₐ₃₁₇₈ | P10 | H | H | P10 | H | H | H | F | P79 | O |
| Lₐ₃₁₇₉ | P10 | H | H | P11 | H | H | H | F | P79 | O |
| Lₐ₃₁₈₀ | P10 | H | H | P12 | H | H | H | F | P79 | O |
| Lₐ₃₁₈₁ | P10 | H | H | P15 | H | H | H | F | P79 | O |
| Lₐ₃₁₈₂ | P10 | H | H | P17 | H | H | H | F | P79 | O |
| Lₐ₃₁₈₃ | P10 | H | F | H | H | H | H | F | P79 | O |
| Lₐ₃₁₈₄ | P10 | H | H | F | H | H | H | F | P79 | O |
| Lₐ₃₁₈₅ | P10 | H | F | P1 | H | H | H | F | P79 | O |
| Lₐ₃₁₈₆ | P10 | H | F | P2 | H | H | H | F | P79 | O |
| Lₐ₃₁₈₇ | P10 | H | P1 | F | H | H | H | F | P79 | O |
| Lₐ₃₁₈₈ | P10 | H | P2 | F | H | H | H | F | P79 | O |
| Lₐ₃₁₈₉ | P10 | H | P1 | P1 | H | H | H | F | P79 | O |
| Lₐ₃₁₉₀ | P10 | H | P2 | P2 | H | H | H | F | P79 | O |
| Lₐ₃₁₉₁ | P10 | H | P1 | H | H | H | H | F | P80 | O |
| Lₐ₃₁₉₂ | P10 | H | P2 | H | H | H | H | F | P80 | O |
| Lₐ₃₁₉₃ | P10 | H | P3 | H | H | H | H | F | P80 | O |
| Lₐ₃₁₉₄ | P10 | H | P4 | H | H | H | H | F | P80 | O |
| Lₐ₃₁₉₅ | P10 | H | P5 | H | H | H | H | F | P80 | O |
| Lₐ₃₁₉₆ | P10 | H | P6 | H | H | H | H | F | P80 | O |
| Lₐ₃₁₉₇ | P10 | H | P7 | H | H | H | H | F | P80 | O |
| Lₐ₃₁₉₈ | P10 | H | P8 | H | H | H | H | F | P80 | O |
| Lₐ₃₁₉₉ | P10 | H | P9 | H | H | H | H | F | P80 | O |
| Lₐ₃₂₀₀ | P10 | H | P10 | H | H | H | H | F | P80 | O |
| Lₐ₃₂₀₁ | P10 | H | P11 | H | H | H | H | F | P80 | O |
| Lₐ₃₂₀₂ | P10 | H | P12 | H | H | H | H | F | P80 | O |
| Lₐ₃₂₀₃ | P10 | H | P15 | H | H | H | H | F | P80 | O |
| Lₐ₃₂₀₄ | P10 | H | P17 | H | H | H | H | F | P80 | O |
| Lₐ₃₂₀₅ | P10 | H | H | P1 | H | H | H | F | P80 | O |
| Lₐ₃₂₀₆ | P10 | H | H | P2 | H | H | H | F | P80 | O |
| Lₐ₃₂₀₇ | P10 | H | H | P3 | H | H | H | F | P80 | O |
| Lₐ₃₂₀₈ | P10 | H | H | P4 | H | H | H | F | P80 | O |
| Lₐ₃₂₀₉ | P10 | H | H | P5 | H | H | H | F | P80 | O |
| Lₐ₃₂₁₀ | P10 | H | H | P6 | H | H | H | F | P80 | O |
| Lₐ₃₂₁₁ | P10 | H | H | P7 | H | H | H | F | P80 | O |
| Lₐ₃₂₁₂ | P10 | H | H | P8 | H | H | H | F | P80 | O |
| Lₐ₃₂₁₃ | P10 | H | H | P9 | H | H | H | F | P80 | O |
| Lₐ₃₂₁₄ | P10 | H | H | P10 | H | H | H | F | P80 | O |
| Lₐ₃₂₁₅ | P10 | H | H | P11 | H | H | H | F | P80 | O |
| Lₐ₃₂₁₆ | P10 | H | H | P12 | H | H | H | F | P80 | O |
| Lₐ₃₂₁₇ | P10 | H | H | P15 | H | H | H | F | P80 | O |
| Lₐ₃₂₁₈ | P10 | H | H | P17 | H | H | H | F | P80 | O |
| Lₐ₃₂₁₉ | P10 | H | F | H | H | H | H | F | P80 | O |
| Lₐ₃₂₂₀ | P10 | H | H | F | H | H | H | F | P80 | O |
| Lₐ₃₂₂₁ | P10 | H | F | P1 | H | H | H | F | P80 | O |
| Lₐ₃₂₂₂ | P10 | H | F | P2 | H | H | H | F | P80 | O |
| Lₐ₃₂₂₃ | P10 | H | P1 | F | H | H | H | F | P80 | O |
| Lₐ₃₂₂₄ | P10 | H | P2 | F | H | H | H | F | P80 | O |
| Lₐ₃₂₂₅ | P10 | H | P1 | P1 | H | H | H | F | P80 | O |
| Lₐ₃₂₂₆ | P10 | H | P2 | P2 | H | H | H | F | P80 | O |
| Lₐ₃₂₂₇ | P10 | H | P1 | H | H | H | H | F | P89 | O |
| Lₐ₃₂₂₈ | P10 | H | P2 | H | H | H | H | F | P89 | O |
| Lₐ₃₂₂₉ | P10 | H | P3 | H | H | H | H | F | P89 | O |
| Lₐ₃₂₃₀ | P10 | H | P4 | H | H | H | H | F | P89 | O |
| Lₐ₃₂₃₁ | P10 | H | P5 | H | H | H | H | F | P89 | O |
| Lₐ₃₂₃₂ | P10 | H | P6 | H | H | H | H | F | P89 | O |
| Lₐ₃₂₃₃ | P10 | H | P7 | H | H | H | H | F | P89 | O |
| Lₐ₃₂₃₄ | P10 | H | P8 | H | H | H | H | F | P89 | O |
| Lₐ₃₂₃₅ | P10 | H | P9 | H | H | H | H | F | P89 | O |
| Lₐ₃₂₃₆ | P10 | H | P10 | H | H | H | H | F | P89 | O |
| Lₐ₃₂₃₇ | P10 | H | P11 | H | H | H | H | F | P89 | O |
| Lₐ₃₂₃₈ | P10 | H | P12 | H | H | H | H | F | P89 | O |
| Lₐ₃₂₃₉ | P10 | H | P15 | H | H | H | H | F | P89 | O |
| Lₐ₃₂₄₀ | P10 | H | P17 | H | H | H | H | F | P89 | O |
| Lₐ₃₂₄₁ | P10 | H | H | P1 | H | H | H | F | P89 | O |
| Lₐ₃₂₄₂ | P10 | H | H | P2 | H | H | H | F | P89 | O |
| Lₐ₃₂₄₃ | P10 | H | H | P3 | H | H | H | F | P89 | O |
| Lₐ₃₂₄₄ | P10 | H | H | P4 | H | H | H | F | P89 | O |
| Lₐ₃₂₄₅ | P10 | H | H | P5 | H | H | H | F | P89 | O |
| Lₐ₃₂₄₆ | P10 | H | H | P6 | H | H | H | F | P89 | O |
| Lₐ₃₂₄₇ | P10 | H | H | P7 | H | H | H | F | P89 | O |
| Lₐ₃₂₄₈ | P10 | H | H | P8 | H | H | H | F | P89 | O |
| Lₐ₃₂₄₉ | P10 | H | H | P9 | H | H | H | F | P89 | O |
| Lₐ₃₂₅₀ | P10 | H | H | P10 | H | H | H | F | P89 | O |
| Lₐ₃₂₅₁ | P10 | H | H | P11 | H | H | H | F | P89 | O |
| Lₐ₃₂₅₂ | P10 | H | H | P12 | H | H | H | F | P89 | O |
| Lₐ₃₂₅₃ | P10 | H | H | P15 | H | H | H | F | P89 | O |
| Lₐ₃₂₅₄ | P10 | H | H | P17 | H | H | H | F | P89 | O |
| Lₐ₃₂₅₅ | P10 | H | F | H | H | H | H | F | P89 | O |
| Lₐ₃₂₅₆ | P10 | H | H | F | H | H | H | F | P89 | O |
| Lₐ₃₂₅₇ | P10 | H | F | P1 | H | H | H | F | P89 | O |
| Lₐ₃₂₅₈ | P10 | H | F | P2 | H | H | H | F | P89 | O |
| Lₐ₃₂₅₉ | P10 | H | P1 | F | H | H | H | F | P89 | O |
| Lₐ₃₂₆₀ | P10 | H | P2 | F | H | H | H | F | P89 | O |
| Lₐ₃₂₆₁ | P10 | H | P1 | P1 | H | H | H | F | P89 | O |
| Lₐ₃₂₆₂ | P10 | H | P2 | P2 | H | H | H | F | P89 | O |
| Lₐ₃₂₆₃ | P1 | H | H | H | H | H | H | F | H | O |
| Lₐ₃₂₆₄ | P2 | H | H | H | H | H | H | F | H | O |
| Lₐ₃₂₆₅ | P3 | H | H | H | H | H | H | F | H | O |
| Lₐ₃₂₆₆ | P4 | H | H | H | H | H | H | F | H | O |
| Lₐ₃₂₆₇ | P5 | H | H | H | H | H | H | F | H | O |
| Lₐ₃₂₆₈ | P7 | H | H | H | H | H | H | F | H | O |
| Lₐ₃₂₆₉ | P8 | H | H | H | H | H | H | F | H | O |
| Lₐ₃₂₇₀ | P9 | H | H | H | H | H | H | F | H | O |
| Lₐ₃₂₇₁ | P12 | H | H | H | H | H | H | F | H | O |
| Lₐ₃₂₇₂ | P13 | H | H | H | H | H | H | F | H | O |
| Lₐ₃₂₇₃ | P14 | H | H | H | H | H | H | F | H | O |
| Lₐ₃₂₇₄ | P15 | H | H | H | H | H | H | F | H | O |
| Lₐ₃₂₇₅ | P16 | H | H | H | H | H | H | F | H | O |
| Lₐ₃₂₇₆ | P17 | H | H | H | H | H | H | F | H | O |
| Lₐ₃₂₇₇ | P18 | H | H | H | H | H | H | F | H | O |
| Lₐ₃₂₇₈ | P19 | H | H | H | H | H | H | F | H | O |
| Lₐ₃₂₇₉ | P20 | H | H | H | H | H | H | F | H | O |
| Lₐ₃₂₈₀ | P25 | H | H | H | H | H | H | F | H | O |
| Lₐ₃₂₈₁ | P27 | H | H | H | H | H | H | F | H | O |
| Lₐ₃₂₈₂ | P29 | H | H | H | H | H | H | F | H | O |
| Lₐ₃₂₈₃ | P31 | H | H | H | H | H | H | F | H | O |
| Lₐ₃₂₈₄ | P33 | H | H | H | H | H | H | F | H | O |
| Lₐ₃₂₈₅ | P34 | H | H | H | H | H | H | F | H | O |
| Lₐ₃₂₈₆ | P1 | H | H | H | H | H | H | F | D | O |
| Lₐ₃₂₈₇ | P2 | H | H | H | H | H | H | F | D | O |
| Lₐ₃₂₈₈ | P3 | H | H | H | H | H | H | F | D | O |
| Lₐ₃₂₈₉ | P4 | H | H | H | H | H | H | F | D | O |
| Lₐ₃₂₉₀ | P5 | H | H | H | H | H | H | F | D | O |
| Lₐ₃₂₉₁ | P7 | H | H | H | H | H | H | F | D | O |
| Lₐ₃₂₉₂ | P8 | H | H | H | H | H | H | F | D | O |
| Lₐ₃₂₉₃ | P9 | H | H | H | H | H | H | F | D | O |
| Lₐ₃₂₉₄ | P12 | H | H | H | H | H | H | F | D | O |
| Lₐ₃₂₉₅ | P13 | H | H | H | H | H | H | F | D | O |
| Lₐ₃₂₉₆ | P14 | H | H | H | H | H | H | F | D | O |
| Lₐ₃₂₉₇ | P15 | H | H | H | H | H | H | F | D | O |
| Lₐ₃₂₉₈ | P16 | H | H | H | H | H | H | F | D | O |
| Lₐ₃₂₉₉ | P17 | H | H | H | H | H | H | F | D | O |
| Lₐ₃₃₀₀ | P18 | H | H | H | H | H | H | F | D | O |
| Lₐ₃₃₀₁ | P19 | H | H | H | H | H | H | F | D | O |
| Lₐ₃₃₀₂ | P20 | H | H | H | H | H | H | F | D | O |
| Lₐ₃₃₀₃ | P25 | H | H | H | H | H | H | F | D | O |
| Lₐ₃₃₀₄ | P27 | H | H | H | H | H | H | F | D | O |
| Lₐ₃₃₀₅ | P29 | H | H | H | H | H | H | F | D | O |
| Lₐ₃₃₀₆ | P31 | H | H | H | H | H | H | F | D | O |
| Lₐ₃₃₀₇ | P33 | H | H | H | H | H | H | F | D | O |
| Lₐ₃₃₀₈ | P34 | H | H | H | H | H | H | F | D | O |
| Lₐ₃₃₀₉ | P1 | H | P4 | H | H | H | H | F | D | O |
| Lₐ₃₃₁₀ | P2 | H | P4 | H | H | H | H | F | D | O |
| Lₐ₃₃₁₁ | P3 | H | P4 | H | H | H | H | F | D | O |
| Lₐ₃₃₁₂ | P4 | H | P4 | H | H | H | H | F | D | O |
| Lₐ₃₃₁₃ | P5 | H | P4 | H | H | H | H | F | D | O |
| Lₐ₃₃₁₄ | P7 | H | P4 | H | H | H | H | F | D | O |
| Lₐ₃₃₁₅ | P8 | H | P4 | H | H | H | H | F | D | O |
| Lₐ₃₃₁₆ | P9 | H | P4 | H | H | H | H | F | D | O |
| Lₐ₃₃₁₇ | P12 | H | P4 | H | H | H | H | F | D | O |
| Lₐ₃₃₁₈ | P13 | H | P4 | H | H | H | H | F | D | O |
| Lₐ₃₃₁₉ | P14 | H | P4 | H | H | H | H | F | D | O |
| Lₐ₃₃₂₀ | P15 | H | P4 | H | H | H | H | F | D | O |
| Lₐ₃₃₂₁ | P16 | H | P4 | H | H | H | H | F | D | O |
| Lₐ₃₃₂₂ | P17 | H | P4 | H | H | H | H | F | D | O |
| Lₐ₃₃₂₃ | P18 | H | P4 | H | H | H | H | F | D | O |
| Lₐ₃₃₂₄ | P19 | H | P4 | H | H | H | H | F | D | O |
| Lₐ₃₃₂₅ | P20 | H | P4 | H | H | H | H | F | D | O |
| Lₐ₃₃₂₆ | P25 | H | P4 | H | H | H | H | F | H | O |
| Lₐ₃₃₂₇ | P27 | H | P4 | H | H | H | H | F | D | O |
| Lₐ₃₃₂₈ | P29 | H | P4 | H | H | H | H | F | D | O |
| Lₐ₃₃₂₉ | P31 | H | P4 | H | H | H | H | F | D | O |
| Lₐ₃₃₃₀ | P33 | H | P4 | H | H | H | H | F | D | O |
| Lₐ₃₃₃₁ | P34 | H | P4 | H | H | H | H | F | D | O |
| Lₐ₃₃₃₂ | P1 | H | H | P4 | H | H | H | F | D | O |
| Lₐ₃₃₃₃ | P2 | H | H | P4 | H | H | H | F | D | O |
| Lₐ₃₃₃₄ | P3 | H | H | P4 | H | H | H | F | D | O |
| Lₐ₃₃₃₅ | P4 | H | H | P4 | H | H | H | F | D | O |
| Lₐ₃₃₃₆ | P5 | H | H | P4 | H | H | H | F | D | O |
| Lₐ₃₃₃₇ | P7 | H | H | P4 | H | H | H | F | D | O |
| Lₐ₃₃₃₈ | P8 | H | H | P4 | H | H | H | F | D | O |
| Lₐ₃₃₃₉ | P9 | H | H | P4 | H | H | H | F | D | O |
| Lₐ₃₃₄₀ | P12 | H | H | P4 | H | H | H | F | D | O |
| Lₐ₃₃₄₁ | P13 | H | H | P4 | H | H | H | F | D | O |
| Lₐ₃₃₄₂ | P14 | H | H | P4 | H | H | H | F | D | O |
| Lₐ₃₃₄₃ | P15 | H | H | P4 | H | H | H | F | D | O |
| Lₐ₃₃₄₄ | P16 | H | H | P4 | H | H | H | F | D | O |
| Lₐ₃₃₄₅ | P17 | H | H | P4 | H | H | H | F | H | O |
| Lₐ₃₃₄₆ | P18 | H | H | P4 | H | H | H | F | D | O |
| Lₐ₃₃₄₇ | P19 | H | H | P4 | H | H | H | F | D | O |
| Lₐ₃₃₄₈ | P20 | H | H | P4 | H | H | H | F | D | O |
| Lₐ₃₃₄₉ | P25 | H | H | P4 | H | H | H | F | D | O |
| Lₐ₃₃₅₀ | P27 | H | H | P4 | H | H | H | F | D | O |
| Lₐ₃₃₅₁ | P29 | H | H | P4 | H | H | H | F | D | O |
| Lₐ₃₃₅₂ | P31 | H | H | P4 | H | H | H | F | D | O |
| Lₐ₃₃₅₃ | P33 | H | H | P4 | H | H | H | F | D | O |
| Lₐ₃₃₅₄ | P34 | H | H | P4 | H | H | H | F | D | O |
| Lₐ₃₃₅₅ | P1 | H | P6 | H | H | H | H | F | D | O |
| Lₐ₃₃₅₆ | P2 | H | P6 | H | H | H | H | F | D | O |
| Lₐ₃₃₅₇ | P3 | H | P6 | H | H | H | H | F | D | O |
| Lₐ₃₃₅₈ | P4 | H | P6 | H | H | H | H | F | D | O |
| Lₐ₃₃₅₉ | P5 | H | P6 | H | H | H | H | F | D | O |
| Lₐ₃₃₆₀ | P7 | H | P6 | H | H | H | H | F | H | O |
| Lₐ₃₃₆₁ | P8 | H | P6 | H | H | H | H | F | D | O |
| Lₐ₃₃₆₂ | P9 | H | P6 | H | H | H | H | F | D | O |
| Lₐ₃₃₆₃ | P12 | H | P6 | H | H | H | H | F | D | O |
| Lₐ₃₃₆₄ | P13 | H | P6 | H | H | H | H | F | D | O |
| Lₐ₃₃₆₅ | P14 | H | P6 | H | H | H | H | F | D | O |
| Lₐ₃₃₆₆ | P15 | H | P6 | H | H | H | H | F | D | O |
| Lₐ₃₃₆₇ | P16 | H | P6 | H | H | H | H | F | D | O |
| Lₐ₃₃₆₈ | P17 | H | P6 | H | H | H | H | F | D | O |
| Lₐ₃₃₆₉ | P18 | H | P6 | H | H | H | H | F | D | O |
| Lₐ₃₃₇₀ | P19 | H | P6 | H | H | H | H | F | D | O |
| Lₐ₃₃₇₁ | P20 | H | P6 | H | H | H | H | F | D | O |
| Lₐ₃₃₇₂ | P25 | H | P6 | H | H | H | H | F | D | O |
| Lₐ₃₃₇₃ | P27 | H | P6 | H | H | H | H | F | D | O |
| Lₐ₃₃₇₄ | P29 | H | P6 | H | H | H | H | F | D | O |
| Lₐ₃₃₇₅ | P31 | H | P6 | H | H | H | H | F | D | O |
| Lₐ₃₃₇₆ | P33 | H | P6 | H | H | H | H | F | D | O |
| Lₐ₃₃₇₇ | P34 | H | P6 | H | H | H | H | F | D | O |
| Lₐ₃₃₇₈ | P1 | H | H | P6 | H | H | H | F | H | O |
| Lₐ₃₃₇₉ | P2 | H | H | P6 | H | H | H | F | D | O |
| Lₐ₃₃₈₀ | P3 | H | H | P6 | H | H | H | F | D | O |
| Lₐ₃₃₈₁ | P4 | H | H | P6 | H | H | H | F | D | O |
| Lₐ₃₃₈₂ | P5 | H | H | P6 | H | H | H | F | H | O |
| Lₐ₃₃₈₃ | P7 | H | H | P6 | H | H | H | F | D | O |
| Lₐ₃₃₈₄ | P8 | H | H | P6 | H | H | H | F | D | O |
| Lₐ₃₃₈₅ | P9 | H | H | P6 | H | H | H | F | D | O |
| Lₐ₃₃₈₆ | P12 | H | H | P6 | H | H | H | F | D | O |
| Lₐ₃₃₈₇ | P13 | H | H | P6 | H | H | H | F | D | O |
| Lₐ₃₃₈₈ | P14 | H | H | P6 | H | H | H | F | D | O |
| Lₐ₃₃₈₉ | P15 | H | H | P6 | H | H | H | F | D | O |
| Lₐ₃₃₉₀ | P16 | H | H | P6 | H | H | H | F | D | O |
| Lₐ₃₃₉₁ | P17 | H | H | P6 | H | H | H | F | D | O |
| Lₐ₃₃₉₂ | P18 | H | H | P6 | H | H | H | F | D | O |
| Lₐ₃₃₉₃ | P19 | H | H | P6 | H | H | H | F | D | O |
| Lₐ₃₃₉₄ | P20 | H | H | P6 | H | H | H | F | D | O |
| Lₐ₃₃₉₅ | P25 | H | H | P6 | H | H | H | F | D | O |
| Lₐ₃₃₉₆ | P27 | H | H | P6 | H | H | H | F | D | O |
| Lₐ₃₃₉₇ | P29 | H | H | P6 | H | H | H | F | D | O |
| Lₐ₃₃₉₈ | P31 | H | H | P6 | H | H | H | F | D | O |
| Lₐ₃₃₉₉ | P33 | H | H | P6 | H | H | H | F | D | O |
| Lₐ₃₄₀₀ | P34 | H | H | P6 | H | H | H | F | D | O |
| Lₐ₃₄₀₁ | P1 | H | P10 | H | H | H | H | F | D | O |
| Lₐ₃₄₀₂ | P2 | H | P11 | H | H | H | H | F | D | O |
| Lₐ₃₄₀₃ | P3 | H | P10 | H | H | H | H | F | D | O |
| Lₐ₃₄₀₄ | P4 | H | P11 | H | H | H | H | F | D | O |
| Lₐ₃₄₀₅ | P5 | H | P10 | H | H | H | H | F | D | O |
| Lₐ₃₄₀₆ | P7 | H | P11 | H | H | H | H | F | D | O |
| Lₐ₃₄₀₇ | P8 | H | P10 | H | H | H | H | F | D | O |
| Lₐ₃₄₀₈ | P9 | H | P11 | H | H | H | H | F | D | O |
| Lₐ₃₄₀₉ | P12 | H | P10 | H | H | H | H | F | H | O |
| Lₐ₃₄₁₀ | P13 | H | P11 | H | H | H | H | F | H | O |
| Lₐ₃₄₁₁ | P14 | H | P10 | H | H | H | H | F | D | O |
| Lₐ₃₄₁₂ | P15 | H | P11 | H | H | H | H | F | D | O |
| Lₐ₃₄₁₃ | P16 | H | P10 | H | H | H | H | F | D | O |
| Lₐ₃₄₁₄ | P17 | H | P11 | H | H | H | H | F | D | O |
| Lₐ₃₄₁₅ | P18 | H | P10 | H | H | H | H | F | H | O |
| Lₐ₃₄₁₆ | P19 | H | P11 | H | H | H | H | F | D | O |
| Lₐ₃₄₁₇ | P20 | H | P10 | H | H | H | H | F | D | O |
| Lₐ₃₄₁₈ | P25 | H | P11 | H | H | H | H | F | D | O |
| Lₐ₃₄₁₉ | P27 | H | P10 | H | H | H | H | F | H | O |
| Lₐ₃₄₂₀ | P29 | H | P11 | H | H | H | H | F | D | O |
| Lₐ₃₄₂₁ | P31 | H | P10 | H | H | H | H | F | D | O |
| Lₐ₃₄₂₂ | P33 | H | P11 | H | H | H | H | F | D | O |
| Lₐ₃₄₂₃ | P34 | H | P10 | H | H | H | H | F | D | O |
| Lₐ₃₄₂₄ | P1 | H | H | P10 | H | H | H | F | D | O |
| Lₐ₃₄₂₅ | P2 | H | H | P11 | H | H | H | F | D | O |
| Lₐ₃₄₂₆ | P3 | H | H | P10 | H | H | H | F | D | O |
| Lₐ₃₄₂₇ | P4 | H | H | P11 | H | H | H | F | D | O |
| Lₐ₃₄₂₈ | P5 | H | H | P10 | H | H | H | F | D | O |
| Lₐ₃₄₂₉ | P7 | H | H | P11 | H | H | H | F | D | O |
| Lₐ₃₄₃₀ | P8 | H | H | P10 | H | H | H | F | D | O |
| Lₐ₃₄₃₁ | P9 | H | H | P11 | H | H | H | F | D | O |
| Lₐ₃₄₃₂ | P12 | H | H | P10 | H | H | H | F | D | O |
| Lₐ₃₄₃₃ | P13 | H | H | P11 | H | H | H | F | D | O |
| Lₐ₃₄₃₄ | P14 | H | H | P10 | H | H | H | F | D | O |
| Lₐ₃₄₃₅ | P15 | H | H | P11 | H | H | H | F | D | O |
| Lₐ₃₄₃₆ | P16 | H | H | P10 | H | H | H | F | D | O |
| Lₐ₃₄₃₇ | P17 | H | H | P11 | H | H | H | F | D | O |
| Lₐ₃₄₃₈ | P18 | H | H | P10 | H | H | H | F | D | O |
| Lₐ₃₄₃₉ | P19 | H | H | P11 | H | H | H | F | D | O |
| Lₐ₃₄₄₀ | P20 | H | H | P10 | H | H | H | F | D | O |
| Lₐ₃₄₄₁ | P25 | H | H | P11 | H | H | H | F | D | O |
| Lₐ₃₄₄₂ | P27 | H | H | P10 | H | H | H | F | D | O |
| Lₐ₃₄₄₃ | P29 | H | H | P11 | H | H | H | F | D | O |
| Lₐ₃₄₄₄ | P31 | H | H | P10 | H | H | H | F | D | O |
| Lₐ₃₄₄₅ | P33 | H | H | P11 | H | H | H | F | D | O |
| Lₐ₃₄₄₆ | P34 | H | H | P10 | H | H | H | F | D | O |
| Lₐ₃₄₄₇ | P1 | H | P1 | P1 | H | H | H | F | D | O |
| Lₐ₃₄₄₈ | P2 | H | P1 | P1 | H | H | H | F | D | O |
| Lₐ₃₄₄₉ | P3 | H | P1 | P1 | H | H | H | F | D | O |
| Lₐ₃₄₅₀ | P4 | H | P1 | P1 | H | H | H | F | D | O |
| Lₐ₃₄₅₁ | P5 | H | P1 | P1 | H | H | H | F | D | O |
| Lₐ₃₄₅₂ | P7 | H | P1 | P1 | H | H | H | F | D | O |
| Lₐ₃₄₅₃ | P8 | H | P1 | P1 | H | H | H | F | D | O |
| Lₐ₃₄₅₄ | P9 | H | P1 | P1 | H | H | H | F | D | O |
| Lₐ₃₄₅₅ | P12 | H | P1 | P1 | H | H | H | F | D | O |
| Lₐ₃₄₅₆ | P13 | H | P1 | P1 | H | H | H | F | D | O |
| Lₐ₃₄₅₇ | P14 | H | P1 | P1 | H | H | H | F | D | O |
| Lₐ₃₄₅₈ | P15 | H | P1 | P1 | H | H | H | F | D | O |
| Lₐ₃₄₅₉ | P16 | H | P1 | P1 | H | H | H | F | D | O |
| Lₐ₃₄₆₀ | P17 | H | P1 | P1 | H | H | H | F | D | O |
| Lₐ₃₄₆₁ | P18 | H | P1 | P1 | H | H | H | F | D | O |
| Lₐ₃₄₆₂ | P19 | H | P1 | P1 | H | H | H | F | D | O |
| Lₐ₃₄₆₃ | P20 | H | P1 | P1 | H | H | H | F | D | O |
| Lₐ₃₄₆₄ | P25 | H | P1 | P1 | H | H | H | F | D | O |
| Lₐ₃₄₆₅ | P27 | H | P1 | P1 | H | H | H | F | D | O |
| Lₐ₃₄₆₆ | P29 | H | P1 | P1 | H | H | H | F | D | O |
| Lₐ₃₄₆₇ | P31 | H | P1 | P1 | H | H | H | F | D | O |
| Lₐ₃₄₆₈ | P33 | H | P1 | P1 | H | H | H | F | D | O |
| Lₐ₃₄₆₉ | P34 | H | P1 | P1 | H | H | H | F | D | O |
| Lₐ₃₄₇₀ | P1 | H | P2 | P2 | H | H | H | F | D | O |
| Lₐ₃₄₇₁ | P2 | H | P2 | P2 | H | H | H | F | D | O |
| Lₐ₃₄₇₂ | P3 | H | P2 | P2 | H | H | H | F | D | O |
| Lₐ₃₄₇₃ | P4 | H | P2 | P2 | H | H | H | F | D | O |
| Lₐ₃₄₇₄ | P5 | H | P2 | P2 | H | H | H | F | D | O |
| Lₐ₃₄₇₅ | P7 | H | P2 | P2 | H | H | H | F | D | O |
| Lₐ₃₄₇₆ | P8 | H | P2 | P2 | H | H | H | F | D | O |
| Lₐ₃₄₇₇ | P9 | H | P2 | P2 | H | H | H | F | D | O |
| Lₐ₃₄₇₈ | P12 | H | P2 | P2 | H | H | H | F | D | O |
| Lₐ₃₄₇₉ | P13 | H | P2 | P2 | H | H | H | F | D | O |
| Lₐ₃₄₈₀ | P14 | H | P2 | P2 | H | H | H | F | D | O |
| Lₐ₃₄₈₁ | P15 | H | P2 | P2 | H | H | H | F | D | O |
| Lₐ₃₄₈₂ | P16 | H | P2 | P2 | H | H | H | F | D | O |
| Lₐ₃₄₈₃ | P17 | H | P2 | P2 | H | H | H | F | D | O |
| Lₐ₃₄₈₄ | P18 | H | P2 | P2 | H | H | H | F | D | O |
| Lₐ₃₄₈₅ | P19 | H | P2 | P2 | H | H | H | F | D | O |
| Lₐ₃₄₈₆ | P20 | H | P2 | P2 | H | H | H | F | D | O |
| Lₐ₃₄₈₇ | P25 | H | P2 | P2 | H | H | H | F | D | O |
| Lₐ₃₄₈₈ | P27 | H | P2 | P2 | H | H | H | F | D | O |
| Lₐ₃₄₈₉ | P29 | H | P2 | P2 | H | H | H | F | D | O |
| Lₐ₃₄₉₀ | P31 | H | P2 | P2 | H | H | H | F | D | O |
| Lₐ₃₄₉₁ | P33 | H | P2 | P2 | H | H | H | F | D | O |
| Lₐ₃₄₉₂ | P34 | H | P2 | P2 | H | H | H | F | D | O |
| Lₐ₃₄₉₃ | P6 | H | H | H | H | H | H | H | F | O |
| Lₐ₃₄₉₄ | P6 | H | H | H | H | H | F | H | H | O |
| Lₐ₃₄₉₅ | P6 | H | H | H | H | F | H | H | H | O |
| Lₐ₃₄₉₆ | P6 | H | P6 | H | H | H | H | H | F | O |
| Lₐ₃₄₉₇ | P6 | H | P6 | H | H | H | F | H | H | O |
| Lₐ₃₄₉₈ | P6 | H | P6 | H | H | F | H | H | H | O |
| Lₐ₃₄₉₉ | P6 | H | H | P6 | H | H | H | H | F | O |
| Lₐ₃₅₀₀ | P6 | H | H | P6 | H | H | F | H | H | O |
| Lₐ₃₅₀₁ | P6 | H | H | P6 | H | F | H | H | H | O |
| Lₐ₃₅₀₂ | P6 | H | H | H | H | H | H | P24 | F | O |
| Lₐ₃₅₀₃ | P6 | H | H | H | H | H | H | D | F | O |
| Lₐ₃₅₀₄ | P6 | H | H | H | H | H | H | P56 | F | O |
| Lₐ₃₅₀₅ | P6 | H | H | H | H | H | H | P24 | F | O |
| Lₐ₃₅₀₆ | P6 | H | H | H | H | H | H | P74 | F | O |
| Lₐ₃₅₀₇ | P6 | H | H | H | H | H | H | F | H | S |
| Lₐ₃₅₀₈ | P6 | H | H | P2 | H | H | H | F | H | S |
| Lₐ₃₅₀₉ | P6 | H | H | P4 | H | H | H | F | H | S |
| Lₐ₃₅₁₀ | P6 | H | H | H | H | H | H | H | F | S |
| Lₐ₃₅₁₁ | P6 | H | P2 | H | H | H | H | H | F | S |
| Lₐ₃₅₁₂ | P6 | H | H | P2 | H | H | H | H | F | S |
| Lₐ₃₅₁₃ | P6 | H | H | P11 | H | H | H | F | H | S |
| Lₐ₃₅₁₄ | P6 | H | H | P6 | H | H | H | F | H | S |
| Lₐ₃₅₁₅ | P6 | H | P11 | H | H | H | H | F | H | S |
| Lₐ₃₅₁₆ | P6 | H | P6 | H | H | H | H | F | H | S |
| Lₐ₃₅₁₇ | P11 | H | H | H | H | H | H | F | H | S |
| Lₐ₃₅₁₈ | P11 | H | P1 | P1 | H | H | H | F | H | S |
| Lₐ₃₅₁₉ | P11 | H | P2 | P2 | H | H | H | F | H | S |
| Lₐ₃₅₂₀ | P11 | H | H | H | H | H | H | H | F | S |
| Lₐ₃₅₂₁ | P11 | H | P1 | P1 | H | H | H | H | F | S |
| Lₐ₃₅₂₂ | P11 | H | P2 | P2 | H | H | H | H | F | S |
| Lₐ₃₅₂₃ | P11 | H | H | P11 | H | H | H | F | H | S |
| Lₐ₃₅₂₄ | P11 | H | H | HP6 | H | H | H | F | H | S |
| Lₐ₃₅₂₅ | P11 | H | P11 | H | H | H | H | F | H | S |
| Lₐ₃₅₂₆ | P11 | H | P6 | H | H | H | H | F | H | S |

wherein optionally, hydrogens in ligands Lₐ₁ to Lₐ₃₅₂₆ can be partially or fully substituted with deuterium;
P1 to P90 are selected from the group consisting of the following structures: 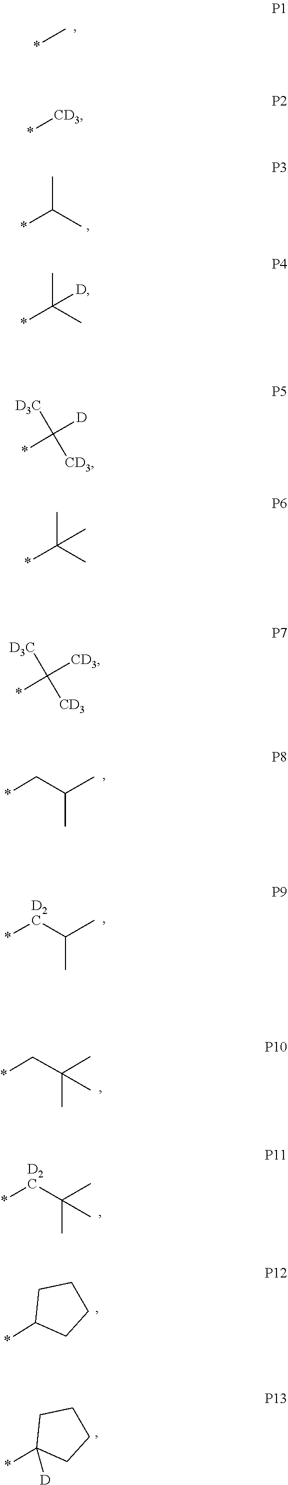 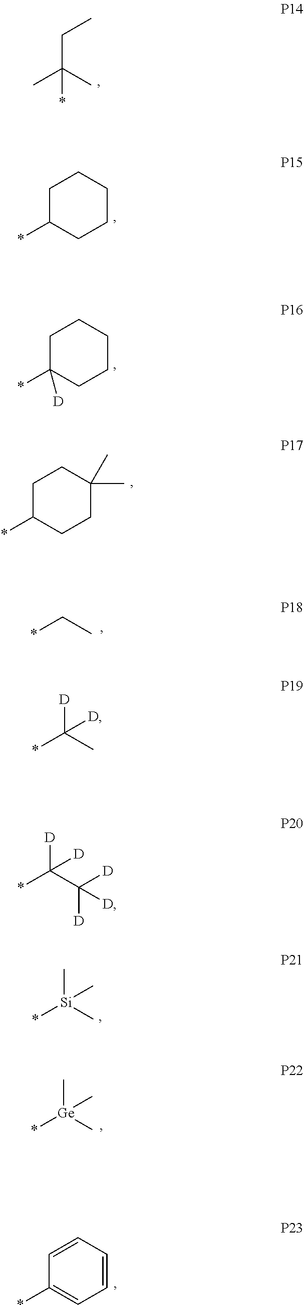 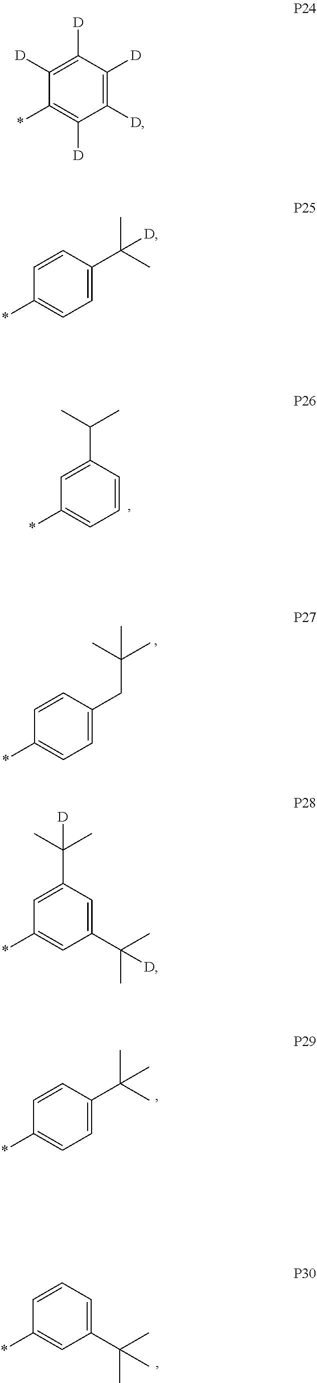 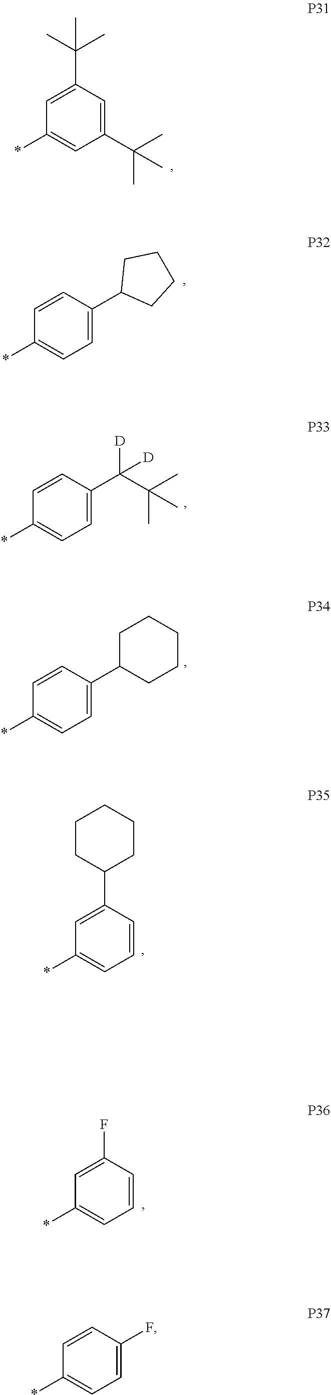 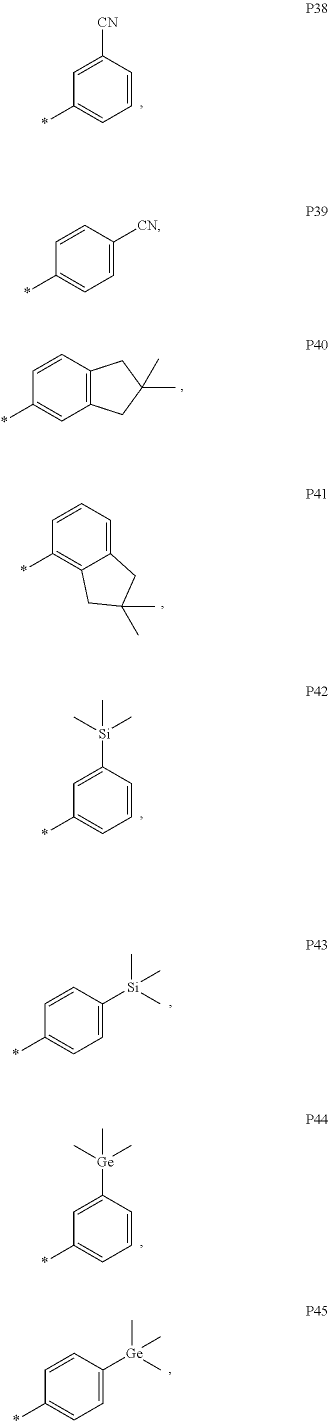 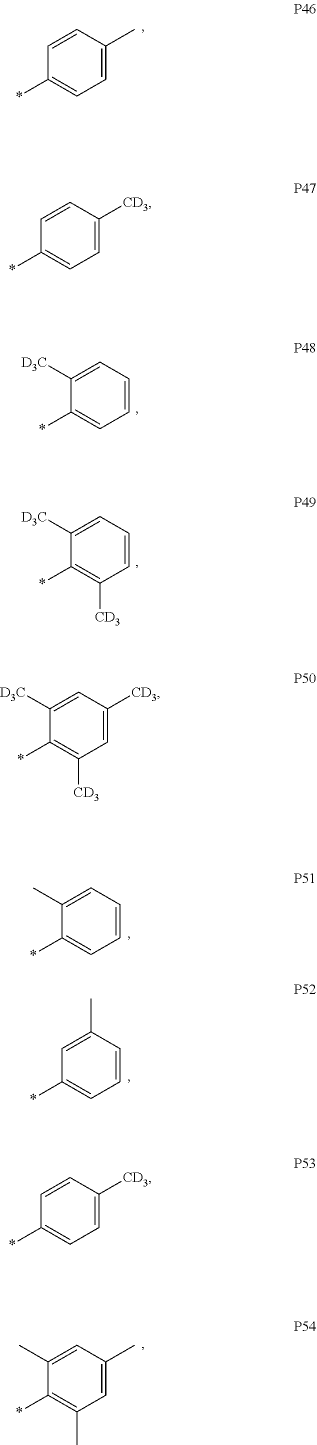 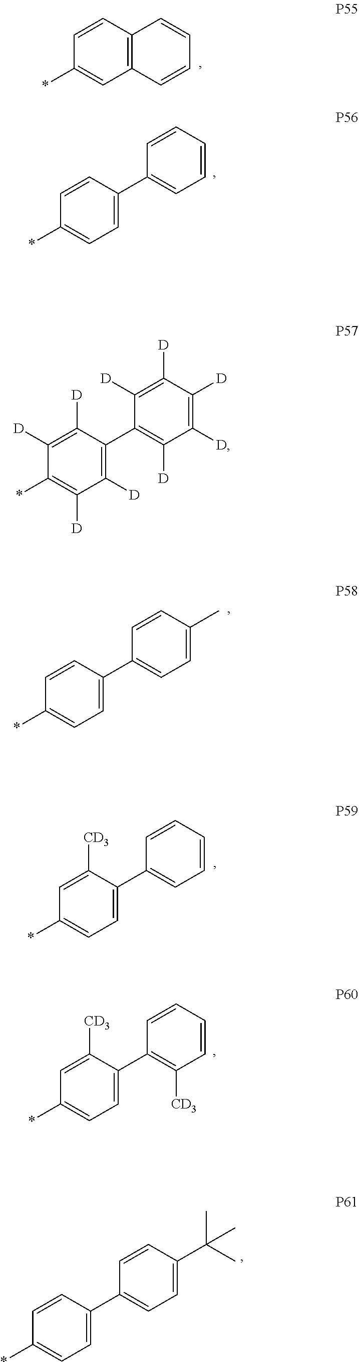 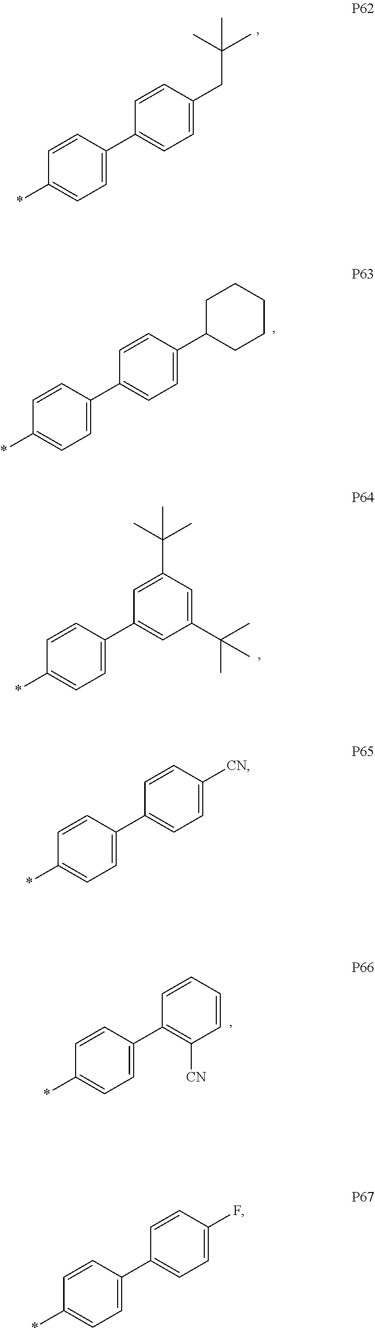 [SMILES: *c1ccc(-c2ccc(CC(C)(C)C)cc2)cc1 ; *c1ccc(-c2ccc(C3CCCCC3)cc2)cc1 ; *c1ccc(-c2cc(C(C)(C)C)cc(C(C)(C)C)c2)cc1 ; *c1ccc(-c2ccc(C#N)cc2)cc1 ; *c1ccc(-c2ccccc2C#N)cc1 ; *c1ccc(-c2ccc(F)cc2)cc1] 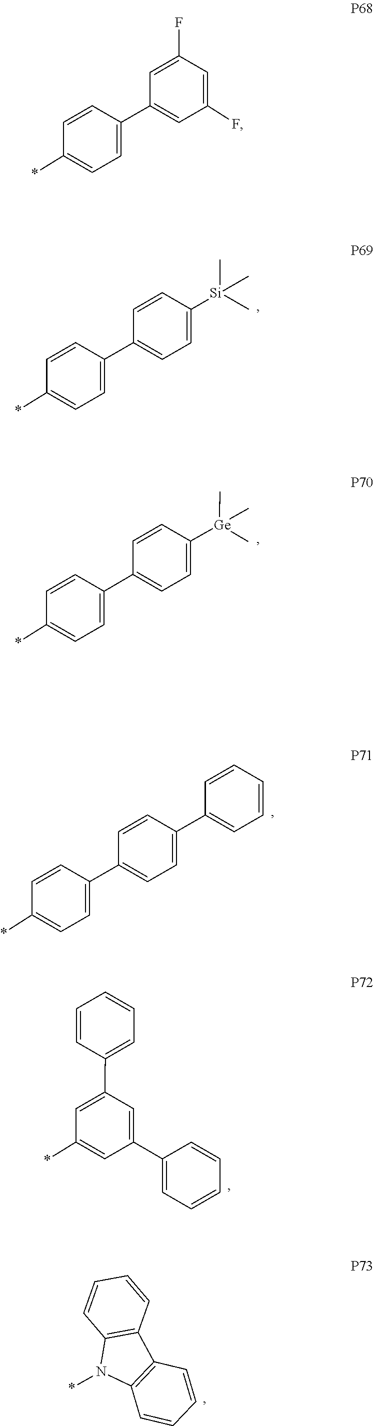 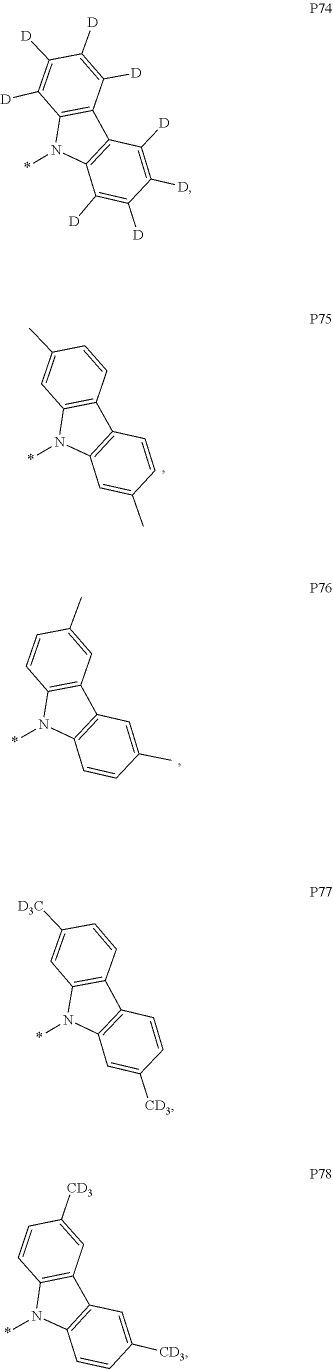 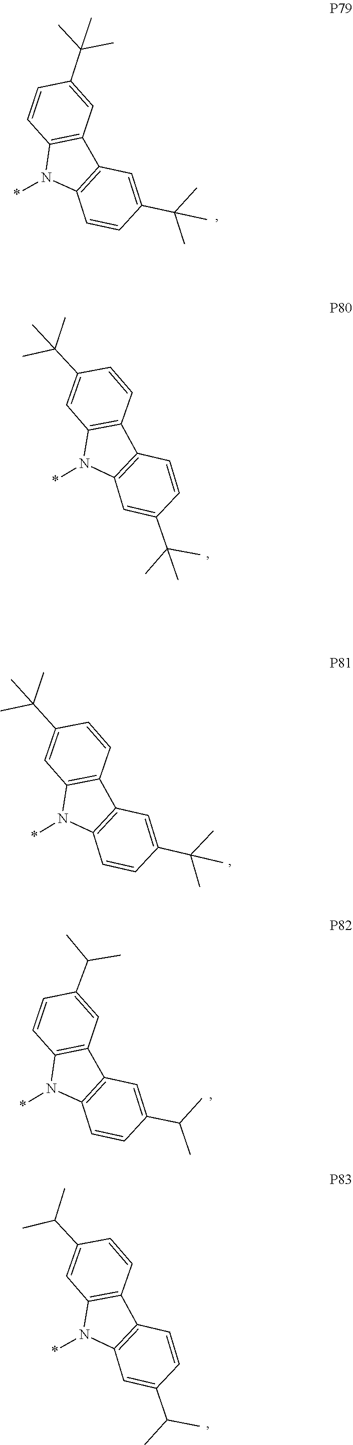 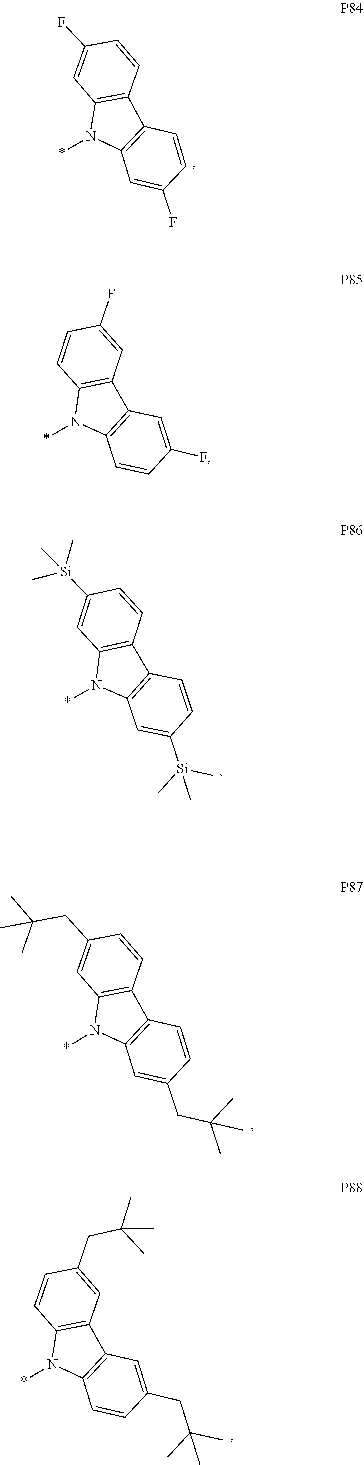 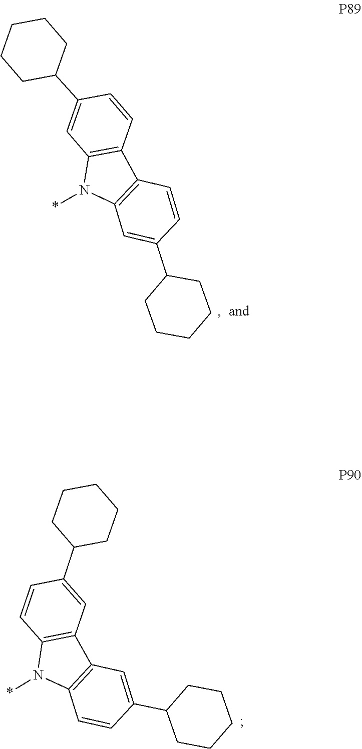 [SMILES: *n1c2cc(C3CCCCC3)ccc2c2ccc(C3CCCCC3)cc21 ; *n1c2ccc(C3CCCCC3)cc2c2cc(C3CCCCC3)ccc21]
wherein “*” in P1 to P90 represents the position of attachment to the ligand Lₐ.

16. The metal complex of claim 15, wherein L_{b} is, at each occurrence identically or differently, selected from the group consisting of L_{b1} to L_{b1566}:
wherein L_{b1} to L_{b1566} each have the following structure: 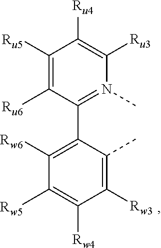
wherein Rᵤ₃ to Rᵤ₆ and R_{w3} to R_{w6} are selected from the atoms or groups in the following table:

| L_{b} | Rᵤ₃ | Rᵤ₄ | Rᵤ₅ | Rᵤ₆ | R_{w3} | R_{w4} | R_{w5} | R_{w6} |
|---|---|---|---|---|---|---|---|---|
| L_{b1} | H | P23 | H | H | H | H | H | H |
| L_{b2} | H | P23 | H | H | D | D | D | D |
| L_{b3} | H | P23 | H | H | H | P1 | H | H |
| L_{b4} | H | P23 | H | H | H | P2 | H | H |
| L_{b5} | H | P23 | H | H | H | P3 | H | H |
| L_{b6} | H | P23 | H | H | H | P4 | H | H |
| L_{b7} | H | P23 | H | H | H | P5 | H | H |
| L_{b8} | H | P23 | H | H | H | P6 | H | H |
| L_{b9} | H | P23 | H | H | H | P7 | H | H |
| L_{b10} | H | P23 | H | H | H | P8 | H | H |
| L_{b11} | H | P23 | H | H | H | P9 | H | H |
| L_{b12} | H | P23 | H | H | H | P10 | H | H |
| L_{b13} | H | P23 | H | H | H | P11 | H | H |
| L_{b14} | H | P23 | H | H | H | P12 | H | H |
| L_{b15} | H | P23 | H | H | H | P13 | H | H |
| L_{b16} | H | P23 | H | H | H | P14 | H | H |
| L_{b17} | H | P23 | H | H | H | P15 | H | H |
| L_{b18} | H | P23 | H | H | H | P16 | H | H |
| L_{b19} | H | P23 | H | H | H | P17 | H | H |
| L_{b20} | H | P23 | H | H | H | P18 | H | H |
| L_{b21} | H | P23 | H | H | H | P19 | H | H |
| L_{b22} | H | P23 | H | H | H | P20 | H | H |
| L_{b23} | H | P23 | H | H | H | P21 | H | H |
| L_{b24} | H | P23 | H | H | H | P22 | H | H |
| L_{b25} | H | P23 | H | H | H | P23 | H | H |
| L_{b26} | H | P23 | H | H | H | P24 | H | H |
| L_{b27} | H | P23 | H | H | H | P25 | H | H |
| L_{b28} | H | P23 | H | H | H | P26 | H | H |
| L_{b29} | H | P23 | H | H | H | P27 | H | H |
| L_{b30} | H | P23 | H | H | H | P28 | H | H |
| L_{b31} | H | P23 | H | H | H | P29 | H | H |
| L_{b32} | H | P23 | H | H | H | P30 | H | H |
| L_{b33} | H | P23 | H | H | H | P31 | H | H |
| L_{b34} | H | P23 | H | H | H | P32 | H | H |
| L_{b35} | H | P23 | H | H | H | P33 | H | H |
| L_{b36} | H | P23 | H | H | H | P34 | H | H |
| L_{b37} | H | P23 | H | H | H | P35 | H | H |
| L_{b38} | H | P23 | H | H | H | P36 | H | H |
| L_{b39} | H | P23 | H | H | H | P37 | H | H |
| L_{b40} | H | P23 | H | H | H | P38 | H | H |
| L_{b41} | H | P23 | H | H | H | P39 | H | H |
| L_{b42} | H | P23 | H | H | H | P40 | H | H |
| L_{b43} | H | P23 | H | H | H | P41 | H | H |
| L_{b44} | H | P23 | H | H | H | P42 | H | H |
| L_{b45} | H | P23 | H | H | H | P43 | H | H |
| L_{b46} | H | P23 | H | H | H | P44 | H | H |
| L_{b47} | H | P23 | H | H | H | P45 | H | H |
| L_{b48} | H | P23 | H | H | H | P46 | H | H |
| L_{b49} | H | P23 | H | H | H | P47 | H | H |
| L_{b50} | H | P23 | H | H | H | P48 | H | H |
| L_{b51} | H | P23 | H | H | H | P49 | H | H |
| L_{b52} | H | P23 | H | H | H | P50 | H | H |
| L_{b53} | H | P23 | H | H | H | P51 | H | H |
| L_{b54} | H | P23 | H | H | H | P52 | H | H |
| L_{b55} | H | P23 | H | H | H | P53 | H | H |
| L_{b56} | H | P23 | H | H | H | P54 | H | H |
| L_{b57} | H | P23 | H | H | H | H | P1 | H |
| L_{b58} | H | P23 | H | H | H | H | P2 | H |
| L_{b59} | H | P23 | H | H | H | H | P3 | H |
| L_{b60} | H | P23 | H | H | H | H | P4 | H |
| L_{b61} | H | P23 | H | H | H | H | P5 | H |
| L_{b62} | H | P23 | H | H | H | H | P6 | H |
| L_{b63} | H | P23 | H | H | H | H | P7 | H |
| L_{b64} | H | P23 | H | H | H | H | P8 | H |
| L_{b65} | H | P23 | H | H | H | H | P9 | H |
| L_{b66} | H | P23 | H | H | H | H | P10 | H |
| L_{b67} | H | P23 | H | H | H | H | P11 | H |
| L_{b68} | H | P23 | H | H | H | H | P12 | H |
| L_{b69} | H | P23 | H | H | H | H | P13 | H |
| L_{b70} | H | P23 | H | H | H | H | P14 | H |
| L_{b71} | H | P23 | H | H | H | H | P15 | H |
| L_{b72} | H | P23 | H | H | H | H | P16 | H |
| L_{b73} | H | P23 | H | H | H | H | P17 | H |
| L_{b74} | H | P23 | H | H | H | H | P18 | H |
| L_{b75} | H | P23 | H | H | H | H | P19 | H |
| L₆₇₆ | H | P23 | H | H | H | H | P20 | H |
| L_{b77} | H | P23 | H | H | H | H | P21 | H |
| L_{b78} | H | P23 | H | H | H | H | P22 | H |
| L_{b79} | H | P23 | H | H | H | H | P23 | H |
| L_{b80} | H | P23 | H | H | H | H | P24 | H |
| L_{b81} | H | P23 | H | H | H | H | P25 | H |
| L_{b82} | H | P23 | H | H | H | H | P26 | H |
| L_{b83} | H | P23 | H | H | H | H | P27 | H |
| L_{b84} | H | P23 | H | H | H | H | P28 | H |
| L_{b85} | H | P23 | H | H | H | H | P29 | H |
| L_{b86} | H | P23 | H | H | H | H | P30 | H |
| L_{b87} | H | P23 | H | H | H | H | P31 | H |
| L_{b88} | H | P23 | H | H | H | H | P32 | H |
| L_{b89} | H | P23 | H | H | H | H | P33 | H |
| L_{b90} | H | P23 | H | H | H | H | P34 | H |
| L_{b91} | H | P23 | H | H | H | H | P35 | H |
| L_{b92} | H | P23 | H | H | H | H | P36 | H |
| L_{b93} | H | P23 | H | H | H | H | P37 | H |
| L_{b94} | H | P23 | H | H | H | H | P38 | H |
| L_{b95} | H | P23 | H | H | H | H | P39 | H |
| L_{b96} | H | P23 | H | H | H | H | P40 | H |
| L_{b97} | H | P23 | H | H | H | H | P41 | H |
| L_{b98} | H | P23 | H | H | H | H | P42 | H |
| L_{b99} | H | P23 | H | H | H | H | P43 | H |
| L_{b100} | H | P23 | H | H | H | H | P44 | H |
| L_{b101} | H | P23 | H | H | H | H | P45 | H |
| L_{b102} | H | P23 | H | H | H | H | P46 | H |
| L_{b103} | H | P23 | H | H | H | H | P47 | H |
| L_{b104} | H | P23 | H | H | H | H | P48 | H |
| L_{b105} | H | P23 | H | H | H | H | P49 | H |
| L_{b106} | H | P23 | H | H | H | H | P50 | H |
| L_{b107} | H | P23 | H | H | H | H | P51 | H |
| L_{b108} | H | P23 | H | H | H | H | P52 | H |
| L_{b109} | H | P23 | H | H | H | H | P53 | H |
| L_{b110} | H | P23 | H | H | H | H | P54 | H |
| L_{b111} | H | P23 | H | H | H | P1 | P1 | H |
| L_{b112} | H | P23 | H | H | H | P2 | P2 | H |
| L_{b113} | H | P23 | P1 | H | H | H | H | H |
| L_{b114} | H | P23 | P1 | D | D | D | D | D |
| L_{b115} | H | P23 | P1 | H | H | P1 | H | H |
| L_{b116} | H | P23 | P1 | H | H | P3 | H | H |
| L_{b117} | H | P23 | P1 | H | H | P6 | H | H |
| L_{b118} | H | P23 | P1 | H | H | P8 | H | H |
| L_{b119} | H | P23 | P1 | H | H | P10 | H | H |
| L_{b120} | H | P23 | P1 | H | H | P12 | H | H |
| L_{b121} | H | P23 | P1 | H | H | P14 | H | H |
| L_{b122} | H | P23 | P1 | H | H | P15 | H | H |
| L_{b123} | H | P23 | P1 | H | H | P17 | H | H |
| L_{b124} | H | P23 | P1 | H | H | P18 | H | H |
| L_{b125} | H | P23 | P1 | H | H | H | P1 | H |
| L_{b126} | H | P23 | P1 | H | H | H | P3 | H |
| L_{b127} | H | P23 | P1 | H | H | H | P6 | H |
| L_{b128} | H | P23 | P1 | H | H | H | P8 | H |
| L_{b129} | H | P23 | P1 | H | H | H | P10 | H |
| L_{b130} | H | P23 | P1 | H | H | H | P12 | H |
| L_{b131} | H | P23 | P1 | H | H | H | P14 | H |
| L_{b132} | H | P23 | P1 | H | H | H | P15 | H |
| L_{b133} | H | P23 | P1 | H | H | H | P17 | H |
| L_{b134} | H | P23 | P1 | H | H | H | P18 | H |
| L_{b135} | H | P23 | P1 | H | H | P1 | P1 | H |
| L_{b136} | H | P23 | P1 | H | H | P10 | P1 | H |
| L_{b137} | H | P23 | P1 | H | H | P8 | P1 | H |
| L_{b138} | H | P23 | P2 | H | H | H | H | H |
| L_{b139} | H | P23 | P2 | D | D | D | D | D |
| L_{b140} | H | P23 | P2 | H | H | P2 | H | H |
| L_{b141} | H | P23 | P2 | H | H | P4 | H | H |
| L_{b142} | H | P23 | P2 | H | H | P5 | H | H |
| L_{b143} | H | P23 | P2 | H | H | P7 | H | H |
| L_{b144} | H | P23 | P2 | H | H | P6 | H | H |
| L_{b145} | H | P23 | P2 | H | H | P11 | H | H |
| L_{b146} | H | P23 | P2 | H | H | P13 | H | H |
| L_{b147} | H | P23 | P2 | H | H | P16 | H | H |
| L_{b148} | H | P23 | P2 | H | H | P19 | H | H |
| L_{b149} | H | P23 | P2 | H | H | P20 | H | H |
| L_{b150} | H | P23 | P2 | H | H | H | P2 | H |
| L_{b151} | H | P23 | P2 | H | H | H | P4 | H |
| L_{b152} | H | P23 | P2 | H | H | H | P5 | H |
| L_{b153} | H | P23 | P2 | H | H | H | P7 | H |
| L_{b154} | H | P23 | P2 | H | H | H | P9 | H |
| L_{b155} | H | P23 | P2 | H | H | H | P11 | H |
| L_{b156} | H | P23 | P2 | H | H | H | P13 | H |
| L_{b157} | H | P23 | P2 | H | H | H | P16 | H |
| L_{b158} | H | P23 | P2 | H | H | H | P19 | H |
| L_{b159} | H | P23 | P2 | H | H | H | P20 | H |
| L_{b160} | H | P23 | P2 | H | H | P2 | P2 | H |
| L_{b161} | H | P23 | P2 | H | H | P9 | P2 | H |
| L_{b162} | H | P23 | P2 | H | H | P11 | P2 | H |
| L_{b163} | H | H | P23 | H | H | H | H | H |
| L_{b164} | H | H | P23 | H | D | D | D | D |
| L_{b165} | H | H | P23 | H | H | P1 | H | H |
| L_{b166} | H | H | P23 | H | H | P2 | H | H |
| L_{b167} | H | H | P23 | H | H | P3 | H | H |
| L_{b168} | H | H | P23 | H | H | P4 | H | H |
| L_{b169} | H | H | P23 | H | H | P5 | H | H |
| L_{b170} | H | H | P23 | H | H | P6 | H | H |
| L_{b171} | H | H | P23 | H | H | P7 | H | H |
| L_{b172} | H | H | P23 | H | H | P8 | H | H |
| L_{b173} | H | H | P23 | H | H | P9 | H | H |
| L_{b174} | H | H | P23 | H | H | P10 | H | H |
| L_{b175} | H | H | P23 | H | H | P11 | H | H |
| L_{b176} | H | H | P23 | H | H | P12 | H | H |
| L_{b177} | H | H | P23 | H | H | P13 | H | H |
| L_{b178} | H | H | P23 | H | H | P14 | H | H |
| L_{b179} | H | H | P23 | H | H | P15 | H | H |
| L_{b180} | H | H | P23 | H | H | P16 | H | H |
| L_{b181} | H | H | P23 | H | H | P17 | H | H |
| L_{b182} | H | H | P23 | H | H | P18 | H | H |
| L_{b183} | H | H | P23 | H | H | P19 | H | H |
| L_{b184} | H | H | P23 | H | H | P20 | H | H |
| L_{b185} | H | H | P23 | H | H | P21 | H | H |
| L_{b186} | H | H | P23 | H | H | P22 | H | H |
| L_{b187} | H | H | P23 | H | H | P23 | H | H |
| L_{b188} | H | H | P23 | H | H | P24 | H | H |
| L_{b189} | H | H | P23 | H | H | P25 | H | H |
| L_{b190} | H | H | P23 | H | H | P26 | H | H |
| L_{b191} | H | H | P23 | H | H | P27 | H | H |
| L_{b192} | H | H | P23 | H | H | P28 | H | H |
| L_{b193} | H | H | P23 | H | H | P29 | H | H |
| L_{b194} | H | H | P23 | H | H | P30 | H | H |
| L_{b195} | H | H | P23 | H | H | P31 | H | H |
| L_{b196} | H | H | P23 | H | H | P32 | H | H |
| L_{b197} | H | H | P23 | H | H | P33 | H | H |
| L_{b198} | H | H | P23 | H | H | P34 | H | H |
| L_{b199} | H | H | P23 | H | H | P35 | H | H |
| L_{b200} | H | H | P23 | H | H | P36 | H | H |
| L_{b201} | H | H | P23 | H | H | P37 | H | H |
| L_{b202} | H | H | P23 | H | H | P38 | H | H |
| L_{b203} | H | H | P23 | H | H | P39 | H | H |
| L_{b204} | H | H | P23 | H | H | P40 | H | H |
| L_{b205} | H | H | P23 | H | H | P41 | H | H |
| L_{b206} | H | H | P23 | H | H | P42 | H | H |
| L_{b207} | H | H | P23 | H | H | P43 | H | H |
| L_{b208} | H | H | P23 | H | H | P44 | H | H |
| L_{b209} | H | H | P23 | H | H | P45 | H | H |
| L_{b210} | H | H | P23 | H | H | P46 | H | H |
| L_{b211} | H | H | P23 | H | H | P47 | H | H |
| L_{b212} | H | H | P23 | H | H | P48 | H | H |
| L_{b213} | H | H | P23 | H | H | P49 | H | H |
| L_{b214} | H | H | P23 | H | H | P50 | H | H |
| L_{b215} | H | H | P23 | H | H | P51 | H | H |
| L_{b216} | H | H | P23 | H | H | P52 | H | H |
| L_{b217} | H | H | P23 | H | H | P53 | H | H |
| L_{b218} | H | H | P23 | H | H | P54 | H | H |
| L_{b219} | H | H | P23 | H | H | H | P1 | H |
| L_{b220} | H | H | P23 | H | H | H | P2 | H |
| L_{b221} | H | H | P23 | H | H | H | P3 | H |
| L_{b222} | H | H | P23 | H | H | H | P4 | H |
| L_{b223} | H | H | P23 | H | H | H | P5 | H |
| L_{b224} | H | H | P23 | H | H | H | P6 | H |
| L_{b225} | H | H | P23 | H | H | H | P7 | H |
| L_{b226} | H | H | P23 | H | H | H | P8 | H |
| L_{b227} | H | H | P23 | H | H | H | P9 | H |
| L_{b228} | H | H | P23 | H | H | H | P10 | H |
| L_{b229} | H | H | P23 | H | H | H | P11 | H |
| L_{b230} | H | H | P23 | H | H | H | P12 | H |
| L_{b231} | H | H | P23 | H | H | H | P13 | H |
| L_{b232} | H | H | P23 | H | H | H | P14 | H |
| L_{b233} | H | H | P23 | H | H | H | P15 | H |
| L_{b234} | H | H | P23 | H | H | H | P16 | H |
| L_{b235} | H | H | P23 | H | H | H | P17 | H |
| L_{b236} | H | H | P23 | H | H | H | P18 | H |
| L_{b237} | H | H | P23 | H | H | H | P19 | H |
| L_{b238} | H | H | P23 | H | H | H | P20 | H |
| L_{b239} | H | H | P23 | H | H | H | P21 | H |
| L_{b240} | H | H | P23 | H | H | H | P22 | H |
| L_{b241} | H | H | P23 | H | H | H | P23 | H |
| L_{b242} | H | H | P23 | H | H | H | P24 | H |
| L_{b243} | H | H | P23 | H | H | H | P25 | H |
| L_{b244} | H | H | P23 | H | H | H | P26 | H |
| L_{b245} | H | H | P23 | H | H | H | P27 | H |
| L_{b246} | H | H | P23 | H | H | H | P28 | H |
| L_{b247} | H | H | P23 | H | H | H | P29 | H |
| L_{b248} | H | H | P23 | H | H | H | P30 | H |
| L_{b249} | H | H | P23 | H | H | H | P31 | H |
| L_{b250} | H | H | P23 | H | H | H | P32 | H |
| L_{b251} | H | H | P23 | H | H | H | P33 | H |
| L_{b252} | H | H | P23 | H | H | H | P34 | H |
| L_{b253} | H | H | P23 | H | H | H | P35 | H |
| L_{b254} | H | H | P23 | H | H | H | P36 | H |
| L_{b255} | H | H | P23 | H | H | H | P37 | H |
| L_{b256} | H | H | P23 | H | H | H | P38 | H |
| L_{b257} | H | H | P23 | H | H | H | P39 | H |
| L_{b258} | H | H | P23 | H | H | H | P40 | H |
| L_{b259} | H | H | P23 | H | H | H | P41 | H |
| L_{b260} | H | H | P23 | H | H | H | P42 | H |
| L_{b261} | H | H | P23 | H | H | H | P43 | H |
| L_{b262} | H | H | P23 | H | H | H | P44 | H |
| L_{b263} | H | H | P23 | H | H | H | P45 | H |
| L_{b264} | H | H | P23 | H | H | H | P46 | H |
| L_{b265} | H | H | P23 | H | H | H | P47 | H |
| L_{b266} | H | H | P23 | H | H | H | P48 | H |
| L_{b267} | H | H | P23 | H | H | H | P49 | H |
| L_{b268} | H | H | P23 | H | H | H | P50 | H |
| L_{b269} | H | H | P23 | H | H | H | P51 | H |
| L_{b270} | H | H | P23 | H | H | H | P52 | H |
| L_{b271} | H | H | P23 | H | H | H | P53 | H |
| L_{b272} | H | H | P23 | H | H | H | P54 | H |
| L_{b273} | H | H | P23 | H | H | P1 | P1 | H |
| L_{b274} | H | H | P23 | H | H | P2 | P2 | H |
| L_{b275} | H | P1 | P23 | H | H | H | H | H |
| L_{b276} | H | P1 | P23 | D | D | D | D | D |
| L_{b277} | H | P1 | P23 | H | H | P1 | H | H |
| L_{b278} | H | P1 | P23 | H | H | P3 | H | H |
| L_{b279} | H | P1 | P23 | H | H | P6 | H | H |
| L_{b280} | H | P1 | P23 | H | H | P8 | H | H |
| L_{b281} | H | P1 | P23 | H | H | P10 | H | H |
| L_{b282} | H | P1 | P23 | H | H | P12 | H | H |
| L_{b283} | H | P1 | P23 | H | H | P14 | H | H |
| L_{b284} | H | P1 | P23 | H | H | P15 | H | H |
| L_{b285} | H | P1 | P23 | H | H | P17 | H | H |
| L_{b286} | H | P1 | P23 | H | H | P18 | H | H |
| L_{b287} | H | P1 | P23 | H | H | H | P1 | H |
| L_{b288} | H | P1 | P23 | H | H | H | P3 | H |
| L_{b289} | H | P1 | P23 | H | H | H | P6 | H |
| L_{b290} | H | P1 | P23 | H | H | H | P8 | H |
| L_{b291} | H | P1 | P23 | H | H | H | P10 | H |
| L_{b292} | H | P1 | P23 | H | H | H | P12 | H |
| L_{b293} | H | P1 | P23 | H | H | H | P14 | H |
| L_{b294} | H | P1 | P23 | H | H | H | P15 | H |
| L_{b295} | H | P1 | P23 | H | H | H | P17 | H |
| L_{b296} | H | P1 | P23 | H | H | H | P18 | H |
| L_{b297} | H | P1 | P23 | H | H | P1 | P1 | H |
| L_{b298} | H | P1 | P23 | H | H | P10 | P1 | H |
| L_{b299} | H | P1 | P23 | H | H | P8 | P1 | H |
| L_{b300} | H | P2 | P23 | H | H | H | H | H |
| L_{b301} | H | P2 | P23 | D | D | D | D | D |
| L_{b302} | H | P2 | P23 | H | H | P2 | H | H |
| L_{b303} | H | P2 | P23 | H | H | P4 | H | H |
| L_{b304} | H | P2 | P23 | H | H | P5 | H | H |
| L_{b305} | H | P2 | P23 | H | H | P7 | H | H |
| L_{b306} | H | P2 | P23 | H | H | P9 | H | H |
| L_{b307} | H | P2 | P23 | H | H | P11 | H | H |
| L_{b308} | H | P2 | P23 | H | H | P13 | H | H |
| L_{b309} | H | P2 | P23 | H | H | P16 | H | H |
| L_{b310} | H | P2 | P23 | H | H | P19 | H | H |
| L_{b311} | H | P2 | P23 | H | H | P20 | H | H |
| L_{b312} | H | P2 | P23 | H | H | H | P2 | H |
| L_{b313} | H | P2 | P23 | H | H | H | P4 | H |
| L_{b314} | H | P2 | P23 | H | H | H | P5 | H |
| L_{b315} | H | P2 | P23 | H | H | H | P7 | H |
| L_{b316} | H | P2 | P23 | H | H | H | P9 | H |
| L_{b317} | H | P2 | P23 | H | H | H | P11 | H |
| L_{b318} | H | P2 | P23 | H | H | H | P13 | H |
| L_{b319} | H | P2 | P23 | H | H | H | P16 | H |
| L_{b320} | H | P2 | P23 | H | H | H | P19 | H |
| L_{b321} | H | P2 | P23 | H | H | H | P20 | H |
| L_{b322} | H | P2 | P23 | H | H | P2 | P2 | H |
| L_{b323} | H | P2 | P23 | H | H | P9 | P2 | H |
| L_{b324} | H | P2 | P23 | H | H | P11 | P2 | H |
| L_{b325} | H | H | P24 | H | H | H | H | H |
| L_{b326} | H | H | P24 | H | D | D | D | D |
| L_{b327} | H | H | P24 | H | H | P1 | H | H |
| L_{b328} | H | H | P24 | H | H | P2 | H | H |
| L_{b329} | H | H | P24 | H | H | P3 | H | H |
| L_{b330} | H | H | P24 | H | H | P4 | H | H |
| L_{b331} | H | H | P24 | H | H | P5 | H | H |
| L_{b332} | H | H | P24 | H | H | P6 | H | H |
| L_{b333} | H | H | P24 | H | H | P7 | H | H |
| L_{b334} | H | H | P24 | H | H | P8 | H | H |
| L_{b335} | H | H | P24 | H | H | P9 | H | H |
| L_{b336} | H | H | P24 | H | H | P10 | H | H |
| L_{b337} | H | H | P24 | H | H | P11 | H | H |
| L_{b338} | H | H | P24 | H | H | P12 | H | H |
| L_{b339} | H | H | P24 | H | H | P13 | H | H |
| L_{b340} | H | H | P24 | H | H | P14 | H | H |
| L_{b341} | H | H | P24 | H | H | P15 | H | H |
| L_{b342} | H | H | P24 | H | H | P16 | H | H |
| L_{b343} | H | H | P24 | H | H | P17 | H | H |
| L_{b344} | H | H | P24 | H | H | P18 | H | H |
| L_{b345} | H | H | P24 | H | H | P19 | H | H |
| L_{b346} | H | H | P24 | H | H | P20 | H | H |
| L_{b347} | H | H | P24 | H | H | P21 | H | H |
| L_{b348} | H | H | P24 | H | H | P22 | H | H |
| L_{b349} | H | H | P24 | H | H | P23 | H | H |
| L_{b350} | H | H | P24 | H | H | P24 | H | H |
| L_{b351} | H | H | P24 | H | H | P25 | H | H |
| L_{b352} | H | H | P24 | H | H | P26 | H | H |
| L_{b353} | H | H | P24 | H | H | P27 | H | H |
| L_{b354} | H | H | P24 | H | H | P28 | H | H |
| L_{b355} | H | H | P24 | H | H | P29 | H | H |
| L_{b356} | H | H | P24 | H | H | P30 | H | H |
| L_{b357} | H | H | P24 | H | H | P31 | H | H |
| L_{b358} | H | H | P24 | H | H | P32 | H | H |
| L_{b359} | H | H | P24 | H | H | P33 | H | H |
| L_{b360} | H | H | P24 | H | H | P34 | H | H |
| L_{b361} | H | H | P24 | H | H | P35 | H | H |
| L_{b362} | H | H | P24 | H | H | P36 | H | H |
| L_{b363} | H | H | P24 | H | H | P37 | H | H |
| L_{b364} | H | H | P24 | H | H | P38 | H | H |
| L_{b365} | H | H | P24 | H | H | P39 | H | H |
| L_{b366} | H | H | P24 | H | H | P40 | H | H |
| L_{b367} | H | H | P24 | H | H | P41 | H | H |
| L_{b368} | H | H | P24 | H | H | P42 | H | H |
| L_{b369} | H | H | P24 | H | H | P43 | H | H |
| L_{b370} | H | H | P24 | H | H | P44 | H | H |
| L_{b371} | H | H | P24 | H | H | P45 | H | H |
| L_{b372} | H | H | P24 | H | H | P46 | H | H |
| L_{b373} | H | H | P24 | H | H | P47 | H | H |
| L_{b374} | H | H | P24 | H | H | P48 | H | H |
| L_{b375} | H | H | P24 | H | H | P49 | H | H |
| L_{b376} | H | H | P24 | H | H | P50 | H | H |
| L_{b377} | H | H | P24 | H | H | P51 | H | H |
| L_{b378} | H | H | P24 | H | H | P52 | H | H |
| L_{b379} | H | H | P24 | H | H | P53 | H | H |
| L_{b380} | H | H | P24 | H | H | P54 | H | H |
| L_{b381} | H | H | P24 | H | H | H | P1 | H |
| L_{b382} | H | H | P24 | H | H | H | P2 | H |
| L_{b383} | H | H | P24 | H | H | H | P3 | H |
| L_{b384} | H | H | P24 | H | H | H | P4 | H |
| L_{b385} | H | H | P24 | H | H | H | P5 | H |
| L_{b386} | H | H | P24 | H | H | H | P6 | H |
| L_{b387} | H | H | P24 | H | H | H | P7 | H |
| L_{b388} | H | H | P24 | H | H | H | P8 | H |
| L_{b389} | H | H | P24 | H | H | H | P9 | H |
| L_{b390} | H | H | P24 | H | H | H | P10 | H |
| L_{b391} | H | H | P24 | H | H | H | P11 | H |
| L_{b392} | H | H | P24 | H | H | H | P12 | H |
| L_{b393} | H | H | P24 | H | H | H | P13 | H |
| L_{b394} | H | H | P24 | H | H | H | P14 | H |
| L_{b395} | H | H | P24 | H | H | H | P15 | H |
| L_{b396} | H | H | P24 | H | H | H | P16 | H |
| L_{b397} | H | H | P24 | H | H | H | P17 | H |
| L_{b398} | H | H | P24 | H | H | H | P18 | H |
| L_{b399} | H | H | P24 | H | H | H | P19 | H |
| L_{b400} | H | H | P24 | H | H | H | P20 | H |
| L_{b401} | H | H | P24 | H | H | H | P21 | H |
| L_{b402} | H | H | P24 | H | H | H | P22 | H |
| L_{b403} | H | H | P24 | H | H | H | P23 | H |
| L_{b404} | H | H | P24 | H | H | H | P24 | H |
| L_{b405} | H | H | P24 | H | H | H | P25 | H |
| L_{b406} | H | H | P24 | H | H | H | P26 | H |
| L_{b407} | H | H | P24 | H | H | H | P27 | H |
| L_{b408} | H | H | P24 | H | H | H | P28 | H |
| L_{b409} | H | H | P24 | H | H | H | P29 | H |
| L_{b410} | H | H | P24 | H | H | H | P30 | H |
| L_{b411} | H | H | P24 | H | H | H | P31 | H |
| L_{b412} | H | H | P24 | H | H | H | P32 | H |
| L_{b413} | H | H | P24 | H | H | H | P33 | H |
| L_{b414} | H | H | P24 | H | H | H | P34 | H |
| L_{b415} | H | H | P24 | H | H | H | P35 | H |
| L_{b416} | H | H | P24 | H | H | H | P36 | H |
| L_{b417} | H | H | P24 | H | H | H | P37 | H |
| L_{b418} | H | H | P24 | H | H | H | P38 | H |
| L_{b419} | H | H | P24 | H | H | H | P39 | H |
| L_{b420} | H | H | P24 | H | H | H | P40 | H |
| L_{b421} | H | H | P24 | H | H | H | P41 | H |
| L_{b422} | H | H | P24 | H | H | H | P42 | H |
| L_{b423} | H | H | P24 | H | H | H | P43 | H |
| L_{b424} | H | H | P24 | H | H | H | P44 | H |
| L_{b425} | H | H | P24 | H | H | H | P45 | H |
| L_{b426} | H | H | P24 | H | H | H | P46 | H |
| L_{b427} | H | H | P24 | H | H | H | P47 | H |
| L_{b428} | H | H | P24 | H | H | H | P48 | H |
| L_{b429} | H | H | P24 | H | H | H | P49 | H |
| L_{b430} | H | H | P24 | H | H | H | P50 | H |
| L_{b431} | H | H | P24 | H | H | H | P51 | H |
| L_{b432} | H | H | P24 | H | H | H | P52 | H |
| L_{b433} | H | H | P24 | H | H | H | P53 | H |
| L_{b434} | H | H | P24 | H | H | H | P54 | H |
| L_{b435} | H | H | P24 | H | H | P1 | P1 | H |
| L_{b436} | H | H | P24 | H | H | P2 | P2 | H |
| L_{b437} | H | P1 | P24 | H | H | H | H | H |
| L_{b438} | H | P1 | P24 | D | D | D | D | D |
| L_{b439} | H | P1 | P24 | H | H | P1 | H | H |
| L_{b440} | H | P1 | P24 | H | H | P3 | H | H |
| L_{b441} | H | P1 | P24 | H | H | P6 | H | H |
| L_{b442} | H | P1 | P24 | H | H | P8 | H | H |
| L_{b443} | H | P1 | P24 | H | H | P10 | H | H |
| L_{b444} | H | P1 | P24 | H | H | P12 | H | H |
| L_{b445} | H | P1 | P24 | H | H | P14 | H | H |
| L_{b446} | H | P1 | P24 | H | H | P15 | H | H |
| L_{b447} | H | P1 | P24 | H | H | P17 | H | H |
| L_{b448} | H | P1 | P24 | H | H | P18 | H | H |
| L_{b449} | H | P1 | P24 | H | H | H | P1 | H |
| L_{b450} | H | P1 | P24 | H | H | H | P3 | H |
| L_{b451} | H | P1 | P24 | H | H | H | P6 | H |
| L_{b452} | H | P1 | P24 | H | H | H | P8 | H |
| L_{b453} | H | P1 | P24 | H | H | H | P10 | H |
| L_{b454} | H | P1 | P24 | H | H | H | P12 | H |
| L_{b455} | H | P1 | P24 | H | H | H | P14 | H |
| L_{b456} | H | P1 | P24 | H | H | H | P15 | H |
| L_{b457} | H | P1 | P24 | H | H | H | P17 | H |
| L_{b458} | H | P1 | P24 | H | H | H | P18 | H |
| L_{b459} | H | P1 | P24 | H | H | P1 | P1 | H |
| L_{b460} | H | P1 | P24 | H | H | P10 | P1 | H |
| L_{b461} | H | P1 | P24 | H | H | P8 | P1 | H |
| L_{b462} | H | P2 | P24 | H | H | H | H | H |
| L_{b463} | H | P2 | P24 | D | D | D | D | D |
| L_{b464} | H | P2 | P24 | H | H | P2 | H | H |
| L_{b465} | H | P2 | P24 | H | H | P4 | H | H |
| L_{b466} | H | P2 | P24 | H | H | P5 | H | H |
| L_{b467} | H | P2 | P24 | H | H | P7 | H | H |
| L_{b468} | H | P2 | P24 | H | H | P9 | H | H |
| L_{b469} | H | P2 | P24 | H | H | P11 | H | H |
| L_{b470} | H | P2 | P24 | H | H | P13 | H | H |
| L_{b471} | H | P2 | P24 | H | H | P16 | H | H |
| L_{b472} | H | P2 | P24 | H | H | P19 | H | H |
| L_{b473} | H | P2 | P24 | H | H | P20 | H | H |
| L_{b474} | H | P2 | P24 | H | H | H | P2 | H |
| L_{b475} | H | P2 | P24 | H | H | H | P4 | H |
| L_{b476} | H | P2 | P24 | H | H | H | P5 | H |
| L_{b477} | H | P2 | P24 | H | H | H | P7 | H |
| L_{b478} | H | P2 | P24 | H | H | H | P9 | H |
| L_{b479} | H | P2 | P24 | H | H | H | P11 | H |
| L_{b480} | H | P2 | P24 | H | H | H | P13 | H |
| L_{b481} | H | P2 | P24 | H | H | H | P16 | H |
| L_{b482} | H | P2 | P24 | H | H | H | P19 | H |
| L_{b483} | H | P2 | P24 | H | H | H | P20 | H |
| L_{b484} | H | P2 | P24 | H | H | P2 | P2 | H |
| L_{b485} | H | P2 | P24 | H | H | P9 | P2 | H |
| L_{b486} | H | P2 | P24 | H | H | P11 | P2 | H |
| L_{b487} | H | H | H | H | H | H | P23 | H |
| L_{b488} | D | D | D | D | D | D | P23 | D |
| L_{b489} | H | P1 | H | H | H | H | P23 | H |
| L_{b490} | H | P2 | H | H | H | H | P23 | H |
| L_{b491} | H | P3 | H | H | H | H | P23 | H |
| L_{b492} | H | P4 | H | H | H | H | P23 | H |
| L_{b493} | H | P5 | H | H | H | H | P23 | H |
| L_{b494} | H | P6 | H | H | H | H | P23 | H |
| L_{b495} | H | P7 | H | H | H | H | P23 | H |
| L_{b496} | H | P8 | H | H | H | H | P23 | H |
| L_{b497} | H | P9 | H | H | H | H | P23 | H |
| L_{b498} | H | P10 | H | H | H | H | P23 | H |
| L_{b499} | H | P11 | H | H | H | H | P23 | H |
| L_{b500} | H | P12 | H | H | H | H | P23 | H |
| L_{b501} | H | P13 | H | H | H | H | P23 | H |
| L_{b502} | H | P14 | H | H | H | H | P23 | H |
| L_{b503} | H | P15 | H | H | H | H | P23 | H |
| L_{b504} | H | P16 | H | H | H | H | P23 | H |
| L_{b505} | H | P17 | H | H | H | H | P23 | H |
| L_{b506} | H | P18 | H | H | H | H | P23 | H |
| L_{b507} | H | P19 | H | H | H | H | P23 | H |
| L_{b508} | H | P20 | H | H | H | H | P23 | H |
| L_{b509} | H | P21 | H | H | H | H | P23 | H |
| L_{b510} | H | P22 | H | H | H | H | P23 | H |
| L_{b511} | H | P23 | H | H | H | H | P23 | H |
| L_{b512} | H | P24 | H | H | H | H | P23 | H |
| L_{b513} | H | P25 | H | H | H | H | P23 | H |
| L_{b514} | H | P26 | H | H | H | H | P23 | H |
| L_{b515} | H | P27 | H | H | H | H | P23 | H |
| L_{b516} | H | P28 | H | H | H | H | P23 | H |
| L_{b517} | H | P29 | H | H | H | H | P23 | H |
| L_{b518} | H | P30 | H | H | H | H | P23 | H |
| L_{b519} | H | P31 | H | H | H | H | P23 | H |
| L_{b520} | H | P32 | H | H | H | H | P23 | H |
| L_{b521} | H | P33 | H | H | H | H | P23 | H |
| L_{b522} | H | P34 | H | H | H | H | P23 | H |
| L_{b523} | H | P35 | H | H | H | H | P23 | H |
| L_{b524} | H | P36 | H | H | H | H | P23 | H |
| L_{b525} | H | P37 | H | H | H | H | P23 | H |
| L_{b526} | H | P38 | H | H | H | H | P23 | H |
| L_{b527} | H | P39 | H | H | H | H | P23 | H |
| L_{b528} | H | P40 | H | H | H | H | P23 | H |
| L_{b529} | H | P41 | H | H | H | H | P23 | H |
| L_{b530} | H | P42 | H | H | H | H | P23 | H |
| L_{b531} | H | P43 | H | H | H | H | P23 | H |
| L_{b532} | H | P44 | H | H | H | H | P23 | H |
| L_{b533} | H | P45 | H | H | H | H | P23 | H |
| L_{b534} | H | P46 | H | H | H | H | P23 | H |
| L_{b535} | H | P47 | H | H | H | H | P23 | H |
| L_{b536} | H | P48 | H | H | H | H | P23 | H |
| L_{b537} | H | P49 | H | H | H | H | P23 | H |
| L_{b538} | H | P50 | H | H | H | H | P23 | H |
| L_{b539} | H | P51 | H | H | H | H | P23 | H |
| L_{b540} | H | P52 | H | H | H | H | P23 | H |
| L_{b541} | H | P53 | H | H | H | H | P23 | H |
| L_{b542} | H | P54 | H | H | H | H | P23 | H |
| L_{b543} | H | H | P1 | H | H | H | P23 | H |
| L_{b544} | H | H | P2 | H | H | H | P23 | H |
| L_{b545} | H | H | P3 | H | H | H | P23 | H |
| L_{b546} | H | H | P4 | H | H | H | P23 | H |
| L_{b547} | H | H | P5 | H | H | H | P23 | H |
| L_{b548} | H | H | P6 | H | H | H | P23 | H |
| L_{b549} | H | H | P7 | H | H | H | P23 | H |
| L_{b550} | H | H | P8 | H | H | H | P23 | H |
| L_{b551} | H | H | P9 | H | H | H | P23 | H |
| L_{b552} | H | H | P10 | H | H | H | P23 | H |
| L_{b553} | H | H | P11 | H | H | H | P23 | H |
| L_{b554} | H | H | P12 | H | H | H | P23 | H |
| L_{b555} | H | H | P13 | H | H | H | P23 | H |
| L_{b556} | H | H | P14 | H | H | H | P23 | H |
| L_{b557} | H | H | P15 | H | H | H | P23 | H |
| L_{b558} | H | H | P16 | H | H | H | P23 | H |
| L_{b559} | H | H | P17 | H | H | H | P23 | H |
| L_{b560} | H | H | P18 | H | H | H | P23 | H |
| L_{b561} | H | H | P19 | H | H | H | P23 | H |
| L_{b562} | H | H | P20 | H | H | H | P23 | H |
| L_{b563} | H | H | P21 | H | H | H | P23 | H |
| L_{b564} | H | H | P22 | H | H | H | P23 | H |
| L_{b565} | H | H | P23 | H | H | H | P23 | H |
| L_{b566} | H | H | P24 | H | H | H | P23 | H |
| L_{b567} | H | H | P25 | H | H | H | P23 | H |
| L_{b568} | H | H | P26 | H | H | H | P23 | H |
| L_{b569} | H | H | P27 | H | H | H | P23 | H |
| L_{b570} | H | H | P28 | H | H | H | P23 | H |
| L_{b571} | H | H | P29 | H | H | H | P23 | H |
| L_{b572} | H | H | P30 | H | H | H | P23 | H |
| L_{b573} | H | H | P31 | H | H | H | P23 | H |
| L_{b574} | H | H | P32 | H | H | H | P23 | H |
| L_{b575} | H | H | P33 | H | H | H | P23 | H |
| L_{b576} | H | H | P34 | H | H | H | P23 | H |
| L_{b577} | H | H | P35 | H | H | H | P23 | H |
| L_{b578} | H | H | P36 | H | H | H | P23 | H |
| L_{b579} | H | H | P37 | H | H | H | P23 | H |
| L_{b580} | H | H | P38 | H | H | H | P23 | H |
| L_{b581} | H | H | P39 | H | H | H | P23 | H |
| L_{b582} | H | H | P40 | H | H | H | P23 | H |
| L_{b583} | H | H | P41 | H | H | H | P23 | H |
| L_{b584} | H | H | P42 | H | H | H | P23 | H |
| L_{b585} | H | H | P43 | H | H | H | P23 | H |
| L_{b586} | H | H | P44 | H | H | H | P23 | H |
| L_{b587} | H | H | P45 | H | H | H | P23 | H |
| L_{b588} | H | H | P46 | H | H | H | P23 | H |
| L_{b589} | H | H | P47 | H | H | H | P23 | H |
| L_{b590} | H | H | P48 | H | H | H | P23 | H |
| L_{b591} | H | H | P49 | H | H | H | P23 | H |
| L_{b592} | H | H | P50 | H | H | H | P23 | H |
| L_{b593} | H | H | P51 | H | H | H | P23 | H |
| L_{b594} | H | H | P52 | H | H | H | P23 | H |
| L_{b595} | H | H | P53 | H | H | H | P23 | H |
| L_{b596} | H | H | P54 | H | H | H | P23 | H |
| L_{b597} | H | P1 | H | H | H | P1 | P23 | H |
| L_{b598} | H | P2 | H | H | H | P1 | P23 | H |
| L_{b599} | H | P3 | H | H | H | P1 | P23 | H |
| L_{b600} | H | P4 | H | H | H | P1 | P23 | H |
| L_{b601} | H | P5 | H | H | H | P1 | P23 | H |
| L_{b602} | H | P6 | H | H | H | P1 | P23 | H |
| L_{b603} | H | P7 | H | H | H | P1 | P23 | H |
| L_{b604} | H | P8 | H | H | H | P1 | P23 | H |
| L_{b605} | H | P9 | H | H | H | P1 | P23 | H |
| L_{b606} | H | P10 | H | H | H | P1 | P23 | H |
| L_{b607} | H | P11 | H | H | H | P1 | P23 | H |
| L_{b608} | H | P12 | H | H | H | P1 | P23 | H |
| L_{b609} | H | P13 | H | H | H | P1 | P23 | H |
| L_{b610} | H | P14 | H | H | H | P1 | P23 | H |
| L_{b611} | H | P15 | H | H | H | P1 | P23 | H |
| L_{b612} | H | P16 | H | H | H | P1 | P23 | H |
| L_{b613} | H | P17 | H | H | H | P1 | P23 | H |
| L_{b614} | H | P18 | H | H | H | P1 | P23 | H |
| L_{b615} | H | P19 | H | H | H | P1 | P23 | H |
| L_{b616} | H | P20 | H | H | H | P1 | P23 | H |
| L_{b617} | H | P21 | H | H | H | P1 | P23 | H |
| L_{b618} | H | P22 | H | H | H | P1 | P23 | H |
| L_{b619} | H | P23 | H | H | H | P1 | P23 | H |
| L_{b620} | H | P24 | H | H | H | P1 | P23 | H |
| L_{b621} | H | P25 | H | H | H | P1 | P23 | H |
| L_{b622} | H | P26 | H | H | H | P1 | P23 | H |
| L_{b623} | H | P27 | H | H | H | P1 | P23 | H |
| L_{b624} | H | P28 | H | H | H | P1 | P23 | H |
| L_{b625} | H | P29 | H | H | H | P1 | P23 | H |
| L_{b626} | H | P30 | H | H | H | P1 | P23 | H |
| L_{b627} | H | P31 | H | H | H | P1 | P23 | H |
| L_{b628} | H | P32 | H | H | H | P1 | P23 | H |
| L_{b629} | H | P33 | H | H | H | P1 | P23 | H |
| L_{b630} | H | P34 | H | H | H | P1 | P23 | H |
| L_{b631} | H | P35 | H | H | H | P1 | P23 | H |
| L_{b632} | H | P36 | H | H | H | P1 | P23 | H |
| L_{b633} | H | P37 | H | H | H | P1 | P23 | H |
| L_{b634} | H | P38 | H | H | H | P1 | P23 | H |
| L_{b635} | H | P39 | H | H | H | P1 | P23 | H |
| L_{b636} | H | P40 | H | H | H | P1 | P23 | H |
| L_{b637} | H | P41 | H | H | H | P1 | P23 | H |
| L_{b638} | H | P42 | H | H | H | P1 | P23 | H |
| L_{b639} | H | P43 | H | H | H | P1 | P23 | H |
| L_{b640} | H | P44 | H | H | H | P1 | P23 | H |
| L_{b641} | H | P45 | H | H | H | P1 | P23 | H |
| L_{b642} | H | P46 | H | H | H | P1 | P23 | H |
| L_{b643} | H | P47 | H | H | H | P1 | P23 | H |
| L_{b644} | H | P48 | H | H | H | P1 | P23 | H |
| L_{b645} | H | P49 | H | H | H | P1 | P23 | H |
| L_{b646} | H | P50 | H | H | H | P1 | P23 | H |
| L_{b647} | H | P51 | H | H | H | P1 | P23 | H |
| L_{b648} | H | P52 | H | H | H | P1 | P23 | H |
| L_{b649} | H | P53 | H | H | H | P1 | P23 | H |
| L_{b650} | H | P54 | H | H | H | P1 | P23 | H |
| L_{b651} | H | H | P1 | H | H | P1 | P23 | H |
| L_{b652} | H | H | P2 | H | H | P1 | P23 | H |
| L_{b653} | H | H | P3 | H | H | P1 | P23 | H |
| L_{b654} | H | H | P4 | H | H | P1 | P23 | H |
| L_{b655} | H | H | P5 | H | H | P1 | P23 | H |
| L_{b656} | H | H | P6 | H | H | P1 | P23 | H |
| L_{b657} | H | H | P7 | H | H | P1 | P23 | H |
| L_{b658} | H | H | P8 | H | H | P1 | P23 | H |
| L_{b659} | H | H | P9 | H | H | P1 | P23 | H |
| L_{b660} | H | H | P10 | H | H | P1 | P23 | H |
| L_{b661} | H | H | P11 | H | H | P1 | P23 | H |
| L_{b662} | H | H | P12 | H | H | P1 | P23 | H |
| L_{b663} | H | H | P13 | H | H | P1 | P23 | H |
| L_{b664} | H | H | P14 | H | H | P1 | P23 | H |
| L_{b665} | H | H | P15 | H | H | P1 | P23 | H |
| L_{b666} | H | H | P16 | H | H | P1 | P23 | H |
| L_{b667} | H | H | P17 | H | H | P1 | P23 | H |
| L_{b668} | H | H | P18 | H | H | P1 | P23 | H |
| L_{b669} | H | H | P19 | H | H | P1 | P23 | H |
| L_{b670} | H | H | P20 | H | H | P1 | P23 | H |
| L_{b671} | H | H | P21 | H | H | P1 | P23 | H |
| L_{b672} | H | H | P22 | H | H | P1 | P23 | H |
| L_{b673} | H | H | P23 | H | H | P1 | P23 | H |
| L_{b674} | H | H | P24 | H | H | P1 | P23 | H |
| L_{b675} | H | H | P25 | H | H | P1 | P23 | H |
| L_{b676} | H | H | P26 | H | H | P1 | P23 | H |
| L_{b677} | H | H | P27 | H | H | P1 | P23 | H |
| L_{b678} | H | H | P28 | H | H | P1 | P23 | H |
| L_{b679} | H | H | P29 | H | H | P1 | P23 | H |
| L_{b680} | H | H | P30 | H | H | P1 | P23 | H |
| L_{b681} | H | H | P31 | H | H | P1 | P23 | H |
| L_{b682} | H | H | P32 | H | H | P1 | P23 | H |
| L_{b683} | H | H | P33 | H | H | P1 | P23 | H |
| L_{b684} | H | H | P34 | H | H | P1 | P23 | H |
| L_{b685} | H | H | P35 | H | H | P1 | P23 | H |
| L_{b686} | H | H | P36 | H | H | P1 | P23 | H |
| L_{b687} | H | H | P37 | H | H | P1 | P23 | H |
| L_{b688} | H | H | P38 | H | H | P1 | P23 | H |
| L_{b689} | H | H | P39 | H | H | P1 | P23 | H |
| L_{b690} | H | H | P40 | H | H | P1 | P23 | H |
| L_{b691} | H | H | P41 | H | H | P1 | P23 | H |
| L_{b692} | H | H | P42 | H | H | P1 | P23 | H |
| L_{b693} | H | H | P43 | H | H | P1 | P23 | H |
| L_{b694} | H | H | P44 | H | H | P1 | P23 | H |
| L_{b695} | H | H | P45 | H | H | P1 | P23 | H |
| L_{b696} | H | H | P46 | H | H | P1 | P23 | H |
| L_{b697} | H | H | P47 | H | H | P1 | P23 | H |
| L_{b698} | H | H | P48 | H | H | P1 | P23 | H |
| L_{b699} | H | H | P49 | H | H | P1 | P23 | H |
| L_{b700} | H | H | P50 | H | H | P1 | P23 | H |
| L_{b701} | H | H | P51 | H | H | P1 | P23 | H |
| L_{b702} | H | H | P52 | H | H | P1 | P23 | H |
| L_{b703} | H | H | P53 | H | H | P1 | P23 | H |
| L_{b704} | H | H | P54 | H | H | P1 | P23 | H |
| L_{b705} | H | P1 | H | H | H | P2 | P23 | H |
| L_{b706} | H | P2 | H | H | H | P2 | P23 | H |
| L_{b707} | H | P3 | H | H | H | P2 | P23 | H |
| L_{b708} | H | P4 | H | H | H | P2 | P23 | H |
| L_{b709} | H | P5 | H | H | H | P2 | P23 | H |
| L_{b710} | H | P6 | H | H | H | P2 | P23 | H |
| L_{b711} | H | P7 | H | H | H | P2 | P23 | H |
| L_{b712} | H | P8 | H | H | H | P2 | P23 | H |
| L_{b713} | H | P9 | H | H | H | P2 | P23 | H |
| L_{b714} | H | P10 | H | H | H | P2 | P23 | H |
| L_{b715} | H | P11 | H | H | H | P2 | P23 | H |
| L_{b716} | H | P12 | H | H | H | P2 | P23 | H |
| L_{b717} | H | P13 | H | H | H | P2 | P23 | H |
| L_{b718} | H | P14 | H | H | H | P2 | P23 | H |
| L_{b719} | H | P15 | H | H | H | P2 | P23 | H |
| L_{b720} | H | P16 | H | H | H | P2 | P23 | H |
| L_{b721} | H | P17 | H | H | H | P2 | P23 | H |
| L_{b722} | H | P18 | H | H | H | P2 | P23 | H |
| L_{b723} | H | P19 | H | H | H | P2 | P23 | H |
| L_{b724} | H | P20 | H | H | H | P2 | P23 | H |
| L_{b725} | H | P21 | H | H | H | P2 | P23 | H |
| L_{b726} | H | P22 | H | H | H | P2 | P23 | H |
| L_{b727} | H | P23 | H | H | H | P2 | P23 | H |
| L_{b728} | H | P24 | H | H | H | P2 | P23 | H |
| L_{b729} | H | P25 | H | H | H | P2 | P23 | H |
| L_{b730} | H | P26 | H | H | H | P2 | P23 | H |
| L_{b731} | H | P27 | H | H | H | P2 | P23 | H |
| L_{b732} | H | P28 | H | H | H | P2 | P23 | H |
| L_{b733} | H | P29 | H | H | H | P2 | P23 | H |
| L_{b734} | H | P30 | H | H | H | P2 | P23 | H |
| L_{b735} | H | P31 | H | H | H | P2 | P23 | H |
| L_{b736} | H | P32 | H | H | H | P2 | P23 | H |
| L_{b737} | H | P33 | H | H | H | P2 | P23 | H |
| L_{b738} | H | P34 | H | H | H | P2 | P23 | H |
| L_{b739} | H | P35 | H | H | H | P2 | P23 | H |
| L_{b740} | H | P36 | H | H | H | P2 | P23 | H |
| L_{b741} | H | P37 | H | H | H | P2 | P23 | H |
| L_{b742} | H | P38 | H | H | H | P2 | P23 | H |
| L_{b743} | H | P39 | H | H | H | P2 | P23 | H |
| L_{b744} | H | P40 | H | H | H | P2 | P23 | H |
| L_{b745} | H | P41 | H | H | H | P2 | P23 | H |
| L_{b746} | H | P42 | H | H | H | P2 | P23 | H |
| L_{b747} | H | P43 | H | H | H | P2 | P23 | H |
| L_{b748} | H | P44 | H | H | H | P2 | P23 | H |
| L_{b749} | H | P45 | H | H | H | P2 | P23 | H |
| L_{b750} | H | P46 | H | H | H | P2 | P23 | H |
| L_{b751} | H | P47 | H | H | H | P2 | P23 | H |
| L_{b752} | H | P48 | H | H | H | P2 | P23 | H |
| L_{b753} | H | P49 | H | H | H | P2 | P23 | H |
| L_{b754} | H | P50 | H | H | H | P2 | P23 | H |
| L_{b755} | H | P51 | H | H | H | P2 | P23 | H |
| L_{b756} | H | P52 | H | H | H | P2 | P23 | H |
| L_{b757} | H | P53 | H | H | H | P2 | P23 | H |
| L_{b758} | H | P54 | H | H | H | P2 | P23 | H |
| L_{b759} | H | H | P1 | H | H | P2 | P23 | H |
| L_{b760} | H | H | P2 | H | H | P2 | P23 | H |
| L_{b761} | H | H | P3 | H | H | P2 | P23 | H |
| L_{b762} | H | H | P4 | H | H | P2 | P23 | H |
| L_{b763} | H | H | P5 | H | H | P2 | P23 | H |
| L_{b764} | H | H | P6 | H | H | P2 | P23 | H |
| L_{b765} | H | H | P7 | H | H | P2 | P23 | H |
| L_{b766} | H | H | P8 | H | H | P2 | P23 | H |
| L_{b767} | H | H | P9 | H | H | P2 | P23 | H |
| L_{b768} | H | H | P10 | H | H | P2 | P23 | H |
| L_{b769} | H | H | P11 | H | H | P2 | P23 | H |
| L_{b770} | H | H | P12 | H | H | P2 | P23 | H |
| L_{b771} | H | H | P13 | H | H | P2 | P23 | H |
| L_{b772} | H | H | P14 | H | H | P2 | P23 | H |
| L_{b773} | H | H | P15 | H | H | P2 | P23 | H |
| L_{b774} | H | H | P16 | H | H | P2 | P23 | H |
| L_{b775} | H | H | P17 | H | H | P2 | P23 | H |
| L_{b776} | H | H | P18 | H | H | P2 | P23 | H |
| L_{b777} | H | H | P19 | H | H | P2 | P23 | H |
| L_{b778} | H | H | P20 | H | H | P2 | P23 | H |
| L_{b779} | H | H | P21 | H | H | P2 | P23 | H |
| L_{b780} | H | H | P22 | H | H | P2 | P23 | H |
| L_{b781} | H | H | P23 | H | H | P2 | P23 | H |
| L_{b782} | H | H | P24 | H | H | P2 | P23 | H |
| L_{b783} | H | H | P25 | H | H | P2 | P23 | H |
| L_{b784} | H | H | P26 | H | H | P2 | P23 | H |
| L_{b785} | H | H | P27 | H | H | P2 | P23 | H |
| L_{b786} | H | H | P28 | H | H | P2 | P23 | H |
| L_{b787} | H | H | P29 | H | H | P2 | P23 | H |
| L_{b788} | H | H | P30 | H | H | P2 | P23 | H |
| L_{b789} | H | H | P31 | H | H | P2 | P23 | H |
| L_{b790} | H | H | P32 | H | H | P2 | P23 | H |
| L_{b791} | H | H | P33 | H | H | P2 | P23 | H |
| L_{b792} | H | H | P34 | H | H | P2 | P23 | H |
| L_{b793} | H | H | P35 | H | H | P2 | P23 | H |
| L_{b794} | H | H | P36 | H | H | P2 | P23 | H |
| L_{b795} | H | H | P37 | H | H | P2 | P23 | H |
| L_{b796} | H | H | P38 | H | H | P2 | P23 | H |
| L_{b797} | H | H | P39 | H | H | P2 | P23 | H |
| L_{b798} | H | H | P40 | H | H | P2 | P23 | H |
| L_{b799} | H | H | P41 | H | H | P2 | P23 | H |
| L_{b800} | H | H | P42 | H | H | P2 | P23 | H |
| L_{b801} | H | H | P43 | H | H | P2 | P23 | H |
| L_{b802} | H | H | P44 | H | H | P2 | P23 | H |
| L_{b803} | H | H | P45 | H | H | P2 | P23 | H |
| L_{b804} | H | H | P46 | H | H | P2 | P23 | H |
| L_{b805} | H | H | P47 | H | H | P2 | P23 | H |
| L_{b806} | H | H | P48 | H | H | P2 | P23 | H |
| L_{b807} | H | H | P49 | H | H | P2 | P23 | H |
| L_{b808} | H | H | P50 | H | H | P2 | P23 | H |
| L_{b809} | H | H | P51 | H | H | P2 | P23 | H |
| L_{b810} | H | H | P52 | H | H | P2 | P23 | H |
| L_{b811} | H | H | P53 | H | H | P2 | P23 | H |
| L_{b812} | H | H | P54 | H | H | P2 | P23 | H |
| L_{b813} | D | P1 | H | H | H | P2 | P23 | H |
| L_{b814} | D | P2 | H | H | H | P2 | P23 | H |
| L_{b815} | D | P3 | H | H | H | P2 | P23 | H |
| L_{b816} | D | P4 | H | H | H | P2 | P23 | H |
| L_{b817} | D | P5 | H | H | H | P2 | P23 | H |
| L_{b818} | D | P6 | H | H | H | P2 | P23 | H |
| L_{b819} | D | P7 | H | H | H | P2 | P23 | H |
| L_{b820} | D | P8 | H | H | H | P2 | P23 | H |
| L_{b821} | D | P9 | H | H | H | P2 | P23 | H |
| L_{b822} | D | P10 | H | H | H | P2 | P23 | H |
| L_{b823} | D | P11 | H | H | H | P2 | P23 | H |
| L_{b824} | D | P12 | H | H | H | P2 | P23 | H |
| L_{b825} | D | P13 | H | H | H | P2 | P23 | H |
| L_{b826} | D | P14 | H | H | H | P2 | P23 | H |
| L_{b827} | D | P15 | H | H | H | P2 | P23 | H |
| L_{b828} | D | P16 | H | H | H | P2 | P23 | H |
| L_{b829} | D | P17 | H | H | H | P2 | P23 | H |
| L_{b830} | D | P18 | H | H | H | P2 | P23 | H |
| L_{b831} | D | P19 | H | H | H | P2 | P23 | H |
| L_{b832} | D | P20 | H | H | H | P2 | P23 | H |
| L_{b833} | D | P21 | H | H | H | P2 | P23 | H |
| L_{b834} | D | P22 | H | H | H | P2 | P23 | H |
| L_{b835} | D | P23 | H | H | H | P2 | P23 | H |
| L_{b836} | D | P24 | H | H | H | P2 | P23 | H |
| L_{b837} | D | P25 | H | H | H | P2 | P23 | H |
| L_{b838} | D | P26 | H | H | H | P2 | P23 | H |
| L_{b839} | D | P27 | H | H | H | P2 | P23 | H |
| L_{b840} | D | P28 | H | H | H | P2 | P23 | H |
| L_{b841} | D | P29 | H | H | H | P2 | P23 | H |
| L_{b842} | D | P30 | H | H | H | P2 | P23 | H |
| L_{b843} | D | P31 | H | H | H | P2 | P23 | H |
| L_{b844} | D | P32 | H | H | H | P2 | P23 | H |
| L_{b845} | D | P33 | H | H | H | P2 | P23 | H |
| L_{b846} | D | P34 | H | H | H | P2 | P23 | H |
| L_{b847} | D | P35 | H | H | H | P2 | P23 | H |
| L_{b848} | D | P36 | H | H | H | P2 | P23 | H |
| L_{b849} | D | P37 | H | H | H | P2 | P23 | H |
| L_{b850} | D | P38 | H | H | H | P2 | P23 | H |
| L_{b851} | D | P39 | H | H | H | P2 | P23 | H |
| L_{b852} | D | P40 | H | H | H | P2 | P23 | H |
| L_{b853} | D | P41 | H | H | H | P2 | P23 | H |
| L_{b854} | D | P42 | H | H | H | P2 | P23 | H |
| L_{b855} | D | P43 | H | H | H | P2 | P23 | H |
| L_{b856} | D | P44 | H | H | H | P2 | P23 | H |
| L_{b857} | D | P45 | H | H | H | P2 | P23 | H |
| L_{b858} | D | P46 | H | H | H | P2 | P23 | H |
| L_{b859} | D | P47 | H | H | H | P2 | P23 | H |
| L_{b860} | D | P48 | H | H | H | P2 | P23 | H |
| L_{b861} | D | P49 | H | H | H | P2 | P23 | H |
| L_{b862} | D | P50 | H | H | H | P2 | P23 | H |
| L_{b863} | D | P51 | H | H | H | P2 | P23 | H |
| L_{b864} | D | P52 | H | H | H | P2 | P23 | H |
| L_{b865} | D | P53 | H | H | H | P2 | P23 | H |
| L_{b866} | D | P54 | H | H | H | P2 | P23 | H |
| L_{b867} | D | H | P1 | H | H | P2 | P23 | H |
| L_{b868} | D | H | P2 | H | H | P2 | P23 | H |
| L_{b869} | D | H | P3 | H | H | P2 | P23 | H |
| L_{b870} | D | H | P4 | H | H | P2 | P23 | H |
| L_{b871} | D | H | P5 | H | H | P2 | P23 | H |
| L_{b872} | D | H | P6 | H | H | P2 | P23 | H |
| L_{b873} | D | H | P7 | H | H | P2 | P23 | H |
| L_{b874} | D | H | P8 | H | H | P2 | P23 | H |
| L_{b875} | D | H | P9 | H | H | P2 | P23 | H |
| L_{b876} | D | H | P10 | H | H | P2 | P23 | H |
| L_{b877} | D | H | P11 | H | H | P2 | P23 | H |
| L_{b878} | D | H | P12 | H | H | P2 | P23 | H |
| L_{b879} | D | H | P13 | H | H | P2 | P23 | H |
| L_{b880} | D | H | P14 | H | H | P2 | P23 | H |
| L_{b881} | D | H | P15 | H | H | P2 | P23 | H |
| L_{b882} | D | H | P16 | H | H | P2 | P23 | H |
| L_{b883} | D | H | P17 | H | H | P2 | P23 | H |
| L_{b884} | D | H | P18 | H | H | P2 | P23 | H |
| L_{b885} | D | H | P19 | H | H | P2 | P23 | H |
| L_{b886} | D | H | P20 | H | H | P2 | P23 | H |
| L_{b887} | D | H | P21 | H | H | P2 | P23 | H |
| L_{b888} | D | H | P22 | H | H | P2 | P23 | H |
| L_{b889} | D | H | P23 | H | H | P2 | P23 | H |
| L_{b890} | D | H | P24 | H | H | P2 | P23 | H |
| L_{b891} | D | H | P25 | H | H | P2 | P23 | H |
| L_{b892} | D | H | P26 | H | H | P2 | P23 | H |
| L_{b893} | D | H | P27 | H | H | P2 | P23 | H |
| L_{b894} | D | H | P28 | H | H | P2 | P23 | H |
| L_{b895} | D | H | P29 | H | H | P2 | P23 | H |
| L_{b896} | D | H | P30 | H | H | P2 | P23 | H |
| L_{b897} | D | H | P31 | H | H | P2 | P23 | H |
| L_{b898} | D | H | P32 | H | H | P2 | P23 | H |
| L_{b899} | D | H | P33 | H | H | P2 | P23 | H |
| L_{b900} | D | H | P34 | H | H | P2 | P23 | H |
| L_{b901} | D | H | P35 | H | H | P2 | P23 | H |
| L_{b902} | D | H | P36 | H | H | P2 | P23 | H |
| L_{b903} | D | H | P37 | H | H | P2 | P23 | H |
| L_{b904} | D | H | P38 | H | H | P2 | P23 | H |
| L_{b905} | D | H | P39 | H | H | P2 | P23 | H |
| L_{b906} | D | H | P40 | H | H | P2 | P23 | H |
| L_{b907} | D | H | P41 | H | H | P2 | P23 | H |
| L_{b908} | D | H | P42 | H | H | P2 | P23 | H |
| L_{b909} | D | H | P43 | H | H | P2 | P23 | H |
| L₆₉₁₀ | D | H | P44 | H | H | P2 | P23 | H |
| L_{b911} | D | H | P45 | H | H | P2 | P23 | H |
| L_{b912} | D | H | P46 | H | H | P2 | P23 | H |
| L_{b913} | D | H | P47 | H | H | P2 | P23 | H |
| L_{b914} | D | H | P48 | H | H | P2 | P23 | H |
| L_{b915} | D | H | P49 | H | H | P2 | P23 | H |
| L_{b916} | D | H | P50 | H | H | P2 | P23 | H |
| L_{b917} | D | H | P51 | H | H | P2 | P23 | H |
| L_{b918} | D | H | P52 | H | H | P2 | P23 | H |
| L_{b919} | D | H | P53 | H | H | P2 | P23 | H |
| L_{b920} | D | H | P54 | H | H | P2 | P23 | H |
| L_{b921} | H | P1 | P1 | H | H | H | P23 | H |
| L_{b922} | H | P2 | P2 | H | H | H | P23 | H |
| L_{b923} | H | P1 | F | H | H | H | P23 | H |
| L_{b924} | H | P2 | F | H | H | H | P23 | H |
| L_{b925} | H | P1 | P3 | H | H | H | P23 | H |
| L_{b926} | H | P2 | P4 | H | H | H | P23 | H |
| L_{b927} | H | P1 | P1 | H | H | P1 | P23 | H |
| L_{b928} | H | P2 | P2 | H | H | P2 | P23 | H |
| L_{b929} | D | P2 | P2 | D | H | P2 | P23 | H |
| L_{b930} | H | P3 | P1 | H | H | P1 | P23 | H |
| L_{b931} | H | P8 | P1 | H | H | P1 | P23 | H |
| L_{b932} | H | P10 | P1 | H | H | P1 | P23 | H |
| L_{b933} | H | P4 | P2 | H | H | P2 | P23 | H |
| L_{b934} | H | P5 | P2 | H | H | P2 | P23 | H |
| L_{b935} | H | P9 | P2 | H | H | P2 | P23 | H |
| L_{b936} | H | P11 | P2 | H | H | P2 | P23 | H |
| L_{b937} | H | P13 | P2 | H | H | P2 | P23 | H |
| L_{b938} | H | P16 | P2 | H | H | P2 | P23 | H |
| L_{b939} | D | P5 | P2 | D | H | P2 | P23 | H |
| L_{b940} | D | P9 | P2 | D | H | P2 | P23 | H |
| L_{b941} | D | P11 | P2 | D | H | P2 | P23 | H |
| L_{b942} | H | H | H | H | H | H | P24 | H |
| L_{b943} | D | D | D | D | D | D | P24 | D |
| L_{b944} | H | P1 | H | H | H | H | P24 | H |
| L_{b945} | H | P2 | H | H | H | H | P24 | H |
| L_{b946} | H | P3 | H | H | H | H | P24 | H |
| L_{b947} | H | P4 | H | H | H | H | P24 | H |
| L_{b948} | H | P5 | H | H | H | H | P24 | H |
| L_{b949} | H | P6 | H | H | H | H | P24 | H |
| L_{b950} | H | P7 | H | H | H | H | P24 | H |
| L_{b951} | H | P8 | H | H | H | H | P24 | H |
| L_{b952} | H | P9 | H | H | H | H | P24 | H |
| L_{b953} | H | P10 | H | H | H | H | P24 | H |
| L_{b954} | H | P11 | H | H | H | H | P24 | H |
| L_{b955} | H | P12 | H | H | H | H | P24 | H |
| L_{b956} | H | P13 | H | H | H | H | P24 | H |
| L_{b957} | H | P14 | H | H | H | H | P24 | H |
| L_{b958} | H | P15 | H | H | H | H | P24 | H |
| L_{b959} | H | P16 | H | H | H | H | P24 | H |
| L_{b960} | H | P17 | H | H | H | H | P24 | H |
| L_{b961} | H | P18 | H | H | H | H | P24 | H |
| L_{b962} | H | P19 | H | H | H | H | P24 | H |
| L_{b963} | H | P20 | H | H | H | H | P24 | H |
| L_{b964} | H | P21 | H | H | H | H | P24 | H |
| L_{b965} | H | P22 | H | H | H | H | P24 | H |
| L_{b966} | H | P23 | H | H | H | H | P24 | H |
| L_{b967} | H | P24 | H | H | H | H | P24 | H |
| L_{b968} | H | P25 | H | H | H | H | P24 | H |
| L_{b969} | H | P26 | H | H | H | H | P24 | H |
| L_{b970} | H | P27 | H | H | H | H | P24 | H |
| L_{b971} | H | P28 | H | H | H | H | P24 | H |
| L_{b972} | H | P29 | H | H | H | H | P24 | H |
| L_{b973} | H | P30 | H | H | H | H | P24 | H |
| L_{b974} | H | P31 | H | H | H | H | P24 | H |
| L_{b975} | H | P32 | H | H | H | H | P24 | H |
| L_{b976} | H | P33 | H | H | H | H | P24 | H |
| L_{b977} | H | P34 | H | H | H | H | P24 | H |
| L_{b978} | H | P35 | H | H | H | H | P24 | H |
| L_{b979} | H | P36 | H | H | H | H | P24 | H |
| L_{b980} | H | P37 | H | H | H | H | P24 | H |
| L_{b981} | H | P38 | H | H | H | H | P24 | H |
| L_{b982} | H | P39 | H | H | H | H | P24 | H |
| L_{b983} | H | P40 | H | H | H | H | P24 | H |
| L_{b984} | H | P41 | H | H | H | H | P24 | H |
| L_{b985} | H | P42 | H | H | H | H | P24 | H |
| L_{b986} | H | P43 | H | H | H | H | P24 | H |
| L_{b987} | H | P44 | H | H | H | H | P24 | H |
| L_{b988} | H | P45 | H | H | H | H | P24 | H |
| L_{b989} | H | P46 | H | H | H | H | P24 | H |
| L_{b990} | H | P47 | H | H | H | H | P24 | H |
| L_{b991} | H | P48 | H | H | H | H | P24 | H |
| L_{b992} | H | P49 | H | H | H | H | P24 | H |
| L_{b993} | H | P50 | H | H | H | H | P24 | H |
| L_{b994} | H | P51 | H | H | H | H | P24 | H |
| L_{b995} | H | P52 | H | H | H | H | P24 | H |
| L_{b996} | H | P53 | H | H | H | H | P24 | H |
| L_{b997} | H | P54 | H | H | H | H | P24 | H |
| L_{b998} | H | H | P1 | H | H | H | P24 | H |
| L_{b999} | H | H | P2 | H | H | H | P24 | H |
| L_{b1000} | H | H | P3 | H | H | H | P24 | H |
| L_{b1001} | H | H | P4 | H | H | H | P24 | H |
| L_{b1002} | H | H | P5 | H | H | H | P24 | H |
| L_{b1003} | H | H | P6 | H | H | H | P24 | H |
| L_{b1004} | H | H | P7 | H | H | H | P24 | H |
| L_{b1005} | H | H | P8 | H | H | H | P24 | H |
| L_{b1006} | H | H | P9 | H | H | H | P24 | H |
| L_{b1007} | H | H | P10 | H | H | H | P24 | H |
| L_{b1008} | H | H | P11 | H | H | H | P24 | H |
| L_{b1009} | H | H | P12 | H | H | H | P24 | H |
| L_{b1010} | H | H | P13 | H | H | H | P24 | H |
| L_{b1011} | H | H | P14 | H | H | H | P24 | H |
| L_{b1012} | H | H | P15 | H | H | H | P24 | H |
| L_{b1013} | H | H | P16 | H | H | H | P24 | H |
| L_{b1014} | H | H | P17 | H | H | H | P24 | H |
| L_{b1015} | H | H | P18 | H | H | H | P24 | H |
| L_{b1016} | H | H | P19 | H | H | H | P24 | H |
| L_{b1017} | H | H | P20 | H | H | H | P24 | H |
| L_{b1018} | H | H | P21 | H | H | H | P24 | H |
| L_{b1019} | H | H | P22 | H | H | H | P24 | H |
| L_{b1020} | H | H | P23 | H | H | H | P24 | H |
| L_{b1021} | H | H | P24 | H | H | H | P24 | H |
| L_{b1022} | H | H | P25 | H | H | H | P24 | H |
| L_{b1023} | H | H | P26 | H | H | H | P24 | H |
| L_{b1024} | H | H | P27 | H | H | H | P24 | H |
| L_{b1025} | H | H | P28 | H | H | H | P24 | H |
| L_{b1026} | H | H | P29 | H | H | H | P24 | H |
| L_{b1027} | H | H | P30 | H | H | H | P24 | H |
| L_{b1028} | H | H | P31 | H | H | H | P24 | H |
| L_{b1029} | H | H | P32 | H | H | H | P24 | H |
| L_{b1030} | H | H | P33 | H | H | H | P24 | H |
| L_{b1031} | H | H | P34 | H | H | H | P24 | H |
| L_{b1032} | H | H | P35 | H | H | H | P24 | H |
| L_{b1033} | H | H | P36 | H | H | H | P24 | H |
| L_{b1034} | H | H | P37 | H | H | H | P24 | H |
| L_{b1035} | H | H | P38 | H | H | H | P24 | H |
| L_{b1036} | H | H | P39 | H | H | H | P24 | H |
| L_{b1037} | H | H | P40 | H | H | H | P24 | H |
| L_{b1038} | H | H | P41 | H | H | H | P24 | H |
| L_{b1039} | H | H | P42 | H | H | H | P24 | H |
| L_{b1040} | H | H | P43 | H | H | H | P24 | H |
| L_{b1041} | H | H | P44 | H | H | H | P24 | H |
| L_{b1042} | H | H | P45 | H | H | H | P24 | H |
| L_{b1043} | H | H | P46 | H | H | H | P24 | H |
| L_{b1044} | H | H | P47 | H | H | H | P24 | H |
| L_{b1045} | H | H | P48 | H | H | H | P24 | H |
| L_{b1046} | H | H | P49 | H | H | H | P24 | H |
| L_{b1047} | H | H | P50 | H | H | H | P24 | H |
| L_{b1048} | H | H | P51 | H | H | H | P24 | H |
| L_{b1049} | H | H | P52 | H | H | H | P24 | H |
| L_{b1050} | H | H | P53 | H | H | H | P24 | H |
| L_{b1051} | H | H | P54 | H | H | H | P24 | H |
| L_{b1052} | H | P1 | H | H | H | P1 | P24 | H |
| L_{b1053} | H | P2 | H | H | H | P1 | P24 | H |
| L_{b1054} | H | P3 | H | H | H | P1 | P24 | H |
| L_{b1055} | H | P4 | H | H | H | P1 | P24 | H |
| L_{b1056} | H | P5 | H | H | H | P1 | P24 | H |
| L_{b1057} | H | P6 | H | H | H | P1 | P24 | H |
| L_{b1058} | H | P7 | H | H | H | P1 | P24 | H |
| L_{b1059} | H | P8 | H | H | H | P1 | P24 | H |
| L_{b1060} | H | P9 | H | H | H | P1 | P24 | H |
| L_{b1061} | H | P10 | H | H | H | P1 | P24 | H |
| L_{b1062} | H | P11 | H | H | H | P1 | P24 | H |
| L_{b1063} | H | P12 | H | H | H | P1 | P24 | H |
| L_{b1064} | H | P13 | H | H | H | P1 | P24 | H |
| L_{b1065} | H | P14 | H | H | H | P1 | P24 | H |
| L_{b1066} | H | P15 | H | H | H | P1 | P24 | H |
| L_{b1067} | H | P16 | H | H | H | P1 | P24 | H |
| L_{b1068} | H | P17 | H | H | H | P1 | P24 | H |
| L_{b1069} | H | P18 | H | H | H | P1 | P24 | H |
| L_{b1070} | H | P19 | H | H | H | P1 | P24 | H |
| L_{b1071} | H | P20 | H | H | H | P1 | P24 | H |
| L_{b1072} | H | P21 | H | H | H | P1 | P24 | H |
| L_{b1073} | H | P22 | H | H | H | P1 | P24 | H |
| L_{b1074} | H | P23 | H | H | H | P1 | P24 | H |
| L_{b1075} | H | P24 | H | H | H | P1 | P24 | H |
| L_{b1076} | H | P25 | H | H | H | P1 | P24 | H |
| L_{b1077} | H | P26 | H | H | H | P1 | P24 | H |
| L_{b1078} | H | P27 | H | H | H | P1 | P24 | H |
| L_{b1079} | H | P28 | H | H | H | P1 | P24 | H |
| L_{b1080} | H | P29 | H | H | H | P1 | P24 | H |
| L_{b1081} | H | P30 | H | H | H | P1 | P24 | H |
| L_{b1082} | H | P31 | H | H | H | P1 | P24 | H |
| L_{b1083} | H | P32 | H | H | H | P1 | P24 | H |
| L_{b1084} | H | P33 | H | H | H | P1 | P24 | H |
| L_{b1085} | H | P34 | H | H | H | P1 | P24 | H |
| L_{b1086} | H | P35 | H | H | H | P1 | P24 | H |
| L_{b1087} | H | P36 | H | H | H | P1 | P24 | H |
| L_{b1088} | H | P37 | H | H | H | P1 | P24 | H |
| L_{b1089} | H | P38 | H | H | H | P1 | P24 | H |
| L_{b1090} | H | P39 | H | H | H | P1 | P24 | H |
| L_{b1091} | H | P40 | H | H | H | P1 | P24 | H |
| L_{b1092} | H | P41 | H | H | H | P1 | P24 | H |
| L_{b1093} | H | P42 | H | H | H | P1 | P24 | H |
| L_{b1094} | H | P43 | H | H | H | P1 | P24 | H |
| L_{b1095} | H | P44 | H | H | H | P1 | P24 | H |
| L_{b1096} | H | P45 | H | H | H | P1 | P24 | H |
| L_{b1097} | H | P46 | H | H | H | P1 | P24 | H |
| L_{b1098} | H | P47 | H | H | H | P1 | P24 | H |
| L_{b1099} | H | P48 | H | H | H | P1 | P24 | H |
| L_{b1100} | H | P49 | H | H | H | P1 | P24 | H |
| L_{b1101} | H | P50 | H | H | H | P1 | P24 | H |
| L_{b1102} | H | P51 | H | H | H | P1 | P24 | H |
| L_{b1103} | H | P52 | H | H | H | P1 | P24 | H |
| L_{b1104} | H | P53 | H | H | H | P1 | P24 | H |
| L_{b1105} | H | P54 | H | H | H | P1 | P24 | H |
| L_{b1106} | H | H | P1 | H | H | P1 | P24 | H |
| L_{b1107} | H | H | P2 | H | H | P1 | P24 | H |
| L_{b1108} | H | H | P3 | H | H | P1 | P24 | H |
| L_{b1109} | H | H | P4 | H | H | P1 | P24 | H |
| L_{b1110} | H | H | P5 | H | H | P1 | P24 | H |
| L_{b1111} | H | H | P6 | H | H | P1 | P24 | H |
| L_{b1112} | H | H | P7 | H | H | P1 | P24 | H |
| L_{b1113} | H | H | P8 | H | H | P1 | P24 | H |
| L_{b1114} | H | H | P9 | H | H | P1 | P24 | H |
| L_{b1115} | H | H | P10 | H | H | P1 | P24 | H |
| L_{b1116} | H | H | P11 | H | H | P1 | P24 | H |
| L_{b1117} | H | H | P12 | H | H | P1 | P24 | H |
| L_{b1118} | H | H | P13 | H | H | P1 | P24 | H |
| L_{b1119} | H | H | P14 | H | H | P1 | P24 | H |
| L_{b1120} | H | H | P15 | H | H | P1 | P24 | H |
| L_{b1121} | H | H | P16 | H | H | P1 | P24 | H |
| L_{b1122} | H | H | P17 | H | H | P1 | P24 | H |
| L_{b1123} | H | H | P18 | H | H | P1 | P24 | H |
| L_{b1124} | H | H | P19 | H | H | P1 | P24 | H |
| L_{b1125} | H | H | P20 | H | H | P1 | P24 | H |
| L_{b1126} | H | H | P21 | H | H | P1 | P24 | H |
| L_{b1127} | H | H | P22 | H | H | P1 | P24 | H |
| L_{b1128} | H | H | P23 | H | H | P1 | P24 | H |
| L_{b1129} | H | H | P24 | H | H | P1 | P24 | H |
| L_{b1130} | H | H | P25 | H | H | P1 | P24 | H |
| L_{b1131} | H | H | P26 | H | H | P1 | P24 | H |
| L_{b1132} | H | H | P27 | H | H | P1 | P24 | H |
| L_{b1133} | H | H | P28 | H | H | P1 | P24 | H |
| L_{b1134} | H | H | P29 | H | H | P1 | P24 | H |
| L_{b1135} | H | H | P30 | H | H | P1 | P24 | H |
| L_{b1136} | H | H | P31 | H | H | P1 | P24 | H |
| L_{b1137} | H | H | P32 | H | H | P1 | P24 | H |
| L_{b1138} | H | H | P33 | H | H | P1 | P24 | H |
| L_{b1139} | H | H | P34 | H | H | P1 | P24 | H |
| L_{b1140} | H | H | P35 | H | H | P1 | P24 | H |
| L_{b1141} | H | H | P36 | H | H | P1 | P24 | H |
| L_{b1142} | H | H | P37 | H | H | P1 | P24 | H |
| L_{b1143} | H | H | P38 | H | H | P1 | P24 | H |
| L_{b1144} | H | H | P39 | H | H | P1 | P24 | H |
| L_{b1145} | H | H | P40 | H | H | P1 | P24 | H |
| L_{b1146} | H | H | P41 | H | H | P1 | P24 | H |
| L_{b1147} | H | H | P42 | H | H | P1 | P24 | H |
| L_{b1148} | H | H | P43 | H | H | P1 | P24 | H |
| L_{b1149} | H | H | P44 | H | H | P1 | P24 | H |
| L_{b1150} | H | H | P45 | H | H | P1 | P24 | H |
| L_{b1151} | H | H | P46 | H | H | P1 | P24 | H |
| L_{b1152} | H | H | P47 | H | H | P1 | P24 | H |
| L_{b1153} | H | H | P48 | H | H | P1 | P24 | H |
| L_{b1154} | H | H | P49 | H | H | P1 | P24 | H |
| L_{b1155} | H | H | P50 | H | H | P1 | P24 | H |
| L_{b1156} | H | H | P51 | H | H | P1 | P24 | H |
| L_{b1157} | H | H | P52 | H | H | P1 | P24 | H |
| L_{b1158} | H | H | P53 | H | H | P1 | P24 | H |
| L_{b1159} | H | H | P54 | H | H | P1 | P24 | H |
| L_{b1160} | H | P1 | H | H | H | P2 | P24 | H |
| L_{b1161} | H | P2 | H | H | H | P2 | P24 | H |
| L_{b1162} | H | P3 | H | H | H | P2 | P24 | H |
| L_{b1163} | H | P4 | H | H | H | P2 | P24 | H |
| L_{b1164} | H | P5 | H | H | H | P2 | P24 | H |
| L_{b1165} | H | P6 | H | H | H | P2 | P24 | H |
| L_{b1166} | H | P7 | H | H | H | P2 | P24 | H |
| L_{b1167} | H | P8 | H | H | H | P2 | P24 | H |
| L_{b1168} | H | P9 | H | H | H | P2 | P24 | H |
| L_{b1169} | H | P10 | H | H | H | P2 | P24 | H |
| L_{b1170} | H | P11 | H | H | H | P2 | P24 | H |
| L_{b1171} | H | P12 | H | H | H | P2 | P24 | H |
| L_{b1172} | H | P13 | H | H | H | P2 | P24 | H |
| L_{b1173} | H | P14 | H | H | H | P2 | P24 | H |
| L_{b1174} | H | P15 | H | H | H | P2 | P24 | H |
| L_{b1175} | H | P16 | H | H | H | P2 | P24 | H |
| L_{b1176} | H | P17 | H | H | H | P2 | P24 | H |
| L_{b1177} | H | P18 | H | H | H | P2 | P24 | H |
| L_{b1178} | H | P19 | H | H | H | P2 | P24 | H |
| L_{b1179} | H | P20 | H | H | H | P2 | P24 | H |
| L_{b1180} | H | P21 | H | H | H | P2 | P24 | H |
| L_{b1181} | H | P22 | H | H | H | P2 | P24 | H |
| L_{b1182} | H | P23 | H | H | H | P2 | P24 | H |
| L_{b1183} | H | P24 | H | H | H | P2 | P24 | H |
| L_{b1184} | H | P25 | H | H | H | P2 | P24 | H |
| L_{b1185} | H | P26 | H | H | H | P2 | P24 | H |
| L_{b1186} | H | P27 | H | H | H | P2 | P24 | H |
| L_{b1187} | H | P28 | H | H | H | P2 | P24 | H |
| L_{b1188} | H | P29 | H | H | H | P2 | P24 | H |
| L_{b1189} | H | P30 | H | H | H | P2 | P24 | H |
| L_{b1190} | H | P31 | H | H | H | P2 | P24 | H |
| L_{b1191} | H | P32 | H | H | H | P2 | P24 | H |
| L_{b1192} | H | P33 | H | H | H | P2 | P24 | H |
| L_{b1193} | H | P34 | H | H | H | P2 | P24 | H |
| L_{b1194} | H | P35 | H | H | H | P2 | P24 | H |
| L_{b1195} | H | P36 | H | H | H | P2 | P24 | H |
| L_{b1196} | H | P37 | H | H | H | P2 | P24 | H |
| L_{b1197} | H | P38 | H | H | H | P2 | P24 | H |
| L_{b1198} | H | P39 | H | H | H | P2 | P24 | H |
| L_{b1199} | H | P40 | H | H | H | P2 | P24 | H |
| L_{b1200} | H | P41 | H | H | H | P2 | P24 | H |
| L_{b1201} | H | P42 | H | H | H | P2 | P24 | H |
| L_{b1202} | H | P43 | H | H | H | P2 | P24 | H |
| L_{b1203} | H | P44 | H | H | H | P2 | P24 | H |
| L_{b1204} | H | P45 | H | H | H | P2 | P24 | H |
| L_{b1205} | H | P46 | H | H | H | P2 | P24 | H |
| L_{b1206} | H | P47 | H | H | H | P2 | P24 | H |
| L_{b1207} | H | P48 | H | H | H | P2 | P24 | H |
| L_{b1208} | H | P49 | H | H | H | P2 | P24 | H |
| L_{b1209} | H | P50 | H | H | H | P2 | P24 | H |
| L_{b1210} | H | P51 | H | H | H | P2 | P24 | H |
| L_{b1211} | H | P52 | H | H | H | P2 | P24 | H |
| L_{b1212} | H | P53 | H | H | H | P2 | P24 | H |
| L_{b1213} | H | P54 | H | H | H | P2 | P24 | H |
| L_{b1214} | H | H | P1 | H | H | P2 | P24 | H |
| L_{b1215} | H | H | P2 | H | H | P2 | P24 | H |
| L_{b1216} | H | H | P3 | H | H | P2 | P24 | H |
| L_{b1217} | H | H | P4 | H | H | P2 | P24 | H |
| L_{b1218} | H | H | P5 | H | H | P2 | P24 | H |
| L_{b1219} | H | H | P6 | H | H | P2 | P24 | H |
| L_{b1220} | H | H | P7 | H | H | P2 | P24 | H |
| L_{b1221} | H | H | P8 | H | H | P2 | P24 | H |
| L_{b1222} | H | H | P9 | H | H | P2 | P24 | H |
| L_{b1223} | H | H | P10 | H | H | P2 | P24 | H |
| L_{b1224} | H | H | P11 | H | H | P2 | P24 | H |
| L_{b1225} | H | H | P12 | H | H | P2 | P24 | H |
| L_{b1226} | H | H | P13 | H | H | P2 | P24 | H |
| L_{b1227} | H | H | P14 | H | H | P2 | P24 | H |
| L_{b1228} | H | H | P15 | H | H | P2 | P24 | H |
| L_{b1229} | H | H | P16 | H | H | P2 | P24 | H |
| L_{b1230} | H | H | P17 | H | H | P2 | P24 | H |
| L_{b1231} | H | H | P18 | H | H | P2 | P24 | H |
| L_{b1232} | H | H | P19 | H | H | P2 | P24 | H |
| L_{b1233} | H | H | P20 | H | H | P2 | P24 | H |
| L_{b1234} | H | H | P21 | H | H | P2 | P24 | H |
| L_{b1235} | H | H | P22 | H | H | P2 | P24 | H |
| L_{b1236} | H | H | P23 | H | H | P2 | P24 | H |
| L_{b1237} | H | H | P24 | H | H | P2 | P24 | H |
| L_{b1238} | H | H | P25 | H | H | P2 | P24 | H |
| L_{b1239} | H | H | P26 | H | H | P2 | P24 | H |
| L_{b1240} | H | H | P27 | H | H | P2 | P24 | H |
| L_{b1241} | H | H | P28 | H | H | P2 | P24 | H |
| L_{b1242} | H | H | P29 | H | H | P2 | P24 | H |
| L_{b1243} | H | H | P30 | H | H | P2 | P24 | H |
| L_{b1244} | H | H | P31 | H | H | P2 | P24 | H |
| L_{b1245} | H | H | P32 | H | H | P2 | P24 | H |
| L_{b1246} | H | H | P33 | H | H | P2 | P24 | H |
| L_{b1247} | H | H | P34 | H | H | P2 | P24 | H |
| L_{b1248} | H | H | P35 | H | H | P2 | P24 | H |
| L_{b1249} | H | H | P36 | H | H | P2 | P24 | H |
| L_{b1250} | H | H | P37 | H | H | P2 | P24 | H |
| L_{b1251} | H | H | P38 | H | H | P2 | P24 | H |
| L_{b1252} | H | H | P39 | H | H | P2 | P24 | H |
| L_{b1253} | H | H | P40 | H | H | P2 | P24 | H |
| L_{b1254} | H | H | P41 | H | H | P2 | P24 | H |
| L_{b1255} | H | H | P42 | H | H | P2 | P24 | H |
| L_{b1256} | H | H | P43 | H | H | P2 | P24 | H |
| L_{b1257} | H | H | P44 | H | H | P2 | P24 | H |
| L_{b1258} | H | H | P45 | H | H | P2 | P24 | H |
| L_{b1259} | H | H | P46 | H | H | P2 | P24 | H |
| L_{b1260} | H | H | P47 | H | H | P2 | P24 | H |
| L_{b1261} | H | H | P48 | H | H | P2 | P24 | H |
| L_{b1262} | H | H | P49 | H | H | P2 | P24 | H |
| L_{b1263} | H | H | P50 | H | H | P2 | P24 | H |
| L_{b1264} | H | H | P51 | H | H | P2 | P24 | H |
| L_{b1265} | H | H | P52 | H | H | P2 | P24 | H |
| L_{b1266} | H | H | P53 | H | H | P2 | P24 | H |
| L_{b1267} | H | H | P54 | H | H | P2 | P24 | H |
| L_{b1268} | D | P1 | H | H | H | P2 | P24 | H |
| L_{b1269} | D | P2 | H | H | H | P2 | P24 | H |
| L_{b1270} | D | P3 | H | H | H | P2 | P24 | H |
| L_{b1271} | D | P4 | H | H | H | P2 | P24 | H |
| L_{b1272} | D | P5 | H | H | H | P2 | P24 | H |
| L_{b1273} | D | P6 | H | H | H | P2 | P24 | H |
| L_{b1274} | D | P7 | H | H | H | P2 | P24 | H |
| L_{b1275} | D | P8 | H | H | H | P2 | P24 | H |
| L_{b1276} | D | P9 | H | H | H | P2 | P24 | H |
| L_{b1277} | D | P10 | H | H | H | P2 | P24 | H |
| L_{b1278} | D | P11 | H | H | H | P2 | P24 | H |
| L_{b1279} | D | P12 | H | H | H | P2 | P24 | H |
| L_{b1280} | D | P13 | H | H | H | P2 | P24 | H |
| L_{b1281} | D | P14 | H | H | H | P2 | P24 | H |
| L_{b1282} | D | P15 | H | H | H | P2 | P24 | H |
| L_{b1283} | D | P16 | H | H | H | P2 | P24 | H |
| L_{b1284} | D | P17 | H | H | H | P2 | P24 | H |
| L_{b1285} | D | P18 | H | H | H | P2 | P24 | H |
| L_{b1286} | D | P19 | H | H | H | P2 | P24 | H |
| L_{b1287} | D | P20 | H | H | H | P2 | P24 | H |
| L_{b1288} | D | P21 | H | H | H | P2 | P24 | H |
| L_{b1289} | D | P22 | H | H | H | P2 | P24 | H |
| L_{b1290} | D | P23 | H | H | H | P2 | P24 | H |
| L_{b1291} | D | P24 | H | H | H | P2 | P24 | H |
| L_{b1292} | D | P25 | H | H | H | P2 | P24 | H |
| L_{b1293} | D | P26 | H | H | H | P2 | P24 | H |
| L_{b1294} | D | P27 | H | H | H | P2 | P24 | H |
| L_{b1295} | D | P28 | H | H | H | P2 | P24 | H |
| L_{b1296} | D | P29 | H | H | H | P2 | P24 | H |
| L_{b1297} | D | P30 | H | H | H | P2 | P24 | H |
| L_{b1298} | D | P31 | H | H | H | P2 | P24 | H |
| L_{b1299} | D | P32 | H | H | H | P2 | P24 | H |
| L_{b1300} | D | P33 | H | H | H | P2 | P24 | H |
| L_{b1301} | D | P34 | H | H | H | P2 | P24 | H |
| L_{b1302} | D | P35 | H | H | H | P2 | P24 | H |
| L_{b1303} | D | P36 | H | H | H | P2 | P24 | H |
| L_{b1304} | D | P37 | H | H | H | P2 | P24 | H |
| L_{b1305} | D | P38 | H | H | H | P2 | P24 | H |
| L_{b1306} | D | P39 | H | H | H | P2 | P24 | H |
| L_{b1307} | D | P40 | H | H | H | P2 | P24 | H |
| L_{b1308} | D | P41 | H | H | H | P2 | P24 | H |
| L_{b1309} | D | P42 | H | H | H | P2 | P24 | H |
| L_{b1310} | D | P43 | H | H | H | P2 | P24 | H |
| L_{b1311} | D | P44 | H | H | H | P2 | P24 | H |
| L_{b1312} | D | P45 | H | H | H | P2 | P24 | H |
| L_{b1313} | D | P46 | H | H | H | P2 | P24 | H |
| L_{b1314} | D | P47 | H | H | H | P2 | P24 | H |
| L_{b1315} | D | P48 | H | H | H | P2 | P24 | H |
| L_{b1316} | D | P49 | H | H | H | P2 | P24 | H |
| L_{b1317} | D | P50 | H | H | H | P2 | P24 | H |
| L_{b1318} | D | P51 | H | H | H | P2 | P24 | H |
| L_{b1319} | D | P52 | H | H | H | P2 | P24 | H |
| L_{b1320} | D | P53 | H | H | H | P2 | P24 | H |
| L_{b1321} | D | P54 | H | H | H | P2 | P24 | H |
| L_{b1322} | D | H | P1 | H | H | P2 | P24 | H |
| L_{b1323} | D | H | P2 | H | H | P2 | P24 | H |
| L_{b1324} | D | H | P3 | H | H | P2 | P24 | H |
| L_{b1325} | D | H | P4 | H | H | P2 | P24 | H |
| L_{b1326} | D | H | P5 | H | H | P2 | P24 | H |
| L_{b1327} | D | H | P6 | H | H | P2 | P24 | H |
| L_{b1328} | D | H | P7 | H | H | P2 | P24 | H |
| L_{b1329} | D | H | P8 | H | H | P2 | P24 | H |
| L_{b1330} | D | H | P9 | H | H | P2 | P24 | H |
| L_{b1331} | D | H | P10 | H | H | P2 | P24 | H |
| L_{b1332} | D | H | P11 | H | H | P2 | P24 | H |
| L_{b1333} | D | H | P12 | H | H | P2 | P24 | H |
| L_{b1334} | D | H | P13 | H | H | P2 | P24 | H |
| L_{b1335} | D | H | P14 | H | H | P2 | P24 | H |
| L_{b1336} | D | H | P15 | H | H | P2 | P24 | H |
| L_{b1337} | D | H | P16 | H | H | P2 | P24 | H |
| L_{b1338} | D | H | P17 | H | H | P2 | P24 | H |
| L_{b1339} | D | H | P18 | H | H | P2 | P24 | H |
| L_{b1340} | D | H | P19 | H | H | P2 | P24 | H |
| L_{b1341} | D | H | P20 | H | H | P2 | P24 | H |
| L_{b1342} | D | H | P21 | H | H | P2 | P24 | H |
| L_{b1343} | D | H | P22 | H | H | P2 | P24 | H |
| L_{b1344} | D | H | P23 | H | H | P2 | P24 | H |
| L_{b1345} | D | H | P24 | H | H | P2 | P24 | H |
| L_{b1346} | D | H | P25 | H | H | P2 | P24 | H |
| L_{b1347} | D | H | P26 | H | H | P2 | P24 | H |
| L_{b1348} | D | H | P27 | H | H | P2 | P24 | H |
| L_{b1349} | D | H | P28 | H | H | P2 | P24 | H |
| L_{b1350} | D | H | P29 | H | H | P2 | P24 | H |
| L_{b1351} | D | H | P30 | H | H | P2 | P24 | H |
| L_{b1352} | D | H | P31 | H | H | P2 | P24 | H |
| L_{b1353} | D | H | P32 | H | H | P2 | P24 | H |
| L_{b1354} | D | H | P33 | H | H | P2 | P24 | H |
| L_{b1355} | D | H | P34 | H | H | P2 | P24 | H |
| L_{b1356} | D | H | P35 | H | H | P2 | P24 | H |
| L_{b1357} | D | H | P36 | H | H | P2 | P24 | H |
| L_{b1358} | D | H | P37 | H | H | P2 | P24 | H |
| L_{b1359} | D | H | P38 | H | H | P2 | P24 | H |
| L_{b1360} | D | H | P39 | H | H | P2 | P24 | H |
| L_{b1361} | D | H | P40 | H | H | P2 | P24 | H |
| L_{b1362} | D | H | P41 | H | H | P2 | P24 | H |
| L_{b1363} | D | H | P42 | H | H | P2 | P24 | H |
| L_{b1364} | D | H | P43 | H | H | P2 | P24 | H |
| L_{b1365} | D | H | P44 | H | H | P2 | P24 | H |
| L_{b1366} | D | H | P45 | H | H | P2 | P24 | H |
| L_{b1367} | D | H | P46 | H | H | P2 | P24 | H |
| L_{b1368} | D | H | P47 | H | H | P2 | P24 | H |
| L_{b1369} | D | H | P48 | H | H | P2 | P24 | H |
| L_{b1370} | D | H | P49 | H | H | P2 | P24 | H |
| L_{b1371} | D | H | P50 | H | H | P2 | P24 | H |
| L_{b1372} | D | H | P51 | H | H | P2 | P24 | H |
| L_{b1373} | D | H | P52 | H | H | P2 | P24 | H |
| L_{b1374} | D | H | P53 | H | H | P2 | P24 | H |
| L_{b1375} | D | H | P54 | H | H | P2 | P24 | H |
| L_{b1376} | H | P1 | P1 | H | H | P1 | P24 | H |
| L_{b1377} | H | P2 | P2 | H | H | P2 | P24 | H |
| L_{b1378} | D | P2 | P2 | D | H | P2 | P24 | H |
| L_{b1379} | H | P3 | P1 | H | H | P1 | P24 | H |
| L_{b1380} | H | P8 | P1 | H | H | P1 | P24 | H |
| L_{b1381} | H | P10 | P1 | H | H | P1 | P24 | H |
| L_{b1382} | H | P4 | P2 | H | H | P2 | P24 | H |
| L_{b1383} | H | P5 | P2 | H | H | P2 | P24 | H |
| L_{b1384} | H | P9 | P2 | H | H | P2 | P24 | H |
| L_{b1385} | H | P11 | P2 | H | H | P2 | P24 | H |
| L_{b1386} | H | P13 | P2 | H | H | P2 | P24 | H |
| L_{b1387} | H | P16 | P2 | H | H | P2 | P24 | H |
| L_{b1388} | D | P5 | P2 | D | H | P2 | P24 | H |
| L_{b1389} | D | P9 | P2 | D | H | P2 | P24 | H |
| L_{b1390} | D | P11 | P2 | D | H | P2 | P24 | H |
| L_{b1391} | H | P1 | P1 | H | H | H | P24 | H |
| L_{b1392} | H | P2 | P2 | H | H | H | P24 | H |
| L_{b1393} | H | P1 | F | H | H | H | P24 | H |
| L_{b1394} | H | P2 | F | H | H | H | P24 | H |
| L_{b1395} | H | P1 | P3 | H | H | H | P24 | H |
| L_{b1396} | H | P2 | P4 | H | H | H | P24 | H |
| L_{b1397} | H | H | H | H | H | P23 | H | H |
| L_{b1398} | H | P1 | H | H | H | P23 | H | H |
| L_{b1399} | H | P2 | H | H | H | P23 | H | H |
| L_{b1400} | H | P3 | H | H | H | P23 | H | H |
| L_{b1401} | H | P4 | H | H | H | P23 | H | H |
| L_{b1402} | H | P5 | H | H | H | P23 | H | H |
| L_{b1403} | H | P6 | H | H | H | P23 | H | H |
| L_{b1404} | H | P7 | H | H | H | P23 | H | H |
| L_{b1405} | H | P8 | H | H | H | P23 | H | H |
| L_{b1406} | H | P9 | H | H | H | P23 | H | H |
| L_{b1407} | H | P10 | H | H | H | P23 | H | H |
| L_{b1408} | H | P11 | H | H | H | P23 | H | H |
| L_{b1409} | H | H | P1 | H | H | P23 | H | H |
| L_{b1410} | H | H | P2 | H | H | P23 | H | H |
| L_{b1411} | H | H | P3 | H | H | P23 | H | H |
| L_{b1412} | H | H | P4 | H | H | P23 | H | H |
| L_{b1413} | H | H | P5 | H | H | P23 | H | H |
| L_{b1414} | H | H | P6 | H | H | P23 | H | H |
| L_{b1415} | H | H | P7 | H | H | P23 | H | H |
| L_{b1416} | H | H | P8 | H | H | P23 | H | H |
| L_{b1417} | H | H | P9 | H | H | P23 | H | H |
| L_{b1418} | H | H | P10 | H | H | P23 | H | H |
| L_{b1419} | H | H | P11 | H | H | P23 | H | H |
| L_{b1420} | H | P1 | P1 | H | H | P23 | H | H |
| L_{b1421} | H | P2 | P2 | H | H | P23 | H | H |
| L_{b1422} | H | H | H | H | H | P24 | H | H |
| L_{b1423} | H | P1 | H | H | H | P24 | H | H |
| L_{b1424} | H | P2 | H | H | H | P24 | H | H |
| L_{b1425} | H | P3 | H | H | H | P24 | H | H |
| L_{b1426} | H | P4 | H | H | H | P24 | H | H |
| L_{b1427} | H | P5 | H | H | H | P24 | H | H |
| L_{b1428} | H | P6 | H | H | H | P24 | H | H |
| L_{b1429} | H | P7 | H | H | H | P24 | H | H |
| L_{b1430} | H | P8 | H | H | H | P24 | H | H |
| L_{b1431} | H | P9 | H | H | H | P24 | H | H |
| L_{b1432} | H | P10 | H | H | H | P24 | H | H |
| L_{b1433} | H | P11 | H | H | H | P24 | H | H |
| L_{b1434} | H | H | P1 | H | H | P24 | H | H |
| L_{b1435} | H | H | P2 | H | H | P24 | H | H |
| L_{b1436} | H | H | P3 | H | H | P24 | H | H |
| L_{b1437} | H | H | P4 | H | H | P24 | H | H |
| L_{b1438} | H | H | P5 | H | H | P24 | H | H |
| L_{b1439} | H | H | P6 | H | H | P24 | H | H |
| L_{b1440} | H | H | P7 | H | H | P24 | H | H |
| L_{b1441} | H | H | P8 | H | H | P24 | H | H |
| L_{b1442} | H | H | P9 | H | H | P24 | H | H |
| L_{b1443} | H | H | P10 | H | H | P24 | H | H |
| L_{b1444} | H | H | P11 | H | H | P24 | H | H |
| L_{b1445} | H | P1 | P1 | H | H | P24 | H | H |
| L_{b1446} | H | P2 | P2 | H | H | P24 | H | H |
| L_{b1447} | H | P2 | H | H | H | H | P25 | H |
| L_{b1448} | H | P2 | H | H | H | H | P26 | H |
| L_{b1449} | H | P2 | H | H | H | H | P27 | H |
| L_{b1450} | H | P2 | H | H | H | H | P28 | H |
| L_{b1451} | H | P2 | H | H | H | H | P29 | H |
| L_{b1452} | H | P2 | H | H | H | H | P30 | H |
| L_{b1453} | H | P2 | H | H | H | H | P31 | H |
| L_{b1454} | H | P2 | H | H | H | H | P32 | H |
| L_{b1455} | H | P2 | H | H | H | H | P33 | H |
| L_{b1456} | H | P2 | H | H | H | H | P34 | H |
| L_{b1457} | H | P2 | H | H | H | H | P35 | H |
| L_{b1458} | H | P2 | H | H | H | H | P36 | H |
| L_{b1459} | H | P2 | H | H | H | H | P37 | H |
| L_{b1460} | H | P2 | H | H | H | H | P38 | H |
| L_{b1461} | H | P2 | H | H | H | H | P39 | H |
| L_{b1462} | H | P2 | H | H | H | H | P40 | H |
| L_{b1463} | H | P2 | H | H | H | H | P41 | H |
| L_{b1464} | H | P2 | H | H | H | H | P42 | H |
| L_{b1465} | H | P2 | H | H | H | H | P43 | H |
| L_{b1466} | H | P2 | H | H | H | H | P44 | H |
| L_{b1467} | H | P2 | H | H | H | H | P45 | H |
| L_{b1468} | H | P2 | H | H | H | H | P46 | H |
| L_{b1469} | H | P2 | H | H | H | H | P47 | H |
| L_{b1470} | H | P2 | H | H | H | H | P48 | H |
| L_{b1471} | H | P2 | H | H | H | H | P49 | H |
| L_{b1472} | H | P2 | H | H | H | H | P50 | H |
| L_{b1473} | H | P2 | H | H | H | H | P51 | H |
| L_{b1474} | H | P2 | H | H | H | H | P52 | H |
| L_{b1475} | H | P2 | H | H | H | H | P53 | H |
| L_{b1476} | H | P2 | H | H | H | H | P54 | H |
| L_{b1477} | H | P6 | H | H | H | H | P25 | H |
| L_{b1478} | H | P6 | H | H | H | H | P26 | H |
| L_{b1479} | H | P6 | H | H | H | H | P27 | H |
| L_{b1480} | H | P6 | H | H | H | H | P28 | H |
| L_{b1481} | H | P6 | H | H | H | H | P29 | H |
| L_{b1482} | H | P6 | H | H | H | H | P30 | H |
| L_{b1483} | H | P6 | H | H | H | H | P31 | H |
| L_{b1484} | H | P6 | H | H | H | H | P32 | H |
| L_{b1485} | H | P6 | H | H | H | H | P33 | H |
| L_{b1486} | H | P6 | H | H | H | H | P34 | H |
| L_{b1487} | H | P6 | H | H | H | H | P35 | H |
| L_{b1488} | H | P6 | H | H | H | H | P36 | H |
| L_{b1489} | H | P6 | H | H | H | H | P37 | H |
| L_{b1490} | H | P6 | H | H | H | H | P38 | H |
| L_{b1491} | H | P6 | H | H | H | H | P39 | H |
| L_{b1492} | H | P6 | H | H | H | H | P40 | H |
| L_{b1493} | H | P6 | H | H | H | H | P41 | H |
| L_{b1494} | H | P6 | H | H | H | H | P42 | H |
| L_{b1495} | H | P6 | H | H | H | H | P43 | H |
| L_{b1496} | H | P6 | H | H | H | H | P44 | H |
| L_{b1497} | H | P6 | H | H | H | H | P45 | H |
| L_{b1498} | H | P6 | H | H | H | H | P46 | H |
| L_{b1499} | H | P6 | H | H | H | H | P47 | H |
| L_{b1500} | H | P6 | H | H | H | H | P48 | H |
| L_{b1501} | H | P6 | H | H | H | H | P49 | H |
| L_{b1502} | H | P6 | H | H | H | H | P50 | H |
| L_{b1503} | H | P6 | H | H | H | H | P51 | H |
| L_{b1504} | H | P6 | H | H | H | H | P52 | H |
| L_{b1505} | H | P6 | H | H | H | H | P53 | H |
| L_{b1506} | H | P6 | H | H | H | H | P54 | H |
| L_{b1507} | H | P1 | P1 | H | H | P1 | P25 | H |
| L_{b1508} | H | P1 | P1 | H | H | P1 | P26 | H |
| L_{b1509} | H | P1 | P1 | H | H | P1 | P27 | H |
| L_{b1510} | H | P1 | P1 | H | H | P1 | P28 | H |
| L_{b1511} | H | P1 | P1 | H | H | P1 | P29 | H |
| L_{b1512} | H | P1 | P1 | H | H | P1 | P30 | H |
| L_{b1513} | H | P1 | P1 | H | H | P1 | P31 | H |
| L_{b1514} | H | P1 | P1 | H | H | P1 | P32 | H |
| L_{b1515} | H | P1 | P1 | H | H | P1 | P33 | H |
| L_{b1516} | H | P1 | P1 | H | H | P1 | P34 | H |
| L_{b1517} | H | P1 | P1 | H | H | P1 | P35 | H |
| L_{b1518} | H | P1 | P1 | H | H | P1 | P36 | H |
| L_{b1519} | H | P1 | P1 | H | H | P1 | P37 | H |
| L_{b1520} | H | P1 | P1 | H | H | P1 | P38 | H |
| L_{b1521} | H | P1 | P1 | H | H | P1 | P39 | H |
| L_{b1522} | H | P1 | P1 | H | H | P1 | P40 | H |
| L_{b1523} | H | P1 | P1 | H | H | P1 | P41 | H |
| L_{b1524} | H | P1 | P1 | H | H | P1 | P42 | H |
| L_{b1525} | H | P1 | P1 | H | H | P1 | P43 | H |
| L_{b1526} | H | P1 | P1 | H | H | P1 | P44 | H |
| L_{b1527} | H | P1 | P1 | H | H | P1 | P45 | H |
| L_{b1528} | H | P1 | P1 | H | H | P1 | P46 | H |
| L_{b1529} | H | P1 | P1 | H | H | P1 | P47 | H |
| L_{b1530} | H | P1 | P1 | H | H | P1 | P48 | H |
| L_{b1531} | H | P1 | P1 | H | H | P1 | P49 | H |
| L_{b1532} | H | P1 | P1 | H | H | P1 | P50 | H |
| L_{b1533} | H | P1 | P1 | H | H | P1 | P51 | H |
| L_{b1534} | H | P1 | P1 | H | H | P1 | P52 | H |
| L_{b1535} | H | P1 | P1 | H | H | P1 | P53 | H |
| L_{b1536} | H | P1 | P1 | H | H | P1 | P54 | H |
| L_{b1537} | H | P2 | P2 | H | H | P2 | P25 | H |
| L_{b1538} | H | P2 | P2 | H | H | P2 | P26 | H |
| L_{b1539} | H | P2 | P2 | H | H | P2 | P27 | H |
| L_{b1540} | H | P2 | P2 | H | H | P2 | P28 | H |
| L_{b1541} | H | P2 | P2 | H | H | P2 | P29 | H |
| L_{b1542} | H | P2 | P2 | H | H | P2 | P30 | H |
| L_{b1543} | H | P2 | P2 | H | H | P2 | P31 | H |
| L_{b1544} | H | P2 | P2 | H | H | P2 | P32 | H |
| L_{b1545} | H | P2 | P2 | H | H | P2 | P33 | H |
| L_{b1546} | H | P2 | P2 | H | H | P2 | P34 | H |
| L_{b1547} | H | P2 | P2 | H | H | P2 | P35 | H |
| L_{b1548} | H | P2 | P2 | H | H | P2 | P36 | H |
| L_{b1549} | H | P2 | P2 | H | H | P2 | P37 | H |
| L_{b1550} | H | P2 | P2 | H | H | P2 | P38 | H |
| L_{b1551} | H | P2 | P2 | H | H | P2 | P39 | H |
| L_{b1552} | H | P2 | P2 | H | H | P2 | P40 | H |
| L_{b1553} | H | P2 | P2 | H | H | P2 | P41 | H |
| L_{b1554} | H | P2 | P2 | H | H | P2 | P42 | H |
| L_{b1555} | H | P2 | P2 | H | H | P2 | P43 | H |
| L_{b1556} | H | P2 | P2 | H | H | P2 | P44 | H |
| L_{b1557} | H | P2 | P2 | H | H | P2 | P45 | H |
| L_{b1558} | H | P2 | P2 | H | H | P2 | P46 | H |
| L_{b1559} | H | P2 | P2 | H | H | P2 | P47 | H |
| L_{b1560} | H | P2 | P2 | H | H | P2 | P48 | H |
| L_{b1561} | H | P2 | P2 | H | H | P2 | P49 | H |
| L_{b1562} | H | P2 | P2 | H | H | P2 | P50 | H |
| L_{b1563} | H | P2 | P2 | H | H | P2 | P51 | H |
| L_{b1564} | H | P2 | P2 | H | H | P2 | P52 | H |
| L_{b1565} | H | P2 | P2 | H | H | P2 | P53 | H |
| L_{b1566} | H | P2 | P2 | H | H | P2 | P54 | H |

wherein optionally, hydrogens in L_{b1} to L_{b1566} can be partially or fully substituted with deuterium;
P1 to P54 are selected from the group consisting of the following structures: 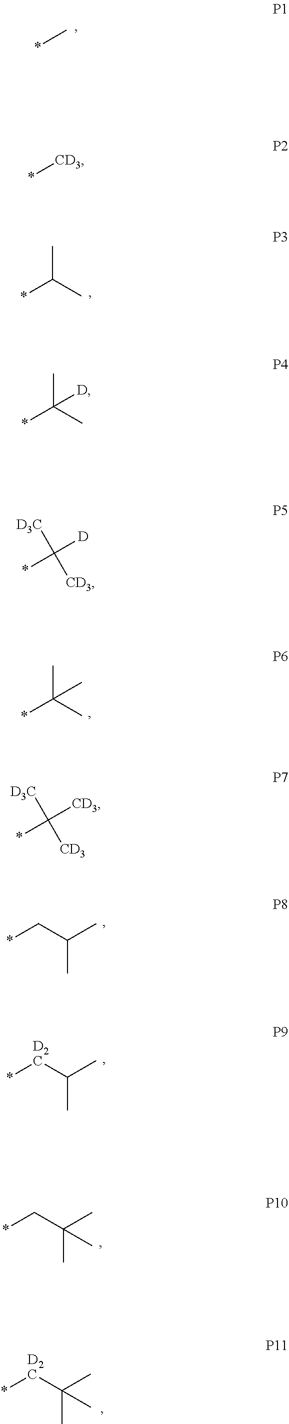 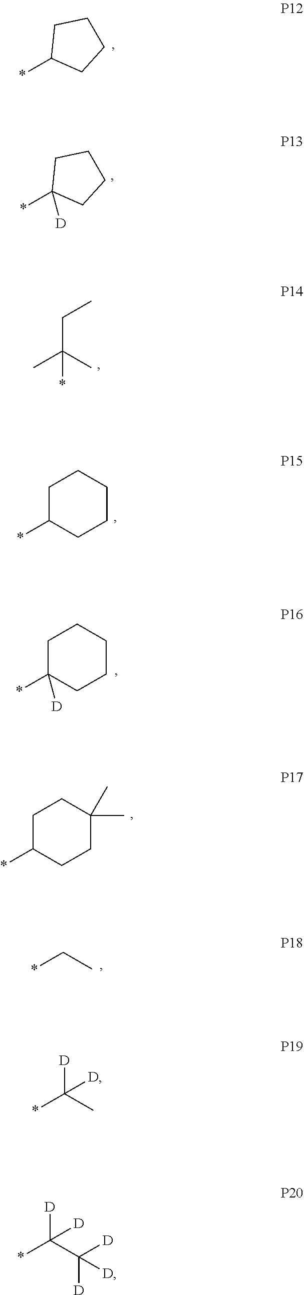 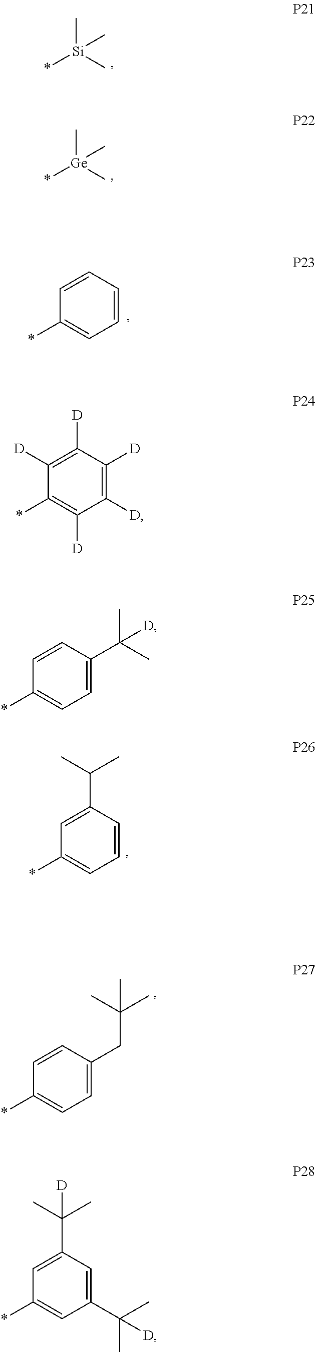 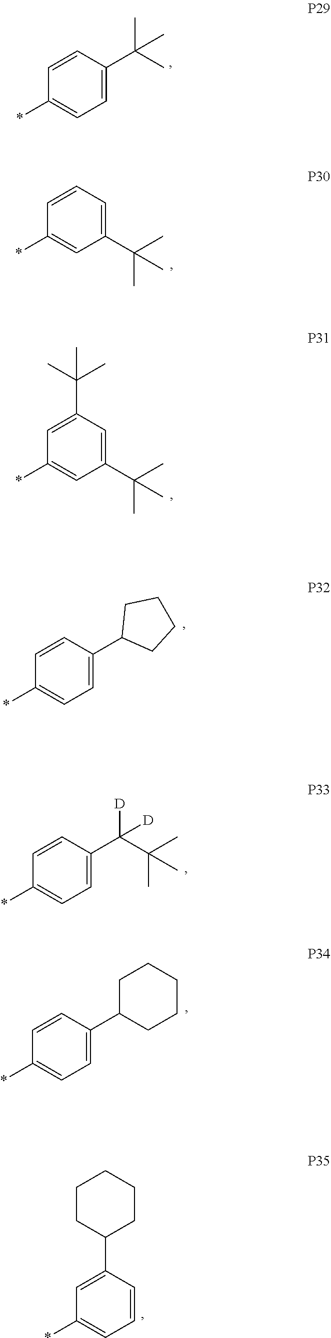 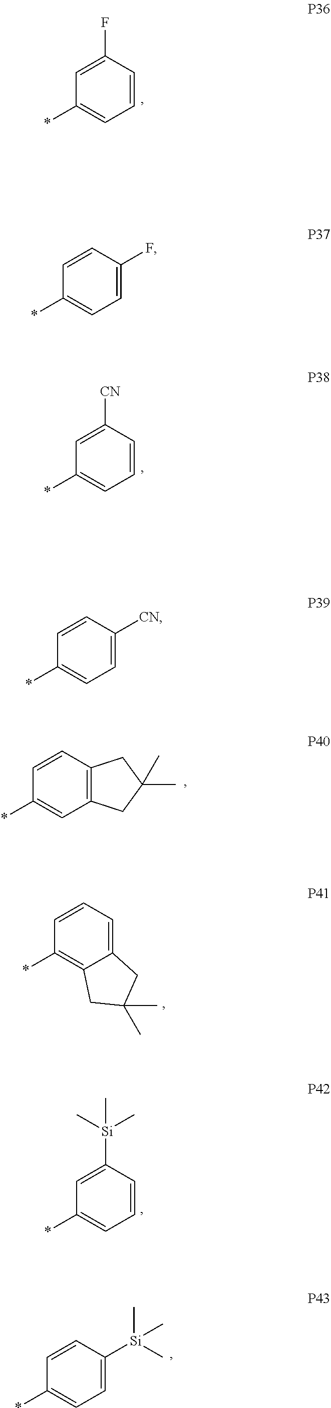 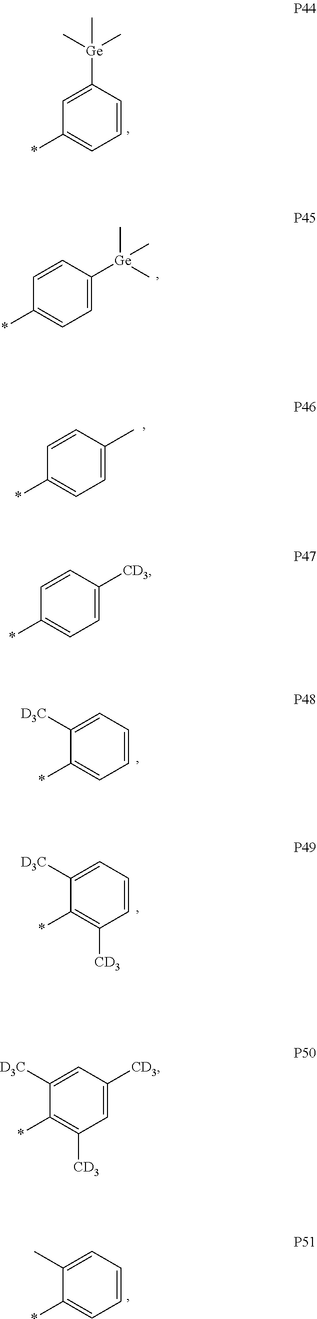 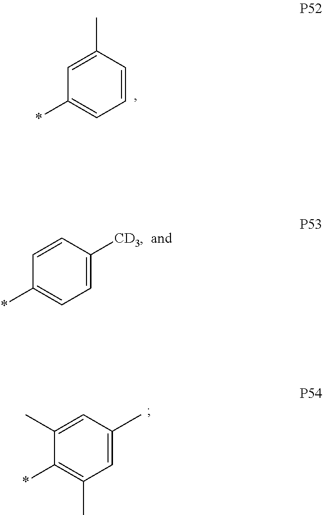
wherein “*” in P1 to P54 represents the position of attachment to the ligand L_{b}.

17. The metal complex of claim 16, wherein L_{c} is, at each occurrence identically or differently, selected from the following structures: 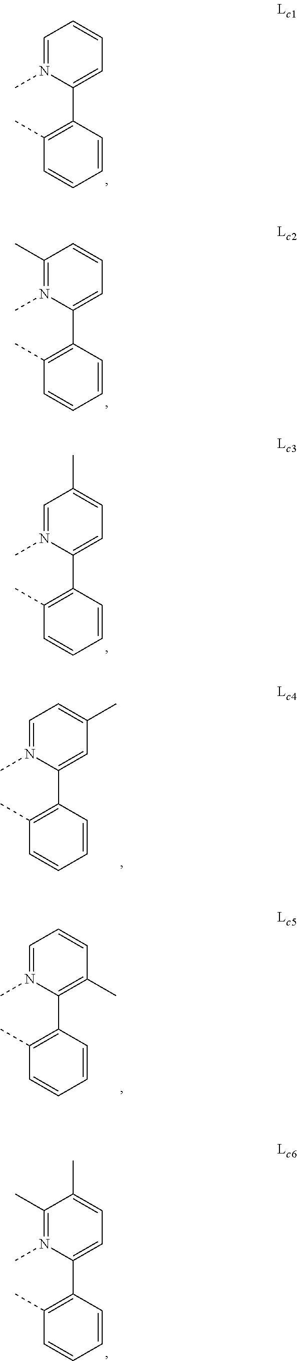 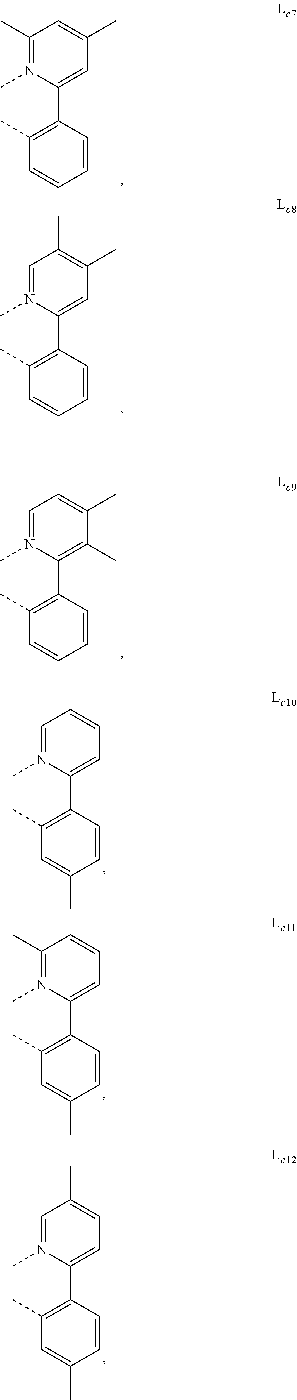 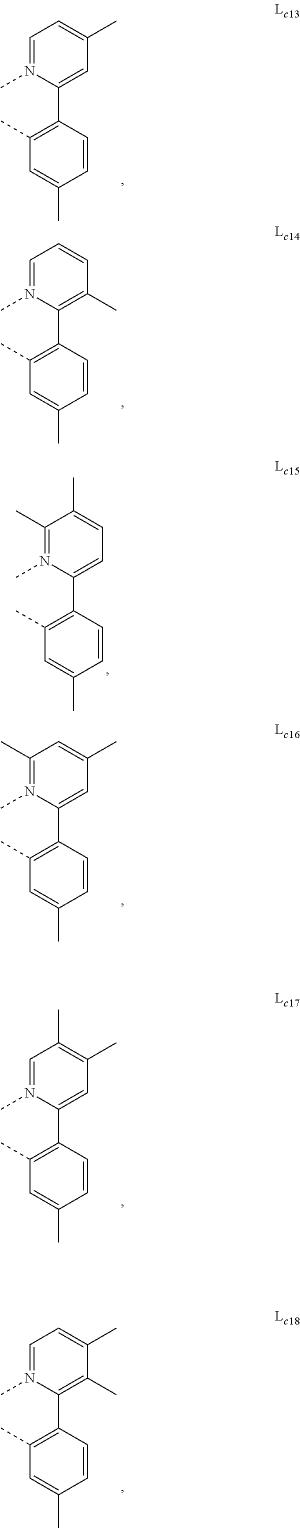 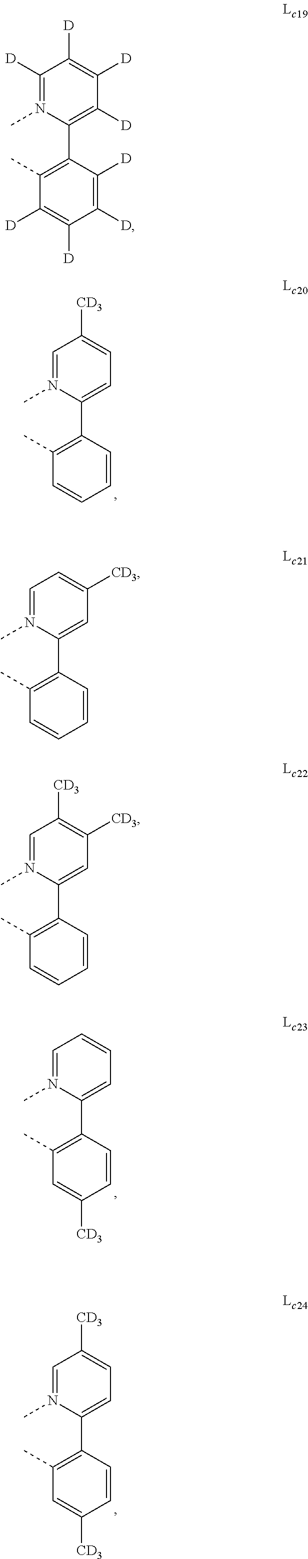 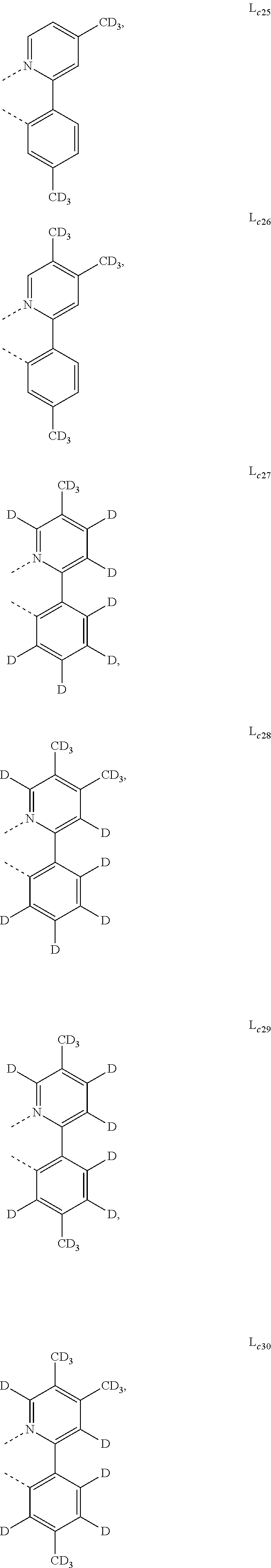 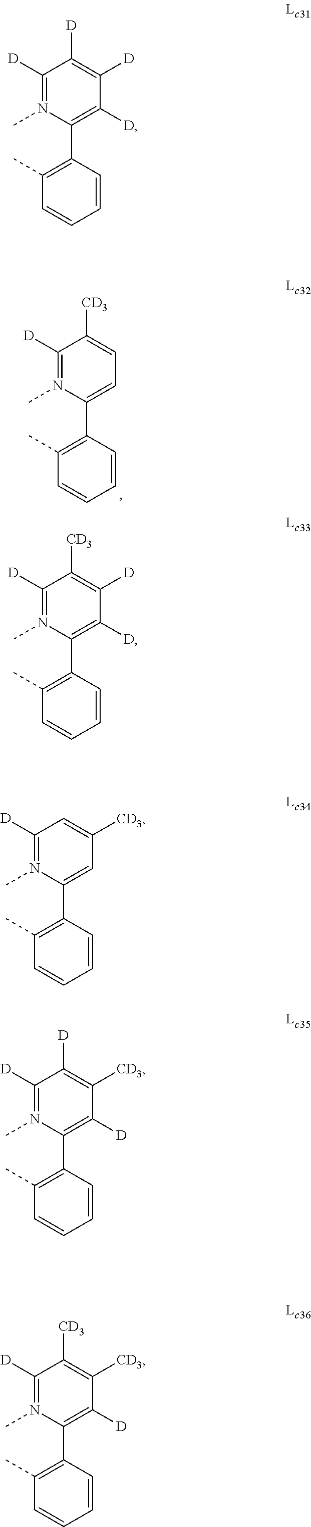 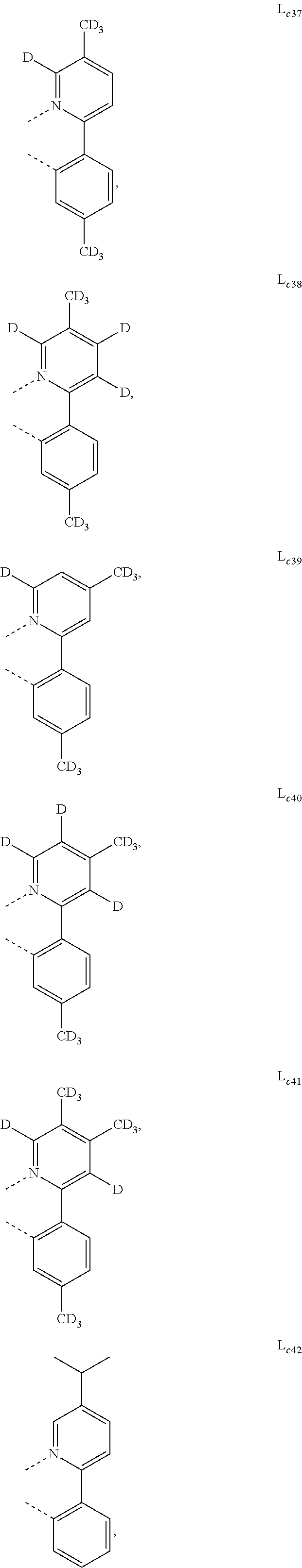 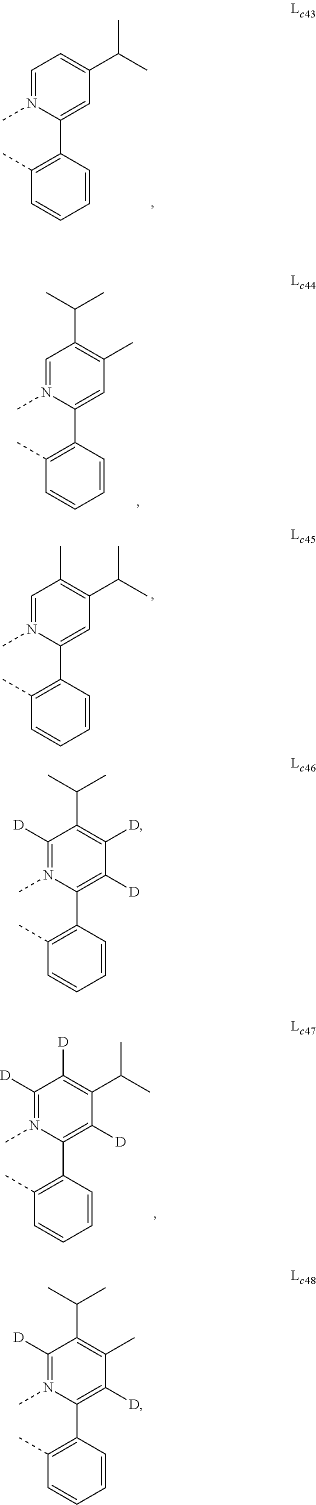 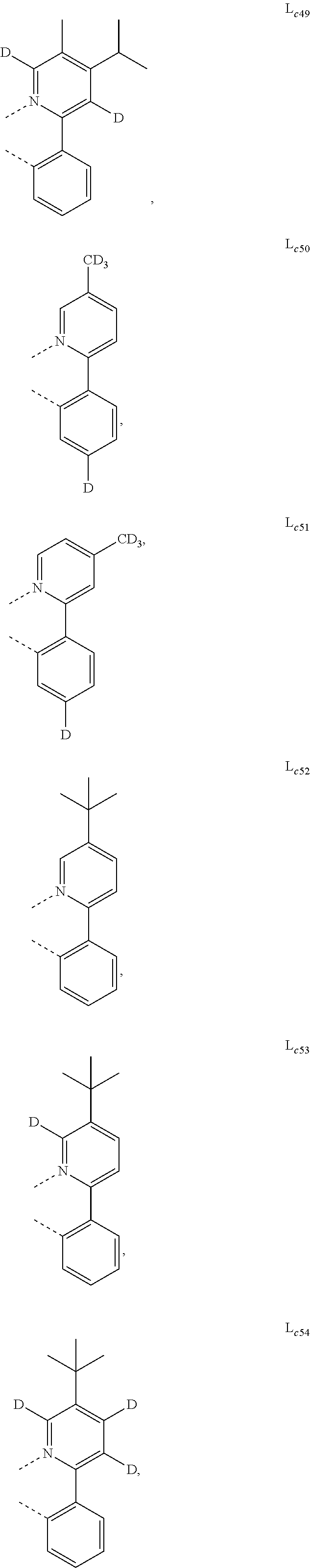 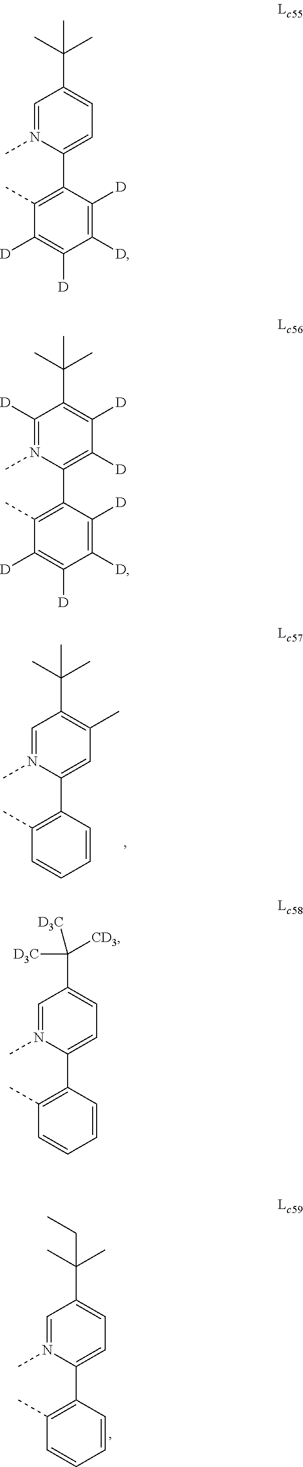 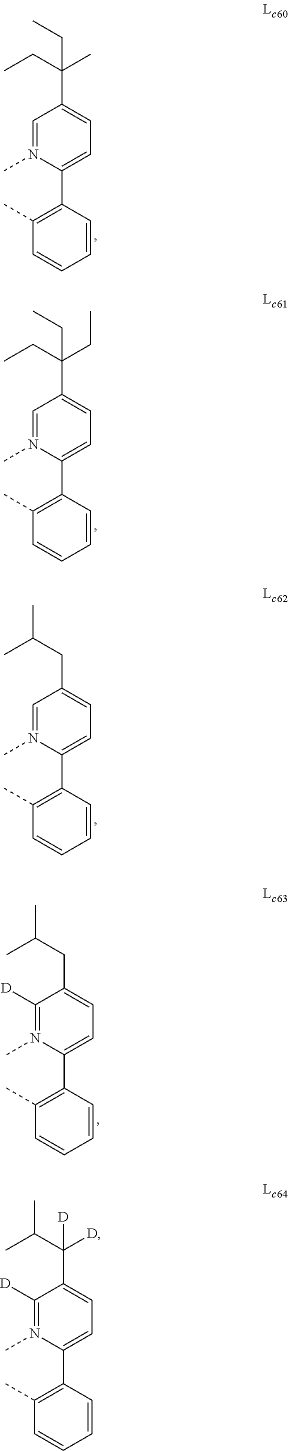 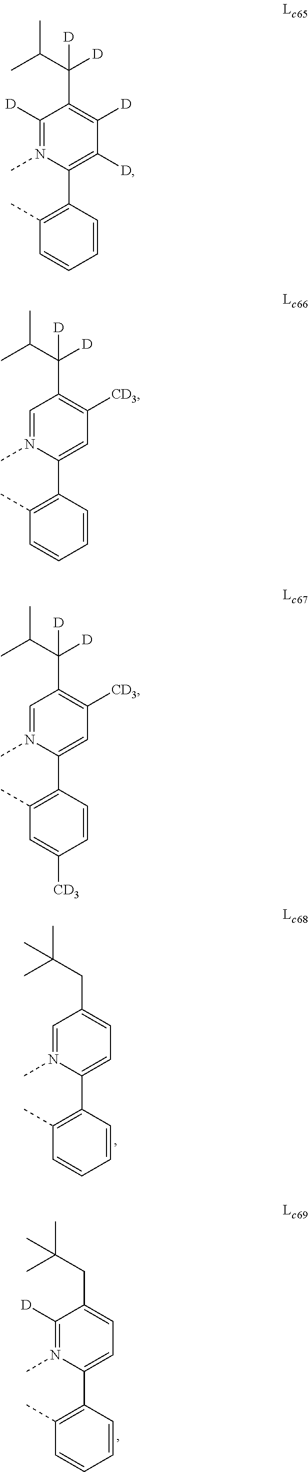 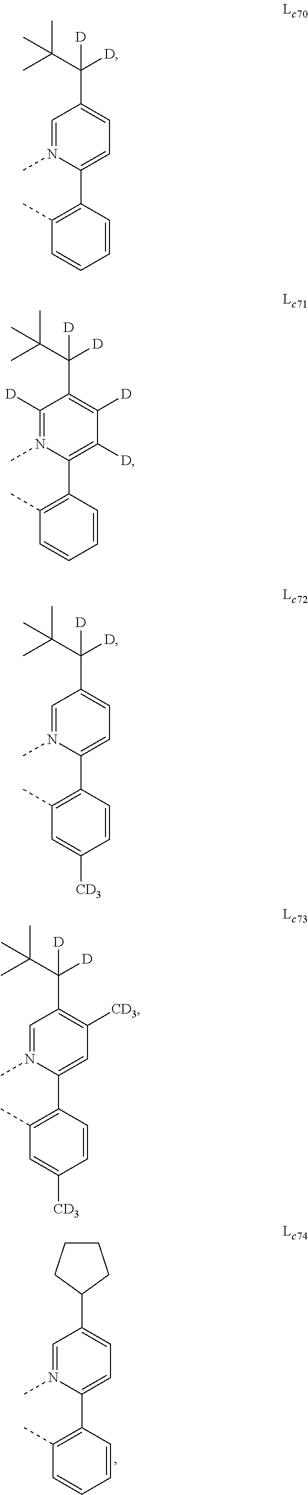 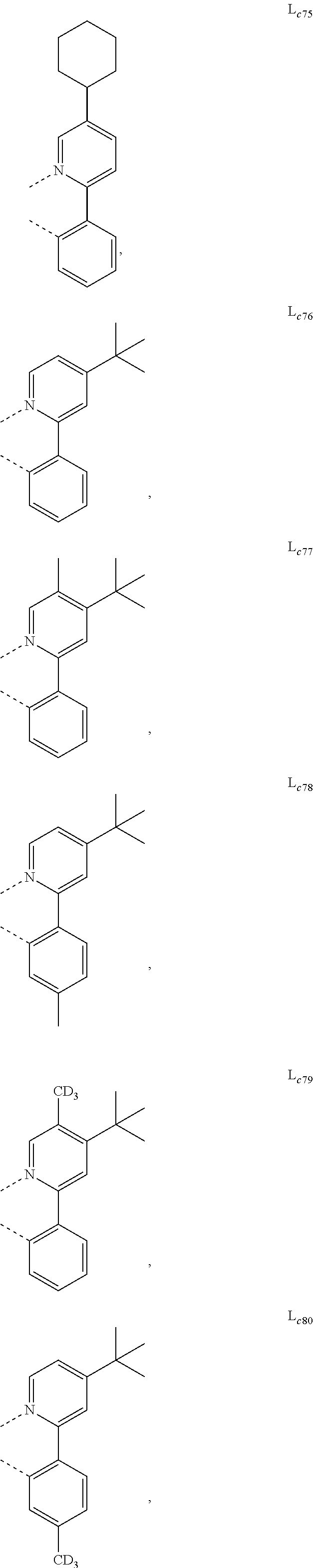 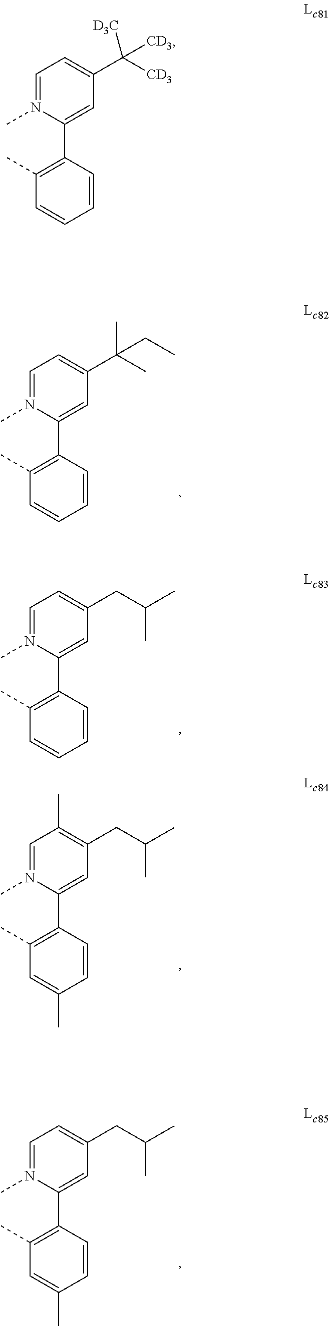 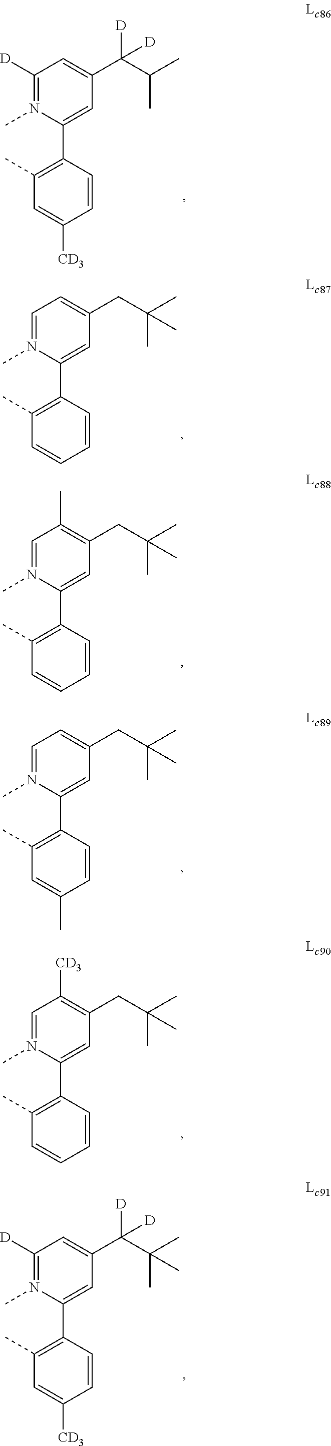 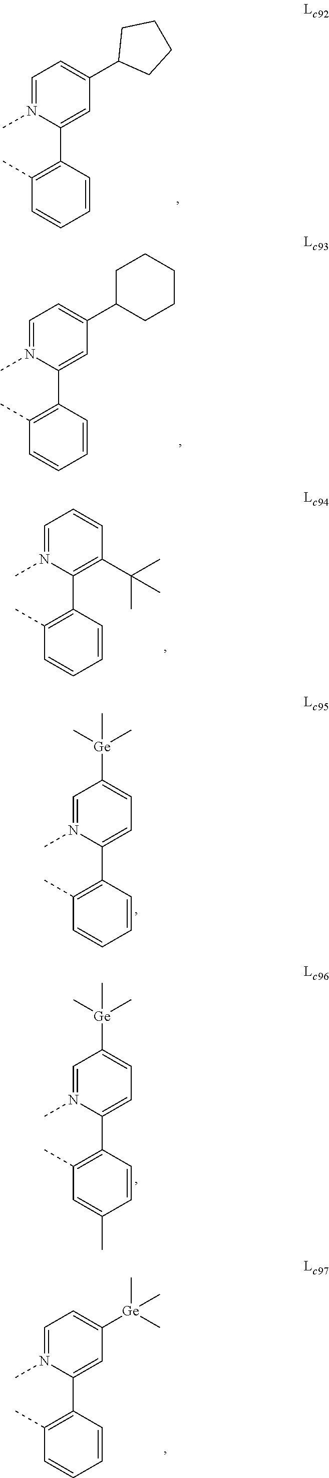 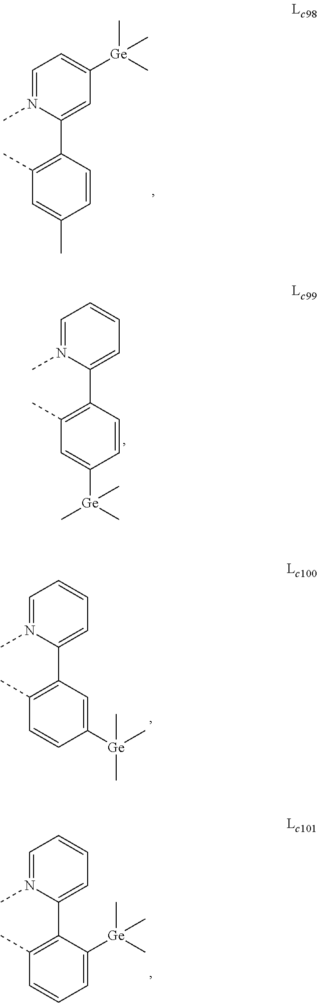 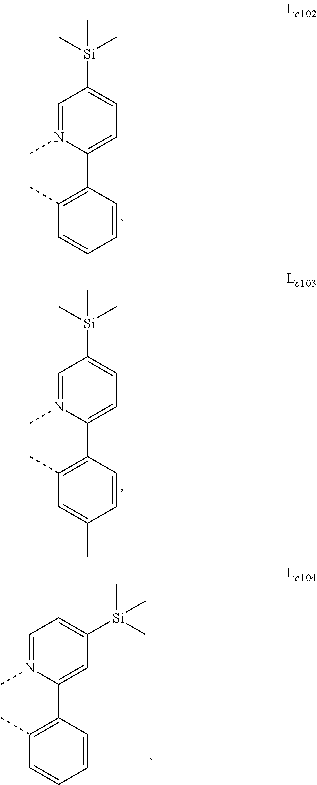 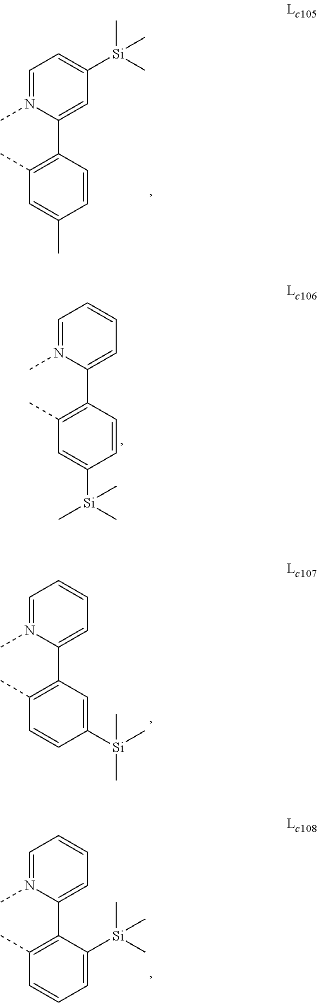 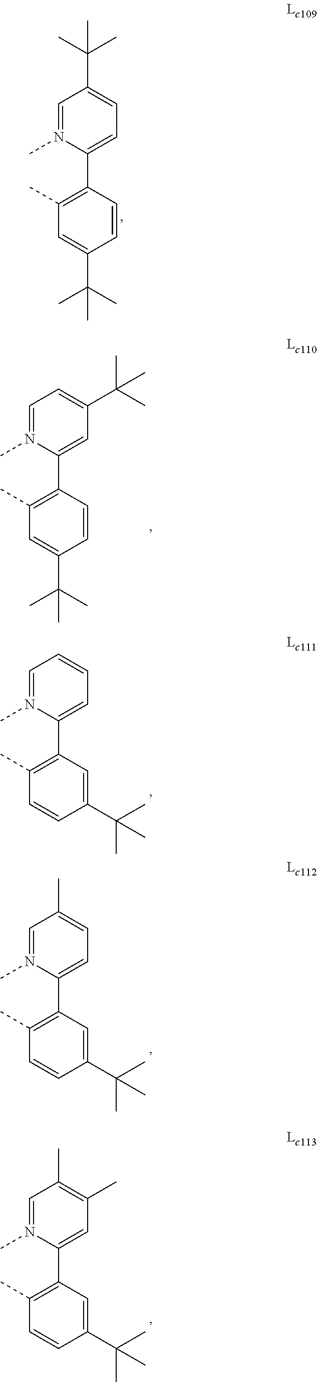 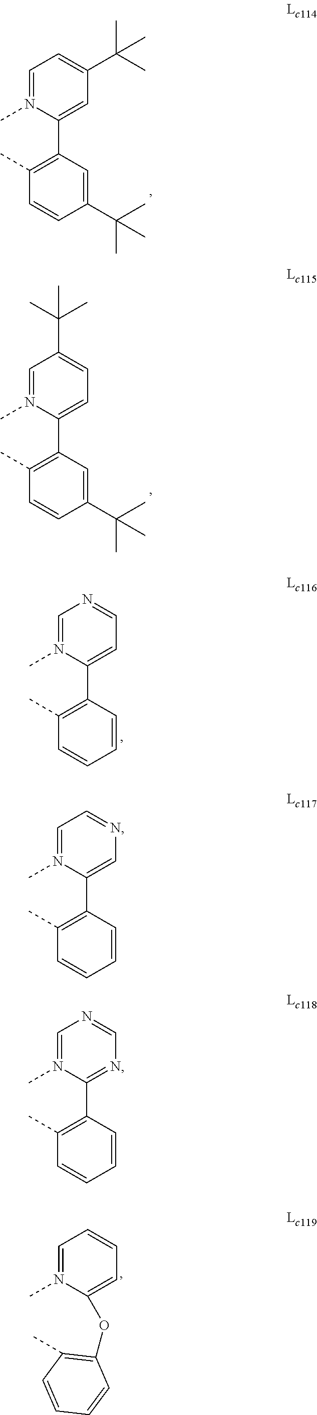 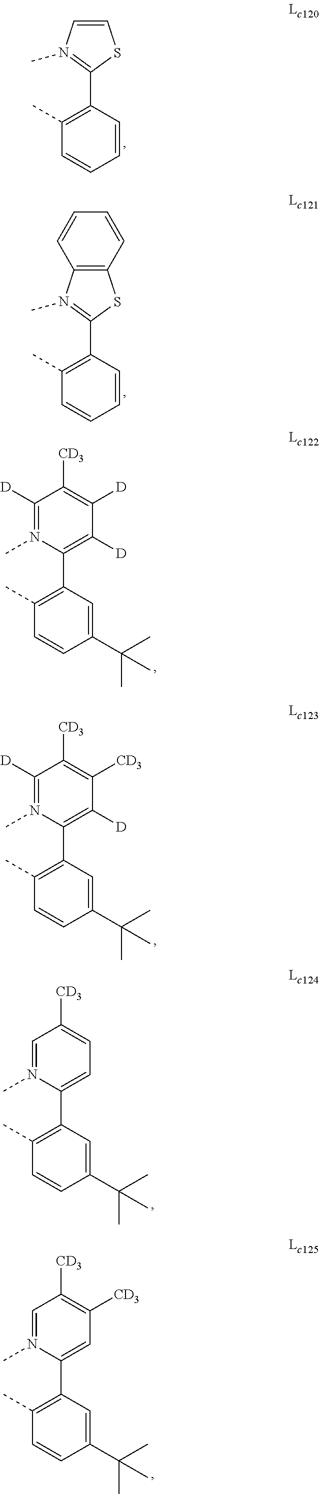 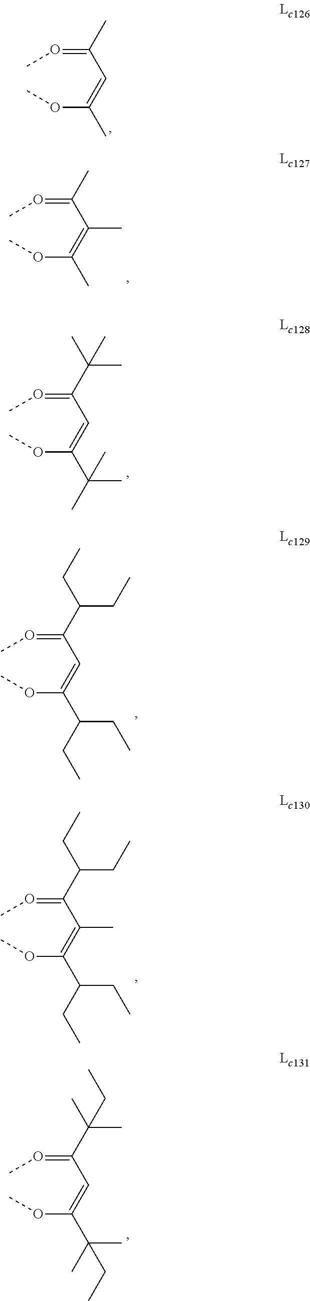 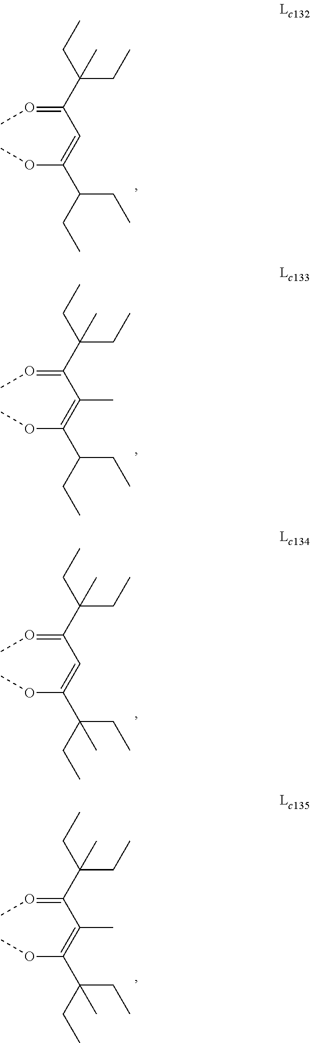 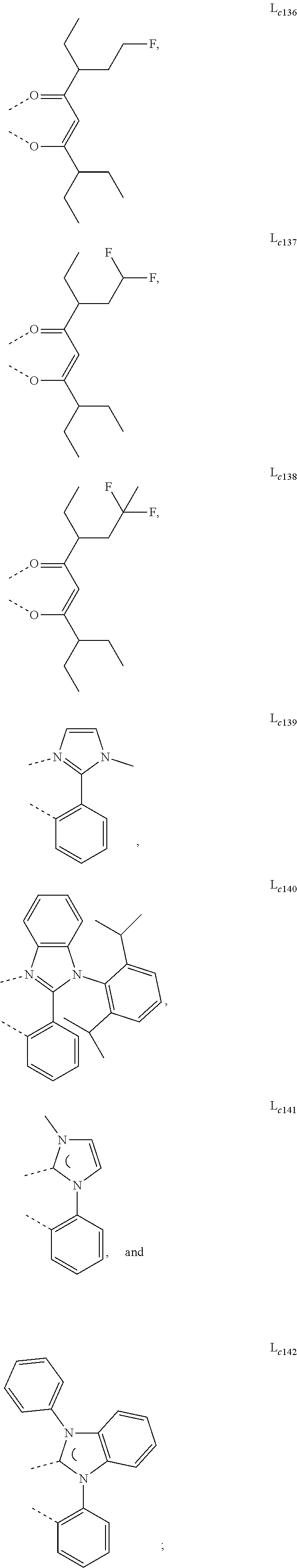
wherein optionally, hydrogens in L_{c1} to L_{c18}, L_{c20} to L_{c26} and L_{c31} to L_{c142} can be partially or fully substituted with deuterium.

18. The metal complex of claim 17, wherein the metal complex is selected from the group consisting of Metal Complex 1 to Metal Complex 2959;
wherein Metal Complex 1 to Metal Complex 2943 each have a structure of Ir(L)(L_{b})₂, wherein two L_{b} are identical, and Lₐ and L_{b} correspond to structures listed in the following table, respectively:

| Metal | | | Metal | | | Metal | | |
|---|---|---|---|---|---|---|---|---|
| Com- | | | Com- | | | Com- | | |
| plex | Lₐ | L_{b} | plex | Lₐ | L_{b} | plex | Lₐ | L_{b} |
| 1 | Lₐ₁ | L_{b494} | 2 | Lₐ₁ | L_{b710} | 3 | Lₐ₁ | L_{b1165} |
| 4 | Lₐ₂ | L_{b494} | 5 | Lₐ₂ | L_{b710} | 6 | Lₐ₂ | L_{b1165} |
| 7 | Lₐ₃ | L_{b494} | 8 | Lₐ₃ | L_{b710} | 9 | Lₐ₃ | L_{b1165} |
| 10 | Lₐ₄ | L_{b494} | 11 | Lₐ₄ | L_{b710} | 12 | Lₐ₄ | L_{b1165} |
| 13 | Lₐ₁₁ | L_{b494} | 14 | Lₐ₁₁ | L_{b710} | 15 | Lₐ₁₁ | L_{b1165} |
| 16 | Lₐ₁₂ | L_{b494} | 17 | Lₐ₁₂ | L_{b710} | 18 | Lₐ₁₂ | L_{b1165} |
| 19 | Lₐ₁₃ | L_{b494} | 20 | Lₐ₁₃ | L_{b710} | 21 | Lₐ₁₃ | L_{b1165} |
| 22 | Lₐ₁₆ | L_{b494} | 23 | Lₐ₁₆ | L_{b710} | 24 | Lₐ₁₆ | L_{b1165} |
| 25 | Lₐ₁₇ | L_{b494} | 26 | Lₐ₁₇ | L_{b710} | 27 | Lₐ₁₇ | L_{b1165} |
| 28 | Lₐ₂₃ | L_{b494} | 29 | Lₐ₂₃ | L_{b710} | 30 | Lₐ₂₃ | L_{b1165} |
| 31 | Lₐ₂₄ | L_{b494} | 32 | Lₐ₂₄ | L_{b710} | 33 | Lₐ₂₄ | L_{b1165} |
| 34 | Lₐ₃₀ | L_{b494} | 35 | Lₐ₃₀ | L_{b710} | 36 | Lₐ₃₀ | L_{b1165} |
| 37 | Lₐ₃₂ | L_{b494} | 38 | Lₐ₃₂ | L_{b710} | 39 | Lₐ₃₂ | L_{b1165} |
| 40 | Lₐ₃₅ | L_{b494} | 41 | Lₐ₃₅ | L_{b710} | 42 | Lₐ₃₅ | L_{b1165} |
| 43 | Lₐ₇₈ | L_{b494} | 44 | Lₐ₇₈ | L_{b710} | 45 | Lₐ₇₈ | L_{b1165} |
| 46 | Lₐ₈₆ | L_{b494} | 47 | Lₐ₈₆ | L_{b710} | 48 | Lₐ₈₆ | L_{b1165} |
| 49 | Lₐ₈₇ | L_{b494} | 50 | Lₐ₈₇ | L_{b710} | 51 | Lₐ₈₇ | L_{b1165} |
| 52 | Lₐ₈₈ | L_{b494} | 53 | Lₐ₈₈ | L_{b710} | 54 | Lₐ₈₈ | L_{b1165} |
| 55 | Lₐ₈₉ | L_{b494} | 56 | Lₐ₈₉ | L_{b710} | 57 | Lₐ₈₉ | L_{b1165} |
| 58 | Lₐ₁₅₇ | L_{b494} | 59 | Lₐ₁₅₇ | L_{b710} | 60 | Lₐ₁₅₇ | L_{b1165} |
| 61 | Lₐ₁₅₈ | L_{b494} | 62 | Lₐ₁₅₈ | L_{b710} | 63 | Lₐ₁₅₈ | L_{b1165} |
| 64 | Lₐ₁₆₅ | L_{b494} | 65 | Lₐ₁₆₅ | L_{b710} | 66 | Lₐ₁₆₅ | L_{b1165} |
| 67 | Lₐ₁₆₈ | L_{b494} | 68 | Lₐ₁₆₈ | L_{b710} | 69 | Lₐ₁₆₈ | L_{b1165} |
| 70 | Lₐ₁₉₀ | L_{b494} | 71 | Lₐ₁₉₀ | L_{b710} | 72 | Lₐ₁₉₀ | L_{b1165} |
| 73 | Lₐ₁₉₄ | L_{b494} | 74 | Lₐ₁₉₄ | L_{b710} | 75 | Lₐ₁₉₄ | L_{b1165} |
| 76 | Lₐ₂₀₇ | L_{b494} | 77 | Lₐ₂₀₇ | L_{b710} | 78 | Lₐ₂₀₇ | L_{b1165} |
| 79 | Lₐ₂₀₈ | L_{b494} | 80 | Lₐ₂₀₈ | L_{b710} | 81 | Lₐ₂₀₈ | L_{b1165} |
| 82 | Lₐ₂₁₃ | L_{b494} | 83 | Lₐ₂₁₃ | L_{b710} | 84 | Lₐ₂₁₃ | L_{b1165} |
| 85 | Lₐ₂₁₄ | L_{b494} | 86 | Lₐ₂₁₄ | L_{b710} | 87 | Lₐ₂₁₄ | L_{b1165} |
| 88 | Lₐ₂₁₅ | L_{b494} | 89 | Lₐ₂₁₅ | L_{b710} | 90 | Lₐ₂₁₅ | L_{b1165} |
| 91 | Lₐ₂₁₆ | L_{b494} | 92 | Lₐ₂₁₆ | L_{b710} | 93 | Lₐ₂₁₆ | L_{b1165} |
| 94 | Lₐ₂₁₇ | L_{b494} | 95 | Lₐ₂₁₇ | L_{b710} | 96 | Lₐ₂₁₇ | L_{b1165} |
| 97 | Lₐ₂₁₈ | L_{b494} | 98 | Lₐ₂₁₈ | L_{b710} | 99 | Lₐ₂₁₈ | L_{b1165} |
| 100 | Lₐ₂₂₁ | L_{b494} | 101 | Lₐ₂₂₁ | L_{b710} | 102 | Lₐ₂₂₁ | L_{b1165} |
| 103 | Lₐ₂₂₂ | L_{b494} | 104 | Lₐ₂₂₂ | L_{b710} | 105 | Lₐ₂₂₂ | L_{b1165} |
| 106 | Lₐ₂₂₃ | L_{b494} | 107 | Lₐ₂₂₃ | L_{b710} | 108 | Lₐ₂₂₃ | L_{b1165} |
| 109 | Lₐ₂₂₄ | L_{b494} | 110 | Lₐ₂₂₄ | L_{b710} | 111 | Lₐ₂₂₄ | L_{b1165} |
| 112 | Lₐ₂₂₅ | L_{b494} | 113 | Lₐ₂₂₅ | L_{b710} | 114 | Lₐ₂₂₅ | L_{b1165} |
| 115 | Lₐ₂₂₆ | L_{b494} | 116 | Lₐ₂₂₆ | L_{b710} | 117 | Lₐ₂₂₆ | L_{b1165} |
| 118 | Lₐ₂₂₇ | L_{b494} | 119 | Lₐ₂₂₇ | L_{b710} | 120 | Lₐ₂₂₇ | L_{b1165} |
| 121 | Lₐ₂₂₈ | L_{b494} | 122 | Lₐ₂₂₈ | L_{b710} | 123 | Lₐ₂₂₈ | L_{b1165} |
| 124 | Lₐ₂₂₉ | L_{b494} | 125 | Lₐ₂₂₉ | L_{b710} | 126 | Lₐ₂₂₉ | L_{b1165} |
| 127 | Lₐ₂₃₀ | L_{b494} | 128 | Lₐ₂₃₀ | L_{b710} | 129 | Lₐ₂₃₀ | L_{b1165} |
| 130 | Lₐ₂₃₃ | L_{b494} | 131 | Lₐ₂₃₃ | L_{b710} | 132 | Lₐ₂₃₃ | L_{b1165} |
| 133 | Lₐ₂₃₄ | L_{b494} | 134 | Lₐ₂₃₄ | L_{b710} | 135 | Lₐ₂₃₄ | L_{b1165} |
| 136 | Lₐ₂₃₅ | L_{b494} | 137 | Lₐ₂₃₅ | L_{b710} | 138 | Lₐ₂₃₅ | L_{b1165} |
| 139 | Lₐ₂₃₆ | L_{b494} | 140 | Lₐ₂₃₆ | L_{b710} | 141 | Lₐ₂₃₆ | L_{b1165} |
| 142 | Lₐ₂₃₇ | L_{b494} | 143 | Lₐ₂₃₇ | L_{b710} | 144 | Lₐ₂₃₇ | L_{b1165} |
| 145 | Lₐ₂₃₈ | L_{b494} | 146 | Lₐ₂₃₈ | L_{b710} | 147 | Lₐ₂₃₈ | L_{b1165} |
| 148 | Lₐ₂₅₉ | L_{b494} | 149 | Lₐ₂₅₉ | L_{b710} | 150 | Lₐ₂₅₉ | L_{b1165} |
| 151 | Lₐ₂₆₀ | L_{b494} | 152 | Lₐ₂₆₀ | L_{b710} | 153 | Lₐ₂₆₀ | L_{b1165} |
| 154 | Lₐ₂₇₈ | L_{b494} | 155 | Lₐ₂₇₈ | L_{b710} | 156 | Lₐ₂₇₈ | L_{b1165} |
| 157 | Lₐ₂₇₉ | L_{b494} | 158 | Lₐ₂₇₉ | L_{b710} | 159 | Lₐ₂₇₉ | L_{b1165} |
| 160 | Lₐ₃₀₂ | L_{b494} | 161 | Lₐ₃₀₂ | L_{b710} | 162 | Lₐ₃₀₂ | L_{b1165} |
| 163 | Lₐ₃₀₆ | L_{b494} | 164 | Lₐ₃₀₆ | L_{b710} | 165 | Lₐ₃₀₆ | L_{b1165} |
| 166 | Lₐ₃₀₇ | L_{b494} | 167 | Lₐ₃₀₇ | L_{b710} | 168 | Lₐ₃₀₇ | L_{b1165} |
| 169 | Lₐ₃₀₈ | L_{b494} | 170 | Lₐ₃₀₈ | L_{b710} | 171 | Lₐ₃₀₈ | L_{b1165} |
| 172 | Lₐ₃₀₉ | L_{b494} | 173 | Lₐ₃₀₉ | L_{b710} | 174 | Lₐ₃₀₉ | L_{b1165} |
| 175 | Lₐ₃₁₀ | L_{b494} | 176 | Lₐ₃₁₀ | L_{b710} | 177 | Lₐ₃₁₀ | L_{b1165} |
| 178 | Lₐ₃₃₀ | L_{b494} | 179 | Lₐ₃₃₀ | L_{b710} | 180 | Lₐ₃₃₀ | L_{b1165} |
| 181 | Lₐ₃₃₁ | L_{b494} | 182 | Lₐ₃₃₁ | L_{b710} | 183 | Lₐ₃₃₁ | L_{b1165} |
| 184 | Lₐ₃₃₂ | L_{b494} | 185 | Lₐ₃₃₂ | L_{b710} | 186 | Lₐ₃₃₂ | L_{b1165} |
| 187 | Lₐ₃₃₃ | L_{b494} | 188 | Lₐ₃₃₃ | L_{b710} | 189 | Lₐ₃₃₃ | L_{b1165} |
| 190 | Lₐ₃₃₇ | L_{b494} | 191 | Lₐ₃₃₇ | L_{b710} | 192 | Lₐ₃₃₇ | L_{b1165} |
| 193 | Lₐ₃₄₂ | L_{b494} | 194 | Lₐ₃₄₂ | L_{b710} | 195 | Lₐ₃₄₂ | L_{b1165} |
| 196 | Lₐ₃₄₃ | L_{b494} | 197 | Lₐ₃₄₃ | L_{b710} | 198 | Lₐ₃₄₃ | L_{b1165} |
| 199 | Lₐ₃₅₁ | L_{b494} | 200 | Lₐ₃₅₁ | L_{b710} | 201 | Lₐ₃₅₁ | L_{b1165} |
| 202 | Lₐ₃₅₂ | L_{b494} | 203 | Lₐ₃₅₂ | L_{b710} | 204 | Lₐ₃₅₂ | L_{b1165} |
| 205 | Lₐ₃₅₆ | L_{b494} | 206 | Lₐ₃₅₆ | L_{b710} | 207 | Lₐ₃₅₆ | L_{b1165} |
| 208 | Lₐ₃₅₇ | L_{b494} | 209 | Lₐ₃₅₇ | L_{b710} | 210 | Lₐ₃₅₇ | L_{b1165} |
| 211 | Lₐ₃₅₈ | L_{b494} | 212 | Lₐ₃₅₈ | L_{b710} | 213 | Lₐ₃₅₈ | L_{b1165} |
| 214 | Lₐ₃₅₉ | L_{b494} | 215 | Lₐ₃₅₉ | L_{b710} | 216 | Lₐ₃₅₉ | L_{b1165} |
| 217 | Lₐ₃₆₇ | L_{b494} | 218 | Lₐ₃₆₇ | L_{b710} | 219 | Lₐ₃₆₇ | L_{b1165} |
| 220 | Lₐ₄₀₄ | L_{b494} | 221 | Lₐ₄₀₄ | L_{b710} | 222 | Lₐ₄₀₄ | L_{b1165} |
| 223 | Lₐ₄₀₅ | L_{b494} | 224 | Lₐ₄₀₅ | L_{b710} | 225 | Lₐ₄₀₅ | L_{b1165} |
| 226 | Lₐ₄₀₆ | L_{b494} | 227 | Lₐ₄₀₆ | L_{b710} | 228 | Lₐ₄₀₆ | L_{b1165} |
| 229 | Lₐ₄₁₃ | L_{b494} | 230 | Lₐ₄₁₃ | L_{b710} | 231 | Lₐ₄₁₃ | L_{b1165} |
| 232 | Lₐ₄₁₄ | L_{b494} | 233 | Lₐ₄₁₄ | L_{b710} | 234 | Lₐ₄₁₄ | L_{b1165} |
| 235 | Lₐ₄₂₃ | L_{b494} | 236 | Lₐ₄₂₃ | L_{b710} | 237 | Lₐ₄₂₃ | L_{b1165} |
| 238 | Lₐ₄₂₇ | L_{b494} | 239 | Lₐ₄₂₇ | L_{b710} | 240 | Lₐ₄₂₇ | L_{b1165} |
| 241 | Lₐ₄₂₈ | L_{b494} | 242 | Lₐ₄₂₈ | L_{b710} | 243 | Lₐ₄₂₈ | L_{b1165} |
| 244 | Lₐ₄₅₉ | L_{b494} | 245 | Lₐ₄₅₉ | L_{b710} | 246 | Lₐ₄₅₉ | L_{b1165} |
| 247 | Lₐ₄₉₅ | L_{b494} | 248 | Lₐ₄₉₅ | L_{b710} | 249 | Lₐ₄₉₅ | L_{b1165} |
| 250 | Lₐ₅₁₂ | L_{b494} | 251 | Lₐ₅₁₂ | L_{b710} | 252 | Lₐ₅₁₂ | L_{b1165} |
| 253 | Lₐ₅₂₂ | L_{b494} | 254 | Lₐ₅₂₂ | L_{b710} | 255 | Lₐ₅₂₂ | L_{b1165} |
| 256 | Lₐ₅₂₃ | L_{b494} | 257 | Lₐ₅₂₃ | L_{b710} | 258 | Lₐ₅₂₃ | L_{b1165} |
| 259 | Lₐ₅₃₇ | L_{b494} | 260 | Lₐ₅₃₇ | L_{b710} | 261 | Lₐ₅₃₇ | L_{b1165} |
| 262 | Lₐ₅₄₀ | L_{b494} | 263 | Lₐ₅₄₀ | L_{b710} | 264 | Lₐ₅₄₀ | L_{b1165} |
| 265 | Lₐ₅₈₁ | L_{b494} | 266 | Lₐ₅₈₁ | L_{b710} | 267 | Lₐ₅₈₁ | L_{b1165} |
| 268 | Lₐ₅₈₂ | L_{b494} | 269 | Lₐ₅₈₂ | L_{b710} | 270 | Lₐ₅₈₂ | L_{b1165} |
| 271 | Lₐ₅₈₉ | L_{b494} | 272 | Lₐ₅₈₉ | L_{b710} | 273 | Lₐ₅₈₉ | L_{b1165} |
| 274 | Lₐ₆₆₈ | L_{b494} | 275 | Lₐ₆₆₈ | L_{b710} | 276 | Lₐ₆₆₈ | L_{b1165} |
| 277 | Lₐ₆₆₉ | L_{b494} | 278 | Lₐ₆₆₉ | L_{b710} | 279 | Lₐ₆₆₉ | L_{b1165} |
| 280 | Lₐ₆₈₆ | L_{b494} | 281 | Lₐ₆₈₆ | L_{b710} | 282 | Lₐ₆₈₆ | L_{b1165} |
| 283 | Lₐ₇₀₁ | L_{b494} | 284 | Lₐ₇₀₁ | L_{b710} | 285 | Lₐ₇₀₁ | L_{b1165} |
| 286 | Lₐ₇₁₈ | L_{b494} | 287 | Lₐ₇₁₈ | L_{b710} | 288 | Lₐ₇₁₈ | L_{b1165} |
| 289 | Lₐ₇₁₉ | L_{b494} | 290 | Lₐ₇₁₉ | L_{b710} | 291 | Lₐ₇₁₉ | L_{b1165} |
| 292 | Lₐ₇₂₄ | L_{b494} | 293 | Lₐ₇₂₄ | L_{b710} | 294 | Lₐ₇₂₄ | L_{b1165} |
| 295 | Lₐ₇₂₅ | L_{b494} | 296 | Lₐ₇₂₅ | L_{b710} | 297 | Lₐ₇₂₅ | L_{b1165} |
| 298 | Lₐ₇₄₁ | L_{b494} | 299 | Lₐ₇₄₁ | L_{b710} | 300 | Lₐ₇₄₁ | L_{b1165} |
| 301 | Lₐ₇₄₈ | L_{b494} | 302 | Lₐ₇₄₈ | L_{b710} | 303 | Lₐ₇₄₈ | L_{b1165} |
| 304 | Lₐ₇₄₉ | L_{b494} | 305 | Lₐ₇₄₉ | L_{b710} | 306 | Lₐ₇₄₉ | L_{b1165} |
| 307 | Lₐ₇₅₅ | L_{b494} | 308 | Lₐ₇₅₅ | L_{b710} | 309 | Lₐ₇₅₅ | L_{b1165} |
| 310 | Lₐ₇₆₂ | L_{b494} | 311 | Lₐ₇₆₂ | L_{b710} | 312 | Lₐ₇₆₂ | L_{b1165} |
| 313 | Lₐ₇₆₃ | L_{b494} | 314 | Lₐ₇₆₃ | L_{b710} | 315 | Lₐ₇₆₃ | L_{b1165} |
| 316 | Lₐ₇₆₄ | L_{b494} | 317 | Lₐ₇₆₄ | L_{b710} | 318 | Lₐ₇₆₄ | L_{b1165} |
| 319 | Lₐ₇₆₅ | L_{b494} | 320 | Lₐ₇₆₅ | L_{b710} | 321 | Lₐ₇₆₅ | L_{b1165} |
| 322 | Lₐ₇₆₇ | L_{b494} | 323 | Lₐ₇₆₇ | L_{b710} | 324 | Lₐ₇₆₇ | L_{b1165} |
| 325 | Lₐ₇₆₈ | L_{b494} | 326 | Lₐ₇₆₈ | L_{b710} | 327 | Lₐ₇₆₈ | L_{b1165} |
| 328 | Lₐ₇₉₁ | L_{b494} | 329 | Lₐ₇₉₁ | L_{b710} | 330 | Lₐ₇₉₁ | L_{b1165} |
| 331 | Lₐ₈₂₇ | L_{b494} | 332 | Lₐ₈₂₇ | L_{b710} | 333 | Lₐ₈₂₇ | L_{b1165} |
| 334 | Lₐ₈₃₂ | L_{b494} | 335 | Lₐ₈₃₂ | L_{b710} | 336 | Lₐ₈₃₂ | L_{b1165} |
| 337 | Lₐ₈₄₃ | L_{b494} | 338 | Lₐ₈₄₃ | L_{b710} | 339 | Lₐ₈₄₃ | L_{b1165} |
| 340 | Lₐ₉₃₅ | L_{b494} | 341 | Lₐ₉₃₅ | L_{b710} | 342 | Lₐ₉₃₅ | L_{b1165} |
| 343 | Lₐ₉₅₇ | L_{b494} | 344 | Lₐ₉₅₇ | L_{b710} | 345 | Lₐ₉₅₇ | L_{b1165} |
| 346 | Lₐ₁₀₂₄ | L_{b494} | 347 | Lₐ₁₀₂₄ | L_{b710} | 348 | Lₐ₁₀₂₄ | L_{b1165} |
| 349 | Lₐ₁₀₃₄ | L_{b494} | 350 | Lₐ₁₀₃₄ | L_{b710} | 351 | Lₐ₁₀₃₄ | L_{b1165} |
| 352 | Lₐ₁₀₃₅ | L_{b494} | 353 | Lₐ₁₀₃₅ | L_{b710} | 354 | Lₐ₁₀₃₅ | L_{b1165} |
| 355 | Lₐ₁₁₀₁ | L_{b494} | 356 | Lₐ₁₁₀₁ | L_{b710} | 357 | Lₐ₁₁₀₁ | L_{b1165} |
| 358 | Lₐ₁₁₄₁ | L_{b494} | 359 | Lₐ₁₁₄₁ | L_{b710} | 360 | Lₐ₁₁₄₁ | L_{b1165} |
| 361 | Lₐ₁₁₈₀ | L_{b494} | 362 | Lₐ₁₁₈₀ | L_{b710} | 363 | Lₐ₁₁₈₀ | L_{b1165} |
| 364 | Lₐ₁₁₈₁ | L_{b494} | 365 | Lₐ₁₁₈₁ | L_{b710} | 366 | Lₐ₁₁₈₁ | L_{b1165} |
| 367 | Lₐ₁₂₁₃ | L_{b494} | 368 | Lₐ₁₂₁₃ | L_{b710} | 369 | Lₐ₁₂₁₃ | L_{b1165} |
| 370 | Lₐ₁₂₃₀ | L_{b494} | 371 | Lₐ₁₂₃₀ | L_{b710} | 372 | Lₐ₁₂₃₀ | L_{b1165} |
| 373 | Lₐ₁₂₃₁ | L_{b494} | 374 | Lₐ₁₂₃₁ | L_{b710} | 375 | Lₐ₁₂₃₁ | L_{b1165} |
| 376 | Lₐ₁₂₃₆ | L_{b494} | 377 | Lₐ₁₂₃₆ | L_{b710} | 378 | Lₐ₁₂₃₆ | L_{b1165} |
| 379 | Lₐ₁₂₃₇ | L_{b494} | 380 | Lₐ₁₂₃₇ | L_{b710} | 381 | Lₐ₁₂₃₇ | L_{b1165} |
| 382 | Lₐ₁₂₆₇ | L_{b494} | 383 | Lₐ₁₂₆₇ | L_{b710} | 384 | Lₐ₁₂₆₇ | L_{b1165} |
| 385 | Lₐ₁₃₃₉ | L_{b494} | 386 | Lₐ₁₃₃₉ | L_{b710} | 387 | Lₐ₁₃₃₉ | L_{b1165} |
| 388 | Lₐ₁₃₆₁ | L_{b494} | 389 | Lₐ₁₃₆₁ | L_{b710} | 390 | Lₐ₁₃₆₁ | L_{b1165} |
| 391 | Lₐ₁₅₂₃ | L_{b494} | 392 | Lₐ₁₅₂₃ | L_{b710} | 393 | Lₐ₁₅₂₃ | L_{b1165} |
| 394 | Lₐ₁₅₂₄ | L_{b494} | 395 | Lₐ₁₅₂₄ | L_{b710} | 396 | Lₐ₁₅₂₄ | L_{b1165} |
| 397 | Lₐ₁₅₂₅ | L_{b494} | 398 | Lₐ₁₅₂₅ | L_{b710} | 399 | Lₐ₁₅₂₅ | L_{b1165} |
| 400 | Lₐ₁₅₃₄ | L_{b494} | 401 | Lₐ₁₅₃₄ | L_{b710} | 402 | Lₐ₁₅₃₄ | L_{b1165} |
| 403 | Lₐ₁₅₃₆ | L_{b494} | 404 | Lₐ₁₅₃₆ | L_{b710} | 405 | Lₐ₁₅₃₆ | L_{b1165} |
| 406 | Lₐ₁₅₄₂ | L_{b494} | 407 | Lₐ₁₅₄₂ | L_{b710} | 40 | Lₐ₁₅₄₂ | L_{b1165} |
| 409 | Lₐ₁₅₄₄ | L_{b494} | 410 | Lₐ₁₅₄₄ | L_{b710} | 411 | Lₐ₁₅₄₄ | L_{b1165} |
| 412 | Lₐ₁₆₅₁ | L_{b494} | 413 | Lₐ₁₆₅₁ | L_{b710} | 414 | Lₐ₁₆₅₁ | L_{b1165} |
| 415 | Lₐ₁₇₃₃ | L_{b494} | 416 | Lₐ₁₇₃₃ | L_{b710} | 417 | Lₐ₁₇₃₃ | L_{b1165} |
| 418 | Lₐ₁₇₃₄ | L_{b494} | 419 | Lₐ₁₇₃₄ | L_{b710} | 420 | Lₐ₁₇₃₄ | L_{b1165} |
| 421 | Lₐ₁₇₃₅ | L_{b494} | 422 | Lₐ₁₇₃₅ | L_{b710} | 423 | Lₐ₁₇₃₅ | L_{b1165} |
| 424 | Lₐ₁₇₆₄ | L_{b494} | 425 | Lₐ₁₇₆₄ | L_{b710} | 426 | Lₐ₁₇₆₄ | L_{b1165} |
| 427 | Lₐ₁₈₃₃ | L_{b494} | 428 | Lₐ₁₈₃₃ | L_{b710} | 429 | Lₐ₁₈₃₃ | L_{b1165} |
| 430 | Lₐ₁₈₃₄ | L_{b494} | 431 | Lₐ₁₈₃₄ | L_{b710} | 432 | Lₐ₁₈₃₄ | L_{b1165} |
| 433 | Lₐ₁₈₄₁ | L_{b494} | 434 | Lₐ₁₈₄₁ | L_{b710} | 435 | Lₐ₁₈₄₁ | L_{b1165} |
| 436 | Lₐ₁₉₂₀ | L_{b494} | 437 | Lₐ₁₉₂₀ | L_{b710} | 438 | Lₐ₁₉₂₀ | L_{b1165} |
| 439 | Lₐ₁₉₂₁ | L_{b494} | 440 | Lₐ₁₉₂₁ | L_{b710} | 441 | Lₐ₁₉₂₁ | L_{b1165} |
| 442 | Lₐ₁₉₅₃ | L_{b494} | 443 | Lₐ₁₉₅₃ | L_{b710} | 444 | Lₐ₁₉₅₃ | L_{b1165} |
| 445 | Lₐ₁₉₇₀ | L_{b494} | 446 | Lₐ₁₉₇₀ | L_{b710} | 447 | Lₐ₁₉₇₀ | L_{b1165} |
| 448 | Lₐ₁₉₇₁ | L_{b494} | 449 | Lₐ₁₉₇₁ | L_{b710} | 450 | Lₐ₁₉₇₁ | L_{b1165} |
| 451 | Lₐ₁₉₇₆ | L_{b494} | 452 | Lₐ₁₉₇₆ | L_{b710} | 453 | Lₐ₁₉₇₆ | L_{b1165} |
| 454 | Lₐ₁₉₇₇ | L_{b494} | 455 | Lₐ₁₉₇₇ | L_{b710} | 456 | Lₐ₁₉₇₇ | L_{b1165} |
| 457 | Lₐ₁₉₈₈ | L_{b494} | 458 | Lₐ₁₉₈₈ | L_{b710} | 459 | Lₐ₁₉₈₈ | L_{b1165} |
| 460 | Lₐ₁₉₈₉ | L_{b494} | 461 | Lₐ₁₉₈₉ | L_{b710} | 462 | Lₐ₁₉₈₉ | L_{b1165} |
| 463 | Lₐ₂₁₈₆ | L_{b494} | 464 | Lₐ₂₁₈₆ | L_{b710} | 465 | Lₐ₂₁₈₆ | L_{b1165} |
| 466 | Lₐ₂₁₉₄ | L_{b494} | 467 | Lₐ₂₁₉₄ | L_{b710} | 468 | Lₐ₂₁₉₄ | L_{b1165} |
| 469 | Lₐ₂₂₇₅ | L_{b494} | 470 | Lₐ₂₂₇₅ | L_{b710} | 471 | Lₐ₂₂₇₅ | L_{b1165} |
| 472 | Lₐ₂₃₅₂ | L_{b494} | 473 | Lₐ₂₃₅₂ | L_{b710} | 474 | Lₐ₂₃₅₂ | L_{b1165} |
| 475 | Lₐ₂₄₃₁ | L_{b494} | 476 | Lₐ₂₄₃₁ | L_{b710} | 477 | Lₐ₂₄₃₁ | L_{b1165} |
| 478 | Lₐ₂₄₃₂ | L_{b494} | 479 | Lₐ₂₄₃₂ | L_{b710} | 480 | Lₐ₂₄₃₂ | L_{b1165} |
| 481 | Lₐ₂₄₄₂ | L_{b494} | 482 | Lₐ₂₄₄₂ | L_{b710} | 483 | Lₐ₂₄₄₂ | L_{b1165} |
| 484 | Lₐ₂₄₆₄ | L_{b494} | 485 | Lₐ₂₄₆₄ | L_{b710} | 486 | Lₐ₂₄₆₄ | L_{b1165} |
| 487 | Lₐ₂₆₀₆ | L_{b494} | 488 | Lₐ₂₆₀₆ | L_{b710} | 489 | Lₐ₂₆₀₆ | L_{b1165} |
| 490 | Lₐ₂₆₇₁ | L_{b494} | 491 | Lₐ₂₆₇₁ | L_{b710} | 492 | Lₐ₂₆₇₁ | L_{b1165} |
| 493 | Lₐ₂₇₄₆ | L_{b494} | 494 | Lₐ₂₇₄₆ | L_{b710} | 495 | Lₐ₂₇₄₆ | L_{b1165} |
| 496 | Lₐ₂₇₅₆ | L_{b494} | 497 | Lₐ₂₇₅₆ | L_{b710} | 498 | Lₐ₂₇₅₆ | L_{b1165} |
| 499 | Lₐ₂₇₈₇ | L_{b494} | 500 | Lₐ₂₇₈₇ | L_{b710} | 501 | Lₐ₂₇₈₇ | L_{b1165} |
| 502 | Lₐ₂₉₄₃ | L_{b494} | 503 | Lₐ₂₉₄₃ | L_{b710} | 504 | Lₐ₂₉₄₃ | L_{b1165} |
| 505 | Lₐ₂₈₈₇ | L_{b494} | 506 | Lₐ₂₈₈₇ | L_{b710} | 507 | Lₐ₂₈₈₇ | L_{b1165} |
| 508 | Lₐ₃₀₉₃ | L_{b494} | 509 | Lₐ₃₀₉₃ | L_{b710} | 510 | Lₐ₃₀₉₃ | L_{b1165} |
| 511 | Lₐ₃₁₅₄ | L_{b494} | 512 | Lₐ₃₁₅₄ | L_{b710} | 513 | Lₐ₃₁₅₄ | L_{b1165} |
| 514 | Lₐ₃₂₆₂ | L_{b494} | 515 | Lₐ₃₂₆₂ | L_{b710} | 516 | Lₐ₃₂₆₂ | L_{b1165} |
| 517 | Lₐ₃₂₇₄ | L_{b494} | 518 | Lₐ₃₂₇₄ | L_{b710} | 519 | Lₐ₃₂₇₄ | L_{b1165} |
| 520 | Lₐ₃₂₉₉ | L_{b494} | 521 | Lₐ₃₂₉₉ | L_{b710} | 522 | Lₐ₃₂₉₉ | L_{b1165} |
| 523 | Lₐ₃₄₈₉ | L_{b494} | 524 | Lₐ₃₄₈₉ | L_{b710} | 525 | Lₐ₃₄₈₉ | L_{b1165} |
| 526 | Lₐ₁₇₄₄ | L_{b494} | 527 | Lₐ₁₇₄₄ | L_{b710} | 528 | Lₐ₁₇₄₄ | L_{b1165} |
| 529 | Lₐ₁₇₄₅ | L_{b494} | 530 | Lₐ₁₇₄₅ | L_{b710} | 531 | Lₐ₁₇₄₅ | L_{b1165} |
| 532 | Lₐ₁₇₅₁ | L_{b494} | 533 | Lₐ₁₇₅₁ | L_{b710} | 534 | Lₐ₁₇₅₁ | L_{b1165} |
| 535 | Lₐ₁₇₅₂ | L_{b494} | 536 | Lₐ₁₇₅₂ | L_{b710} | 537 | Lₐ₁₇₅₂ | L_{b1165} |
| 538 | Lₐ₂ | L_{b928} | 539 | Lₐ₂ | L_{b922} | 540 | Lₐ₁ | L_{b144} |
| 541 | Lₐ₃ | L_{b928} | 542 | Lₐ₃ | L_{b922} | 543 | Lₐ₂ | L_{b144} |
| 544 | Lₐ₄ | L_{b928} | 545 | Lₐ₄ | L_{b922} | 546 | Lₐ₃ | L_{b144} |
| 547 | Lₐ₁₁ | L_{b928} | 548 | Lₐ₁₁ | L_{b922} | 549 | Lₐ₄ | L_{b144} |
| 550 | Lₐ₁₂ | L_{b928} | 551 | Lₐ₁₂ | L_{b922} | 552 | Lₐ₁₁ | L_{b144} |
| 553 | Lₐ₁₃ | L_{b928} | 554 | Lₐ₁₃ | L_{b922} | 555 | Lₐ₁₂ | L_{b144} |
| 556 | Lₐ₁₆ | L_{b928} | 557 | Lₐ₁₆ | L_{b922} | 558 | Lₐ₁₃ | L_{b144} |
| 559 | Lₐ₁₇ | L_{b928} | 560 | Lₐ₁₇ | L_{b922} | 561 | Lₐ₁₆ | L_{b144} |
| 562 | Lₐ₂₃ | L_{b928} | 563 | Lₐ₂₃ | L_{b922} | 564 | Lₐ₁₇ | L_{b144} |
| 565 | Lₐ₂₄ | L_{b928} | 566 | Lₐ₂₄ | L_{b922} | 567 | Lₐ₂₃ | L_{b144} |
| 568 | Lₐ₃₀ | L_{b928} | 569 | Lₐ₃₀ | L_{b922} | 570 | Lₐ₂₄ | L_{b144} |
| 571 | Lₐ₃₂ | L_{b928} | 572 | Lₐ₃₂ | L_{b922} | 573 | Lₐ₃₀ | L_{b144} |
| 574 | Lₐ₃₅ | L_{b928} | 575 | Lₐ₃₅ | L_{b922} | 576 | Lₐ₃₂ | L_{b144} |
| 577 | Lₐ₈₆ | L_{b928} | 578 | Lₐ₈₆ | L_{b922} | 579 | Lₐ₃₅ | L_{b144} |
| 580 | Lₐ₈₇ | L_{b928} | 581 | Lₐ₈₇ | L_{b922} | 582 | Lₐ₇₈ | L_{b144} |
| 583 | Lₐ₈₈ | L_{b928} | 584 | Lₐ₈₈ | L_{b922} | 585 | Lₐ₈₆ | L_{b144} |
| 586 | Lₐ₈₉ | L_{b928} | 587 | Lₐ₈₉ | L_{b922} | 588 | Lₐ₈₇ | L_{b144} |
| 589 | Lₐ₁₅₇ | L_{b928} | 590 | Lₐ₁₆₅ | L_{b922} | 591 | Lₐ₈₈ | L_{b144} |
| 592 | Lₐ₁₅₈ | L_{b928} | 593 | Lₐ₁₆₈ | L_{b922} | 594 | Lₐ₈₉ | L_{b144} |
| 595 | Lₐ₁₆₈ | L_{b928} | 596 | Lₐ₁₉₄ | L_{b922} | 597 | Lₐ₁₅₇ | L_{b144} |
| 598 | Lₐ₁₉₄ | L_{b928} | 599 | Lₐ₂₁₅ | L_{b922} | 600 | Lₐ₁₅₈ | L_{b144} |
| 601 | Lₐ₂₁₅ | L_{b928} | 602 | Lₐ₂₁₆ | L_{b922} | 603 | Lₐ₁₆₅ | L_{b144} |
| 604 | Lₐ₂₁₆ | L_{b928} | 605 | Lₐ₂₁₇ | L_{b922} | 606 | Lₐ₁₆₈ | L_{b144} |
| 607 | Lₐ₂₁₇ | L_{b928} | 608 | Lₐ₂₁₈ | L_{b922} | 609 | Lₐ₁₉₀ | L_{b144} |
| 610 | Lₐ₂₁₈ | L_{b928} | 611 | Lₐ₂₂₁ | L_{b922} | 612 | Lₐ₁₉₄ | L_{b144} |
| 613 | Lₐ₂₂₁ | L_{b928} | 614 | Lₐ₂₂₂ | L_{b922} | 615 | Lₐ₂₀₇ | L_{b144} |
| 616 | Lₐ₂₂₂ | L_{b928} | 617 | Lₐ₂₂₃ | L_{b922} | 618 | Lₐ₂₀₈ | L_{b144} |
| 619 | Lₐ₂₂₃ | L_{b928} | 620 | Lₐ₂₂₄ | L_{b922} | 621 | Lₐ₂₁₃ | L_{b144} |
| 622 | Lₐ₂₂₄ | L_{b928} | 623 | Lₐ₂₂₅ | L_{b922} | 624 | Lₐ₂₁₄ | L_{b144} |
| 625 | Lₐ₂₂₅ | L_{b928} | 626 | Lₐ₂₂₆ | L_{b922} | 627 | Lₐ₂₁₅ | L_{b144} |
| 628 | Lₐ₂₂₆ | L_{b928} | 629 | Lₐ₂₂₇ | L_{b922} | 630 | Lₐ₂₁₆ | L_{b144} |
| 631 | Lₐ₂₂₇ | L_{b928} | 632 | Lₐ₂₂₈ | L_{b922} | 633 | Lₐ₂₁₇ | L_{b144} |
| 634 | Lₐ₂₂₈ | L_{b928} | 635 | Lₐ₂₂₉ | L_{b922} | 636 | Lₐ₂₁₈ | L_{b144} |
| 637 | Lₐ₂₂₉ | L_{b928} | 638 | Lₐ₂₃₀ | L_{b922} | 639 | Lₐ₂₂₁ | L_{b144} |
| 640 | Lₐ₂₃₀ | L_{b928} | 641 | Lₐ₂₃₃ | L_{b922} | 642 | Lₐ₂₂₂ | L_{b144} |
| 643 | Lₐ₂₃₃ | L_{b928} | 644 | Lₐ₂₃₄ | L_{b922} | 645 | Lₐ₂₂₃ | L_{b144} |
| 646 | Lₐ₂₃₄ | L_{b928} | 647 | Lₐ₂₃₅ | L_{b922} | 648 | Lₐ₂₂₄ | L_{b144} |
| 649 | Lₐ₂₃₅ | L_{b928} | 650 | Lₐ₂₃₆ | L_{b922} | 651 | Lₐ₂₂₅ | L_{b144} |
| 652 | Lₐ₂₃₆ | L_{b928} | 653 | Lₐ₂₃₇ | L_{b922} | 654 | Lₐ₂₂₆ | L_{b144} |
| 655 | Lₐ₂₃₇ | L_{b928} | 656 | Lₐ₂₃₈ | L_{b922} | 657 | Lₐ₂₂₇ | L_{b144} |
| 658 | Lₐ₂₃₈ | L_{b928} | 659 | Lₐ₂₅₉ | L_{b922} | 660 | Lₐ₂₂₈ | L_{b144} |
| 661 | Lₐ₂₅₉ | L_{b928} | 662 | Lₐ₂₆₀ | L_{b922} | 663 | Lₐ₂₂₉ | L_{b144} |
| 664 | Lₐ₂₆₀ | L_{b928} | 665 | Lₐ₂₇₈ | L_{b922} | 666 | Lₐ₂₃₀ | L_{b144} |
| 667 | Lₐ₂₇₈ | L_{b928} | 668 | Lₐ₂₇₉ | L_{b922} | 669 | Lₐ₂₃₃ | L_{b144} |
| 670 | Lₐ₂₇₉ | L_{b928} | 671 | Lₐ₃₀₂ | L_{b922} | 672 | Lₐ₂₃₄ | L_{b144} |
| 673 | Lₐ₃₀₂ | L_{b928} | 674 | Lₐ₃₀₆ | L_{b922} | 675 | Lₐ₂₃₅ | L_{b144} |
| 676 | Lₐ₃₀₆ | L_{b928} | 677 | Lₐ₃₀₇ | L_{b922} | 678 | Lₐ₂₃₆ | L_{b144} |
| 679 | Lₐ₃₀₇ | L_{b928} | 680 | Lₐ₃₀₈ | L_{b922} | 681 | Lₐ₂₃₇ | L_{b144} |
| 682 | Lₐ₃₀₈ | L_{b928} | 683 | Lₐ₃₀₉ | L_{b922} | 684 | Lₐ₂₃₈ | L_{b144} |
| 685 | Lₐ₃₀₉ | L_{b928} | 686 | Lₐ₃₁₀ | L_{b922} | 687 | Lₐ₂₅₉ | L_{b144} |
| 688 | Lₐ₃₁₀ | L_{b928} | 689 | Lₐ₃₃₀ | L_{b922} | 690 | Lₐ₂₆₀ | L_{b144} |
| 691 | Lₐ₃₃₀ | L_{b928} | 692 | Lₐ₃₃₁ | L_{b922} | 693 | Lₐ₂₇₈ | L_{b144} |
| 694 | Lₐ₃₃₁ | L_{b928} | 695 | Lₐ₃₃₂ | L_{b922} | 696 | Lₐ₂₇₉ | L_{b144} |
| 697 | Lₐ₃₃₂ | L_{b928} | 698 | Lₐ₃₃₃ | L_{b922} | 699 | Lₐ₃₀₂ | L_{b144} |
| 700 | Lₐ₃₃₃ | L_{b928} | 701 | Lₐ₃₃₇ | L_{b922} | 702 | Lₐ₃₀₆ | L_{b144} |
| 703 | Lₐ₃₃₇ | L_{b928} | 704 | Lₐ₃₄₂ | L_{b922} | 705 | Lₐ₃₀₇ | L_{b144} |
| 706 | Lₐ₃₄₂ | L_{b928} | 707 | Lₐ₃₄₃ | L_{b922} | 708 | Lₐ₃₀₈ | L_{b144} |
| 709 | Lₐ₃₄₃ | L_{b928} | 710 | Lₐ₃₅₁ | L_{b922} | 711 | Lₐ₃₀₉ | L_{b144} |
| 712 | Lₐ₃₅₁ | L_{b928} | 713 | Lₐ₃₅₂ | L_{b922} | 714 | Lₐ₃₁₀ | L_{b144} |
| 715 | Lₐ₃₅₂ | L_{b928} | 716 | Lₐ₃₅₆ | L_{b922} | 717 | Lₐ₃₃₀ | L_{b144} |
| 718 | Lₐ₃₅₆ | L_{b928} | 719 | Lₐ₃₅₇ | L_{b922} | 720 | Lₐ₃₃₁ | L_{b144} |
| 721 | Lₐ₃₅₇ | L_{b928} | 722 | Lₐ₃₅₈ | L_{b922} | 723 | Lₐ₃₃₂ | L_{b144} |
| 724 | Lₐ₃₅₈ | L_{b928} | 725 | Lₐ₃₅₉ | L_{b922} | 726 | Lₐ₃₃₃ | L_{b144} |
| 727 | Lₐ₃₅₉ | L_{b928} | 728 | Lₐ₃₆₇ | L_{b922} | 729 | Lₐ₃₃₇ | L_{b144} |
| 730 | Lₐ₃₆₇ | L_{b928} | 731 | Lₐ₄₀₄ | L_{b922} | 732 | Lₐ₃₄₂ | L_{b144} |
| 733 | La₄₀₄ | L_{b928} | 734 | Lₐ₄₀₅ | L_{b922} | 735 | Lₐ₃₄₃ | L_{b144} |
| 736 | Lₐ₄₀₅ | L_{b928} | 737 | Lₐ₄₀₆ | L_{b922} | 738 | Lₐ₃₅₁ | L_{b144} |
| 739 | Lₐ₄₀₆ | L_{b928} | 740 | Lₐ₄₁₃ | L_{b922} | 741 | Lₐ₃₅₂ | L_{b144} |
| 742 | Lₐ₄₁₃ | L_{b928} | 743 | Lₐ₄₁₄ | L_{b922} | 744 | Lₐ₃₅₆ | L_{b144} |
| 745 | Lₐ₄₁₄ | L_{b928} | 746 | Lₐ₄₂₃ | L_{b922} | 747 | Lₐ₃₅₇ | L_{b144} |
| 748 | Lₐ₄₂₃ | L_{b928} | 749 | Lₐ₄₂₇ | L_{b922} | 750 | Lₐ₃₅₈ | L_{b144} |
| 751 | Lₐ₄₂₇ | L_{b928} | 752 | Lₐ₄₂₈ | L_{b922} | 753 | Lₐ₃₅₉ | L_{b144} |
| 754 | Lₐ₄₂₈ | L_{b928} | 755 | Lₐ₄₅₉ | L_{b922} | 756 | Lₐ₃₆₇ | L_{b144} |
| 757 | Lₐ₄₅₉ | L_{b928} | 758 | Lₐ₄₉₅ | L_{b922} | 759 | La₄₀₄ | L_{b144} |
| 760 | Lₐ₄₉₅ | L_{b928} | 761 | Lₐ₅₂₂ | L_{b922} | 762 | Lₐ₄₀₅ | L_{b144} |
| 763 | Lₐ₅₂₂ | L_{b928} | 764 | Lₐ₅₂₃ | L_{b922} | 765 | Lₐ₄₀₆ | L_{b144} |
| 766 | Lₐ₅₂₃ | L_{b928} | 76″ | Lₐ₅₃₇ | L_{b922} | 768 | Lₐ₄₁₃ | L_{b144} |
| 769 | Lₐ₅₃₇ | L_{b928} | 770 | Lₐ₅₄₀ | L_{b922} | 771 | Lₐ₄₁₄ | L_{b144} |
| 772 | Lₐ₅₄₀ | L_{b928} | 773 | Lₐ₅₈₁ | L_{b922} | 774 | Lₐ₄₂₃ | L_{b144} |
| 775 | Lₐ₅₈₁ | L_{b928} | 776 | Lₐ₅₈₂ | L_{b922} | 777 | Lₐ₄₂₇ | L_{b144} |
| 778 | Lₐ₅₈₂ | L_{b928} | 779 | Lₐ₆₈₆ | L_{b922} | 780 | Lₐ₄₂₈ | L_{b144} |
| 781 | Lₐ₆₈₆ | L_{b928} | 782 | Lₐ₇₅₅ | L_{b922} | 783 | Lₐ₄₅₉ | L_{b144} |
| 784 | Lₐ₇₅₅ | L_{b928} | 785 | Lₐ₇₄₁ | L_{b922} | 786 | Lₐ₄₉₅ | L_{b144} |
| 787 | Lₐ₇₄₁ | L_{b928} | 788 | Lₐ₇₄₈ | L_{b922} | 789 | Lₐ₅₁₂ | L_{b144} |
| 790 | Lₐ₇₄₈ | L_{b928} | 791 | Lₐ₇₄₉ | L_{b922} | 792 | Lₐ₅₂₂ | L_{b144} |
| 793 | Lₐ₇₄₉ | L_{b928} | 794 | Lₐ₇₆₂ | L_{b922} | 795 | Lₐ₅₂₃ | L_{b144} |
| 796 | Lₐ₇₆₂ | L_{b928} | 797 | Lₐ₇₆₃ | L_{b922} | 798 | Lₐ₅₃₇ | L_{b144} |
| 799 | Lₐ₇₆₃ | L_{b928} | 800 | Lₐ₇₆₄ | L_{b922} | 801 | Lₐ₅₄₀ | L_{b144} |
| 802 | Lₐ₇₆₄ | L_{b928} | 803 | Lₐ₇₆₅ | L_{b922} | 804 | Lₐ₅₈₁ | L_{b144} |
| 805 | Lₐ₇₆₅ | L_{b928} | 806 | Lₐ₇₆₇ | L_{b922} | 807 | Lₐ₅₈₂ | L_{b144} |
| 808 | Lₐ₇₆₇ | L_{b928} | 809 | Lₐ₇₆₈ | L_{b922} | 810 | Lₐ₅₈₉ | L_{b144} |
| 811 | Lₐ₇₆₈ | L_{b928} | 812 | Lₐ₇₉₁ | L_{b922} | 813 | Lₐ₆₆₈ | L_{b144} |
| 814 | Lₐ₇₉₁ | L_{b928} | 815 | Lₐ₈₂₇ | L_{b922} | 816 | Lₐ₆₆₉ | L_{b144} |
| 817 | Lₐ₈₂₇ | L_{b928} | 818 | Lₐ₈₃₂ | L_{b922} | 819 | Lₐ₆₈₆ | L_{b144} |
| 820 | Lₐ₈₃₂ | L_{b928} | 821 | Lₐ₈₄₃ | L_{b922} | 822 | Lₐ₇₀₁ | L_{b144} |
| 823 | Lₐ₈₄₃ | L_{b928} | 824 | Lₐ₉₃₅ | L_{b922} | 825 | Lₐ₇₁₈ | L_{b144} |
| 826 | Lₐ₉₃₅ | L_{b928} | 827 | Lₐ₉₅₇ | L_{b922} | 828 | Lₐ₇₁₉ | L_{b144} |
| 829 | Lₐ₉₅₇ | L_{b928} | 830 | Lₐ₁₀₃₄ | L_{b922} | 831 | Lₐ₇₂₄ | L_{b144} |
| 832 | Lₐ₁₀₃₄ | L_{b928} | 833 | Lₐ₁₀₃₅ | L_{b922} | 834 | Lₐ₇₂₅ | L_{b144} |
| 835 | Lₐ₁₀₃₅ | L_{b928} | 836 | Lₐ₁₁₄₁ | L_{b922} | 837 | Lₐ₇₄₁ | L_{b144} |
| 838 | Lₐ₁₁₄₁ | L_{b928} | 839 | Lₐ₁₂₆₇ | L_{b922} | 840 | Lₐ₇₄₈ | L_{b144} |
| 841 | Lₐ₁₂₆₇ | L_{b928} | 842 | Lₐ₁₃₃₉ | L_{b922} | 843 | Lₐ₇₄₉ | L_{b144} |
| 844 | Lₐ₁₃₃₉ | L_{b928} | 845 | Lₐ₁₃₆₁ | L_{b922} | 846 | Lₐ₇₅₅ | L_{b144} |
| 847 | Lₐ₁₃₆₁ | L_{b928} | 848 | Lₐ₁₅₂₃ | L_{b922} | 849 | Lₐ₇₆₂ | L_{b144} |
| 850 | Lₐ₁₅₂₃ | L_{b928} | 851 | Lₐ₁₅₂₄ | L_{b922} | 852 | Lₐ₇₆₃ | L_{b144} |
| 853 | Lₐ₁₅₂₄ | L_{b928} | 854 | Lₐ₁₅₂₅ | L_{b922} | 855 | Lₐ₇₆₄ | L_{b144} |
| 856 | Lₐ₁₅₂₅ | L_{b928} | 857 | Lₐ₁₅₃₄ | L_{b922} | 858 | Lₐ₇₆₅ | L_{b144} |
| 859 | Lₐ₁₅₃₄ | L_{b928} | 860 | Lₐ₁₅₃₆ | L_{b922} | 861 | Lₐ₇₆₇ | L_{b144} |
| 862 | Lₐ₁₅₃₆ | L_{b928} | 863 | Lₐ₁₅₄₂ | L_{b922} | 864 | Lₐ₇₆₈ | L_{b144} |
| 865 | Lₐ₁₅₄₂ | L_{b928} | 866 | Lₐ₁₅₄₄ | L_{b922} | 867 | Lₐ₇₉₁ | L_{b144} |
| 868 | Lₐ₁₅₄₄ | L_{b928} | 869 | Lₐ₁₆₅₁ | L_{b922} | 870 | Lₐ₈₂₇ | L_{b144} |
| 871 | Lₐ₁₆₅₁ | L_{b928} | 872 | Lₐ₁₇₃₃ | L_{b922} | 873 | Lₐ₈₃₂ | L_{b144} |
| 874 | Lₐ₁₇₃₃ | L_{b928} | 875 | Lₐ₁₇₃₄ | L_{b922} | 876 | Lₐ₈₄₃ | L_{b144} |
| 877 | Lₐ₁₇₃₄ | L_{b928} | 878 | Lₐ₁₇₃₅ | L_{b922} | 879 | Lₐ₉₃₅ | L_{b144} |
| 880 | Lₐ₁₇₃₅ | L_{b928} | 881 | Lₐ₁₈₃₃ | L_{b922} | 882 | Lₐ₉₅₇ | L_{b144} |
| 883 | Lₐ₁₈₃₃ | L_{b928} | 884 | Lₐ₁₈₃₄ | L_{b922} | 885 | Lₐ₁₀₂₄ | L_{b144} |
| 886 | Lₐ₁₈₃₄ | L_{b928} | 887 | Lₐ₁₉₈₈ | L_{b922} | 888 | Lₐ₁₀₃₄ | L_{b144} |
| 889 | Lₐ₁₉₈₈ | L_{b928} | 890 | Lₐ₁₉₈₉ | L_{b922} | 891 | Lₐ₁₀₃₅ | L_{b144} |
| 892 | Lₐ₁₉₈₉ | L_{b928} | 893 | Lₐ₂₁₈₆ | L_{b922} | 894 | Lₐ₁₁₀₁ | L_{b144} |
| 895 | Lₐ₂₁₈₆ | L_{b928} | 896 | Lₐ₂₁₉₄ | L_{b922} | 897 | Lₐ₁₁₄₁ | L_{b144} |
| 898 | Lₐ₂₁₉₄ | L_{b928} | 899 | Lₐ₂₄₄₂ | L_{b922} | 900 | Lₐ₁₁₈₀ | L_{b144} |
| 901 | Lₐ₂₄₄₂ | L_{b928} | 902 | Lₐ₂₆₀₆ | L_{b922} | 903 | Lₐ₁₁₈₁ | L_{b144} |
| 904 | Lₐ₂₆₀₆ | L_{b928} | 905 | Lₐ₂₇₄₆ | L_{b922} | 906 | Lₐ₁₂₁₃ | L_{b144} |
| 907 | Lₐ₂₇₄₆ | L_{b928} | 908 | Lₐ₂₇₅₆ | L_{b922} | 909 | Lₐ₁₂₃₀ | L_{b144} |
| 910 | Lₐ₂₇₅₆ | L_{b928} | 911 | Lₐ₂₈₈₇ | L_{b922} | 912 | Lₐ₁₂₃₁ | L_{b144} |
| 913 | Lₐ₂₈₈₇ | L_{b928} | 914 | Lₐ₃₀₉₃ | L_{b922} | 915 | Lₐ₁₂₃₆ | L_{b144} |
| 916 | Lₐ₃₀₉₃ | L_{b928} | 917 | Lₐ₃₁₅₄ | L_{b922} | 918 | Lₐ₁₂₃₇ | L_{b144} |
| 919 | Lₐ₃₁₅₄ | L_{b928} | 920 | Lₐ₃₂₆₂ | L_{b922} | 921 | Lₐ₁₂₆₇ | L_{b144} |
| 922 | Lₐ₃₂₆₂ | L_{b928} | 923 | Lₐ₃₄₈₉ | L_{b922} | 924 | Lₐ₁₃₃₉ | L_{b144} |
| 925 | Lₐ₃₄₈₉ | L_{b928} | 926 | Lₐ₁₉₂₁ | L_{b144} | 927 | Lₐ₁₃₆₁ | L_{b144} |
| 928 | Lₐ₂₆₇₁ | L_{b144} | 929 | Lₐ₁₉₅₃ | L_{b144} | 930 | Lₐ₁₅₂₃ | L_{b144} |
| 931 | Lₐ₂₇₄₆ | L_{b144} | 932 | Lₐ₁₉₇₀ | L_{b144} | 933 | Lₐ₁₅₂₄ | L_{b144} |
| 934 | Lₐ₂₇₅₆ | L_{b144} | 935 | Lₐ₁₉₇₁ | L_{b144} | 936 | Lₐ₁₅₂₅ | L_{b144} |
| 937 | Lₐ₂₇₈₇ | L_{b144} | 938 | Lₐ₁₉₇₆ | L_{b144} | 939 | Lₐ₁₅₃₄ | L_{b144} |
| 940 | Lₐ₂₉₄₃ | L_{b144} | 941 | Lₐ₁₉₇₇ | L_{b144} | 942 | Lₐ₁₅₃₆ | L_{b144} |
| 943 | Lₐ₂₈₈₇ | L_{b144} | 944 | Lₐ₁₉₈₈ | L_{b144} | 945 | Lₐ₁₅₄₂ | L_{b144} |
| 946 | Lₐ₃₀₉₃ | L_{b144} | 947 | Lₐ₁₉₈₉ | L_{b144} | 948 | Lₐ₁₅₄₄ | L_{b144} |
| 949 | Lₐ₃₁₅₄ | L_{b144} | 950 | Lₐ₂₁₈₆ | L_{b144} | 951 | Lₐ₁₆₅₁ | L_{b144} |
| 952 | Lₐ₃₂₆₂ | L_{b144} | 953 | Lₐ₂₁₉₄ | L_{b144} | 954 | Lₐ₁₇₃₃ | L_{b144} |
| 955 | Lₐ₃₂₇₄ | L_{b144} | 956 | Lₐ₂₂₇₅ | L_{b144} | 957 | Lₐ₁₇₃₄ | L_{b144} |
| 958 | Lₐ₃₂₉₉ | L_{b144} | 959 | Lₐ₂₃₅₂ | L_{b144} | 960 | Lₐ₁₇₃₅ | L_{b144} |
| 961 | Lₐ₃₄₈₉ | L_{b144} | 962 | Lₐ₂₄₃₁ | L_{b144} | 963 | Lₐ₁₇₆₄ | L_{b144} |
| 964 | Lₐ₁₇₄₄ | L_{b144} | 965 | Lₐ₂₄₃₂ | L_{b144} | 966 | Lₐ₁₈₃₃ | L_{b144} |
| 967 | Lₐ₁₇₄₅ | L_{b144} | 968 | Lₐ₂₄₄₂ | L_{b144} | 969 | Lₐ₁₈₃₄ | L_{b144} |
| 970 | Lₐ₁₇₅₁ | L_{b144} | 971 | Lₐ₂₄₆₄ | L_{b144} | 972 | Lₐ₁₈₄₁ | L_{b144} |
| 973 | Lₐ₁₇₅₂ | L_{b144} | 974 | Lₐ₂₆₀₆ | L_{b144} | 975 | Lₐ₁₉₂₀ | L_{b144} |
| 976 | Lₐ₁ | L_{b1} | 977 | Lₐ₇ | L_{b1} | 978 | Lₐ₄₁ | L_{b1} |
| 979 | Lₐ₁ | L_{b2} | 980 | Lₐ₇ | L_{b2} | 981 | Lₐ₄₁ | L_{b2} |
| 982 | Lₐ₁ | L_{b3} | 983 | Lₐ₇ | L_{b3} | 984 | Lₐ₄₁ | L_{b3} |
| 985 | Lₐ₁ | L_{b4} | 986 | Lₐ₇ | L_{b4} | 987 | Lₐ₄₁ | L_{b4} |
| 988 | Lₐ₁ | L_{b5} | 989 | Lₐ₇ | L_{b5} | 990 | Lₐ₄₁ | L_{b5} |
| 991 | Lₐ₁ | L_{b6} | 992 | Lₐ₇ | L_{b6} | 993 | Lₐ₄₁ | L_{b6} |
| 994 | Lₐ₁ | L_{b7} | 995 | Lₐ₇ | L_{b7} | 996 | Lₐ₄₁ | L_{b7} |
| 997 | Lₐ₁ | L_{b8} | 998 | Lₐ₇ | L_{b8} | 999 | Lₐ₄₁ | L_{b8} |
| 1000 | Lₐ₁ | L_{b17} | 1001 | Lₐ₇ | L_{b17} | 1002 | Lₐ₄₁ | L_{b17} |
| 1003 | Lₐ₁ | L_{b19} | 1004 | Lₐ₇ | L_{b19} | 1005 | Lₐ₄₁ | L_{b19} |
| 1006 | Lₐ₁ | L_{b25} | 1007 | Lₐ₇ | L_{b25} | 1008 | Lₐ₄₁ | L_{b25} |
| 1009 | Lₐ₁ | L_{b62} | 1010 | Lₐ₇ | L_{b62} | 1011 | Lₐ₄₁ | L_{b62} |
| 1012 | Lₐ₁ | L_{b73} | 1013 | Lₐ₇ | L_{b73} | 1014 | Lₐ₄₁ | L_{b73} |
| 1015 | Lₐ₁ | L_{b79} | 1016 | Lₐ₇ | L_{b79} | 1017 | Lₐ₄₁ | L_{b79} |
| 1018 | Lₐ₁ | L_{b111} | 1019 | Lₐ₇ | L_{b111} | 1020 | Lₐ₄₁ | L_{b111} |
| 1021 | Lₐ₁ | L_{b112} | 1022 | Lₐ₇ | L_{b112} | 1023 | Lₐ₄₁ | L_{b112} |
| 1024 | Lₐ₁ | L_{b114} | 1025 | Lₐ₇ | L_{b114} | 1026 | Lₐ₄₁ | L_{b114} |
| 1027 | Lₐ₁ | L_{b117} | 1028 | Lₐ₇ | L_{b117} | 1029 | Lₐ₄₁ | L_{b117} |
| 1030 | Lₐ₁ | L_{b127} | 1031 | Lₐ₇ | L_{b127} | 1032 | Lₐ₄₁ | L_{b127} |
| 1033 | Lₐ₁ | L_{b135} | 1034 | Lₐ₇ | L_{b135} | 1035 | Lₐ₄₁ | L_{b135} |
| 1036 | Lₐ₁ | L_{b160} | 1037 | Lₐ₇ | L_{b160} | 1038 | Lₐ₄₁ | L_{b160} |
| 1039 | Lₐ₁ | L_{b161} | 1040 | Lₐ₇ | L_{b161} | 1041 | Lₐ₄₁ | L_{b161} |
| 1042 | Lₐ₁ | L_{b170} | 1043 | Lₐ₇ | L_{b170} | 1044 | Lₐ₄₁ | L_{b170} |
| 1045 | Lₐ₁ | L_{b188} | 1046 | Lₐ₇ | L_{b188} | 1047 | Lₐ₄₁ | L_{b188} |
| 1048 | Lₐ₁ | L_{b224} | 1049 | Lₐ₇ | L_{b224} | 1050 | Lₐ₄₁ | L_{b224} |
| 1051 | Lₐ₁ | L_{b249} | 1052 | Lₐ₇ | L_{b249} | 1053 | Lₐ₄₁ | L_{b249} |
| 1054 | Lₐ₁ | L_{b289} | 1055 | Lₐ₇ | L_{b289} | 1056 | Lₐ₄₁ | L_{b289} |
| 1057 | Lₐ₁ | L_{b332} | 1058 | Lₐ₇ | L_{b332} | 1059 | Lₐ₄₁ | L_{b332} |
| 1060 | Lₐ₁ | L_{b336} | 1061 | Lₐ₇ | L_{b336} | 1062 | Lₐ₄₁ | L_{b336} |
| 1063 | Lₐ₁ | L_{b337} | 1064 | Lₐ₇ | L_{b337} | 1065 | Lₐ₄₁ | L_{b337} |
| 1066 | Lₐ₁ | L_{b382} | 1067 | Lₐ₇ | L_{b382} | 1068 | Lₐ₄₁ | L_{b382} |
| 1069 | Lₐ₁ | L_{b474} | 1070 | Lₐ₇ | L_{b474} | 1071 | Lₐ₄₁ | L_{b474} |
| 1072 | Lₐ₁ | L_{b487} | 1073 | Lₐ₇ | L_{b487} | 1074 | Lₐ₄₁ | L_{b487} |
| 1075 | Lₐ₁ | L_{b488} | 1076 | Lₐ₇ | L_{b488} | 1077 | Lₐ₄₁ | L_{b488} |
| 1078 | Lₐ₁ | L_{b489} | 1079 | Lₐ₇ | L_{b489} | 1080 | Lₐ₄₁ | L_{b489} |
| 1081 | Lₐ₁ | L_{b490} | 1082 | Lₐ₇ | L_{b490} | 1083 | Lₐ₄₁ | L_{b490} |
| 1084 | Lₐ₁ | L_{b498} | 1085 | Lₐ₇ | L_{b498} | 1086 | Lₐ₄₁ | L_{b498} |
| 1087 | Lₐ₁ | L_{b499} | 1088 | Lₐ₇ | L_{b499} | 1089 | Lₐ₄₁ | L_{b499} |
| 1090 | Lₐ₁ | L_{b543} | 1091 | Lₐ₇ | L_{b543} | 1092 | Lₐ₄₁ | L_{b543} |
| 1093 | Lₐ₁ | L_{b544} | 1094 | Lₐ₇ | L_{b544} | 1095 | Lₐ₄₁ | L_{b544} |
| 1096 | Lₐ₁ | L_{b545} | 1097 | Lₐ₇ | L_{b545} | 1098 | Lₐ₄₁ | L_{b545} |
| 1099 | Lₐ₁ | L_{b597} | 1100 | Lₐ₇ | L_{b597} | 1101 | Lₐ₄₁ | L_{b597} |
| 1102 | Lₐ₁ | L_{b598} | 1103 | Lₐ₇ | L_{b598} | 1104 | Lₐ₄₁ | L_{b598} |
| 1105 | Lₐ₁ | L_{b602} | 1106 | Lₐ₇ | L_{b602} | 1107 | Lₐ₄₁ | L_{b602} |
| 1108 | Lₐ₁ | L_{b651} | 1109 | Lₐ₇ | L_{b651} | 1110 | Lₐ₄₁ | L_{b651} |
| 1111 | Lₐ₁ | L_{b652} | 1112 | Lₐ₇ | L_{b652} | 1113 | Lₐ₄₁ | L_{b652} |
| 1114 | Lₐ₁ | L_{b705} | 1115 | Lₐ₇ | L_{b705} | 1116 | Lₐ₄₁ | L_{b705} |
| 1117 | Lₐ₁ | L_{b706} | 1118 | Lₐ₇ | L_{b706} | 1119 | Lₐ₄₁ | L_{b706} |
| 1120 | Lₐ₁ | L_{b727} | 1121 | Lₐ₇ | L_{b727} | 1122 | Lₐ₄₁ | L_{b727} |
| 1123 | Lₐ₁ | L_{b728} | 1124 | Lₐ₇ | L_{b728} | 1125 | Lₐ₄₁ | L_{b728} |
| 1126 | Lₐ₁ | L_{b759} | 1127 | Lₐ₇ | L_{b759} | 1128 | Lₐ₄₁ | L_{b759} |
| 1129 | Lₐ₁ | L_{b760} | 1130 | Lₐ₇ | L_{b760} | 1131 | Lₐ₄₁ | L_{b760} |
| 1132 | Lₐ₁ | L_{b813} | 1133 | Lₐ₇ | L_{b813} | 1134 | Lₐ₄₁ | L_{b813} |
| 1135 | Lₐ₁ | L_{b814} | 1136 | Lₐ₇ | L_{b814} | 1137 | Lₐ₄₁ | L_{b814} |
| 1138 | Lₐ₁ | L_{b815} | 1139 | Lₐ₇ | L_{b815} | 1140 | Lₐ₄₁ | L_{b815} |
| 1141 | Lₐ₁ | L_{b818} | 1142 | Lₐ₇ | L_{b818} | 1143 | Lₐ₄₁ | L_{b818} |
| 1144 | Lₐ₁ | L_{b867} | 1145 | Lₐ₇ | L_{b867} | 1146 | Lₐ₄₁ | L_{b867} |
| 1147 | Lₐ₁ | L_{b868} | 1148 | Lₐ₇ | L_{b868} | 1149 | Lₐ₄₁ | L_{b868} |
| 1150 | Lₐ₁ | L_{b927} | 1151 | Lₐ₇ | L_{b927} | 1152 | Lₐ₄₁ | L_{b927} |
| 1153 | Lₐ₁ | L_{b949} | 1154 | Lₐ₇ | L_{b949} | 1155 | Lₐ₄₁ | L_{b949} |
| 1156 | Lₐ₁ | L_{b1003} | 1157 | Lₐ₇ | L_{b1003} | 1158 | Lₐ₄₁ | L_{b1003} |
| 1159 | Lₐ₁ | L_{b1052} | 1160 | Lₐ₇ | L_{b1052} | 1161 | Lₐ₄₁ | L_{b1052} |
| 1162 | Lₐ₁ | L_{b1053} | 1163 | Lₐ₇ | L_{b1053} | 1164 | Lₐ₄₁ | L_{b1053} |
| 1165 | Lₐ₁ | L_{b1057} | 1166 | Lₐ₇ | L_{b1057} | 1167 | Lₐ₄₁ | L_{b1057} |
| 1168 | Lₐ₁ | L_{b1106} | 1169 | Lₐ₇ | L_{b1106} | 1170 | Lₐ₄₁ | L_{b1106} |
| 1171 | Lₐ₁ | L_{b1107} | 1172 | Lₐ₇ | L_{b1107} | 1173 | Lₐ₄₁ | L_{b1107} |
| 1174 | Lₐ₁ | L_{b1111} | 1175 | Lₐ₇ | L_{b1111} | 1176 | Lₐ₄₁ | L_{b1111} |
| 1177 | Lₐ₁ | L_{b1160} | 1178 | Lₐ₇ | L_{b1160} | 1179 | Lₐ₄₁ | L_{b1160} |
| 1180 | Lₐ₁ | L_{b1161} | 1181 | Lₐ₇ | L_{b1161} | 1182 | Lₐ₄₁ | L_{b1161} |
| 1183 | Lₐ₁ | L_{b1162} | 1184 | Lₐ₇ | L_{b1162} | 1185 | Lₐ₄₁ | L_{b1162} |
| 1186 | Lₐ₁ | L_{b1163} | 1187 | Lₐ₇ | L_{b1163} | 1188 | Lₐ₄₁ | L_{b1163} |
| 1189 | Lₐ₁ | L_{b1214} | 1190 | Lₐ₇ | L_{b1214} | 1191 | Lₐ₄₁ | L_{b1214} |
| 1192 | Lₐ₁ | L_{b1215} | 1193 | Lₐ₇ | L_{b1215} | 1194 | Lₐ₄₁ | L_{b1215} |
| 1195 | Lₐ₁ | L_{b1216} | 1196 | Lₐ₇ | L_{b1216} | 1197 | Lₐ₄₁ | L_{b1216} |
| 1198 | Lₐ₁ | L_{b1217} | 1199 | Lₐ₇ | L_{b1217} | 1200 | Lₐ₄₁ | L_{b1217} |
| 1201 | Lₐ₁ | L_{b1219} | 1202 | Lₐ₇ | L_{b1219} | 1203 | Lₐ₄₁ | L_{b1219} |
| 1204 | Lₐ₁ | L_{b1270} | 1205 | Lₐ₇ | L_{b1270} | 1206 | Lₐ₄₁ | L_{b1270} |
| 1207 | Lₐ₁ | L_{b1271} | 1208 | Lₐ₇ | L_{b1271} | 1209 | Lₐ₄₁ | L_{b1271} |
| 1210 | Lₐ₁ | L_{b1273} | 1211 | Lₐ₇ | L_{b1273} | 1212 | Lₐ₄₁ | L_{b1273} |
| 1213 | Lₐ₁ | L_{b1376} | 1214 | Lₐ₇ | L_{b1376} | 1215 | Lₐ₄₁ | L_{b1376} |
| 1216 | Lₐ₁ | L_{b1377} | 1217 | Lₐ₇ | L_{b1377} | 1218 | Lₐ₄₁ | L_{b1377} |
| 1219 | Lₐ₁ | L_{b1378} | 1220 | Lₐ₇ | L_{b1378} | 1221 | Lₐ₄₁ | L_{b1378} |
| 1222 | Lₐ₅₈ | L_{b1} | 1223 | Lₐ₅₉ | L_{b1} | 1224 | Lₐ₆₄ | L_{b1} |
| 1225 | Lₐ₅₈ | L_{b2} | 1226 | Lₐ₅₉ | L_{b2} | 1227 | Lₐ₆₄ | L_{b2} |
| 1228 | Lₐ₅₈ | L_{b3} | 1229 | Lₐ₅₉ | L_{b3} | 1230 | Lₐ₆₄ | L_{b3} |
| 1231 | Lₐ₅₈ | L_{b4} | 1232 | Lₐ₅₉ | L_{b4} | 1233 | Lₐ₆₄ | L_{b4} |
| 1234 | Lₐ₅₈ | L_{b5} | 1235 | Lₐ₅₉ | L_{b5} | 1236 | Lₐ₆₄ | L_{b5} |
| 1237 | Lₐ₅₈ | L_{b6} | 1238 | Lₐ₅₉ | L_{b6} | 1239 | Lₐ₆₄ | L_{b6} |
| 1240 | Lₐ₅₈ | L_{b7} | 1241 | Lₐ₅₉ | L_{b7} | 1242 | Lₐ₆₄ | L_{b7} |
| 1243 | Lₐ₅₈ | L_{b8} | 1244 | Lₐ₅₉ | L_{b8} | 1245 | Lₐ₆₄ | L_{b8} |
| 1246 | Lₐ₅₈ | L_{b17} | 1247 | Lₐ₅₉ | L_{b17} | 1248 | Lₐ₆₄ | L_{b17} |
| 1249 | Lₐ₅₈ | L_{b19} | 1250 | Lₐ₅₉ | L_{b19} | 1251 | Lₐ₆₄ | L_{b19} |
| 1252 | Lₐ₅₈ | L_{b25} | 1253 | Lₐ₅₉ | L_{b25} | 1254 | Lₐ₆₄ | L_{b25} |
| 1255 | Lₐ₅₈ | L_{b62} | 1256 | Lₐ₅₉ | L_{b62} | 1257 | Lₐ₆₄ | L_{b62} |
| 1258 | Lₐ₅₈ | L_{b73} | 1259 | Lₐ₅₉ | L_{b73} | 1260 | Lₐ₆₄ | L_{b73} |
| 1261 | Lₐ₅₈ | L_{b79} | 1262 | Lₐ₅₉ | L_{b79} | 1263 | Lₐ₆₄ | L_{b79} |
| 1264 | Lₐ₅₈ | L_{b111} | 1265 | Lₐ₅₉ | L_{b111} | 1266 | Lₐ₆₄ | L_{b111} |
| 1267 | Lₐ₅₈ | L_{b112} | 1268 | Lₐ₅₉ | L_{b112} | 1269 | Lₐ₆₄ | L_{b112} |
| 1270 | Lₐ₅₈ | L_{b114} | 1271 | Lₐ₅₉ | L_{b114} | 1272 | Lₐ₆₄ | L_{b114} |
| 1273 | Lₐ₅₈ | L_{b117} | 1274 | Lₐ₅₉ | L_{b117} | 1275 | Lₐ₆₄ | L_{b117} |
| 1276 | Lₐ₅₈ | L_{b127} | 1277 | Lₐ₅₉ | L_{b127} | 1278 | Lₐ₆₄ | L_{b127} |
| 1279 | Lₐ₅₈ | L_{b135} | 1280 | Lₐ₅₉ | L_{b135} | 1281 | Lₐ₆₄ | L_{b135} |
| 1282 | Lₐ₅₈ | L_{b160} | 1283 | Lₐ₅₉ | L_{b160} | 1284 | Lₐ₆₄ | L_{b160} |
| 1285 | Lₐ₅₈ | L_{b161} | 1286 | Lₐ₅₉ | L_{b161} | 1287 | Lₐ₆₄ | L_{b161} |
| 1288 | Lₐ₅₈ | L_{b170} | 1289 | Lₐ₅₉ | L_{b170} | 1290 | Lₐ₆₄ | L_{b170} |
| 1291 | Lₐ₅₈ | L_{b188} | 1292 | Lₐ₅₉ | L_{b188} | 1293 | Lₐ₆₄ | L_{b188} |
| 1294 | Lₐ₅₈ | L_{b224} | 1295 | Lₐ₅₉ | L_{b224} | 1296 | Lₐ₆₄ | L_{b224} |
| 1297 | Lₐ₅₈ | L_{b249} | 1298 | Lₐ₅₉ | L_{b249} | 1299 | Lₐ₆₄ | L_{b249} |
| 1300 | Lₐ₅₈ | L_{b289} | 1301 | Lₐ₅₉ | L_{b289} | 1302 | Lₐ₆₄ | L_{b289} |
| 1303 | Lₐ₅₈ | L_{b332} | 1304 | Lₐ₅₉ | L_{b332} | 1305 | Lₐ₆₄ | L_{b332} |
| 1306 | Lₐ₅₈ | L_{b336} | 1307 | Lₐ₅₉ | L_{b336} | 1308 | Lₐ₆₄ | L_{b336} |
| 1309 | Lₐ₅₈ | L_{b337} | 1310 | Lₐ₅₉ | L_{b337} | 1311 | Lₐ₆₄ | L_{b337} |
| 1312 | Lₐ₅₈ | L_{b382} | 1313 | Lₐ₅₉ | L_{b382} | 1314 | Lₐ₆₄ | L_{b382} |
| 1315 | Lₐ₅₈ | L_{b474} | 1316 | Lₐ₅₉ | L_{b474} | 1317 | Lₐ₆₄ | L_{b474} |
| 1318 | Lₐ₅₈ | L_{b487} | 1319 | Lₐ₅₉ | L_{b487} | 1320 | Lₐ₆₄ | L_{b487} |
| 1321 | Lₐ₅₈ | L_{b488} | 1322 | Lₐ₅₉ | L_{b488} | 1323 | Lₐ₆₄ | L_{b488} |
| 1324 | Lₐ₅₈ | L_{b489} | 1325 | Lₐ₅₉ | L_{b489} | 1326 | Lₐ₆₄ | L_{b489} |
| 1327 | Lₐ₅₈ | L_{b490} | 1328 | Lₐ₅₉ | L_{b490} | 1329 | Lₐ₆₄ | L_{b490} |
| 1330 | Lₐ₅₈ | L_{b498} | 1331 | Lₐ₅₉ | L_{b498} | 1332 | Lₐ₆₄ | L_{b498} |
| 1333 | Lₐ₅₈ | L_{b499} | 1334 | Lₐ₅₉ | L_{b499} | 1335 | Lₐ₆₄ | L_{b499} |
| 1336 | Lₐ₅₈ | L_{b543} | 1337 | Lₐ₅₉ | L_{b543} | 1338 | Lₐ₆₄ | L_{b543} |
| 1339 | Lₐ₅₈ | L_{b544} | 1340 | Lₐ₅₉ | L_{b544} | 1341 | Lₐ₆₄ | L_{b544} |
| 1342 | Lₐ₅₈ | L_{b545} | 1343 | Lₐ₅₉ | L_{b545} | 1344 | Lₐ₆₄ | L_{b545} |
| 1345 | Lₐ₅₈ | L_{b597} | 1346 | Lₐ₅₉ | L_{b597} | 1347 | Lₐ₆₄ | L_{b597} |
| 1348 | Lₐ₅₈ | L_{b598} | 1349 | Lₐ₅₉ | L_{b598} | 1350 | Lₐ₆₄ | L_{b598} |
| 1351 | Lₐ₅₈ | L_{b602} | 1352 | Lₐ₅₉ | L_{b602} | 1353 | Lₐ₆₄ | L_{b602} |
| 1354 | Lₐ₅₈ | L_{b651} | 1355 | Lₐ₅₉ | L_{b651} | 1356 | Lₐ₆₄ | L_{b651} |
| 1357 | Lₐ₅₈ | L_{b652} | 1358 | Lₐ₅₉ | L_{b652} | 1359 | Lₐ₆₄ | L_{b652} |
| 1360 | Lₐ₅₈ | L_{b705} | 1361 | Lₐ₅₉ | L_{b705} | 1362 | Lₐ₆₄ | L_{b705} |
| 1363 | Lₐ₅₈ | L_{b706} | 1364 | Lₐ₅₉ | L_{b706} | 1365 | Lₐ₆₄ | L_{b706} |
| 1366 | Lₐ₅₈ | L_{b727} | 1367 | Lₐ₅₉ | L_{b727} | 1368 | Lₐ₆₄ | L_{b727} |
| 1369 | Lₐ₅₈ | L_{b728} | 1370 | Lₐ₅₉ | L_{b728} | 1371 | Lₐ₆₄ | L_{b728} |
| 1372 | Lₐ₅₈ | L_{b759} | 1373 | Lₐ₅₉ | L_{b759} | 1374 | Lₐ₆₄ | L_{b759} |
| 1375 | Lₐ₅₈ | L_{b760} | 1376 | Lₐ₅₉ | L_{b760} | 1377 | Lₐ₆₄ | L_{b760} |
| 1378 | Lₐ₅₈ | L_{b813} | 1379 | Lₐ₅₉ | L_{b813} | 1380 | Lₐ₆₄ | L_{b813} |
| 1381 | Lₐ₅₈ | L_{b814} | 1382 | Lₐ₅₉ | L_{b814} | 1383 | Lₐ₆₄ | L_{b814} |
| 1384 | Lₐ₅₈ | L_{b815} | 1385 | Lₐ₅₉ | L_{b815} | 1386 | Lₐ₆₄ | L_{b815} |
| 1387 | Lₐ₅₈ | L_{b818} | 1388 | Lₐ₅₉ | L_{b818} | 1389 | Lₐ₆₄ | L_{b818} |
| 1390 | Lₐ₅₈ | L_{b867} | 1391 | Lₐ₅₉ | L_{b867} | 1392 | Lₐ₆₄ | L_{b867} |
| 1393 | Lₐ₅₈ | L_{b868} | 1394 | Lₐ₅₉ | L_{b868} | 1395 | Lₐ₆₄ | L_{b868} |
| 1396 | Lₐ₅₈ | L_{b927} | 1397 | Lₐ₅₉ | L_{b927} | 1398 | Lₐ₆₄ | L_{b927} |
| 1399 | Lₐ₅₈ | L_{b949} | 1400 | Lₐ₅₉ | L_{b949} | 1401 | Lₐ₆₄ | L_{b949} |
| 1402 | Lₐ₅₈ | L_{b1003} | 1403 | Lₐ₅₉ | L_{b1003} | 1404 | Lₐ₆₄ | L_{b1003} |
| 1405 | Lₐ₅₈ | L_{b1052} | 1406 | Lₐ₅₉ | L_{b1052} | 1407 | Lₐ₆₄ | L_{b1052} |
| 1408 | Lₐ₅₈ | L_{b1053} | 1409 | Lₐ₅₉ | L_{b1053} | 1410 | Lₐ₆₄ | L_{b1053} |
| 1411 | Lₐ₅₈ | L_{b1057} | 1412 | Lₐ₅₉ | L_{b1057} | 1413 | Lₐ₆₄ | L_{b1057} |
| 1414 | Lₐ₅₈ | L_{b1106} | 1415 | Lₐ₅₉ | L_{b1106} | 1416 | Lₐ₆₄ | L_{b1106} |
| 1417 | Lₐ₅₈ | L_{b1107} | 1418 | Lₐ₅₉ | L_{b1107} | 1419 | Lₐ₆₄ | L_{b1107} |
| 1420 | Lₐ₅₈ | L_{b1111} | 1421 | Lₐ₅₉ | L_{b1111} | 1422 | Lₐ₆₄ | L_{b1111} |
| 1423 | Lₐ₅₈ | L_{b1160} | 1424 | Lₐ₅₉ | L_{b1160} | 1425 | Lₐ₆₄ | L_{b1160} |
| 1426 | Lₐ₅₈ | L_{b1161} | 1427 | Lₐ₅₉ | L_{b1161} | 1428 | Lₐ₆₄ | L_{b1161} |
| 1429 | Lₐ₅₈ | L_{b1162} | 1430 | Lₐ₅₉ | L_{b1162} | 1431 | Lₐ₆₄ | L_{b1162} |
| 1432 | Lₐ₅₈ | L_{b1163} | 1433 | Lₐ₅₉ | L_{b1163} | 1434 | Lₐ₆₄ | L_{b1163} |
| 1435 | Lₐ₅₈ | L_{b1214} | 1436 | Lₐ₅₉ | L_{b1214} | 1437 | Lₐ₆₄ | L_{b1214} |
| 1438 | Lₐ₅₈ | L_{b1215} | 1439 | Lₐ₅₉ | L_{b1215} | 1440 | Lₐ₆₄ | L_{b1215} |
| 1441 | Lₐ₅₈ | L_{b1216} | 1442 | Lₐ₅₉ | L_{b1216} | 1443 | Lₐ₆₄ | L_{b1216} |
| 1444 | Lₐ₅₈ | L_{b1217} | 1445 | Lₐ₅₉ | L_{b1217} | 1446 | Lₐ₆₄ | L_{b1217} |
| 1447 | Lₐ₅₈ | L_{b1219} | 1448 | Lₐ₅₉ | L_{b1219} | 1449 | Lₐ₆₄ | L_{b1219} |
| 1450 | Lₐ₅₈ | L_{b1270} | 1451 | Lₐ₅₉ | L_{b1270} | 1452 | Lₐ₆₄ | L_{b1270} |
| 1453 | Lₐ₅₈ | L_{b1271} | 1454 | Lₐ₅₉ | L_{b1271} | 1455 | Lₐ₆₄ | L_{b1271} |
| 1456 | Lₐ₅₈ | L_{b1273} | 1457 | Lₐ₅₉ | L_{b1273} | 1458 | Lₐ₆₄ | L_{b1273} |
| 1459 | Lₐ₅₈ | L_{b1376} | 1460 | Lₐ₅₉ | L_{b1376} | 1461 | Lₐ₆₄ | L_{b1376} |
| 1462 | Lₐ₅₈ | L_{b1377} | 1463 | Lₐ₅₉ | L_{b1377} | 1464 | Lₐ₆₄ | L_{b1377} |
| 1465 | Lₐ₅₈ | L_{b1378} | 1466 | Lₐ₅₉ | L_{b1378} | 1467 | Lₐ₆₄ | L_{b1378} |
| 1468 | Lₐ₇₈ | L_{b1} | 1469 | Lₐ₈₄ | L_{b1} | 1470 | Lₐ₁₂₃ | L_{b1} |
| 1471 | Lₐ₇₈ | L_{b2} | 1472 | Lₐ₈₄ | L_{b2} | 1473 | Lₐ₁₂₃ | L_{b2} |
| 1474 | Lₐ₇₈ | L_{b3} | 1475 | Lₐ₈₄ | L_{b3} | 1476 | Lₐ₁₂₃ | L_{b3} |
| 1477 | Lₐ₇₈ | L_{b4} | 1478 | Lₐ₈₄ | L_{b4} | 1479 | Lₐ₁₂₃ | L_{b4} |
| 1480 | Lₐ₇₈ | L_{b5} | 1481 | Lₐ₈₄ | L_{b5} | 1482 | Lₐ₁₂₃ | L_{b5} |
| 1483 | Lₐ₇₈ | L_{b6} | 1484 | Lₐ₈₄ | L_{b6} | 1485 | Lₐ₁₂₃ | L_{b6} |
| 1486 | Lₐ₇₈ | L_{b7} | 1487 | Lₐ₈₄ | L_{b7} | 1488 | Lₐ₁₂₃ | L_{b7} |
| 1489 | Lₐ₇₈ | L_{b8} | 1490 | Lₐ₈₄ | L_{b8} | 1491 | Lₐ₁₂₃ | L_{b8} |
| 1492 | Lₐ₇₈ | L_{b17} | 1493 | Lₐ₈₄ | L_{b17} | 1494 | Lₐ₁₂₃ | L_{b17} |
| 1495 | Lₐ₇₈ | L_{b19} | 1496 | Lₐ₈₄ | L_{b19} | 1497 | Lₐ₁₂₃ | L_{b19} |
| 1498 | Lₐ₇₈ | L_{b25} | 1499 | Lₐ₈₄ | L_{b25} | 1500 | Lₐ₁₂₃ | L_{b25} |
| 1501 | Lₐ₇₈ | L_{b62} | 1502 | Lₐ₈₄ | L_{b62} | 1503 | Lₐ₁₂₃ | L_{b62} |
| 1504 | Lₐ₇₈ | L_{b73} | 1505 | Lₐ₈₄ | L_{b73} | 1506 | Lₐ₁₂₃ | L_{b73} |
| 1507 | Lₐ₇₈ | L_{b79} | 1508 | Lₐ₈₄ | L_{b79} | 1509 | Lₐ₁₂₃ | L_{b79} |
| 1510 | Lₐ₇₈ | L_{b111} | 1511 | Lₐ₈₄ | L_{b111} | 1512 | Lₐ₁₂₃ | L_{b111} |
| 1513 | Lₐ₇₈ | L_{b112} | 1514 | Lₐ₈₄ | L_{b112} | 1515 | Lₐ₁₂₃ | L_{b112} |
| 1516 | Lₐ₇₈ | L_{b114} | 1517 | Lₐ₈₄ | L_{b114} | 1518 | Lₐ₁₂₃ | L_{b114} |
| 1519 | Lₐ₇₈ | L_{b117} | 1520 | Lₐ₈₄ | L_{b117} | 1521 | Lₐ₁₂₃ | L_{b117} |
| 1522 | Lₐ₇₈ | L_{b127} | 1523 | Lₐ₈₄ | L_{b127} | 1524 | Lₐ₁₂₃ | L_{b127} |
| 1525 | Lₐ₇₈ | L_{b135} | 1526 | Lₐ₈₄ | L_{b135} | 1527 | Lₐ₁₂₃ | L_{b135} |
| 1528 | Lₐ₇₈ | L_{b160} | 1529 | Lₐ₈₄ | L_{b160} | 1530 | Lₐ₁₂₃ | L_{b160} |
| 1531 | Lₐ₇₈ | L_{b161} | 1532 | Lₐ₈₄ | L_{b161} | 1533 | Lₐ₁₂₃ | L_{b161} |
| 1534 | Lₐ₇₈ | L_{b170} | 1535 | Lₐ₈₄ | L_{b170} | 1536 | Lₐ₁₂₃ | L_{b170} |
| 1537 | Lₐ₇₈ | L_{b188} | 1538 | Lₐ₈₄ | L_{b188} | 1539 | Lₐ₁₂₃ | L_{b188} |
| 1540 | Lₐ₇₈ | L_{b224} | 1541 | Lₐ₈₄ | L_{b224} | 1542 | Lₐ₁₂₃ | L_{b224} |
| 1543 | Lₐ₇₈ | L_{b249} | 1544 | Lₐ₈₄ | L_{b249} | 1545 | Lₐ₁₂₃ | L_{b249} |
| 1546 | Lₐ₇₈ | L_{b289} | 1547 | Lₐ₈₄ | L_{b289} | 1548 | Lₐ₁₂₃ | L_{b289} |
| 1549 | Lₐ₇₈ | L_{b332} | 1550 | Lₐ₈₄ | L_{b332} | 1551 | Lₐ₁₂₃ | L_{b332} |
| 1552 | Lₐ₇₈ | L_{b336} | 1553 | Lₐ₈₄ | L_{b336} | 1554 | Lₐ₁₂₃ | L_{b336} |
| 1555 | Lₐ₇₈ | L_{b337} | 1556 | Lₐ₈₄ | L_{b337} | 1557 | Lₐ₁₂₃ | L_{b337} |
| 1558 | Lₐ₇₈ | L_{b382} | 1559 | Lₐ₈₄ | L_{b382} | 1560 | Lₐ₁₂₃ | L_{b382} |
| 1561 | Lₐ₇₈ | L_{b474} | 1562 | Lₐ₈₄ | L_{b474} | 1563 | Lₐ₁₂₃ | L_{b474} |
| 1564 | Lₐ₇₈ | L_{b487} | 1565 | Lₐ₈₄ | L_{b487} | 1566 | Lₐ₁₂₃ | L_{b487} |
| 1567 | Lₐ₇₈ | L_{b488} | 1568 | Lₐ₈₄ | L_{b488} | 1569 | Lₐ₁₂₃ | L_{b488} |
| 1570 | Lₐ₇₈ | L_{b489} | 1571 | Lₐ₈₄ | L_{b489} | 1572 | Lₐ₁₂₃ | L_{b489} |
| 1573 | Lₐ₇₈ | L_{b490} | 1574 | Lₐ₈₄ | L_{b490} | 1575 | Lₐ₁₂₃ | L_{b490} |
| 1576 | Lₐ₇₈ | L_{b498} | 1577 | Lₐ₈₄ | L_{b498} | 1578 | Lₐ₁₂₃ | L_{b498} |
| 1579 | Lₐ₇₈ | L_{b499} | 1580 | Lₐ₈₄ | L_{b499} | 1581 | Lₐ₁₂₃ | L_{b499} |
| 1582 | Lₐ₇₈ | L_{b543} | 1583 | Lₐ₈₄ | L_{b543} | 1584 | Lₐ₁₂₃ | L_{b543} |
| 1585 | Lₐ₇₈ | L_{b544} | 1586 | Lₐ₈₄ | L_{b544} | 1587 | Lₐ₁₂₃ | L_{b544} |
| 1588 | Lₐ₇₈ | L_{b545} | 1589 | Lₐ₈₄ | L_{b545} | 1590 | Lₐ₁₂₃ | L_{b545} |
| 1591 | Lₐ₇₈ | L_{b597} | 1592 | Lₐ₈₄ | L_{b597} | 1593 | Lₐ₁₂₃ | L_{b597} |
| 1594 | Lₐ₇₈ | L_{b598} | 1595 | Lₐ₈₄ | L_{b598} | 1596 | Lₐ₁₂₃ | L_{b598} |
| 1597 | Lₐ₇₈ | L_{b602} | 1598 | Lₐ₈₄ | L_{b602} | 1599 | Lₐ₁₂₃ | L_{b602} |
| 1600 | Lₐ₇₈ | L_{b651} | 1601 | Lₐ₈₄ | L_{b651} | 1602 | Lₐ₁₂₃ | L_{b651} |
| 1603 | Lₐ₇₈ | L_{b652} | 1604 | Lₐ₈₄ | L_{b652} | 1605 | Lₐ₁₂₃ | L_{b652} |
| 1606 | Lₐ₇₈ | L_{b705} | 1607 | Lₐ₈₄ | L_{b705} | 1608 | Lₐ₁₂₃ | L_{b705} |
| 1609 | Lₐ₇₈ | L_{b706} | 1610 | Lₐ₈₄ | L_{b706} | 1611 | Lₐ₁₂₃ | L_{b706} |
| 1612 | Lₐ₇₈ | L_{b727} | 1613 | Lₐ₈₄ | L_{b727} | 1614 | Lₐ₁₂₃ | L_{b727} |
| 1615 | Lₐ₇₈ | L_{b728} | 1616 | Lₐ₈₄ | L_{b728} | 1617 | Lₐ₁₂₃ | L_{b728} |
| 1618 | Lₐ₇₈ | L_{b759} | 1619 | Lₐ₈₄ | L_{b759} | 1620 | Lₐ₁₂₃ | L_{b759} |
| 1621 | Lₐ₇₈ | L_{b760} | 1622 | Lₐ₈₄ | L_{b760} | 1623 | Lₐ₁₂₃ | L_{b760} |
| 1624 | Lₐ₇₈ | L_{b813} | 1625 | Lₐ₈₄ | L_{b813} | 1626 | Lₐ₁₂₃ | L_{b813} |
| 1627 | Lₐ₇₈ | L_{b814} | 1628 | Lₐ₈₄ | L_{b814} | 1629 | Lₐ₁₂₃ | L_{b814} |
| 1630 | Lₐ₇₈ | L_{b815} | 1631 | Lₐ₈₄ | L_{b815} | 1632 | Lₐ₁₂₃ | L_{b815} |
| 1633 | Lₐ₇₈ | L_{b818} | 1634 | Lₐ₈₄ | L_{b818} | 1635 | Lₐ₁₂₃ | L_{b818} |
| 1636 | Lₐ₇₈ | L_{b867} | 1637 | Lₐ₈₄ | L_{b867} | 1638 | Lₐ₁₂₃ | L_{b867} |
| 1639 | Lₐ₇₈ | L_{b868} | 1640 | Lₐ₈₄ | L_{b868} | 1641 | Lₐ₁₂₃ | L_{b868} |
| 1642 | Lₐ₇₈ | L_{b927} | 1643 | Lₐ₈₄ | L_{b927} | 1644 | Lₐ₁₂₃ | L_{b927} |
| 1645 | Lₐ₇₈ | L_{b949} | 1646 | Lₐ₈₄ | L_{b949} | 1647 | Lₐ₁₂₃ | L_{b949} |
| 1648 | Lₐ₇₈ | L_{b1003} | 1649 | Lₐ₈₄ | L_{b1003} | 1650 | Lₐ₁₂₃ | L_{b1003} |
| 1651 | Lₐ₇₈ | L_{b1052} | 1652 | Lₐ₈₄ | L_{b1052} | 1653 | Lₐ₁₂₃ | L_{b1052} |
| 1654 | Lₐ₇₈ | L_{b1053} | 1655 | Lₐ₈₄ | L_{b1053} | 1656 | Lₐ₁₂₃ | L_{b1053} |
| 1657 | Lₐ₇₈ | L_{b1057} | 1658 | Lₐ₈₄ | L_{b1057} | 1659 | Lₐ₁₂₃ | L_{b1057} |
| 1660 | Lₐ₇₈ | L_{b1106} | 1661 | Lₐ₈₄ | L_{b1106} | 1662 | Lₐ₁₂₃ | L_{b1106} |
| 1663 | Lₐ₇₈ | L_{b1107} | 1664 | Lₐ₈₄ | L_{b1107} | 1665 | Lₐ₁₂₃ | L_{b1107} |
| 1666 | Lₐ₇₈ | L_{b1111} | 1667 | Lₐ₈₄ | L_{b1111} | 1668 | Lₐ₁₂₃ | L_{b1111} |
| 1669 | Lₐ₇₈ | L_{b1160} | 1670 | Lₐ₈₄ | L_{b1160} | 1671 | Lₐ₁₂₃ | L_{b1160} |
| 1672 | Lₐ₇₈ | L_{b1161} | 1673 | Lₐ₈₄ | L_{b1161} | 1674 | Lₐ₁₂₃ | L_{b1161} |
| 1675 | Lₐ₇₈ | L_{b1162} | 1676 | Lₐ₈₄ | L_{b1162} | 1677 | Lₐ₁₂₃ | L_{b1162} |
| 1678 | Lₐ₇₈ | L_{b1163} | 1679 | Lₐ₈₄ | L_{b1163} | 1680 | Lₐ₁₂₃ | L_{b1163} |
| 1681 | Lₐ₇₈ | L_{b1214} | 1682 | Lₐ₈₄ | L_{b1214} | 1683 | Lₐ₁₂₃ | L_{b1214} |
| 1684 | Lₐ₇₈ | L_{b1215} | 1685 | Lₐ₈₄ | L_{b1215} | 1686 | Lₐ₁₂₃ | L_{b1215} |
| 1687 | Lₐ₇₈ | L_{b1216} | 1688 | Lₐ₈₄ | L_{b1216} | 1689 | Lₐ₁₂₃ | L_{b1216} |
| 1690 | Lₐ₇₈ | L_{b1217} | 1691 | Lₐ₈₄ | L_{b1217} | 1692 | Lₐ₁₂₃ | L_{b1217} |
| 1693 | Lₐ₇₈ | L_{b1219} | 1694 | Lₐ₈₄ | L_{b1219} | 1695 | Lₐ₁₂₃ | L_{b1219} |
| 1696 | Lₐ₇₈ | L_{b1270} | 1697 | Lₐ₈₄ | L_{b1270} | 1698 | Lₐ₁₂₃ | L_{b1270} |
| 1699 | Lₐ₇₈ | L_{b1271} | 1700 | Lₐ₈₄ | L_{b1271} | 1701 | Lₐ₁₂₃ | L_{b1271} |
| 1702 | Lₐ₇₈ | L_{b1273} | 1703 | Lₐ₈₄ | L_{b1273} | 1704 | Lₐ₁₂₃ | L_{b1273} |
| 1705 | Lₐ₇₈ | L_{b1376} | 1706 | Lₐ₈₄ | L_{b1376} | 1707 | Lₐ₁₂₃ | L_{b1376} |
| 1708 | Lₐ₇₈ | L_{b1377} | 1709 | Lₐ₈₄ | L_{b1377} | 1710 | Lₐ₁₂₃ | L_{b1377} |
| 1711 | Lₐ₇₈ | L_{b1378} | 1712 | Lₐ₈₄ | L_{b1378} | 1713 | Lₐ₁₂₃ | L_{b1378} |
| 1714 | Lₐ₈₀ | L_{b1} | 1715 | Lₐ₈₉ | L_{b1} | 1716 | Lₐ₁₂₇ | L_{b1} |
| 1717 | Lₐ₈₀ | L_{b2} | 1718 | Lₐ₈₉ | L_{b2} | 1719 | Lₐ₁₂₇ | L_{b2} |
| 1720 | Lₐ₈₀ | L_{b3} | 1721 | Lₐ₈₉ | L_{b3} | 1722 | Lₐ₁₂₇ | L_{b3} |
| 1723 | Lₐ₈₀ | L_{b4} | 1724 | Lₐ₈₉ | L_{b4} | 1725 | Lₐ₁₂₇ | L_{b4} |
| 1726 | Lₐ₈₀ | L_{b5} | 1727 | Lₐ₈₉ | L_{b5} | 1728 | Lₐ₁₂₇ | L_{b5} |
| 1729 | Lₐ₈₀ | L_{b6} | 1730 | Lₐ₈₉ | L_{b6} | 1731 | Lₐ₁₂₇ | L_{b6} |
| 1732 | Lₐ₈₀ | L_{b7} | 1733 | Lₐ₈₉ | L_{b7} | 1734 | Lₐ₁₂₇ | L_{b7} |
| 1735 | Lₐ₈₀ | L_{b8} | 1736 | Lₐ₈₉ | L_{b8} | 1737 | Lₐ₁₂₇ | L_{b8} |
| 1738 | Lₐ₈₀ | L_{b17} | 1739 | Lₐ₈₉ | L_{b17} | 1740 | Lₐ₁₂₇ | L_{b17} |
| 1741 | Lₐ₈₀ | L_{b19} | 1742 | Lₐ₈₉ | L_{b19} | 1743 | Lₐ₁₂₇ | L_{b19} |
| 1744 | Lₐ₈₀ | L_{b25} | 1745 | Lₐ₈₉ | L_{b25} | 1746 | Lₐ₁₂₇ | L_{b25} |
| 1747 | Lₐ₈₀ | L_{b62} | 1748 | Lₐ₈₉ | L_{b62} | 1749 | Lₐ₁₂₇ | L_{b62} |
| 1750 | Lₐ₈₀ | L_{b73} | 1751 | Lₐ₈₉ | L_{b73} | 1752 | Lₐ₁₂₇ | L_{b73} |
| 1753 | Lₐ₈₀ | L_{b79} | 1754 | Lₐ₈₉ | L_{b79} | 1755 | Lₐ₁₂₇ | L_{b79} |
| 1756 | Lₐ₈₀ | L_{b111} | 1757 | Lₐ₈₉ | L_{b111} | 1758 | Lₐ₁₂₇ | L_{b111} |
| 1759 | Lₐ₈₀ | L_{b112} | 1760 | Lₐ₈₉ | L_{b112} | 1761 | Lₐ₁₂₇ | L_{b112} |
| 1762 | Lₐ₈₀ | L_{b114} | 1763 | Lₐ₈₉ | L_{b114} | 1764 | Lₐ₁₂₇ | L_{b114} |
| 1765 | Lₐ₈₀ | L_{b117} | 1766 | Lₐ₈₉ | L_{b117} | 1767 | Lₐ₁₂₇ | L_{b117} |
| 1768 | Lₐ₈₀ | L_{b127} | 1769 | Lₐ₈₉ | L_{b127} | 1770 | Lₐ₁₂₇ | L_{b127} |
| 1771 | Lₐ₈₀ | L_{b135} | 1772 | Lₐ₈₉ | L_{b135} | 1773 | Lₐ₁₂₇ | L_{b135} |
| 1774 | Lₐ₈₀ | L_{b160} | 1775 | Lₐ₈₉ | L_{b160} | 1776 | Lₐ₁₂₇ | L_{b160} |
| 1777 | Lₐ₈₀ | L_{b161} | 1778 | Lₐ₈₉ | L_{b161} | 1779 | Lₐ₁₂₇ | L_{b161} |
| 1780 | Lₐ₈₀ | L_{b170} | 1781 | Lₐ₈₉ | L_{b170} | 1782 | Lₐ₁₂₇ | L_{b170} |
| 1783 | Lₐ₈₀ | L_{b188} | 1784 | Lₐ₈₉ | L_{b188} | 1785 | Lₐ₁₂₇ | L_{b188} |
| 1786 | Lₐ₈₀ | L_{b224} | 1787 | Lₐ₈₉ | L_{b224} | 1788 | Lₐ₁₂₇ | L_{b224} |
| 1789 | Lₐ₈₀ | L_{b249} | 1790 | Lₐ₈₉ | L_{b249} | 1791 | Lₐ₁₂₇ | L_{b249} |
| 1792 | Lₐ₈₀ | L_{b289} | 1793 | Lₐ₈₉ | L_{b289} | 1794 | Lₐ₁₂₇ | L_{b289} |
| 1795 | Lₐ₈₀ | L_{b332} | 1796 | Lₐ₈₉ | L_{b332} | 1797 | Lₐ₁₂₇ | L_{b332} |
| 1798 | Lₐ₈₀ | L_{b336} | 1799 | Lₐ₈₉ | L_{b336} | 1800 | Lₐ₁₂₇ | L_{b336} |
| 1801 | Lₐ₈₀ | L_{b337} | 1802 | Lₐ₈₉ | L_{b337} | 1803 | Lₐ₁₂₇ | L_{b337} |
| 1804 | Lₐ₈₀ | L_{b382} | 1805 | Lₐ₈₉ | L_{b382} | 1806 | Lₐ₁₂₇ | L_{b382} |
| 1807 | Lₐ₈₀ | L_{b474} | 1808 | Lₐ₈₉ | L_{b474} | 1809 | Lₐ₁₂₇ | L_{b474} |
| 1810 | Lₐ₈₀ | L_{b487} | 1811 | Lₐ₈₉ | L_{b487} | 1812 | Lₐ₁₂₇ | L_{b487} |
| 1813 | Lₐ₈₀ | L_{b488} | 1814 | Lₐ₈₉ | L_{b488} | 1815 | Lₐ₁₂₇ | L_{b488} |
| 1816 | Lₐ₈₀ | L_{b489} | 1817 | Lₐ₈₉ | L_{b489} | 1818 | Lₐ₁₂₇ | L_{b489} |
| 1819 | Lₐ₈₀ | L_{b490} | 1820 | Lₐ₈₉ | L_{b490} | 1821 | Lₐ₁₂₇ | L_{b490} |
| 1822 | Lₐ₈₀ | L_{b498} | 1823 | Lₐ₈₉ | L_{b498} | 1824 | Lₐ₁₂₇ | L_{b498} |
| 1825 | Lₐ₈₀ | L_{b499} | 1826 | Lₐ₈₉ | L_{b499} | 1827 | Lₐ₁₂₇ | L_{b499} |
| 1828 | Lₐ₈₀ | L_{b543} | 1829 | Lₐ₈₉ | L_{b543} | 1830 | Lₐ₁₂₇ | L_{b543} |
| 1831 | Lₐ₈₀ | L_{b544} | 1832 | Lₐ₈₉ | L_{b544} | 1833 | Lₐ₁₂₇ | L_{b544} |
| 1834 | Lₐ₈₀ | L_{b545} | 1835 | Lₐ₈₉ | L_{b545} | 1836 | Lₐ₁₂₇ | L_{b545} |
| 1837 | Lₐ₈₀ | L_{b597} | 1838 | Lₐ₈₉ | L_{b597} | 1839 | Lₐ₁₂₇ | L_{b597} |
| 1840 | Lₐ₈₀ | L_{b598} | 1841 | Lₐ₈₉ | L_{b598} | 1842 | Lₐ₁₂₇ | L_{b598} |
| 1843 | Lₐ₈₀ | L_{b602} | 1844 | Lₐ₈₉ | L_{b602} | 1845 | Lₐ₁₂₇ | L_{b602} |
| 1846 | Lₐ₈₀ | L_{b651} | 1847 | Lₐ₈₉ | L_{b651} | 1848 | Lₐ₁₂₇ | L_{b651} |
| 1849 | Lₐ₈₀ | L_{b652} | 1850 | Lₐ₈₉ | L_{b652} | 1851 | Lₐ₁₂₇ | L_{b652} |
| 1852 | Lₐ₈₀ | L_{b705} | 1853 | Lₐ₈₉ | L_{b705} | 1854 | Lₐ₁₂₇ | L_{b705} |
| 1855 | Lₐ₈₀ | L_{b706} | 1856 | Lₐ₈₉ | L_{b706} | 1857 | Lₐ₁₂₇ | L_{b706} |
| 1858 | Lₐ₈₀ | L_{b727} | 1859 | Lₐ₈₉ | L_{b727} | 1860 | Lₐ₁₂₇ | L_{b727} |
| 1861 | Lₐ₈₀ | L_{b728} | 1862 | Lₐ₈₉ | L_{b728} | 1863 | Lₐ₁₂₇ | L_{b728} |
| 1864 | Lₐ₈₀ | L_{b759} | 1865 | Lₐ₈₉ | L_{b759} | 1866 | Lₐ₁₂₇ | L_{b759} |
| 1867 | Lₐ₈₀ | L_{b760} | 1868 | Lₐ₈₉ | L_{b760} | 1869 | Lₐ₁₂₇ | L_{b760} |
| 1870 | Lₐ₈₀ | L_{b813} | 1871 | Lₐ₈₉ | L_{b813} | 1872 | Lₐ₁₂₇ | L_{b813} |
| 1873 | Lₐ₈₀ | L_{b814} | 1874 | Lₐ₈₉ | L_{b814} | 1875 | Lₐ₁₂₇ | L_{b814} |
| 1876 | Lₐ₈₀ | L_{b815} | 1877 | Lₐ₈₉ | L_{b815} | 1878 | Lₐ₁₂₇ | L_{b815} |
| 1879 | Lₐ₈₀ | L_{b818} | 1880 | Lₐ₈₉ | L_{b818} | 1881 | Lₐ₁₂₇ | L_{b818} |
| 1882 | Lₐ₈₀ | L_{b867} | 1883 | Lₐ₈₉ | L_{b867} | 1884 | Lₐ₁₂₇ | L_{b867} |
| 1885 | Lₐ₈₀ | L_{b868} | 1886 | Lₐ₈₉ | L_{b868} | 1887 | Lₐ₁₂₇ | L_{b868} |
| 1888 | Lₐ₈₀ | L_{b927} | 1889 | Lₐ₈₉ | L_{b927} | 1890 | Lₐ₁₂₇ | L_{b927} |
| 1891 | Lₐ₈₀ | L_{b949} | 1892 | Lₐ₈₉ | L_{b949} | 1893 | Lₐ₁₂₇ | L_{b949} |
| 1894 | Lₐ₈₀ | L_{b1003} | 1895 | Lₐ₈₉ | L_{b1003} | 1896 | Lₐ₁₂₇ | L_{b1003} |
| 1897 | Lₐ₈₀ | L_{b1052} | 1898 | Lₐ₈₉ | L_{b1052} | 1899 | Lₐ₁₂₇ | L_{b1052} |
| 1900 | Lₐ₈₀ | L_{b1053} | 1901 | Lₐ₈₉ | L_{b1053} | 1902 | Lₐ₁₂₇ | L_{b1053} |
| 1903 | Lₐ₈₀ | L_{b1057} | 1904 | Lₐ₈₉ | L_{b1057} | 1905 | Lₐ₁₂₇ | L_{b1057} |
| 1906 | Lₐ₈₀ | L_{b1106} | 1907 | Lₐ₈₉ | L_{b1106} | 1908 | Lₐ₁₂₇ | L_{b1106} |
| 1909 | Lₐ₈₀ | L_{b1107} | 1910 | Lₐ₈₉ | L_{b1107} | 1911 | Lₐ₁₂₇ | L_{b1107} |
| 1912 | Lₐ₈₀ | L_{b1111} | 1913 | Lₐ₈₉ | L_{b1111} | 1914 | Lₐ₁₂₇ | L_{b1111} |
| 1915 | Lₐ₈₀ | L_{b1160} | 1916 | Lₐ₈₉ | L_{b1160} | 1917 | Lₐ₁₂₇ | L_{b1160} |
| 1918 | Lₐ₈₀ | L_{b1161} | 1919 | Lₐ₈₉ | L_{b1161} | 1920 | Lₐ₁₂₇ | L_{b1161} |
| 1921 | Lₐ₈₀ | L_{b1162} | 1922 | Lₐ₈₉ | L_{b1162} | 1923 | Lₐ₁₂₇ | L_{b1162} |
| 1924 | Lₐ₈₀ | L_{b1163} | 1925 | Lₐ₈₉ | L_{b1163} | 1926 | Lₐ₁₂₇ | L_{b1163} |
| 1927 | Lₐ₈₀ | L_{b1214} | 1928 | Lₐ₈₉ | L_{b1214} | 1929 | Lₐ₁₂₇ | L_{b1214} |
| 1930 | Lₐ₈₀ | L_{b1215} | 1931 | Lₐ₈₉ | L_{b1215} | 1932 | Lₐ₁₂₇ | L_{b1215} |
| 1933 | Lₐ₈₀ | L_{b1216} | 1934 | Lₐ₈₉ | L_{b1216} | 1935 | Lₐ₁₂₇ | L_{b1216} |
| 1936 | Lₐ₈₀ | L_{b1217} | 1937 | Lₐ₈₉ | L_{b1217} | 1938 | Lₐ₁₂₇ | L_{b1217} |
| 1939 | Lₐ₈₀ | L_{b1219} | 1940 | Lₐ₈₉ | L_{b1219} | 1941 | Lₐ₁₂₇ | L_{b1219} |
| 1942 | Lₐ₈₀ | L_{b1270} | 1943 | Lₐ₈₉ | L_{b1270} | 1944 | Lₐ₁₂₇ | L_{b1270} |
| 1945 | Lₐ₈₀ | L_{b1271} | 1946 | Lₐ₈₉ | L_{b1271} | 1947 | Lₐ₁₂₇ | L_{b1271} |
| 1948 | Lₐ₈₀ | L_{b1273} | 1949 | Lₐ₈₉ | L_{b1273} | 1950 | Lₐ₁₂₇ | L_{b1273} |
| 1951 | Lₐ₈₀ | L_{b1376} | 1952 | Lₐ₈₉ | L_{b1376} | 1953 | Lₐ₁₂₇ | L_{b1376} |
| 1954 | Lₐ₈₀ | L_{b1377} | 1955 | Lₐ₈₉ | L_{b1377} | 1956 | Lₐ₁₂₇ | L_{b1377} |
| 1957 | Lₐ₈₀ | L_{b1378} | 1958 | Lₐ₈₉ | L_{b1378} | 1959 | Lₐ₁₂₇ | L_{b1378} |
| 1960 | Lₐ₁₄₇ | L_{b1} | 1961 | Lₐ₁₅₇ | L_{b1} | 1962 | Lₐ₁₉₀ | L_{b1} |
| 1963 | Lₐ₁₄₇ | L_{b2} | 1964 | Lₐ₁₅₇ | L_{b2} | 1965 | Lₐ₁₉₀ | L_{b2} |
| 1966 | Lₐ₁₄₇ | L_{b3} | 1967 | Lₐ₁₅₇ | L_{b3} | 1968 | Lₐ₁₉₀ | L_{b3} |
| 1969 | Lₐ₁₄₇ | L_{b4} | 1970 | Lₐ₁₅₇ | L_{b4} | 1971 | Lₐ₁₉₀ | L_{b4} |
| 1972 | Lₐ₁₄₇ | L_{b5} | 1973 | Lₐ₁₅₇ | L_{b5} | 1974 | Lₐ₁₉₀ | L_{b5} |
| 1975 | Lₐ₁₄₇ | L_{b6} | 1976 | Lₐ₁₅₇ | L_{b6} | 1977 | Lₐ₁₉₀ | L_{b6} |
| 1978 | Lₐ₁₄₇ | L_{b7} | 1979 | Lₐ₁₅₇ | L_{b7} | 1980 | Lₐ₁₉₀ | L_{b7} |
| 1981 | Lₐ₁₄₇ | L_{b8} | 1982 | Lₐ₁₅₇ | L_{b8} | 1983 | Lₐ₁₉₀ | L_{b8} |
| 1984 | Lₐ₁₄₇ | L_{b17} | 1985 | Lₐ₁₅₇ | L_{b17} | 1986 | Lₐ₁₉₀ | L_{b17} |
| 1987 | Lₐ₁₄₇ | L_{b19} | 1988 | Lₐ₁₅₇ | L_{b19} | 1989 | Lₐ₁₉₀ | L_{b19} |
| 1990 | Lₐ₁₄₇ | L_{b25} | 1991 | Lₐ₁₅₇ | L_{b25} | 1992 | Lₐ₁₉₀ | L_{b25} |
| 1993 | Lₐ₁₄₇ | L_{b62} | 1994 | Lₐ₁₅₇ | L_{b62} | 1995 | Lₐ₁₉₀ | L_{b62} |
| 1996 | Lₐ₁₄₇ | L_{b73} | 1997 | Lₐ₁₅₇ | L_{b73} | 1998 | Lₐ₁₉₀ | L_{b73} |
| 1999 | Lₐ₁₄₇ | L_{b79} | 2000 | Lₐ₁₅₇ | L_{b79} | 2001 | Lₐ₁₉₀ | L_{b79} |
| 2002 | Lₐ₁₄₇ | L_{b111} | 2003 | Lₐ₁₅₇ | L_{b111} | 2004 | Lₐ₁₉₀ | L_{b111} |
| 2005 | Lₐ₁₄₇ | L_{b112} | 2006 | Lₐ₁₅₇ | L_{b112} | 2007 | Lₐ₁₉₀ | L_{b112} |
| 2008 | Lₐ₁₄₇ | L_{b114} | 2009 | Lₐ₁₅₇ | L_{b114} | 2010 | Lₐ₁₉₀ | L_{b114} |
| 2011 | Lₐ₁₄₇ | L_{b117} | 2012 | Lₐ₁₅₇ | L_{b117} | 2013 | Lₐ₁₉₀ | L_{b117} |
| 2014 | Lₐ₁₄₇ | L_{b127} | 2015 | Lₐ₁₅₇ | L_{b127} | 2016 | Lₐ₁₉₀ | L_{b127} |
| 2017 | Lₐ₁₄₇ | L_{b135} | 2018 | Lₐ₁₅₇ | L_{b135} | 2019 | Lₐ₁₉₀ | L_{b135} |
| 2020 | Lₐ₁₄₇ | L_{b160} | 2021 | Lₐ₁₅₇ | L_{b160} | 2022 | Lₐ₁₉₀ | L_{b160} |
| 2023 | Lₐ₁₄₇ | L_{b161} | 2024 | Lₐ₁₅₇ | L_{b161} | 2025 | Lₐ₁₉₀ | L_{b161} |
| 2026 | Lₐ₁₄₇ | L_{b170} | 2027 | Lₐ₁₅₇ | L_{b170} | 2028 | Lₐ₁₉₀ | L_{b170} |
| 2029 | Lₐ₁₄₇ | L_{b188} | 2030 | Lₐ₁₅₇ | L_{b188} | 2031 | Lₐ₁₉₀ | L_{b188} |
| 2032 | Lₐ₁₄₇ | L_{b224} | 2033 | Lₐ₁₅₇ | L_{b224} | 2034 | Lₐ₁₉₀ | L_{b224} |
| 2035 | Lₐ₁₄₇ | L_{b249} | 2036 | Lₐ₁₅₇ | L_{b249} | 2037 | Lₐ₁₉₀ | L_{b249} |
| 2038 | Lₐ₁₄₇ | L_{b289} | 2039 | Lₐ₁₅₇ | L_{b289} | 2040 | Lₐ₁₉₀ | L_{b289} |
| 2041 | Lₐ₁₄₇ | L_{b332} | 2042 | Lₐ₁₅₇ | L_{b332} | 2043 | Lₐ₁₉₀ | L_{b332} |
| 2044 | Lₐ₁₄₇ | L_{b336} | 2045 | Lₐ₁₅₇ | L_{b336} | 2046 | Lₐ₁₉₀ | L_{b336} |
| 2047 | Lₐ₁₄₇ | L_{b337} | 2048 | Lₐ₁₅₇ | L_{b337} | 2049 | Lₐ₁₉₀ | L_{b337} |
| 2050 | Lₐ₁₄₇ | L_{b382} | 2051 | Lₐ₁₅₇ | L_{b382} | 2052 | Lₐ₁₉₀ | L_{b382} |
| 2053 | Lₐ₁₄₇ | L_{b474} | 2054 | Lₐ₁₅₇ | L_{b474} | 2055 | Lₐ₁₉₀ | L_{b474} |
| 2056 | Lₐ₁₄₇ | L_{b487} | 2057 | Lₐ₁₅₇ | L_{b487} | 2058 | Lₐ₁₉₀ | L_{b487} |
| 2059 | Lₐ₁₄₇ | L_{b488} | 2060 | Lₐ₁₅₇ | L_{b488} | 2061 | Lₐ₁₉₀ | L_{b488} |
| 2062 | Lₐ₁₄₇ | L_{b489} | 2063 | Lₐ₁₅₇ | L_{b489} | 2064 | Lₐ₁₉₀ | L_{b489} |
| 2065 | Lₐ₁₄₇ | L_{b490} | 2066 | Lₐ₁₅₇ | L_{b490} | 2067 | Lₐ₁₉₀ | L_{b490} |
| 2068 | Lₐ₁₄₇ | L_{b498} | 2069 | Lₐ₁₅₇ | L_{b498} | 2070 | Lₐ₁₉₀ | L_{b498} |
| 2071 | Lₐ₁₄₇ | L_{b499} | 2072 | Lₐ₁₅₇ | L_{b499} | 2073 | Lₐ₁₉₀ | L_{b499} |
| 2074 | Lₐ₁₄₇ | L_{b543} | 2075 | Lₐ₁₅₇ | L_{b543} | 2076 | Lₐ₁₉₀ | L_{b543} |
| 2077 | Lₐ₁₄₇ | L_{b544} | 2078 | Lₐ₁₅₇ | L_{b544} | 2079 | Lₐ₁₉₀ | L_{b544} |
| 2080 | Lₐ₁₄₇ | L_{b545} | 2081 | Lₐ₁₅₇ | L_{b545} | 2082 | Lₐ₁₉₀ | L_{b545} |
| 2083 | Lₐ₁₄₇ | L_{b597} | 2084 | Lₐ₁₅₇ | L_{b597} | 2085 | Lₐ₁₉₀ | L_{b597} |
| 2086 | Lₐ₁₄₇ | L_{b598} | 2087 | Lₐ₁₅₇ | L_{b598} | 2088 | Lₐ₁₉₀ | L_{b598} |
| 2089 | Lₐ₁₄₇ | L_{b602} | 2090 | Lₐ₁₅₇ | L_{b602} | 2091 | Lₐ₁₉₀ | L_{b602} |
| 2092 | Lₐ₁₄₇ | L_{b651} | 2093 | Lₐ₁₅₇ | L_{b651} | 2094 | Lₐ₁₉₀ | L_{b651} |
| 2095 | Lₐ₁₄₇ | L_{b652} | 2096 | Lₐ₁₅₇ | L_{b652} | 2097 | Lₐ₁₉₀ | L_{b652} |
| 2098 | Lₐ₁₄₇ | L_{b705} | 2099 | Lₐ₁₅₇ | L_{b705} | 2100 | Lₐ₁₉₀ | L_{b705} |
| 2101 | Lₐ₁₄₇ | L_{b706} | 2102 | Lₐ₁₅₇ | L_{b706} | 2103 | Lₐ₁₉₀ | L_{b706} |
| 2104 | Lₐ₁₄₇ | L_{b727} | 2105 | Lₐ₁₅₇ | L_{b727} | 2106 | Lₐ₁₉₀ | L_{b727} |
| 2107 | Lₐ₁₄₇ | L_{b728} | 2108 | Lₐ₁₅₇ | L_{b728} | 2109 | Lₐ₁₉₀ | L_{b728} |
| 2110 | Lₐ₁₄₇ | L_{b759} | 2111 | Lₐ₁₅₇ | L_{b759} | 2112 | Lₐ₁₉₀ | L_{b759} |
| 2113 | Lₐ₁₄₇ | L_{b760} | 2114 | Lₐ₁₅₇ | L_{b760} | 2115 | Lₐ₁₉₀ | L_{b760} |
| 2116 | Lₐ₁₄₇ | L_{b813} | 2117 | Lₐ₁₅₇ | L_{b813} | 2118 | Lₐ₁₉₀ | L_{b813} |
| 2119 | Lₐ₁₄₇ | L_{b814} | 2120 | Lₐ₁₅₇ | L_{b814} | 2121 | Lₐ₁₉₀ | L_{b814} |
| 2122 | Lₐ₁₄₇ | L_{b815} | 2123 | Lₐ₁₅₇ | L_{b815} | 2124 | Lₐ₁₉₀ | L_{b815} |
| 2125 | Lₐ₁₄₇ | L_{b818} | 2126 | Lₐ₁₅₇ | L_{b818} | 2127 | Lₐ₁₉₀ | L_{b818} |
| 2128 | Lₐ₁₄₇ | L_{b867} | 2129 | Lₐ₁₅₇ | L_{b867} | 2130 | Lₐ₁₉₀ | L_{b867} |
| 2131 | Lₐ₁₄₇ | L_{b868} | 2132 | Lₐ₁₅₇ | L_{b868} | 2133 | Lₐ₁₉₀ | L_{b868} |
| 2134 | Lₐ₁₄₇ | L_{b927} | 2135 | Lₐ₁₅₇ | L_{b927} | 2136 | Lₐ₁₉₀ | L_{b927} |
| 2137 | Lₐ₁₄₇ | L_{b949} | 2138 | Lₐ₁₅₇ | L_{b949} | 2139 | Lₐ₁₉₀ | L_{b949} |
| 2140 | Lₐ₁₄₇ | L_{b1003} | 2141 | Lₐ₁₅₇ | L_{b1003} | 2142 | Lₐ₁₉₀ | L_{b1003} |
| 2143 | Lₐ₁₄₇ | L_{b1052} | 2144 | Lₐ₁₅₇ | L_{b1052} | 2145 | Lₐ₁₉₀ | L_{b1052} |
| 2146 | Lₐ₁₄₇ | L_{b1053} | 2147 | Lₐ₁₅₇ | L_{b1053} | 2148 | Lₐ₁₉₀ | L_{b1053} |
| 2149 | Lₐ₁₄₇ | L_{b1057} | 2150 | Lₐ₁₅₇ | L_{b1057} | 2151 | Lₐ₁₉₀ | L_{b1057} |
| 2152 | Lₐ₁₄₇ | L_{b1106} | 2153 | Lₐ₁₅₇ | L_{b1106} | 2154 | Lₐ₁₉₀ | L_{b1106} |
| 2155 | Lₐ₁₄₇ | L_{b1107} | 2156 | Lₐ₁₅₇ | L_{b1107} | 2157 | Lₐ₁₉₀ | L_{b1107} |
| 2158 | Lₐ₁₄₇ | L_{b1111} | 2159 | Lₐ₁₅₇ | L_{b1111} | 2160 | Lₐ₁₉₀ | L_{b1111} |
| 2161 | Lₐ₁₄₇ | L_{b1160} | 2162 | Lₐ₁₅₇ | L_{b1160} | 2163 | Lₐ₁₉₀ | L_{b1160} |
| 2164 | Lₐ₁₄₇ | L_{b1161} | 2165 | Lₐ₁₅₇ | L_{b1161} | 2166 | Lₐ₁₉₀ | L_{b1161} |
| 2167 | Lₐ₁₄₇ | L_{b1162} | 2168 | Lₐ₁₅₇ | L_{b1162} | 2169 | Lₐ₁₉₀ | L_{b1162} |
| 2170 | Lₐ₁₄₇ | L_{b1163} | 2171 | Lₐ₁₅₇ | L_{b1163} | 2172 | Lₐ₁₉₀ | L_{b1163} |
| 2173 | Lₐ₁₄₇ | L_{b1214} | 2174 | Lₐ₁₅₇ | L_{b1214} | 2175 | Lₐ₁₉₀ | L_{b1214} |
| 2176 | Lₐ₁₄₇ | L_{b1215} | 2177 | Lₐ₁₅₇ | L_{b1215} | 2178 | Lₐ₁₉₀ | L_{b1215} |
| 2179 | Lₐ₁₄₇ | L_{b1216} | 2180 | Lₐ₁₅₇ | L_{b1216} | 2181 | Lₐ₁₉₀ | L_{b1216} |
| 2182 | Lₐ₁₄₇ | L_{b1217} | 2183 | Lₐ₁₅₇ | L_{b1217} | 2184 | Lₐ₁₉₀ | L_{b1217} |
| 2185 | Lₐ₁₄₇ | L_{b1219} | 2186 | Lₐ₁₅₇ | L_{b1219} | 2187 | Lₐ₁₉₀ | L_{b1219} |
| 2188 | Lₐ₁₄₇ | L_{b1270} | 2189 | Lₐ₁₅₇ | L_{b1270} | 2190 | Lₐ₁₉₀ | L_{b1270} |
| 2191 | Lₐ₁₄₇ | L_{b1271} | 2192 | Lₐ₁₅₇ | L_{b1271} | 2193 | Lₐ₁₉₀ | L_{b1271} |
| 2194 | Lₐ₁₄₇ | L_{b1273} | 2195 | Lₐ₁₅₇ | L_{b1273} | 2196 | Lₐ₁₉₀ | L_{b1273} |
| 2197 | Lₐ₁₄₇ | L_{b1376} | 2198 | Lₐ₁₅₇ | L_{b1376} | 2199 | Lₐ₁₉₀ | L_{b1376} |
| 2200 | Lₐ₁₄₇ | L_{b1377} | 2201 | Lₐ₁₅₇ | L_{b1377} | 2202 | Lₐ₁₉₀ | L_{b1377} |
| 2203 | Lₐ₁₄₇ | L_{b1378} | 2204 | Lₐ₁₅₇ | L_{b1378} | 2205 | Lₐ₁₉₀ | L_{b1378} |
| 2206 | Lₐ₁₄₈ | L_{b1} | 2207 | Lₐ₁₅₈ | L_{b1} | 2208 | Lₐ₁₉₅ | L_{b1} |
| 2209 | Lₐ₁₄₈ | L_{b2} | 2210 | Lₐ₁₅₈ | L_{b2} | 2211 | Lₐ₁₉₅ | L_{b2} |
| 2212 | Lₐ₁₄₈ | L_{b3} | 2213 | Lₐ₁₅₈ | L_{b3} | 2214 | Lₐ₁₉₅ | L_{b3} |
| 2215 | Lₐ₁₄₈ | L_{b4} | 2216 | Lₐ₁₅₈ | L_{b4} | 2217 | Lₐ₁₉₅ | L_{b4} |
| 2218 | Lₐ₁₄₈ | L_{b5} | 2219 | Lₐ₁₅₈ | L_{b5} | 2220 | Lₐ₁₉₅ | L_{b5} |
| 2221 | Lₐ₁₄₈ | L_{b6} | 2222 | Lₐ₁₅₈ | L_{b6} | 2223 | Lₐ₁₉₅ | L_{b6} |
| 2224 | Lₐ₁₄₈ | L_{b7} | 2225 | Lₐ₁₅₈ | L_{b7} | 2226 | Lₐ₁₉₅ | L_{b7} |
| 2227 | Lₐ₁₄₈ | L_{b8} | 2228 | Lₐ₁₅₈ | L_{b8} | 2229 | Lₐ₁₉₅ | L_{b8} |
| 2230 | Lₐ₁₄₈ | L_{b17} | 2231 | Lₐ₁₅₈ | L_{b17} | 2232 | Lₐ₁₉₅ | L_{b17} |
| 2233 | Lₐ₁₄₈ | L_{b19} | 2234 | Lₐ₁₅₈ | L_{b19} | 2235 | Lₐ₁₉₅ | L_{b19} |
| 2236 | Lₐ₁₄₈ | L_{b25} | 2237 | Lₐ₁₅₈ | L_{b25} | 2238 | Lₐ₁₉₅ | L_{b25} |
| 2239 | Lₐ₁₄₈ | L_{b62} | 2240 | Lₐ₁₅₈ | L_{b62} | 2241 | Lₐ₁₉₅ | L_{b62} |
| 2242 | Lₐ₁₄₈ | L_{b73} | 2243 | Lₐ₁₅₈ | L_{b73} | 2244 | Lₐ₁₉₅ | L_{b73} |
| 2245 | Lₐ₁₄₈ | L_{b79} | 2246 | Lₐ₁₅₈ | L_{b79} | 2247 | Lₐ₁₉₅ | L_{b79} |
| 2248 | Lₐ₁₄₈ | L_{b111} | 2249 | Lₐ₁₅₈ | L_{b111} | 2250 | Lₐ₁₉₅ | L_{b111} |
| 2251 | Lₐ₁₄₈ | L_{b112} | 2252 | Lₐ₁₅₈ | L_{b112} | 2253 | Lₐ₁₉₅ | L_{b112} |
| 2254 | Lₐ₁₄₈ | L_{b114} | 2255 | Lₐ₁₅₈ | L_{b114} | 2256 | Lₐ₁₉₅ | L_{b114} |
| 2257 | Lₐ₁₄₈ | L_{b117} | 2258 | Lₐ₁₅₈ | L_{b117} | 2259 | Lₐ₁₉₅ | L_{b117} |
| 2260 | Lₐ₁₄₈ | L_{b127} | 2261 | Lₐ₁₅₈ | L_{b127} | 2262 | Lₐ₁₉₅ | L_{b127} |
| 2263 | Lₐ₁₄₈ | L_{b135} | 2264 | Lₐ₁₅₈ | L_{b135} | 2265 | Lₐ₁₉₅ | L_{b135} |
| 2266 | Lₐ₁₄₈ | L_{b160} | 2267 | Lₐ₁₅₈ | L_{b160} | 2268 | Lₐ₁₉₅ | L_{b160} |
| 2269 | Lₐ₁₄₈ | L_{b161} | 2270 | Lₐ₁₅₈ | L_{b161} | 2271 | Lₐ₁₉₅ | L_{b161} |
| 2272 | Lₐ₁₄₈ | L_{b170} | 2273 | Lₐ₁₅₈ | L_{b170} | 2274 | Lₐ₁₉₅ | L_{b170} |
| 2275 | Lₐ₁₄₈ | L_{b188} | 2276 | Lₐ₁₅₈ | L_{b188} | 2277 | Lₐ₁₉₅ | L_{b188} |
| 2278 | Lₐ₁₄₈ | L_{b224} | 2279 | Lₐ₁₅₈ | L_{b224} | 2280 | Lₐ₁₉₅ | L_{b224} |
| 2281 | Lₐ₁₄₈ | L_{b249} | 2282 | Lₐ₁₅₈ | L_{b249} | 2283 | Lₐ₁₉₅ | L_{b249} |
| 2284 | Lₐ₁₄₈ | L_{b289} | 2285 | Lₐ₁₅₈ | L_{b289} | 2286 | Lₐ₁₉₅ | L_{b289} |
| 2287 | Lₐ₁₄₈ | L_{b332} | 2288 | Lₐ₁₅₈ | L_{b332} | 2289 | Lₐ₁₉₅ | L_{b332} |
| 2290 | Lₐ₁₄₈ | L_{b336} | 2291 | Lₐ₁₅₈ | L_{b336} | 2292 | Lₐ₁₉₅ | L_{b336} |
| 2293 | Lₐ₁₄₈ | L_{b337} | 2294 | Lₐ₁₅₈ | L_{b337} | 2295 | Lₐ₁₉₅ | L_{b337} |
| 2296 | Lₐ₁₄₈ | L_{b382} | 2297 | Lₐ₁₅₈ | L_{b382} | 2298 | Lₐ₁₉₅ | L_{b382} |
| 2299 | Lₐ₁₄₈ | L_{b474} | 2300 | Lₐ₁₅₈ | L_{b474} | 2301 | Lₐ₁₉₅ | L_{b474} |
| 2302 | Lₐ₁₄₈ | L_{b487} | 2303 | Lₐ₁₅₈ | L_{b487} | 2304 | Lₐ₁₉₅ | L_{b487} |
| 2305 | Lₐ₁₄₈ | L_{b488} | 2306 | Lₐ₁₅₈ | L_{b488} | 2307 | Lₐ₁₉₅ | L_{b488} |
| 2308 | Lₐ₁₄₈ | L_{b489} | 2309 | Lₐ₁₅₈ | L_{b489} | 2310 | Lₐ₁₉₅ | L_{b489} |
| 2311 | Lₐ₁₄₈ | L_{b490} | 2312 | Lₐ₁₅₈ | L_{b490} | 2313 | Lₐ₁₉₅ | L_{b490} |
| 2314 | Lₐ₁₄₈ | L_{b498} | 2315 | Lₐ₁₅₈ | L_{b498} | 2316 | Lₐ₁₉₅ | L_{b498} |
| 2317 | Lₐ₁₄₈ | L_{b499} | 2318 | Lₐ₁₅₈ | L_{b499} | 2319 | Lₐ₁₉₅ | L_{b499} |
| 2320 | Lₐ₁₄₈ | L_{b543} | 2321 | Lₐ₁₅₈ | L_{b543} | 2322 | Lₐ₁₉₅ | L_{b543} |
| 2323 | Lₐ₁₄₈ | L_{b544} | 2324 | Lₐ₁₅₈ | L_{b544} | 2325 | Lₐ₁₉₅ | L_{b544} |
| 2326 | Lₐ₁₄₈ | L_{b545} | 2327 | Lₐ₁₅₈ | L_{b545} | 2328 | Lₐ₁₉₅ | L_{b545} |
| 2329 | Lₐ₁₄₈ | L_{b597} | 2330 | Lₐ₁₅₈ | L_{b597} | 2331 | Lₐ₁₉₅ | L_{b597} |
| 2332 | Lₐ₁₄₈ | L_{b598} | 2333 | Lₐ₁₅₈ | L_{b598} | 2334 | Lₐ₁₉₅ | L_{b598} |
| 2335 | Lₐ₁₄₈ | L_{b602} | 2336 | Lₐ₁₅₈ | L_{b602} | 2337 | Lₐ₁₉₅ | L_{b602} |
| 2338 | Lₐ₁₄₈ | L_{b651} | 2339 | Lₐ₁₅₈ | L_{b651} | 2340 | Lₐ₁₉₅ | L_{b651} |
| 2341 | Lₐ₁₄₈ | L_{b652} | 2342 | Lₐ₁₅₈ | L_{b652} | 2343 | Lₐ₁₉₅ | L_{b652} |
| 2344 | Lₐ₁₄₈ | L_{b705} | 2345 | Lₐ₁₅₈ | L_{b705} | 2346 | Lₐ₁₉₅ | L_{b705} |
| 2347 | Lₐ₁₄₈ | L_{b706} | 2348 | Lₐ₁₅₈ | L_{b706} | 2349 | Lₐ₁₉₅ | L_{b706} |
| 2350 | Lₐ₁₄₈ | L_{b727} | 2351 | Lₐ₁₅₈ | L_{b727} | 2352 | Lₐ₁₉₅ | L_{b727} |
| 2353 | Lₐ₁₄₈ | L_{b728} | 2354 | Lₐ₁₅₈ | L_{b728} | 2355 | Lₐ₁₉₅ | L_{b728} |
| 2356 | Lₐ₁₄₈ | L_{b759} | 2357 | Lₐ₁₅₈ | L_{b759} | 2358 | Lₐ₁₉₅ | L_{b759} |
| 2359 | Lₐ₁₄₈ | L_{b760} | 2360 | Lₐ₁₅₈ | L_{b760} | 2361 | Lₐ₁₉₅ | L_{b760} |
| 2362 | Lₐ₁₄₈ | L_{b813} | 2363 | Lₐ₁₅₈ | L_{b813} | 2364 | Lₐ₁₉₅ | L_{b813} |
| 2365 | Lₐ₁₄₈ | L_{b814} | 2366 | Lₐ₁₅₈ | L_{b814} | 2367 | Lₐ₁₉₅ | L_{b814} |
| 2368 | Lₐ₁₄₈ | L_{b815} | 2369 | Lₐ₁₅₈ | L_{b815} | 2370 | Lₐ₁₉₅ | L_{b815} |
| 2371 | Lₐ₁₄₈ | L_{b818} | 2372 | Lₐ₁₅₈ | L_{b818} | 2373 | Lₐ₁₉₅ | L_{b818} |
| 2374 | Lₐ₁₄₈ | L_{b867} | 2375 | Lₐ₁₅₈ | L_{b867} | 2376 | Lₐ₁₉₅ | L_{b867} |
| 2377 | Lₐ₁₄₈ | L_{b868} | 2378 | Lₐ₁₅₈ | L_{b868} | 2379 | Lₐ₁₉₅ | L_{b868} |
| 2380 | Lₐ₁₄₈ | L_{b927} | 2381 | Lₐ₁₅₈ | L_{b927} | 2382 | Lₐ₁₉₅ | L_{b927} |
| 2383 | Lₐ₁₄₈ | L_{b949} | 2384 | Lₐ₁₅₈ | L_{b949} | 2385 | Lₐ₁₉₅ | L_{b949} |
| 2386 | Lₐ₁₄₈ | L_{b1003} | 2387 | Lₐ₁₅₈ | L_{b1003} | 2388 | Lₐ₁₉₅ | L_{b1003} |
| 2389 | Lₐ₁₄₈ | L_{b1052} | 2390 | Lₐ₁₅₈ | L_{b1052} | 2391 | Lₐ₁₉₅ | L_{b1052} |
| 2392 | Lₐ₁₄₈ | L_{b1053} | 2393 | Lₐ₁₅₈ | L_{b1053} | 2394 | Lₐ₁₉₅ | L_{b1053} |
| 2395 | Lₐ₁₄₈ | L_{b1057} | 2396 | Lₐ₁₅₈ | L_{b1057} | 2397 | Lₐ₁₉₅ | L_{b1057} |
| 2398 | Lₐ₁₄₈ | L_{b1106} | 2399 | Lₐ₁₅₈ | L_{b1106} | 2400 | Lₐ₁₉₅ | L_{b1106} |
| 2401 | Lₐ₁₄₈ | L_{b1107} | 2402 | Lₐ₁₅₈ | L_{b1107} | 2403 | Lₐ₁₉₅ | L_{b1107} |
| 2404 | Lₐ₁₄₈ | L_{b1111} | 2405 | Lₐ₁₅₈ | L_{b1111} | 2406 | Lₐ₁₉₅ | L_{b1111} |
| 2407 | Lₐ₁₄₈ | L_{b1160} | 2408 | Lₐ₁₅₈ | L_{b1160} | 2409 | Lₐ₁₉₅ | L_{b1160} |
| 2410 | Lₐ₁₄₈ | L_{b1161} | 2411 | Lₐ₁₅₈ | L_{b1161} | 2412 | Lₐ₁₉₅ | L_{b1161} |
| 2413 | Lₐ₁₄₈ | L_{b1162} | 2414 | Lₐ₁₅₈ | L_{b1162} | 2415 | Lₐ₁₉₅ | L_{b1162} |
| 2416 | Lₐ₁₄₈ | L_{b1163} | 2417 | Lₐ₁₅₈ | L_{b1163} | 2418 | Lₐ₁₉₅ | L_{b1163} |
| 2419 | Lₐ₁₄₈ | L_{b1214} | 2420 | Lₐ₁₅₈ | L_{b1214} | 2421 | Lₐ₁₉₅ | L_{b1214} |
| 2422 | Lₐ₁₄₈ | L_{b1215} | 2423 | Lₐ₁₅₈ | L_{b1215} | 2424 | Lₐ₁₉₅ | L_{b1215} |
| 2425 | Lₐ₁₄₈ | L_{b1216} | 2426 | Lₐ₁₅₈ | L_{b1216} | 2427 | Lₐ₁₉₅ | L_{b1216} |
| 2428 | Lₐ₁₄₈ | L_{b1217} | 2429 | Lₐ₁₅₈ | L_{b1217} | 2430 | Lₐ₁₉₅ | L_{b1217} |
| 2431 | Lₐ₁₄₈ | L_{b1219} | 2432 | Lₐ₁₅₈ | L_{b1219} | 2433 | Lₐ₁₉₅ | L_{b1219} |
| 2434 | Lₐ₁₄₈ | L_{b1270} | 2435 | Lₐ₁₅₈ | L_{b1270} | 2436 | Lₐ₁₉₅ | L_{b1270} |
| 2437 | Lₐ₁₄₈ | L_{b1271} | 2438 | Lₐ₁₅₈ | L_{b1271} | 2439 | Lₐ₁₉₅ | L_{b1271} |
| 2440 | Lₐ₁₄₈ | L_{b1273} | 2441 | Lₐ₁₅₈ | L_{b1273} | 2442 | Lₐ₁₉₅ | L_{b1273} |
| 2443 | Lₐ₁₄₈ | L_{b1376} | 2444 | Lₐ₁₅₈ | L_{b1376} | 2445 | Lₐ₁₉₅ | L_{b1376} |
| 2446 | Lₐ₁₄₈ | L_{b1377} | 2447 | Lₐ₁₅₈ | L_{b1377} | 2448 | Lₐ₁₉₅ | L_{b1377} |
| 2449 | Lₐ₁₄₈ | L_{b1378} | 2450 | Lₐ₁₅₈ | L_{b1378} | 2451 | Lₐ₁₉₅ | L_{b1378} |
| 2452 | Lₐ₂₆₆ | L_{b1} | 2453 | Lₐ₂₈₀ | L_{b1} | 2454 | Lₐ₃₃₇ | L_{b1} |
| 2455 | Lₐ₂₆₆ | L_{b2} | 2456 | Lₐ₂₈₀ | L_{b2} | 2457 | Lₐ₃₃₇ | L_{b2} |
| 2458 | Lₐ₂₆₆ | L_{b3} | 2459 | Lₐ₂₈₀ | L_{b3} | 2460 | Lₐ₃₃₇ | L_{b3} |
| 2461 | Lₐ₂₆₆ | L_{b4} | 2462 | Lₐ₂₈₀ | L_{b4} | 2463 | Lₐ₃₃₇ | L_{b4} |
| 2464 | Lₐ₂₆₆ | L_{b5} | 2465 | Lₐ₂₈₀ | L_{b5} | 2466 | Lₐ₃₃₇ | L_{b5} |
| 2467 | Lₐ₂₆₆ | L_{b6} | 2468 | Lₐ₂₈₀ | L_{b6} | 2469 | Lₐ₃₃₇ | L_{b6} |
| 2470 | Lₐ₂₆₆ | L_{b7} | 2471 | Lₐ₂₈₀ | L_{b7} | 2472 | Lₐ₃₃₇ | L_{b7} |
| 2473 | Lₐ₂₆₆ | L_{b8} | 2474 | Lₐ₂₈₀ | L_{b8} | 2475 | Lₐ₃₃₇ | L_{b8} |
| 2476 | Lₐ₂₆₆ | L_{b17} | 2477 | Lₐ₂₈₀ | L_{b17} | 2478 | Lₐ₃₃₇ | L_{b17} |
| 2479 | Lₐ₂₆₆ | L_{b19} | 2480 | Lₐ₂₈₀ | L_{b19} | 2481 | Lₐ₃₃₇ | L_{b19} |
| 2482 | Lₐ₂₆₆ | L_{b25} | 2483 | Lₐ₂₈₀ | L_{b25} | 2484 | Lₐ₃₃₇ | L_{b25} |
| 2485 | Lₐ₂₆₆ | L_{b62} | 2486 | Lₐ₂₈₀ | L_{b62} | 2487 | Lₐ₃₃₇ | L_{b62} |
| 2488 | Lₐ₂₆₆ | L_{b73} | 2489 | Lₐ₂₈₀ | L_{b73} | 2490 | Lₐ₃₃₇ | L_{b73} |
| 2491 | Lₐ₂₆₆ | L_{b79} | 2492 | Lₐ₂₈₀ | L_{b79} | 2493 | Lₐ₃₃₇ | L_{b79} |
| 2494 | Lₐ₂₆₆ | L_{b111} | 2495 | Lₐ₂₈₀ | L_{b111} | 2496 | Lₐ₃₃₇ | L_{b111} |
| 2497 | Lₐ₂₆₆ | L_{b112} | 2498 | Lₐ₂₈₀ | L_{b112} | 2499 | Lₐ₃₃₇ | L_{b112} |
| 2500 | Lₐ₂₆₆ | L_{b114} | 2501 | Lₐ₂₈₀ | L_{b114} | 2502 | Lₐ₃₃₇ | L_{b114} |
| 2503 | Lₐ₂₆₆ | L_{b117} | 2504 | Lₐ₂₈₀ | L_{b117} | 2505 | Lₐ₃₃₇ | L_{b117} |
| 2506 | Lₐ₂₆₆ | L_{b127} | 2507 | Lₐ₂₈₀ | L_{b127} | 2508 | Lₐ₃₃₇ | L_{b127} |
| 2509 | Lₐ₂₆₆ | L_{b135} | 2510 | Lₐ₂₈₀ | L_{b135} | 2511 | Lₐ₃₃₇ | L_{b135} |
| 2512 | Lₐ₂₆₆ | L_{b160} | 2513 | Lₐ₂₈₀ | L_{b160} | 2514 | Lₐ₃₃₇ | L_{b160} |
| 2515 | Lₐ₂₆₆ | L_{b161} | 2516 | Lₐ₂₈₀ | L_{b161} | 2517 | Lₐ₃₃₇ | L_{b161} |
| 2518 | Lₐ₂₆₆ | L_{b170} | 2519 | Lₐ₂₈₀ | L_{b170} | 2520 | Lₐ₃₃₇ | L_{b170} |
| 2521 | Lₐ₂₆₆ | L_{b188} | 2522 | Lₐ₂₈₀ | L_{b188} | 2523 | Lₐ₃₃₇ | L_{b188} |
| 2524 | Lₐ₂₆₆ | L_{b224} | 2525 | Lₐ₂₈₀ | L_{b224} | 2526 | Lₐ₃₃₇ | L_{b224} |
| 2527 | Lₐ₂₆₆ | L_{b249} | 2528 | Lₐ₂₈₀ | L_{b249} | 2529 | Lₐ₃₃₇ | L_{b249} |
| 2530 | Lₐ₂₆₆ | L_{b289} | 2531 | Lₐ₂₈₀ | L_{b289} | 2532 | Lₐ₃₃₇ | L_{b289} |
| 2533 | Lₐ₂₆₆ | L_{b332} | 2534 | Lₐ₂₈₀ | L_{b332} | 2535 | Lₐ₃₃₇ | L_{b332} |
| 2536 | Lₐ₂₆₆ | L_{b336} | 2537 | Lₐ₂₈₀ | L_{b336} | 2538 | Lₐ₃₃₇ | L_{b336} |
| 2539 | Lₐ₂₆₆ | L_{b337} | 2540 | Lₐ₂₈₀ | L_{b337} | 2541 | Lₐ₃₃₇ | L_{b337} |
| 2542 | Lₐ₂₆₆ | L_{b382} | 2543 | Lₐ₂₈₀ | L_{b382} | 2544 | Lₐ₃₃₇ | L_{b382} |
| 2545 | Lₐ₂₆₆ | L_{b474} | 2546 | Lₐ₂₈₀ | L_{b474} | 2547 | Lₐ₃₃₇ | L_{b474} |
| 2548 | Lₐ₂₆₆ | L_{b487} | 2549 | Lₐ₂₈₀ | L_{b487} | 2550 | Lₐ₃₃₇ | L_{b487} |
| 2551 | Lₐ₂₆₆ | L_{b488} | 2552 | Lₐ₂₈₀ | L_{b488} | 2553 | Lₐ₃₃₇ | L_{b488} |
| 2554 | Lₐ₂₆₆ | L_{b489} | 2555 | Lₐ₂₈₀ | L_{b489} | 2556 | Lₐ₃₃₇ | L_{b489} |
| 2557 | Lₐ₂₆₆ | L_{b490} | 2558 | Lₐ₂₈₀ | L_{b490} | 2559 | Lₐ₃₃₇ | L_{b490} |
| 2560 | Lₐ₂₆₆ | L_{b498} | 2561 | Lₐ₂₈₀ | L_{b498} | 2562 | Lₐ₃₃₇ | L_{b498} |
| 2563 | Lₐ₂₆₆ | L_{b499} | 2564 | Lₐ₂₈₀ | L_{b499} | 2565 | Lₐ₃₃₇ | L_{b499} |
| 2566 | Lₐ₂₆₆ | L_{b543} | 2567 | Lₐ₂₈₀ | L_{b543} | 2568 | Lₐ₃₃₇ | L_{b543} |
| 2569 | Lₐ₂₆₆ | L_{b544} | 2570 | Lₐ₂₈₀ | L_{b544} | 2571 | Lₐ₃₃₇ | L_{b544} |
| 2572 | Lₐ₂₆₆ | L_{b545} | 2573 | Lₐ₂₈₀ | L_{b545} | 2574 | Lₐ₃₃₇ | L_{b545} |
| 2575 | Lₐ₂₆₆ | L_{b597} | 2576 | Lₐ₂₈₀ | L_{b597} | 2577 | Lₐ₃₃₇ | L_{b597} |
| 2578 | Lₐ₂₆₆ | L_{b598} | 2579 | Lₐ₂₈₀ | L_{b598} | 2580 | Lₐ₃₃₇ | L_{b598} |
| 2581 | Lₐ₂₆₆ | L_{b602} | 2582 | Lₐ₂₈₀ | L_{b602} | 2583 | Lₐ₃₃₇ | L_{b602} |
| 2584 | Lₐ₂₆₆ | L_{b651} | 2585 | Lₐ₂₈₀ | L_{b651} | 2586 | Lₐ₃₃₇ | L_{b651} |
| 2587 | Lₐ₂₆₆ | L_{b652} | 2588 | Lₐ₂₈₀ | L_{b652} | 2589 | Lₐ₃₃₇ | L_{b652} |
| 2590 | Lₐ₂₆₆ | L_{b705} | 2591 | Lₐ₂₈₀ | L_{b705} | 2592 | Lₐ₃₃₇ | L_{b705} |
| 2593 | Lₐ₂₆₆ | L_{b706} | 2594 | Lₐ₂₈₀ | L_{b706} | 2595 | Lₐ₃₃₇ | L_{b706} |
| 2596 | Lₐ₂₆₆ | L_{b727} | 2597 | Lₐ₂₈₀ | L_{b727} | 2598 | Lₐ₃₃₇ | L_{b727} |
| 2599 | Lₐ₂₆₆ | L_{b728} | 2600 | Lₐ₂₈₀ | L_{b728} | 2601 | Lₐ₃₃₇ | L_{b728} |
| 2602 | Lₐ₂₆₆ | L_{b759} | 2603 | Lₐ₂₈₀ | L_{b759} | 2604 | Lₐ₃₃₇ | L_{b759} |
| 2605 | Lₐ₂₆₆ | L_{b760} | 2606 | Lₐ₂₈₀ | L_{b760} | 2607 | Lₐ₃₃₇ | L_{b760} |
| 2608 | Lₐ₂₆₆ | L_{b813} | 2609 | Lₐ₂₈₀ | L_{b813} | 2610 | Lₐ₃₃₇ | L_{b813} |
| 2611 | Lₐ₂₆₆ | L_{b814} | 2612 | Lₐ₂₈₀ | L_{b814} | 2613 | Lₐ₃₃₇ | L_{b814} |
| 2614 | Lₐ₂₆₆ | L_{b815} | 2615 | Lₐ₂₈₀ | L_{b815} | 2616 | Lₐ₃₃₇ | L_{b815} |
| 2617 | Lₐ₂₆₆ | L_{b818} | 2618 | Lₐ₂₈₀ | L_{b818} | 2619 | Lₐ₃₃₇ | L_{b818} |
| 2620 | Lₐ₂₆₆ | L_{b867} | 2621 | Lₐ₂₈₀ | L_{b867} | 2622 | Lₐ₃₃₇ | L_{b867} |
| 2623 | Lₐ₂₆₆ | L_{b868} | 2624 | Lₐ₂₈₀ | L_{b868} | 2625 | Lₐ₃₃₇ | L_{b868} |
| 2626 | Lₐ₂₆₆ | L_{b927} | 2627 | Lₐ₂₈₀ | L_{b927} | 2628 | Lₐ₃₃₇ | L_{b927} |
| 2629 | Lₐ₂₆₆ | L_{b949} | 2630 | Lₐ₂₈₀ | L_{b949} | 2631 | Lₐ₃₃₇ | L_{b949} |
| 2632 | Lₐ₂₆₆ | L_{b1003} | 2633 | Lₐ₂₈₀ | L_{b1003} | 2634 | Lₐ₃₃₇ | L_{b1003} |
| 2635 | Lₐ₂₆₆ | L_{b1052} | 2636 | Lₐ₂₈₀ | L_{b1052} | 2637 | Lₐ₃₃₇ | L_{b1052} |
| 2638 | Lₐ₂₆₆ | L_{b1053} | 2639 | Lₐ₂₈₀ | L_{b1053} | 2640 | Lₐ₃₃₇ | L_{b1053} |
| 2641 | Lₐ₂₆₆ | L_{b1057} | 2642 | Lₐ₂₈₀ | L_{b1057} | 2643 | Lₐ₃₃₇ | L_{b1057} |
| 2644 | Lₐ₂₆₆ | L_{b1106} | 2645 | Lₐ₂₈₀ | L_{b1106} | 2646 | Lₐ₃₃₇ | L_{b1106} |
| 2647 | Lₐ₂₆₆ | L_{b1107} | 2648 | Lₐ₂₈₀ | L_{b1107} | 2649 | Lₐ₃₃₇ | L_{b1107} |
| 2650 | Lₐ₂₆₆ | L_{b1111} | 2651 | Lₐ₂₈₀ | L_{b1111} | 2652 | Lₐ₃₃₇ | L_{b1111} |
| 2653 | Lₐ₂₆₆ | L_{b1160} | 2654 | Lₐ₂₈₀ | L_{b1160} | 2655 | Lₐ₃₃₇ | L_{b1160} |
| 2656 | Lₐ₂₆₆ | L_{b1161} | 2657 | Lₐ₂₈₀ | L_{b1161} | 2658 | Lₐ₃₃₇ | L_{b1161} |
| 2659 | Lₐ₂₆₆ | L_{b1162} | 2660 | Lₐ₂₈₀ | L_{b1162} | 2661 | Lₐ₃₃₇ | L_{b1162} |
| 2662 | Lₐ₂₆₆ | L_{b1163} | 2663 | Lₐ₂₈₀ | L_{b1163} | 2664 | Lₐ₃₃₇ | L_{b1163} |
| 2665 | Lₐ₂₆₆ | L_{b1214} | 2666 | Lₐ₂₈₀ | L_{b1214} | 2667 | Lₐ₃₃₇ | L_{b1214} |
| 2668 | Lₐ₂₆₆ | L_{b1215} | 2669 | Lₐ₂₈₀ | L_{b1215} | 2670 | Lₐ₃₃₇ | L_{b1215} |
| 2671 | Lₐ₂₆₆ | L_{b1216} | 2672 | Lₐ₂₈₀ | L_{b1216} | 2673 | Lₐ₃₃₇ | L_{b1216} |
| 2674 | Lₐ₂₆₆ | L_{b1217} | 2675 | Lₐ₂₈₀ | L_{b1217} | 2676 | Lₐ₃₃₇ | L_{b1217} |
| 2677 | Lₐ₂₆₆ | L_{b1219} | 2678 | Lₐ₂₈₀ | L_{b1219} | 2679 | Lₐ₃₃₇ | L_{b1219} |
| 2680 | Lₐ₂₆₆ | L_{b1270} | 2681 | Lₐ₂₈₀ | L_{b1270} | 2682 | Lₐ₃₃₇ | L_{b1270} |
| 2683 | Lₐ₂₆₆ | L_{b1271} | 2684 | Lₐ₂₈₀ | L_{b1271} | 2685 | Lₐ₃₃₇ | L_{b1271} |
| 2686 | Lₐ₂₆₆ | L_{b1273} | 2687 | Lₐ₂₈₀ | L_{b1273} | 2688 | Lₐ₃₃₇ | L_{b1273} |
| 2689 | Lₐ₂₆₆ | L_{b1376} | 2690 | Lₐ₂₈₀ | L_{b1376} | 2691 | Lₐ₃₃₇ | L_{b1376} |
| 2692 | Lₐ₂₆₆ | L_{b1377} | 2693 | Lₐ₂₈₀ | L_{b1377} | 2694 | Lₐ₃₃₇ | L_{b1377} |
| 2695 | Lₐ₂₆₆ | L_{b1378} | 2696 | Lₐ₂₈₀ | L_{b1378} | 2697 | Lₐ₃₃₇ | L_{b1378} |
| 2698 | Lₐ₃₄₂ | L_{b1} | 2699 | Lₐ₅₆₂ | L_{b1} | 2700 | Lₐ₁₇₄₅ | L_{b1} |
| 2701 | Lₐ₃₆₅ | L_{b2} | 2702 | Lₐ₅₆₃ | L_{b2} | 2703 | Lₐ₁₇₄₆ | L_{b2} |
| 2704 | Lₐ₃₆₆ | L_{b3} | 2705 | Lₐ₅₆₄ | L_{b3} | 2706 | Lₐ₁₇₄₇ | L_{b3} |
| 2707 | Lₐ₃₆₇ | L_{b4} | 2708 | Lₐ₅₆₅ | L_{b4} | 2709 | Lₐ₁₇₄₈ | L_{b4} |
| 2710 | Lₐ₃₆₈ | L_{b5} | 2711 | Lₐ₅₆₆ | L_{b5} | 2712 | Lₐ₁₇₄₉ | L_{b5} |
| 2713 | Lₐ₃₆₉ | L_{b6} | 2714 | Lₐ₅₆₇ | L_{b6} | 2715 | Lₐ₁₇₅₀ | L_{b6} |
| 2716 | Lₐ₃₇₀ | L_{b7} | 2717 | Lₐ₅₆₈ | L_{b7} | 2718 | Lₐ₁₇₆₈ | L_{b7} |
| 2719 | Lₐ₃₇₁ | L_{b8} | 2720 | Lₐ₅₈₄ | L_{b8} | 2721 | Lₐ₁₇₆₉ | L_{b8} |
| 2722 | Lₐ₃₇₂ | L_{b17} | 2723 | Lₐ₅₈₅ | L_{b17} | 2724 | Lₐ₁₇₇₀ | L_{b17} |
| 2725 | Lₐ₃₇₃ | L_{b19} | 2726 | Lₐ₅₈₆ | L_{b19} | 2727 | Lₐ₁₇₇₁ | L_{b19} |
| 2728 | Lₐ₃₇₇ | L_{b25} | 2729 | Lₐ₅₈₇ | L_{b25} | 2730 | Lₐ₁₈₃₉ | L_{b25} |
| 2731 | Lₐ₃₇₈ | L_{b62} | 2732 | Lₐ₅₈₈ | L_{b62} | 2733 | Lₐ₁₈₄₀ | L_{b62} |
| 2734 | Lₐ₃₇₉ | L_{b73} | 2735 | Lₐ₅₈₉ | L_{b73} | 2736 | Lₐ₁₈₄₁ | L_{b73} |
| 2737 | Lₐ₃₈₀ | L_{b79} | 2738 | Lₐ₆₂₆ | L_{b79} | 2739 | Lₐ₁₈₈₇ | L_{b79} |
| 2740 | Lₐ₃₈₁ | L_{b111} | 2741 | Lₐ₆₂₇ | L_{b111} | 2742 | Lₐ₁₈₈₈ | L_{b111} |
| 2743 | Lₐ₃₈₅ | L_{b112} | 2744 | Lₐ₆₂₈ | L_{b112} | 2745 | Lₐ₁₈₈₉ | L_{b112} |
| 2746 | Lₐ₃₈₆ | L_{b114} | 2747 | Lₐ₆₂₉ | L_{b114} | 2748 | Lₐ₁₈₉₀ | L_{b114} |
| 2749 | Lₐ₃₈₇ | L_{b117} | 2750 | Lₐ₆₃₀ | L_{b117} | 2751 | Lₐ₁₉₁₉ | L_{b117} |
| 2752 | Lₐ₃₈₈ | L_{b127} | 2753 | Lₐ₆₃₁ | L_{b127} | 2754 | Lₐ₁₉₂₀ | L_{b127} |
| 2755 | Lₐ₃₉₁ | L_{b135} | 2756 | Lₐ₇₄₀ | L_{b135} | 2757 | Lₐ₁₉₂₁ | L_{b135} |
| 2758 | Lₐ₃₉₂ | L_{b160} | 2759 | Lₐ₇₄₁ | L_{b160} | 2760 | Lₐ₁₉₂₂ | L_{b160} |
| 2761 | Lₐ₃₉₃ | L_{b161} | 2762 | Lₐ₇₄₂ | L_{b161} | 2763 | Lₐ₂₀₂₅ | L_{b161} |
| 2764 | Lₐ₃₉₄ | L_{b170} | 2765 | Lₐ₇₉₇ | L_{b170} | 2766 | Lₐ₂₀₂₆ | L_{b170} |
| 2767 | Lₐ₃₉₅ | L_{b188} | 2768 | Lₐ₇₉₈ | L_{b188} | 2769 | Lₐ₂₀₂₇ | L_{b188} |
| 2770 | Lₐ₃₉₆ | L_{b224} | 2771 | Lₐ₇₉₉ | L_{b224} | 2772 | Lₐ₂₁₀₀ | L_{b224} |
| 2773 | Lₐ₄₀₈ | L_{b249} | 2774 | Lₐ₈₀₀ | L_{b249} | 2775 | Lₐ₂₁₀₁ | L_{b249} |
| 2776 | Lₐ₄₀₉ | L_{b289} | 2777 | Lₐ₈₀₁ | L_{b289} | 2778 | Lₐ₂₁₀₂ | L_{b289} |
| 2779 | Lₐ₄₁₀ | L_{b332} | 2780 | Lₐ₈₀₂ | L_{b332} | 2781 | Lₐ₂₂₁₄ | L_{b332} |
| 2782 | Lₐ₄₁₁ | L_{b336} | 2783 | Lₐ₈₀₃ | L_{b336} | 2784 | Lₐ₂₂₁₅ | L_{b336} |
| 2785 | Lₐ₄₁₂ | L_{b337} | 2786 | Lₐ₉₁₁ | L_{b337} | 2787 | Lₐ₂₂₁₆ | L_{b337} |
| 2788 | Lₐ₄₁₃ | L_{b382} | 2789 | Lₐ₉₁₂ | L_{b382} | 2790 | Lₐ₂₃₀₉ | L_{b382} |
| 2791 | Lₐ₄₁₄ | L_{b474} | 2792 | Lₐ₉₁₃ | L_{b474} | 2793 | Lₐ₂₃₁₀ | L_{b474} |
| 2794 | Lₐ₄₂₂ | L_{b487} | 2795 | Lₐ₉₁₄ | L_{b487} | 2796 | Lₐ₂₃₁₁ | L_{b487} |
| 2797 | Lₐ₄₂₃ | L_{b488} | 2798 | Lₐ₉₁₅ | L_{b488} | 2799 | Lₐ₂₃₇₇ | L_{b488} |
| 2800 | Lₐ₄₂₄ | L_{b489} | 2801 | Lₐ₉₅₀ | L_{b489} | 2802 | Lₐ₂₃₇₈ | L_{b489} |
| 2803 | Lₐ₄₂₅ | L_{b490} | 2804 | Lₐ₉₅₁ | L_{b490} | 2805 | Lₐ₂₃₇₉ | L_{b490} |
| 2806 | Lₐ₄₂₆ | L_{b498} | 2807 | Lₐ₉₅₂ | L_{b498} | 2808 | Lₐ₂₄₁₅ | L_{b498} |
| 2809 | Lₐ₄₂₇ | L_{b499} | 2810 | Lₐ₉₅₃ | L_{b499} | 2811 | Lₐ₂₄₁₆ | L_{b499} |
| 2812 | Lₐ₄₂₈ | L_{b543} | 2813 | Lₐ₉₅₄ | L_{b543} | 2814 | Lₐ₂₄₁₇ | L_{b543} |
| 2815 | Lₐ₄₂₉ | L_{b544} | 2816 | Lₐ₁₀₁₂ | L_{b544} | 2817 | Lₐ₂₄₁₈ | L_{b544} |
| 2818 | Lₐ₄₃₀ | L_{b545} | 2819 | Lₐ₁₀₁₃ | L_{b545} | 2820 | Lₐ₂₄₁₉ | L_{b545} |
| 2821 | Lₐ₄₃₁ | L_{b597} | 2822 | Lₐ₁₀₁₄ | L_{b597} | 2823 | Lₐ₂₄₁₅ | L_{b597} |
| 2824 | Lₐ₄₄₁ | L_{b598} | 2825 | Lₐ₁₀₆₃ | L_{b598} | 2826 | Lₐ₂₄₁₆ | L_{b598} |
| 2827 | Lₐ₄₄₂ | L_{b602} | 2828 | Lₐ₁₀₆₄ | L_{b602} | 2829 | Lₐ₂₄₁₇ | L_{b602} |
| 2830 | Lₐ₄₄₃ | L_{b651} | 2831 | Lₐ₁₀₆₅ | L_{b651} | 2832 | Lₐ₂₄₁₈ | L_{b651} |
| 2833 | Lₐ₄₄₄ | L_{b652} | 2834 | Lₐ₁₀₆₆ | L_{b652} | 2835 | Lₐ₂₄₁₉ | L_{b652} |
| 2836 | Lₐ₄₅₇ | L_{b705} | 2837 | Lₐ₁₁₀₆ | L_{b705} | 2838 | Lₐ₂₄₆₃ | L_{b705} |
| 2839 | Lₐ₄₅₈ | L_{b706} | 2840 | Lₐ₁₁₀₇ | L_{b706} | 2841 | Lₐ₂₄₆₄ | L_{b706} |
| 2842 | Lₐ₄₅₉ | L_{b727} | 2843 | Lₐ₁₁₀₈ | L_{b727} | 2844 | Lₐ₂₄₆₅ | L_{b727} |
| 2845 | Lₐ₄₆₀ | L_{b728} | 2846 | Lₐ₁₁₁₂ | L_{b728} | 2847 | Lₐ₂₄₆₆ | L_{b728} |
| 2848 | Lₐ₄₆₁ | L_{b759} | 2849 | Lₐ₁₁₁₃ | L_{b759} | 2850 | Lₐ₂₄₆₇ | L_{b759} |
| 2851 | Lₐ₄₆₂ | L_{b760} | 2852 | Lₐ₁₁₃₉ | L_{b760} | 2853 | Lₐ₂₅₁₇ | L_{b760} |
| 2854 | Lₐ₄₆₃ | L_{b813} | 2855 | Lₐ₁₁₄₀ | L_{b813} | 2856 | Lₐ₂₅₁₈ | L_{b813} |
| 2857 | Lₐ₄₆₄ | L_{b814} | 2858 | Lₐ₁₁₄₁ | L_{b814} | 2859 | Lₐ₂₅₁₉ | L_{b814} |
| 2860 | Lₐ₄₆₅ | L_{b815} | 2861 | Lₐ₁₁₄₂ | L_{b815} | 2862 | Lₐ₂₅₂₀ | L_{b815} |
| 2863 | Lₐ₄₆₆ | L_{b818} | 2864 | Lₐ₁₁₈₀ | L_{b818} | 2865 | Lₐ₂₅₂₁ | L_{b818} |
| 2866 | Lₐ₄₇₈ | L_{b867} | 2867 | Lₐ₁₁₈₁ | L_{b867} | 2868 | Lₐ₂₅₂₂ | L_{b867} |
| 2869 | Lₐ₄₇₉ | L_{b868} | 2870 | Lₐ₁₁₈₂ | L_{b868} | 2871 | Lₐ₂₅₅₆ | L_{b868} |
| 2872 | Lₐ₄₈₀ | L_{b927} | 2873 | Lₐ₁₂₀₉ | L_{b927} | 2874 | Lₐ₂₅₅₇ | L_{b927} |
| 2875 | Lₐ₄₈₁ | L_{b949} | 2876 | Lₐ₁₂₁₀ | L_{b949} | 2877 | Lₐ₂₅₅₈ | L_{b949} |
| 2878 | Lₐ₄₈₂ | L_{b1003} | 2879 | Lₐ₁₂₁₁ | L_{b1003} | 2880 | Lₐ₂₅₅₉ | L_{b1003} |
| 2881 | Lₐ₄₈₃ | L_{b1052} | 2882 | Lₐ₁₂₁₂ | L_{b1052} | 2883 | Lₐ₂₅₇₇ | L_{b1052} |
| 2884 | Lₐ₄₈₅ | L_{b1053} | 2885 | Lₐ₁₂₁₃ | L_{b1053} | 2886 | Lₐ₂₅₇₈ | L_{b1053} |
| 2887 | Lₐ₄₈₆ | L_{b1057} | 2888 | Lₐ₁₂₅₃ | L_{b1057} | 2889 | Lₐ₂₅₇₉ | L_{b1057} |
| 2890 | Lₐ₄₈₇ | L_{b1106} | 2891 | Lₐ₁₂₆₀ | L_{b1106} | 2892 | Lₐ₂₆₀₅ | L_{b1106} |
| 2893 | Lₐ₄₈₈ | L_{b1107} | 2894 | Lₐ₁₂₆₁ | L_{b1107} | 2895 | Lₐ₂₆₀₆ | L_{b1107} |
| 2896 | Lₐ₄₈₉ | L_{b1111} | 2897 | Lₐ₁₂₆₂ | L_{b1111} | 2898 | Lₐ₂₆₀₇ | L_{b1111} |
| 2899 | Lₐ₄₉₀ | L_{b1160} | 2900 | Lₐ₁₂₆₃ | L_{b1160} | 2901 | Lₐ₂₈₂₂ | L_{b1160} |
| 2902 | Lₐ₄₉₁ | L_{b1161} | 2903 | Lₐ₁₂₆₄ | L_{b1161} | 2904 | Lₐ₂₈₂₃ | L_{b1161} |
| 2905 | Lₐ₄₉₂ | L_{b1162} | 2906 | Lₐ₁₇₀₇ | L_{b1162} | 2907 | Lₐ₂₈₂₄ | L_{b1162} |
| 2908 | Lₐ₅₀₆ | L_{b1163} | 2909 | Lₐ₁₇₀₈ | L_{b1163} | 2910 | Lₐ₂₈₂₅ | L_{b1163} |
| 2911 | Lₐ₅₀₇ | L_{b1214} | 2912 | Lₐ₁₇₀₉ | L_{b1214} | 2913 | Lₐ₃₁₅₅ | L_{b1214} |
| 2914 | Lₐ₅₀₈ | L_{b1215} | 2915 | Lₐ₁₇₁₀ | L_{b1215} | 2916 | Lₐ₃₁₅₆ | L_{b1215} |
| 2917 | Lₐ₅₀₉ | L_{b1216} | 2918 | Lₐ₁₇₁₁ | L_{b1216} | 2919 | Lₐ₃₁₅₇ | L_{b1216} |
| 2920 | Lₐ₅₁₀ | L_{b1217} | 2921 | Lₐ₁₇₁₂ | L_{b1217} | 2922 | Lₐ₃₄₄₈ | L_{b1217} |
| 2923 | Lₐ₅₁₅ | L_{b1219} | 2924 | Lₐ₁₇₂₆ | L_{b1219} | 2925 | Lₐ₃₄₄₉ | L_{b1219} |
| 2926 | Lₐ₅₁₆ | L_{b1270} | 2927 | Lₐ₁₇₂₇ | L_{b1270} | 2928 | Lₐ₃₄₈₉ | L_{b1270} |
| 2929 | Lₐ₅₁₇ | L_{b1271} | 2930 | Lₐ₁₇₂₈ | L_{b1271} | 2931 | Lₐ₃₄₉₀ | L_{b1271} |
| 2932 | Lₐ₅₁₈ | L_{b1273} | 2933 | Lₐ₁₇₂₉ | L_{b1273} | 2934 | Lₐ₃₅₂₃ | L_{b1273} |
| 2935 | Lₐ₅₁₉ | L_{b1376} | 2936 | Lₐ₁₇₃₀ | L_{b1376} | 2937 | Lₐ₃₅₂₄ | L_{b1376} |
| 2938 | Lₐ₅₂₀ | L_{b1377} | 2939 | Lₐ₁₇₃₁ | L_{b1377} | 2940 | Lₐ₃₅₂₅ | L_{b1377} |
| 2941 | Lₐ₅₂₉ | L_{b1378} | 2942 | Lₐ₁₇₃₃ | L_{b1378} | 2943 | Lₐ₃₅₂₆ | L_{b1378} |

Metal Complex 2944 to Metal Complex 2959 each have a structure of Ir(Lₐ)(L_{b})(L_{c}), wherein Lₐ, L_{b} and L_{c} correspond to the structures listed in the following table, respectively:

| Metal | | | |
|---|---|---|---|
| Complex | Lₐ | L_{b} | L_{c} |
| 2944 | Lₐ₁ | L_{b494} | L_{c1} |
| 2945 | Lₐ₇₈ | L_{b494} | L_{c1} |
| 2946 | Lₐ₁ | L_{b710} | L_{c26} |
| 2947 | Lₐ₇₈ | L_{b710} | L_{c26} |
| 2948 | Lₐ₁ | L_{b928} | L_{c52} |
| 2949 | Lₐ₇₈ | L_{b928} | L_{c52} |
| 2950 | Lₐ₁ | L_{b404} | L_{c115} |
| 2951 | Lₐ₇₈ | L_{b404} | L_{c115} |
| 2952 | Lₐ₁₁₈ | L_{b494} | L_{c1} |
| 2953 | Lₐ₅₁₂ | L_{b494} | L_{c1} |
| 2954 | Lₐ₁₁₈ | L_{b710} | L_{c26} |
| 2955 | Lₐ₅₁₂ | L_{b710} | L_{c26} |
| 2956 | Lₐ₁₁₈ | L_{b928} | L_{c52} |
| 2957 | Lₐ₅₁₂ | L_{b928} | L_{c52} |
| 2958 | Lₐ₁₁₈ | L_{b404} | L_{c115} |
| 2959 | Lₐ₅₁₂ | L_{b404} | L_{c115} |

wherein optionally, hydrogens in Metal Complex 1 to Metal Complex 2959 can be partially or fully substituted with deuterium.

19. An organic electroluminescent device, comprising:
an anode,
a cathode, and
an organic layer disposed between the anode and the cathode, wherein at least one layer of the organic layer comprises the metal complex of claim 1.

20. The organic electroluminescent device of claim 19, wherein the organic layer comprising the metal complex is an emissive layer.

21. The organic electroluminescent device of claim 20, wherein the emissive layer further comprises a first host compound or further comprises a first host compound and a second host compound;
preferably, the first host compound and/or the second host compound comprise at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

22. The organic electroluminescent device of claim 21, wherein the metal complex is doped in the first host compound and the second host compound, and a weight of the metal complex accounts for 1% to 30% of a total weight of the emissive layer,
preferably, the metal complex is doped in the first host compound and the second host compound, and the weight of the metal complex accounts for 3% to 13% of the total weight of the emissive layer.

23. A compound composition, comprising the metal complex of claim 1.
